(19) United States
(12) Patent Application Publication
(10) Pub. No.: US 2020/0235307 A1
(43) Pub. Date: Jul. 23, 2020

(54) ORGANIC ELECTROLUMINESCENT DEVICE

(71) Applicant: ROHM AND HAAS ELECTRONIC MATERIALS KOREA LTD., Chungcheongnam-do (KR)

(72) Inventors: Sang-Hee CHO, Gyeonggi-do (KR); Bitnari KIM, Gyeonggi-do (KR); Jeong-Eun YANG, Gyeonggi-do (KR)

(21) Appl. No.: 16/483,063

(22) PCT Filed: Feb. 28, 2018
(86) PCT No.: PCT/KR2018/002503

§ 371 Date: Aug. 2, 2019

(30) Foreign Application Priority Data
Feb. 28, 2017 (KR) 10-2017-0026014
Sep. 26, 2017 (KR) 10-2017-0124258
Sep. 26, 2017 (KR) 10-2017-0124285
Nov. 3, 2017 (KR) 10-2017-0145972
Dec. 27, 2017 (KR) 10-2017-0180988
Feb. 27, 2018 (KR) 10-2018-0023907

(51) Int. Cl. H01L 51/00

(52) U.S. Cl. CPC H01L 51/0067; H01L 51/0074; H01L 51/5016; H01L 51/0071; H01L 2251/552; H01L 51/0072

(57) ABSTRACT

The present disclosure relates to an organic electroluminescent device. The organic electroluminescent device of the present disclosure comprises a specific combination of a light-emitting layer and an electron transport zone, thereby providing low voltage, high efficiency, and/or long lifespan.

### TECHNICAL FIELD

The present disclosure relates to an organic electroluminescent device comprising a light-emitting layer and an electron transport zone.

### BACKGROUND ART

An electroluminescent (EL) device is a self-light-emitting device with the advantages of providing a wider viewing angle, a greater contrast ratio, and a faster response time. The first organic EL device was developed by Eastman Kodak in 1987, by using small aromatic diamine molecules and aluminum complexes as materials for forming a light-emitting layer (see Appl. Phys. Lett. 51, 913, 1987).

An organic EL device changes electric energy into light by the injection of a charge into an organic light-emitting material, and commonly comprises an anode, a cathode, and an organic layer formed between the two electrodes. The organic layer of the organic EL device may be composed of a hole injection layer, a hole transport layer, an electron blocking layer, a light-emitting layer (containing host and dopant materials), an electron buffer layer, a hole blocking layer, an electron transport layer, an electron injection layer, etc.; the materials used in the organic layer can be classified into a hole injection material, a hole transport material, an electron blocking material, a light-emitting material, an electron buffer material, a hole blocking material, an electron transport material, an electron injection material, etc., depending on functions. In the organic EL device, holes from an anode and electrons from a cathode are injected into a light-emitting layer by electric voltage, and an exciton having high energy is produced by the recombination of the holes and electrons. The organic light-emitting compound moves into an excited state by the energy and emits light from energy when the organic light-emitting compound returns to the ground state from the excited state.

The most important factor determining luminous efficiency in an organic EL device is light-emitting materials. The light-emitting materials are required to have the following features: high quantum efficiency, high movement degree of an electron and a hole, and uniformality and stability of the formed light-emitting material layer. The light-emitting material is classified into blue, green, and red light-emitting materials according to the light-emitting color, and further includes yellow or orange light-emitting materials. Furthermore, the light-emitting material is classified into a host material and a dopant material in a functional aspect. Recently, an urgent task is the development of an organic EL device having high efficiency and long lifespan. In particular, the development of highly excellent light-emitting material over conventional materials is urgently required, considering the EL properties necessary for medium- and large-sized OLED panels.

In an organic EL device, an electron transport material actively transports electrons from a cathode to a light-emitting layer and inhibits transport of holes which are not recombined in the light-emitting layer to increase recombination opportunity of holes and electrons in the light-emitting layer. Thus, electron-affinitive materials are used as an electron transport material. Organic metal complexes having light-emitting function such as Alq₃ are excellent in transporting electrons, and thus have been conventionally used as an electron transport material. However, Alq₃ has problems in that it moves to other layers and shows reduction of lifespan. Therefore, new electron transport materials have been required, which do not have the above problems, are highly electron-affinitive, and quickly transport electrons in organic EL devices to provide organic EL devices having high luminous efficiency.

In addition, the electron buffer layer is a layer for solving the problem of deterioration in luminance caused by the change of a current characteristic of the device when exposed to a high temperature during a process of producing a panel. Thus, the characteristic of the compound comprised in the electron buffer layer is important. Further, the compound used in the electron buffer layer is preferable to function as to control the injection of the electrons due to the electron withdrawing property and the LUMO energy value of electron affinity, thereby enhancing the efficiency and lifespan of the organic EL device.

U.S. Pat. No. 6,902,831 discloses an azulene derivative as an organic electroluminescent compound. However, said reference does not specifically disclose an organic electroluminescent compound of a fused azulene derivative.

### DISCLOSURE OF THE INVENTION

### Problems to be Solved

The objective of the present disclosure is to provide an organic electroluminescent device having low voltage, high efficiency, and/or long lifespan by comprising a specific combination of a light-emitting layer and an electron transport zone.

### Solution to Problems

For a light-emitting layer comprising a phosphorescent dopant, it is preferable that the hole and electron current characteristics of the light-emitting material are excellent for low voltage, high efficiency and long lifespan, and the thermal stability of the material is excellent for improvement of lifespan. In addition, for efficient energy transport from the host to the dopant of the light-emitting layer, using a light-emitting material having a narrow energy band gap can contribute to improve driving voltage and luminous efficiency by minimizing the charge trap. While the azulene derivative comprised in the device of the present disclosure has a slow transition constant of the internal conversion of S₂→S₁ of 7*10⁻⁸ s, the transition constant of the internal conversion of S₁→S₀ is fast, i.e. 7*10⁻¹² s. Thus, the fluorescence quantum yield of S₂-S₀ increases, and so the azulene derivative is one of the representative materials which violates Kasha's rule. According to a non-patent document of [Phys. Chem. Chem. Phys. 2015, 17, 23573, J. Phys. Chem. A, Vol. 103, No. 15, 1999 2529], while the levels of S₂ and S₁ of azulene are 3.565 eV and 1.771 eV, respectively, the level difference of T₁ and S₀ is very small, i.e. the T₁-S₀ transition is 1.711 eV. In addition, the intersystem crossing transition of S₂-Tₙ transition is improved according to the conditions of the substitution material and the solvent polarity. Accordingly, there was a report that due to the increase of the transition to the triplet, there may be an advantage in improvement of the phosphorescent luminous characteristic. These azulene derivatives show a small energy gap of S₁-T₁, and have a relatively high HOMO characteristic compared to carbazole- or benzocarbazole-type compounds, thereby providing a narrow energy band gap. The present inventors found that by comprising the fused azulene derivative of the present disclosure in the light-emitting layer and comprising the heterocyclic derivative comprising azines of the present disclosure in the electron transport zone, it is possible to obtain fast driving voltage, high efficiency, and/or long lifespan characteristics. Specifically, the aforementioned problem can be solved by an organic electroluminescent device comprising a first electrode; a second electrode facing the first electrode; a light-emitting layer between the first electrode and the second electrode; and an electron transport zone between the light-emitting layer and the second electrode, wherein the light-emitting layer comprises a compound represented by the following formula 1, and the electron transport zone comprises a compound represented by the following formula 11:

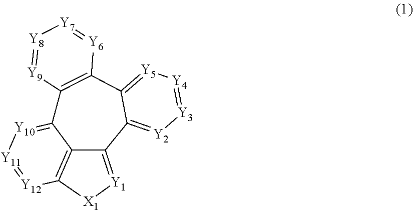

wherein

X₁ represents N-L-(Ar)ₐ, S, or O;

L represents a single bond, a substituted or unsubstituted (C6-C30)arylene, or a substituted or unsubstituted (3- to 30-membered)heteroarylene;

Ar represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino;

Y₁ to Y₁₂ each independently represent N or CR₁;

R₁ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or are linked to an adjacent substituent(s) to form a substituted or unsubstituted ring; and

a represents an integer of 1 to 4, where if a is an integer of 2 or more, each of Ar may be the same or different;

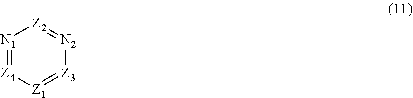

wherein

N₁ and N₂ each independently represent N or CR₁₈, where at least one of N₁ and N₂ represents N;

Z₁ to Z₄ each independently represent N or CR₁₉; and

R₁₈ and R₁₉ each independently represent hydrogen, deuterium, a halogen, a cyano, a substituted or unsubstituted (C1-C30)alkyl, a substituted or unsubstituted (C6-C50)aryl, a substituted or unsubstituted (3- to 50-membered)heteroaryl, a substituted or unsubstituted (C3-C30)cycloalkyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or are linked to an adjacent substituent(s) to form a substituted or unsubstituted ring.

### Effects of the Invention

According to the present disclosure, an organic electroluminescent device having low voltage, high efficiency, and/or long lifespan can be provided, and it is possible to produce a display device or a lighting device using the same.

### BRIEF DESCRIPTION OF THE FIGURES

FIG. 1 illustrates a schematic sectional view of an organic electroluminescent device according to an embodiment of the present disclosure.

FIG. 2 illustrates the molecular shape of the compound represented by formula 1 according to an embodiment of the present disclosure in a three-dimensional shape.

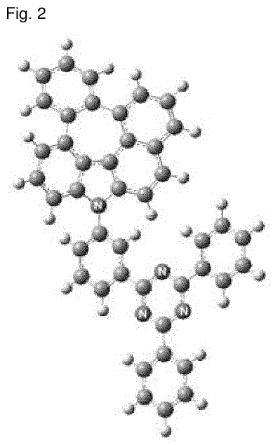

FIG. 3 illustrates a current efficiency versus a luminance of organic electroluminescent devices of Comparative Example 1 and Device Example 1.

### EMBODIMENTS OF THE INVENTION

Hereinafter, the present disclosure will be described in detail. However, the following description is intended to explain the disclosure, and is not meant in any way to restrict the scope of the disclosure.

The term “organic electroluminescent compound” in the present disclosure means a compound that may be used in an organic electroluminescent device, and may be comprised in any material layer constituting an organic electroluminescent device, as necessary.

The term “organic electroluminescent material” in the present disclosure means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material, an electron buffer material, a hole blocking material, an electron transport material, an electron injection material, etc.

The organic electroluminescent device of the present disclosure comprises a first electrode; a second electrode facing the first electrode; and a light-emitting layer between the first electrode and the second electrode, may comprise a hole transport zone between the first electrode and the light-emitting layer, and may comprise an electron transport zone between the light-emitting layer and the second electrode. One of the first and second electrodes may be an anode and the other may be a cathode.

The hole transport zone is meant to be a zone wherein holes are transported between the first electrode and the light-emitting layer, and may comprise, for example, one or more of a hole injection layer, a hole transport layer, a hole auxiliary layer, a light-emitting auxiliary layer, and an electron blocking layer. The hole injection layer, the hole transport layer, the hole auxiliary layer, the light-emitting auxiliary layer, and the electron blocking layer, respectively, may be a single layer, or a multi-layer in which two or more layers are stacked.

In addition, the hole transport zone may comprise a p-doped hole injection layer, hole transport layer, and light-emitting auxiliary layer. The p-doped hole injection layer means a hole injection layer in which a p-dopant is doped. A p-dopant is a material to provide a p semiconductor characteristic. A p semiconductor characteristic means a characteristic receiving or transporting holes by HOMO energy level, i.e. a characteristic of a material of high hole conductivity.

The light-emitting layer emits light, which may be a single layer, or a multi-layer in which two or more layers are stacked. The doping concentration of the dopant compound to the host compound in the light-emitting layer is preferably less than 20 wt %.

The electron transport zone is meant to be a zone wherein electrons are transported between the light-emitting layer and the second electrode, and may comprise, for example, one or more of a hole blocking layer, an electron transport layer, an electron buffer layer, and an electron injection layer. The hole blocking layer, the electron transport layer, the electron buffer layer, and the electron injection layer, respectively, may be a single layer, or a multi-layer in which two or more layers are stacked.

According to one embodiment of the present disclosure, the light-emitting layer comprises a compound represented by formula 1, and the electron transport zone comprises a compound represented by formula 11. The electron transport zone may comprise one or more of an electron transport layer and an electron buffer layer, and the compound represented by formula 11 may be comprised in one or more of the electron transport layer and the electron buffer layer. In addition, the electron buffer layer may be comprised between the light-emitting layer and the electron transport layer, and may be comprised between the electron transport layer and the second electrode.

Hereinafter, the compounds represented by formulas 1 and 11 will be described in detail.

Herein, “(C1-C30)alkyl” is meant to be a linear or branched alkyl having 1 to 30 carbon atoms constituting the chain, in which the number of carbon atoms is preferably 1 to 10, more preferably 1 to 6, and includes methyl, ethyl, n-propyl, isopropyl, n-butyl, isobutyl, tert-butyl, etc. “(C3-C30)cycloalkyl” is a mono- or polycyclic hydrocarbon having 3 to 30 ring backbone carbon atoms, in which the number of carbon atoms is preferably 3 to 20, more preferably 3 to 7, and includes cyclopropyl, cyclobutyl, cyclopentyl, cyclohexyl, etc. “(3- to 7-membered)heterocycloalkyl” is a cycloalkyl having at least one hetero atom selected from the group consisting of B, N, O, S, Si, and P, preferably O, S, and N, and 3 to 7 ring backbone atoms, and includes tetrahydrofuran, pyrrolidine, thiolan, tetrahydropyran, etc. “(C6-C30)aryl(ene)” is a monocyclic or fused ring-type radical derived from an aromatic hydrocarbon having 6 to 30 ring backbone carbon atoms, in which the number of ring backbone carbon atoms is preferably 6 to 20, more preferably 6 to 15, may be partially saturated, and includes phenyl, biphenyl, terphenyl, naphthyl, binaphthyl, phenylnaphthyl, naphthylphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, etc. “(3- to 30-membered)heteroaryl(ene)” is an aryl group having at least one, preferably 1 to 4 hetero atoms selected from the group consisting of B, N, O, S, Si, and P, and 3 to 30 ring backbone atoms, in which the number of ring backbone atoms is preferably 3 to 20, more preferably 5 to 15; is a monocyclic ring, or a fused ring condensed with at least one benzene ring; may be partially saturated; may be one formed by linking at least one heteroaryl or aryl group to a heteroaryl group via a single bond(s); and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzonaphthothiophenyl, benzimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. “Halogen” includes F, Cl, Br, and I.

Herein, “substituted” in the expression “substituted or unsubstituted” means that a hydrogen atom in a certain functional group is replaced with another atom or functional group, i.e., a substituent. The substituents of the substituted alkyl, the substituted aryl(ene), the substituted heteroaryl(ene), the substituted cycloalkyl, the substituted heterocycloalkyl, the substituted alkoxy, the substituted trialkylsilyl, the substituted dialkylarylsilyl, the substituted alkyldiarylsilyl, the substituted triarylsilyl, the substituted mono- or di-alkylamino, the substituted mono- or di-arylamino, the substituted alkylarylamino, and the substituted ring in L, Ar, R₁, R₁₈, and R₁₉ in the formulas of the present disclosure each independently are selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (5- to 50-membered)heteroaryl unsubstituted or substituted with a (C1-C30)alkyl(s) or a (C6-C30)aryl(s); a (C6-C30)aryl unsubstituted or substituted with a (3- to 50-membered)heteroaryl; a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di-(C1-C30)alkylamino; a mono- or di-(C6-C30)arylamino; a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl, preferably, selected from the group consisting of a (C1-C20)alkyl; a (C6-C25)aryl unsubstituted or substituted with a (C1-C20)alkyl(s) and/or a (3- to 30-membered)heteroaryl; a (5- to 40-membered)heteroaryl unsubstituted or substituted with a (C1-C20)alkyl(s) and/or a (C6-C25)aryl(s); and a di(C6-C20)arylamino, and for example, a methyl, a tert-butyl, a phenyl unsubstituted or substituted with a pyridinyl(s), a naphthyl, a biphenyl, a dimethylfluorenyl, a phenylfluorenyl, a diphenylfluorenyl, a phenanthrenyl, a triphenylenyl, a pyridinyl, a triazinyl substituted with a phenyl(s) and/or a naphthyl(s), an indolyl substituted with diphenyl, a benzoimidazolyl substituted with a phenyl(s), a quinolyl, a quinazolinyl substituted with a phenyl(s), a carbazolyl, a dibenzofuranyl, a dibenzothiophenyl, a benzocarbazolyl unsubstituted or substituted with a phenyl(s), a dibenzocarbazolyl, a benzophenanthrothiophenyl, a diphenylamino, a dimethylfluorenylphenylamino, or a substituted or unsubstituted (16- to 33-membered)heteroaryl containing one or more of nitrogen, oxygen, and sulfur.

In formula 1, X₁ represents N-L-(Ar)ₐ, S, or O.

In formula 1, L represents a single bond, a substituted or unsubstituted (C6-C30)arylene, or a substituted or unsubstituted (3- to 30-membered)heteroarylene; preferably, a single bond, a substituted or unsubstituted (C6-C25)arylene, or a substituted or unsubstituted (5- to 25-membered)heteroarylene; and more preferably, a single bond, an unsubstituted (C6-C18)arylene, or an unsubstituted (5- to 18-membered)heteroarylene, wherein the heteroarylene may comprise one or more of nitrogen, oxygen, and sulfur.

According to one embodiment of the present disclosure, L may represent a single bond, a substituted or unsubstituted phenylene, a substituted or unsubstituted naphthylene, a substituted or unsubstituted biphenylene, a substituted or unsubstituted pyridylene, a substituted or unsubstituted pyrimidylene, a substituted or unsubstituted triazinylene, a substituted or unsubstituted quinazolinylene, a substituted or unsubstituted quinoxalinylene, a substituted or unsubstituted naphthyridinylene, a substituted or unsubstituted benzoquinazolinylene, a substituted or unsubstituted benzothienopyrimidinylene, a substituted or unsubstituted acenaphthopyrimidinylene, a substituted or unsubstituted (13- to 16-membered)heteroarylene containing at least one of nitrogen, oxygen, and sulfur.

In formula 1, Ar represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; preferably, a substituted or unsubstituted (C6-C25)aryl, a substituted or unsubstituted (5- to 30-membered)heteroaryl, or a substituted or unsubstituted di(C6-C25)arylamino; and more preferably, a substituted or unsubstituted (C6-C18)aryl, a substituted or unsubstituted (5- to 25-membered)heteroaryl, or a substituted or unsubstituted di(C6-C18)arylamino.

According to one embodiment of the present disclosure, Ar may represent a substituted or unsubstituted phenyl, a substituted or unsubstituted naphthyl, a substituted or unsubstituted biphenyl, a substituted or unsubstituted terphenyl, a substituted or unsubstituted triazinyl, a substituted or unsubstituted pyridyl, a substituted or unsubstituted pyrimidinyl, a substituted or unsubstituted quinazolinyl, a substituted or unsubstituted benzoquinazolinyl, a substituted or unsubstituted quinoxalinyl, a substituted or unsubstituted benzoquinoxalinyl, a substituted or unsubstituted quinolyl, a substituted or unsubstituted benzoquinolyl, a substituted or unsubstituted isoquinolyl, a substituted or unsubstituted benzoisoquinolyl, a substituted or unsubstituted triazolyl, a substituted or unsubstituted pyrazolyl, a substituted or unsubstituted carbazolyl, a substituted or unsubstituted dibenzothiophenyl, a substituted or unsubstituted benzothiophenyl, a substituted or unsubstituted dibenzofuranyl, a substituted or unsubstituted benzofuranyl, a substituted or unsubstituted naphthyridinyl, a substituted or unsubstituted benzothienopyrimidinyl, a substituted or unsubstituted benzothienoquinolinyl, a substituted or unsubstituted benzofuroquinolinyl, a substituted or unsubstituted triazaindenyl, a substituted or unsubstituted phenanthroimidazolyl, a substituted or unsubstituted (9- to 25-membered)heteroaryl containing at least one of nitrogen, oxygen, and sulfur, a substituted or unsubstituted diphenylamino, a substituted or unsubstituted phenylbiphenylamino, or a substituted or unsubstituted fluorenylphenylamino.

In formula 1, a represents an integer of 1 to 4, preferably, 1 or 2, where if a is an integer of 2 or more, each of Ar may be the same or different.

In formula 1, Y₁ to Y₁₂ each independently represent N or CR₁. According to one embodiment of the present disclosure, Y, to Y₁₂ may all represent CR₁, and according to another embodiment of the present disclosure, at least one of Y₁ to Y₁₂ may represent N. Where there are a plurality of R₁'s, each of R, may be the same or different.

R₁ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or are linked to an adjacent substituent(s) to form a substituted or unsubstituted ring; preferably, hydrogen, a substituted or unsubstituted (C1-C20)alkyl, a substituted or unsubstituted (C6-C25)aryl, a substituted or unsubstituted (5- to 25-membered)heteroaryl, or a substituted or unsubstituted di(C6-C25)arylamino; or are linked to an adjacent substituent(s) to form a substituted or unsubstituted, mono- or polycyclic, (3- to 25-membered) aromatic ring, whose carbon atom(s) may be replaced with at least one heteroatom selected from nitrogen, oxygen, and sulfur; and more preferably, hydrogen, a substituted or unsubstituted (C1-C10)alkyl, a substituted or unsubstituted (C6-C18)aryl, a substituted or unsubstituted (5- to 18-membered)heteroaryl, or a substituted or unsubstituted di(C6-C18)arylamino; or are linked to an adjacent substituent(s) to form a substituted or unsubstituted, mono- or polycyclic, (5- to 18-membered) aromatic ring, whose carbon atom(s) may be replaced with at least one heteroatom selected from nitrogen, oxygen, and sulfur.

According to one embodiment of the present disclosure, R₁ may each independently represent hydrogen, a substituted or unsubstituted methyl, a substituted or unsubstituted phenyl, a substituted or unsubstituted naphthyl, a substituted or unsubstituted biphenyl, a substituted or unsubstituted pyridyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted phenylbiphenylamino, etc.

According to one embodiment of the present disclosure, at least one adjacent pair of Y₁ to Y₁₂ in formula 1 are CR₁, and the adjacent two R₁'s of CR₁ are fused together to each independently form a ring represented by any one of the following formulas 2 to 6, but is not limited thereto. For example, the formed ring may be, including the ring of formulas 2 to 6, a substituted or unsubstituted benzene ring, a naphthalene ring, a furan ring, a thiophene ring, a substituted or unsubstituted pyrrole ring, a pyridine ring, a benzofuran ring, a benzothiophene ring, a substituted or unsubstituted indole ring, a dibenzofuran ring, a dibenzothiophene ring, a substituted or unsubstituted carbazole ring, a phenanthrene ring, etc.

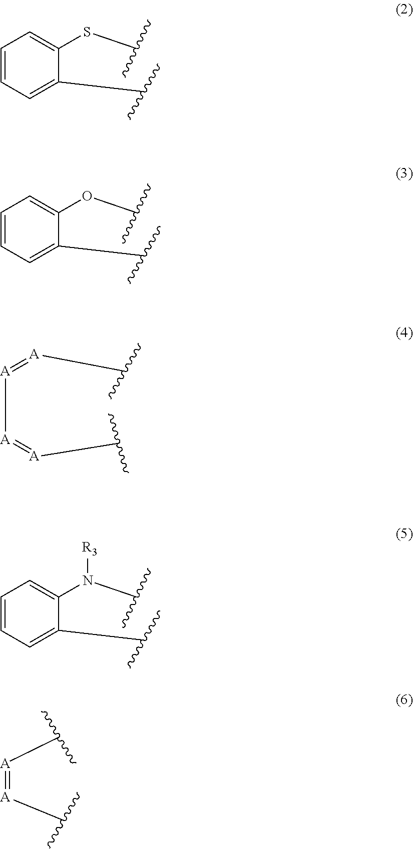

In formulas 2 to 6, [symbol] represents a fusing site of adjacent CR₁'s of formula 1.

In formulas 4 and 6, A represents N or CR₂. According to one embodiment of the present disclosure, all A may represent CR₂, and according to another embodiment of the present disclosure, at least one of A may represent N. Where there are a plurality of R₂'s, each of R₂ may be the same or different.

R₂ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; preferably, a substituted or unsubstituted (C6-C25)aryl, or a substituted or unsubstituted (5- to 25-membered)heteroaryl; and more preferably a substituted or unsubstituted (C6-C18)aryl, or a substituted or unsubstituted (5- to 18-membered)heteroaryl.

In formula 5, R₃ represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; preferably, a substituted or unsubstituted (C6-C25)aryl, or a substituted or unsubstituted (5- to 25-membered)heteroaryl; and more preferably an unsubstituted (C6-C18)aryl, or an unsubstituted (5- to 18-membered)heteroaryl. For example, R₃ may represent a phenyl.

In formula 11, N₁ and N₂ each independently represent N or CR₁₈, where at least one of N₁ and N₂ represents N. According to one embodiment of the present disclosure, N₁ and N₂ both represent N.

In formula 11, Z₁ to Z₄ each independently represent N or CR₁₉. According to one embodiment of the present disclosure, Z₁ represents N or CR₁₉, and Z₂ to Z₄ each independently represent CR₁₉.

In formula 11, R₁₈ and R₁₉ each independently represent hydrogen, deuterium, a halogen, a cyano, a substituted or unsubstituted (C1-C30)alkyl, a substituted or unsubstituted (C6-C50)aryl, a substituted or unsubstituted (3- to 50-membered)heteroaryl, a substituted or unsubstituted (C3-C30)cycloalkyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or are linked to an adjacent substituent(s) to form a substituted or unsubstituted ring. Preferably, R₁₈ and R₁₉ each independently represent hydrogen, a substituted or unsubstituted (C6-C40)aryl, or a substituted or unsubstituted (5- to 45-membered)heteroaryl; or are linked to an adjacent substituent(s) to form a substituted or unsubstituted, mono- or polycyclic, (3- to 25-membered) alicyclic or aromatic ring, or the combination thereof, whose carbon atom(s) may be replaced with at least one heteroatom selected from nitrogen, oxygen, and sulfur; more preferably, hydrogen, a substituted or unsubstituted (C6-C30)aryl, or a substituted or unsubstituted (5- to 40-membered)heteroaryl; or are linked to an adjacent substituent(s) to form a substituted or unsubstituted, mono- or polycyclic, (3- to 18-membered) aromatic ring, whose carbon atom(s) may be replaced with at least one heteroatom selected from nitrogen, oxygen, and sulfur; and for example, hydrogen, a substituted or unsubstituted phenyl, a substituted indole, a substituted or unsubstituted naphthyl, a substituted or unsubstituted biphenyl, a substituted phenylnaphthyl, a substituted biphenylnaphthyl, a fluorenyl substituted with dimethyl, a fluorenyl substituted with diphenyl, a benzofluorenyl substituted with dimethyl, a substituted or unsubstituted terphenyl, an unsubstituted spirobifluorenyl, a substituted carbazolyl, a substituted benzocarbazolyl, an unsubstituted dibenzofuran, or a substituted or unsubstituted (16- to 38-membered)heteroaryl containing at least one of nitrogen, oxygen, and sulfur; or are linked to an adjacent substituent(s) to form an unsubstituted benzofuran ring.

Formula 11 may be represented by the following formula 21:

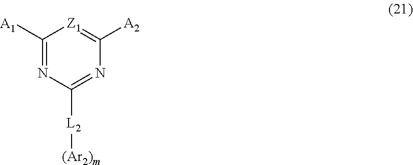

In formula 21, Z₁ is as defined in formula 11, and A₁ and A₂ are each independently identical to the definition of R₁₉ of formula 11, and m represents 1 or 2.

In formula 21, L₂ represents a single bond, a substituted or unsubstituted (C6-C50)arylene, or a substituted or unsubstituted (5- to 50-membered)heteroarylene; preferably, a single bond, a substituted or unsubstituted (C6-C45)arylene, or a substituted or unsubstituted (5- to 45-membered)heteroarylene; more preferably, a single bond, a substituted or unsubstituted (C6-C30)arylene, or a substituted or unsubstituted (5- to 30-membered)heteroarylene; and for example, a single bond, a phenylene unsubstituted or substituted with a pyridinyl(s), an unsubstituted naphthylene, an unsubstituted biphenylene, an unsubstituted terphenylene, an unsubstituted phenylnaphthylene, an unsubstituted biphenylnaphthylene, an indolene substituted with a phenyl(s), a carbazolylene unsubstituted or substituted with a phenyl(s), or an unsubstituted benzocarbazolylene.

In formula 21, Ar₂ represents a substituted or unsubstituted (C6-C50)aryl, or a substituted or unsubstituted (5- to 50-membered)heteroaryl; preferably, a substituted or unsubstituted (C6-C45)aryl, or a substituted or unsubstituted (5- to 45-membered)heteroaryl; more preferably, a substituted or unsubstituted (C6-C30)aryl, or a substituted or unsubstituted (5- to 40-membered)heteroaryl; and for example, a phenyl unsubstituted or substituted with a pyridinyl(s), an unsubstituted naphthyl, a fluorenyl substituted with dimethyl, a fluorenyl substituted with diphenyl, a benzofluorenyl substituted with dimethyl, an unsubstituted phenanthrenyl, an unsubstituted triphenylenyl, an unsubstituted spirobifluorenyl, an unsubstituted pyridinyl, a benzoimidazolyl substituted with a phenyl(s), an indolyl substituted with a phenyl(s), an unsubstituted quinolyl, a substituted or unsubstituted carbazolyl, an unsubstituted dibenzothiophenyl, an unsubstituted dibenzofuranyl, a benzocarbazolyl unsubstituted or substituted with a phenyl(s), an unsubstituted dibenzocarbazolyl, an unsubstituted benzophenanthrothiophenyl, or a substituted or unsubstituted (13- to 38-membered)heteroaryl containing at least one of nitrogen, oxygen, and sulfur, and may be a spiro structure. The substituent of the substituted carbazolyl may be one or more of a fluorenyl substituted with a phenyl(s), a carbazolyl substituted with a phenyl(s), a methyl, a phenyl, a dibenzothiophenyl, and a dibenzofuranyl. The substituent of the substituted (13-to 38-membered)heteroaryl may be one or more of a methyl, a tert-butyl, a phenyl, a naphthyl, and a biphenyl.

In the formulas of the present disclosure, if the adjacent substituents are linked to each other to form a ring, the ring may be a substituted or unsubstituted, mono- or polycyclic, (3- to 30-membered) alicyclic or aromatic ring, or the combination thereof, and may contain at least one heteroatom selected from nitrogen, oxygen, and sulfur.

In the formulas of the present disclosure, the heteroaryl(ene) may each independently comprise one or more heteroatoms selected from B, N, O, S, Si, and P, and preferably selected from N, O, and S. In addition, the heterocycloalkyl comprises one or more heteroatoms selected from N, O, and S. Further, the heteroatom may be bonded by one or more substituent selected from the group consisting of hydrogen, deuterium, a halogen, a cyano, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, and a substituted or unsubstituted (C1-C30)alkyl(C6-C30)arylamino.

The compound represented by formula 1 includes the following compounds, but is not limited thereto:

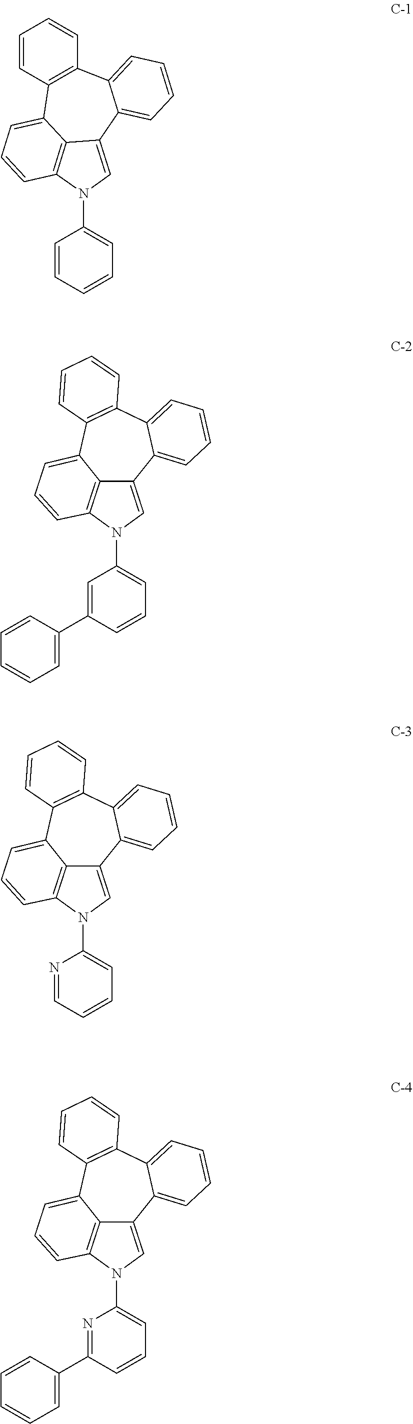 [SMILES: c1ccc(-n2cc3c4c(cccc42)-c2ccccc2-c2ccccc2-3)cc1 ; c1ccc(-c2cccc(-n3cc4c5c(cccc53)-c3ccccc3-c3ccccc3-4)c2)cc1 ; c1ccc(-n2cc3c4c(cccc42)-c2ccccc2-c2ccccc2-3)nc1 ; c1ccc(-c2cccc(-n3cc4c5c(cccc53)-c3ccccc3-c3ccccc3-4)n2)cc1]

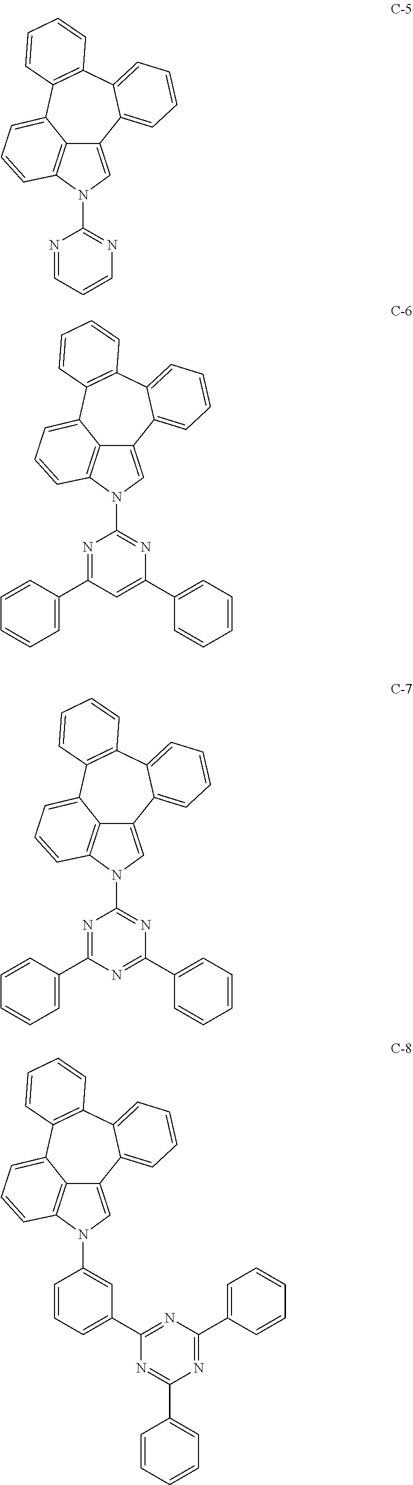

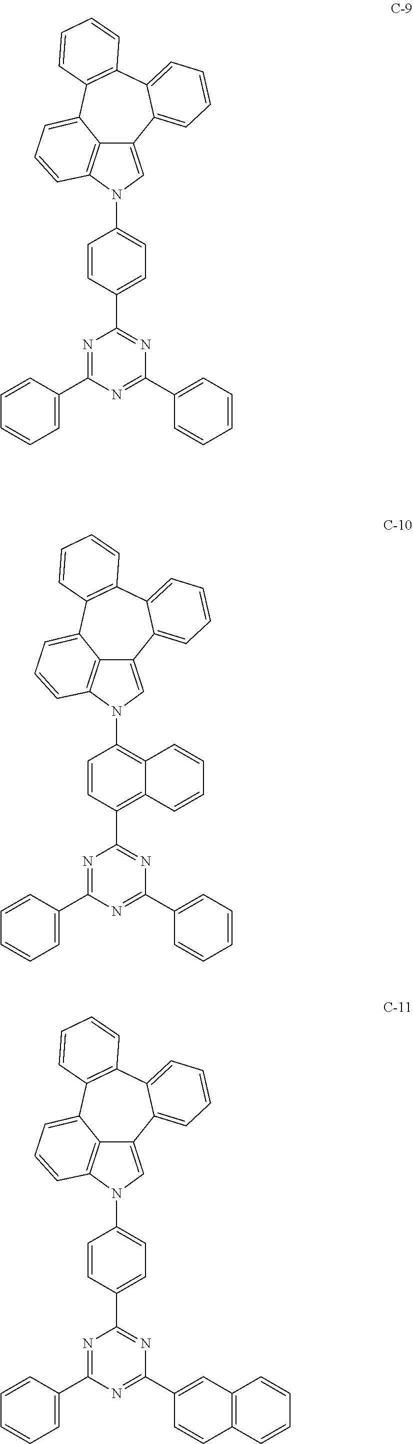 [SMILES: c1ccc(-c2nc(-c3ccccc3)nc(-c3ccc(-n4cc5c6c(cccc64)-c4ccccc4-c4ccccc4-5)cc3)n2)cc1 ; c1ccc(-c2nc(-c3ccccc3)nc(-c3ccc(-n4cc5c6c(cccc64)-c4ccccc4-c4ccccc4-5)c4ccccc34)n2)cc1 ; c1ccc(-c2nc(-c3ccc(-n4cc5c6c(cccc64)-c4ccccc4-c4ccccc4-5)cc3)nc(-c3ccc4ccccc4c3)n2)cc1]

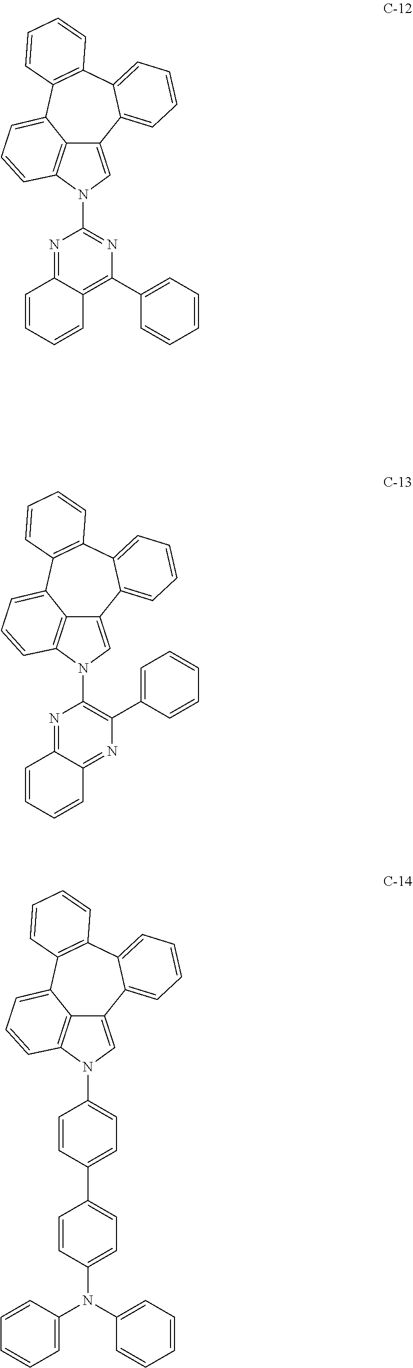 [SMILES: c1ccc(-c2nc(-n3cc4c5c(cccc53)-c3ccccc3-c3ccccc3-4)nc3ccccc23)cc1 ; c1ccc(-c2nc3ccccc3nc2-n2cc3c4c(cccc42)-c2ccccc2-c2ccccc2-3)cc1 ; c1ccc(N(c2ccccc2)c2ccc(-c3ccc(-n4cc5c6c(cccc64)-c4ccccc4-c4ccccc4-5)cc3)cc2)cc1]

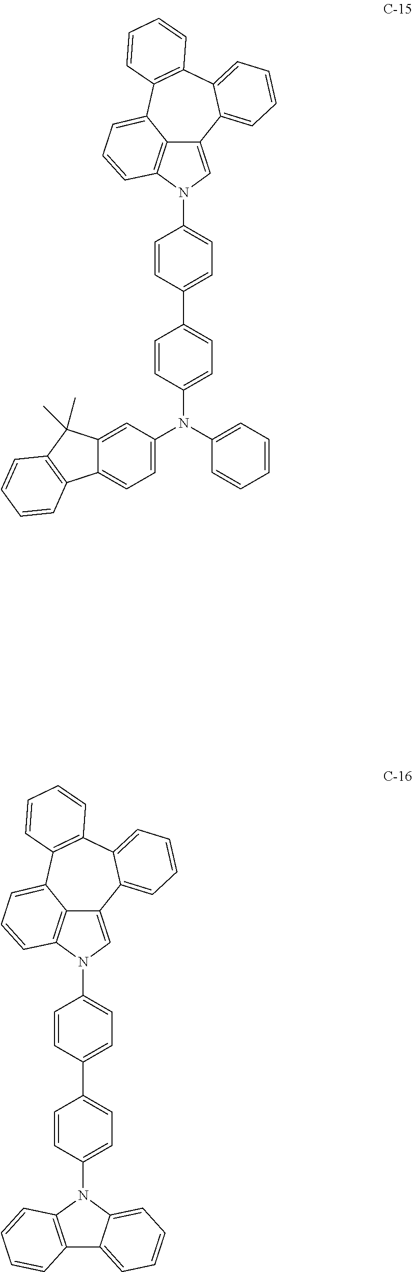 [SMILES: CC1(C)c2ccccc2-c2ccc(N(c3ccccc3)c3ccc(-c4ccc(-n5cc6c7c(cccc75)-c5ccccc5-c5ccccc5-6)cc4)cc3)cc21 ; c1ccc2c(c1)-c1ccccc1-c1cn(-c3ccc(-c4ccc(-n5c6ccccc6c6ccccc65)cc4)cc3)c3cccc-2c13]

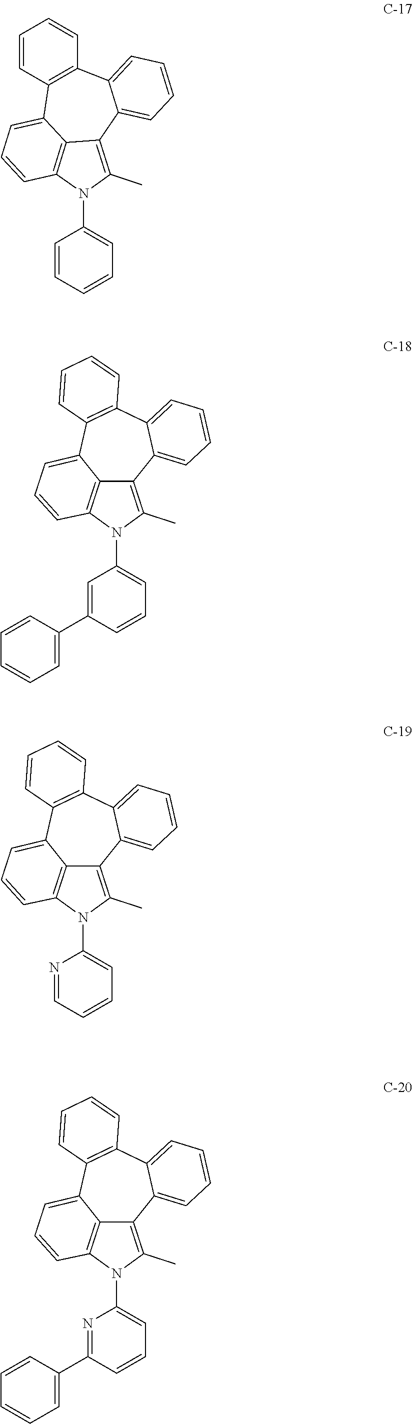 [SMILES: Cc1c2c3c(cccc3n1-c1ccccc1)-c1ccccc1-c1ccccc1-2 ; Cc1c2c3c(cccc3n1-c1cccc(-c3ccccc3)c1)-c1ccccc1-c1ccccc1-2 ; Cc1c2c3c(cccc3n1-c1ccccn1)-c1ccccc1-c1ccccc1-2 ; Cc1c2c3c(cccc3n1-c1cccc(-c3ccccc3)n1)-c1ccccc1-c1ccccc1-2]

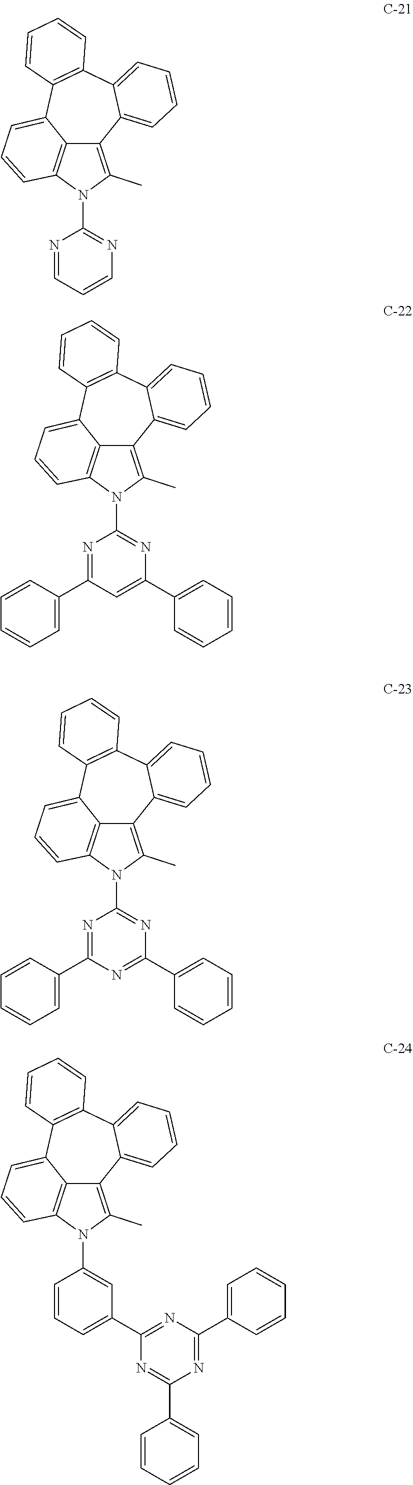

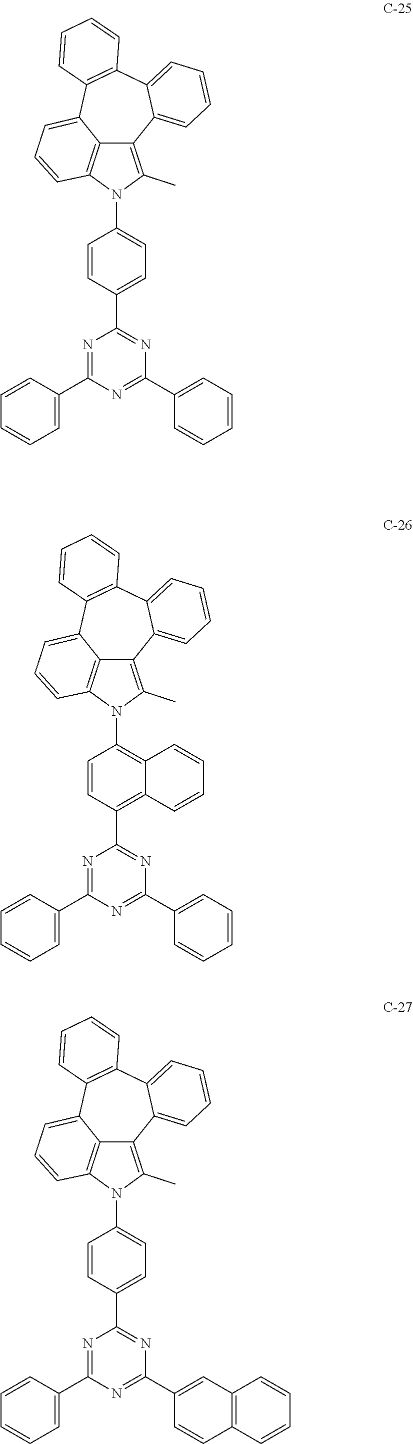 [SMILES: Cc1c2c3c(cccc3n1-c1ccc(-c3nc(-c4ccccc4)nc(-c4ccccc4)n3)cc1)-c1ccccc1-c1ccccc1-2 ; Cc1c2c3c(cccc3n1-c1ccc(-c3nc(-c4ccccc4)nc(-c4ccccc4)n3)c3ccccc13)-c1ccccc1-c1ccccc1-2 ; Cc1c2c3c(cccc3n1-c1ccc(-c3nc(-c4ccccc4)nc(-c4ccc5ccccc5c4)n3)cc1)-c1ccccc1-c1ccccc1-2]

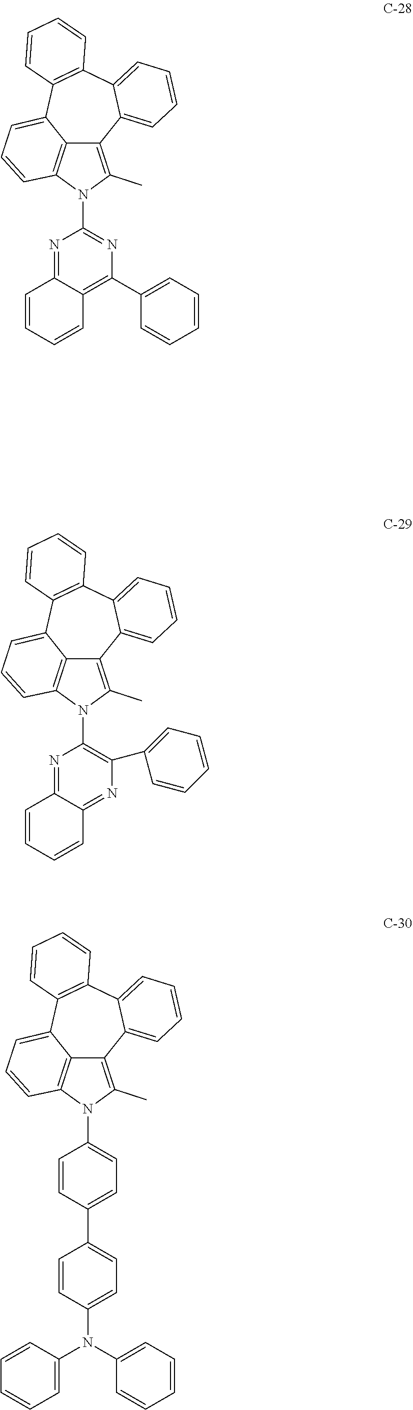 [SMILES: Cc1c2c3c(cccc3n1-c1nc(-c3ccccc3)c3ccccc3n1)-c1ccccc1-c1ccccc1-2 ; Cc1c2c3c(cccc3n1-c1nc3ccccc3nc1-c1ccccc1)-c1ccccc1-c1ccccc1-2 ; Cc1c2c3c(cccc3n1-c1ccc(-c3ccc(N(c4ccccc4)c4ccccc4)cc3)cc1)-c1ccccc1-c1ccccc1-2]

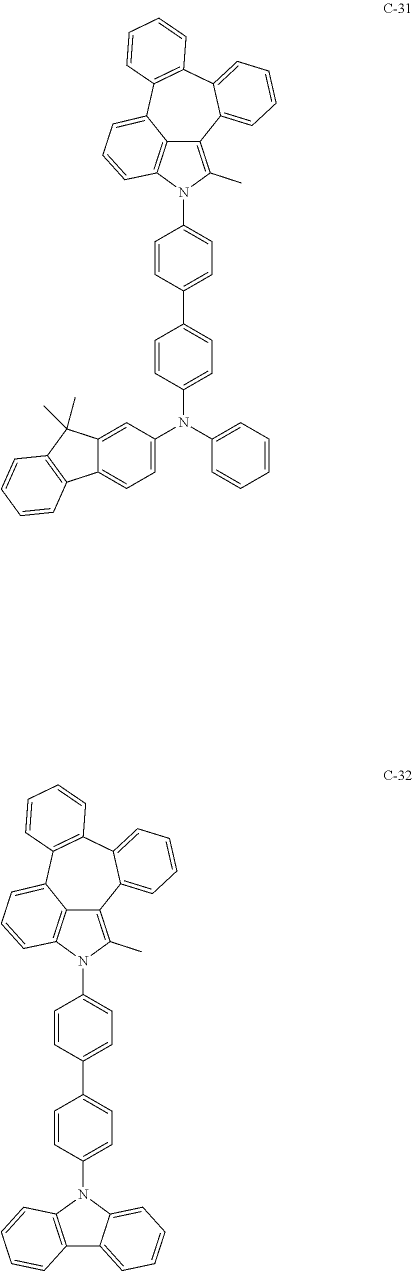 [SMILES: Cc1c2c3c(cccc3n1-c1ccc(-c3ccc(N(c4ccccc4)c4ccc5c(c4)C(C)(C)c4ccccc4-5)cc3)cc1)-c1ccccc1-c1ccccc1-2 ; Cc1c2c3c(cccc3n1-c1ccc(-c3ccc(-n4c5ccccc5c5ccccc54)cc3)cc1)-c1ccccc1-c1ccccc1-2]

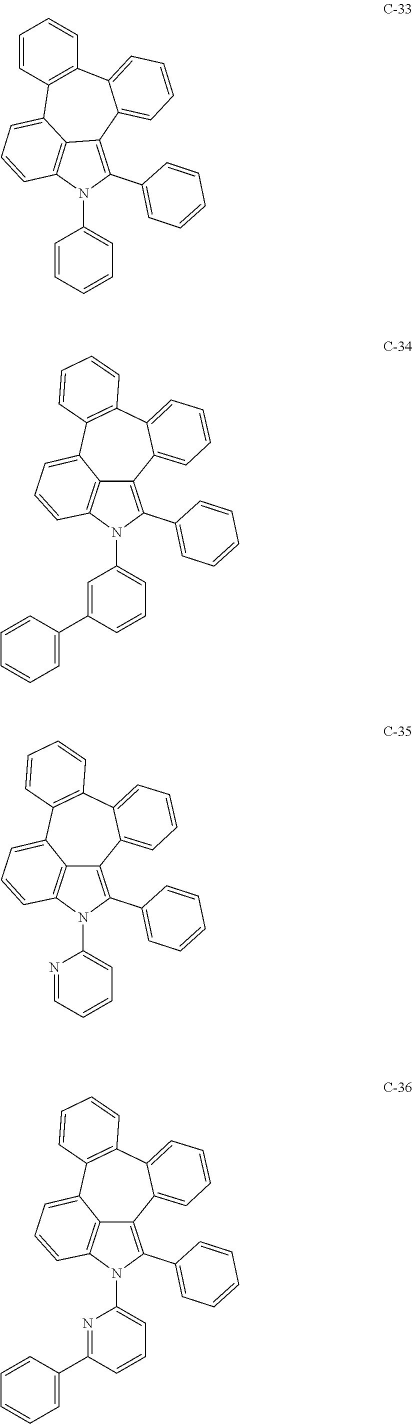 [SMILES: c1ccc(-c2c3c4c(cccc4n2-c2ccccc2)-c2ccccc2-c2ccccc2-3)cc1 ; c1ccc(-c2cccc(-n3c(-c4ccccc4)c4c5c(cccc53)-c3ccccc3-c3ccccc3-4)c2)cc1 ; c1ccc(-c2c3c4c(cccc4n2-c2ccccn2)-c2ccccc2-c2ccccc2-3)cc1 ; c1ccc(-c2cccc(-n3c(-c4ccccc4)c4c5c(cccc53)-c3ccccc3-c3ccccc3-4)n2)cc1]

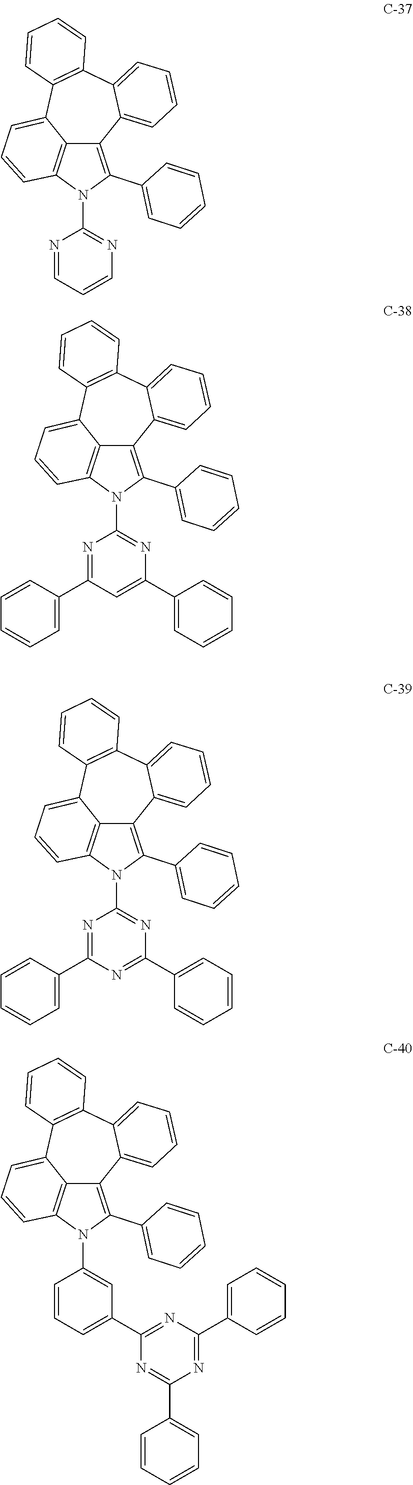

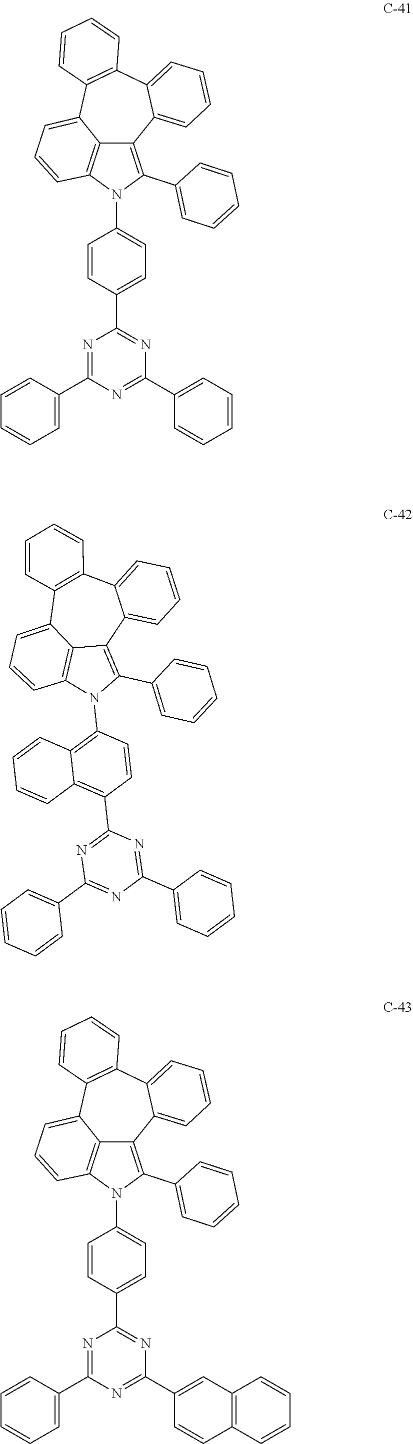 [SMILES: c1ccc(-c2nc(-c3ccccc3)nc(-c3ccc(-n4c(-c5ccccc5)c5c6c(cccc64)-c4ccccc4-c4ccccc4-5)cc3)n2)cc1 ; c1ccc(-c2nc(-c3ccccc3)nc(-c3ccc(-n4c(-c5ccccc5)c5c6c(cccc64)-c4ccccc4-c4ccccc4-5)c4ccccc34)n2)cc1 ; c1ccc(-c2nc(-c3ccc(-n4c(-c5ccccc5)c5c6c(cccc64)-c4ccccc4-c4ccccc4-5)cc3)nc(-c3ccc4ccccc4c3)n2)cc1]

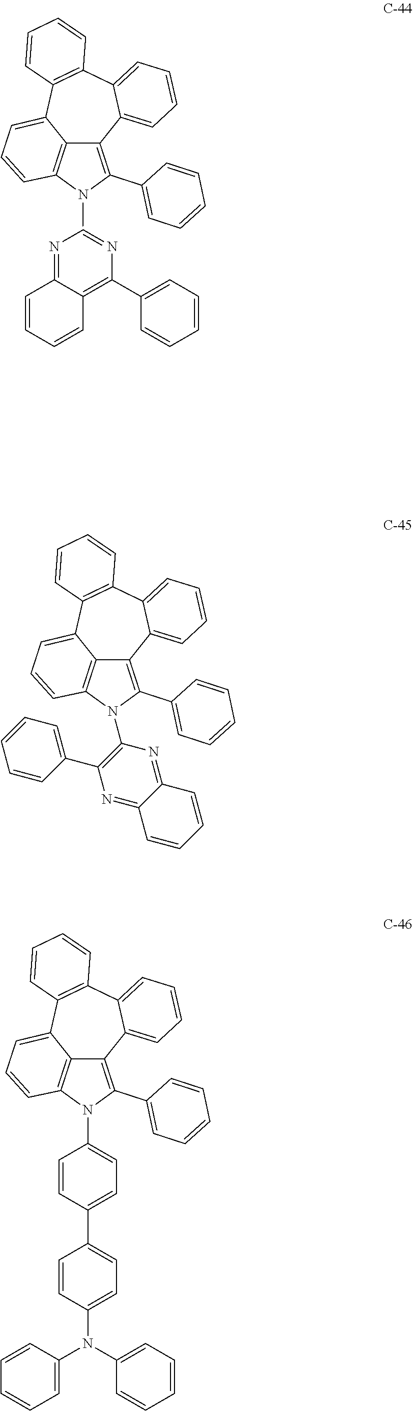

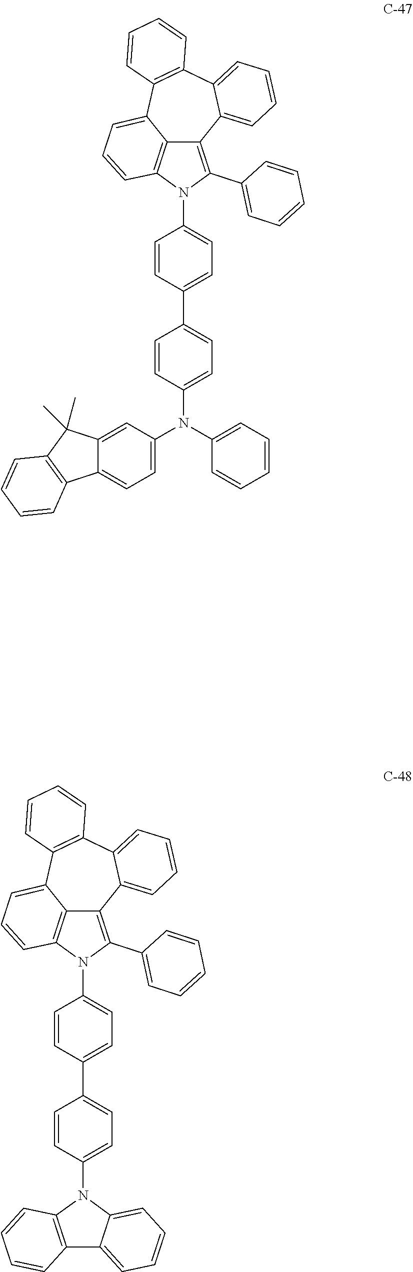 [SMILES: CC1(C)c2ccccc2-c2ccc(N(c3ccccc3)c3ccc(-c4ccc(-n5c(-c6ccccc6)c6c7c(cccc75)-c5ccccc5-c5ccccc5-6)cc4)cc3)cc21 ; c1ccc(-c2c3c4c(cccc4n2-c2ccc(-c4ccc(-n5c6ccccc6c6ccccc65)cc4)cc2)-c2ccccc2-c2ccccc2-3)cc1]

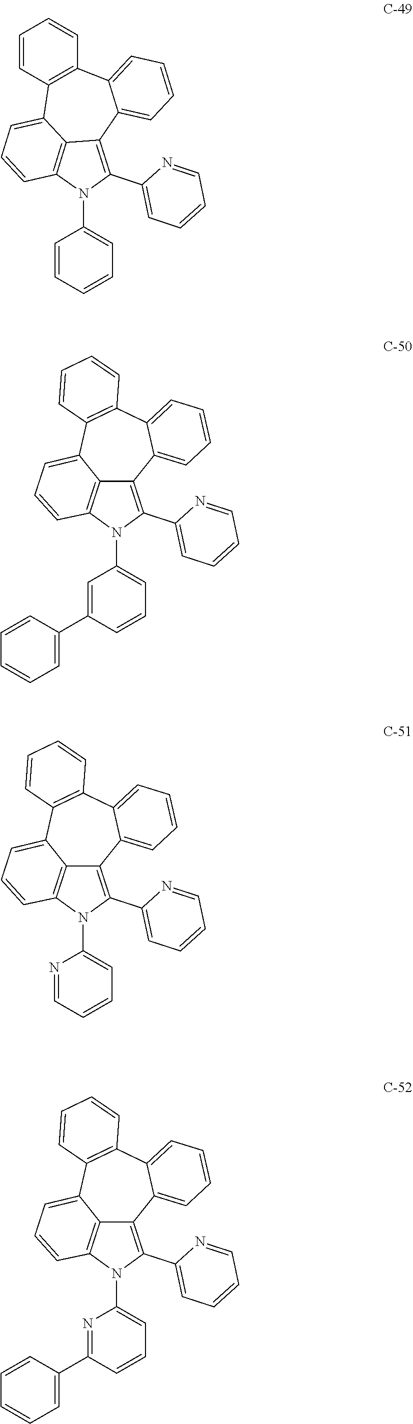 [SMILES: c1ccc(-n2c(-c3ccccn3)c3c4c(cccc42)-c2ccccc2-c2ccccc2-3)cc1 ; c1ccc(-c2cccc(-n3c(-c4ccccn4)c4c5c(cccc53)-c3ccccc3-c3ccccc3-4)c2)cc1 ; c1ccc(-c2c3c4c(cccc4n2-c2ccccn2)-c2ccccc2-c2ccccc2-3)nc1 ; c1ccc(-c2cccc(-n3c(-c4ccccn4)c4c5c(cccc53)-c3ccccc3-c3ccccc3-4)n2)cc1]

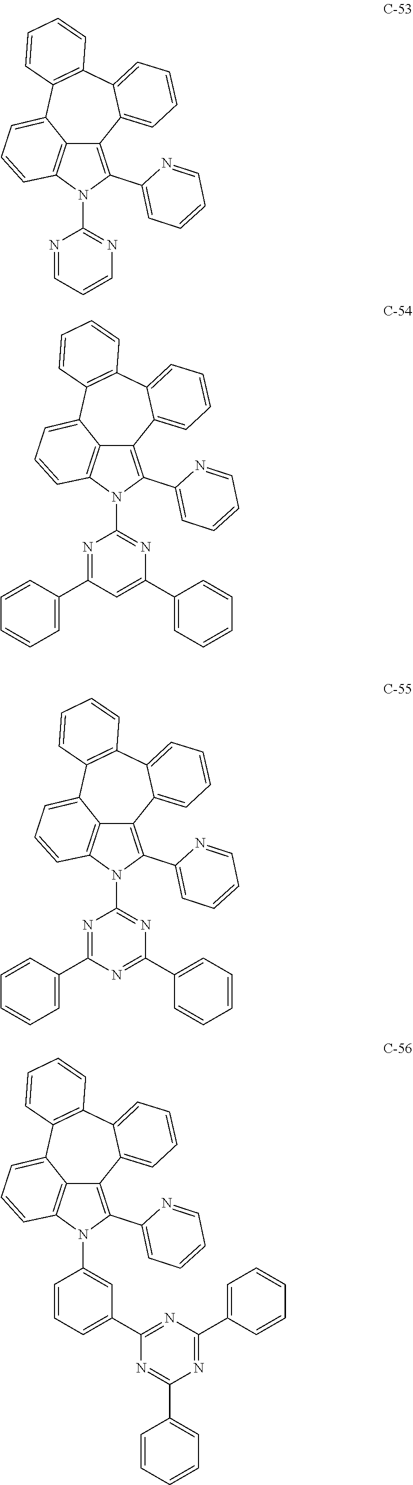

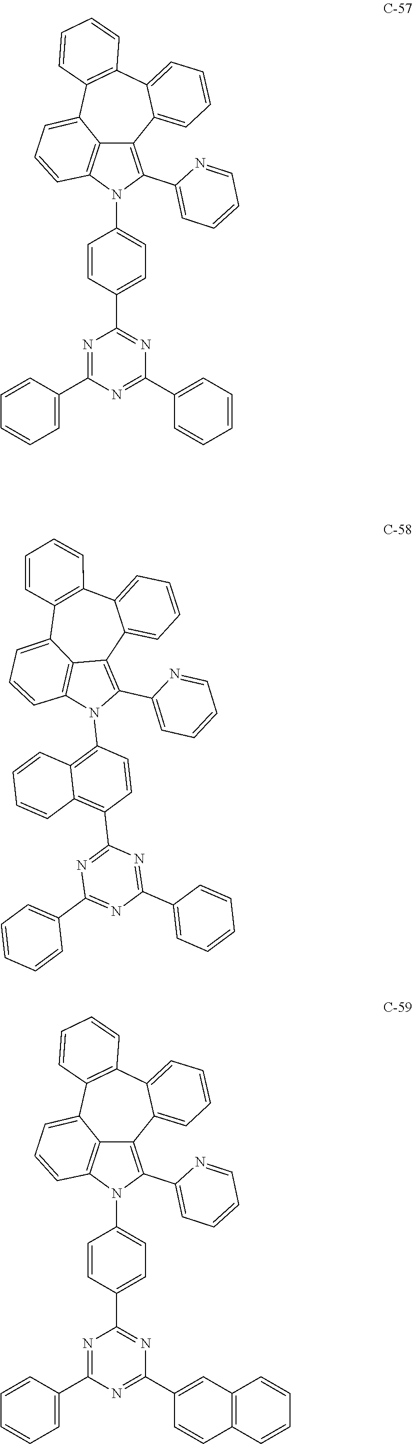 [SMILES: c1ccc(-c2nc(-c3ccccc3)nc(-c3ccc(-n4c(-c5ccccn5)c5c6c(cccc64)-c4ccccc4-c4ccccc4-5)cc3)n2)cc1 ; c1ccc(-c2nc(-c3ccccc3)nc(-c3ccc(-n4c(-c5ccccn5)c5c6c(cccc64)-c4ccccc4-c4ccccc4-5)c4ccccc34)n2)cc1 ; c1ccc(-c2nc(-c3ccc(-n4c(-c5ccccn5)c5c6c(cccc64)-c4ccccc4-c4ccccc4-5)cc3)nc(-c3ccc4ccccc4c3)n2)cc1]

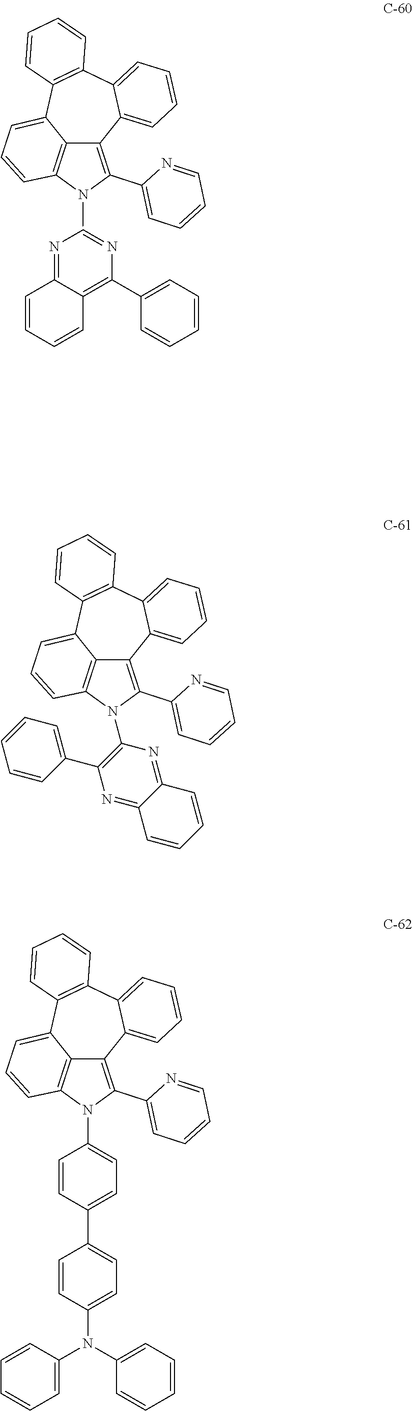

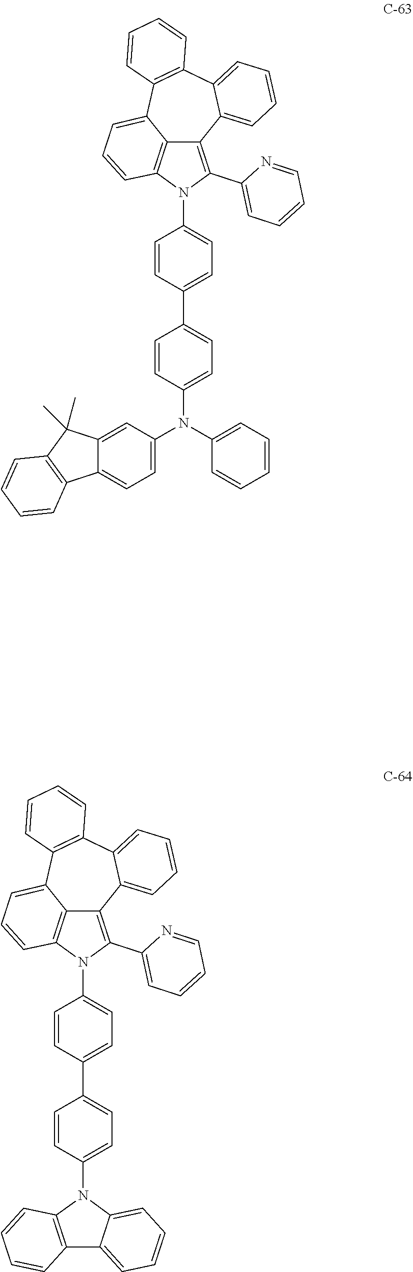 [SMILES: CC1(C)c2ccccc2-c2ccc(N(c3ccccc3)c3ccc(-c4ccc(-n5c(-c6ccccn6)c6c7c(cccc75)-c5ccccc5-c5ccccc5-6)cc4)cc3)cc21 ; c1ccc(-c2c3c4c(cccc4n2-c2ccc(-c4ccc(-n5c6ccccc6c6ccccc65)cc4)cc2)-c2ccccc2-c2ccccc2-3)nc1]

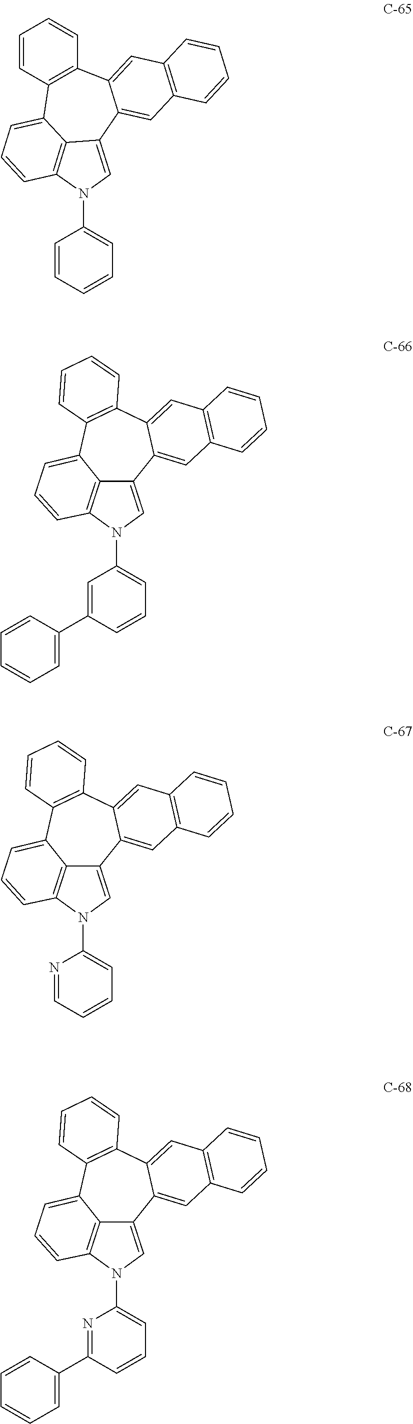 [SMILES: c1ccc(-n2cc3c4c(cccc42)-c2ccccc2-c2cc4ccccc4cc2-3)cc1 ; c1ccc(-c2cccc(-n3cc4c5c(cccc53)-c3ccccc3-c3cc5ccccc5cc3-4)c2)cc1 ; c1ccc(-n2cc3c4c(cccc42)-c2ccccc2-c2cc4ccccc4cc2-3)nc1 ; c1ccc(-c2cccc(-n3cc4c5c(cccc53)-c3ccccc3-c3cc5ccccc5cc3-4)n2)cc1]

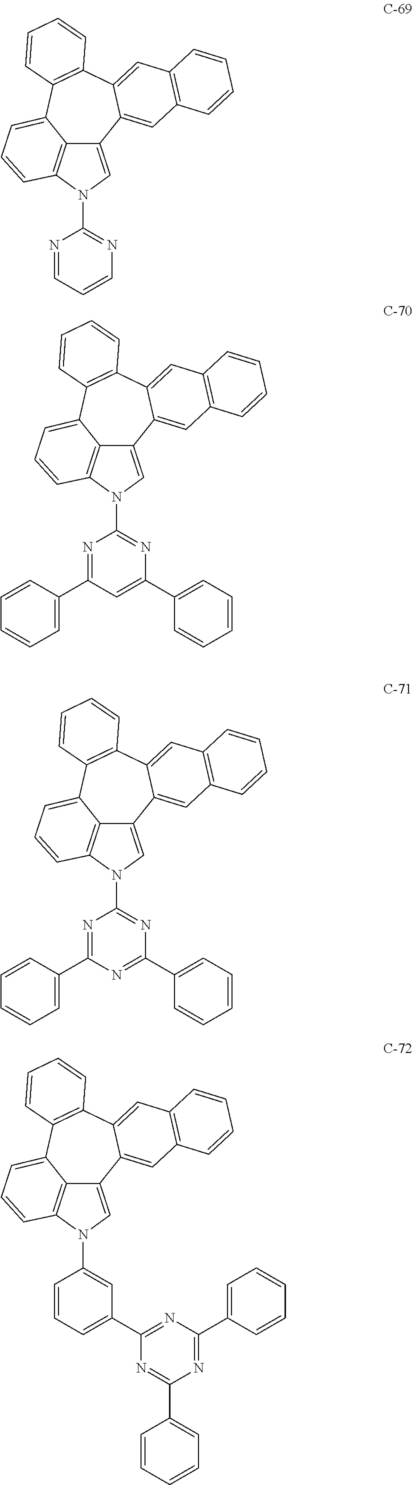

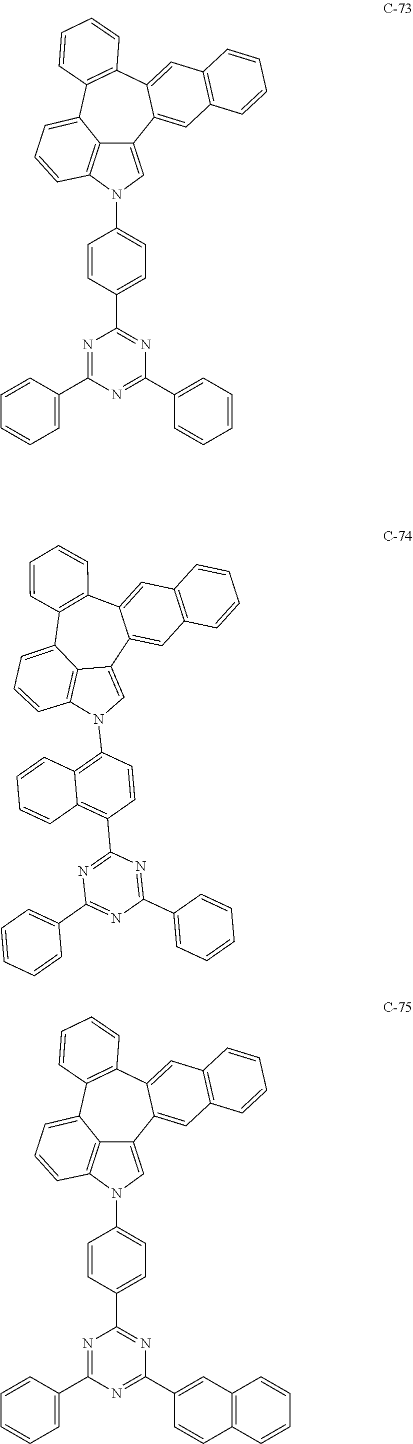 [SMILES: c1ccc(-c2nc(-c3ccccc3)nc(-c3ccc(-n4cc5c6c(cccc64)-c4ccccc4-c4cc6ccccc6cc4-5)cc3)n2)cc1 ; c1ccc(-c2nc(-c3ccccc3)nc(-c3ccc(-n4cc5c6c(cccc64)-c4ccccc4-c4cc6ccccc6cc4-5)c4ccccc34)n2)cc1 ; c1ccc(-c2nc(-c3ccc(-n4cc5c6c(cccc64)-c4ccccc4-c4cc6ccccc6cc4-5)cc3)nc(-c3ccc4ccccc4c3)n2)cc1]

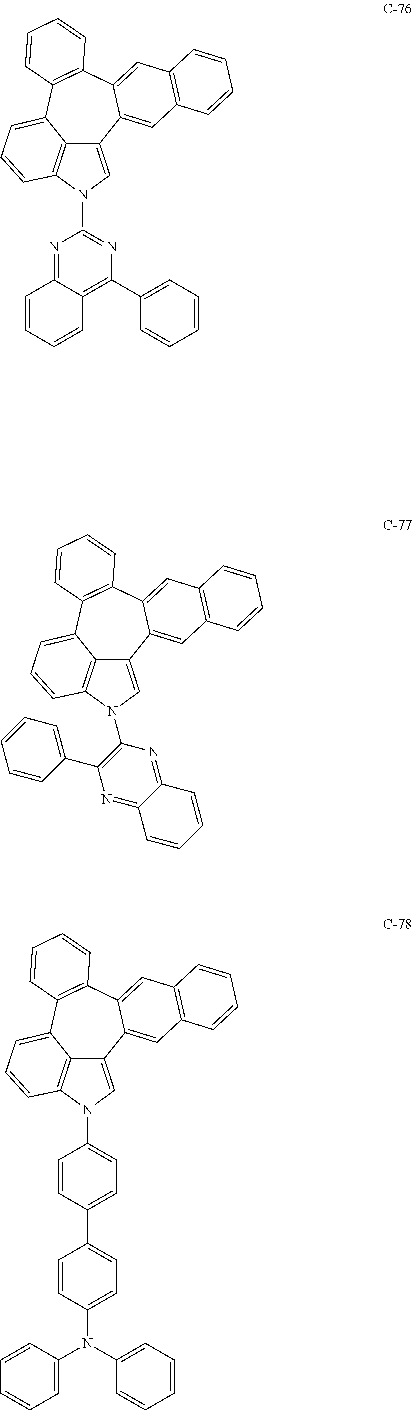

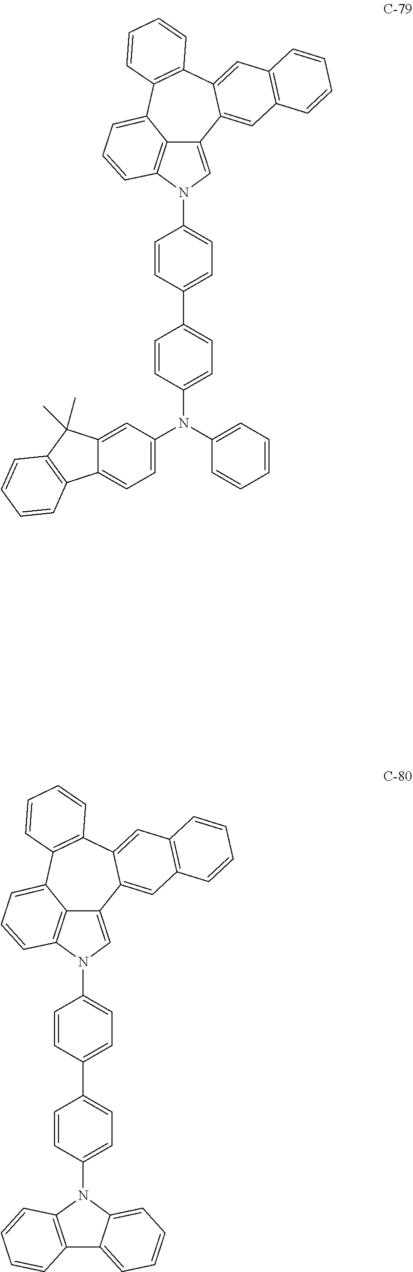 [SMILES: CC1(C)c2ccccc2-c2ccc(N(c3ccccc3)c3ccc(-c4ccc(-n5cc6c7c(cccc75)-c5ccccc5-c5cc7ccccc7cc5-6)cc4)cc3)cc21 ; c1ccc2c(c1)-c1cc3ccccc3cc1-c1cn(-c3ccc(-c4ccc(-n5c6ccccc6c6ccccc65)cc4)cc3)c3cccc-2c13]

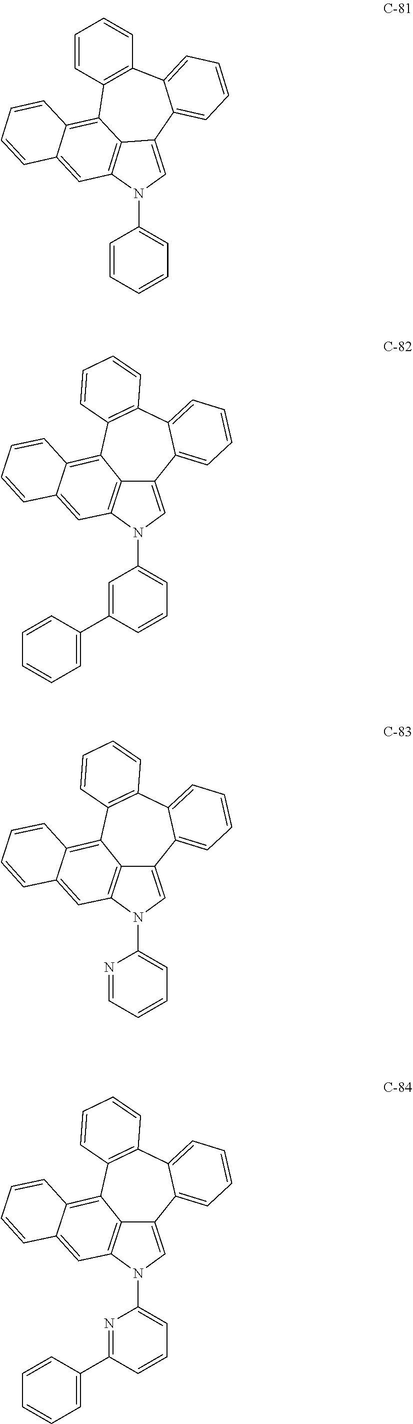 [SMILES: c1ccc(-n2cc3c4c(c5ccccc5cc42)-c2ccccc2-c2ccccc2-3)cc1 ; c1ccc(-c2cccc(-n3cc4c5c(c6ccccc6cc53)-c3ccccc3-c3ccccc3-4)c2)cc1 ; c1ccc(-n2cc3c4c(c5ccccc5cc42)-c2ccccc2-c2ccccc2-3)nc1 ; c1ccc(-c2cccc(-n3cc4c5c(c6ccccc6cc53)-c3ccccc3-c3ccccc3-4)n2)cc1]

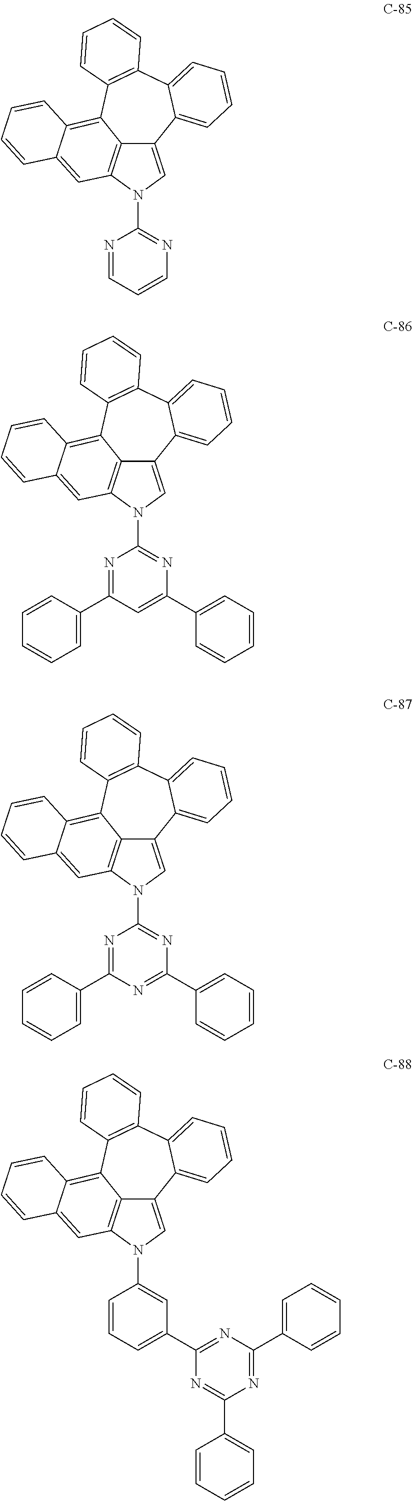 [SMILES: c1cnc(-n2cc3c4c(c5ccccc5cc42)-c2ccccc2-c2ccccc2-3)nc1 ; c1ccc(-c2cc(-c3ccccc3)nc(-n3cc4c5c(c6ccccc6cc53)-c3ccccc3-c3ccccc3-4)n2)cc1 ; c1ccc(-c2nc(-c3ccccc3)nc(-n3cc4c5c(c6ccccc6cc53)-c3ccccc3-c3ccccc3-4)n2)cc1 ; c1ccc(-c2nc(-c3ccccc3)nc(-c3cccc(-n4cc5c6c(c7ccccc7cc64)-c4ccccc4-c4ccccc4-5)c3)n2)cc1]

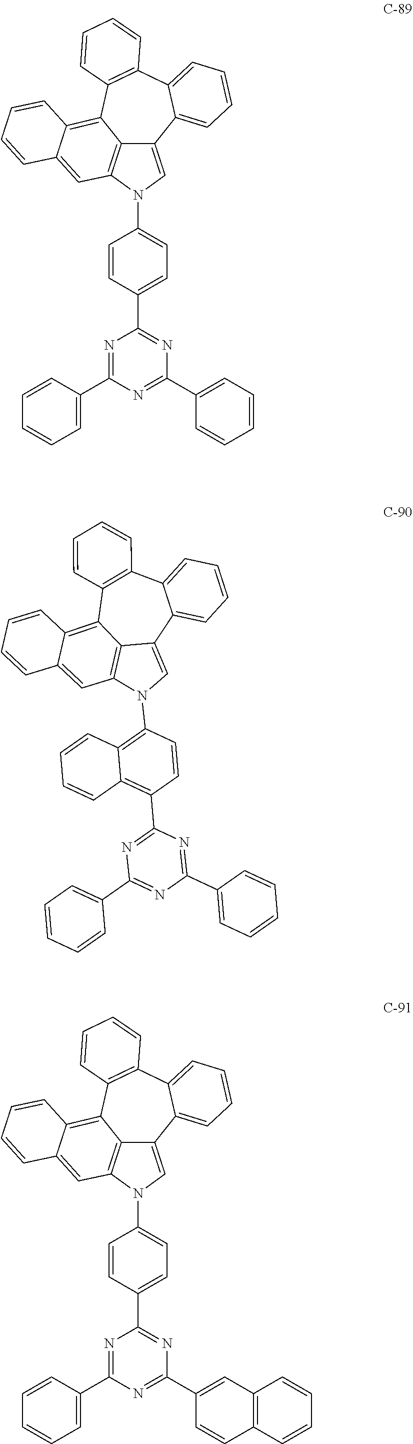 [SMILES: c1ccc(-c2nc(-c3ccccc3)nc(-c3ccc(-n4cc5c6c(c7ccccc7cc64)-c4ccccc4-c4ccccc4-5)cc3)n2)cc1 ; c1ccc(-c2nc(-c3ccccc3)nc(-c3ccc(-n4cc5c6c(c7ccccc7cc64)-c4ccccc4-c4ccccc4-5)c4ccccc34)n2)cc1 ; c1ccc(-c2nc(-c3ccc(-n4cc5c6c(c7ccccc7cc64)-c4ccccc4-c4ccccc4-5)cc3)nc(-c3ccc4ccccc4c3)n2)cc1]

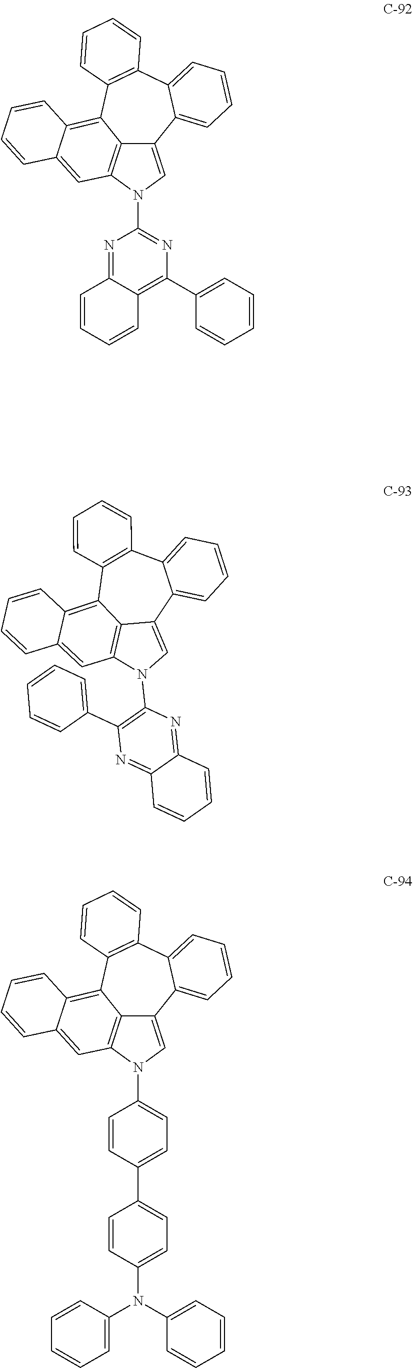 [SMILES: c1ccc(-c2nc(-n3cc4c5c(c6ccccc6cc53)-c3ccccc3-c3ccccc3-4)nc3ccccc23)cc1 ; c1ccc(-c2nc3ccccc3nc2-n2cc3c4c(c5ccccc5cc42)-c2ccccc2-c2ccccc2-3)cc1 ; c1ccc(N(c2ccccc2)c2ccc(-c3ccc(-n4cc5c6c(c7ccccc7cc64)-c4ccccc4-c4ccccc4-5)cc3)cc2)cc1]

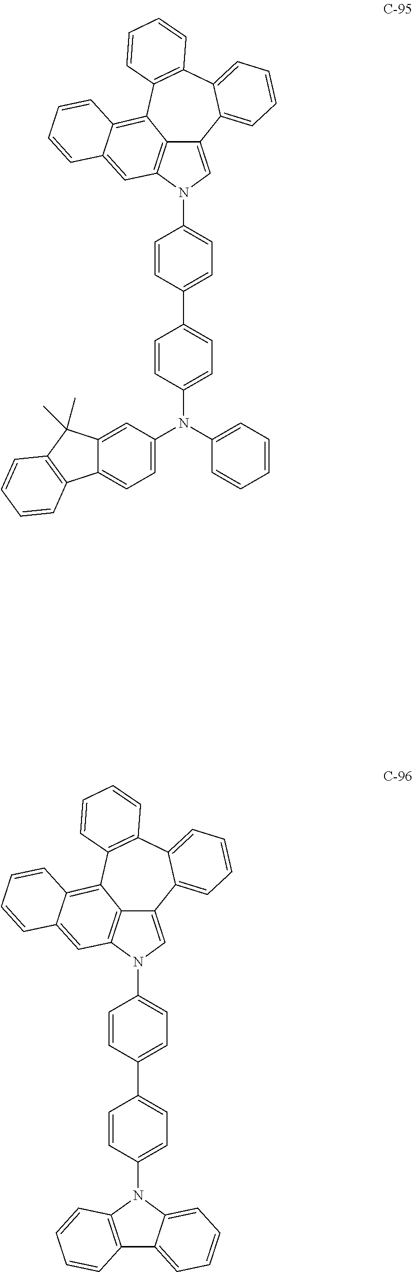 [SMILES: CC1(C)c2ccccc2-c2ccc(N(c3ccccc3)c3ccc(-c4ccc(-n5cc6c7c(c8ccccc8cc75)-c5ccccc5-c5ccccc5-6)cc4)cc3)cc21 ; c1ccc2c(c1)-c1ccccc1-c1c3ccccc3cc3c1c-2cn3-c1ccc(-c2ccc(-n3c4ccccc4c4ccccc43)cc2)cc1]

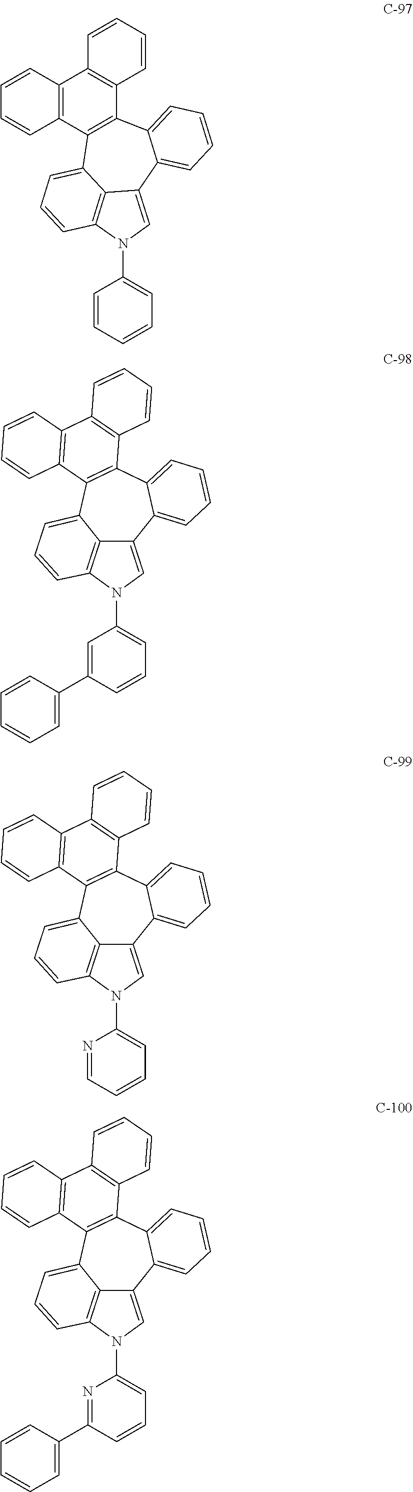

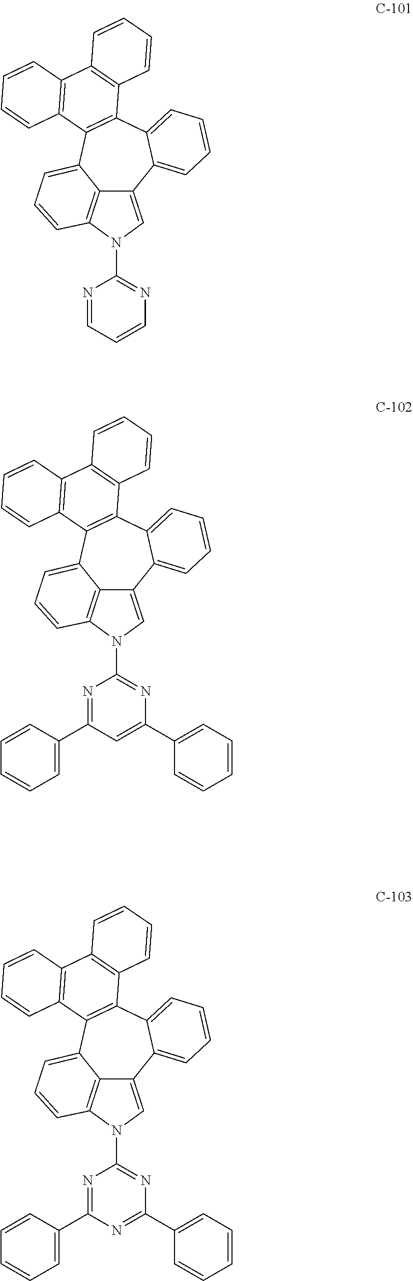 [SMILES: c1cnc(-n2cc3c4c(cccc42)-c2c(c4ccccc4c4ccccc24)-c2ccccc2-3)nc1 ; c1ccc(-c2cc(-c3ccccc3)nc(-n3cc4c5c(cccc53)-c3c(c5ccccc5c5ccccc35)-c3ccccc3-4)n2)cc1 ; c1ccc(-c2nc(-c3ccccc3)nc(-n3cc4c5c(cccc53)-c3c(c5ccccc5c5ccccc35)-c3ccccc3-4)n2)cc1]

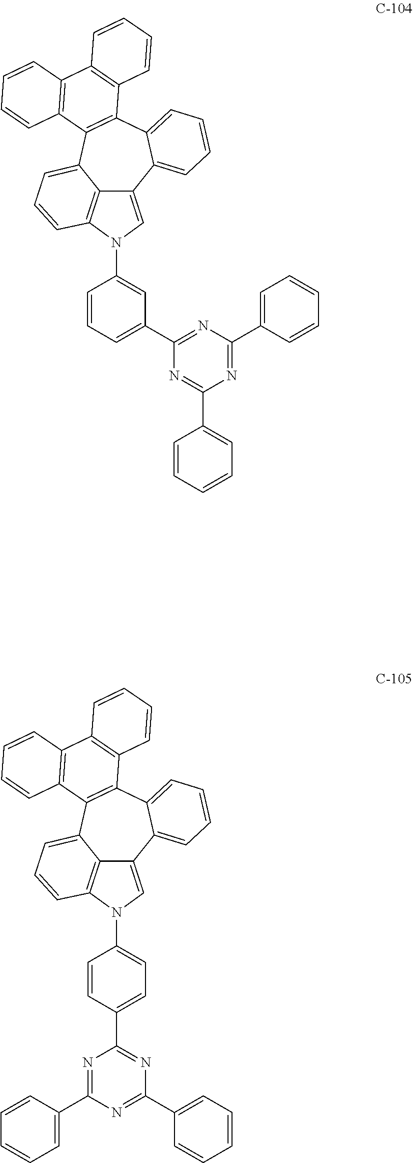 [SMILES: c1ccc(-c2nc(-c3ccccc3)nc(-c3cccc(-n4cc5c6c(cccc64)-c4c(c6ccccc6c6ccccc46)-c4ccccc4-5)c3)n2)cc1 ; c1ccc(-c2nc(-c3ccccc3)nc(-c3ccc(-n4cc5c6c(cccc64)-c4c(c6ccccc6c6ccccc46)-c4ccccc4-5)cc3)n2)cc1]

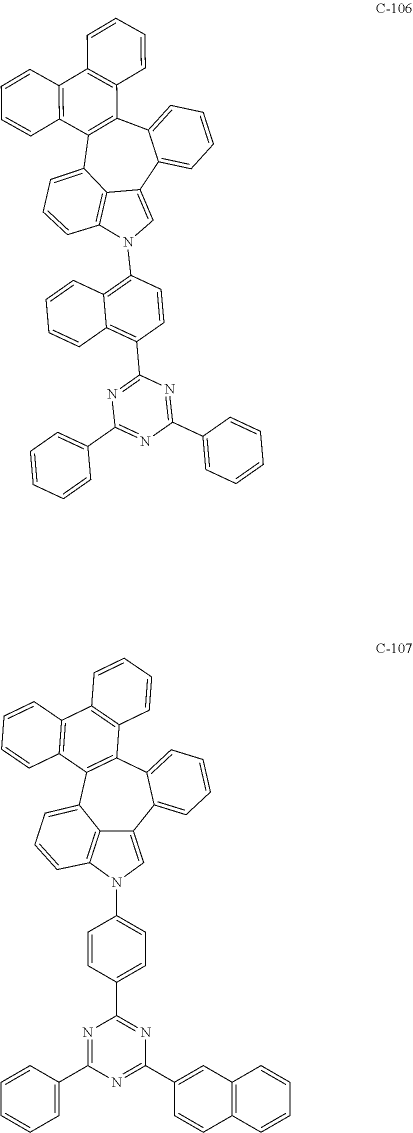 [SMILES: c1ccc(-c2nc(-c3ccccc3)nc(-c3ccc(-n4cc5c6c(cccc64)-c4c(c6ccccc6c6ccccc46)-c4ccccc4-5)c4ccccc34)n2)cc1 ; c1ccc(-c2nc(-c3ccc(-n4cc5c6c(cccc64)-c4c(c6ccccc6c6ccccc46)-c4ccccc4-5)cc3)nc(-c3ccc4ccccc4c3)n2)cc1]

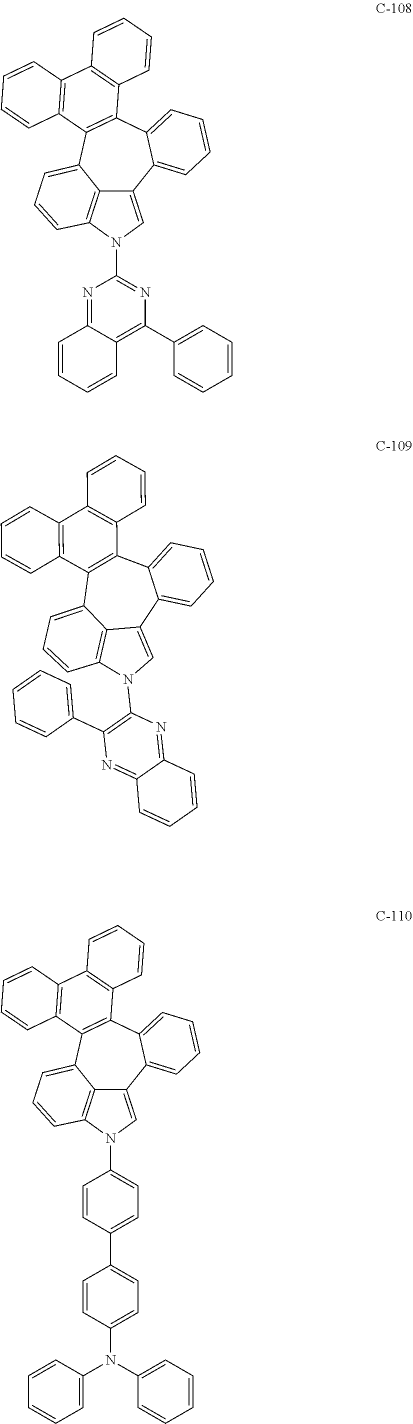 [SMILES: c1ccc(-c2nc(-n3cc4c5c(cccc53)-c3c(c5ccccc5c5ccccc35)-c3ccccc3-4)nc3ccccc23)cc1 ; c1ccc(-c2nc3ccccc3nc2-n2cc3c4c(cccc42)-c2c(c4ccccc4c4ccccc24)-c2ccccc2-3)cc1 ; c1ccc(N(c2ccccc2)c2ccc(-c3ccc(-n4cc5c6c(cccc64)-c4c(c6ccccc6c6ccccc46)-c4ccccc4-5)cc3)cc2)cc1]

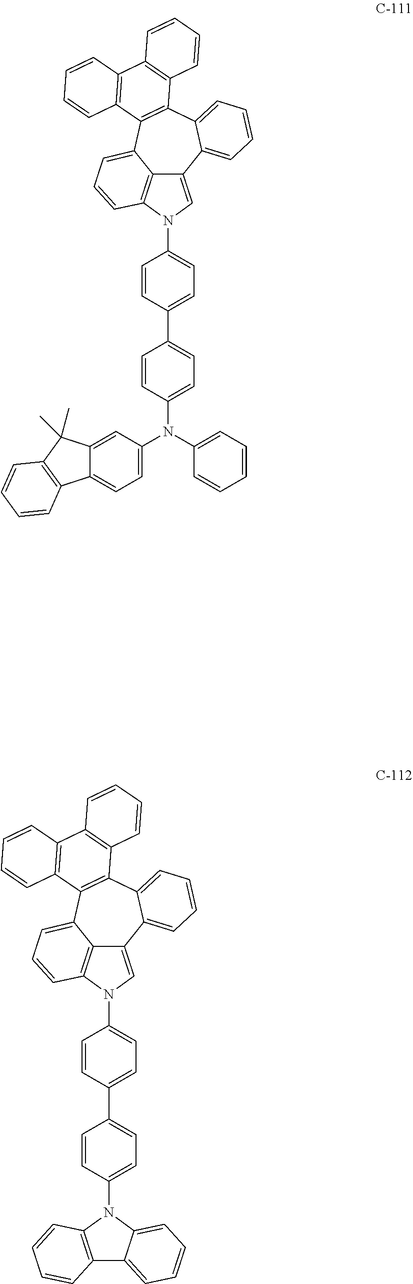 [SMILES: CC1(C)c2ccccc2-c2ccc(N(c3ccccc3)c3ccc(-c4ccc(-n5cc6c7c(cccc75)-c5c(c7ccccc7c7ccccc57)-c5ccccc5-6)cc4)cc3)cc21 ; c1ccc2c(c1)-c1c(c3ccccc3c3ccccc13)-c1cccc3c1c-2cn3-c1ccc(-c2ccc(-n3c4ccccc4c4ccccc43)cc2)cc1]

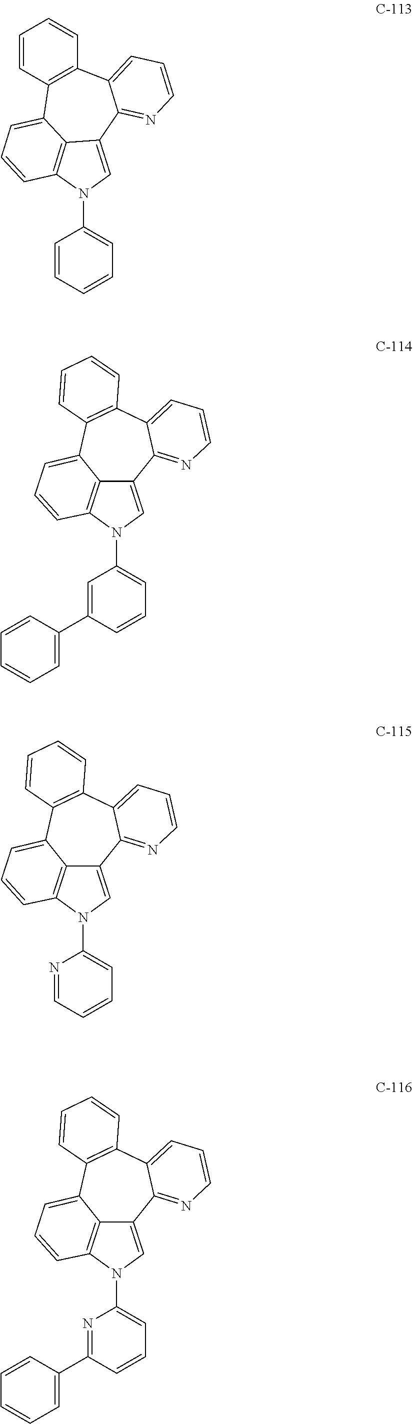 [SMILES: c1ccc(-n2cc3c4c(cccc42)-c2ccccc2-c2cccnc2-3)cc1 ; c1ccc(-c2cccc(-n3cc4c5c(cccc53)-c3ccccc3-c3cccnc3-4)c2)cc1 ; c1ccc(-n2cc3c4c(cccc42)-c2ccccc2-c2cccnc2-3)nc1 ; c1ccc(-c2cccc(-n3cc4c5c(cccc53)-c3ccccc3-c3cccnc3-4)n2)cc1]

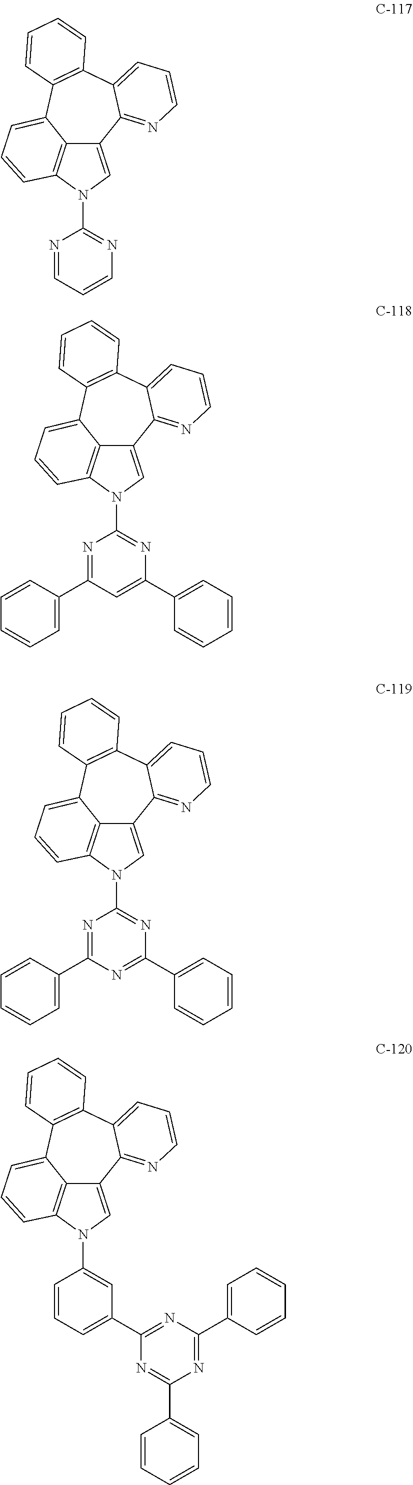

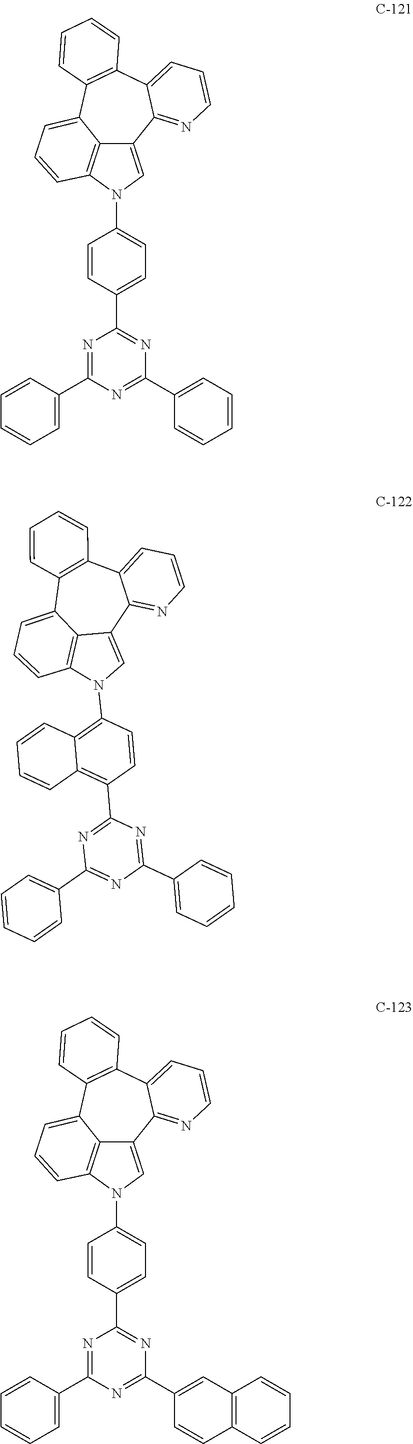 [SMILES: c1ccc(-c2nc(-c3ccccc3)nc(-c3ccc(-n4cc5c6c(cccc64)-c4ccccc4-c4cccnc4-5)cc3)n2)cc1 ; c1ccc(-c2nc(-c3ccccc3)nc(-c3ccc(-n4cc5c6c(cccc64)-c4ccccc4-c4cccnc4-5)c4ccccc34)n2)cc1 ; c1ccc(-c2nc(-c3ccc(-n4cc5c6c(cccc64)-c4ccccc4-c4cccnc4-5)cc3)nc(-c3ccc4ccccc4c3)n2)cc1]

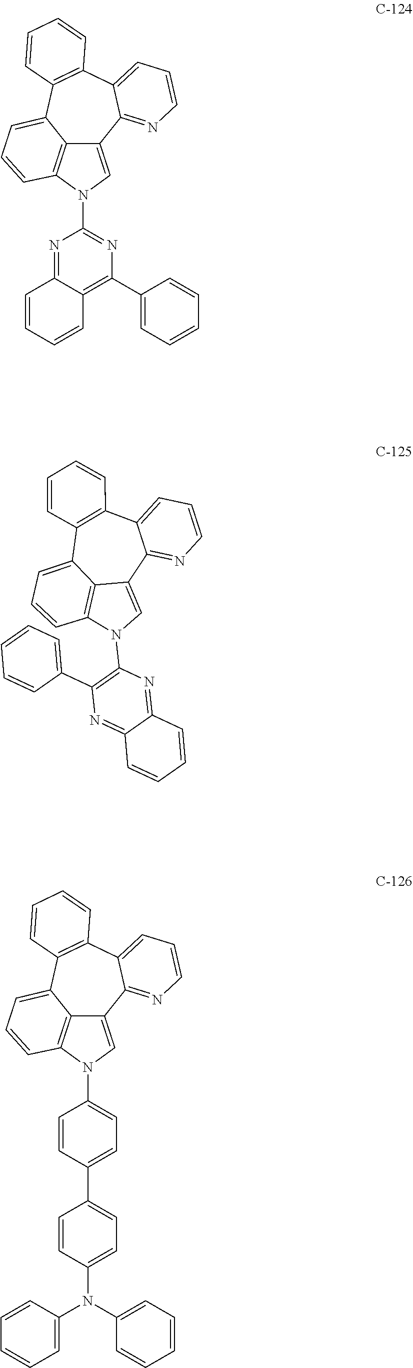 [SMILES: c1ccc(-c2nc(-n3cc4c5c(cccc53)-c3ccccc3-c3cccnc3-4)nc3ccccc23)cc1 ; c1ccc(-c2nc3ccccc3nc2-n2cc3c4c(cccc42)-c2ccccc2-c2cccnc2-3)cc1 ; c1ccc(N(c2ccccc2)c2ccc(-c3ccc(-n4cc5c6c(cccc64)-c4ccccc4-c4cccnc4-5)cc3)cc2)cc1]

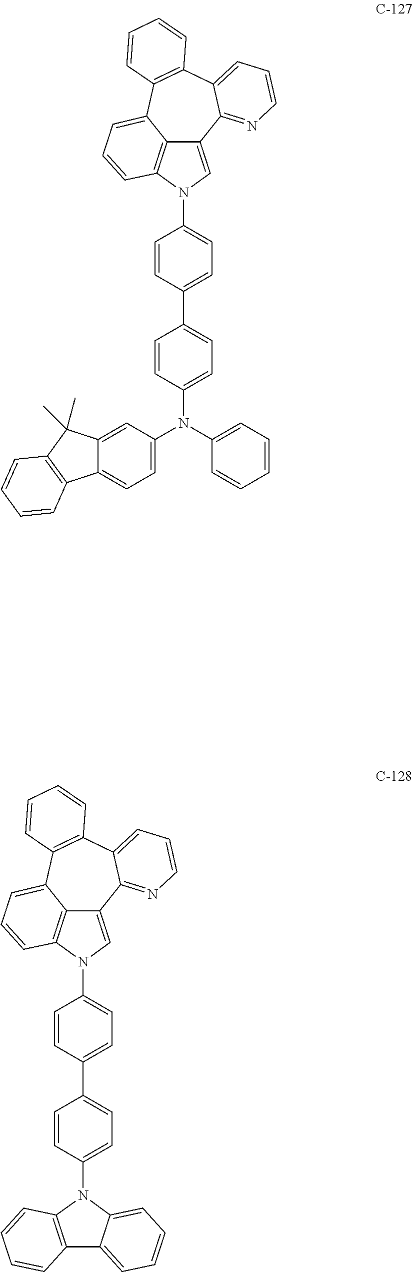 [SMILES: CC1(C)c2ccccc2-c2ccc(N(c3ccccc3)c3ccc(-c4ccc(-n5cc6c7c(cccc75)-c5ccccc5-c5cccnc5-6)cc4)cc3)cc21 ; c1ccc2c(c1)-c1cccnc1-c1cn(-c3ccc(-c4ccc(-n5c6ccccc6c6ccccc65)cc4)cc3)c3cccc-2c13]

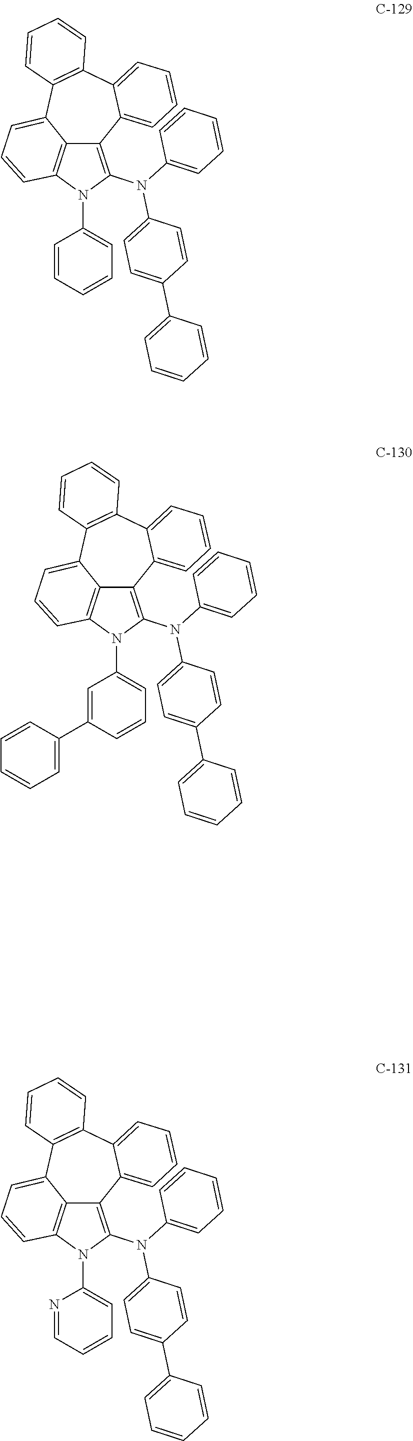 [SMILES: c1ccc(-c2ccc(N(c3ccccc3)c3c4c5c(cccc5n3-c3ccccc3)-c3ccccc3-c3ccccc3-4)cc2)cc1 ; c1ccc(-c2ccc(N(c3ccccc3)c3c4c5c(cccc5n3-c3cccc(-c5ccccc5)c3)-c3ccccc3-c3ccccc3-4)cc2)cc1 ; c1ccc(-c2ccc(N(c3ccccc3)c3c4c5c(cccc5n3-c3ccccn3)-c3ccccc3-c3ccccc3-4)cc2)cc1]

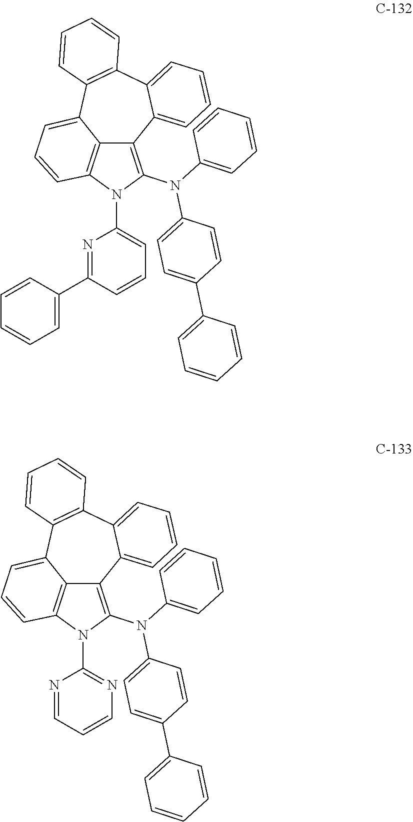 [SMILES: c1ccc(-c2ccc(N(c3ccccc3)c3c4c5c(cccc5n3-c3cccc(-c5ccccc5)n3)-c3ccccc3-c3ccccc3-4)cc2)cc1 ; c1ccc(-c2ccc(N(c3ccccc3)c3c4c5c(cccc5n3-c3ncccn3)-c3ccccc3-c3ccccc3-4)cc2)cc1]

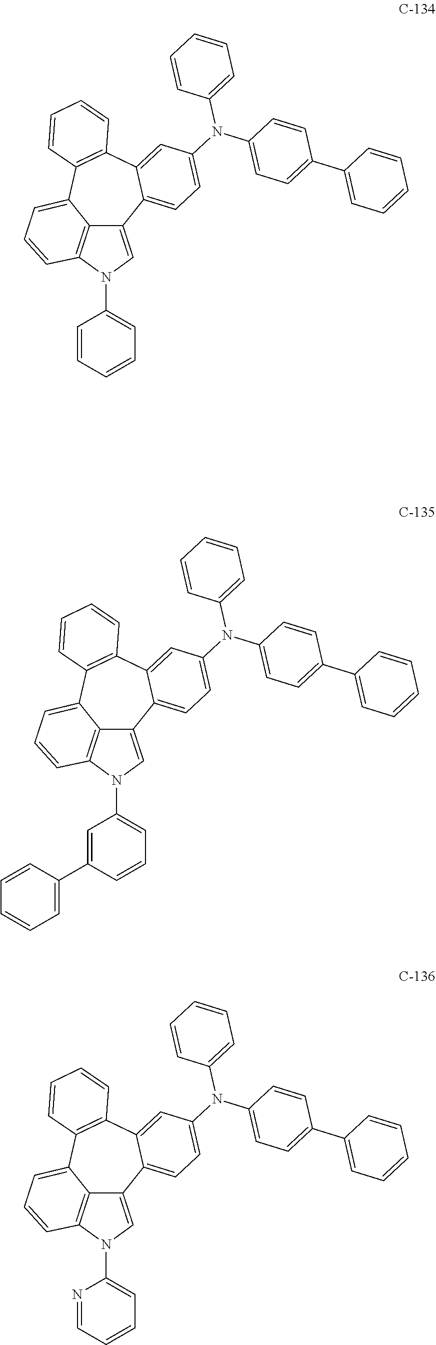 [SMILES: c1ccc(-c2ccc(N(c3ccccc3)c3ccc4c(c3)-c3ccccc3-c3cccc5c3c-4cn5-c3ccccc3)cc2)cc1 ; c1ccc(-c2ccc(N(c3ccccc3)c3ccc4c(c3)-c3ccccc3-c3cccc5c3c-4cn5-c3cccc(-c4ccccc4)c3)cc2)cc1 ; c1ccc(-c2ccc(N(c3ccccc3)c3ccc4c(c3)-c3ccccc3-c3cccc5c3c-4cn5-c3ccccn3)cc2)cc1]

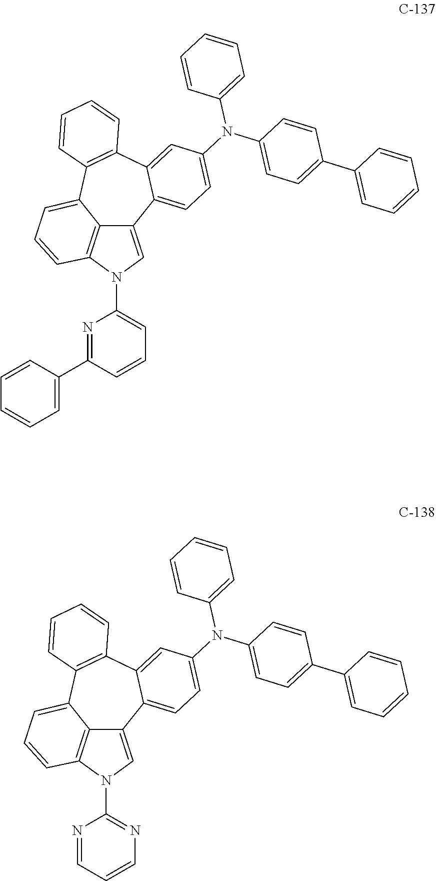 [SMILES: c1ccc(-c2ccc(N(c3ccccc3)c3ccc4c(c3)-c3ccccc3-c3cccc5c3c-4cn5-c3cccc(-c4ccccc4)n3)cc2)cc1 ; c1ccc(-c2ccc(N(c3ccccc3)c3ccc4c(c3)-c3ccccc3-c3cccc5c3c-4cn5-c3ncccn3)cc2)cc1]

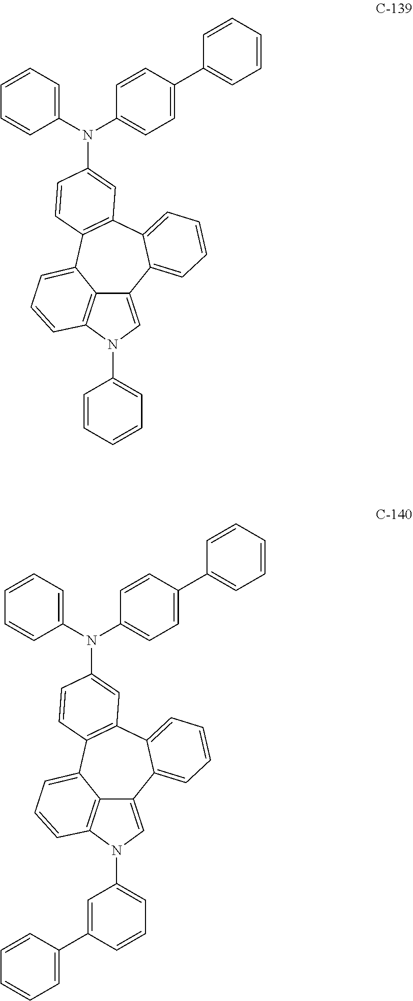 [SMILES: c1ccc(-c2ccc(N(c3ccccc3)c3ccc4c(c3)-c3ccccc3-c3cn(-c5ccccc5)c5cccc-4c35)cc2)cc1 ; c1ccc(-c2ccc(N(c3ccccc3)c3ccc4c(c3)-c3ccccc3-c3cn(-c5cccc(-c6ccccc6)c5)c5cccc-4c35)cc2)cc1]

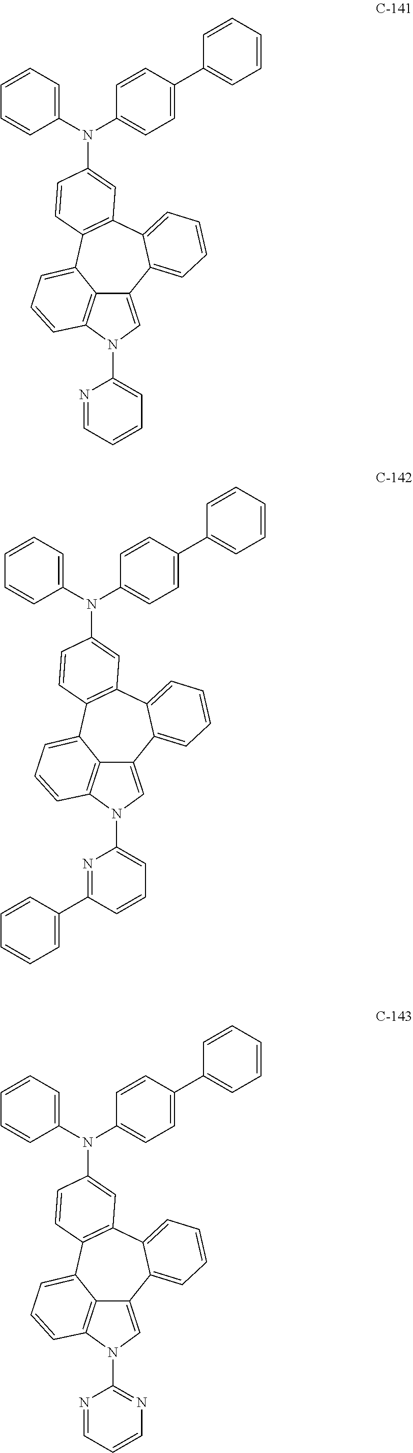 [SMILES: c1ccc(-c2ccc(N(c3ccccc3)c3ccc4c(c3)-c3ccccc3-c3cn(-c5ccccn5)c5cccc-4c35)cc2)cc1 ; c1ccc(-c2ccc(N(c3ccccc3)c3ccc4c(c3)-c3ccccc3-c3cn(-c5cccc(-c6ccccc6)n5)c5cccc-4c35)cc2)cc1 ; c1ccc(-c2ccc(N(c3ccccc3)c3ccc4c(c3)-c3ccccc3-c3cn(-c5ncccn5)c5cccc-4c35)cc2)cc1]

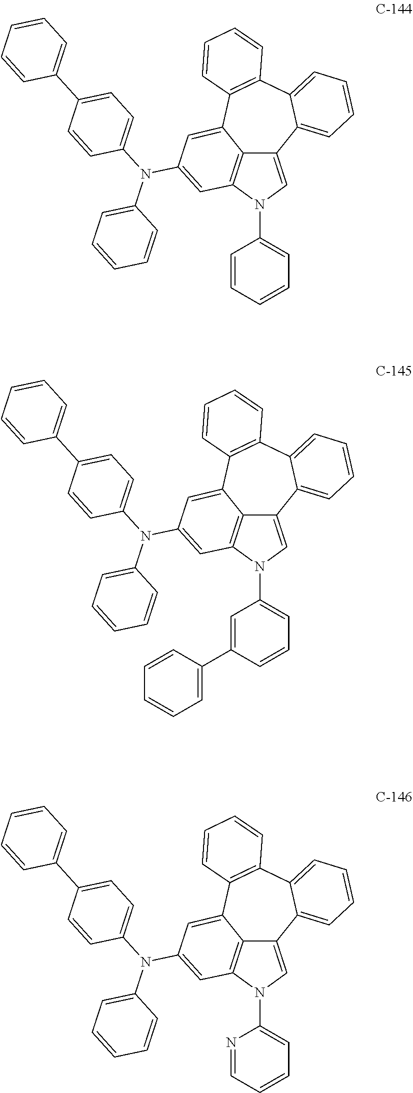 [SMILES: c1ccc(-c2ccc(N(c3ccccc3)c3cc4c5c(cn(-c6ccccc6)c5c3)-c3ccccc3-c3ccccc3-4)cc2)cc1 ; c1ccc(-c2ccc(N(c3ccccc3)c3cc4c5c(cn(-c6cccc(-c7ccccc7)c6)c5c3)-c3ccccc3-c3ccccc3-4)cc2)cc1 ; c1ccc(-c2ccc(N(c3ccccc3)c3cc4c5c(cn(-c6ccccn6)c5c3)-c3ccccc3-c3ccccc3-4)cc2)cc1]

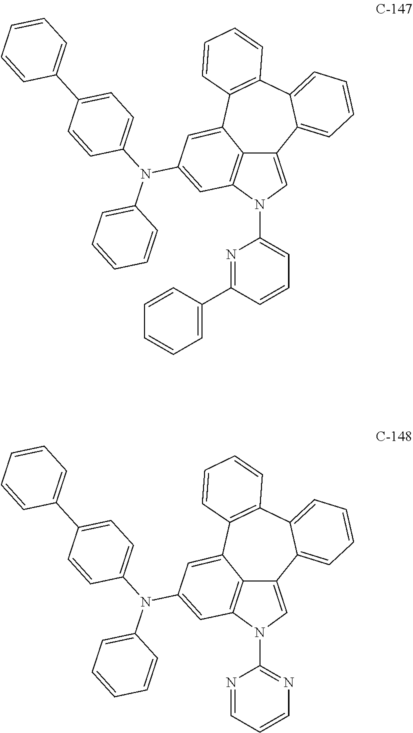 [SMILES: c1ccc(-c2ccc(N(c3ccccc3)c3cc4c5c(cn(-c6cccc(-c7ccccc7)n6)c5c3)-c3ccccc3-c3ccccc3-4)cc2)cc1 ; c1ccc(-c2ccc(N(c3ccccc3)c3cc4c5c(cn(-c6ncccn6)c5c3)-c3ccccc3-c3ccccc3-4)cc2)cc1]

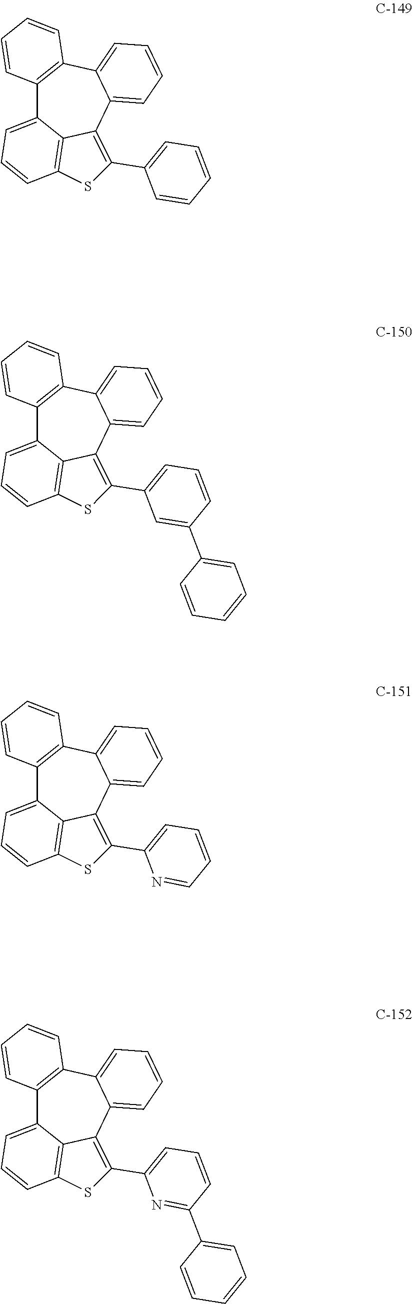 [SMILES: c1ccc(-c2sc3cccc4c3c2-c2ccccc2-c2ccccc2-4)cc1 ; c1ccc(-c2cccc(-c3sc4cccc5c4c3-c3ccccc3-c3ccccc3-5)c2)cc1 ; c1ccc(-c2sc3cccc4c3c2-c2ccccc2-c2ccccc2-4)nc1 ; c1ccc(-c2cccc(-c3sc4cccc5c4c3-c3ccccc3-c3ccccc3-5)n2)cc1]

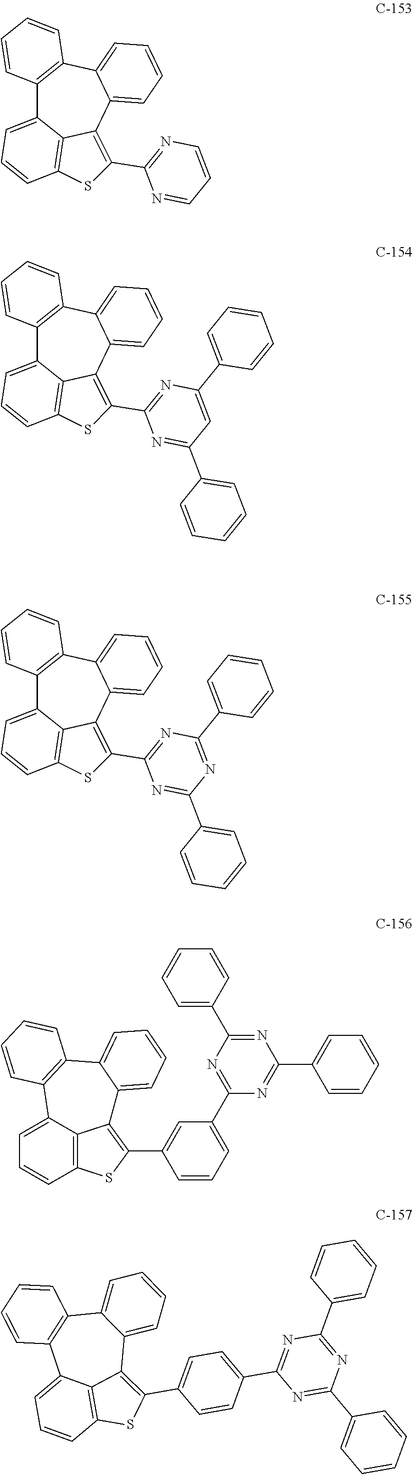 [SMILES: c1cnc(-c2sc3cccc4c3c2-c2ccccc2-c2ccccc2-4)nc1 ; c1ccc(-c2cc(-c3ccccc3)nc(-c3sc4cccc5c4c3-c3ccccc3-c3ccccc3-5)n2)cc1 ; c1ccc(-c2nc(-c3ccccc3)nc(-c3sc4cccc5c4c3-c3ccccc3-c3ccccc3-5)n2)cc1 ; c1ccc(-c2nc(-c3ccccc3)nc(-c3cccc(-c4sc5cccc6c5c4-c4ccccc4-c4ccccc4-6)c3)n2)cc1 ; c1ccc(-c2nc(-c3ccccc3)nc(-c3ccc(-c4sc5cccc6c5c4-c4ccccc4-c4ccccc4-6)cc3)n2)cc1]

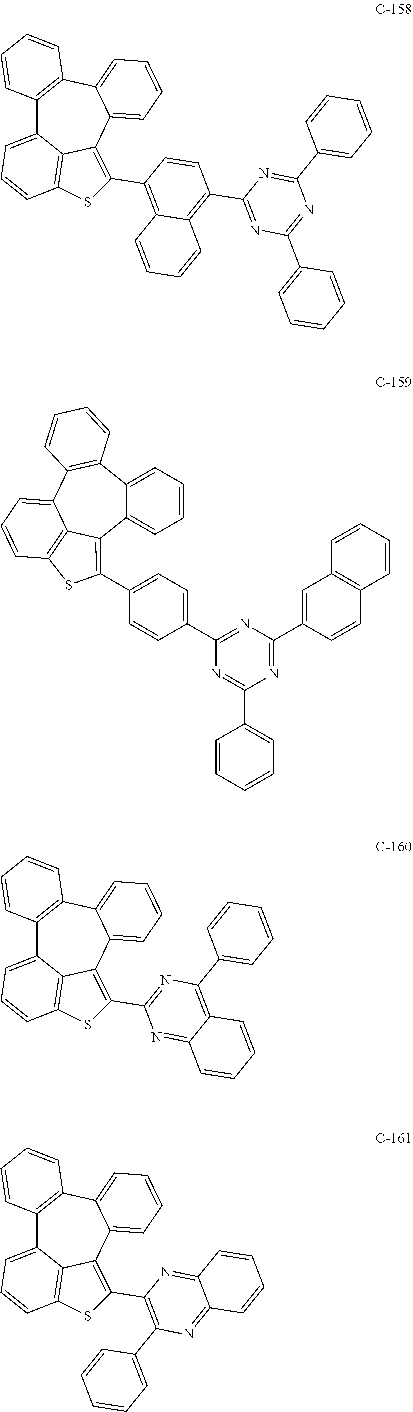 [SMILES: c1ccc(-c2nc(-c3ccccc3)nc(-c3ccc(-c4sc5cccc6c5c4-c4ccccc4-c4ccccc4-6)c4ccccc34)n2)cc1 ; c1ccc(-c2nc(-c3ccc(-c4sc5cccc6c5c4-c4ccccc4-c4ccccc4-6)cc3)nc(-c3ccc4ccccc4c3)n2)cc1 ; c1ccc(-c2nc(-c3sc4cccc5c4c3-c3ccccc3-c3ccccc3-5)nc3ccccc23)cc1 ; c1ccc(-c2nc3ccccc3nc2-c2sc3cccc4c3c2-c2ccccc2-c2ccccc2-4)cc1]

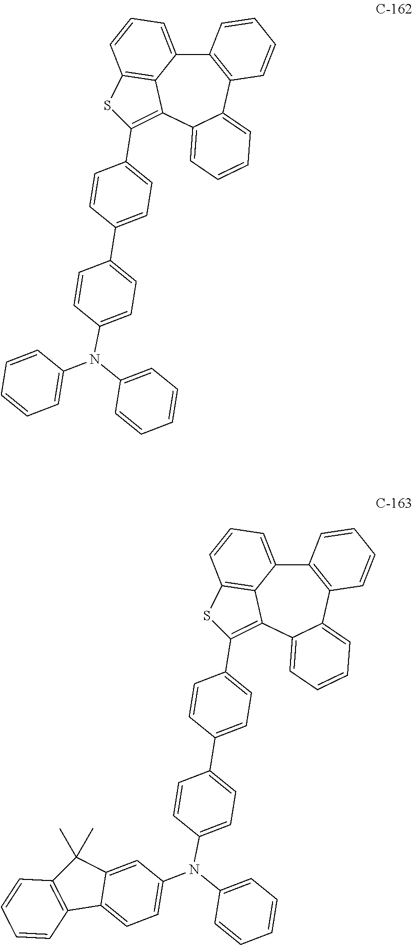 [SMILES: c1ccc(N(c2ccccc2)c2ccc(-c3ccc(-c4sc5cccc6c5c4-c4ccccc4-c4ccccc4-6)cc3)cc2)cc1 ; CC1(C)c2ccccc2-c2ccc(N(c3ccccc3)c3ccc(-c4ccc(-c5sc6cccc7c6c5-c5ccccc5-c5ccccc5-7)cc4)cc3)cc21]

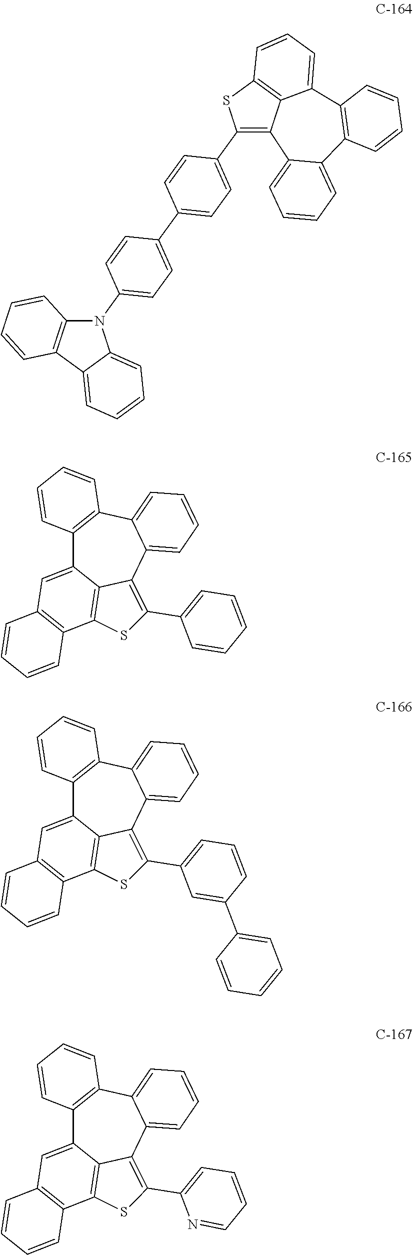 [SMILES: c1ccc2c(c1)-c1ccccc1-c1c(-c3ccc(-c4ccc(-n5c6ccccc6c6ccccc65)cc4)cc3)sc3cccc-2c13 ; c1ccc(-c2sc3c4c(cc5ccccc53)-c3ccccc3-c3ccccc3-c24)cc1 ; c1ccc(-c2cccc(-c3sc4c5c(cc6ccccc64)-c4ccccc4-c4ccccc4-c35)c2)cc1 ; c1ccc(-c2sc3c4c(cc5ccccc53)-c3ccccc3-c3ccccc3-c24)nc1]

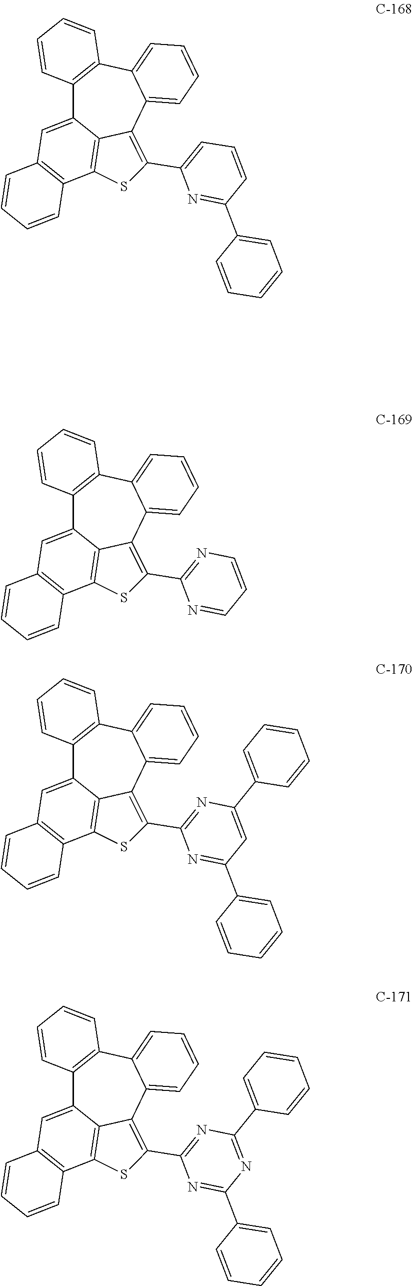 [SMILES: c1ccc(-c2cccc(-c3sc4c5c(cc6ccccc64)-c4ccccc4-c4ccccc4-c35)n2)cc1 ; c1cnc(-c2sc3c4c(cc5ccccc53)-c3ccccc3-c3ccccc3-c24)nc1 ; c1ccc(-c2cc(-c3ccccc3)nc(-c3sc4c5c(cc6ccccc64)-c4ccccc4-c4ccccc4-c35)n2)cc1 ; c1ccc(-c2nc(-c3ccccc3)nc(-c3sc4c5c(cc6ccccc64)-c4ccccc4-c4ccccc4-c35)n2)cc1]

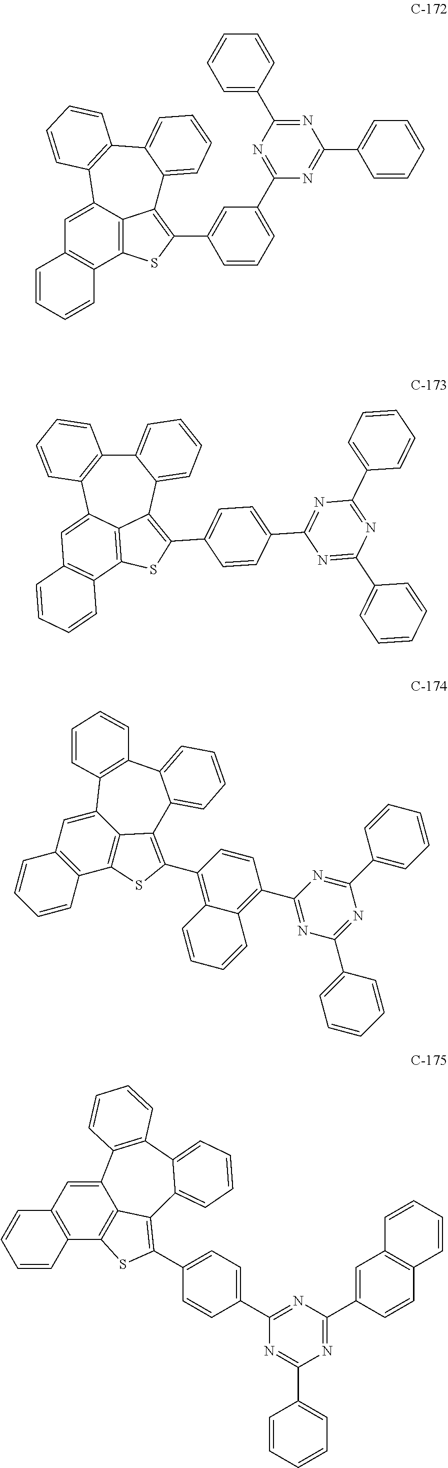 [SMILES: c1ccc(-c2nc(-c3ccccc3)nc(-c3cccc(-c4sc5c6c(cc7ccccc75)-c5ccccc5-c5ccccc5-c46)c3)n2)cc1 ; c1ccc(-c2nc(-c3ccccc3)nc(-c3ccc(-c4sc5c6c(cc7ccccc75)-c5ccccc5-c5ccccc5-c46)cc3)n2)cc1 ; c1ccc(-c2nc(-c3ccccc3)nc(-c3ccc(-c4sc5c6c(cc7ccccc75)-c5ccccc5-c5ccccc5-c46)c4ccccc34)n2)cc1 ; c1ccc(-c2nc(-c3ccc(-c4sc5c6c(cc7ccccc75)-c5ccccc5-c5ccccc5-c46)cc3)nc(-c3ccc4ccccc4c3)n2)cc1]

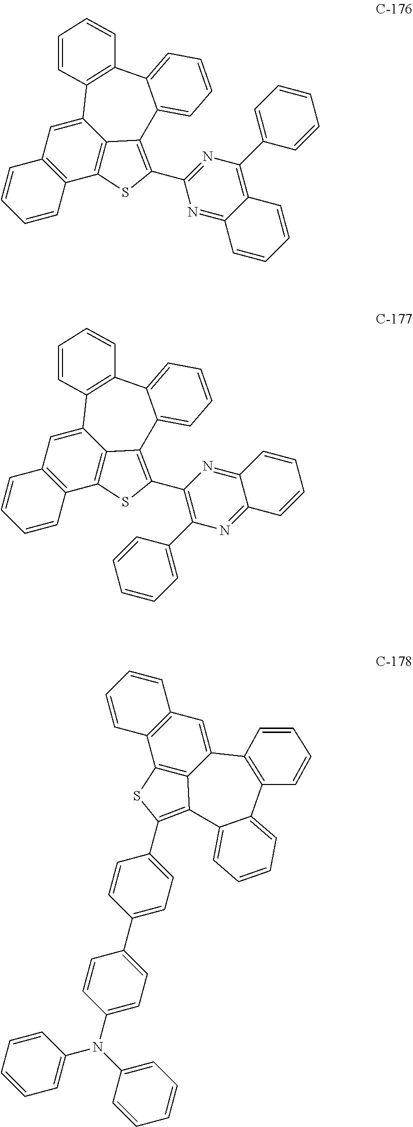 [SMILES: c1ccc(-c2nc(-c3sc4c5c(cc6ccccc64)-c4ccccc4-c4ccccc4-c35)nc3ccccc23)cc1 ; c1ccc(-c2nc3ccccc3nc2-c2sc3c4c(cc5ccccc53)-c3ccccc3-c3ccccc3-c24)cc1 ; c1ccc(N(c2ccccc2)c2ccc(-c3ccc(-c4sc5c6c(cc7ccccc75)-c5ccccc5-c5ccccc5-c46)cc3)cc2)cc1]

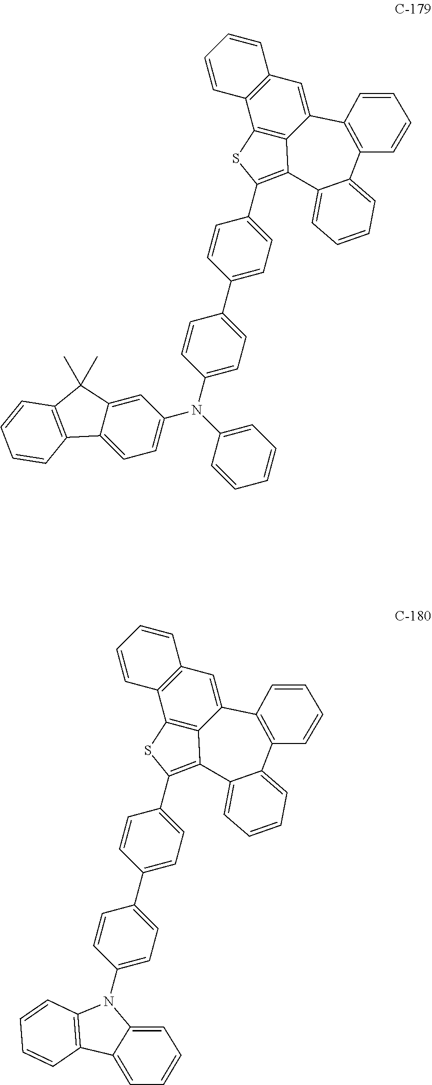 [SMILES: CC1(C)c2ccccc2-c2ccc(N(c3ccccc3)c3ccc(-c4ccc(-c5sc6c7c(cc8ccccc86)-c6ccccc6-c6ccccc6-c57)cc4)cc3)cc21 ; c1ccc2c(c1)-c1ccccc1-c1c(-c3ccc(-c4ccc(-n5c6ccccc6c6ccccc65)cc4)cc3)sc3c1c-2cc1ccccc13]

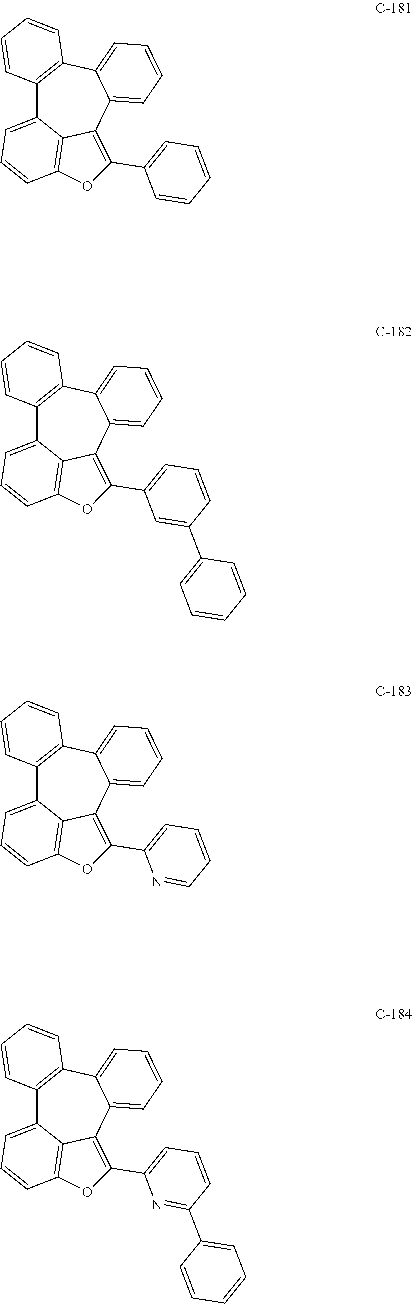 [SMILES: c1ccc(-c2oc3cccc4c3c2-c2ccccc2-c2ccccc2-4)cc1 ; c1ccc(-c2cccc(-c3oc4cccc5c4c3-c3ccccc3-c3ccccc3-5)c2)cc1 ; c1ccc(-c2oc3cccc4c3c2-c2ccccc2-c2ccccc2-4)nc1 ; c1ccc(-c2cccc(-c3oc4cccc5c4c3-c3ccccc3-c3ccccc3-5)n2)cc1]

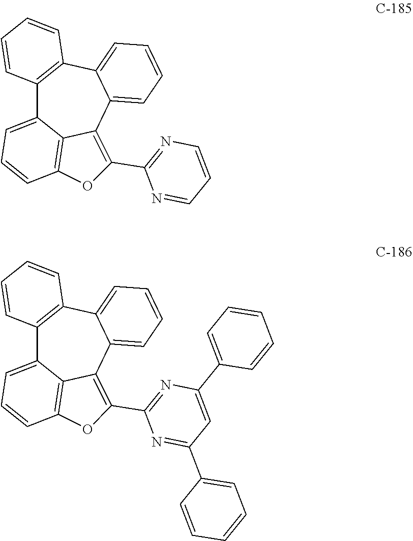 [SMILES: c1cnc(-c2oc3cccc4c3c2-c2ccccc2-c2ccccc2-4)nc1 ; c1ccc(-c2cc(-c3ccccc3)nc(-c3oc4cccc5c4c3-c3ccccc3-c3ccccc3-5)n2)cc1]

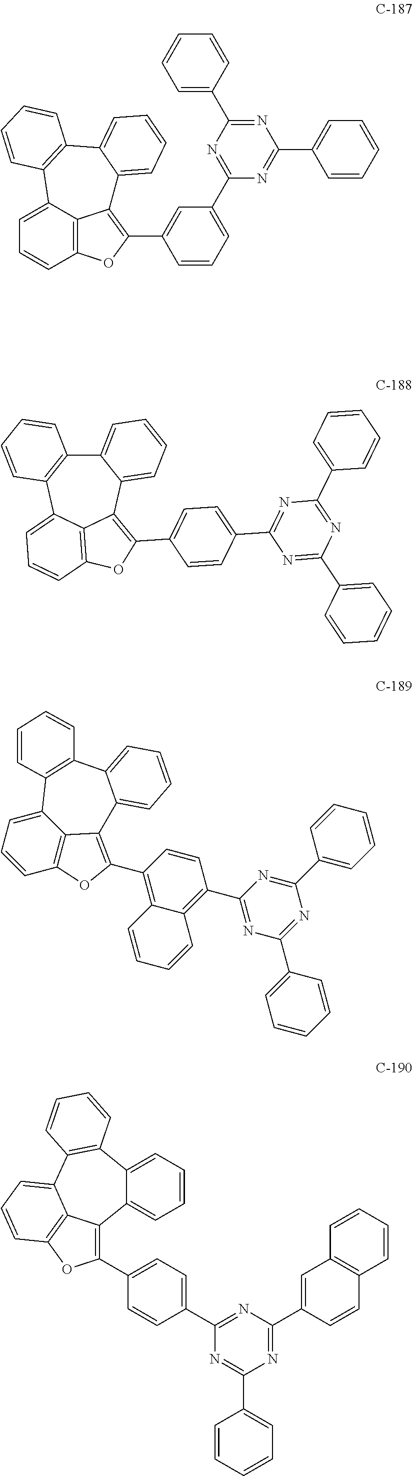 [SMILES: c1ccc(-c2nc(-c3ccccc3)nc(-c3cccc(-c4oc5cccc6c5c4-c4ccccc4-c4ccccc4-6)c3)n2)cc1 ; c1ccc(-c2nc(-c3ccccc3)nc(-c3ccc(-c4oc5cccc6c5c4-c4ccccc4-c4ccccc4-6)cc3)n2)cc1 ; c1ccc(-c2nc(-c3ccccc3)nc(-c3ccc(-c4oc5cccc6c5c4-c4ccccc4-c4ccccc4-6)c4ccccc34)n2)cc1 ; c1ccc(-c2nc(-c3ccc(-c4oc5cccc6c5c4-c4ccccc4-c4ccccc4-6)cc3)nc(-c3ccc4ccccc4c3)n2)cc1]

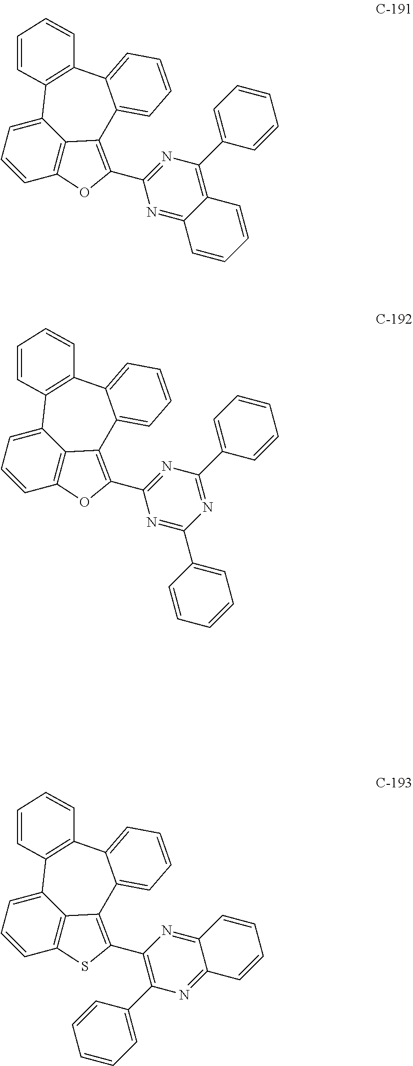 [SMILES: c1ccc(-c2nc(-c3oc4cccc5c4c3-c3ccccc3-c3ccccc3-5)nc3ccccc23)cc1 ; c1ccc(-c2nc(-c3ccccc3)nc(-c3oc4cccc5c4c3-c3ccccc3-c3ccccc3-5)n2)cc1 ; c1ccc(-c2nc3ccccc3nc2-c2sc3cccc4c3c2-c2ccccc2-c2ccccc2-4)cc1]

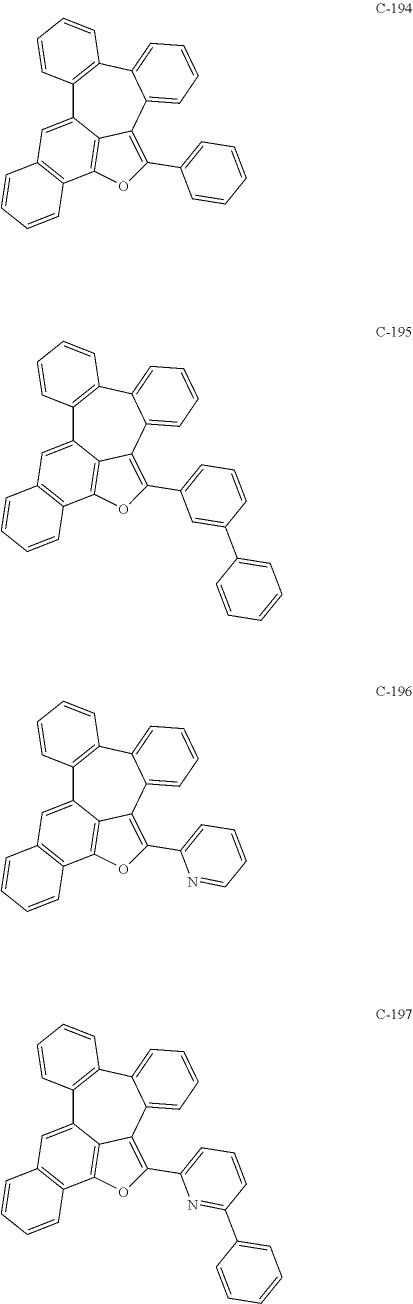 [SMILES: c1ccc(-c2oc3c4c(cc5ccccc53)-c3ccccc3-c3ccccc3-c24)cc1 ; c1ccc(-c2cccc(-c3oc4c5c(cc6ccccc64)-c4ccccc4-c4ccccc4-c35)c2)cc1 ; c1ccc(-c2oc3c4c(cc5ccccc53)-c3ccccc3-c3ccccc3-c24)nc1 ; c1ccc(-c2cccc(-c3oc4c5c(cc6ccccc64)-c4ccccc4-c4ccccc4-c35)n2)cc1]

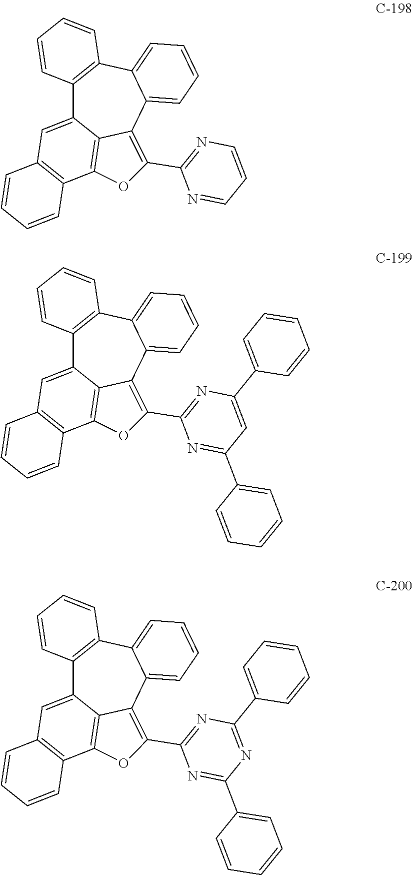 [SMILES: c1cnc(-c2oc3c4c(cc5ccccc53)-c3ccccc3-c3ccccc3-c24)nc1 ; c1ccc(-c2cc(-c3ccccc3)nc(-c3oc4c5c(cc6ccccc64)-c4ccccc4-c4ccccc4-c35)n2)cc1 ; c1ccc(-c2nc(-c3ccccc3)nc(-c3oc4c5c(cc6ccccc64)-c4ccccc4-c4ccccc4-c35)n2)cc1]

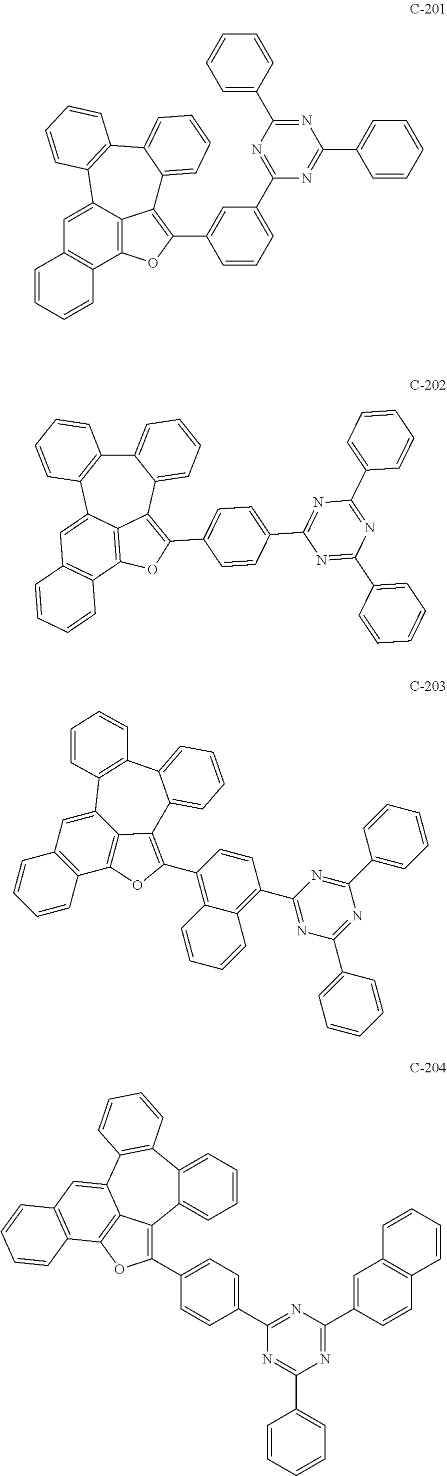 [SMILES: c1ccc(-c2nc(-c3ccccc3)nc(-c3cccc(-c4oc5c6c(cc7ccccc75)-c5ccccc5-c5ccccc5-c46)c3)n2)cc1 ; c1ccc(-c2nc(-c3ccccc3)nc(-c3ccc(-c4oc5c6c(cc7ccccc75)-c5ccccc5-c5ccccc5-c46)cc3)n2)cc1 ; c1ccc(-c2nc(-c3ccccc3)nc(-c3ccc(-c4oc5c6c(cc7ccccc75)-c5ccccc5-c5ccccc5-c46)c4ccccc34)n2)cc1 ; c1ccc(-c2nc(-c3ccc(-c4oc5c6c(cc7ccccc75)-c5ccccc5-c5ccccc5-c46)cc3)nc(-c3ccc4ccccc4c3)n2)cc1]

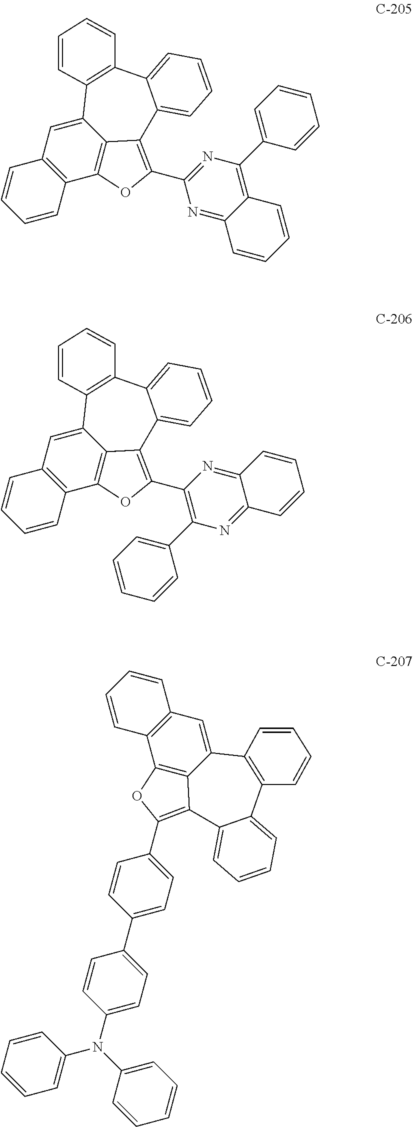 [SMILES: c1ccc(-c2nc(-c3oc4c5c(cc6ccccc64)-c4ccccc4-c4ccccc4-c35)nc3ccccc23)cc1 ; c1ccc(-c2nc3ccccc3nc2-c2oc3c4c(cc5ccccc53)-c3ccccc3-c3ccccc3-c24)cc1 ; c1ccc(N(c2ccccc2)c2ccc(-c3ccc(-c4oc5c6c(cc7ccccc75)-c5ccccc5-c5ccccc5-c46)cc3)cc2)cc1]

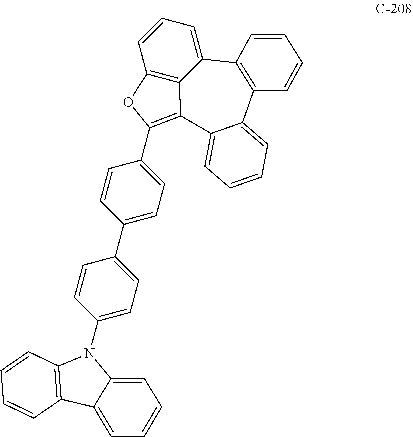 [SMILES: c1ccc2c(c1)-c1ccccc1-c1c(-c3ccc(-c4ccc(-n5c6ccccc6c6ccccc65)cc4)cc3)oc3cccc-2c13]

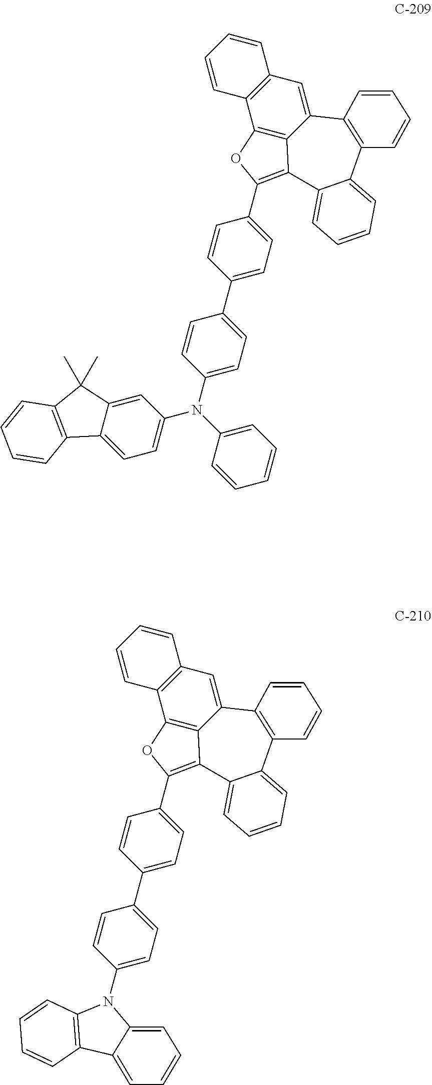 [SMILES: CC1(C)c2ccccc2-c2ccc(N(c3ccccc3)c3ccc(-c4ccc(-c5oc6c7c(cc8ccccc86)-c6ccccc6-c6ccccc6-c57)cc4)cc3)cc21 ; c1ccc2c(c1)-c1ccccc1-c1c(-c3ccc(-c4ccc(-n5c6ccccc6c6ccccc65)cc4)cc3)oc3c1c-2cc1ccccc13]

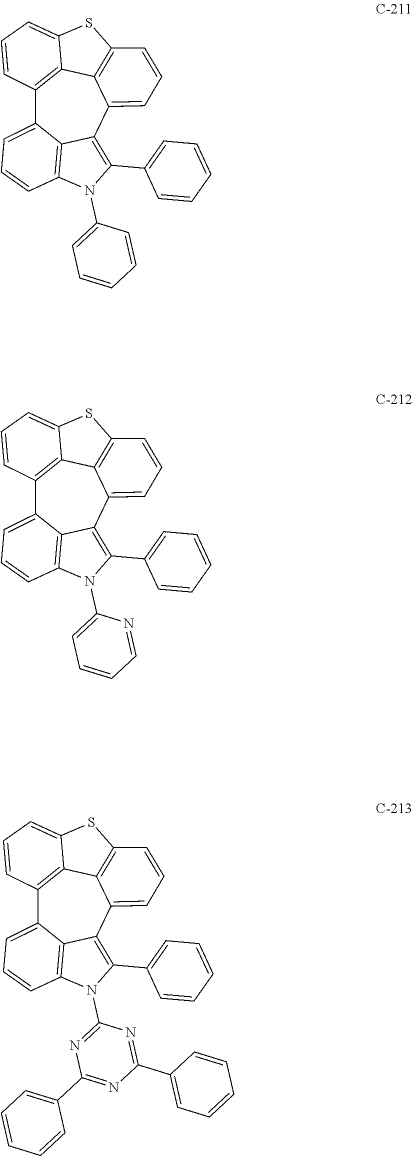 [SMILES: c1ccc(-c2c3c4c(cccc4n2-c2ccccc2)-c2cccc4sc5cccc-3c5c24)cc1 ; c1ccc(-c2c3c4c(cccc4n2-c2ccccn2)-c2cccc4sc5cccc-3c5c24)cc1 ; c1ccc(-c2nc(-c3ccccc3)nc(-n3c(-c4ccccc4)c4c5c(cccc53)-c3cccc5sc6cccc-4c6c35)n2)cc1]

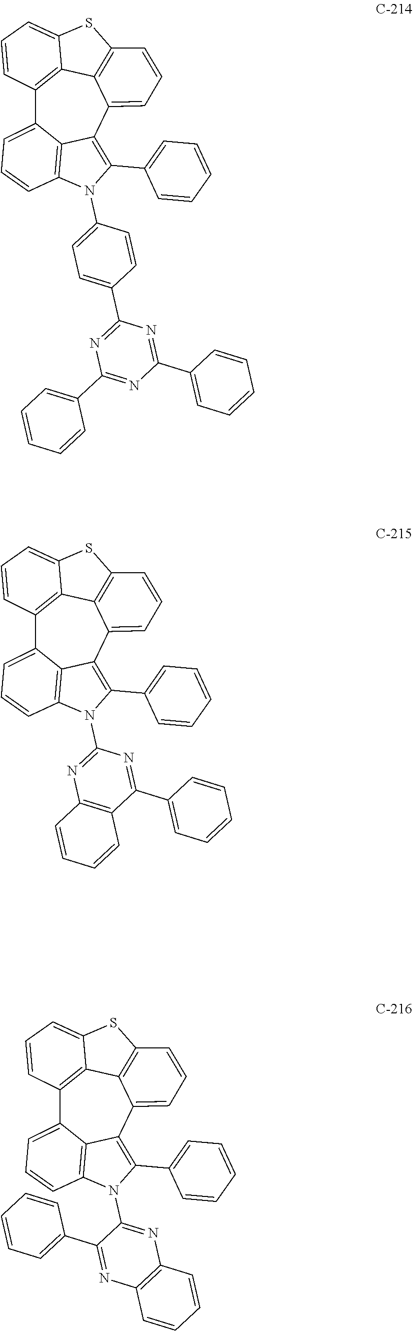 [SMILES: c1ccc(-c2nc(-c3ccccc3)nc(-c3ccc(-n4c(-c5ccccc5)c5c6c(cccc64)-c4cccc6sc7cccc-5c7c46)cc3)n2)cc1 ; c1ccc(-c2nc(-n3c(-c4ccccc4)c4c5c(cccc53)-c3cccc5sc6cccc-4c6c35)nc3ccccc23)cc1 ; c1ccc(-c2nc3ccccc3nc2-n2c(-c3ccccc3)c3c4c(cccc42)-c2cccc4sc5cccc-3c5c24)cc1]

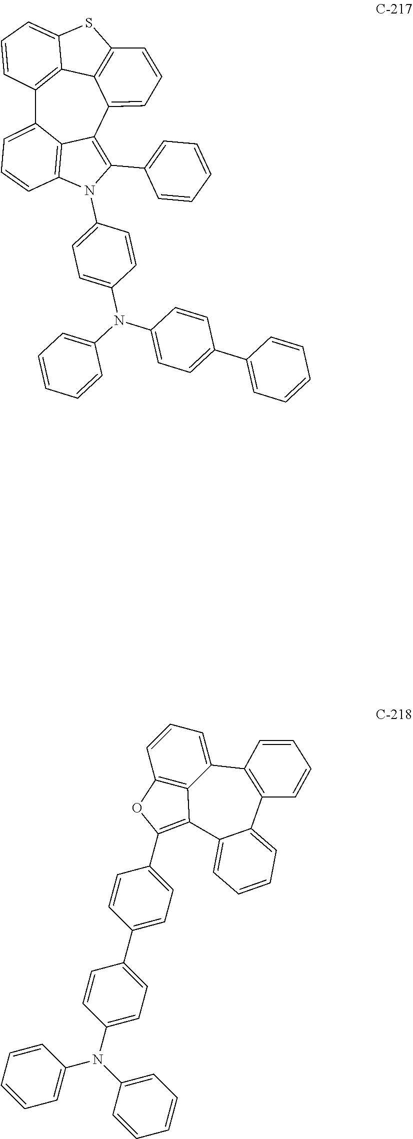 [SMILES: c1ccc(-c2ccc(N(c3ccccc3)c3ccc(-n4c(-c5ccccc5)c5c6c(cccc64)-c4cccc6sc7cccc-5c7c46)cc3)cc2)cc1 ; c1ccc(N(c2ccccc2)c2ccc(-c3ccc(-c4oc5cccc6c5c4-c4ccccc4-c4ccccc4-6)cc3)cc2)cc1]

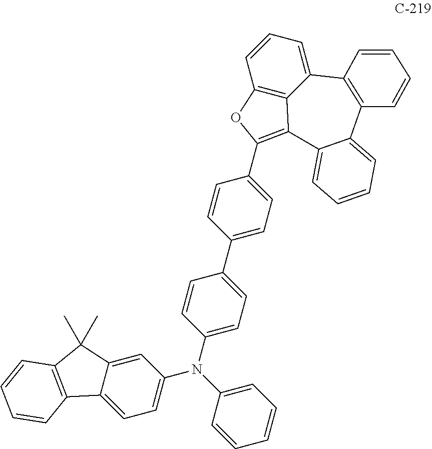 [SMILES: CC1(C)c2ccccc2-c2ccc(N(c3ccccc3)c3ccc(-c4ccc(-c5oc6cccc7c6c5-c5ccccc5-c5ccccc5-7)cc4)cc3)cc21]

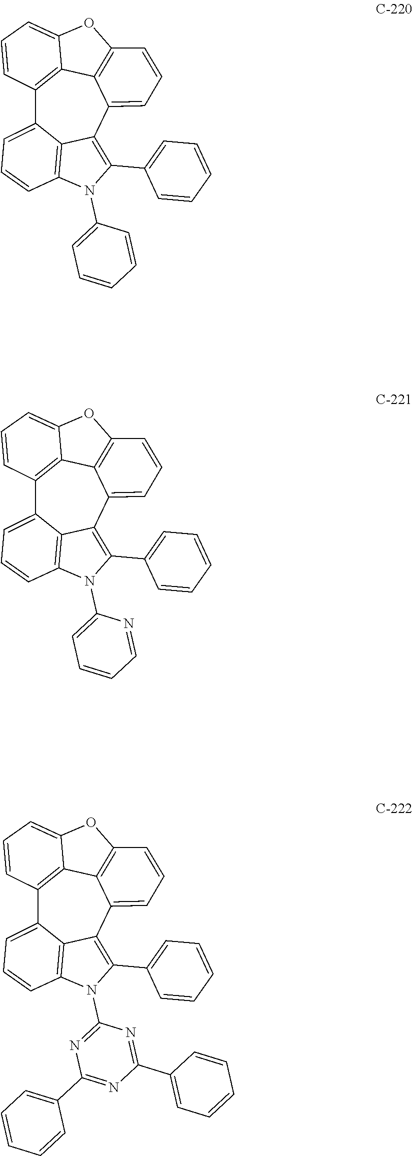 [SMILES: c1ccc(-c2c3c4c(cccc4n2-c2ccccc2)-c2cccc4oc5cccc-3c5c24)cc1 ; c1ccc(-c2c3c4c(cccc4n2-c2ccccn2)-c2cccc4oc5cccc-3c5c24)cc1 ; c1ccc(-c2nc(-c3ccccc3)nc(-n3c(-c4ccccc4)c4c5c(cccc53)-c3cccc5oc6cccc-4c6c35)n2)cc1]

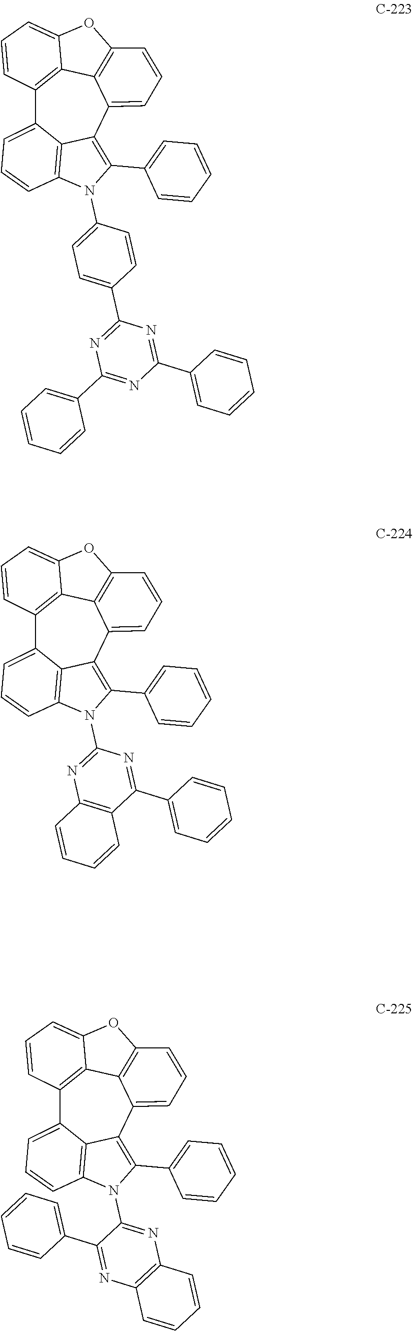 [SMILES: c1ccc(-c2nc(-c3ccccc3)nc(-c3ccc(-n4c(-c5ccccc5)c5c6c(cccc64)-c4cccc6oc7cccc-5c7c46)cc3)n2)cc1 ; c1ccc(-c2nc(-n3c(-c4ccccc4)c4c5c(cccc53)-c3cccc5oc6cccc-4c6c35)nc3ccccc23)cc1 ; c1ccc(-c2nc3ccccc3nc2-n2c(-c3ccccc3)c3c4c(cccc42)-c2cccc4oc5cccc-3c5c24)cc1]

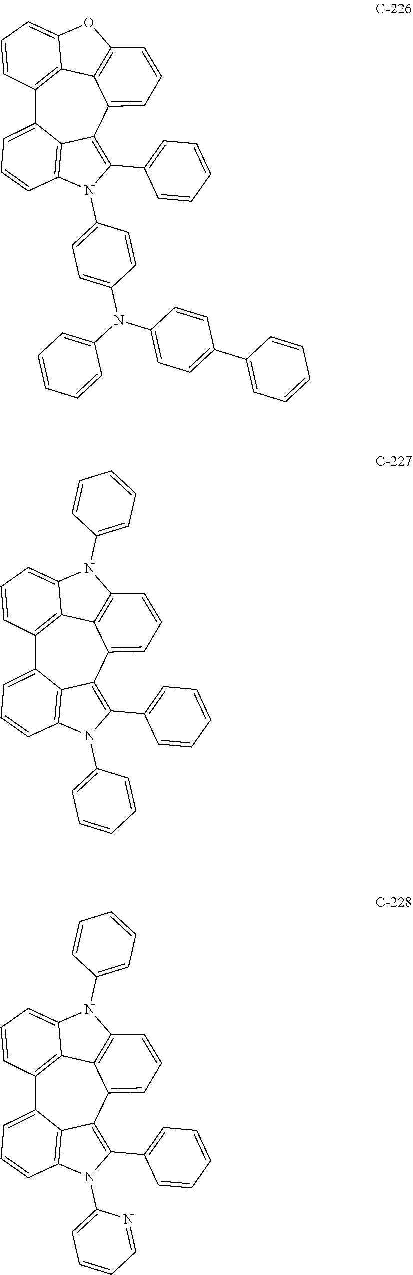 [SMILES: c1ccc(-c2ccc(N(c3ccccc3)c3ccc(-n4c(-c5ccccc5)c5c6c(cccc64)-c4cccc6oc7cccc-5c7c46)cc3)cc2)cc1 ; c1ccc(-c2c3c4c(cccc4n2-c2ccccc2)-c2cccc4c2c2c-3cccc2n4-c2ccccc2)cc1 ; c1ccc(-c2c3c4c(cccc4n2-c2ccccn2)-c2cccc4c2c2c-3cccc2n4-c2ccccc2)cc1]

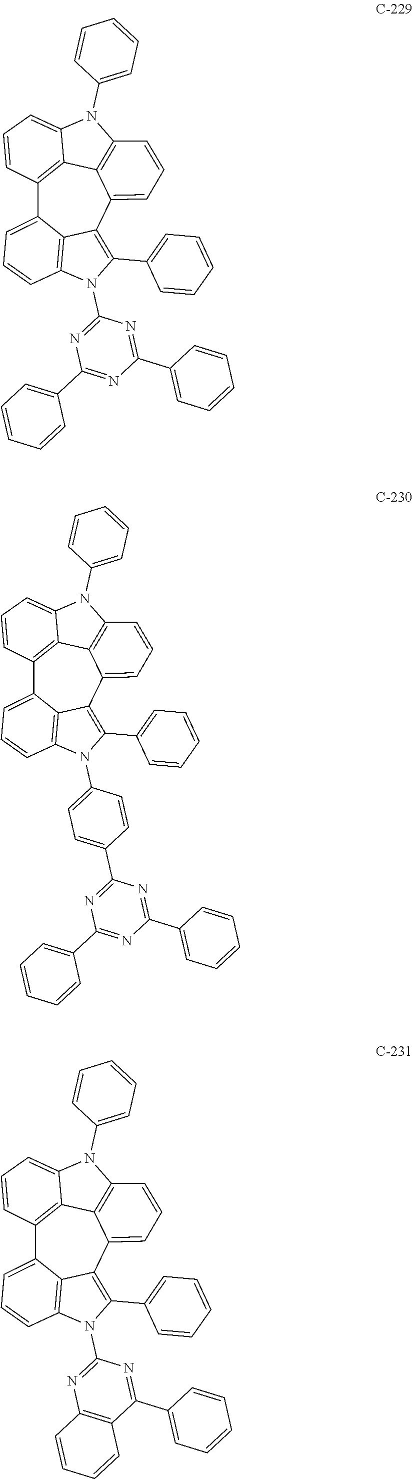 [SMILES: c1ccc(-c2nc(-c3ccccc3)nc(-n3c(-c4ccccc4)c4c5c(cccc53)-c3cccc5c3c3c-4cccc3n5-c3ccccc3)n2)cc1 ; c1ccc(-c2nc(-c3ccccc3)nc(-c3ccc(-n4c(-c5ccccc5)c5c6c(cccc64)-c4cccc6c4c4c-5cccc4n6-c4ccccc4)cc3)n2)cc1 ; c1ccc(-c2nc(-n3c(-c4ccccc4)c4c5c(cccc53)-c3cccc5c3c3c-4cccc3n5-c3ccccc3)nc3ccccc23)cc1]

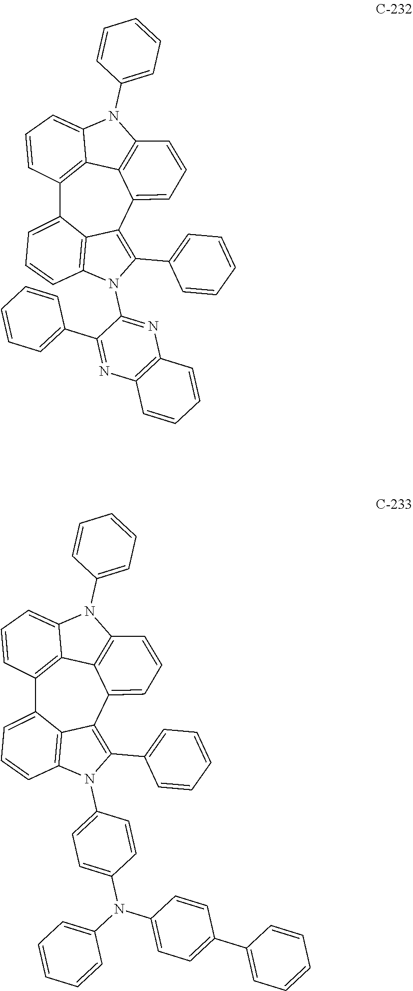 [SMILES: c1ccc(-c2nc3ccccc3nc2-n2c(-c3ccccc3)c3c4c(cccc42)-c2cccc4c2c2c-3cccc2n4-c2ccccc2)cc1 ; c1ccc(-c2ccc(N(c3ccccc3)c3ccc(-n4c(-c5ccccc5)c5c6c(cccc64)-c4cccc6c4c4c-5cccc4n6-c4ccccc4)cc3)cc2)cc1]

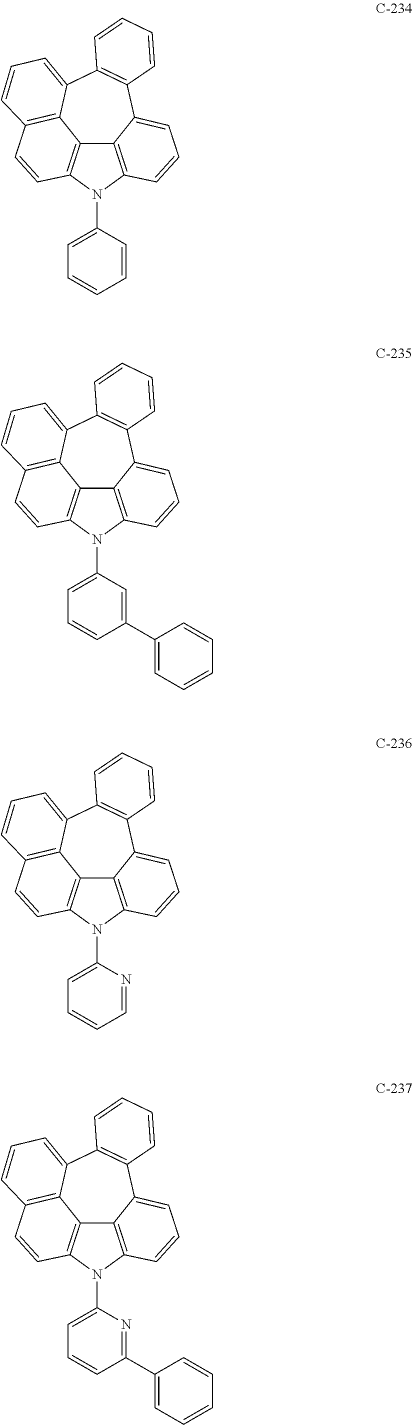 [SMILES: c1ccc(-n2c3cccc4c3c3c5c(cccc5ccc32)-c2ccccc2-4)cc1 ; c1ccc(-c2cccc(-n3c4cccc5c4c4c6c(cccc6ccc43)-c3ccccc3-5)c2)cc1 ; c1ccc(-n2c3cccc4c3c3c5c(cccc5ccc32)-c2ccccc2-4)nc1 ; c1ccc(-c2cccc(-n3c4cccc5c4c4c6c(cccc6ccc43)-c3ccccc3-5)n2)cc1]

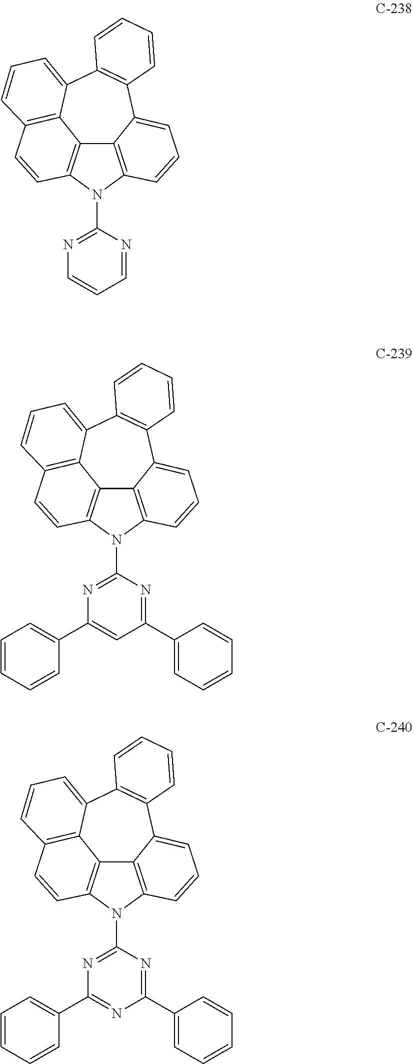 [SMILES: c1cnc(-n2c3cccc4c3c3c5c(cccc5ccc32)-c2ccccc2-4)nc1 ; c1ccc(-c2cc(-c3ccccc3)nc(-n3c4cccc5c4c4c6c(cccc6ccc43)-c3ccccc3-5)n2)cc1 ; c1ccc(-c2nc(-c3ccccc3)nc(-n3c4cccc5c4c4c6c(cccc6ccc43)-c3ccccc3-5)n2)cc1]

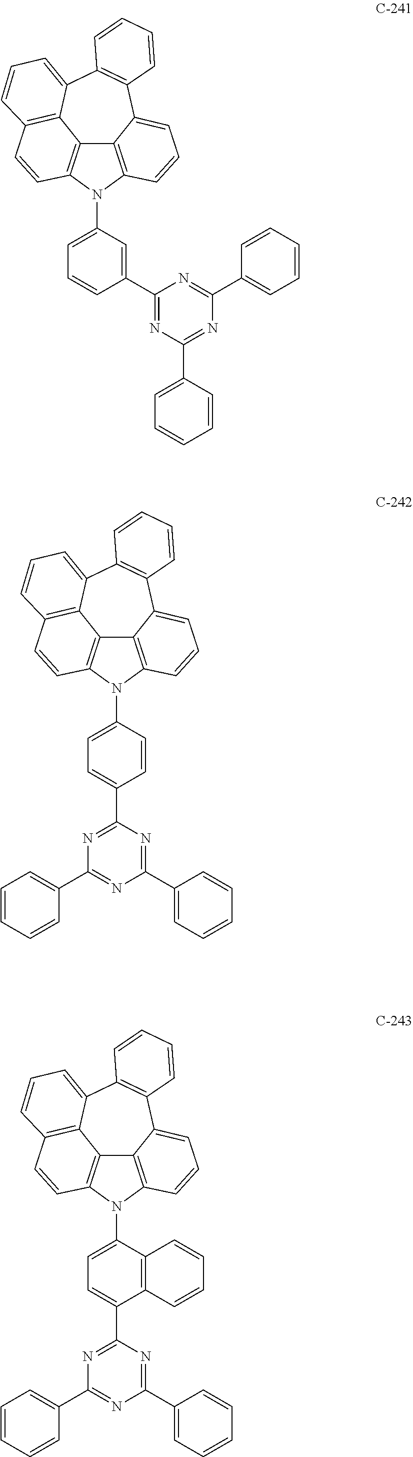 [SMILES: c1ccc(-c2nc(-c3ccccc3)nc(-c3cccc(-n4c5cccc6c5c5c7c(cccc7ccc54)-c4ccccc4-6)c3)n2)cc1 ; c1ccc(-c2nc(-c3ccccc3)nc(-c3ccc(-n4c5cccc6c5c5c7c(cccc7ccc54)-c4ccccc4-6)cc3)n2)cc1 ; c1ccc(-c2nc(-c3ccccc3)nc(-c3ccc(-n4c5cccc6c5c5c7c(cccc7ccc54)-c4ccccc4-6)c4ccccc34)n2)cc1]

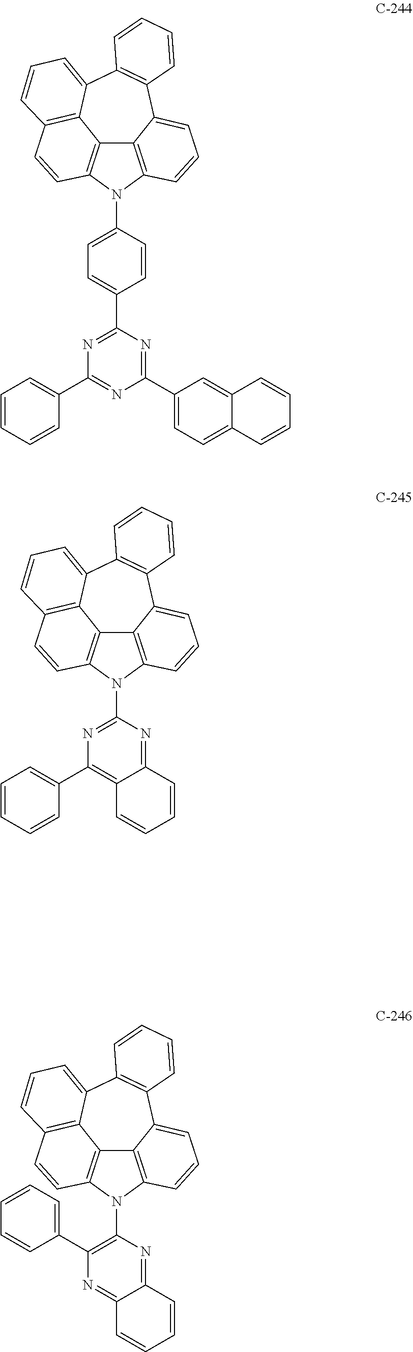 [SMILES: c1ccc(-c2nc(-c3ccc(-n4c5cccc6c5c5c7c(cccc7ccc54)-c4ccccc4-6)cc3)nc(-c3ccc4ccccc4c3)n2)cc1 ; c1ccc(-c2nc(-n3c4cccc5c4c4c6c(cccc6ccc43)-c3ccccc3-5)nc3ccccc23)cc1 ; c1ccc(-c2nc3ccccc3nc2-n2c3cccc4c3c3c5c(cccc5ccc32)-c2ccccc2-4)cc1]

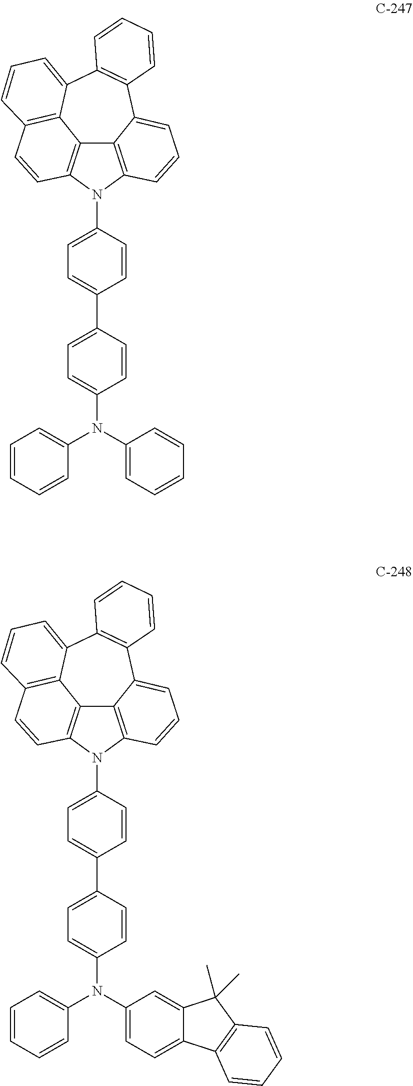 [SMILES: c1ccc(N(c2ccccc2)c2ccc(-c3ccc(-n4c5cccc6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cccc7c6c6c8c(cccc8ccc65)-c5ccccc5-7)cc4)cc3)cc21]

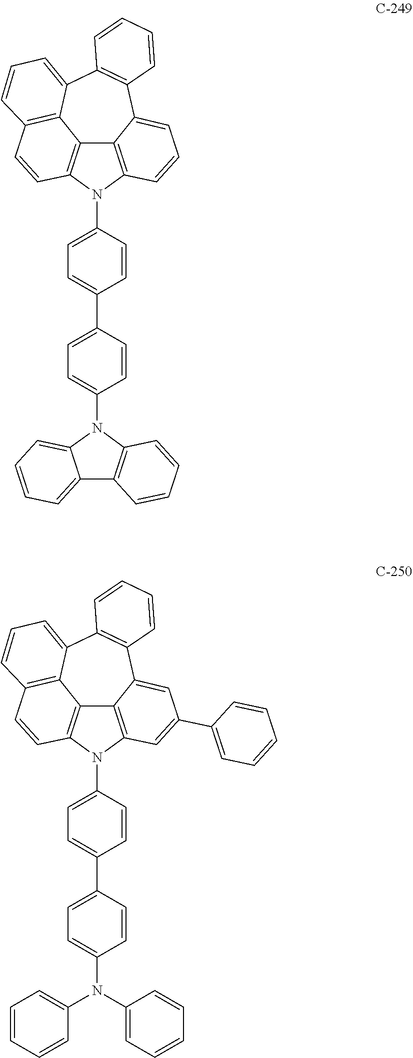 [SMILES: c1ccc2c(c1)-c1cccc3ccc4c(c13)c1c-2cccc1n4-c1ccc(-c2ccc(-n3c4ccccc4c4ccccc43)cc2)cc1 ; c1ccc(-c2cc3c4c5c6c(cccc6ccc5n(-c5ccc(-c6ccc(N(c7ccccc7)c7ccccc7)cc6)cc5)c4c2)-c2ccccc2-3)cc1]

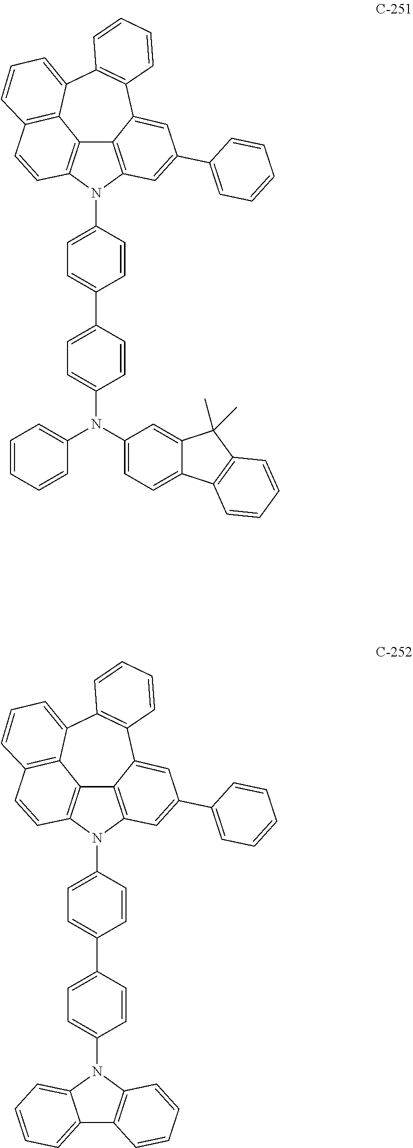 [SMILES: CC1(C)c2ccccc2-c2ccc(N(c3ccccc3)c3ccc(-c4ccc(-n5c6cc(-c7ccccc7)cc7c6c6c8c(cccc8ccc65)-c5ccccc5-7)cc4)cc3)cc21 ; c1ccc(-c2cc3c4c5c6c(cccc6ccc5n(-c5ccc(-c6ccc(-n7c8ccccc8c8ccccc87)cc6)cc5)c4c2)-c2ccccc2-3)cc1]

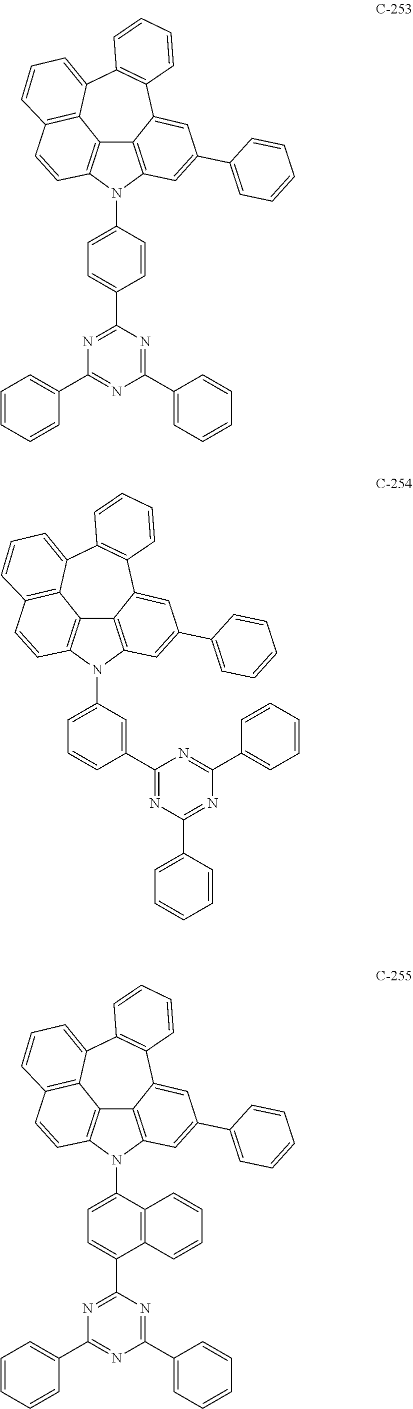 [SMILES: c1ccc(-c2cc3c4c5c6c(cccc6ccc5n(-c5ccc(-c6nc(-c7ccccc7)nc(-c7ccccc7)n6)cc5)c4c2)-c2ccccc2-3)cc1 ; c1ccc(-c2cc3c4c5c6c(cccc6ccc5n(-c5cccc(-c6nc(-c7ccccc7)nc(-c7ccccc7)n6)c5)c4c2)-c2ccccc2-3)cc1 ; c1ccc(-c2cc3c4c5c6c(cccc6ccc5n(-c5ccc(-c6nc(-c7ccccc7)nc(-c7ccccc7)n6)c6ccccc56)c4c2)-c2ccccc2-3)cc1]

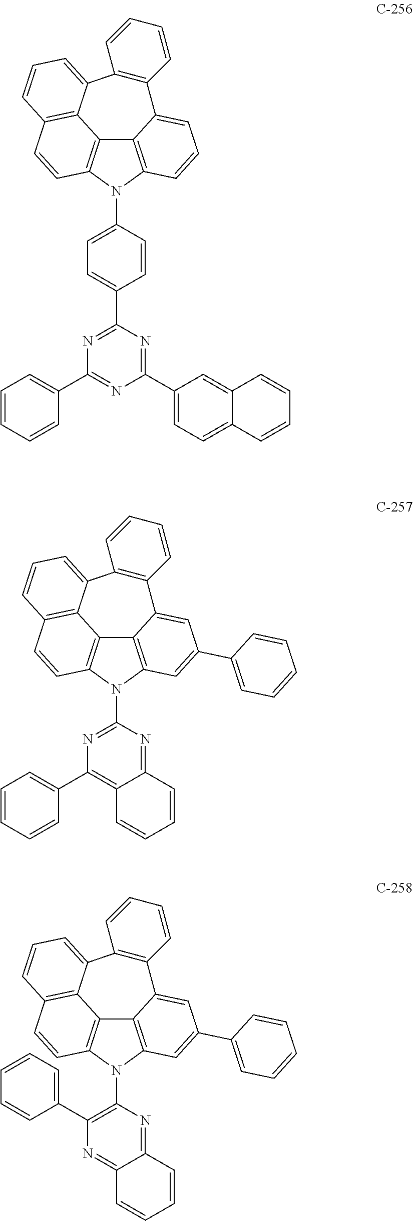 [SMILES: c1ccc(-c2nc(-c3ccc(-n4c5cccc6c5c5c7c(cccc7ccc54)-c4ccccc4-6)cc3)nc(-c3ccc4ccccc4c3)n2)cc1 ; c1ccc(-c2cc3c4c5c6c(cccc6ccc5n(-c5nc(-c6ccccc6)c6ccccc6n5)c4c2)-c2ccccc2-3)cc1 ; c1ccc(-c2cc3c4c5c6c(cccc6ccc5n(-c5nc6ccccc6nc5-c5ccccc5)c4c2)-c2ccccc2-3)cc1]

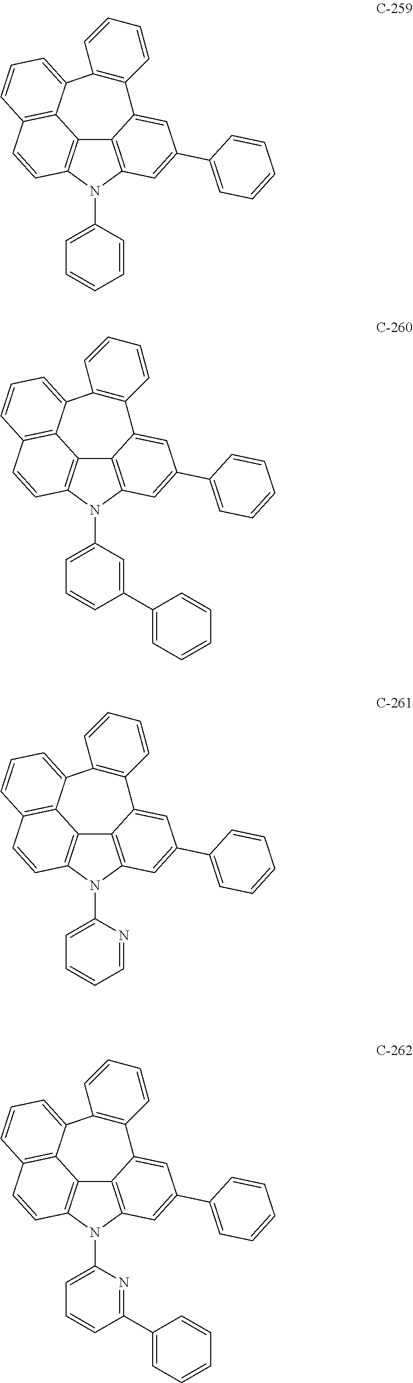 [SMILES: c1ccc(-c2cc3c4c5c6c(cccc6ccc5n(-c5ccccc5)c4c2)-c2ccccc2-3)cc1 ; c1ccc(-c2cccc(-n3c4cc(-c5ccccc5)cc5c4c4c6c(cccc6ccc43)-c3ccccc3-5)c2)cc1 ; c1ccc(-c2cc3c4c5c6c(cccc6ccc5n(-c5ccccn5)c4c2)-c2ccccc2-3)cc1 ; c1ccc(-c2cc3c4c5c6c(cccc6ccc5n(-c5cccc(-c6ccccc6)n5)c4c2)-c2ccccc2-3)cc1]

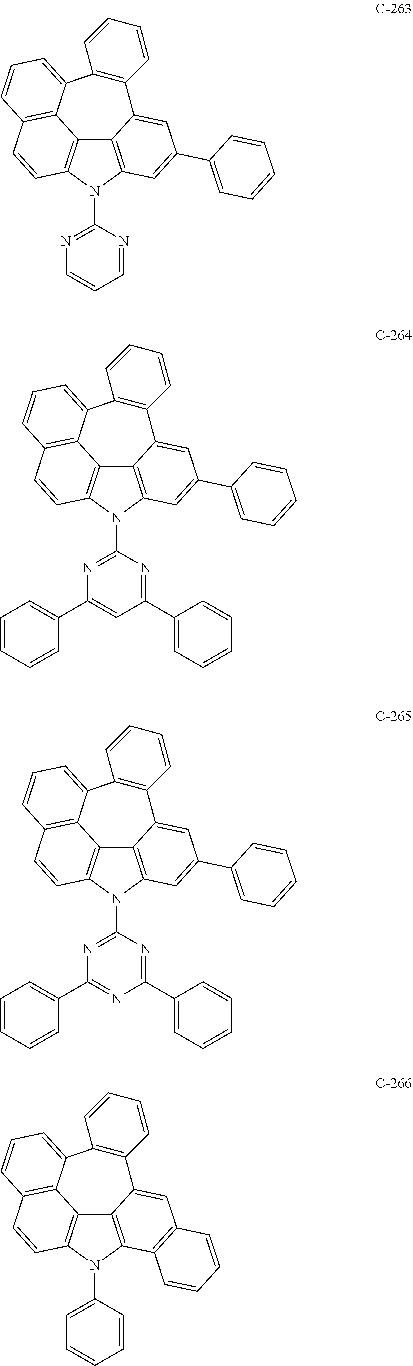 [SMILES: c1ccc(-c2cc3c4c5c6c(cccc6ccc5n(-c5ncccn5)c4c2)-c2ccccc2-3)cc1 ; c1ccc(-c2cc3c4c5c6c(cccc6ccc5n(-c5nc(-c6ccccc6)cc(-c6ccccc6)n5)c4c2)-c2ccccc2-3)cc1 ; c1ccc(-c2cc3c4c5c6c(cccc6ccc5n(-c5nc(-c6ccccc6)nc(-c6ccccc6)n5)c4c2)-c2ccccc2-3)cc1 ; c1ccc(-n2c3ccc4cccc5c4c3c3c(cc4ccccc4c32)-c2ccccc2-5)cc1]

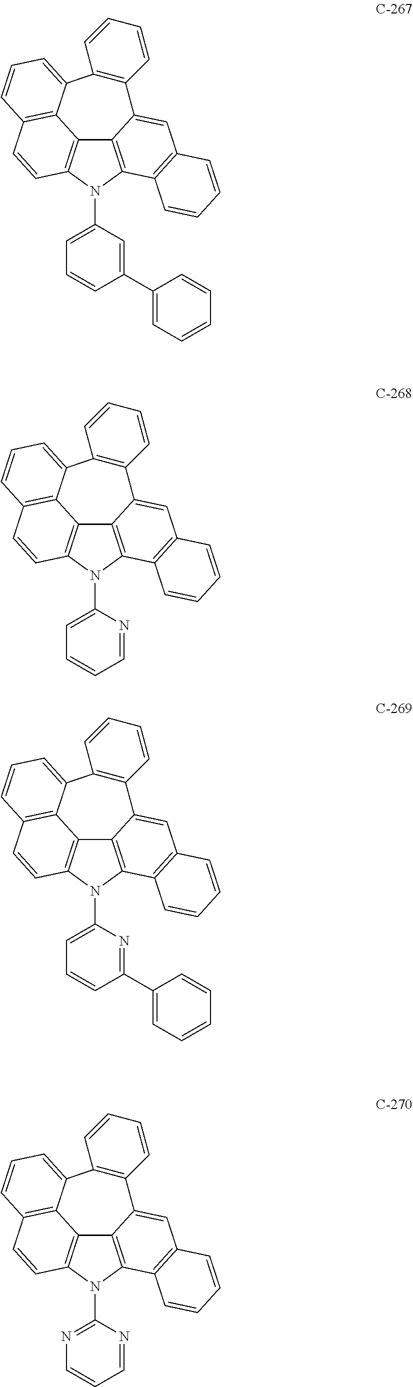

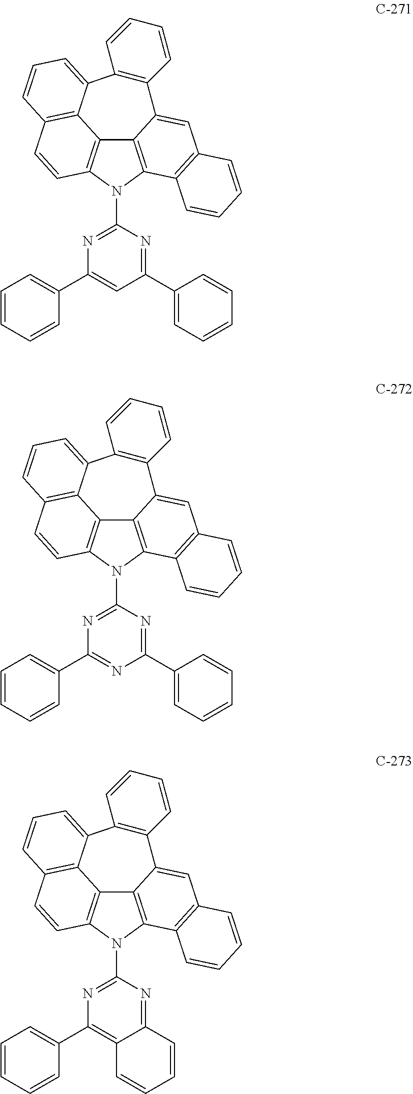 [SMILES: c1ccc(-c2cc(-c3ccccc3)nc(-n3c4ccc5cccc6c5c4c4c(cc5ccccc5c43)-c3ccccc3-6)n2)cc1 ; c1ccc(-c2nc(-c3ccccc3)nc(-n3c4ccc5cccc6c5c4c4c(cc5ccccc5c43)-c3ccccc3-6)n2)cc1 ; c1ccc(-c2nc(-n3c4ccc5cccc6c5c4c4c(cc5ccccc5c43)-c3ccccc3-6)nc3ccccc23)cc1]

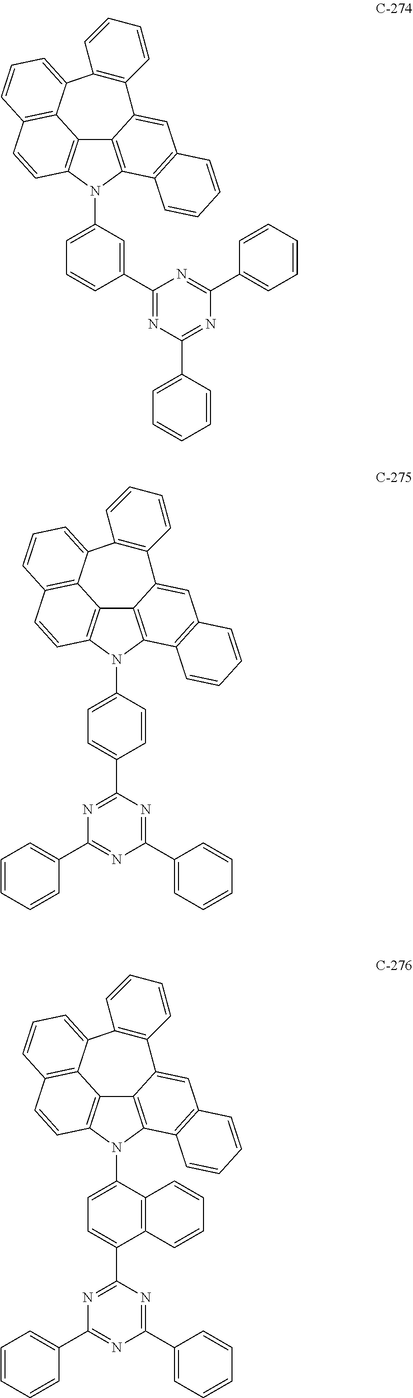 [SMILES: c1ccc(-c2nc(-c3ccccc3)nc(-c3cccc(-n4c5ccc6cccc7c6c5c5c(cc6ccccc6c54)-c4ccccc4-7)c3)n2)cc1 ; c1ccc(-c2nc(-c3ccccc3)nc(-c3ccc(-n4c5ccc6cccc7c6c5c5c(cc6ccccc6c54)-c4ccccc4-7)cc3)n2)cc1 ; c1ccc(-c2nc(-c3ccccc3)nc(-c3ccc(-n4c5ccc6cccc7c6c5c5c(cc6ccccc6c54)-c4ccccc4-7)c4ccccc34)n2)cc1]

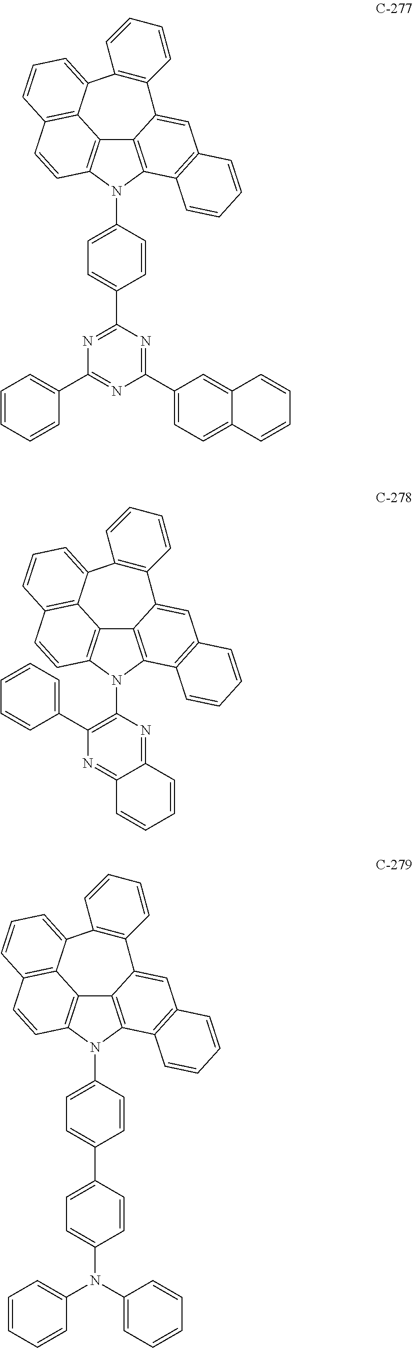 [SMILES: c1ccc(-c2nc(-c3ccc(-n4c5ccc6cccc7c6c5c5c(cc6ccccc6c54)-c4ccccc4-7)cc3)nc(-c3ccc4ccccc4c3)n2)cc1 ; c1ccc(-c2nc3ccccc3nc2-n2c3ccc4cccc5c4c3c3c(cc4ccccc4c32)-c2ccccc2-5)cc1 ; c1ccc(N(c2ccccc2)c2ccc(-c3ccc(-n4c5ccc6cccc7c6c5c5c(cc6ccccc6c54)-c4ccccc4-7)cc3)cc2)cc1]

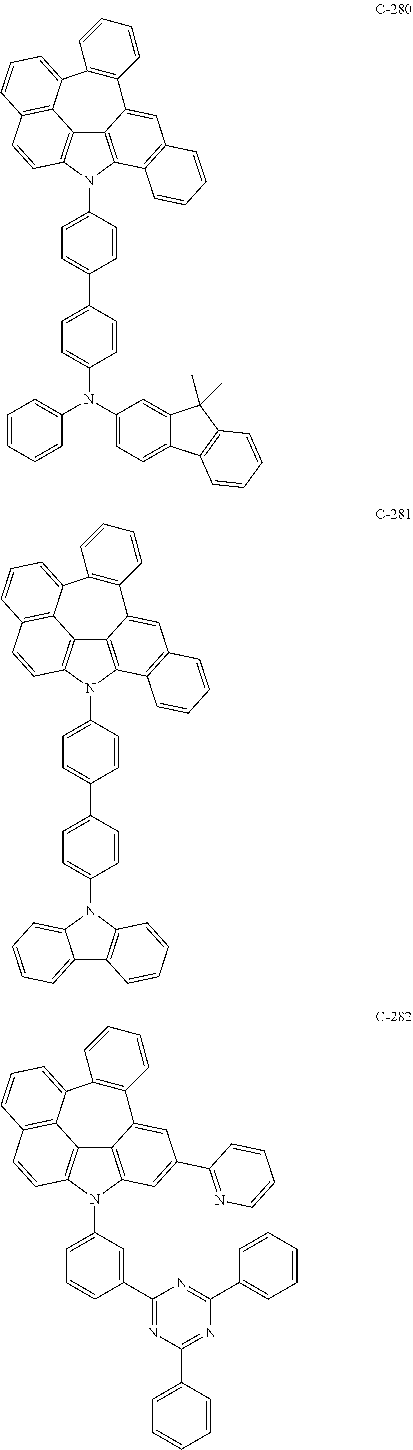 [SMILES: CC1(C)c2ccccc2-c2ccc(N(c3ccccc3)c3ccc(-c4ccc(-n5c6ccc7cccc8c7c6c6c(cc7ccccc7c65)-c5ccccc5-8)cc4)cc3)cc21 ; c1ccc2c(c1)-c1cccc3ccc4c(c13)c1c-2cc2ccccc2c1n4-c1ccc(-c2ccc(-n3c4ccccc4c4ccccc43)cc2)cc1 ; c1ccc(-c2nc(-c3ccccc3)nc(-c3cccc(-n4c5cc(-c6ccccn6)cc6c5c5c7c(cccc7ccc54)-c4ccccc4-6)c3)n2)cc1]

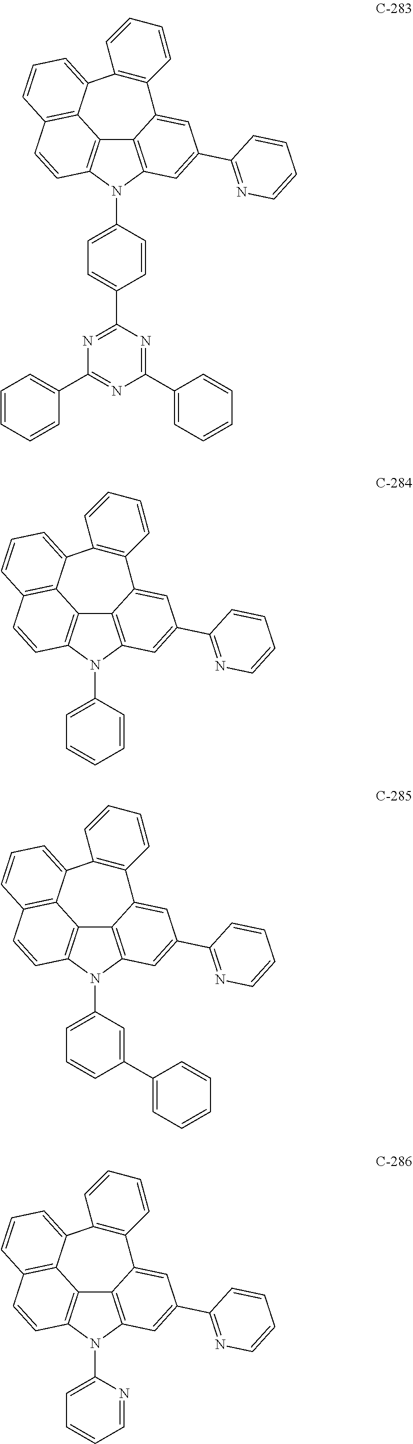

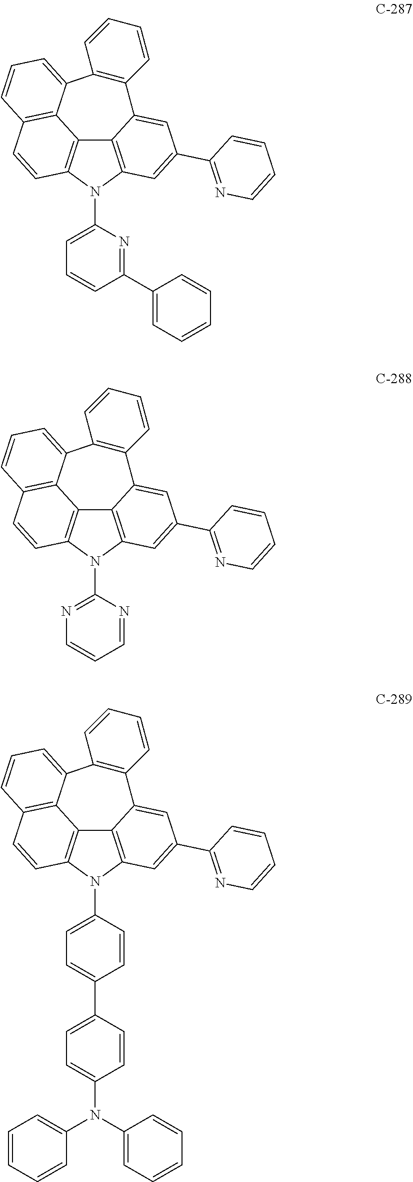 [SMILES: c1ccc(-c2cccc(-n3c4cc(-c5ccccn5)cc5c4c4c6c(cccc6ccc43)-c3ccccc3-5)n2)cc1 ; c1ccc(-c2cc3c4c5c6c(cccc6ccc5n(-c5ncccn5)c4c2)-c2ccccc2-3)nc1 ; c1ccc(N(c2ccccc2)c2ccc(-c3ccc(-n4c5cc(-c6ccccn6)cc6c5c5c7c(cccc7ccc54)-c4ccccc4-6)cc3)cc2)cc1]

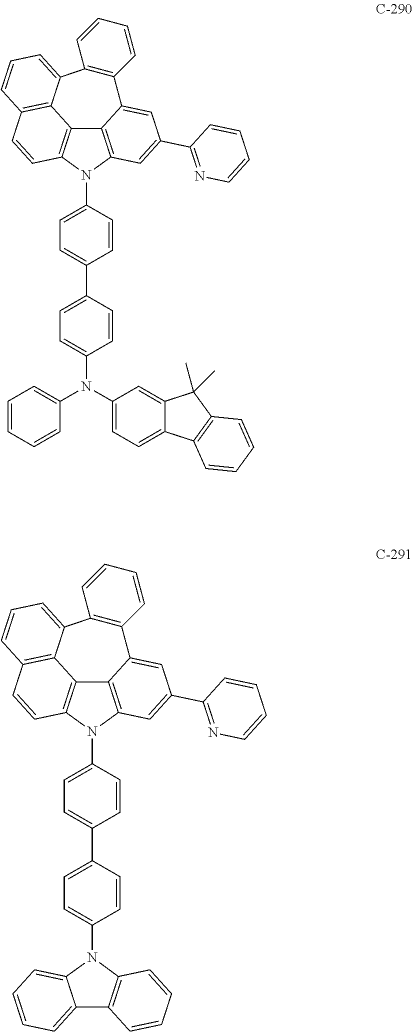 [SMILES: CC1(C)c2ccccc2-c2ccc(N(c3ccccc3)c3ccc(-c4ccc(-n5c6cc(-c7ccccn7)cc7c6c6c8c(cccc8ccc65)-c5ccccc5-7)cc4)cc3)cc21 ; c1ccc(-c2cc3c4c5c6c(cccc6ccc5n(-c5ccc(-c6ccc(-n7c8ccccc8c8ccccc87)cc6)cc5)c4c2)-c2ccccc2-3)nc1]

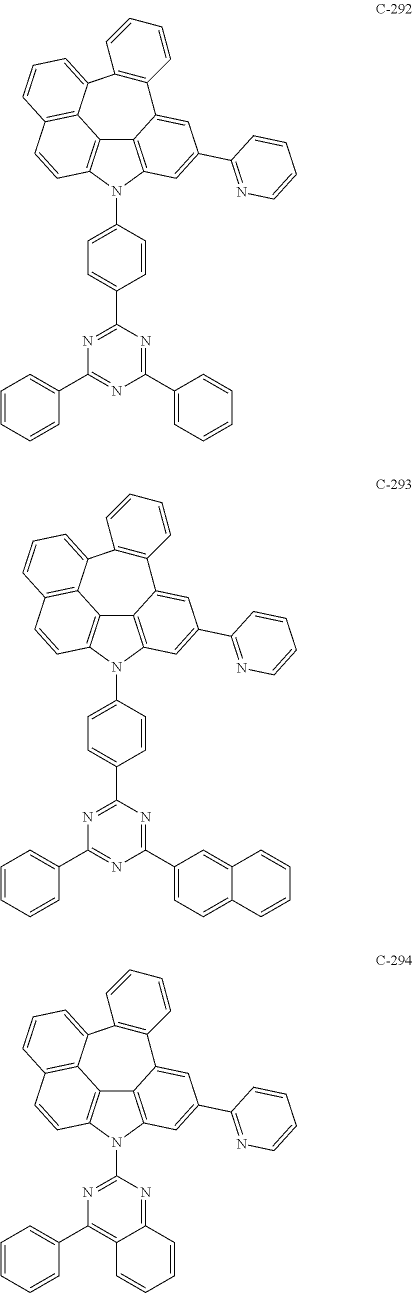 [SMILES: c1ccc(-c2nc(-c3ccccc3)nc(-c3ccc(-n4c5cc(-c6ccccn6)cc6c5c5c7c(cccc7ccc54)-c4ccccc4-6)cc3)n2)cc1 ; c1ccc(-c2nc(-c3ccc(-n4c5cc(-c6ccccn6)cc6c5c5c7c(cccc7ccc54)-c4ccccc4-6)cc3)nc(-c3ccc4ccccc4c3)n2)cc1 ; c1ccc(-c2nc(-n3c4cc(-c5ccccn5)cc5c4c4c6c(cccc6ccc43)-c3ccccc3-5)nc3ccccc23)cc1]

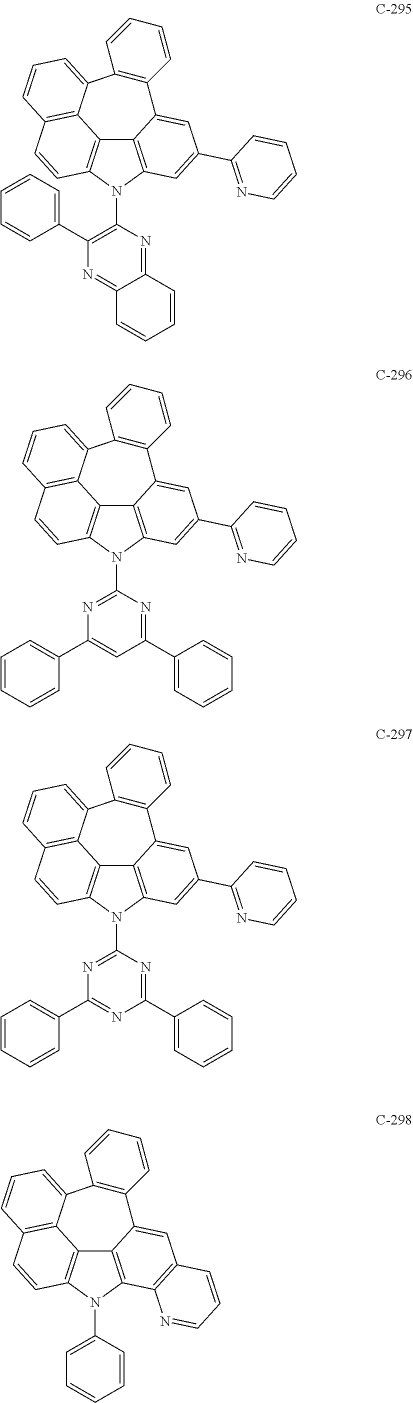

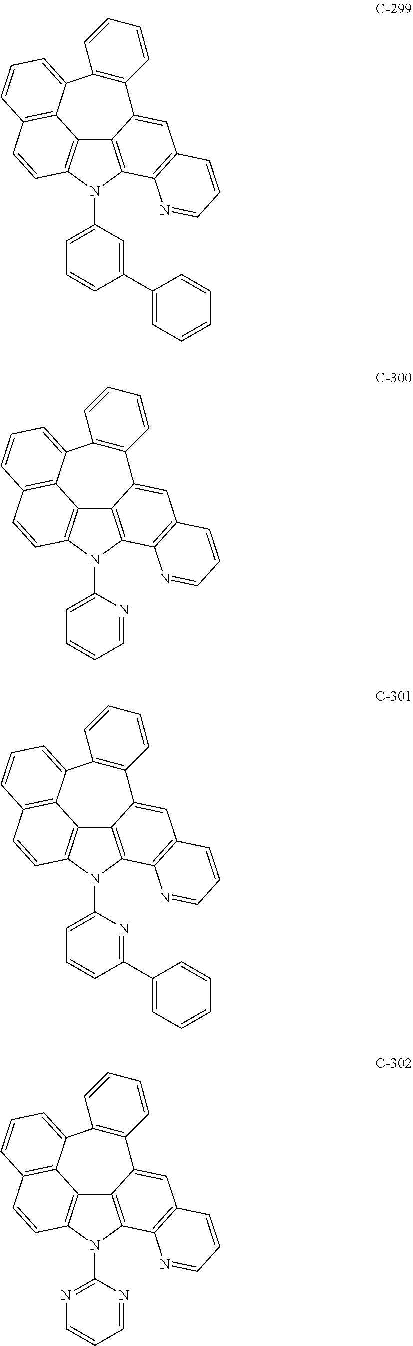 [SMILES: c1ccc(-c2cccc(-n3c4ccc5cccc6c5c4c4c(cc5cccnc5c43)-c3ccccc3-6)c2)cc1 ; c1ccc(-n2c3ccc4cccc5c4c3c3c(cc4cccnc4c32)-c2ccccc2-5)nc1 ; c1ccc(-c2cccc(-n3c4ccc5cccc6c5c4c4c(cc5cccnc5c43)-c3ccccc3-6)n2)cc1 ; c1cnc(-n2c3ccc4cccc5c4c3c3c(cc4cccnc4c32)-c2ccccc2-5)nc1]

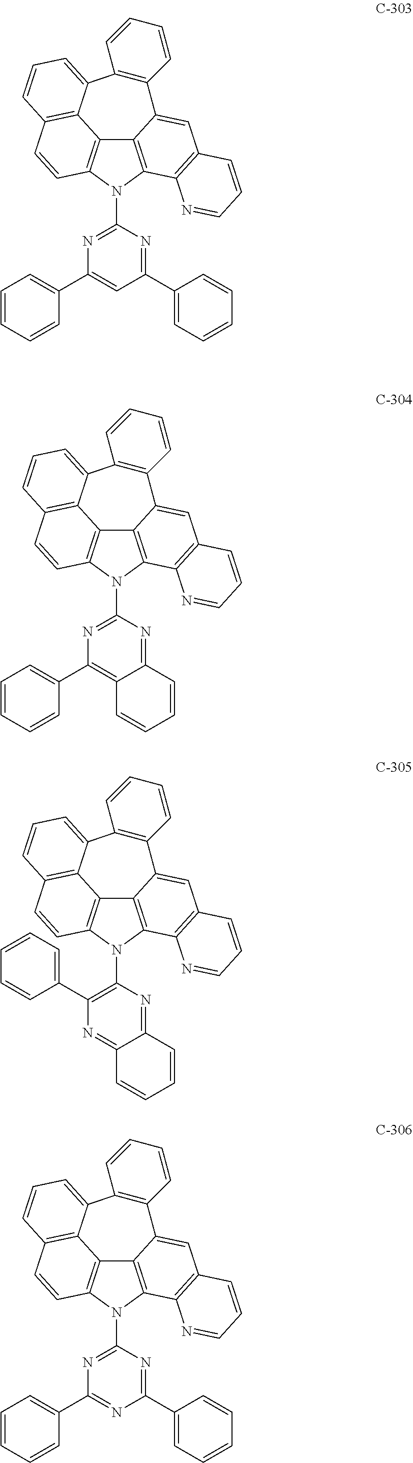

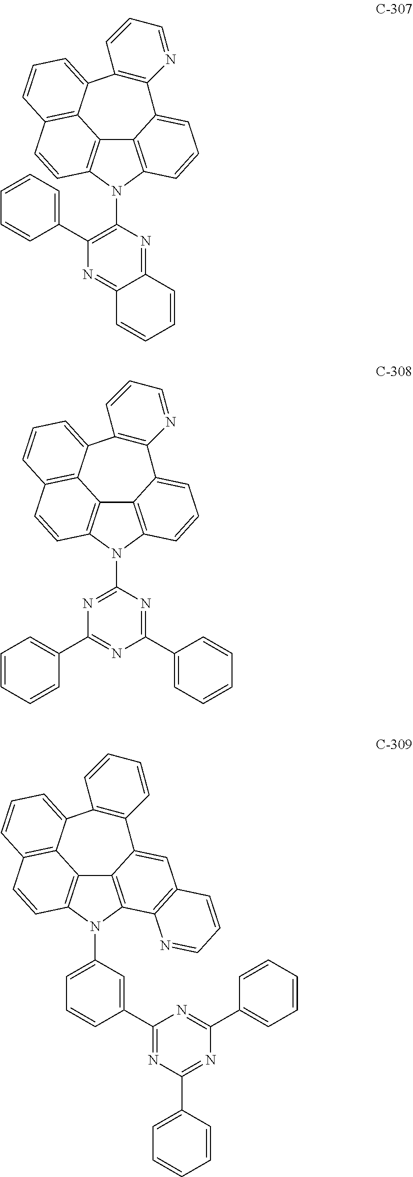

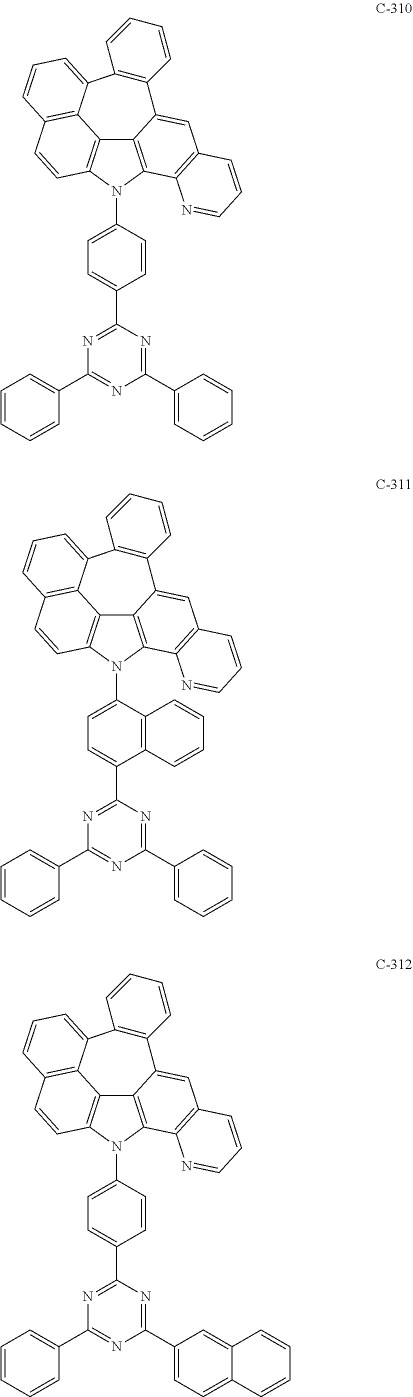 [SMILES: c1ccc(-c2nc(-c3ccccc3)nc(-c3ccc(-n4c5ccc6cccc7c6c5c5c(cc6cccnc6c54)-c4ccccc4-7)cc3)n2)cc1 ; c1ccc(-c2nc(-c3ccccc3)nc(-c3ccc(-n4c5ccc6cccc7c6c5c5c(cc6cccnc6c54)-c4ccccc4-7)c4ccccc34)n2)cc1 ; c1ccc(-c2nc(-c3ccc(-n4c5ccc6cccc7c6c5c5c(cc6cccnc6c54)-c4ccccc4-7)cc3)nc(-c3ccc4ccccc4c3)n2)cc1]

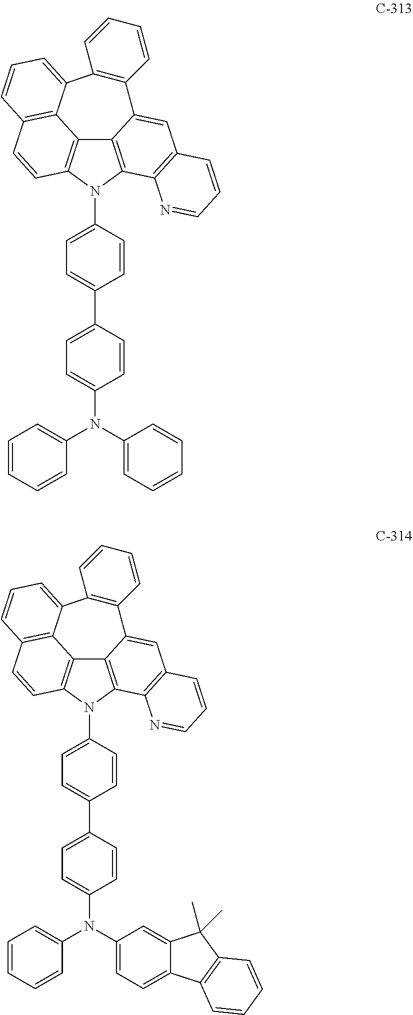 [SMILES: c1ccc(N(c2ccccc2)c2ccc(-c3ccc(-n4c5ccc6cccc7c6c5c5c(cc6cccnc6c54)-c4ccccc4-7)cc3)cc2)cc1 ; CC1(C)c2ccccc2-c2ccc(N(c3ccccc3)c3ccc(-c4ccc(-n5c6ccc7cccc8c7c6c6c(cc7cccnc7c65)-c5ccccc5-8)cc4)cc3)cc21]

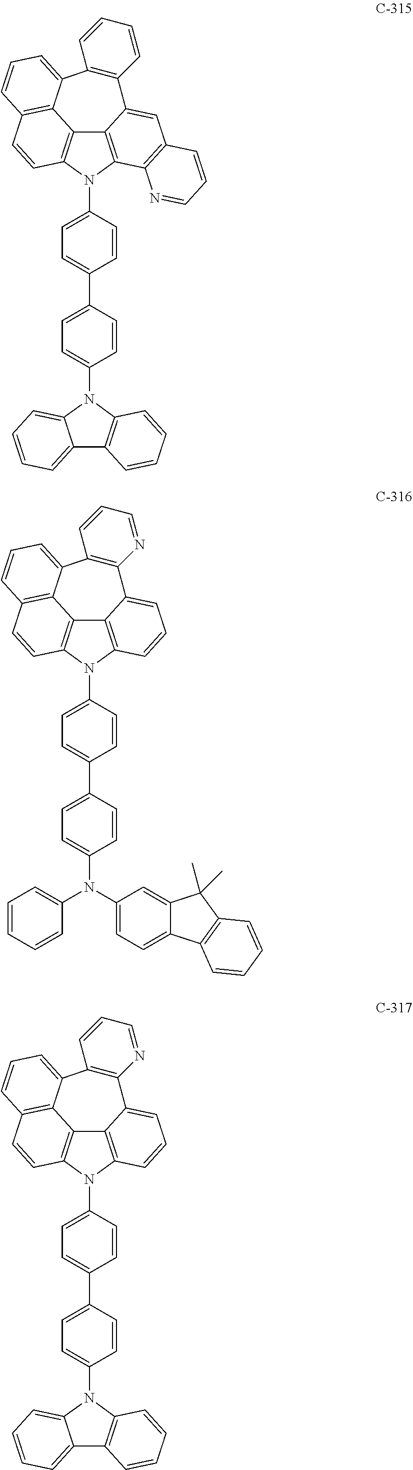

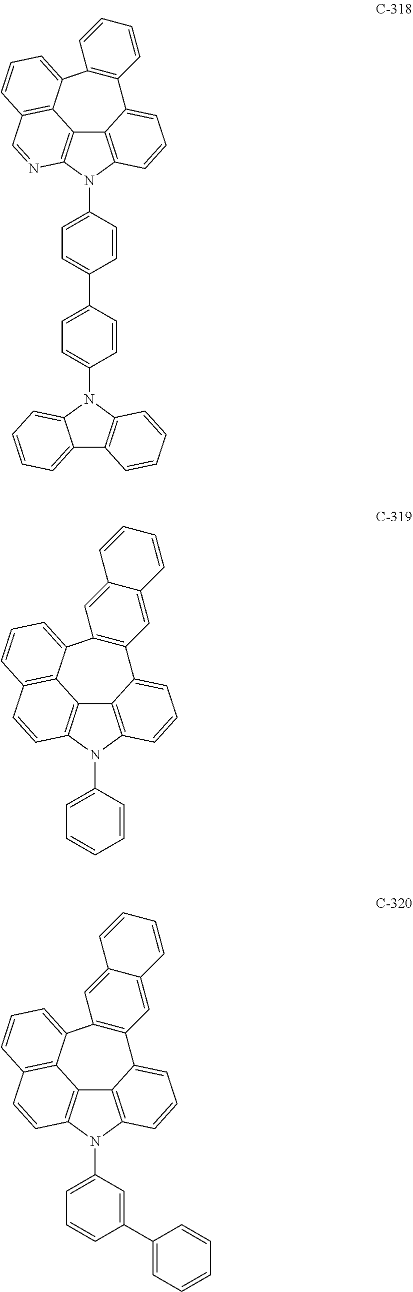 [SMILES: c1ccc2c(c1)-c1cccc3cnc4c(c13)c1c-2cccc1n4-c1ccc(-c2ccc(-n3c4ccccc4c4ccccc43)cc2)cc1 ; c1ccc(-n2c3cccc4c3c3c5c(cccc5ccc32)-c2cc3ccccc3cc2-4)cc1 ; c1ccc(-c2cccc(-n3c4cccc5c4c4c6c(cccc6ccc43)-c3cc4ccccc4cc3-5)c2)cc1]

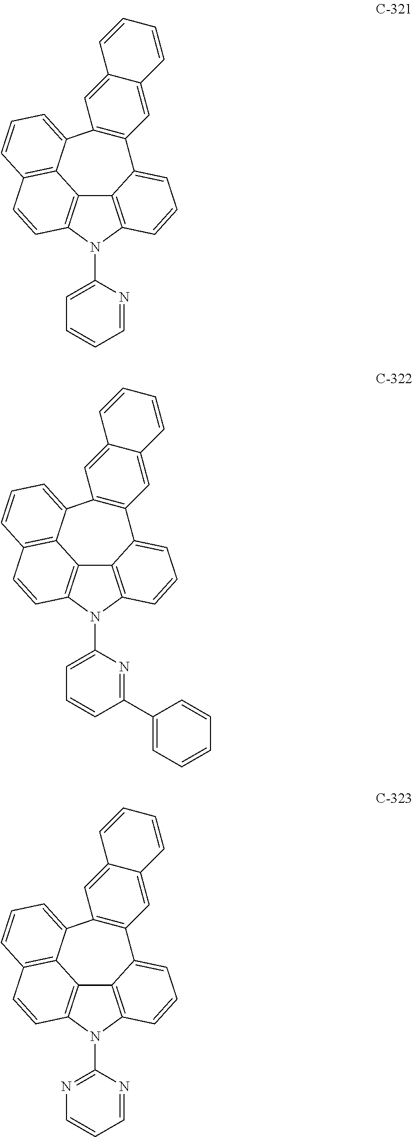 [SMILES: c1ccc(-n2c3cccc4c3c3c5c(cccc5ccc32)-c2cc3ccccc3cc2-4)nc1 ; c1ccc(-c2cccc(-n3c4cccc5c4c4c6c(cccc6ccc43)-c3cc4ccccc4cc3-5)n2)cc1 ; c1cnc(-n2c3cccc4c3c3c5c(cccc5ccc32)-c2cc3ccccc3cc2-4)nc1]

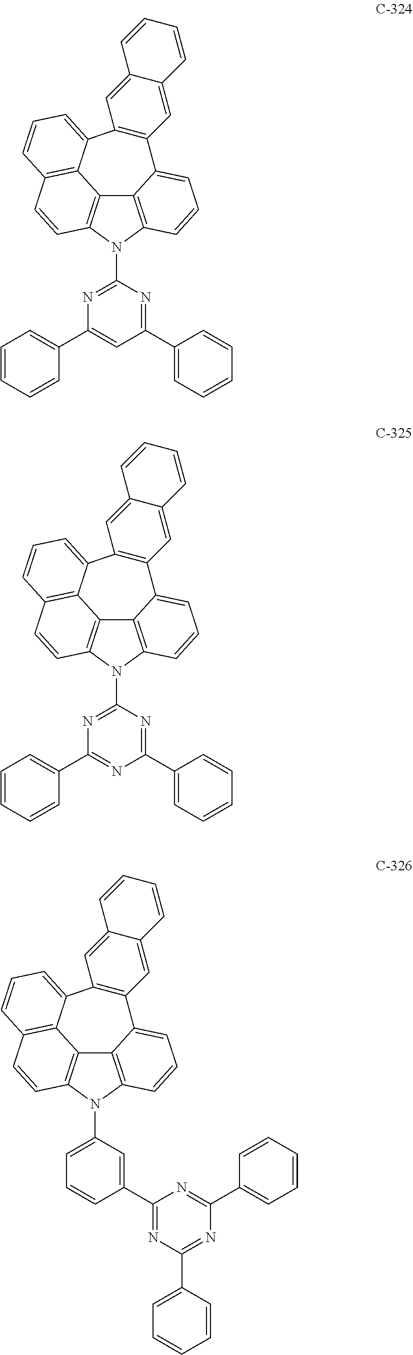 [SMILES: c1ccc(-c2cc(-c3ccccc3)nc(-n3c4cccc5c4c4c6c(cccc6ccc43)-c3cc4ccccc4cc3-5)n2)cc1 ; c1ccc(-c2nc(-c3ccccc3)nc(-n3c4cccc5c4c4c6c(cccc6ccc43)-c3cc4ccccc4cc3-5)n2)cc1 ; c1ccc(-c2nc(-c3ccccc3)nc(-c3cccc(-n4c5cccc6c5c5c7c(cccc7ccc54)-c4cc5ccccc5cc4-6)c3)n2)cc1]

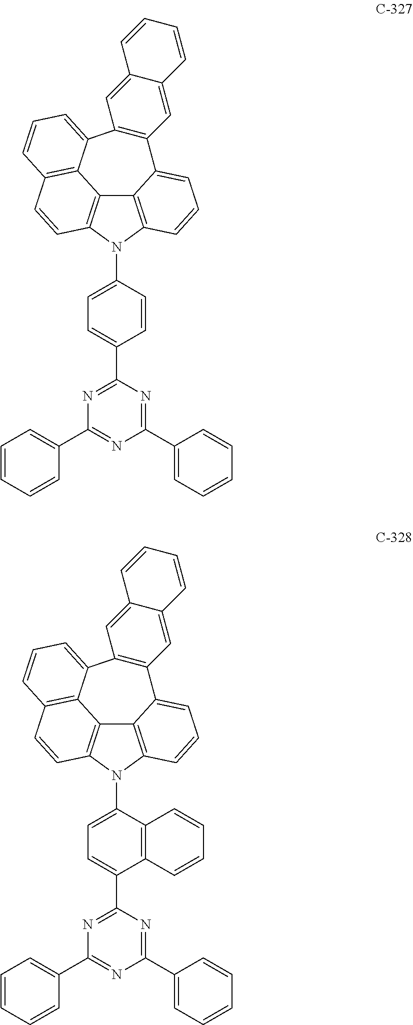 [SMILES: c1ccc(-c2nc(-c3ccccc3)nc(-c3ccc(-n4c5cccc6c5c5c7c(cccc7ccc54)-c4cc5ccccc5cc4-6)cc3)n2)cc1 ; c1ccc(-c2nc(-c3ccccc3)nc(-c3ccc(-n4c5cccc6c5c5c7c(cccc7ccc54)-c4cc5ccccc5cc4-6)c4ccccc34)n2)cc1]

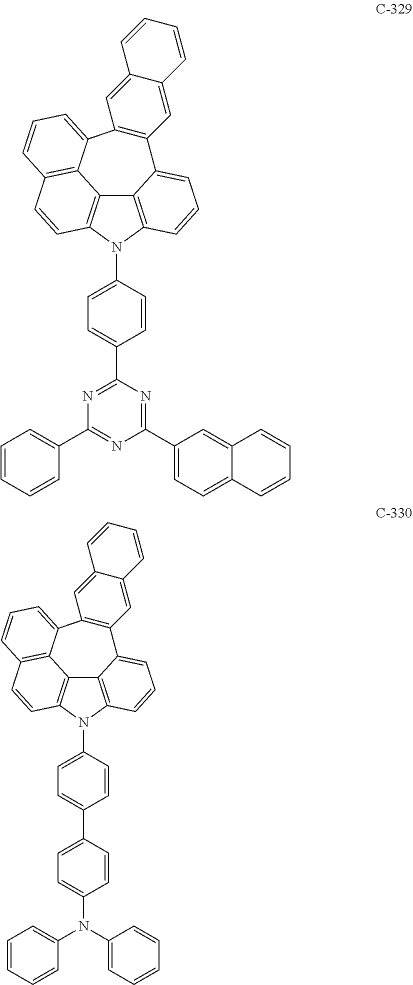 [SMILES: c1ccc(-c2nc(-c3ccc(-n4c5cccc6c5c5c7c(cccc7ccc54)-c4cc5ccccc5cc4-6)cc3)nc(-c3ccc4ccccc4c3)n2)cc1 ; c1ccc(N(c2ccccc2)c2ccc(-c3ccc(-n4c5cccc6c5c5c7c(cccc7ccc54)-c4cc5ccccc5cc4-6)cc3)cc2)cc1]

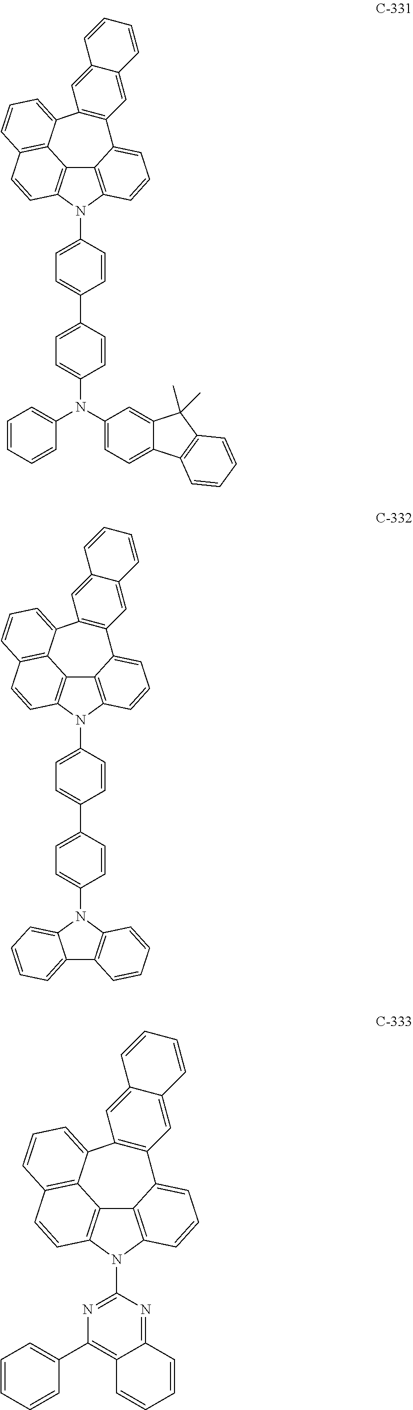 [SMILES: CC1(C)c2ccccc2-c2ccc(N(c3ccccc3)c3ccc(-c4ccc(-n5c6cccc7c6c6c8c(cccc8ccc65)-c5cc6ccccc6cc5-7)cc4)cc3)cc21 ; c1ccc2cc3c(cc2c1)-c1cccc2ccc4c(c12)c1c-3cccc1n4-c1ccc(-c2ccc(-n3c4ccccc4c4ccccc43)cc2)cc1 ; c1ccc(-c2nc(-n3c4cccc5c4c4c6c(cccc6ccc43)-c3cc4ccccc4cc3-5)nc3ccccc23)cc1]

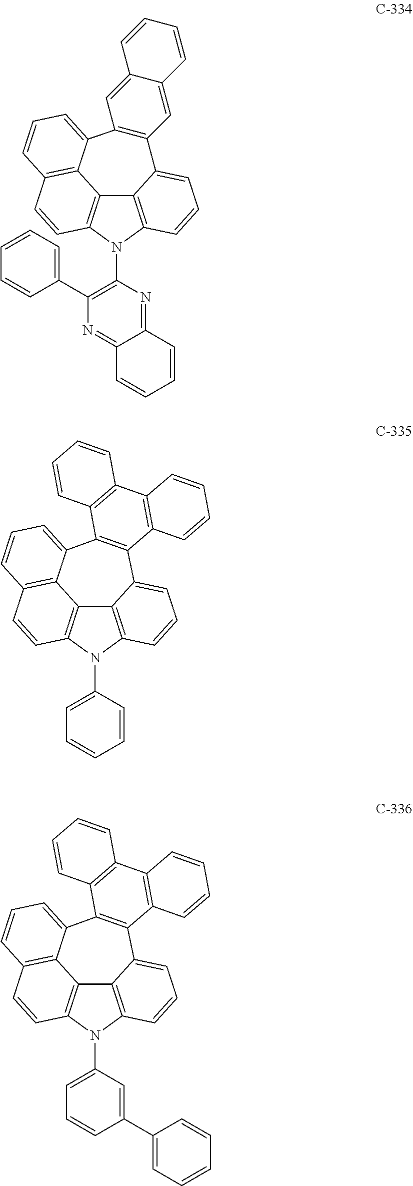 [SMILES: c1ccc(-c2nc3ccccc3nc2-n2c3cccc4c3c3c5c(cccc5ccc32)-c2cc3ccccc3cc2-4)cc1 ; c1ccc(-n2c3cccc4c3c3c5c(cccc5ccc32)-c2c-4c3ccccc3c3ccccc23)cc1 ; c1ccc(-c2cccc(-n3c4cccc5c4c4c6c(cccc6ccc43)-c3c-5c4ccccc4c4ccccc34)c2)cc1]

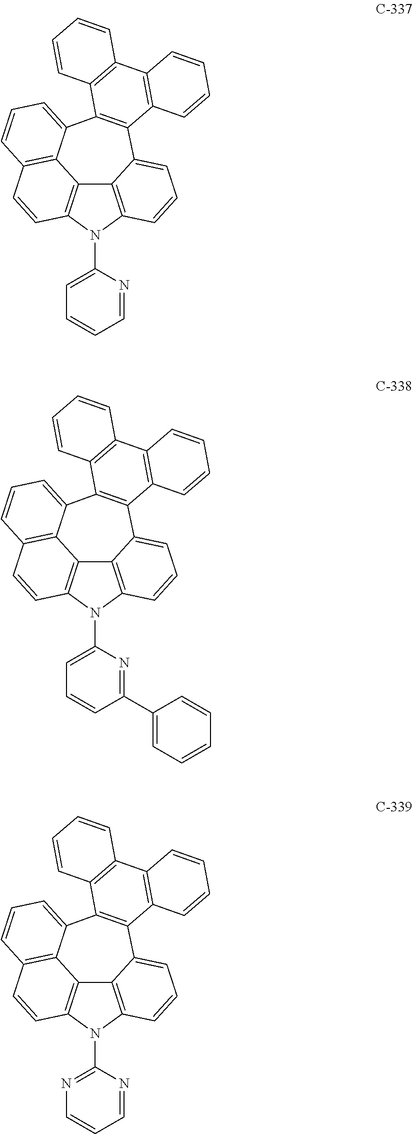 [SMILES: c1ccc(-n2c3cccc4c3c3c5c(cccc5ccc32)-c2c-4c3ccccc3c3ccccc23)nc1 ; c1ccc(-c2cccc(-n3c4cccc5c4c4c6c(cccc6ccc43)-c3c-5c4ccccc4c4ccccc34)n2)cc1 ; c1cnc(-n2c3cccc4c3c3c5c(cccc5ccc32)-c2c-4c3ccccc3c3ccccc23)nc1]

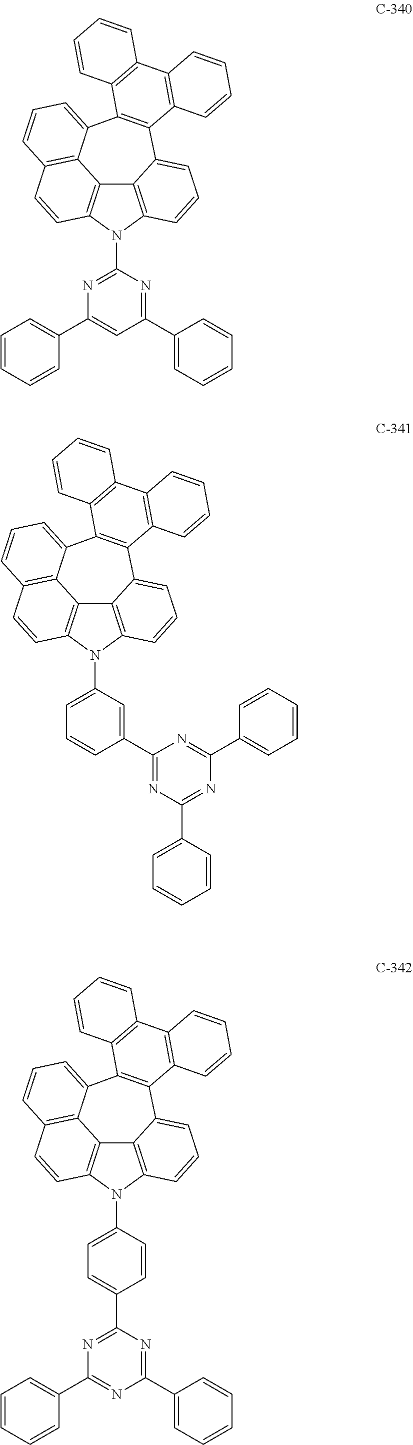 [SMILES: c1ccc(-c2cc(-c3ccccc3)nc(-n3c4cccc5c4c4c6c(cccc6ccc43)-c3c-5c4ccccc4c4ccccc34)n2)cc1 ; c1ccc(-c2nc(-c3ccccc3)nc(-c3cccc(-n4c5cccc6c5c5c7c(cccc7ccc54)-c4c-6c5ccccc5c5ccccc45)c3)n2)cc1 ; c1ccc(-c2nc(-c3ccccc3)nc(-c3ccc(-n4c5cccc6c5c5c7c(cccc7ccc54)-c4c-6c5ccccc5c5ccccc45)cc3)n2)cc1]

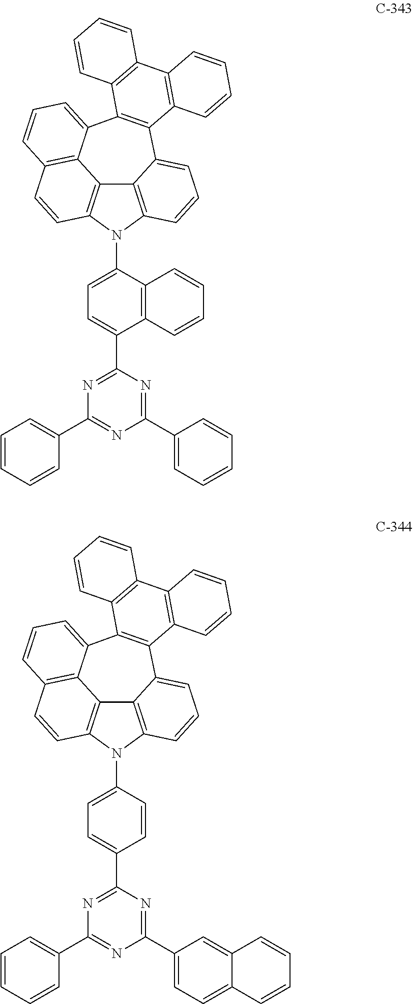 [SMILES: c1ccc(-c2nc(-c3ccccc3)nc(-c3ccc(-n4c5cccc6c5c5c7c(cccc7ccc54)-c4c-6c5ccccc5c5ccccc45)c4ccccc34)n2)cc1 ; c1ccc(-c2nc(-c3ccc(-n4c5cccc6c5c5c7c(cccc7ccc54)-c4c-6c5ccccc5c5ccccc45)cc3)nc(-c3ccc4ccccc4c3)n2)cc1]

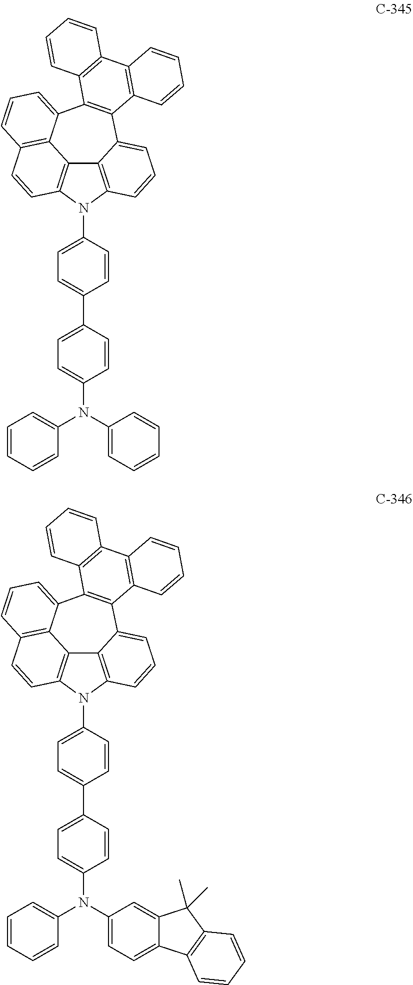 [SMILES: c1ccc(N(c2ccccc2)c2ccc(-c3ccc(-n4c5cccc6c5c5c7c(cccc7ccc54)-c4c-6c5ccccc5c5ccccc45)cc3)cc2)cc1 ; CC1(C)c2ccccc2-c2ccc(N(c3ccccc3)c3ccc(-c4ccc(-n5c6cccc7c6c6c8c(cccc8ccc65)-c5c-7c6ccccc6c6ccccc56)cc4)cc3)cc21]

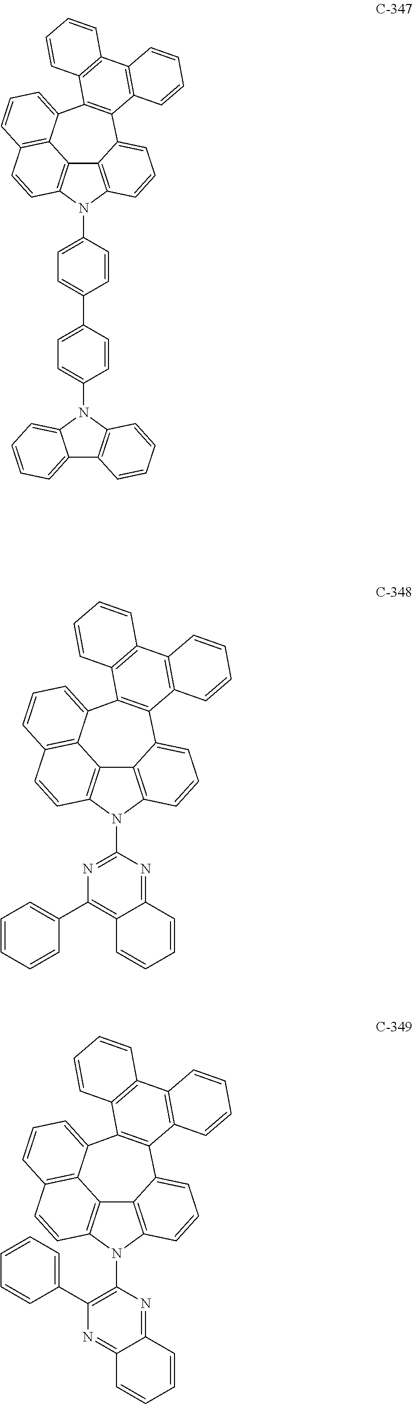 [SMILES: c1cc2c3c(c1)ccc1c3c3c(cccc3n1-c1ccc(-c3ccc(-n4c5ccccc5c5ccccc54)cc3)cc1)-c1c-2c2ccccc2c2ccccc12 ; c1ccc(-c2nc(-n3c4cccc5c4c4c6c(cccc6ccc43)-c3c-5c4ccccc4c4ccccc34)nc3ccccc23)cc1 ; c1ccc(-c2nc3ccccc3nc2-n2c3cccc4c3c3c5c(cccc5ccc32)-c2c-4c3ccccc3c3ccccc23)cc1]

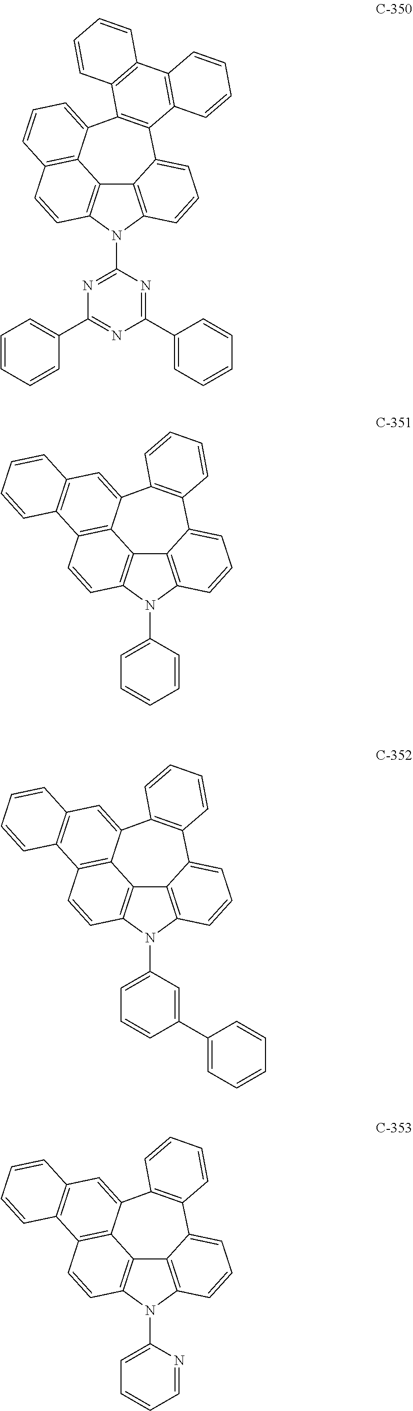 [SMILES: c1ccc(-c2nc(-c3ccccc3)nc(-n3c4cccc5c4c4c6c(cccc6ccc43)-c3c-5c4ccccc4c4ccccc34)n2)cc1 ; c1ccc(-n2c3cccc4c3c3c5c(cc6ccccc6c5ccc32)-c2ccccc2-4)cc1 ; c1ccc(-c2cccc(-n3c4cccc5c4c4c6c(cc7ccccc7c6ccc43)-c3ccccc3-5)c2)cc1 ; c1ccc(-n2c3cccc4c3c3c5c(cc6ccccc6c5ccc32)-c2ccccc2-4)nc1]

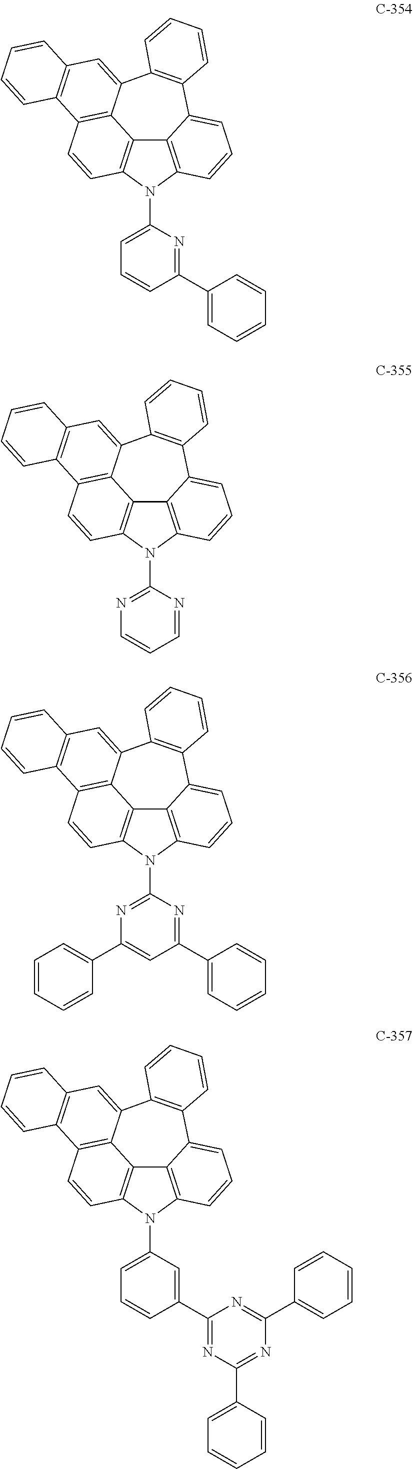

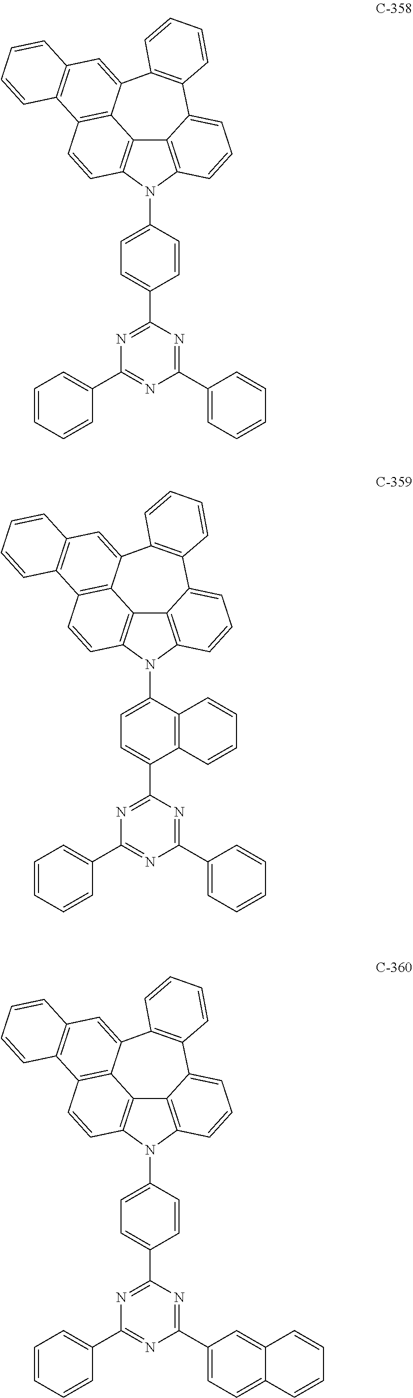 [SMILES: c1ccc(-c2nc(-c3ccccc3)nc(-c3ccc(-n4c5cccc6c5c5c7c(cc8ccccc8c7ccc54)-c4ccccc4-6)cc3)n2)cc1 ; c1ccc(-c2nc(-c3ccccc3)nc(-c3ccc(-n4c5cccc6c5c5c7c(cc8ccccc8c7ccc54)-c4ccccc4-6)c4ccccc34)n2)cc1 ; c1ccc(-c2nc(-c3ccc(-n4c5cccc6c5c5c7c(cc8ccccc8c7ccc54)-c4ccccc4-6)cc3)nc(-c3ccc4ccccc4c3)n2)cc1]

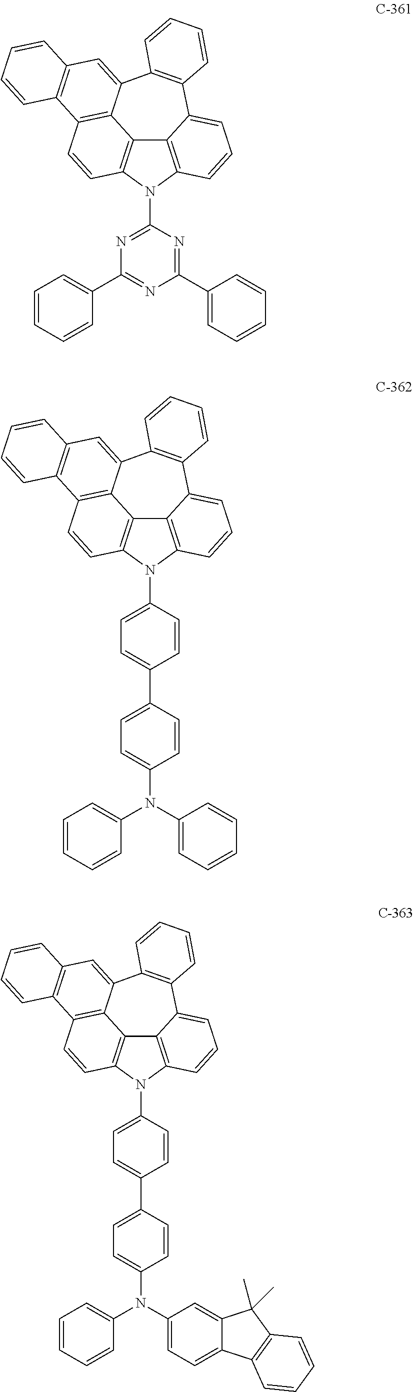 [SMILES: c1ccc(-c2nc(-c3ccccc3)nc(-n3c4cccc5c4c4c6c(cc7ccccc7c6ccc43)-c3ccccc3-5)n2)cc1 ; c1ccc(N(c2ccccc2)c2ccc(-c3ccc(-n4c5cccc6c5c5c7c(cc8ccccc8c7ccc54)-c4ccccc4-6)cc3)cc2)cc1 ; CC1(C)c2ccccc2-c2ccc(N(c3ccccc3)c3ccc(-c4ccc(-n5c6cccc7c6c6c8c(cc9ccccc9c8ccc65)-c5ccccc5-7)cc4)cc3)cc21]

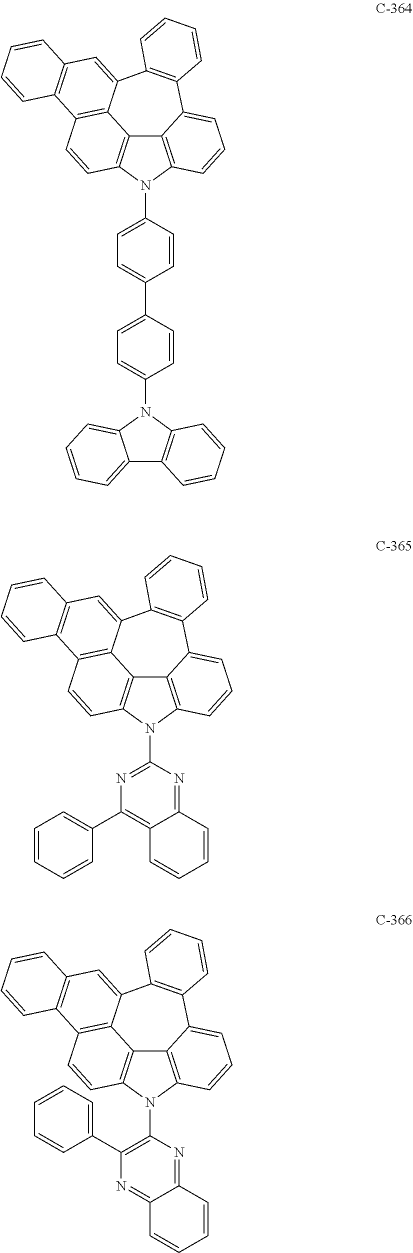 [SMILES: c1ccc2c(c1)-c1cc3ccccc3c3ccc4c(c13)c1c-2cccc1n4-c1ccc(-c2ccc(-n3c4ccccc4c4ccccc43)cc2)cc1 ; c1ccc(-c2nc(-n3c4cccc5c4c4c6c(cc7ccccc7c6ccc43)-c3ccccc3-5)nc3ccccc23)cc1 ; c1ccc(-c2nc3ccccc3nc2-n2c3cccc4c3c3c5c(cc6ccccc6c5ccc32)-c2ccccc2-4)cc1]

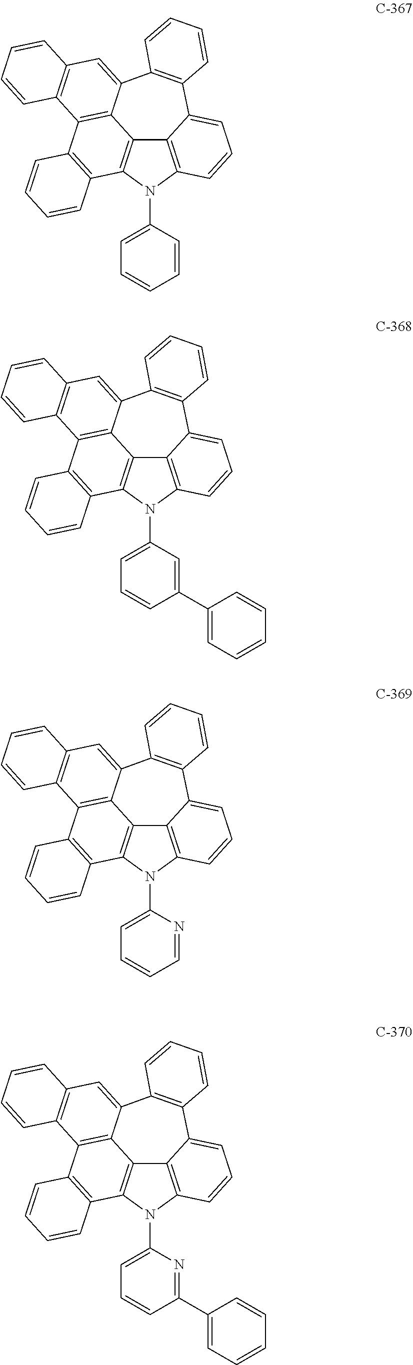 [SMILES: c1ccc(-n2c3cccc4c3c3c5c(cc6ccccc6c5c5ccccc5c32)-c2ccccc2-4)cc1 ; c1ccc(-c2cccc(-n3c4cccc5c4c4c6c(cc7ccccc7c6c6ccccc6c43)-c3ccccc3-5)c2)cc1 ; c1ccc(-n2c3cccc4c3c3c5c(cc6ccccc6c5c5ccccc5c32)-c2ccccc2-4)nc1 ; c1ccc(-c2cccc(-n3c4cccc5c4c4c6c(cc7ccccc7c6c6ccccc6c43)-c3ccccc3-5)n2)cc1]

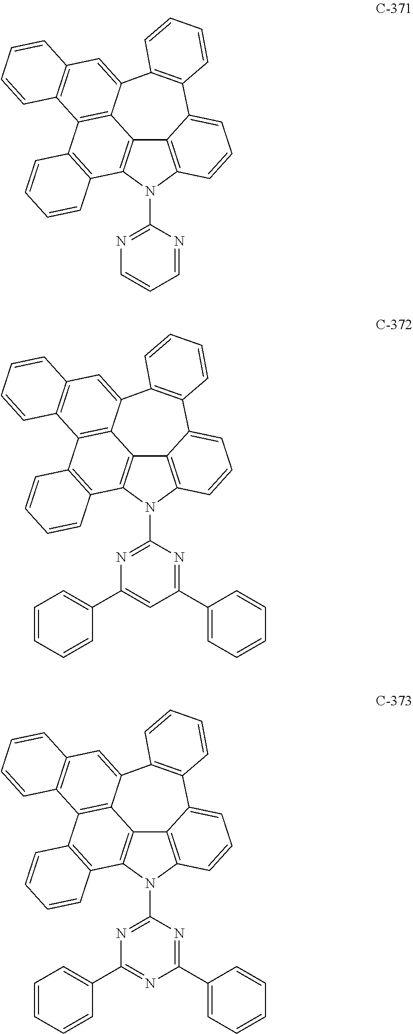 [SMILES: c1cnc(-n2c3cccc4c3c3c5c(cc6ccccc6c5c5ccccc5c32)-c2ccccc2-4)nc1 ; c1ccc(-c2cc(-c3ccccc3)nc(-n3c4cccc5c4c4c6c(cc7ccccc7c6c6ccccc6c43)-c3ccccc3-5)n2)cc1 ; c1ccc(-c2nc(-c3ccccc3)nc(-n3c4cccc5c4c4c6c(cc7ccccc7c6c6ccccc6c43)-c3ccccc3-5)n2)cc1]

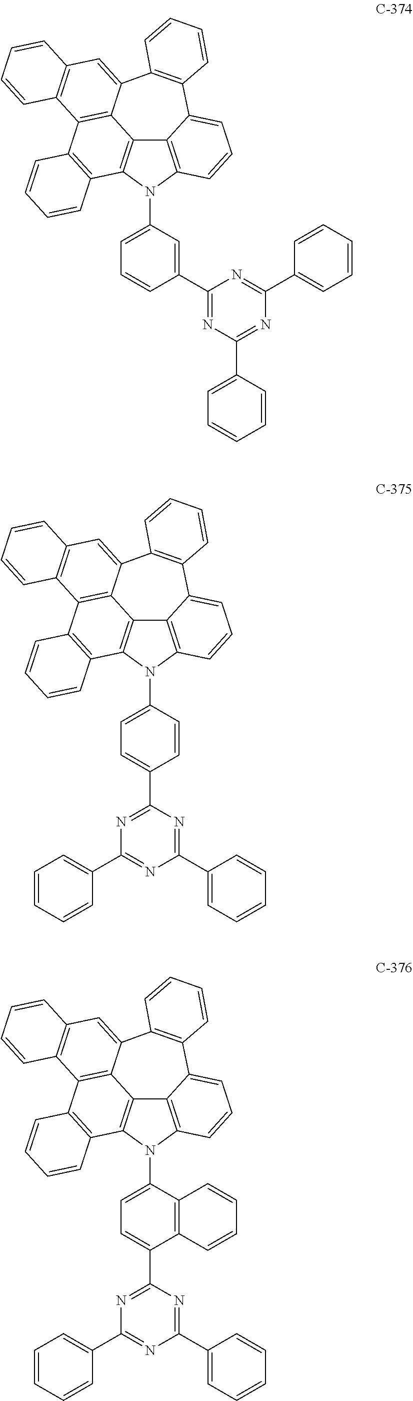 [SMILES: c1ccc(-c2nc(-c3ccccc3)nc(-c3cccc(-n4c5cccc6c5c5c7c(cc8ccccc8c7c7ccccc7c54)-c4ccccc4-6)c3)n2)cc1 ; c1ccc(-c2nc(-c3ccccc3)nc(-c3ccc(-n4c5cccc6c5c5c7c(cc8ccccc8c7c7ccccc7c54)-c4ccccc4-6)cc3)n2)cc1 ; c1ccc(-c2nc(-c3ccccc3)nc(-c3ccc(-n4c5cccc6c5c5c7c(cc8ccccc8c7c7ccccc7c54)-c4ccccc4-6)c4ccccc34)n2)cc1]

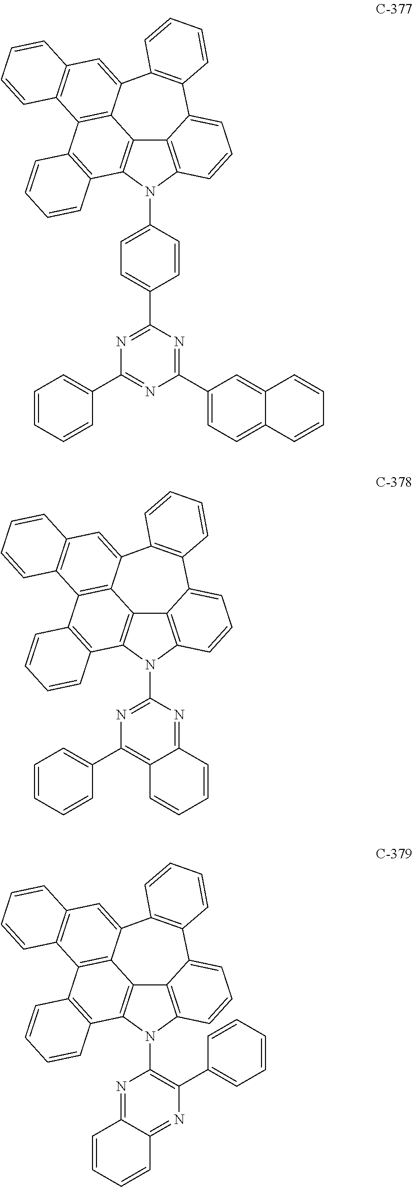 [SMILES: c1ccc(-c2nc(-c3ccc(-n4c5cccc6c5c5c7c(cc8ccccc8c7c7ccccc7c54)-c4ccccc4-6)cc3)nc(-c3ccc4ccccc4c3)n2)cc1 ; c1ccc(-c2nc(-n3c4cccc5c4c4c6c(cc7ccccc7c6c6ccccc6c43)-c3ccccc3-5)nc3ccccc23)cc1 ; c1ccc(-c2nc3ccccc3nc2-n2c3cccc4c3c3c5c(cc6ccccc6c5c5ccccc5c32)-c2ccccc2-4)cc1]

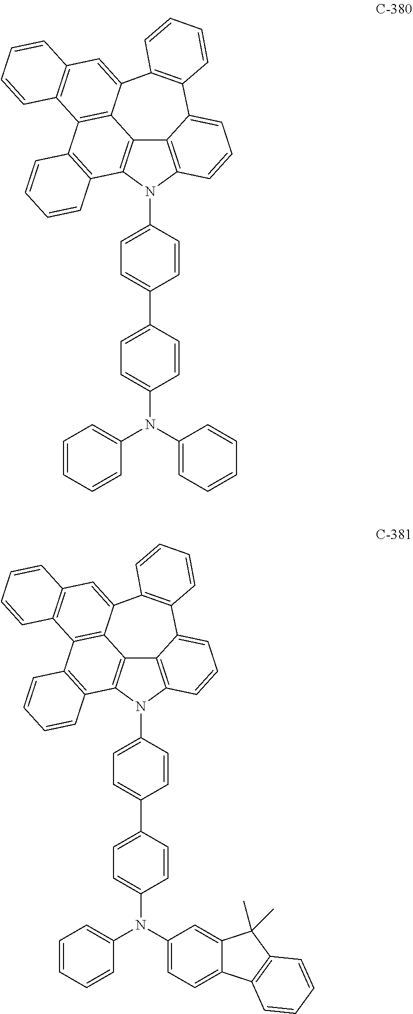 [SMILES: c1ccc(N(c2ccccc2)c2ccc(-c3ccc(-n4c5cccc6c5c5c7c(cc8ccccc8c7c7ccccc7c54)-c4ccccc4-6)cc3)cc2)cc1 ; CC1(C)c2ccccc2-c2ccc(N(c3ccccc3)c3ccc(-c4ccc(-n5c6cccc7c6c6c8c(cc9ccccc9c8c8ccccc8c65)-c5ccccc5-7)cc4)cc3)cc21]

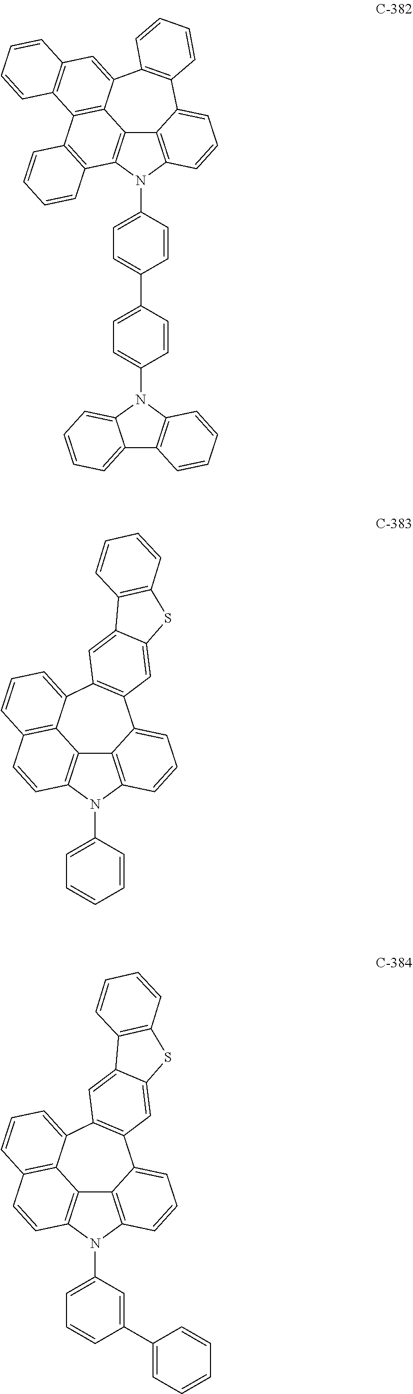 [SMILES: c1ccc2c(c1)-c1cc3ccccc3c3c4ccccc4c4c(c13)c1c-2cccc1n4-c1ccc(-c2ccc(-n3c4ccccc4c4ccccc43)cc2)cc1 ; c1ccc(-n2c3cccc4c3c3c5c(cccc5ccc32)-c2cc3c(cc2-4)sc2ccccc23)cc1 ; c1ccc(-c2cccc(-n3c4cccc5c4c4c6c(cccc6ccc43)-c3cc4c(cc3-5)sc3ccccc34)c2)cc1]

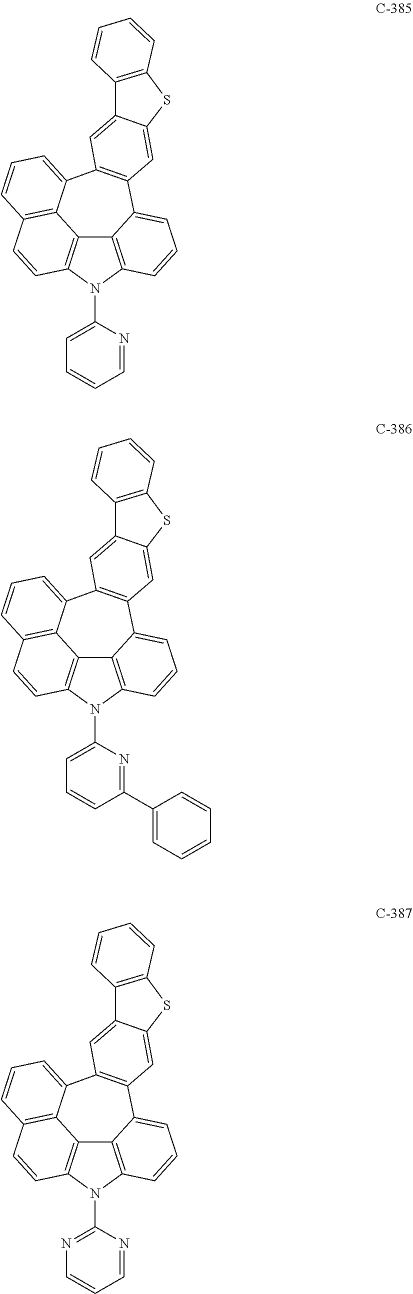 [SMILES: c1ccc(-n2c3cccc4c3c3c5c(cccc5ccc32)-c2cc3c(cc2-4)sc2ccccc23)nc1 ; c1ccc(-c2cccc(-n3c4cccc5c4c4c6c(cccc6ccc43)-c3cc4c(cc3-5)sc3ccccc34)n2)cc1 ; c1cnc(-n2c3cccc4c3c3c5c(cccc5ccc32)-c2cc3c(cc2-4)sc2ccccc23)nc1]

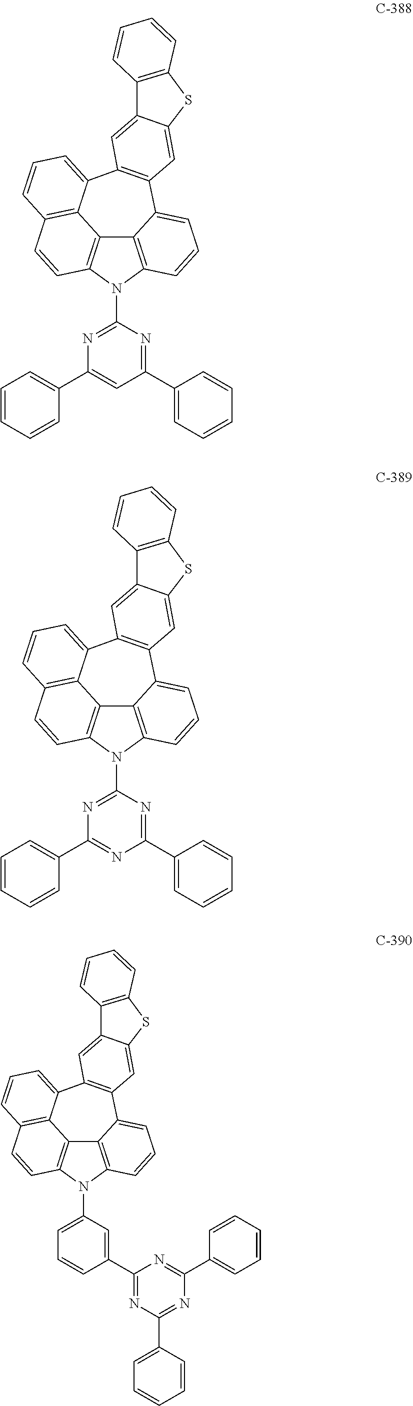 [SMILES: c1ccc(-c2cc(-c3ccccc3)nc(-n3c4cccc5c4c4c6c(cccc6ccc43)-c3cc4c(cc3-5)sc3ccccc34)n2)cc1 ; c1ccc(-c2nc(-c3ccccc3)nc(-n3c4cccc5c4c4c6c(cccc6ccc43)-c3cc4c(cc3-5)sc3ccccc34)n2)cc1 ; c1ccc(-c2nc(-c3ccccc3)nc(-c3cccc(-n4c5cccc6c5c5c7c(cccc7ccc54)-c4cc5c(cc4-6)sc4ccccc45)c3)n2)cc1]

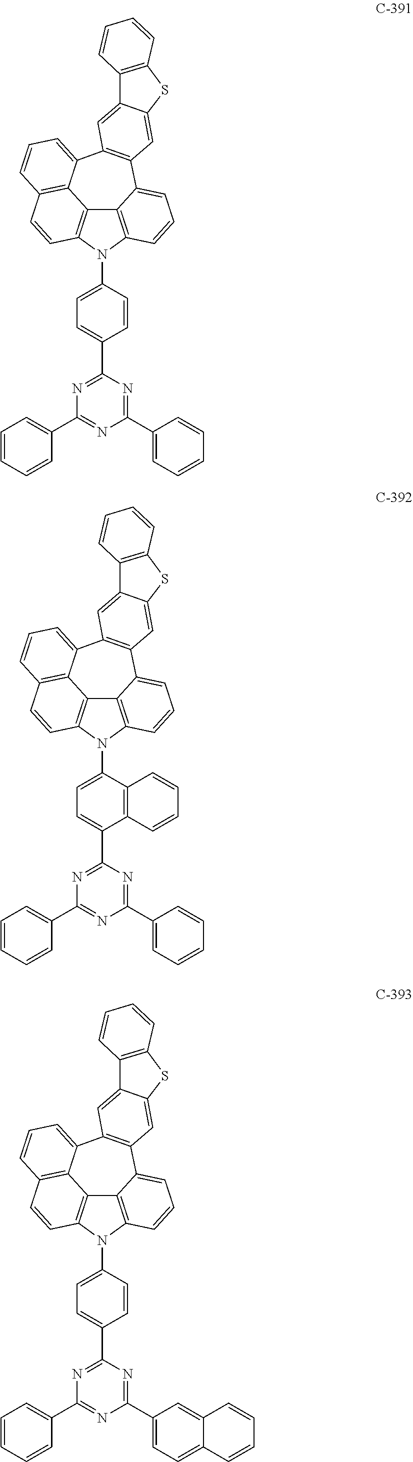 [SMILES: c1ccc(-c2nc(-c3ccccc3)nc(-c3ccc(-n4c5cccc6c5c5c7c(cccc7ccc54)-c4cc5c(cc4-6)sc4ccccc45)cc3)n2)cc1 ; c1ccc(-c2nc(-c3ccccc3)nc(-c3ccc(-n4c5cccc6c5c5c7c(cccc7ccc54)-c4cc5c(cc4-6)sc4ccccc45)c4ccccc34)n2)cc1 ; c1ccc(-c2nc(-c3ccc(-n4c5cccc6c5c5c7c(cccc7ccc54)-c4cc5c(cc4-6)sc4ccccc45)cc3)nc(-c3ccc4ccccc4c3)n2)cc1]

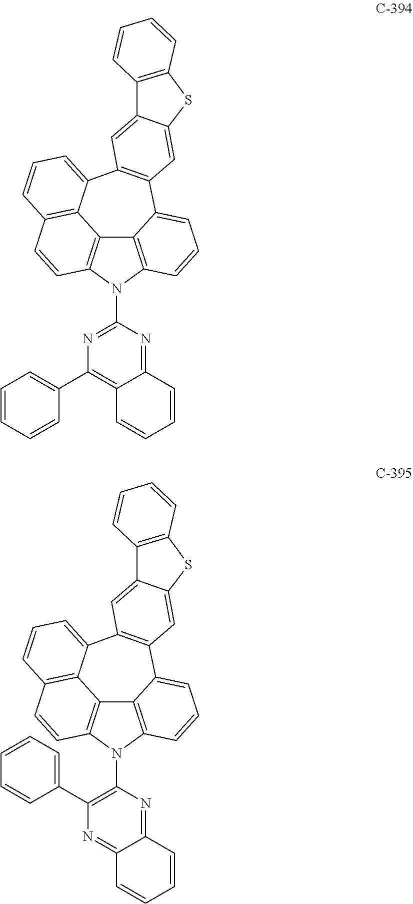

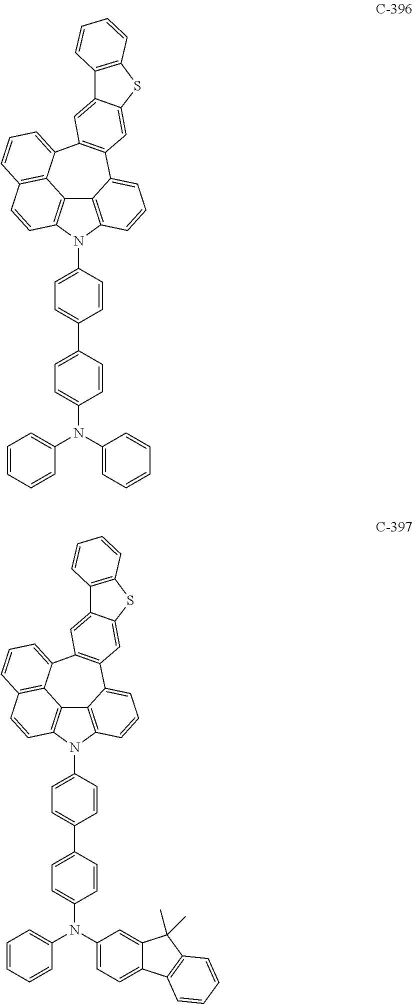 [SMILES: c1ccc(N(c2ccccc2)c2ccc(-c3ccc(-n4c5cccc6c5c5c7c(cccc7ccc54)-c4cc5c(cc4-6)sc4ccccc45)cc3)cc2)cc1 ; CC1(C)c2ccccc2-c2ccc(N(c3ccccc3)c3ccc(-c4ccc(-n5c6cccc7c6c6c8c(cccc8ccc65)-c5cc6c(cc5-7)sc5ccccc56)cc4)cc3)cc21]

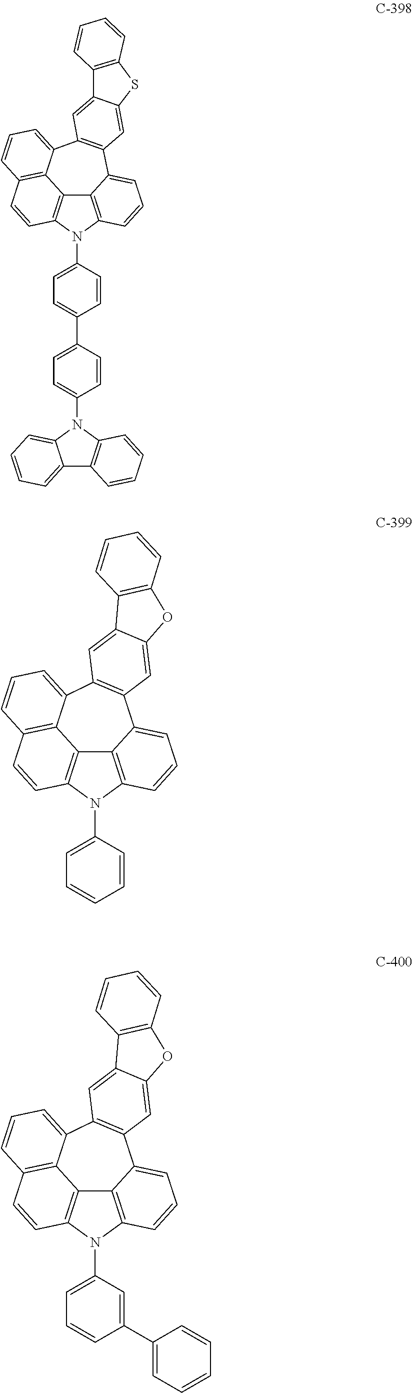 [SMILES: c1cc2c3c(c1)ccc1c3c3c(cccc3n1-c1ccc(-c3ccc(-n4c5ccccc5c5ccccc54)cc3)cc1)-c1cc3sc4ccccc4c3cc1-2 ; c1ccc(-n2c3cccc4c3c3c5c(cccc5ccc32)-c2cc3c(cc2-4)oc2ccccc23)cc1 ; c1ccc(-c2cccc(-n3c4cccc5c4c4c6c(cccc6ccc43)-c3cc4c(cc3-5)oc3ccccc34)c2)cc1]

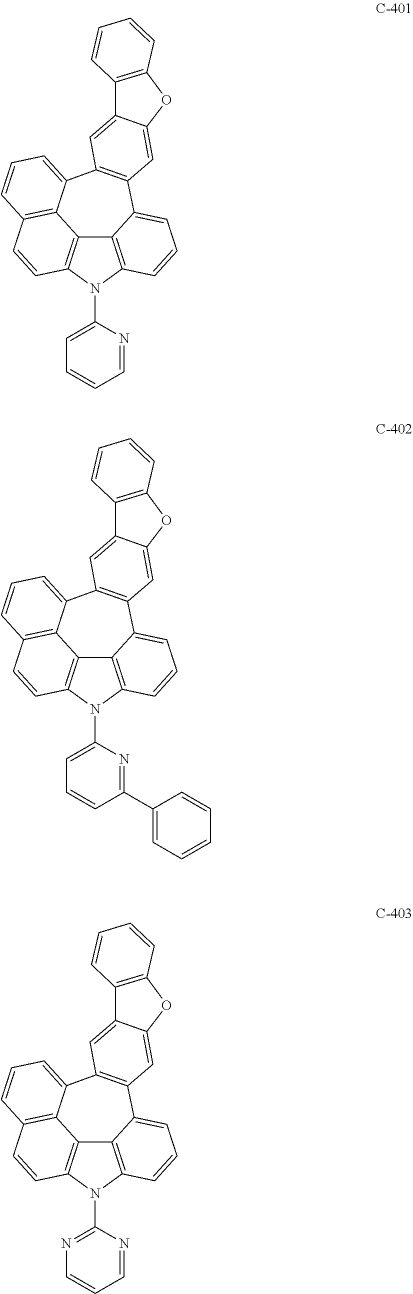 [SMILES: c1ccc(-n2c3cccc4c3c3c5c(cccc5ccc32)-c2cc3c(cc2-4)oc2ccccc23)nc1 ; c1ccc(-c2cccc(-n3c4cccc5c4c4c6c(cccc6ccc43)-c3cc4c(cc3-5)oc3ccccc34)n2)cc1 ; c1cnc(-n2c3cccc4c3c3c5c(cccc5ccc32)-c2cc3c(cc2-4)oc2ccccc23)nc1]

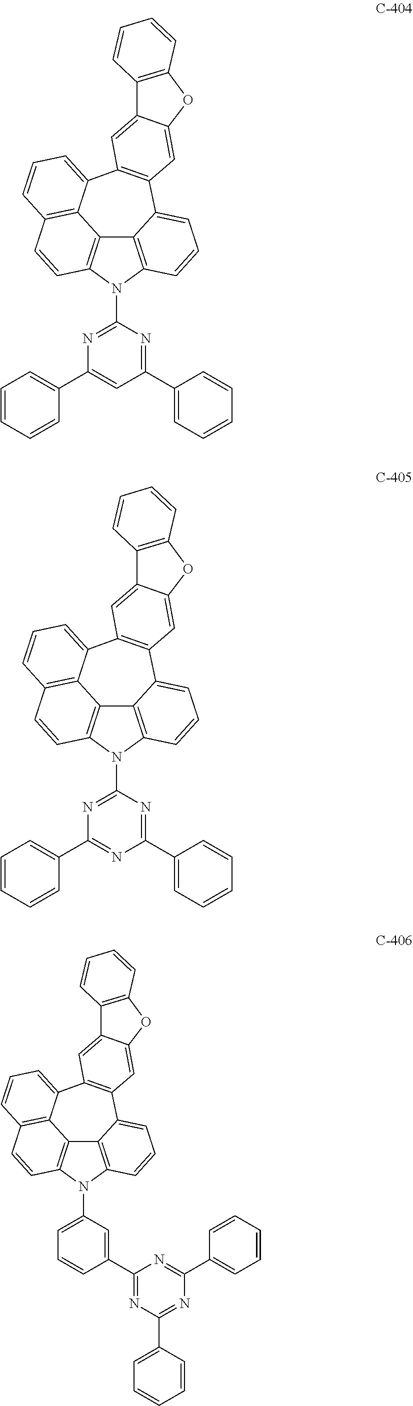 [SMILES: c1ccc(-c2cc(-c3ccccc3)nc(-n3c4cccc5c4c4c6c(cccc6ccc43)-c3cc4c(cc3-5)oc3ccccc34)n2)cc1 ; c1ccc(-c2nc(-c3ccccc3)nc(-n3c4cccc5c4c4c6c(cccc6ccc43)-c3cc4c(cc3-5)oc3ccccc34)n2)cc1 ; c1ccc(-c2nc(-c3ccccc3)nc(-c3cccc(-n4c5cccc6c5c5c7c(cccc7ccc54)-c4cc5c(cc4-6)oc4ccccc45)c3)n2)cc1]

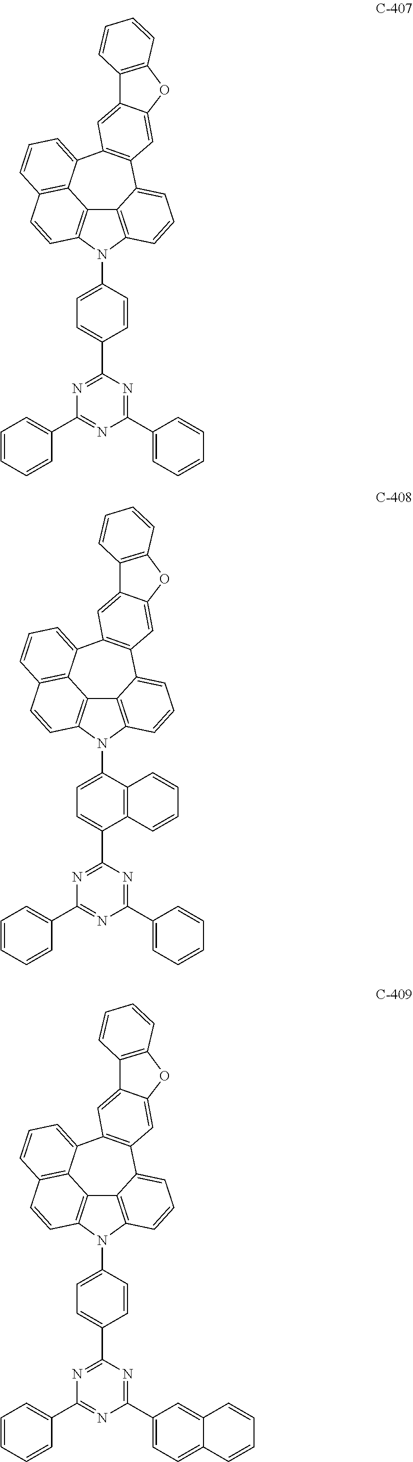 [SMILES: c1ccc(-c2nc(-c3ccccc3)nc(-c3ccc(-n4c5cccc6c5c5c7c(cccc7ccc54)-c4cc5c(cc4-6)oc4ccccc45)cc3)n2)cc1 ; c1ccc(-c2nc(-c3ccccc3)nc(-c3ccc(-n4c5cccc6c5c5c7c(cccc7ccc54)-c4cc5c(cc4-6)oc4ccccc45)c4ccccc34)n2)cc1 ; c1ccc(-c2nc(-c3ccc(-n4c5cccc6c5c5c7c(cccc7ccc54)-c4cc5c(cc4-6)oc4ccccc45)cc3)nc(-c3ccc4ccccc4c3)n2)cc1]

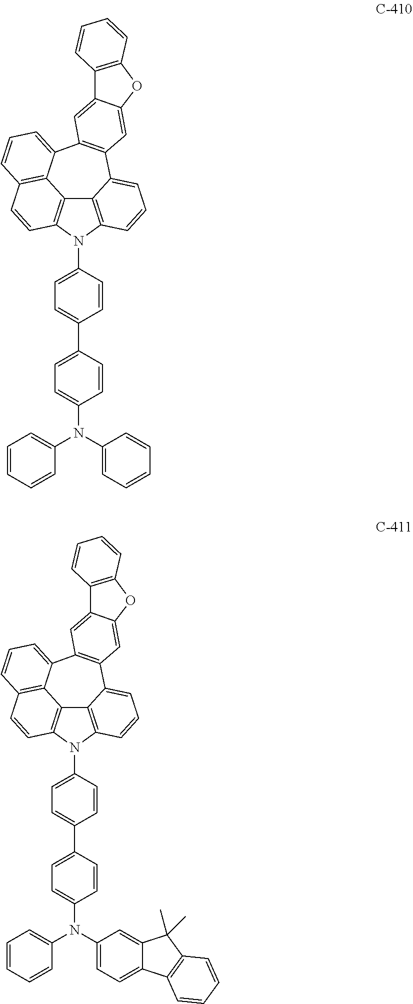 [SMILES: c1ccc(N(c2ccccc2)c2ccc(-c3ccc(-n4c5cccc6c5c5c7c(cccc7ccc54)-c4cc5c(cc4-6)oc4ccccc45)cc3)cc2)cc1 ; CC1(C)c2ccccc2-c2ccc(N(c3ccccc3)c3ccc(-c4ccc(-n5c6cccc7c6c6c8c(cccc8ccc65)-c5cc6c(cc5-7)oc5ccccc56)cc4)cc3)cc21]

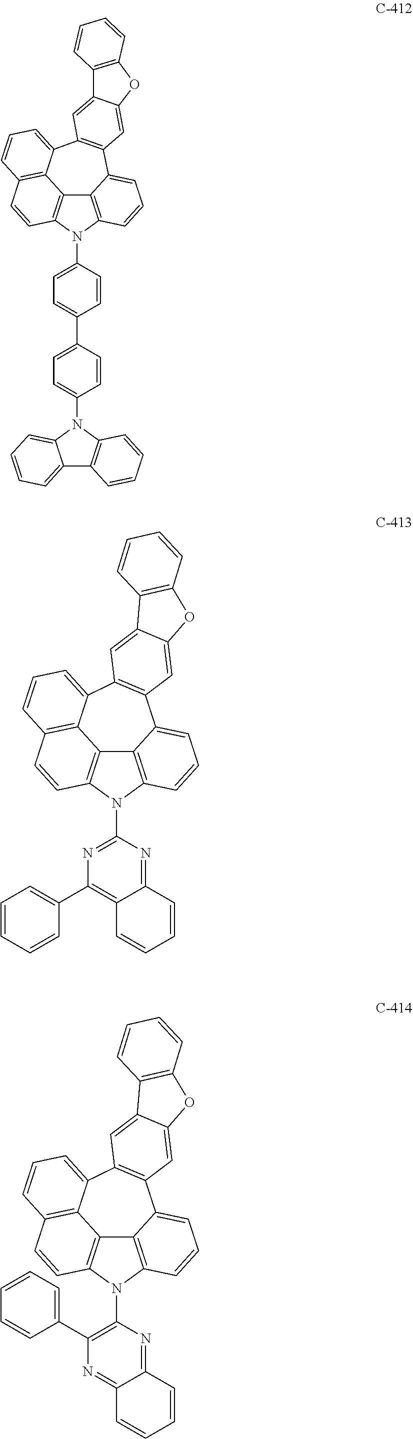 [SMILES: c1cc2c3c(c1)ccc1c3c3c(cccc3n1-c1ccc(-c3ccc(-n4c5ccccc5c5ccccc54)cc3)cc1)-c1cc3oc4ccccc4c3cc1-2 ; c1ccc(-c2nc(-n3c4cccc5c4c4c6c(cccc6ccc43)-c3cc4c(cc3-5)oc3ccccc34)nc3ccccc23)cc1 ; c1ccc(-c2nc3ccccc3nc2-n2c3cccc4c3c3c5c(cccc5ccc32)-c2cc3c(cc2-4)oc2ccccc23)cc1]

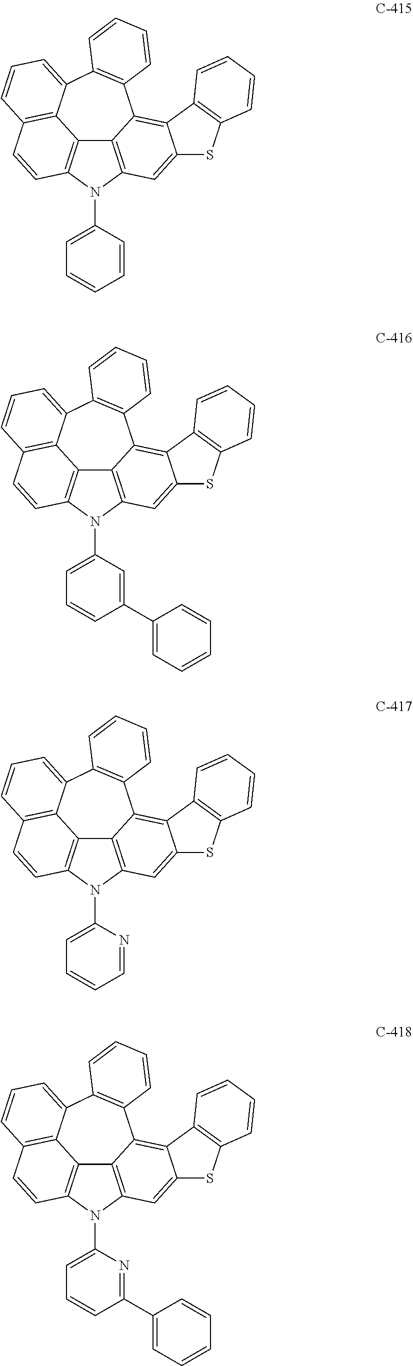 [SMILES: c1ccc(-n2c3cc4sc5ccccc5c4c4c3c3c5c(cccc5ccc32)-c2ccccc2-4)cc1 ; c1ccc(-c2cccc(-n3c4cc5sc6ccccc6c5c5c4c4c6c(cccc6ccc43)-c3ccccc3-5)c2)cc1 ; c1ccc(-n2c3cc4sc5ccccc5c4c4c3c3c5c(cccc5ccc32)-c2ccccc2-4)nc1 ; c1ccc(-c2cccc(-n3c4cc5sc6ccccc6c5c5c4c4c6c(cccc6ccc43)-c3ccccc3-5)n2)cc1]

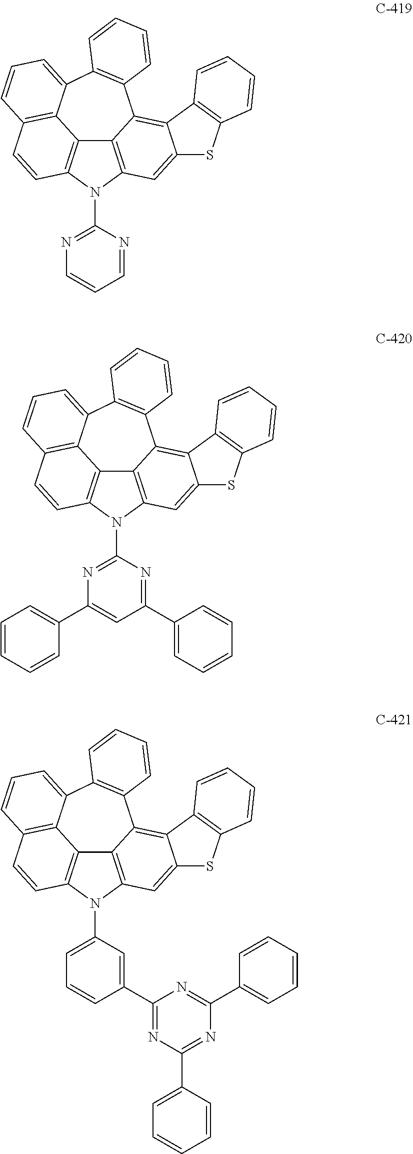 [SMILES: c1cnc(-n2c3cc4sc5ccccc5c4c4c3c3c5c(cccc5ccc32)-c2ccccc2-4)nc1 ; c1ccc(-c2cc(-c3ccccc3)nc(-n3c4cc5sc6ccccc6c5c5c4c4c6c(cccc6ccc43)-c3ccccc3-5)n2)cc1 ; c1ccc(-c2nc(-c3ccccc3)nc(-c3cccc(-n4c5cc6sc7ccccc7c6c6c5c5c7c(cccc7ccc54)-c4ccccc4-6)c3)n2)cc1]

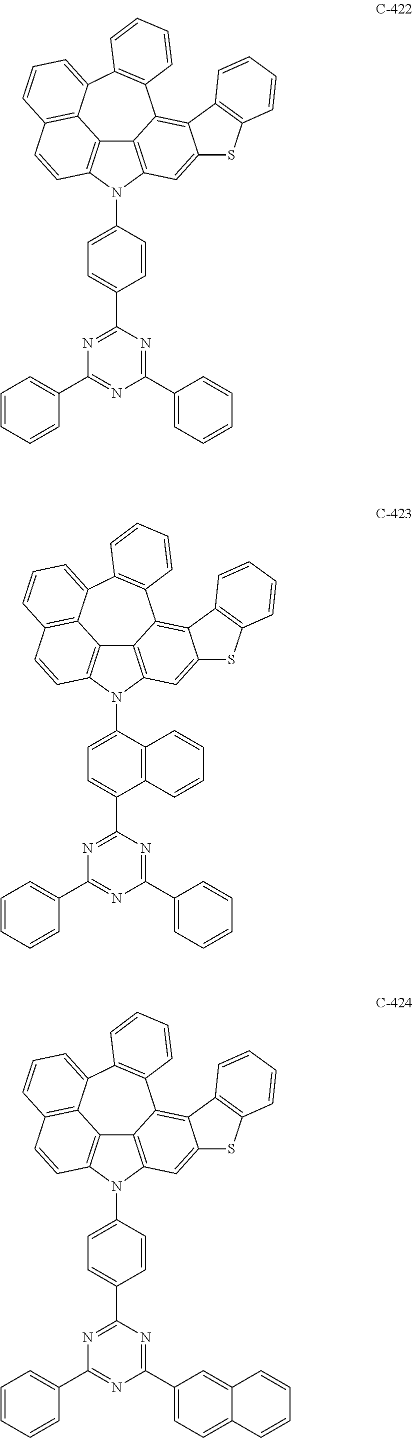 [SMILES: c1ccc(-c2nc(-c3ccccc3)nc(-c3ccc(-n4c5cc6sc7ccccc7c6c6c5c5c7c(cccc7ccc54)-c4ccccc4-6)cc3)n2)cc1 ; c1ccc(-c2nc(-c3ccccc3)nc(-c3ccc(-n4c5cc6sc7ccccc7c6c6c5c5c7c(cccc7ccc54)-c4ccccc4-6)c4ccccc34)n2)cc1 ; c1ccc(-c2nc(-c3ccc(-n4c5cc6sc7ccccc7c6c6c5c5c7c(cccc7ccc54)-c4ccccc4-6)cc3)nc(-c3ccc4ccccc4c3)n2)cc1]

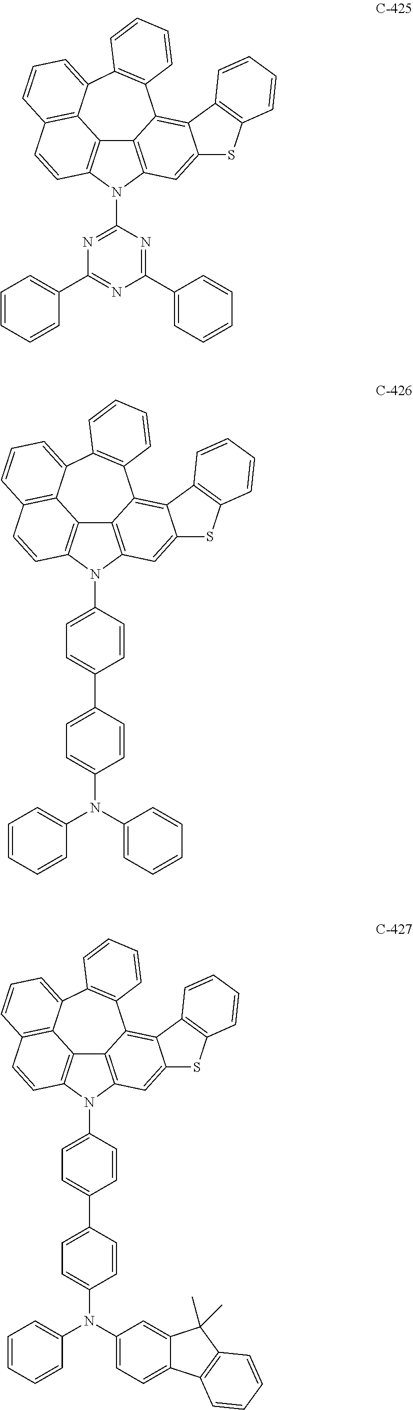 [SMILES: c1ccc(-c2nc(-c3ccccc3)nc(-n3c4cc5sc6ccccc6c5c5c4c4c6c(cccc6ccc43)-c3ccccc3-5)n2)cc1 ; c1ccc(N(c2ccccc2)c2ccc(-c3ccc(-n4c5cc6sc7ccccc7c6c6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cc7sc8ccccc8c7c7c6c6c8c(cccc8ccc65)-c5ccccc5-7)cc4)cc3)cc21]

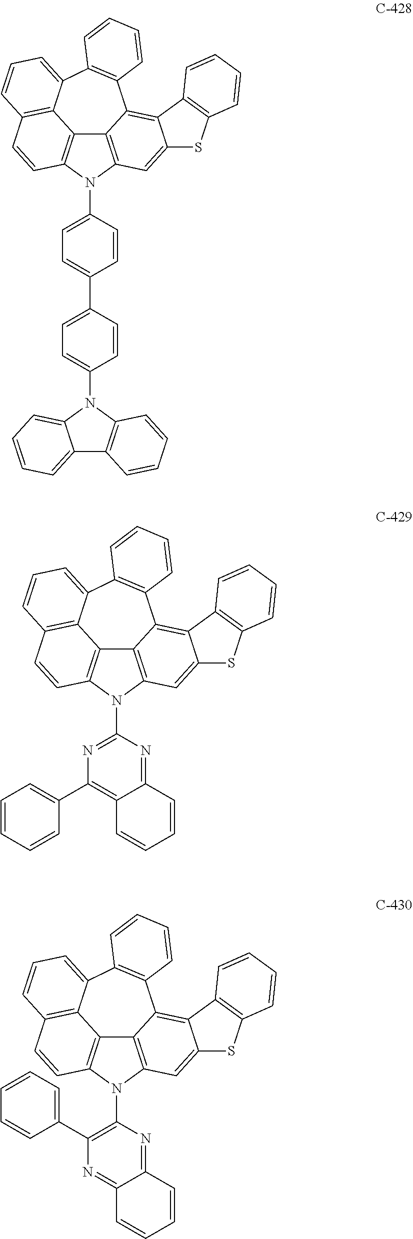 [SMILES: c1ccc2c(c1)-c1cccc3ccc4c(c13)c1c-2c2c(cc1n4-c1ccc(-c3ccc(-n4c5ccccc5c5ccccc54)cc3)cc1)sc1ccccc12 ; c1ccc(-c2nc(-n3c4cc5sc6ccccc6c5c5c4c4c6c(cccc6ccc43)-c3ccccc3-5)nc3ccccc23)cc1 ; c1ccc(-c2nc3ccccc3nc2-n2c3cc4sc5ccccc5c4c4c3c3c5c(cccc5ccc32)-c2ccccc2-4)cc1]

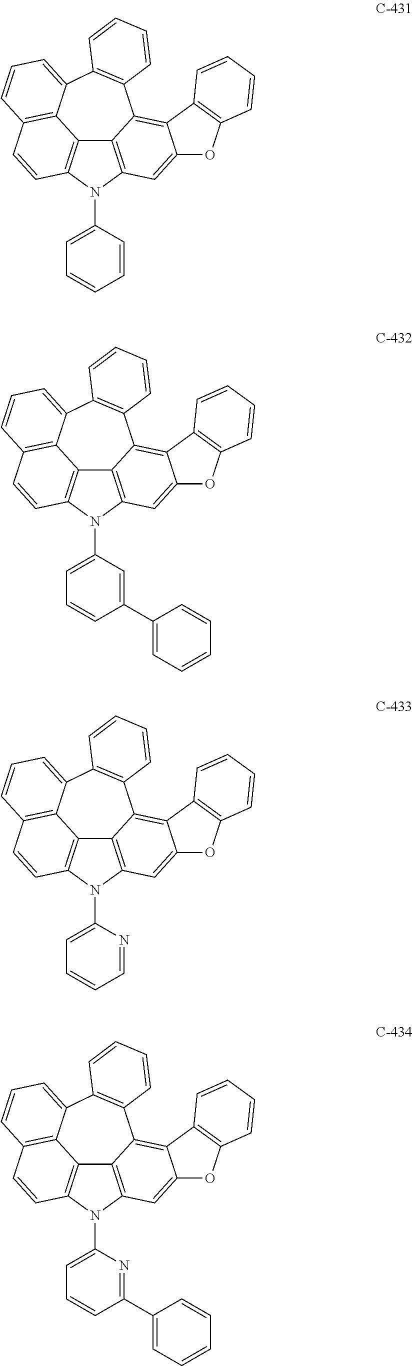 [SMILES: c1ccc(-n2c3cc4oc5ccccc5c4c4c3c3c5c(cccc5ccc32)-c2ccccc2-4)cc1 ; c1ccc(-c2cccc(-n3c4cc5oc6ccccc6c5c5c4c4c6c(cccc6ccc43)-c3ccccc3-5)c2)cc1 ; c1ccc(-n2c3cc4oc5ccccc5c4c4c3c3c5c(cccc5ccc32)-c2ccccc2-4)nc1 ; c1ccc(-c2cccc(-n3c4cc5oc6ccccc6c5c5c4c4c6c(cccc6ccc43)-c3ccccc3-5)n2)cc1]

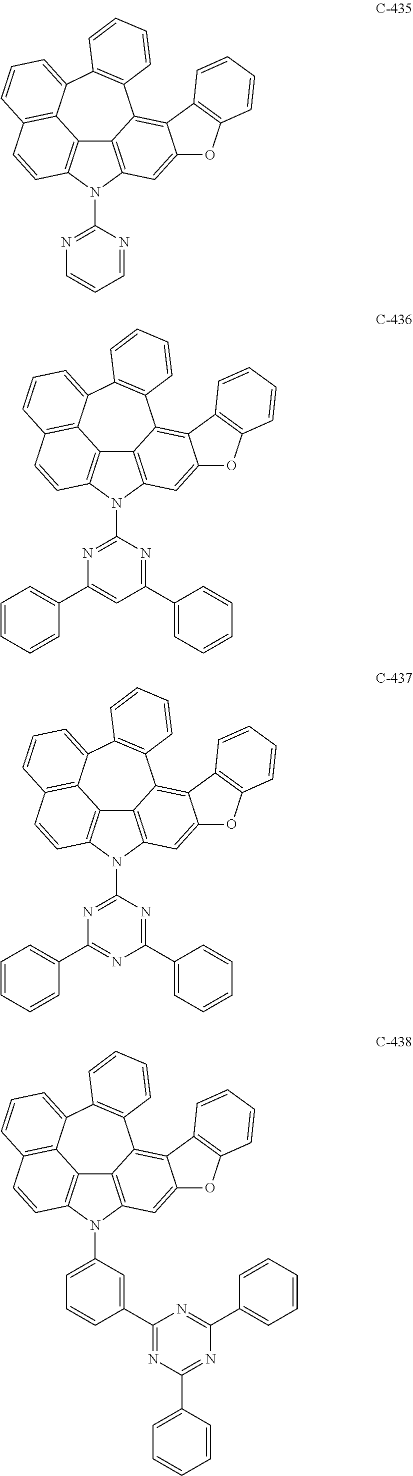 [SMILES: c1cnc(-n2c3cc4oc5ccccc5c4c4c3c3c5c(cccc5ccc32)-c2ccccc2-4)nc1 ; c1ccc(-c2cc(-c3ccccc3)nc(-n3c4cc5oc6ccccc6c5c5c4c4c6c(cccc6ccc43)-c3ccccc3-5)n2)cc1 ; c1ccc(-c2nc(-c3ccccc3)nc(-n3c4cc5oc6ccccc6c5c5c4c4c6c(cccc6ccc43)-c3ccccc3-5)n2)cc1 ; c1ccc(-c2nc(-c3ccccc3)nc(-c3cccc(-n4c5cc6oc7ccccc7c6c6c5c5c7c(cccc7ccc54)-c4ccccc4-6)c3)n2)cc1]

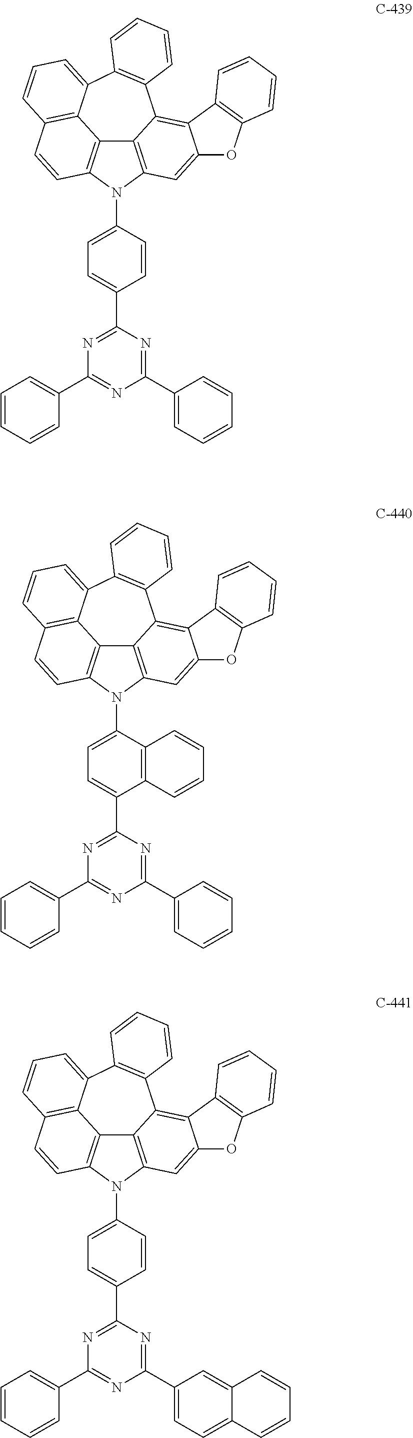 [SMILES: c1ccc(-c2nc(-c3ccccc3)nc(-c3ccc(-n4c5cc6oc7ccccc7c6c6c5c5c7c(cccc7ccc54)-c4ccccc4-6)cc3)n2)cc1 ; c1ccc(-c2nc(-c3ccccc3)nc(-c3ccc(-n4c5cc6oc7ccccc7c6c6c5c5c7c(cccc7ccc54)-c4ccccc4-6)c4ccccc34)n2)cc1 ; c1ccc(-c2nc(-c3ccc(-n4c5cc6oc7ccccc7c6c6c5c5c7c(cccc7ccc54)-c4ccccc4-6)cc3)nc(-c3ccc4ccccc4c3)n2)cc1]

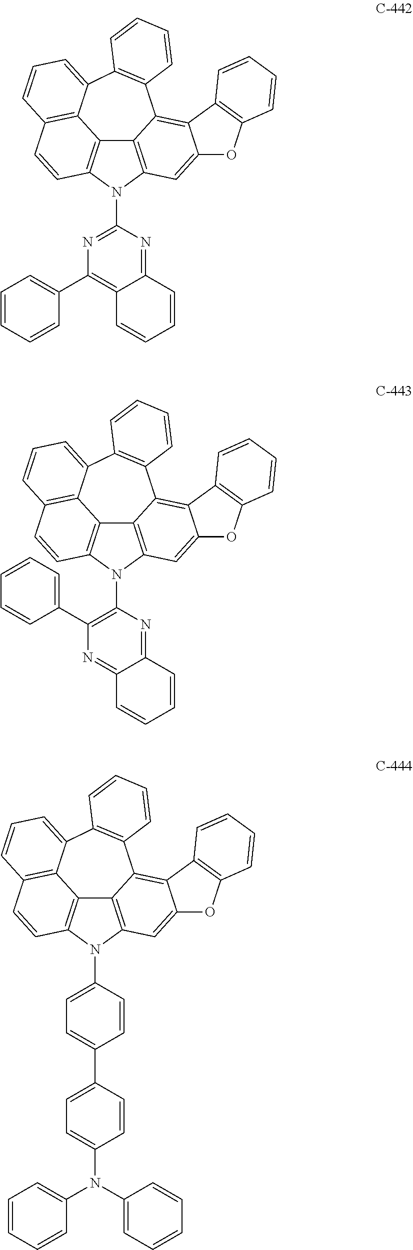 [SMILES: c1ccc(-c2nc(-n3c4cc5oc6ccccc6c5c5c4c4c6c(cccc6ccc43)-c3ccccc3-5)nc3ccccc23)cc1 ; c1ccc(-c2nc3ccccc3nc2-n2c3cc4oc5ccccc5c4c4c3c3c5c(cccc5ccc32)-c2ccccc2-4)cc1 ; c1ccc(N(c2ccccc2)c2ccc(-c3ccc(-n4c5cc6oc7ccccc7c6c6c5c5c7c(cccc7ccc54)-c4ccccc4-6)cc3)cc2)cc1]

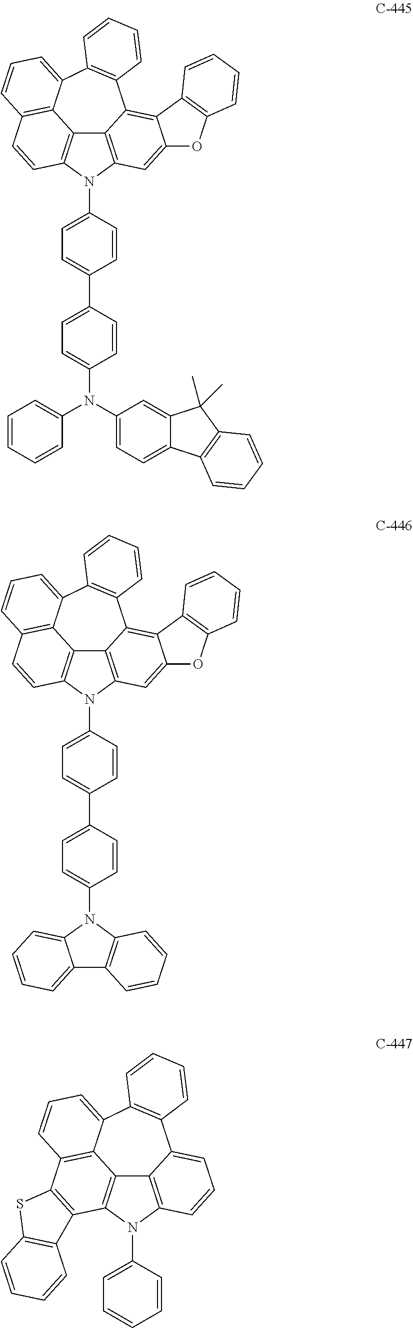 [SMILES: CC1(C)c2ccccc2-c2ccc(N(c3ccccc3)c3ccc(-c4ccc(-n5c6cc7oc8ccccc8c7c7c6c6c8c(cccc8ccc65)-c5ccccc5-7)cc4)cc3)cc21 ; c1ccc2c(c1)-c1cccc3ccc4c(c13)c1c-2c2c(cc1n4-c1ccc(-c3ccc(-n4c5ccccc5c5ccccc54)cc3)cc1)oc1ccccc12 ; c1ccc(-n2c3cccc4c3c3c5c(cccc5c5sc6ccccc6c5c32)-c2ccccc2-4)cc1]

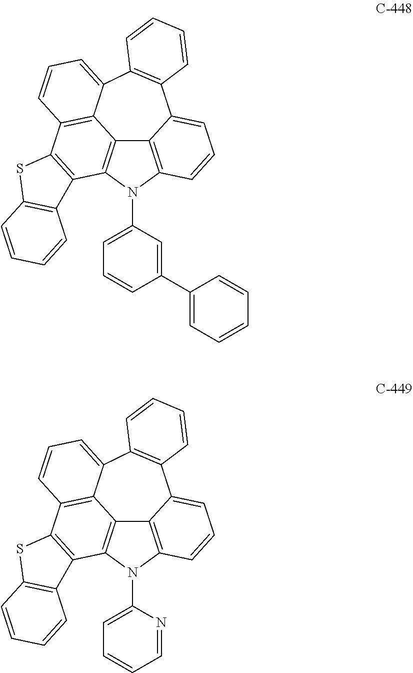 [SMILES: c1ccc(-c2cccc(-n3c4cccc5c4c4c6c(cccc6c6sc7ccccc7c6c43)-c3ccccc3-5)c2)cc1 ; c1ccc(-n2c3cccc4c3c3c5c(cccc5c5sc6ccccc6c5c32)-c2ccccc2-4)nc1]

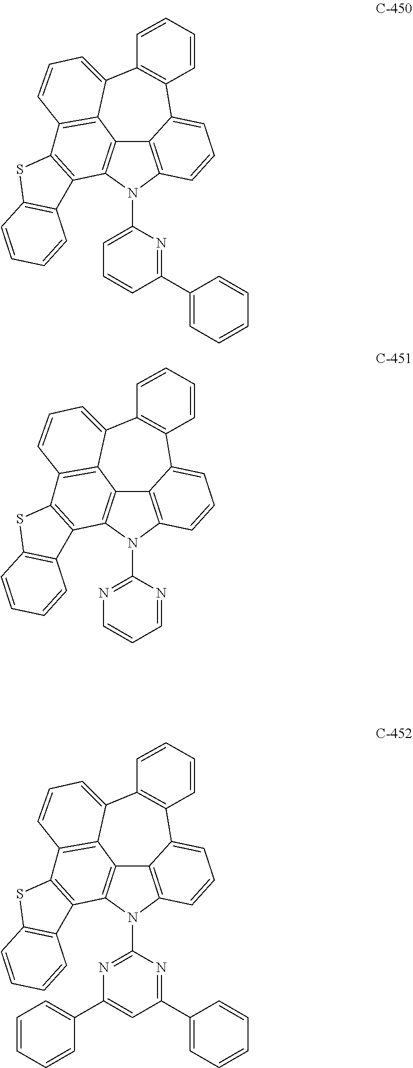 [SMILES: c1ccc(-c2cccc(-n3c4cccc5c4c4c6c(cccc6c6sc7ccccc7c6c43)-c3ccccc3-5)n2)cc1 ; c1cnc(-n2c3cccc4c3c3c5c(cccc5c5sc6ccccc6c5c32)-c2ccccc2-4)nc1 ; c1ccc(-c2cc(-c3ccccc3)nc(-n3c4cccc5c4c4c6c(cccc6c6sc7ccccc7c6c43)-c3ccccc3-5)n2)cc1]

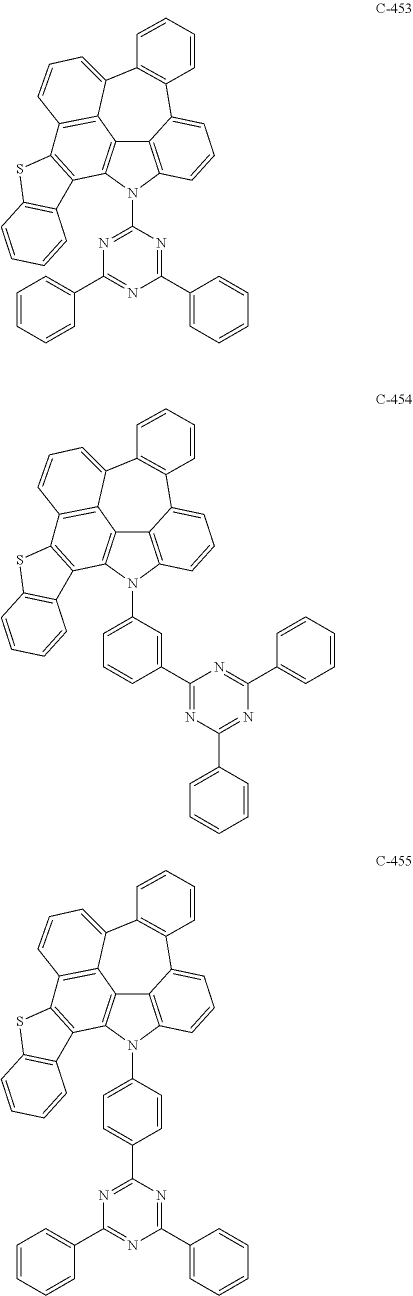 [SMILES: c1ccc(-c2nc(-c3ccccc3)nc(-n3c4cccc5c4c4c6c(cccc6c6sc7ccccc7c6c43)-c3ccccc3-5)n2)cc1 ; c1ccc(-c2nc(-c3ccccc3)nc(-c3cccc(-n4c5cccc6c5c5c7c(cccc7c7sc8ccccc8c7c54)-c4ccccc4-6)c3)n2)cc1 ; c1ccc(-c2nc(-c3ccccc3)nc(-c3ccc(-n4c5cccc6c5c5c7c(cccc7c7sc8ccccc8c7c54)-c4ccccc4-6)cc3)n2)cc1]

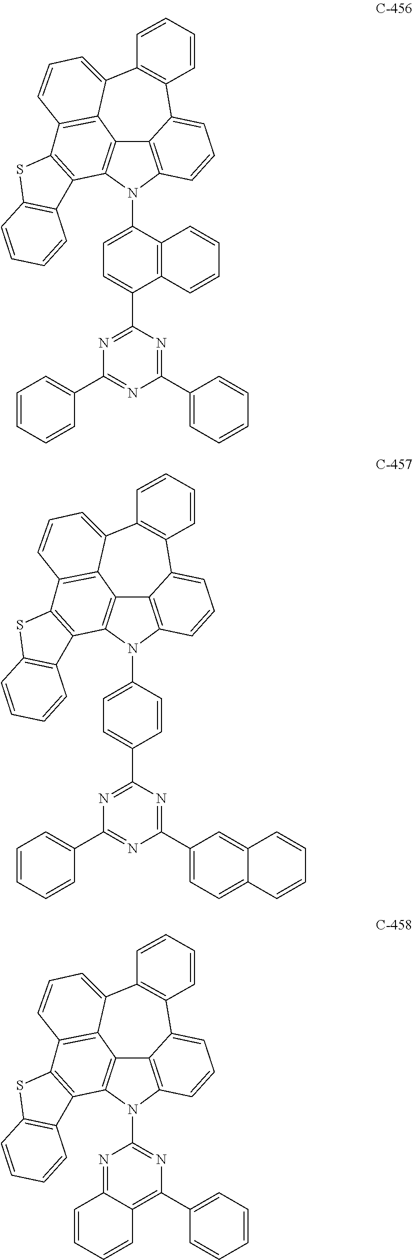 [SMILES: c1ccc(-c2nc(-c3ccccc3)nc(-c3ccc(-n4c5cccc6c5c5c7c(cccc7c7sc8ccccc8c7c54)-c4ccccc4-6)c4ccccc34)n2)cc1 ; c1ccc(-c2nc(-c3ccc(-n4c5cccc6c5c5c7c(cccc7c7sc8ccccc8c7c54)-c4ccccc4-6)cc3)nc(-c3ccc4ccccc4c3)n2)cc1 ; c1ccc(-c2nc(-n3c4cccc5c4c4c6c(cccc6c6sc7ccccc7c6c43)-c3ccccc3-5)nc3ccccc23)cc1]

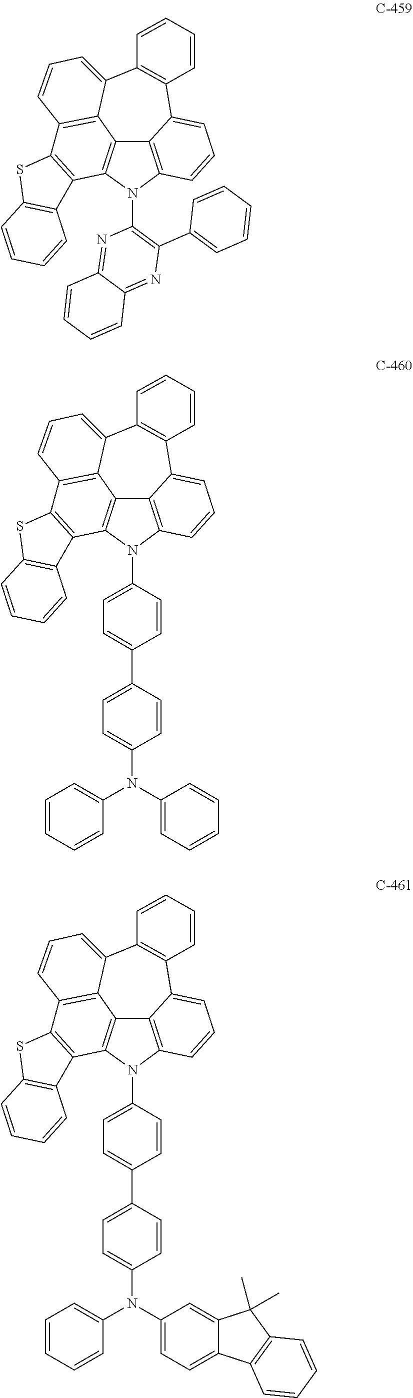 [SMILES: c1ccc(-c2nc3ccccc3nc2-n2c3cccc4c3c3c5c(cccc5c5sc6ccccc6c5c32)-c2ccccc2-4)cc1 ; c1ccc(N(c2ccccc2)c2ccc(-c3ccc(-n4c5cccc6c5c5c7c(cccc7c7sc8ccccc8c7c54)-c4ccccc4-6)cc3)cc2)cc1 ; CC1(C)c2ccccc2-c2ccc(N(c3ccccc3)c3ccc(-c4ccc(-n5c6cccc7c6c6c8c(cccc8c8sc9ccccc9c8c65)-c5ccccc5-7)cc4)cc3)cc21]

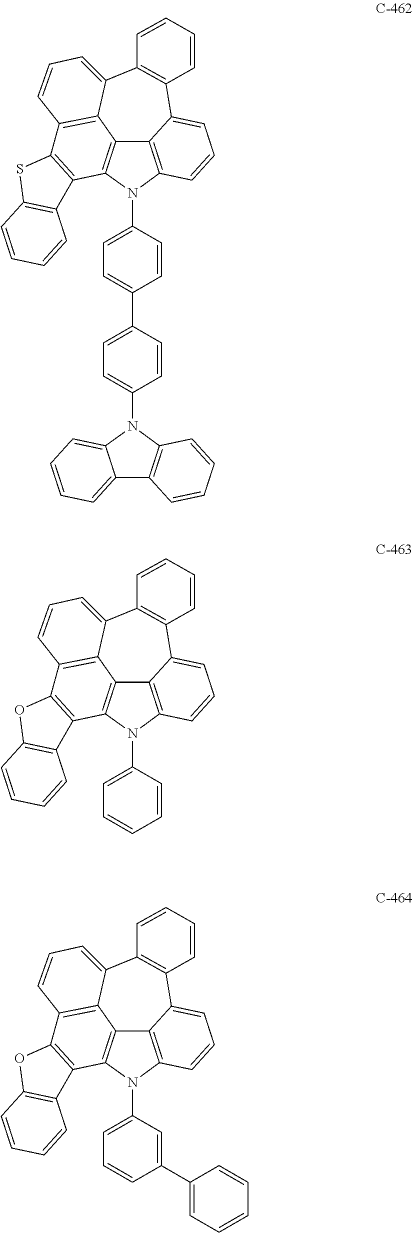 [SMILES: c1ccc2c(c1)-c1cccc3c4sc5ccccc5c4c4c(c13)c1c-2cccc1n4-c1ccc(-c2ccc(-n3c4ccccc4c4ccccc43)cc2)cc1 ; c1ccc(-n2c3cccc4c3c3c5c(cccc5c5oc6ccccc6c5c32)-c2ccccc2-4)cc1 ; c1ccc(-c2cccc(-n3c4cccc5c4c4c6c(cccc6c6oc7ccccc7c6c43)-c3ccccc3-5)c2)cc1]

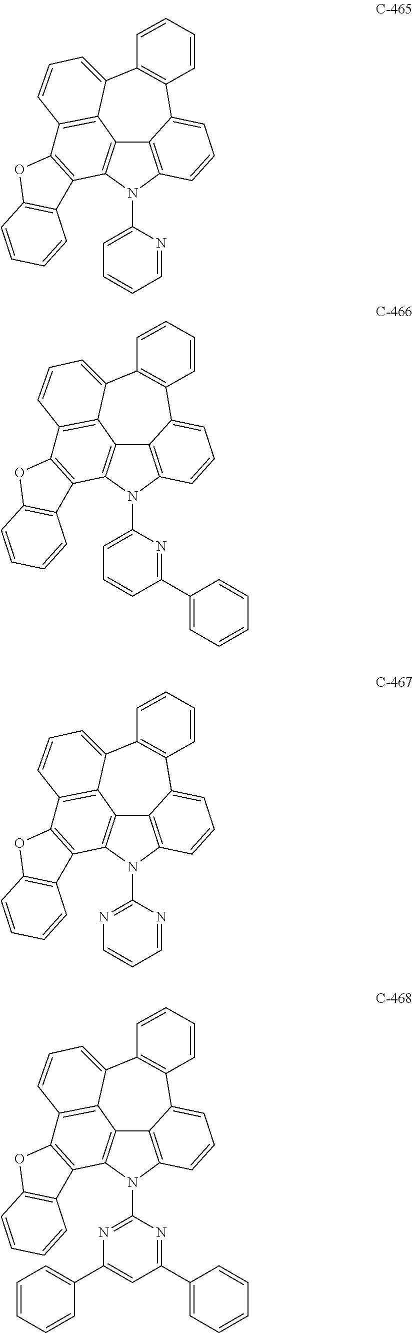

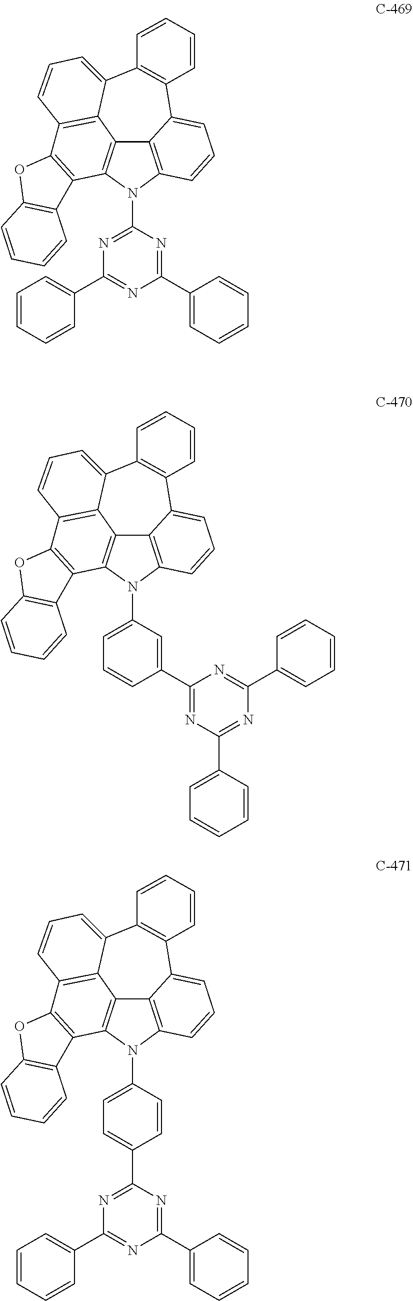 [SMILES: c1ccc(-c2nc(-c3ccccc3)nc(-n3c4cccc5c4c4c6c(cccc6c6oc7ccccc7c6c43)-c3ccccc3-5)n2)cc1 ; c1ccc(-c2nc(-c3ccccc3)nc(-c3cccc(-n4c5cccc6c5c5c7c(cccc7c7oc8ccccc8c7c54)-c4ccccc4-6)c3)n2)cc1 ; c1ccc(-c2nc(-c3ccccc3)nc(-c3ccc(-n4c5cccc6c5c5c7c(cccc7c7oc8ccccc8c7c54)-c4ccccc4-6)cc3)n2)cc1]

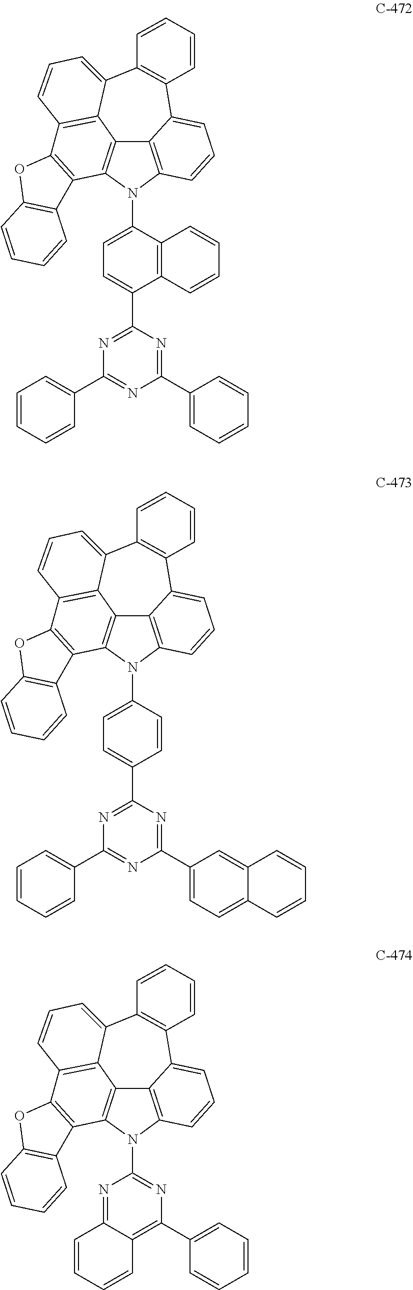 [SMILES: c1ccc(-c2nc(-c3ccccc3)nc(-c3ccc(-n4c5cccc6c5c5c7c(cccc7c7oc8ccccc8c7c54)-c4ccccc4-6)c4ccccc34)n2)cc1 ; c1ccc(-c2nc(-c3ccc(-n4c5cccc6c5c5c7c(cccc7c7oc8ccccc8c7c54)-c4ccccc4-6)cc3)nc(-c3ccc4ccccc4c3)n2)cc1 ; c1ccc(-c2nc(-n3c4cccc5c4c4c6c(cccc6c6oc7ccccc7c6c43)-c3ccccc3-5)nc3ccccc23)cc1]

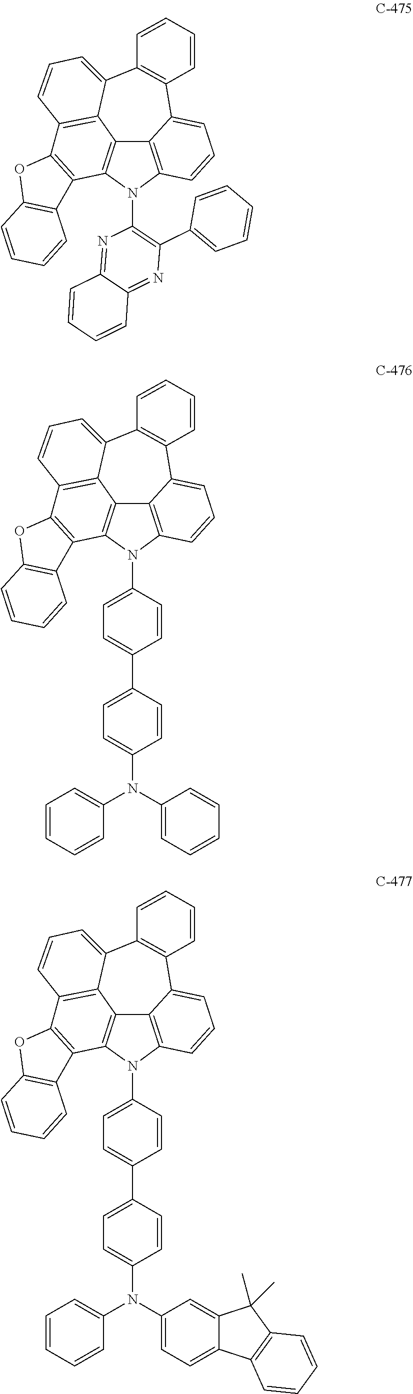

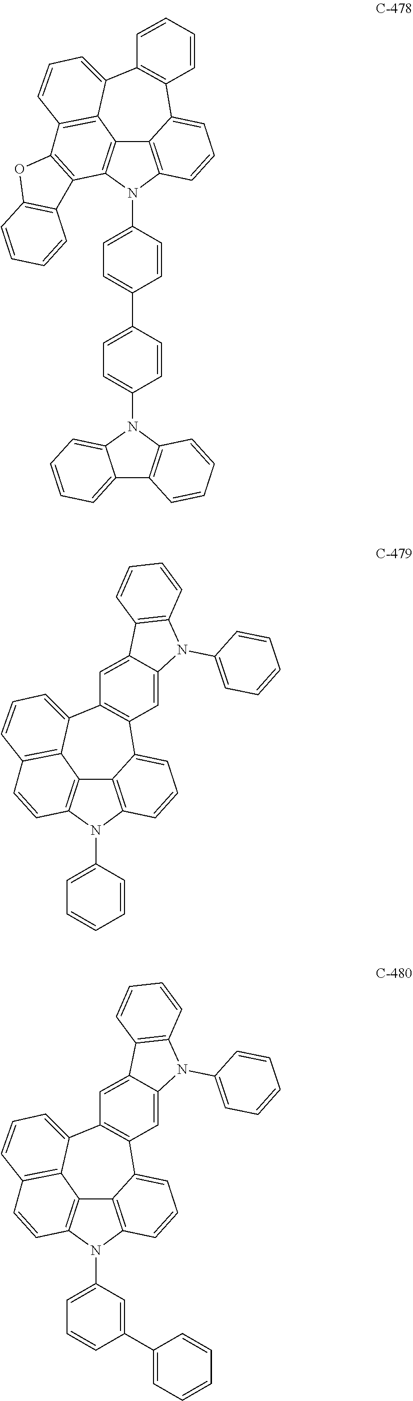 [SMILES: c1ccc2c(c1)-c1cccc3c4oc5ccccc5c4c4c(c13)c1c-2cccc1n4-c1ccc(-c2ccc(-n3c4ccccc4c4ccccc43)cc2)cc1 ; c1ccc(-n2c3ccccc3c3cc4c(cc32)-c2cccc3c2c2c5c-4cccc5ccc2n3-c2ccccc2)cc1 ; c1ccc(-c2cccc(-n3c4cccc5c4c4c6c(cccc6ccc43)-c3cc4c6ccccc6n(-c6ccccc6)c4cc3-5)c2)cc1]

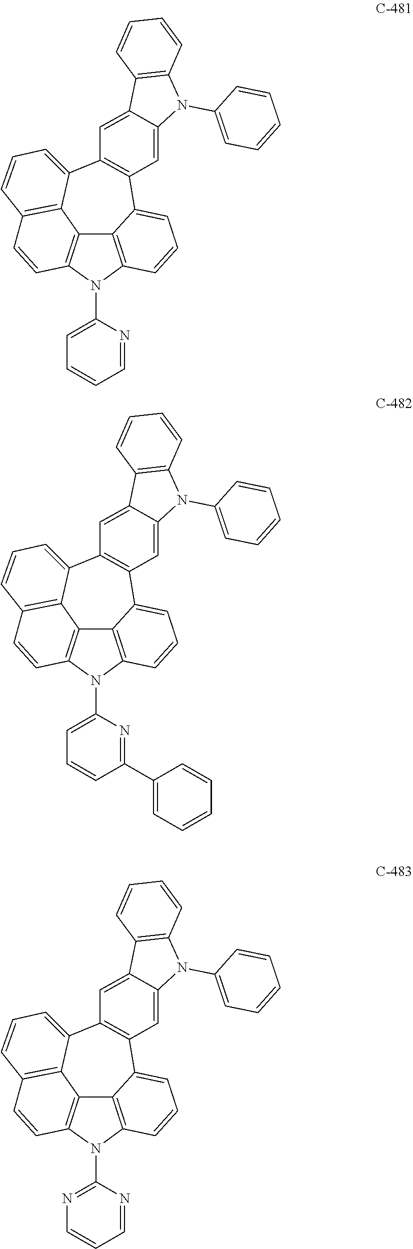

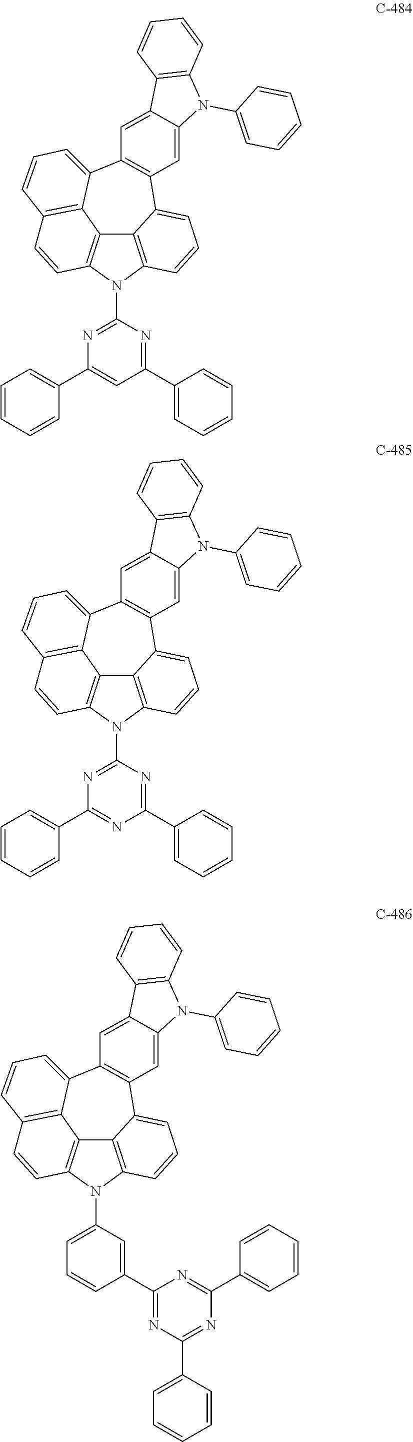

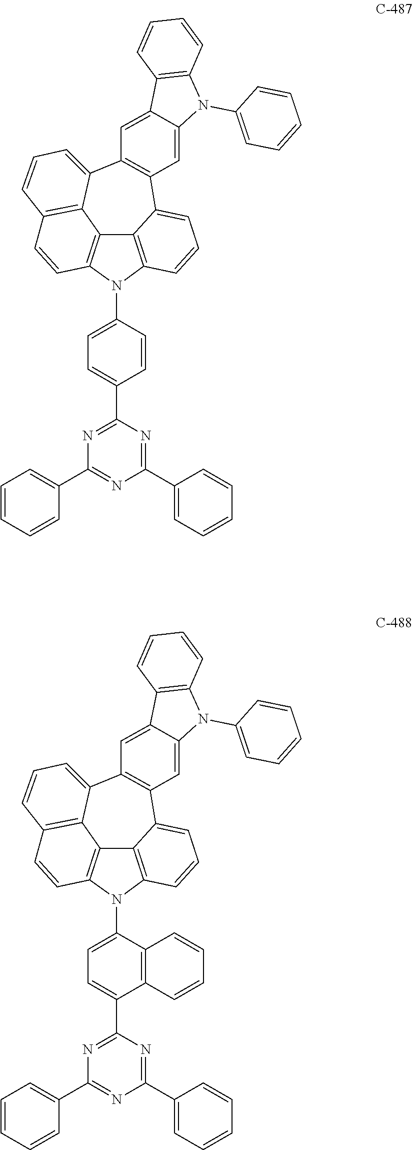 [SMILES: c1ccc(-c2nc(-c3ccccc3)nc(-c3ccc(-n4c5cccc6c5c5c7c(cccc7ccc54)-c4cc5c7ccccc7n(-c7ccccc7)c5cc4-6)cc3)n2)cc1 ; c1ccc(-c2nc(-c3ccccc3)nc(-c3ccc(-n4c5cccc6c5c5c7c(cccc7ccc54)-c4cc5c7ccccc7n(-c7ccccc7)c5cc4-6)c4ccccc34)n2)cc1]

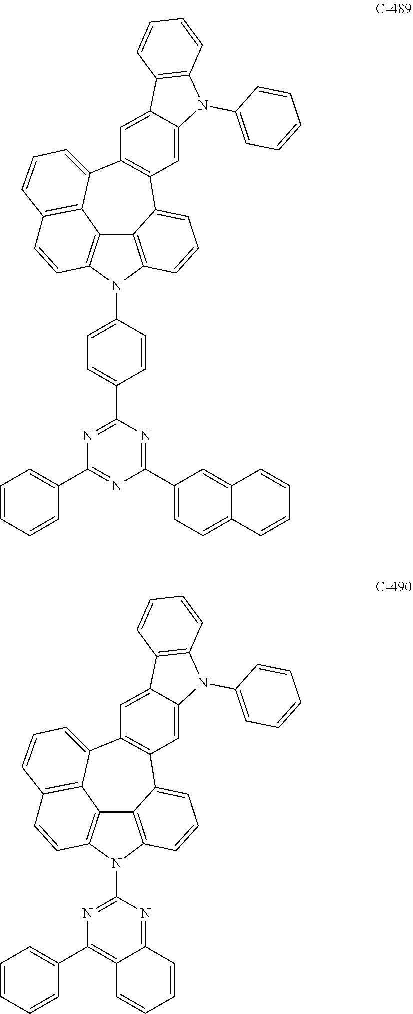 [SMILES: c1ccc(-c2nc(-c3ccc(-n4c5cccc6c5c5c7c(cccc7ccc54)-c4cc5c7ccccc7n(-c7ccccc7)c5cc4-6)cc3)nc(-c3ccc4ccccc4c3)n2)cc1 ; c1ccc(-c2nc(-n3c4cccc5c4c4c6c(cccc6ccc43)-c3cc4c6ccccc6n(-c6ccccc6)c4cc3-5)nc3ccccc23)cc1]

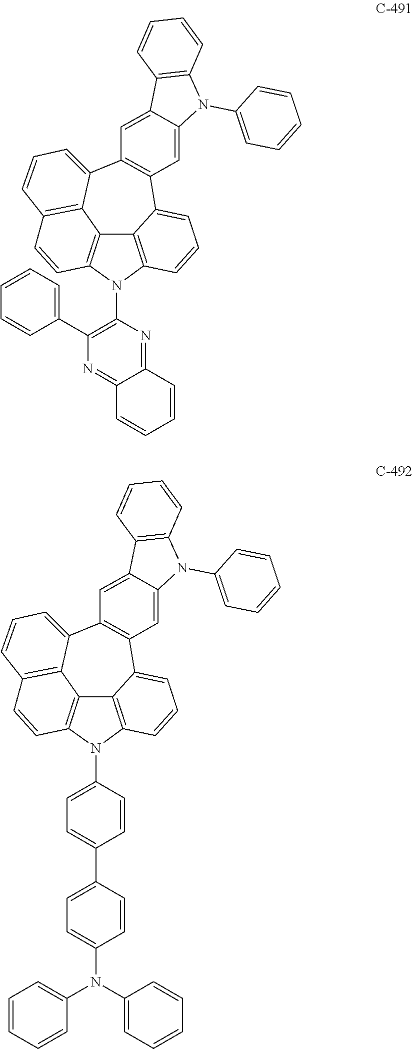 [SMILES: c1ccc(-c2nc3ccccc3nc2-n2c3cccc4c3c3c5c(cccc5ccc32)-c2cc3c5ccccc5n(-c5ccccc5)c3cc2-4)cc1 ; c1ccc(N(c2ccccc2)c2ccc(-c3ccc(-n4c5cccc6c5c5c7c(cccc7ccc54)-c4cc5c7ccccc7n(-c7ccccc7)c5cc4-6)cc3)cc2)cc1]

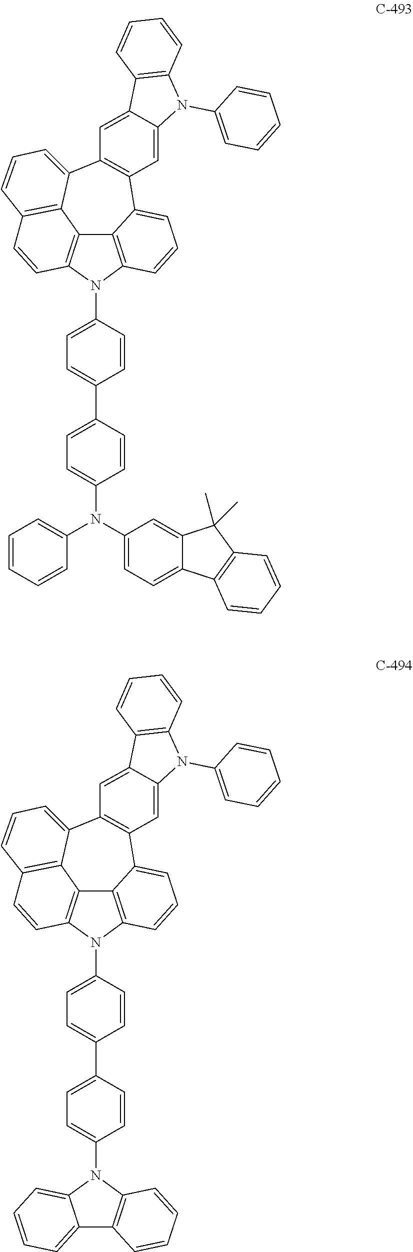 [SMILES: CC1(C)c2ccccc2-c2ccc(N(c3ccccc3)c3ccc(-c4ccc(-n5c6cccc7c6c6c8c(cccc8ccc65)-c5cc6c8ccccc8n(-c8ccccc8)c6cc5-7)cc4)cc3)cc21 ; c1ccc(-n2c3ccccc3c3cc4c(cc32)-c2cccc3c2c2c5c-4cccc5ccc2n3-c2ccc(-c3ccc(-n4c5ccccc5c5ccccc54)cc3)cc2)cc1]

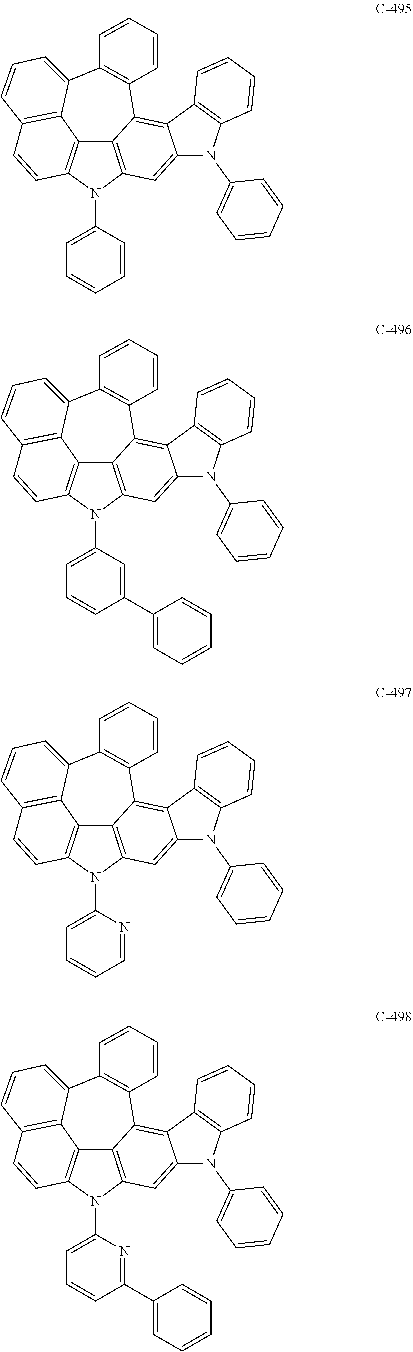 [SMILES: c1ccc(-n2c3ccccc3c3c4c5c6c7c(cccc7ccc6n(-c6ccccc6)c5cc32)-c2ccccc2-4)cc1 ; c1ccc(-c2cccc(-n3c4cc5c(c6c4c4c7c(cccc7ccc43)-c3ccccc3-6)c3ccccc3n5-c3ccccc3)c2)cc1 ; c1ccc(-n2c3ccccc3c3c4c5c6c7c(cccc7ccc6n(-c6ccccn6)c5cc32)-c2ccccc2-4)cc1 ; c1ccc(-c2cccc(-n3c4cc5c(c6c4c4c7c(cccc7ccc43)-c3ccccc3-6)c3ccccc3n5-c3ccccc3)n2)cc1]

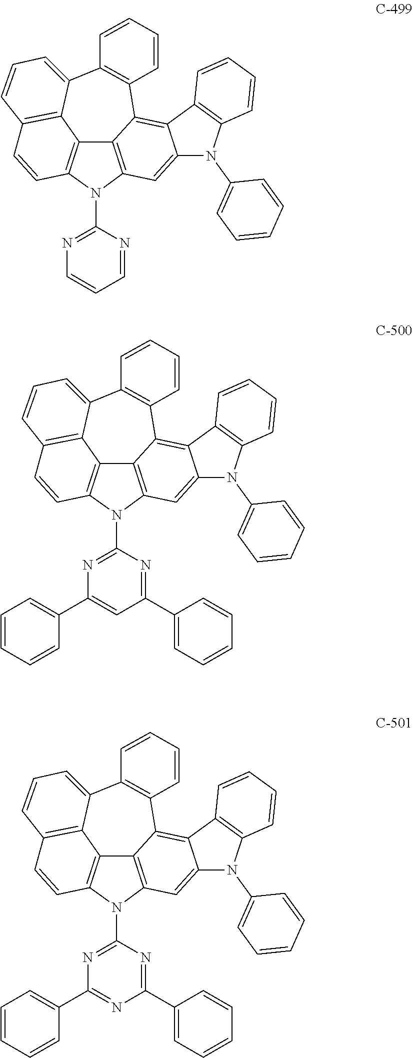 [SMILES: c1ccc(-n2c3ccccc3c3c4c5c6c7c(cccc7ccc6n(-c6ncccn6)c5cc32)-c2ccccc2-4)cc1 ; c1ccc(-c2cc(-c3ccccc3)nc(-n3c4cc5c(c6c4c4c7c(cccc7ccc43)-c3ccccc3-6)c3ccccc3n5-c3ccccc3)n2)cc1 ; c1ccc(-c2nc(-c3ccccc3)nc(-n3c4cc5c(c6c4c4c7c(cccc7ccc43)-c3ccccc3-6)c3ccccc3n5-c3ccccc3)n2)cc1]

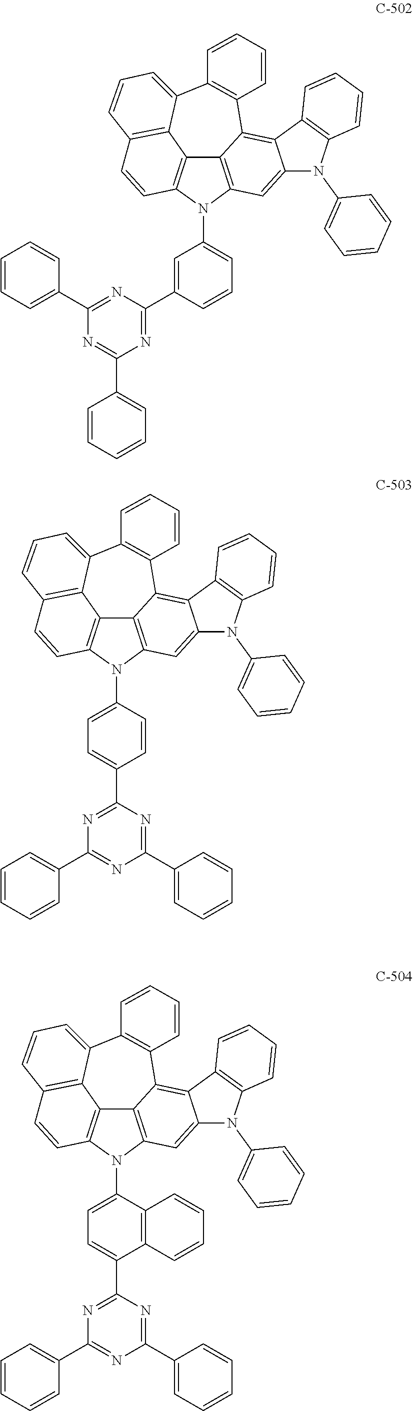 [SMILES: c1ccc(-c2nc(-c3ccccc3)nc(-c3cccc(-n4c5cc6c(c7c5c5c8c(cccc8ccc54)-c4ccccc4-7)c4ccccc4n6-c4ccccc4)c3)n2)cc1 ; c1ccc(-c2nc(-c3ccccc3)nc(-c3ccc(-n4c5cc6c(c7c5c5c8c(cccc8ccc54)-c4ccccc4-7)c4ccccc4n6-c4ccccc4)cc3)n2)cc1 ; c1ccc(-c2nc(-c3ccccc3)nc(-c3ccc(-n4c5cc6c(c7c5c5c8c(cccc8ccc54)-c4ccccc4-7)c4ccccc4n6-c4ccccc4)c4ccccc34)n2)cc1]

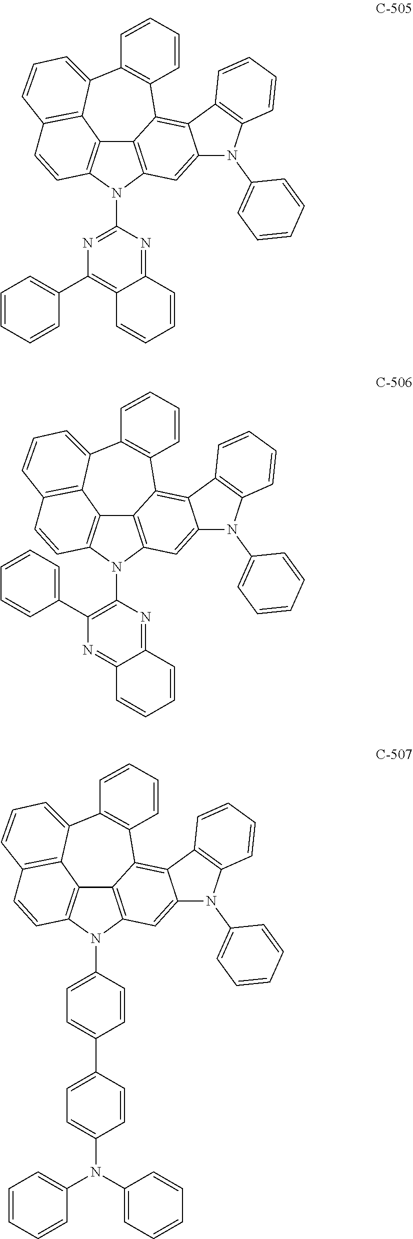 [SMILES: c1ccc(-c2nc(-n3c4cc5c(c6c4c4c7c(cccc7ccc43)-c3ccccc3-6)c3ccccc3n5-c3ccccc3)nc3ccccc23)cc1 ; c1ccc(-c2nc3ccccc3nc2-n2c3cc4c(c5c3c3c6c(cccc6ccc32)-c2ccccc2-5)c2ccccc2n4-c2ccccc2)cc1 ; c1ccc(N(c2ccccc2)c2ccc(-c3ccc(-n4c5cc6c(c7c5c5c8c(cccc8ccc54)-c4ccccc4-7)c4ccccc4n6-c4ccccc4)cc3)cc2)cc1]

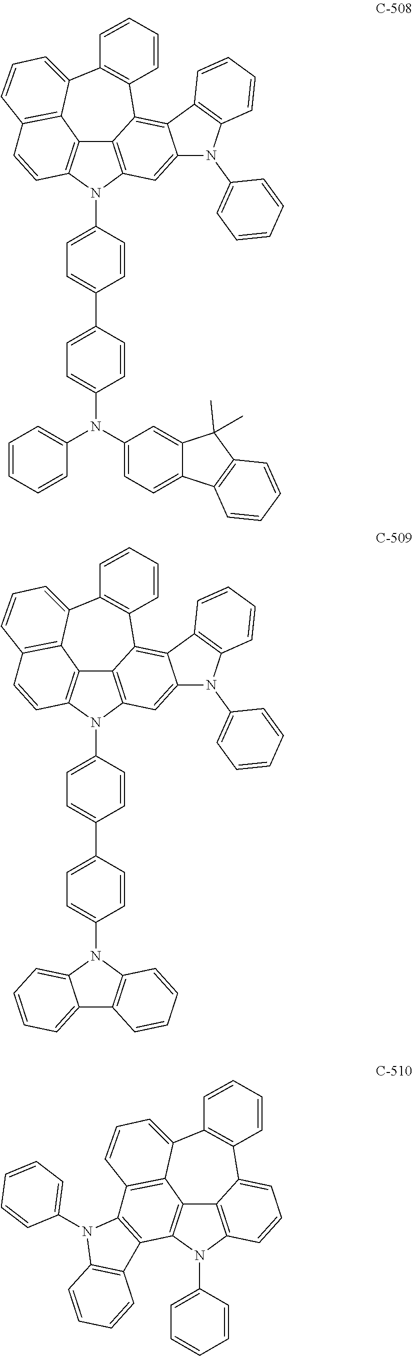

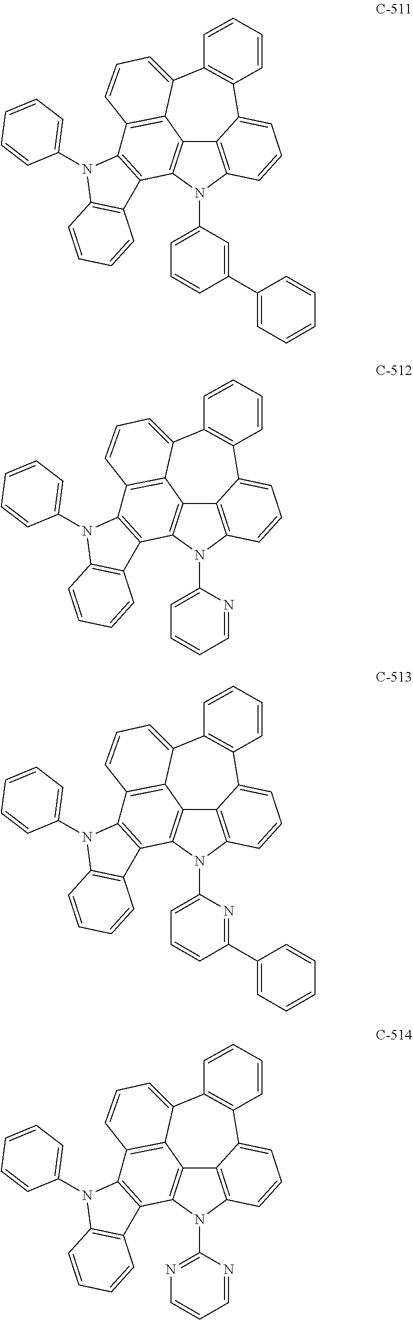

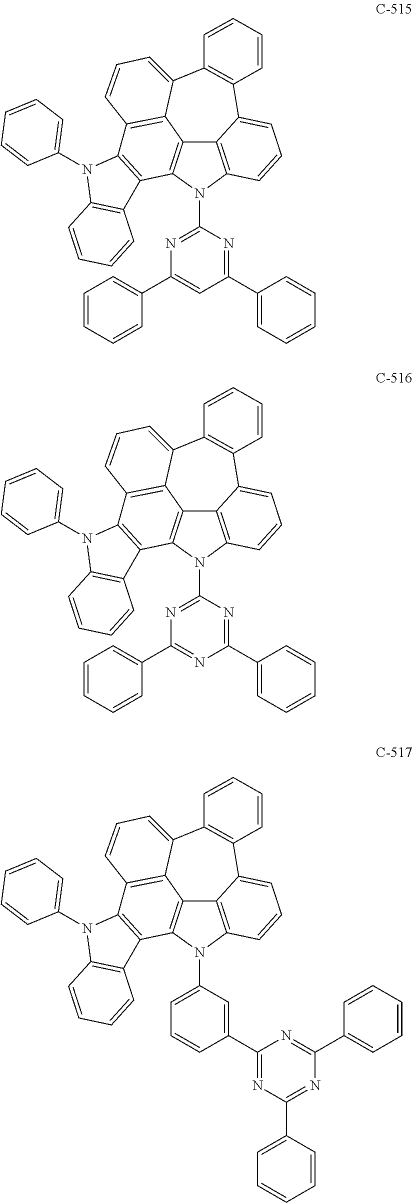 [SMILES: c1ccc(-c2cc(-c3ccccc3)nc(-n3c4cccc5c4c4c6c(cccc6c6c(c7ccccc7n6-c6ccccc6)c43)-c3ccccc3-5)n2)cc1 ; c1ccc(-c2nc(-c3ccccc3)nc(-n3c4cccc5c4c4c6c(cccc6c6c(c7ccccc7n6-c6ccccc6)c43)-c3ccccc3-5)n2)cc1 ; c1ccc(-c2nc(-c3ccccc3)nc(-c3cccc(-n4c5cccc6c5c5c7c(cccc7c7c(c8ccccc8n7-c7ccccc7)c54)-c4ccccc4-6)c3)n2)cc1]

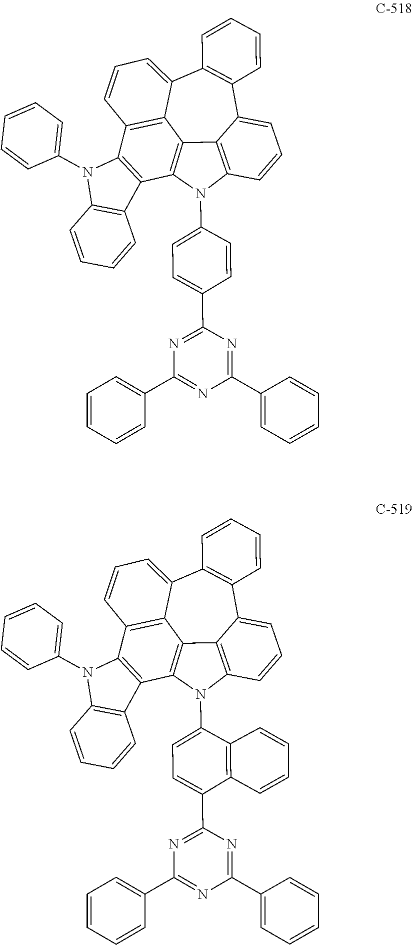 [SMILES: c1ccc(-c2nc(-c3ccccc3)nc(-c3ccc(-n4c5cccc6c5c5c7c(cccc7c7c(c8ccccc8n7-c7ccccc7)c54)-c4ccccc4-6)cc3)n2)cc1 ; c1ccc(-c2nc(-c3ccccc3)nc(-c3ccc(-n4c5cccc6c5c5c7c(cccc7c7c(c8ccccc8n7-c7ccccc7)c54)-c4ccccc4-6)c4ccccc34)n2)cc1]

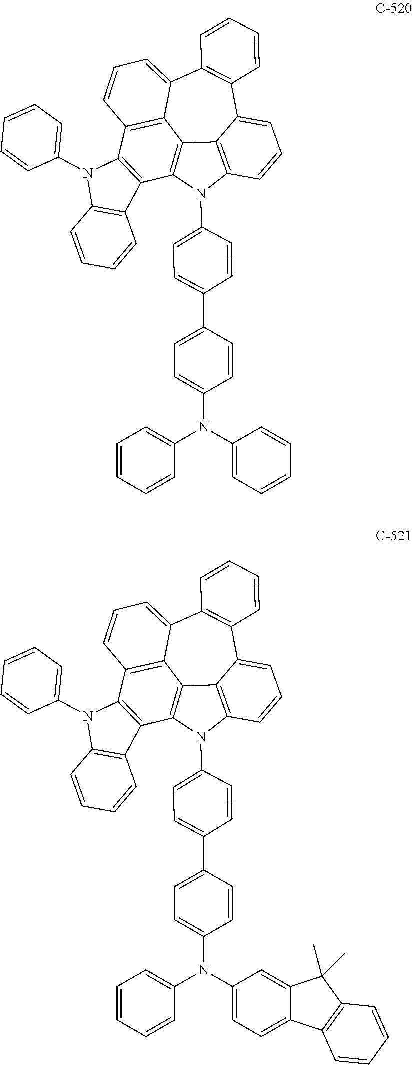 [SMILES: c1ccc(N(c2ccccc2)c2ccc(-c3ccc(-n4c5cccc6c5c5c7c(cccc7c7c(c8ccccc8n7-c7ccccc7)c54)-c4ccccc4-6)cc3)cc2)cc1 ; CC1(C)c2ccccc2-c2ccc(N(c3ccccc3)c3ccc(-c4ccc(-n5c6cccc7c6c6c8c(cccc8c8c(c9ccccc9n8-c8ccccc8)c65)-c5ccccc5-7)cc4)cc3)cc21]

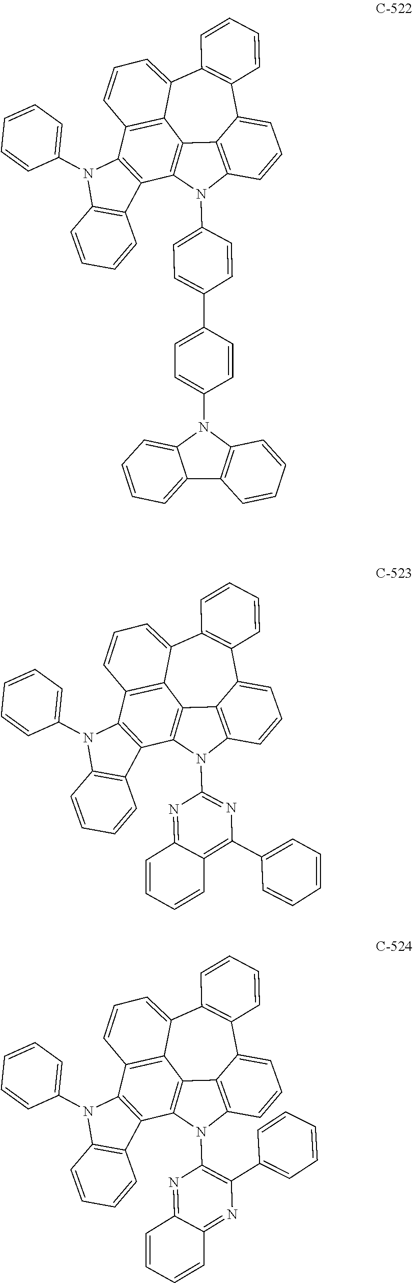 [SMILES: c1ccc(-n2c3ccccc3c3c2c2cccc4c2c2c5c(cccc5n(-c5ccc(-c6ccc(-n7c8ccccc8c8ccccc87)cc6)cc5)c23)-c2ccccc2-4)cc1 ; c1ccc(-c2nc(-n3c4cccc5c4c4c6c(cccc6c6c(c7ccccc7n6-c6ccccc6)c43)-c3ccccc3-5)nc3ccccc23)cc1 ; c1ccc(-c2nc3ccccc3nc2-n2c3cccc4c3c3c5c(cccc5c5c(c6ccccc6n5-c5ccccc5)c32)-c2ccccc2-4)cc1]

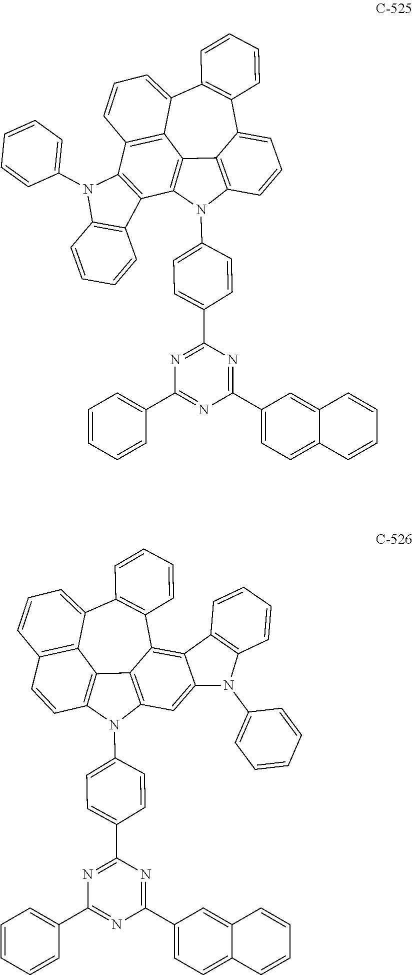 [SMILES: c1ccc(-c2nc(-c3ccc(-n4c5cccc6c5c5c7c(cccc7c7c(c8ccccc8n7-c7ccccc7)c54)-c4ccccc4-6)cc3)nc(-c3ccc4ccccc4c3)n2)cc1 ; c1ccc(-c2nc(-c3ccc(-n4c5cc6c(c7c5c5c8c(cccc8ccc54)-c4ccccc4-7)c4ccccc4n6-c4ccccc4)cc3)nc(-c3ccc4ccccc4c3)n2)cc1]

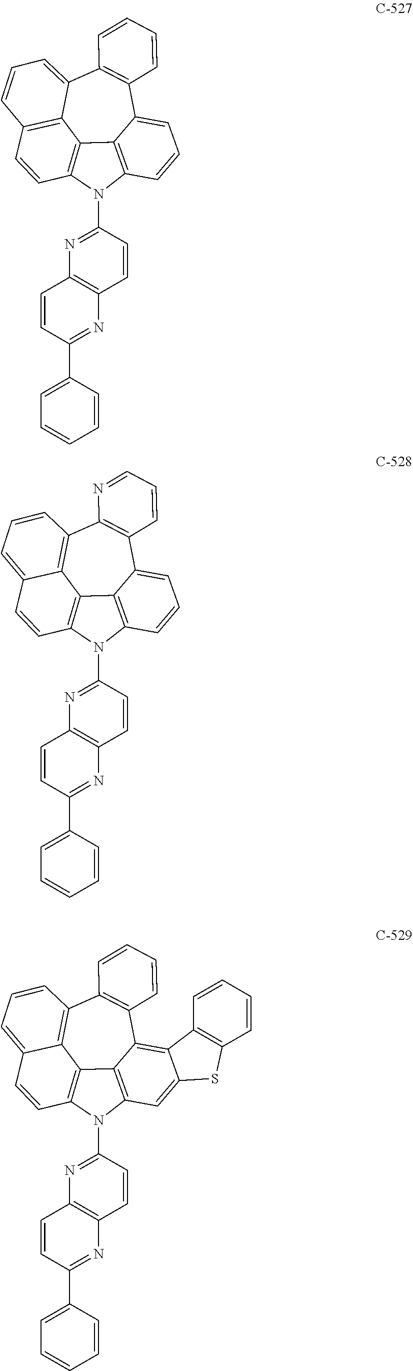 [SMILES: c1ccc(-c2ccc3nc(-n4c5cccc6c5c5c7c(cccc7ccc54)-c4ccccc4-6)ccc3n2)cc1 ; c1ccc(-c2ccc3nc(-n4c5cccc6c5c5c7c(cccc7ccc54)-c4ncccc4-6)ccc3n2)cc1 ; c1ccc(-c2ccc3nc(-n4c5cc6sc7ccccc7c6c6c5c5c7c(cccc7ccc54)-c4ccccc4-6)ccc3n2)cc1]

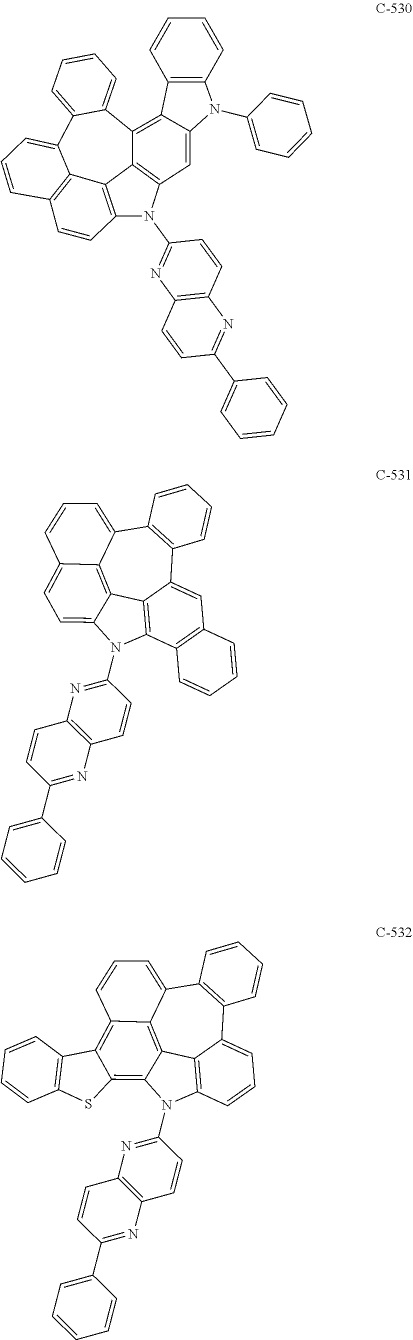 [SMILES: c1ccc(-c2ccc3nc(-n4c5cc6c(c7c5c5c8c(cccc8ccc54)-c4ccccc4-7)c4ccccc4n6-c4ccccc4)ccc3n2)cc1 ; c1ccc(-c2ccc3nc(-n4c5ccc6cccc7c6c5c5c(cc6ccccc6c54)-c4ccccc4-7)ccc3n2)cc1 ; c1ccc(-c2ccc3nc(-n4c5cccc6c5c5c7c(cccc7c7c8ccccc8sc7c54)-c4ccccc4-6)ccc3n2)cc1]

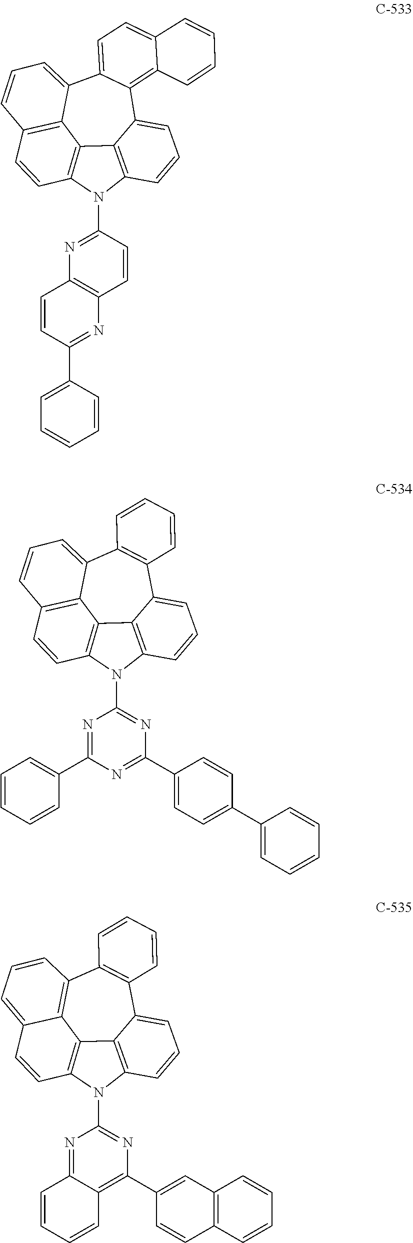 [SMILES: c1ccc(-c2ccc3nc(-n4c5cccc6c5c5c7c(cccc7ccc54)-c4ccc5ccccc5c4-6)ccc3n2)cc1 ; c1ccc(-c2ccc(-c3nc(-c4ccccc4)nc(-n4c5cccc6c5c5c7c(cccc7ccc54)-c4ccccc4-6)n3)cc2)cc1 ; c1ccc2c(c1)-c1cccc3ccc4c(c13)c1c-2cccc1n4-c1nc(-c2ccc3ccccc3c2)c2ccccc2n1]

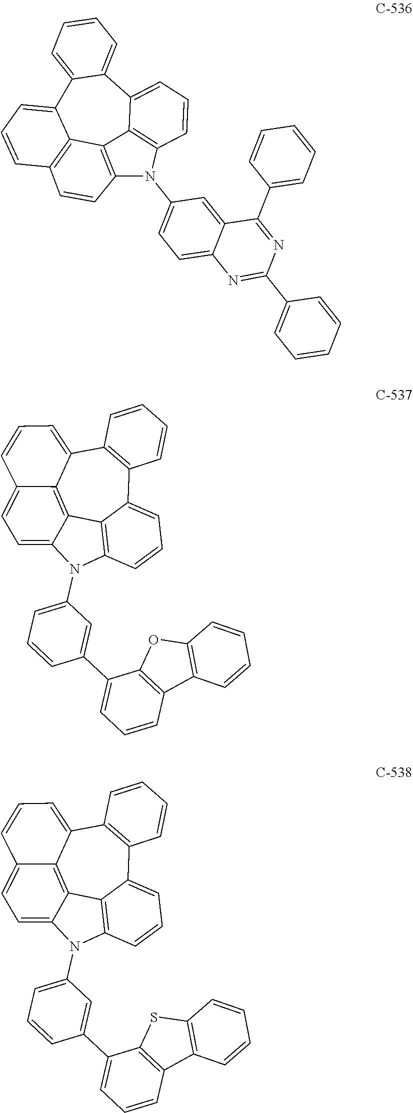 [SMILES: c1ccc(-c2nc(-c3ccccc3)c3cc(-n4c5cccc6c5c5c7c(cccc7ccc54)-c4ccccc4-6)ccc3n2)cc1 ; c1cc(-c2cccc3c2oc2ccccc23)cc(-n2c3cccc4c3c3c5c(cccc5ccc32)-c2ccccc2-4)c1 ; c1cc(-c2cccc3c2sc2ccccc23)cc(-n2c3cccc4c3c3c5c(cccc5ccc32)-c2ccccc2-4)c1]

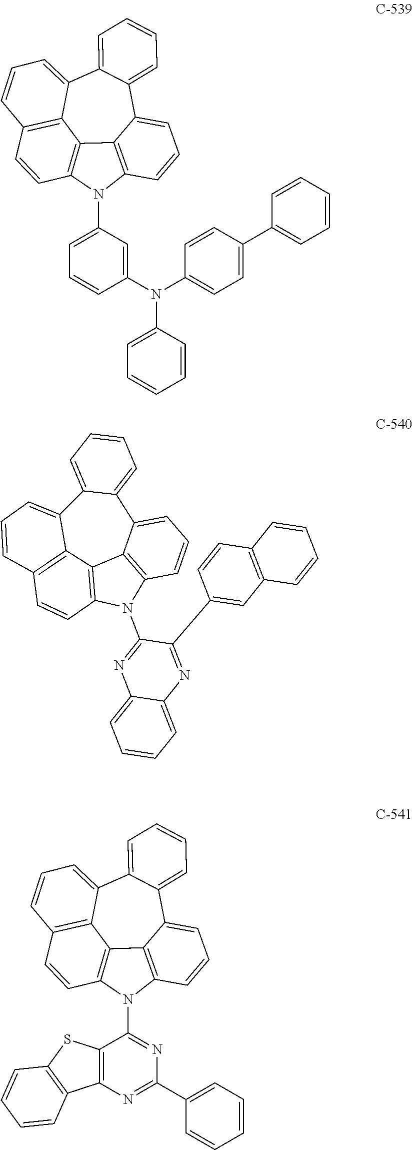 [SMILES: c1ccc(-c2ccc(N(c3ccccc3)c3cccc(-n4c5cccc6c5c5c7c(cccc7ccc54)-c4ccccc4-6)c3)cc2)cc1 ; c1ccc2c(c1)-c1cccc3ccc4c(c13)c1c-2cccc1n4-c1nc2ccccc2nc1-c1ccc2ccccc2c1 ; c1ccc(-c2nc(-n3c4cccc5c4c4c6c(cccc6ccc43)-c3ccccc3-5)c3sc4ccccc4c3n2)cc1]

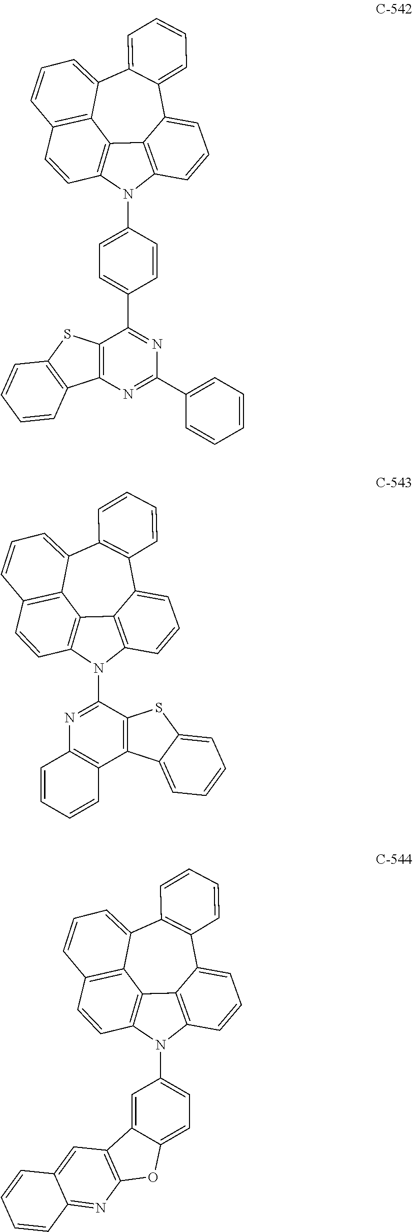 [SMILES: c1ccc(-c2nc(-c3ccc(-n4c5cccc6c5c5c7c(cccc7ccc54)-c4ccccc4-6)cc3)c3sc4ccccc4c3n2)cc1 ; c1ccc2c(c1)-c1cccc3ccc4c(c13)c1c-2cccc1n4-c1nc2ccccc2c2c1sc1ccccc12 ; c1ccc2c(c1)-c1cccc3ccc4c(c13)c1c-2cccc1n4-c1ccc2oc3nc4ccccc4cc3c2c1]

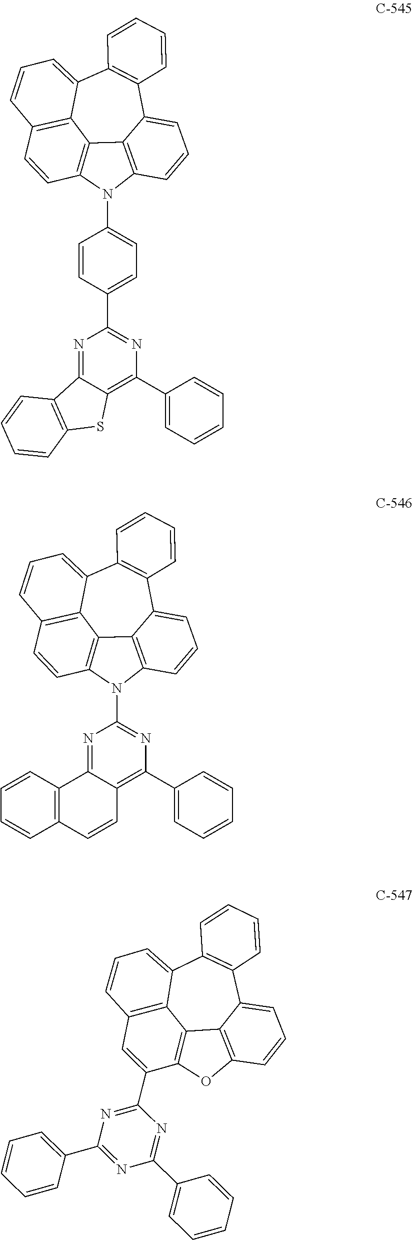 [SMILES: c1ccc(-c2nc(-c3ccc(-n4c5cccc6c5c5c7c(cccc7ccc54)-c4ccccc4-6)cc3)nc3c2sc2ccccc23)cc1 ; c1ccc(-c2nc(-n3c4cccc5c4c4c6c(cccc6ccc43)-c3ccccc3-5)nc3c2ccc2ccccc23)cc1 ; c1ccc(-c2nc(-c3ccccc3)nc(-c3cc4cccc5c4c4c3oc3cccc(c34)-c3ccccc3-5)n2)cc1]

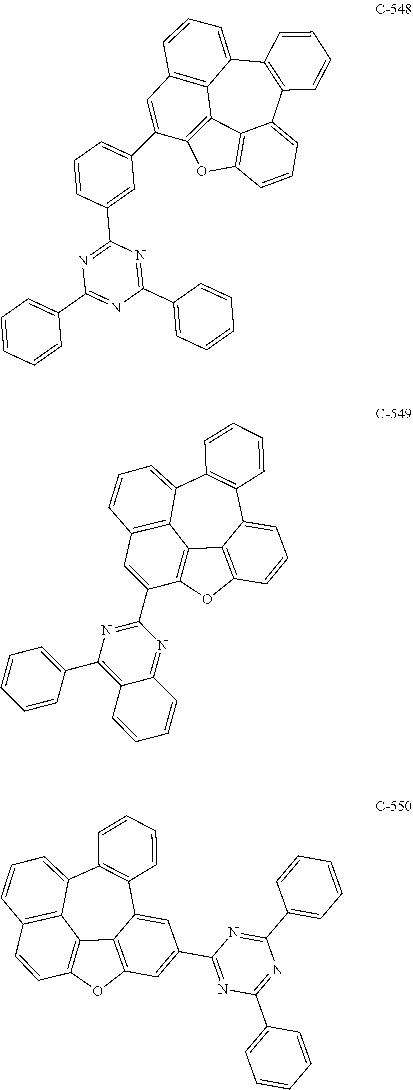 [SMILES: c1ccc(-c2nc(-c3ccccc3)nc(-c3cccc(-c4cc5cccc6c5c5c4oc4cccc(c45)-c4ccccc4-6)c3)n2)cc1 ; c1ccc(-c2nc(-c3cc4cccc5c4c4c3oc3cccc(c34)-c3ccccc3-5)nc3ccccc23)cc1 ; c1ccc(-c2nc(-c3ccccc3)nc(-c3cc4c5c(c3)oc3ccc6cccc(c6c35)-c3ccccc3-4)n2)cc1]

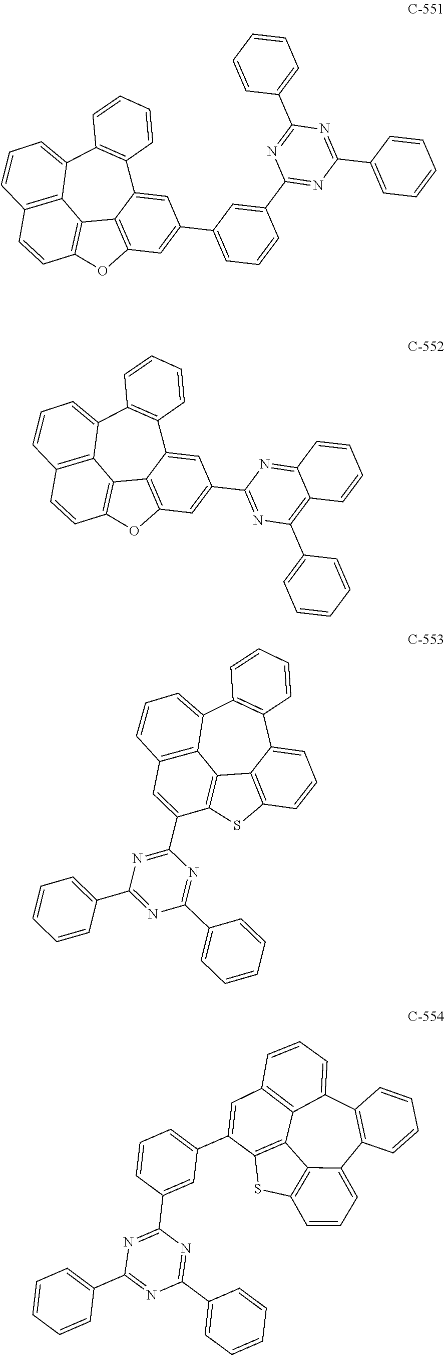 [SMILES: c1ccc(-c2nc(-c3ccccc3)nc(-c3cccc(-c4cc5c6c(c4)oc4ccc7cccc(c7c46)-c4ccccc4-5)c3)n2)cc1 ; c1ccc(-c2nc(-c3cc4c5c(c3)oc3ccc6cccc(c6c35)-c3ccccc3-4)nc3ccccc23)cc1 ; c1ccc(-c2nc(-c3ccccc3)nc(-c3cc4cccc5c4c4c3sc3cccc(c34)-c3ccccc3-5)n2)cc1 ; c1ccc(-c2nc(-c3ccccc3)nc(-c3cccc(-c4cc5cccc6c5c5c4sc4cccc(c45)-c4ccccc4-6)c3)n2)cc1]

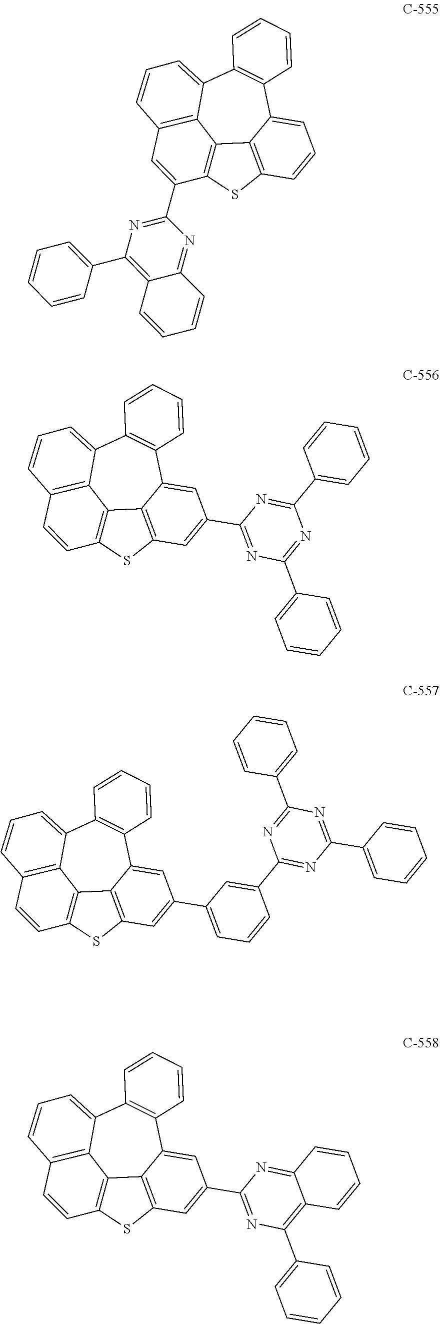 [SMILES: c1ccc(-c2nc(-c3cc4cccc5c4c4c3sc3cccc(c34)-c3ccccc3-5)nc3ccccc23)cc1 ; c1ccc(-c2nc(-c3ccccc3)nc(-c3cc4c5c(c3)sc3ccc6cccc(c6c35)-c3ccccc3-4)n2)cc1 ; c1ccc(-c2nc(-c3ccccc3)nc(-c3cccc(-c4cc5c6c(c4)sc4ccc7cccc(c7c46)-c4ccccc4-5)c3)n2)cc1 ; c1ccc(-c2nc(-c3cc4c5c(c3)sc3ccc6cccc(c6c35)-c3ccccc3-4)nc3ccccc23)cc1]

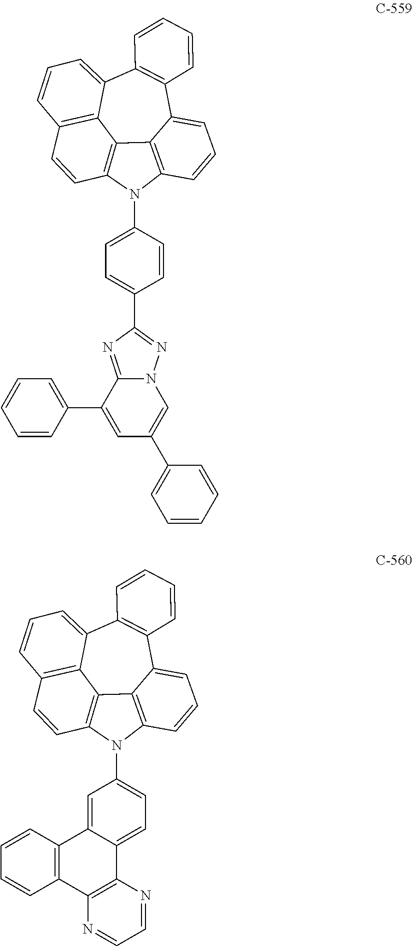 [SMILES: c1ccc(-c2cc(-c3ccccc3)c3nc(-c4ccc(-n5c6cccc7c6c6c8c(cccc8ccc65)-c5ccccc5-7)cc4)nn3c2)cc1 ; c1ccc2c(c1)-c1cccc3ccc4c(c13)c1c-2cccc1n4-c1ccc2c(c1)c1ccccc1c1nccnc21]

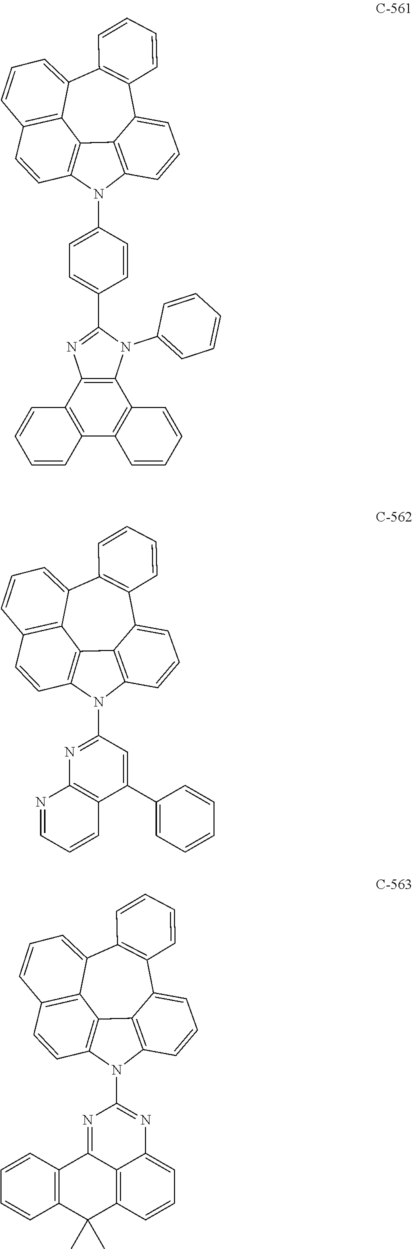 [SMILES: c1ccc(-n2c(-c3ccc(-n4c5cccc6c5c5c7c(cccc7ccc54)-c4ccccc4-6)cc3)nc3c4ccccc4c4ccccc4c32)cc1 ; c1ccc(-c2cc(-n3c4cccc5c4c4c6c(cccc6ccc43)-c3ccccc3-5)nc3ncccc23)cc1 ; CC1(C)c2ccccc2-c2nc(-n3c4cccc5c4c4c6c(cccc6ccc43)-c3ccccc3-5)nc3cccc1c23]

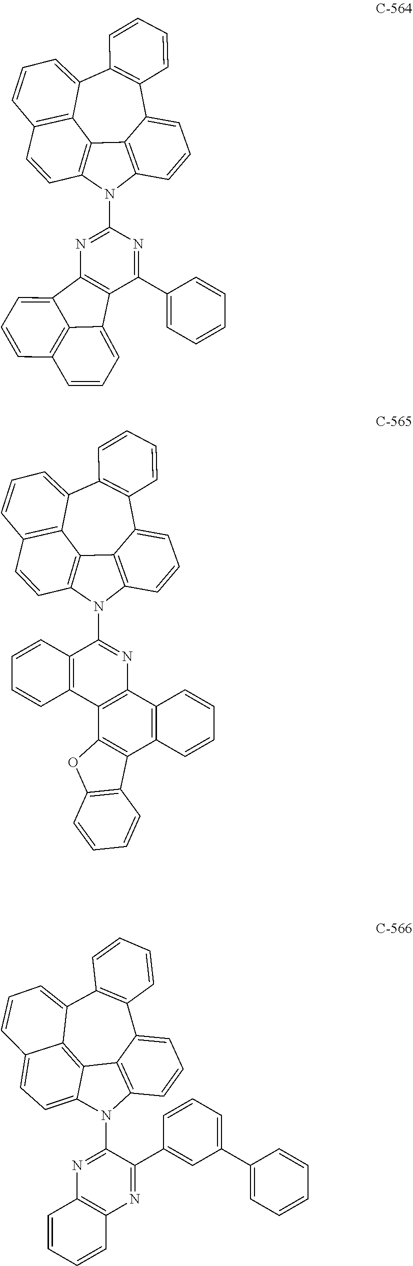 [SMILES: c1ccc(-c2nc(-n3c4cccc5c4c4c6c(cccc6ccc43)-c3ccccc3-5)nc3c2-c2cccc4cccc-3c24)cc1 ; c1ccc2c(c1)-c1cccc3ccc4c(c13)c1c-2cccc1n4-c1nc2c3ccccc3c3c4ccccc4oc3c2c2ccccc12 ; c1ccc(-c2cccc(-c3nc4ccccc4nc3-n3c4cccc5c4c4c6c(cccc6ccc43)-c3ccccc3-5)c2)cc1]

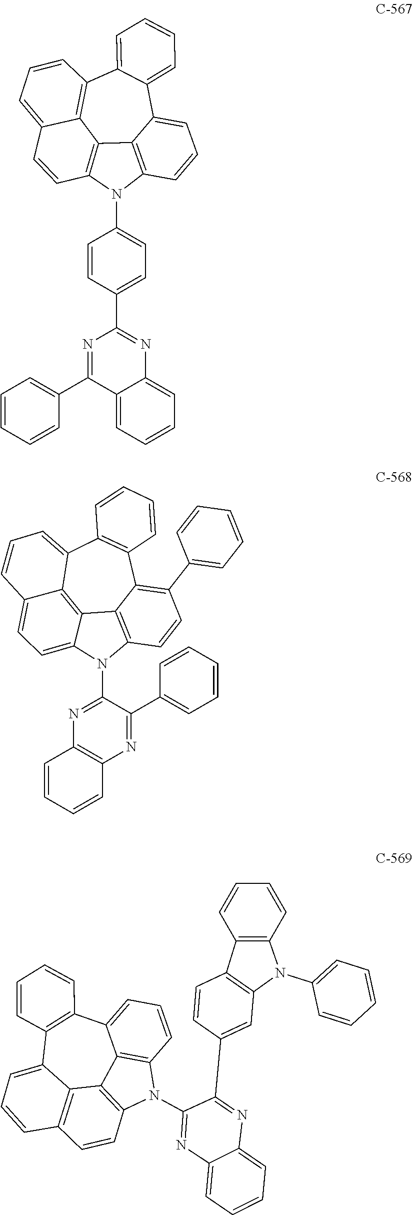 [SMILES: c1ccc(-c2nc(-c3ccc(-n4c5cccc6c5c5c7c(cccc7ccc54)-c4ccccc4-6)cc3)nc3ccccc23)cc1 ; c1ccc(-c2ccc3c4c2-c2ccccc2-c2cccc5ccc(c4c25)n3-c2nc3ccccc3nc2-c2ccccc2)cc1 ; c1ccc(-n2c3ccccc3c3ccc(-c4nc5ccccc5nc4-n4c5cccc6c5c5c7c(cccc7ccc54)-c4ccccc4-6)cc32)cc1]

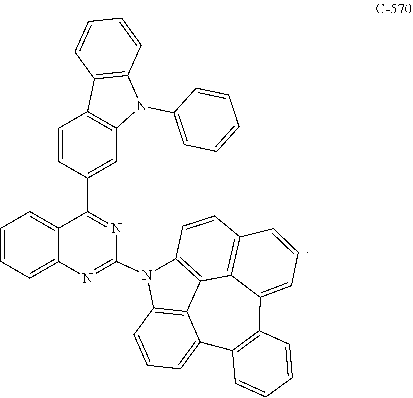 [SMILES: c1ccc(-n2c3ccccc3c3ccc(-c4nc(-n5c6cccc7c6c6c8c(cccc8ccc65)-c5ccccc5-7)nc5ccccc45)cc32)cc1]

The compound represented by formula 11 includes the following compounds, but is not limited thereto:

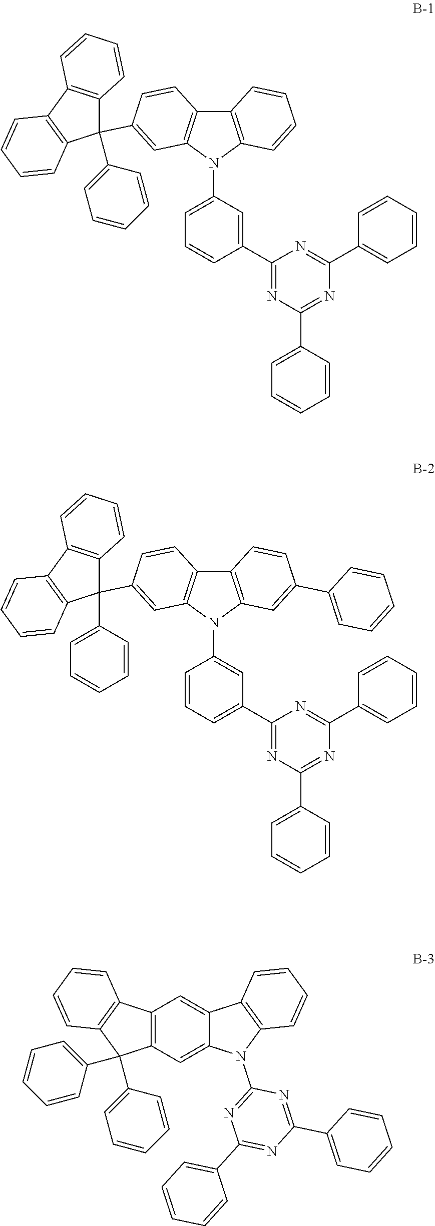 [SMILES: c1ccc(-c2nc(-c3ccccc3)nc(-c3cccc(-n4c5ccccc5c5ccc(C6(c7ccccc7)c7ccccc7-c7ccccc76)cc54)c3)n2)cc1 ; c1ccc(-c2ccc3c4ccc(C5(c6ccccc6)c6ccccc6-c6ccccc65)cc4n(-c4cccc(-c5nc(-c6ccccc6)nc(-c6ccccc6)n5)c4)c3c2)cc1 ; c1ccc(-c2nc(-c3ccccc3)nc(-n3c4ccccc4c4cc5c(cc43)C(c3ccccc3)(c3ccccc3)c3ccccc3-5)n2)cc1]

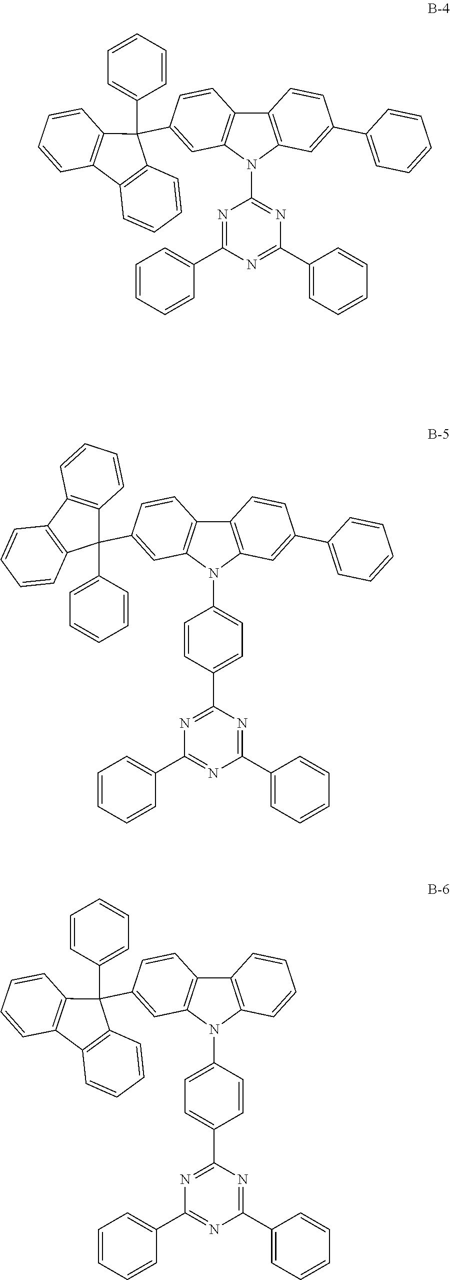 [SMILES: c1ccc(-c2ccc3c4ccc(C5(c6ccccc6)c6ccccc6-c6ccccc65)cc4n(-c4nc(-c5ccccc5)nc(-c5ccccc5)n4)c3c2)cc1 ; c1ccc(-c2ccc3c4ccc(C5(c6ccccc6)c6ccccc6-c6ccccc65)cc4n(-c4ccc(-c5nc(-c6ccccc6)nc(-c6ccccc6)n5)cc4)c3c2)cc1 ; c1ccc(-c2nc(-c3ccccc3)nc(-c3ccc(-n4c5ccccc5c5ccc(C6(c7ccccc7)c7ccccc7-c7ccccc76)cc54)cc3)n2)cc1]

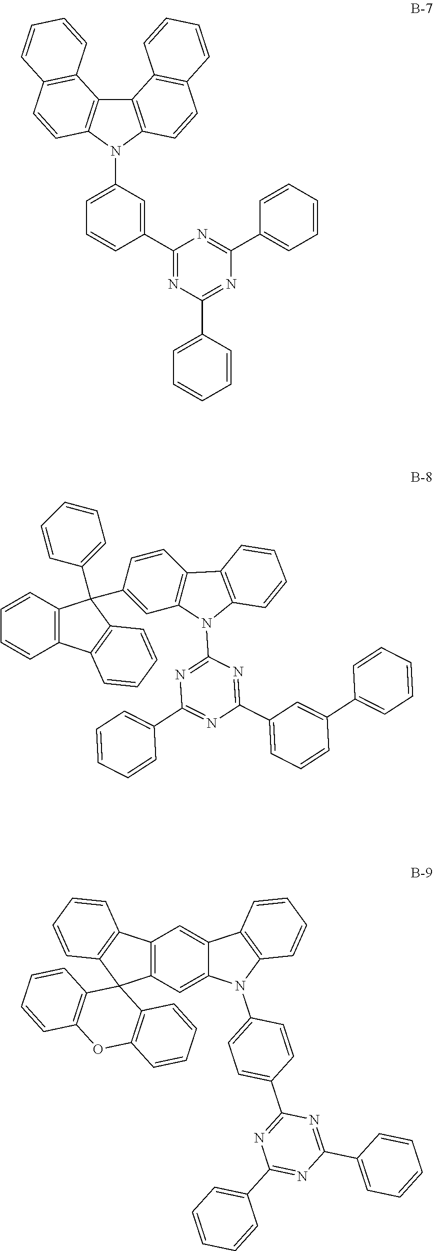 [SMILES: c1ccc(-c2nc(-c3ccccc3)nc(-c3cccc(-n4c5ccc6ccccc6c5c5c6ccccc6ccc54)c3)n2)cc1 ; c1ccc(-c2cccc(-c3nc(-c4ccccc4)nc(-n4c5ccccc5c5ccc(C6(c7ccccc7)c7ccccc7-c7ccccc76)cc54)n3)c2)cc1 ; c1ccc(-c2nc(-c3ccccc3)nc(-c3ccc(-n4c5ccccc5c5cc6c(cc54)C4(c5ccccc5Oc5ccccc54)c4ccccc4-6)cc3)n2)cc1]

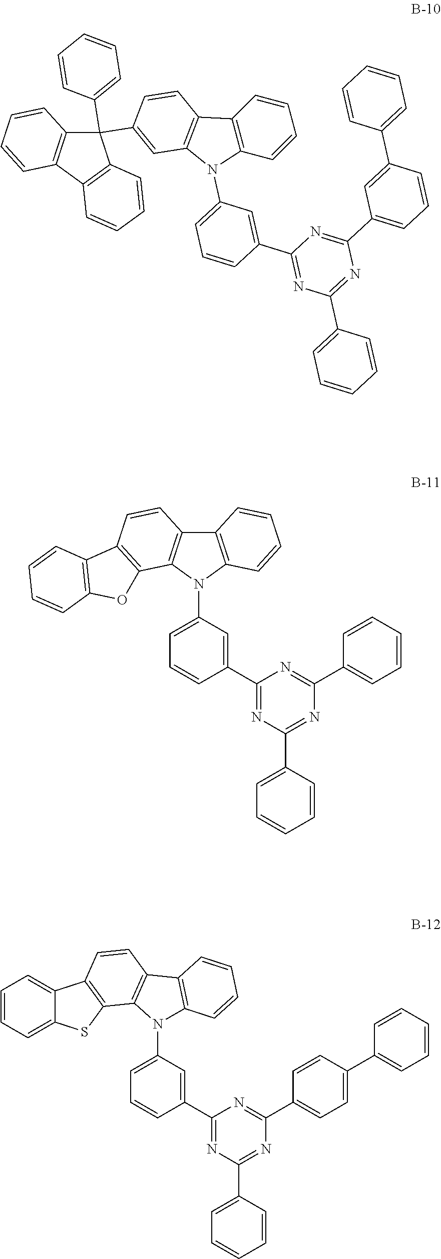 [SMILES: c1ccc(-c2cccc(-c3nc(-c4ccccc4)nc(-c4cccc(-n5c6ccccc6c6ccc(C7(c8ccccc8)c8ccccc8-c8ccccc87)cc65)c4)n3)c2)cc1 ; c1ccc(-c2nc(-c3ccccc3)nc(-c3cccc(-n4c5ccccc5c5ccc6c7ccccc7oc6c54)c3)n2)cc1 ; c1ccc(-c2ccc(-c3nc(-c4ccccc4)nc(-c4cccc(-n5c6ccccc6c6ccc7c8ccccc8sc7c65)c4)n3)cc2)cc1]

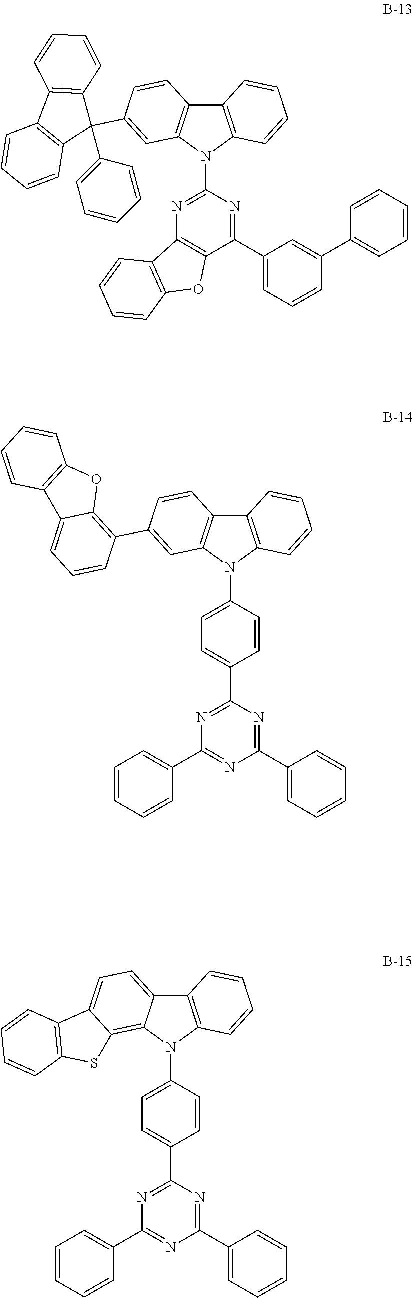 [SMILES: c1ccc(-c2cccc(-c3nc(-n4c5ccccc5c5ccc(C6(c7ccccc7)c7ccccc7-c7ccccc76)cc54)nc4c3oc3ccccc34)c2)cc1 ; c1ccc(-c2nc(-c3ccccc3)nc(-c3ccc(-n4c5ccccc5c5ccc(-c6cccc7c6oc6ccccc67)cc54)cc3)n2)cc1 ; c1ccc(-c2nc(-c3ccccc3)nc(-c3ccc(-n4c5ccccc5c5ccc6c7ccccc7sc6c54)cc3)n2)cc1]

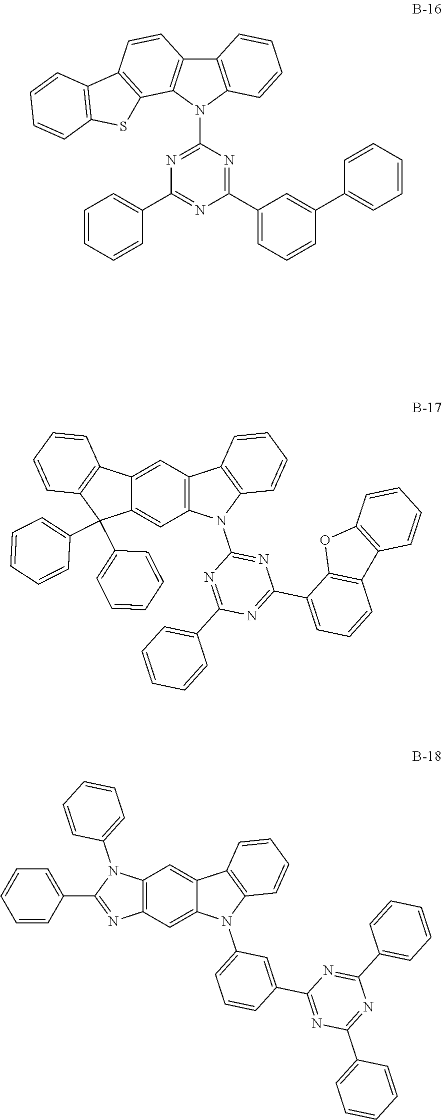 [SMILES: c1ccc(-c2cccc(-c3nc(-c4ccccc4)nc(-n4c5ccccc5c5ccc6c7ccccc7sc6c54)n3)c2)cc1 ; c1ccc(-c2nc(-c3cccc4c3oc3ccccc34)nc(-n3c4ccccc4c4cc5c(cc43)C(c3ccccc3)(c3ccccc3)c3ccccc3-5)n2)cc1 ; c1ccc(-c2nc(-c3ccccc3)nc(-c3cccc(-n4c5ccccc5c5cc6c(cc54)nc(-c4ccccc4)n6-c4ccccc4)c3)n2)cc1]

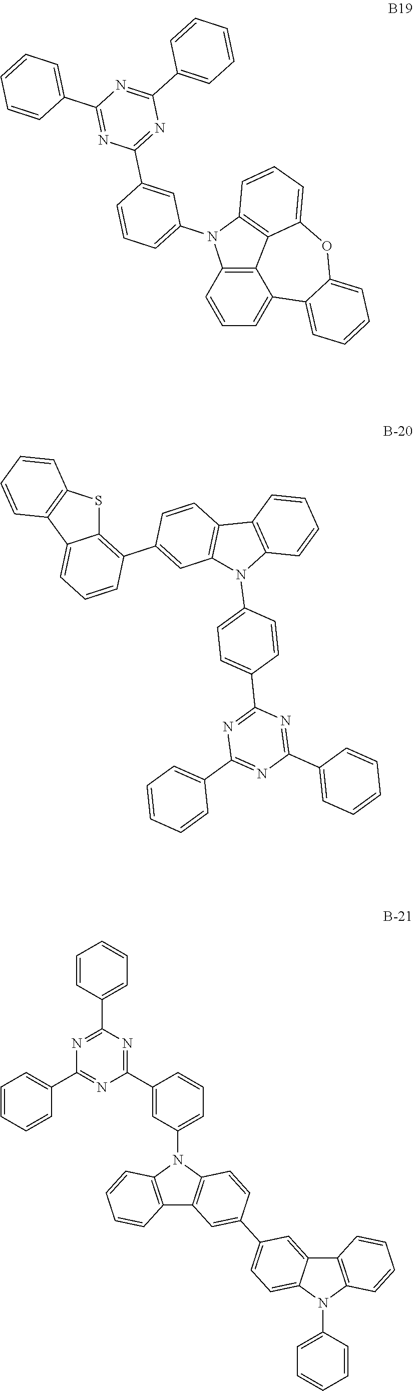 [SMILES: c1ccc(-c2nc(-c3ccccc3)nc(-c3cccc(-n4c5cccc6oc7ccccc7c7cccc4c7c65)c3)n2)cc1 ; c1ccc(-c2nc(-c3ccccc3)nc(-c3ccc(-n4c5ccccc5c5ccc(-c6cccc7c6sc6ccccc67)cc54)cc3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

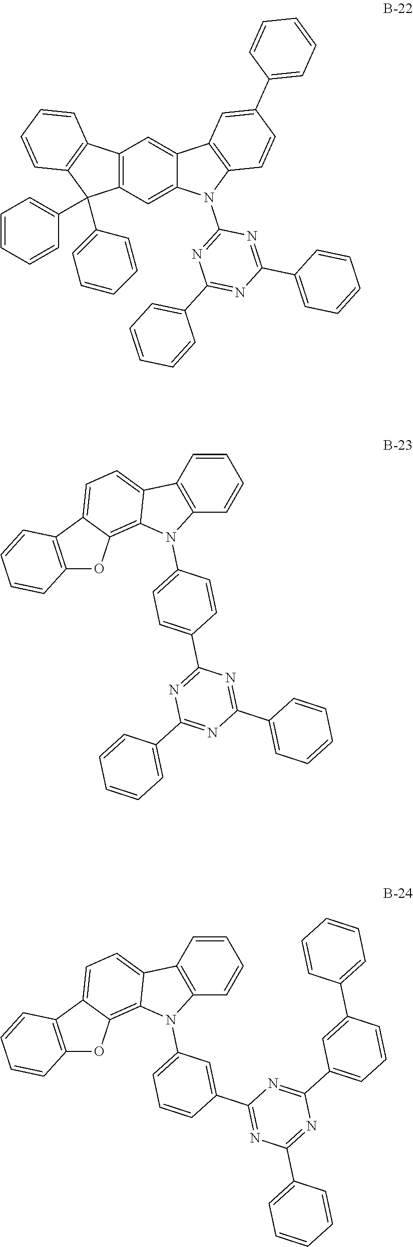 [SMILES: c1ccc(-c2ccc3c(c2)c2cc4c(cc2n3-c2nc(-c3ccccc3)nc(-c3ccccc3)n2)C(c2ccccc2)(c2ccccc2)c2ccccc2-4)cc1 ; c1ccc(-c2nc(-c3ccccc3)nc(-c3ccc(-n4c5ccccc5c5ccc6c7ccccc7oc6c54)cc3)n2)cc1 ; c1ccc(-c2cccc(-c3nc(-c4ccccc4)nc(-c4cccc(-n5c6ccccc6c6ccc7c8ccccc8oc7c65)c4)n3)c2)cc1]

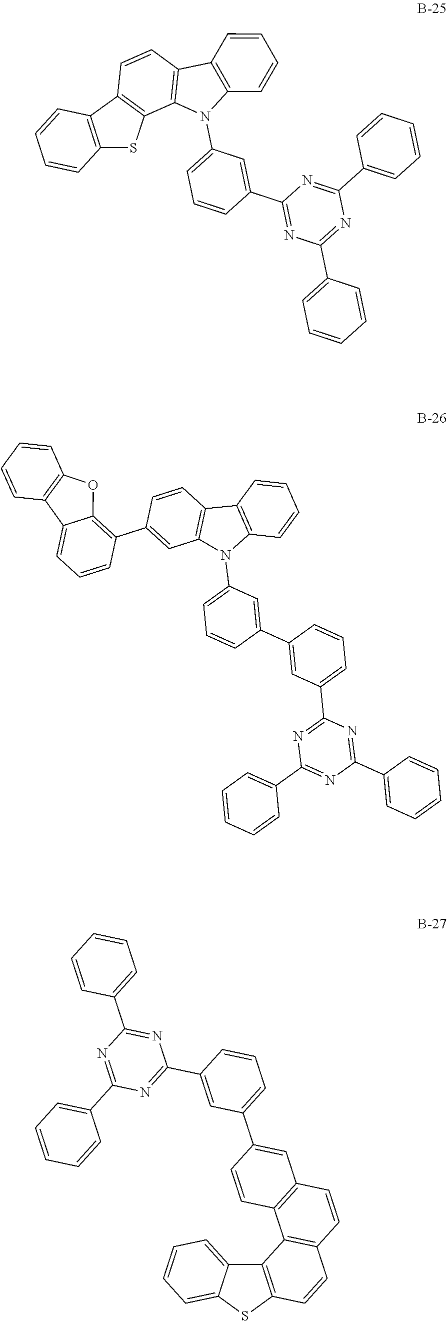 [SMILES: c1ccc(-c2nc(-c3ccccc3)nc(-c3cccc(-n4c5ccccc5c5ccc6c7ccccc7sc6c54)c3)n2)cc1 ; c1ccc(-c2nc(-c3ccccc3)nc(-c3cccc(-c4cccc(-n5c6ccccc6c6ccc(-c7cccc8c7oc7ccccc78)cc65)c4)c3)n2)cc1 ; c1ccc(-c2nc(-c3ccccc3)nc(-c3cccc(-c4ccc5c(ccc6ccc7sc8ccccc8c7c65)c4)c3)n2)cc1]

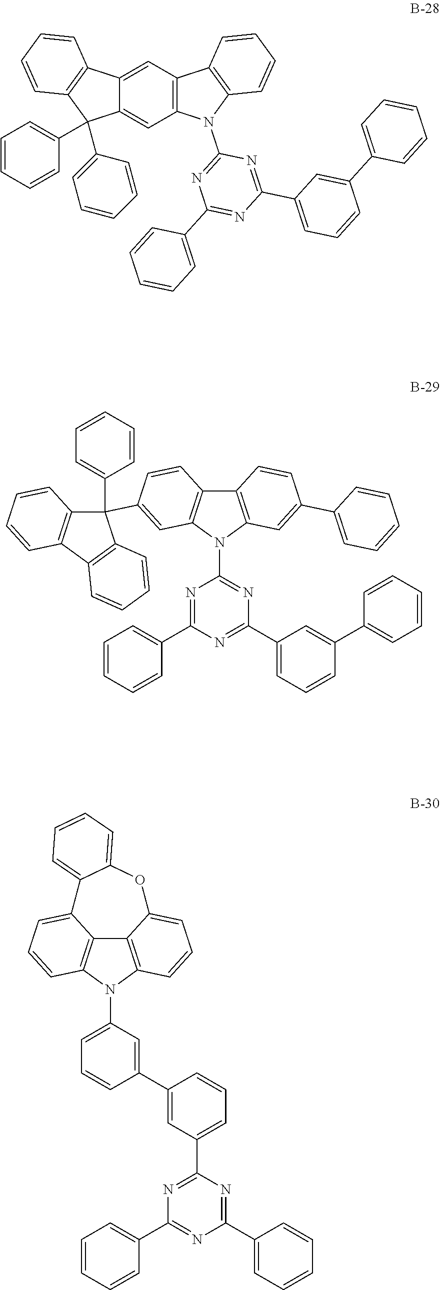 [SMILES: c1ccc(-c2cccc(-c3nc(-c4ccccc4)nc(-n4c5ccccc5c5cc6c(cc54)C(c4ccccc4)(c4ccccc4)c4ccccc4-6)n3)c2)cc1 ; c1ccc(-c2cccc(-c3nc(-c4ccccc4)nc(-n4c5cc(-c6ccccc6)ccc5c5ccc(C6(c7ccccc7)c7ccccc7-c7ccccc76)cc54)n3)c2)cc1 ; c1ccc(-c2nc(-c3ccccc3)nc(-c3cccc(-c4cccc(-n5c6cccc7oc8ccccc8c8cccc5c8c76)c4)c3)n2)cc1]

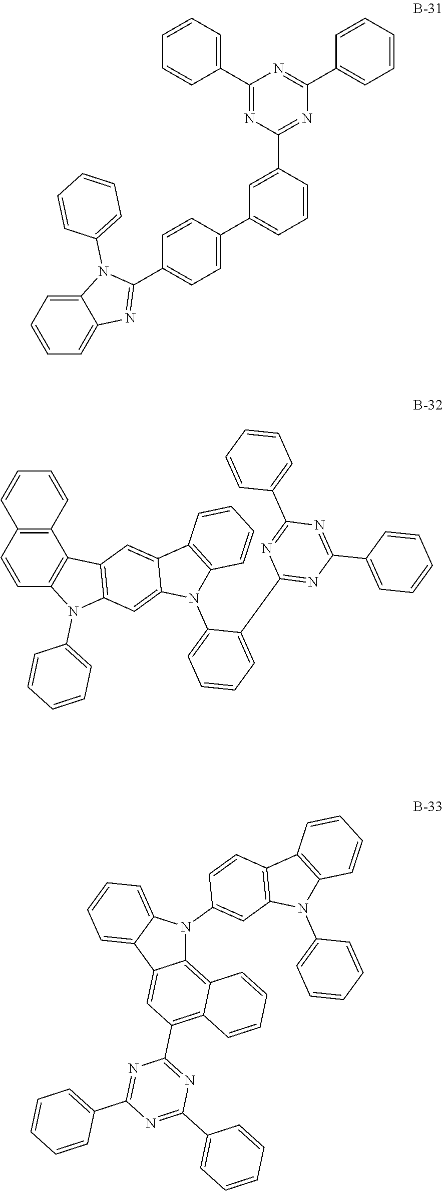 [SMILES: c1ccc(-c2nc(-c3ccccc3)nc(-c3cccc(-c4ccc(-c5nc6ccccc6n5-c5ccccc5)cc4)c3)n2)cc1 ; c1ccc(-c2nc(-c3ccccc3)nc(-c3ccccc3-n3c4ccccc4c4cc5c6c7ccccc7ccc6n(-c6ccccc6)c5cc43)n2)cc1 ; c1ccc(-c2nc(-c3ccccc3)nc(-c3cc4c5ccccc5n(-c5ccc6c7ccccc7n(-c7ccccc7)c6c5)c4c4ccccc34)n2)cc1]

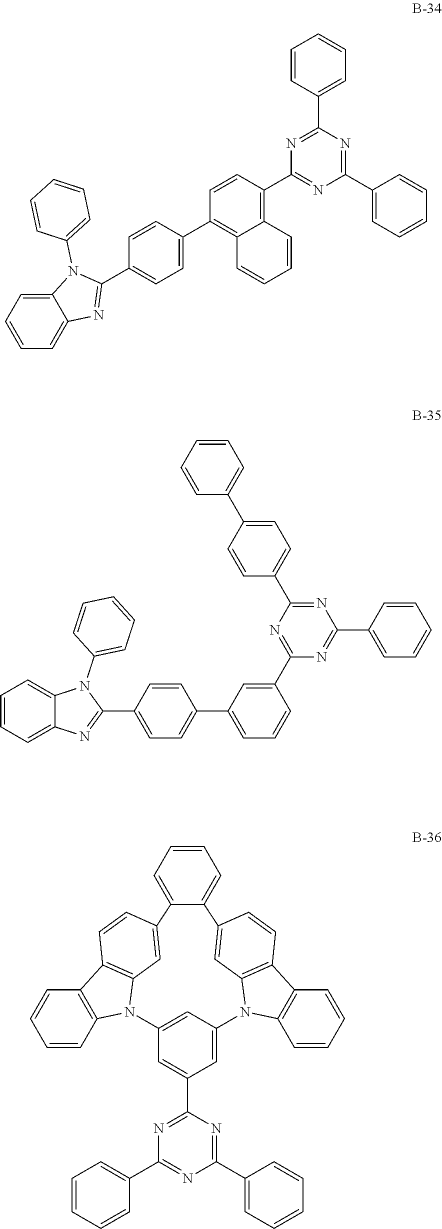 [SMILES: c1ccc(-c2nc(-c3ccccc3)nc(-c3ccc(-c4ccc(-c5nc6ccccc6n5-c5ccccc5)cc4)c4ccccc34)n2)cc1 ; c1ccc(-c2ccc(-c3nc(-c4ccccc4)nc(-c4cccc(-c5ccc(-c6nc7ccccc7n6-c6ccccc6)cc5)c4)n3)cc2)cc1 ; c1ccc(-c2nc(-c3ccccc3)nc(-c3cc4cc(c3)n3c5ccccc5c5ccc(cc53)c3ccccc3c3ccc5c6ccccc6n4c5c3)n2)cc1]

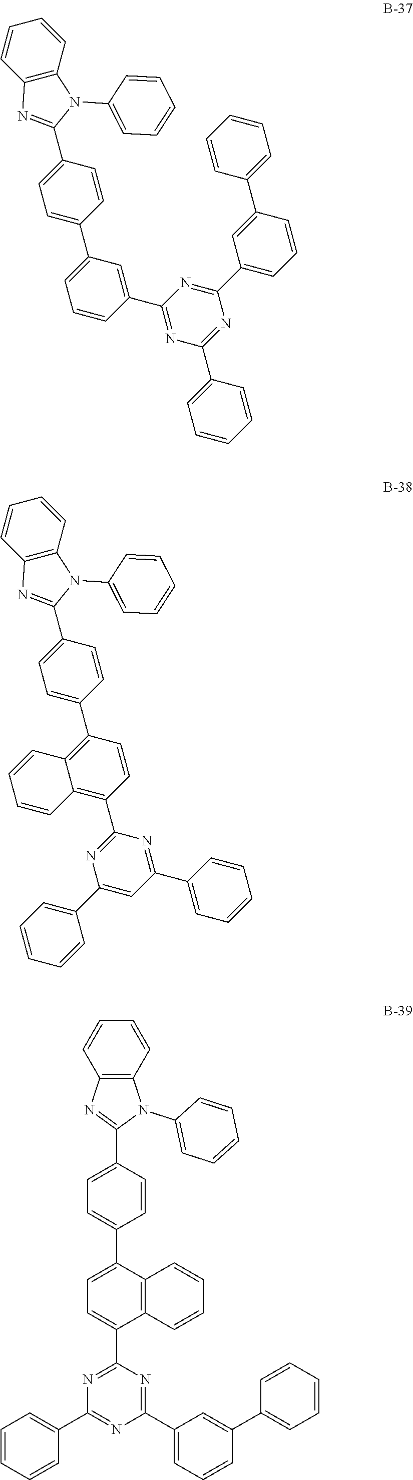 [SMILES: c1ccc(-c2cccc(-c3nc(-c4ccccc4)nc(-c4cccc(-c5ccc(-c6nc7ccccc7n6-c6ccccc6)cc5)c4)n3)c2)cc1 ; c1ccc(-c2cc(-c3ccccc3)nc(-c3ccc(-c4ccc(-c5nc6ccccc6n5-c5ccccc5)cc4)c4ccccc34)n2)cc1 ; c1ccc(-c2cccc(-c3nc(-c4ccccc4)nc(-c4ccc(-c5ccc(-c6nc7ccccc7n6-c6ccccc6)cc5)c5ccccc45)n3)c2)cc1]

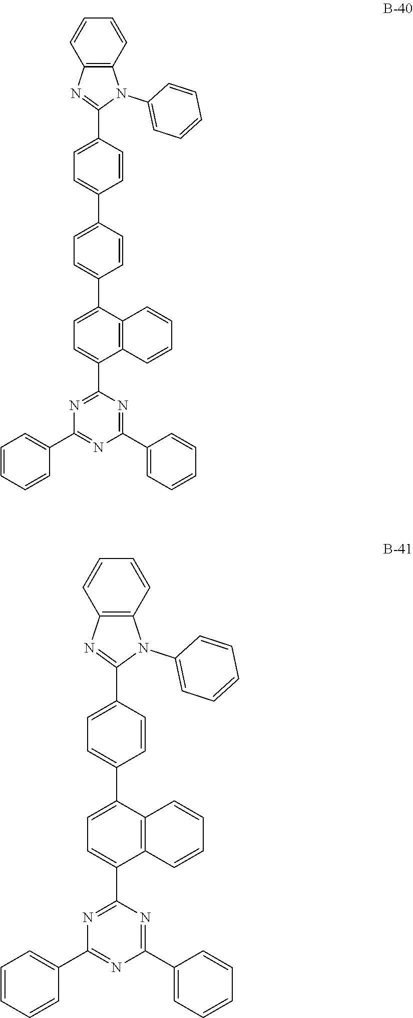 [SMILES: c1ccc(-c2nc(-c3ccccc3)nc(-c3ccc(-c4ccc(-c5ccc(-c6nc7ccccc7n6-c6ccccc6)cc5)cc4)c4ccccc34)n2)cc1 ; c1ccc(-c2nc(-c3ccccc3)nc(-c3ccc(-c4ccc(-c5nc6ccccc6n5-c5ccccc5)cc4)c4ccccc34)n2)cc1]

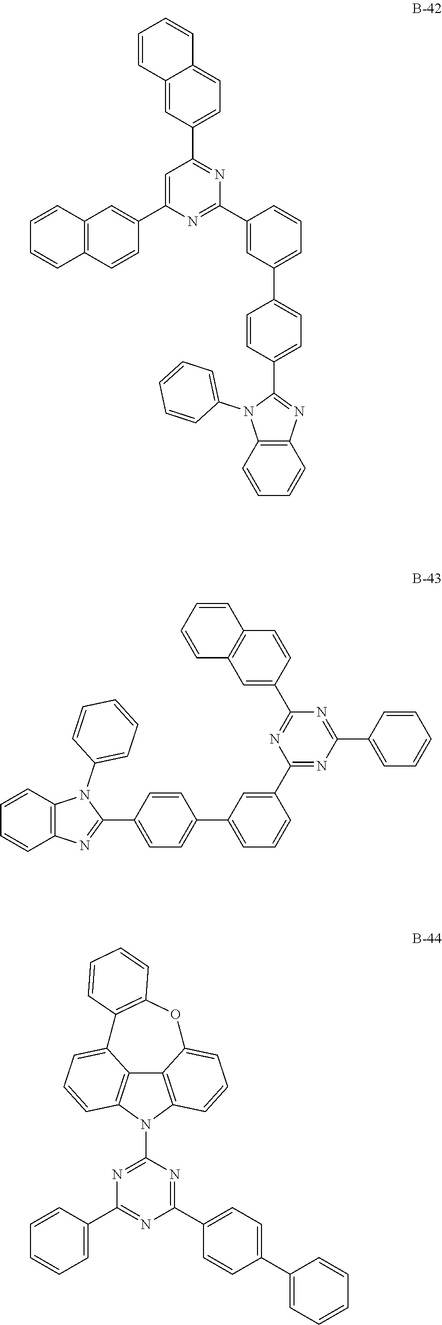 [SMILES: c1ccc(-n2c(-c3ccc(-c4cccc(-c5nc(-c6ccc7ccccc7c6)cc(-c6ccc7ccccc7c6)n5)c4)cc3)nc3ccccc32)cc1 ; c1ccc(-c2nc(-c3cccc(-c4ccc(-c5nc6ccccc6n5-c5ccccc5)cc4)c3)nc(-c3ccc4ccccc4c3)n2)cc1 ; c1ccc(-c2ccc(-c3nc(-c4ccccc4)nc(-n4c5cccc6oc7ccccc7c7cccc4c7c65)n3)cc2)cc1]

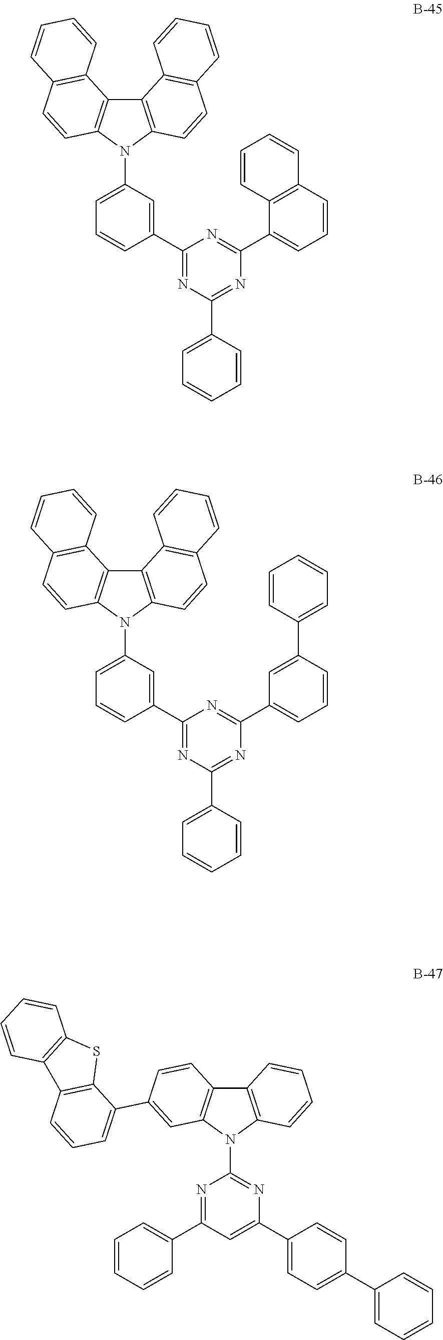 [SMILES: c1ccc(-c2nc(-c3cccc(-n4c5ccc6ccccc6c5c5c6ccccc6ccc54)c3)nc(-c3cccc4ccccc34)n2)cc1 ; c1ccc(-c2cccc(-c3nc(-c4ccccc4)nc(-c4cccc(-n5c6ccc7ccccc7c6c6c7ccccc7ccc65)c4)n3)c2)cc1 ; c1ccc(-c2ccc(-c3cc(-c4ccccc4)nc(-n4c5ccccc5c5ccc(-c6cccc7c6sc6ccccc67)cc54)n3)cc2)cc1]

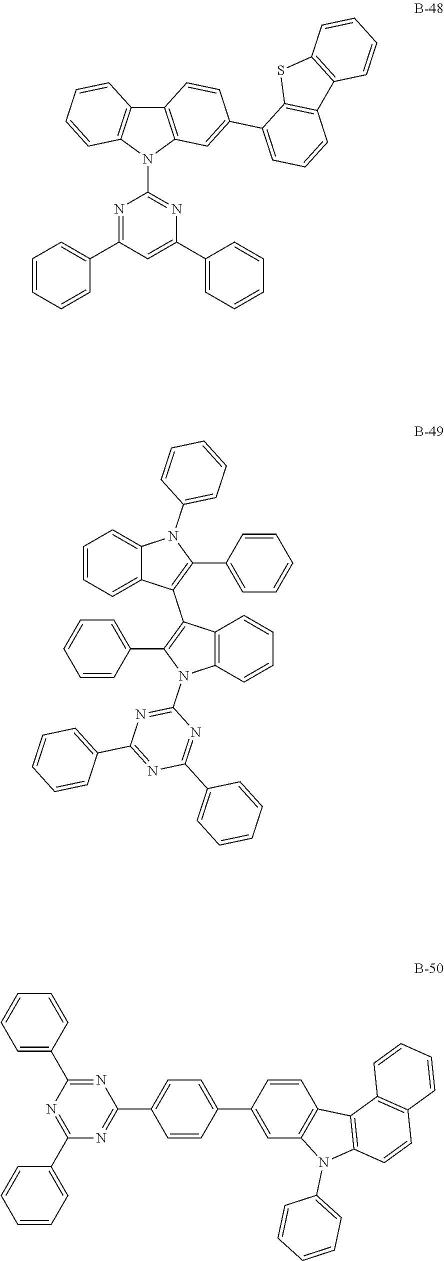 [SMILES: c1ccc(-c2cc(-c3ccccc3)nc(-n3c4ccccc4c4ccc(-c5cccc6c5sc5ccccc56)cc43)n2)cc1 ; c1ccc(-c2nc(-c3ccccc3)nc(-n3c(-c4ccccc4)c(-c4c(-c5ccccc5)n(-c5ccccc5)c5ccccc45)c4ccccc43)n2)cc1 ; c1ccc(-c2nc(-c3ccccc3)nc(-c3ccc(-c4ccc5c6c7ccccc7ccc6n(-c6ccccc6)c5c4)cc3)n2)cc1]

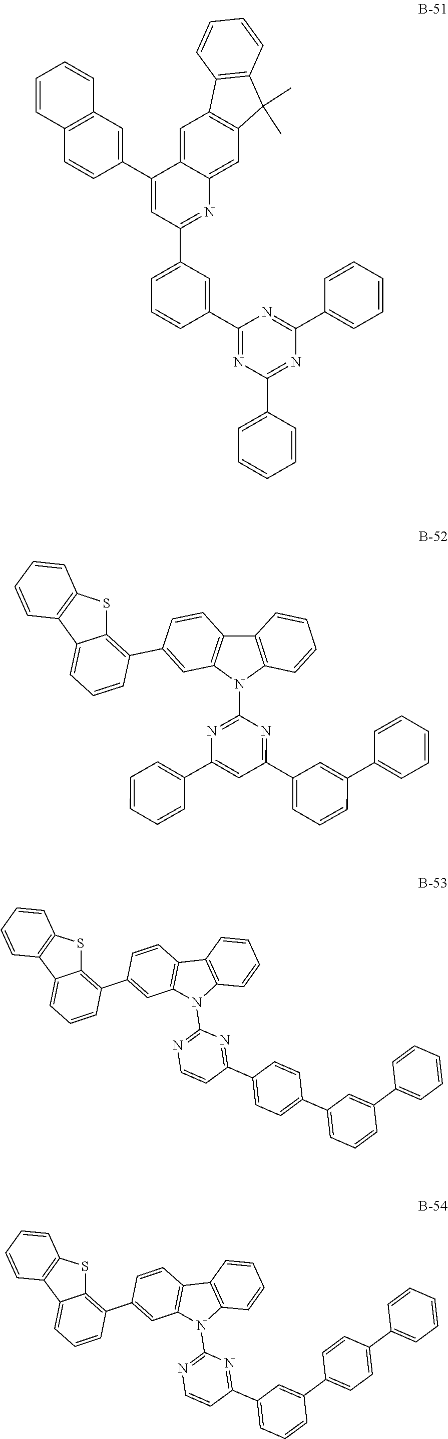 [SMILES: CC1(C)c2ccccc2-c2cc3c(-c4ccc5ccccc5c4)cc(-c4cccc(-c5nc(-c6ccccc6)nc(-c6ccccc6)n5)c4)nc3cc21 ; c1ccc(-c2cccc(-c3cc(-c4ccccc4)nc(-n4c5ccccc5c5ccc(-c6cccc7c6sc6ccccc67)cc54)n3)c2)cc1 ; c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2ccc(-c3cccc(-c4ccnc(-n5c6ccccc6c6ccc(-c7cccc8c7sc7ccccc78)cc65)n4)c3)cc2)cc1]

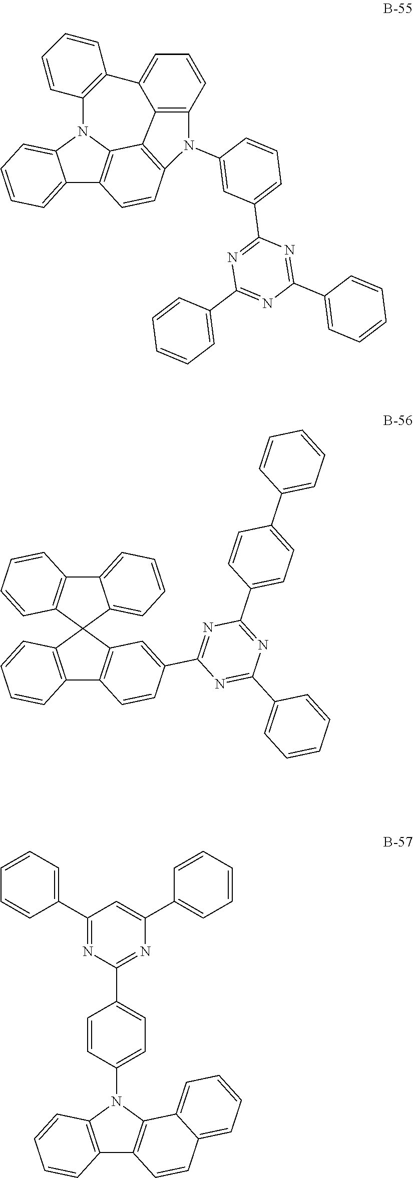 [SMILES: c1ccc(-c2nc(-c3ccccc3)nc(-c3cccc(-n4c5cccc6c7ccccc7n7c8ccccc8c8ccc4c(c65)c87)c3)n2)cc1 ; c1ccc(-c2ccc(-c3nc(-c4ccccc4)nc(-c4ccc5c(c4)C4(c6ccccc6-c6ccccc64)c4ccccc4-5)n3)cc2)cc1 ; c1ccc(-c2cc(-c3ccccc3)nc(-c3ccc(-n4c5ccccc5c5ccc6ccccc6c54)cc3)n2)cc1]

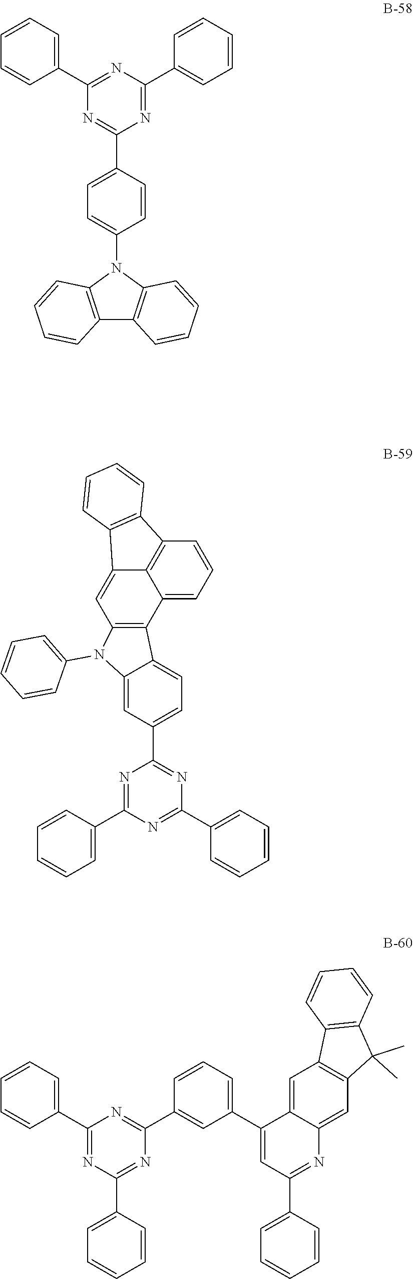 [SMILES: c1ccc(-c2nc(-c3ccccc3)nc(-c3ccc(-n4c5ccccc5c5ccccc54)cc3)n2)cc1 ; c1ccc(-c2nc(-c3ccccc3)nc(-c3ccc4c5c6cccc7c6c(cc5n(-c5ccccc5)c4c3)-c3ccccc3-7)n2)cc1 ; CC1(C)c2ccccc2-c2cc3c(-c4cccc(-c5nc(-c6ccccc6)nc(-c6ccccc6)n5)c4)cc(-c4ccccc4)nc3cc21]

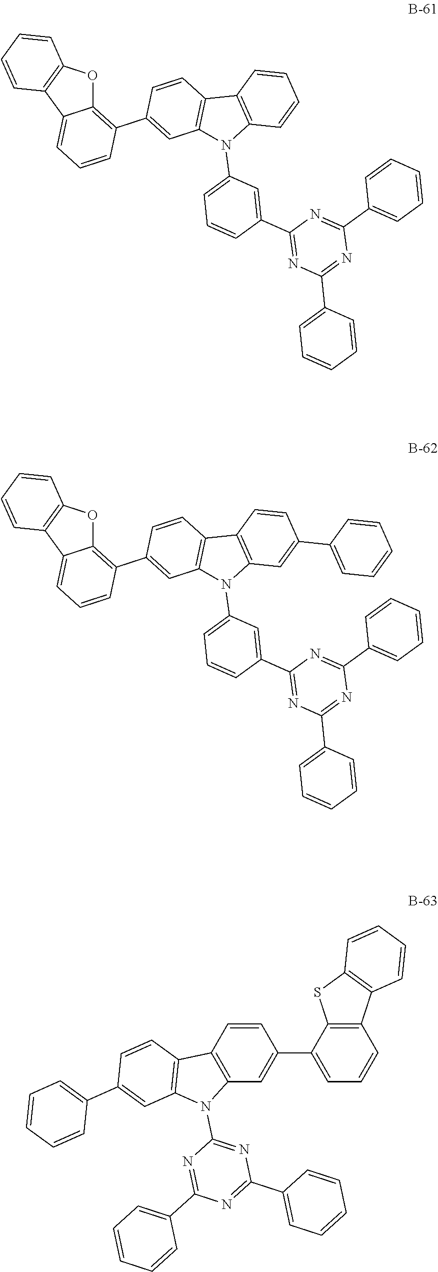 [SMILES: c1ccc(-c2nc(-c3ccccc3)nc(-c3cccc(-n4c5ccccc5c5ccc(-c6cccc7c6oc6ccccc67)cc54)c3)n2)cc1 ; c1ccc(-c2ccc3c4ccc(-c5cccc6c5oc5ccccc56)cc4n(-c4cccc(-c5nc(-c6ccccc6)nc(-c6ccccc6)n5)c4)c3c2)cc1 ; c1ccc(-c2ccc3c4ccc(-c5cccc6c5sc5ccccc56)cc4n(-c4nc(-c5ccccc5)nc(-c5ccccc5)n4)c3c2)cc1]

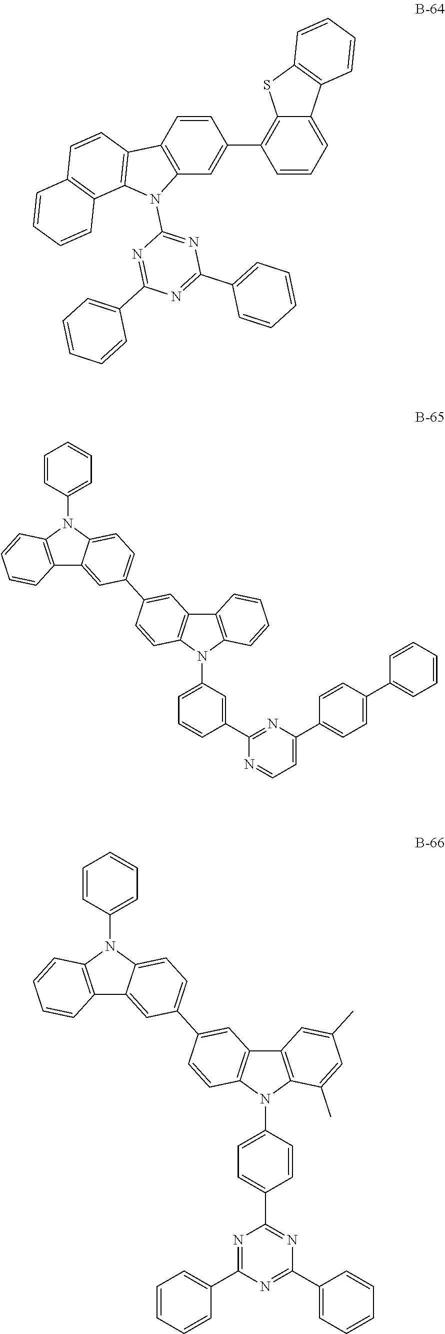 [SMILES: c1ccc(-c2nc(-c3ccccc3)nc(-n3c4cc(-c5cccc6c5sc5ccccc56)ccc4c4ccc5ccccc5c43)n2)cc1 ; c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1]

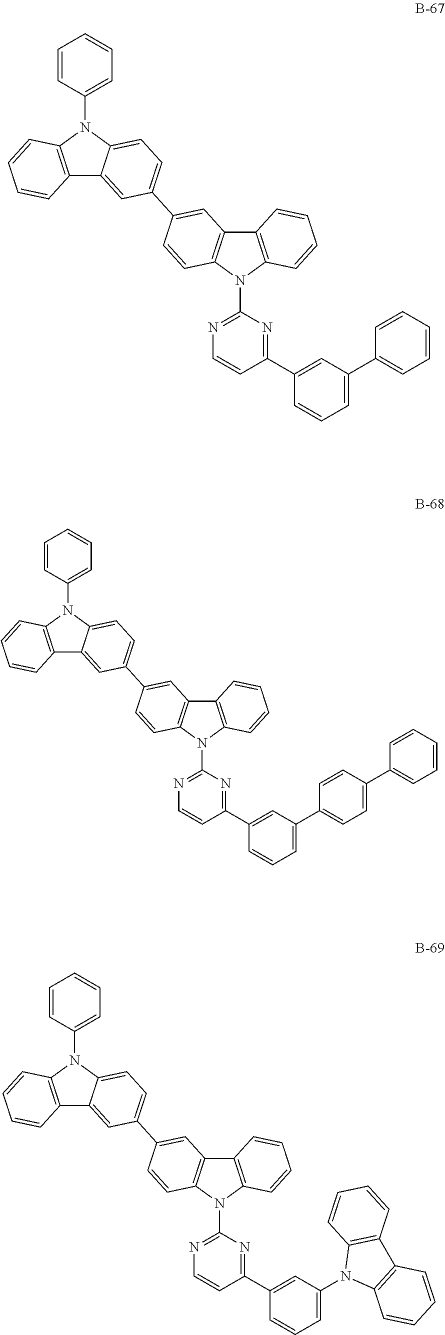 [SMILES: c1ccc(-c2cccc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1 ; c1ccc(-n2c3ccccc3c3cc(-c4ccc5c(c4)c4ccccc4n5-c4nccc(-c5cccc(-n6c7ccccc7c7ccccc76)c5)n4)ccc32)cc1]

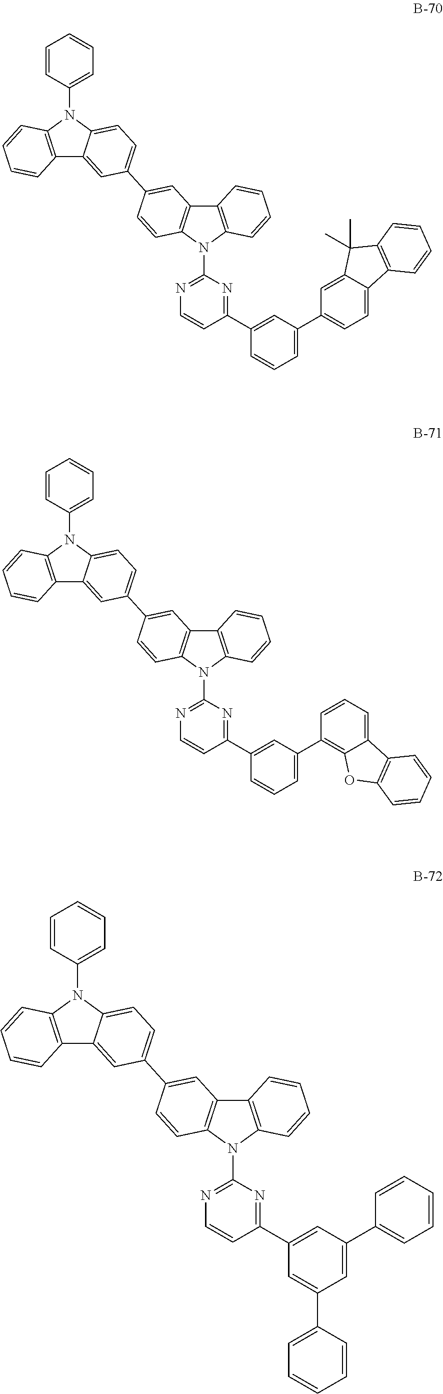 [SMILES: CC1(C)c2ccccc2-c2ccc(-c3cccc(-c4ccnc(-n5c6ccccc6c6cc(-c7ccc8c(c7)c7ccccc7n8-c7ccccc7)ccc65)n4)c3)cc21 ; c1ccc(-n2c3ccccc3c3cc(-c4ccc5c(c4)c4ccccc4n5-c4nccc(-c5cccc(-c6cccc7c6oc6ccccc67)c5)n4)ccc32)cc1 ; c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1]

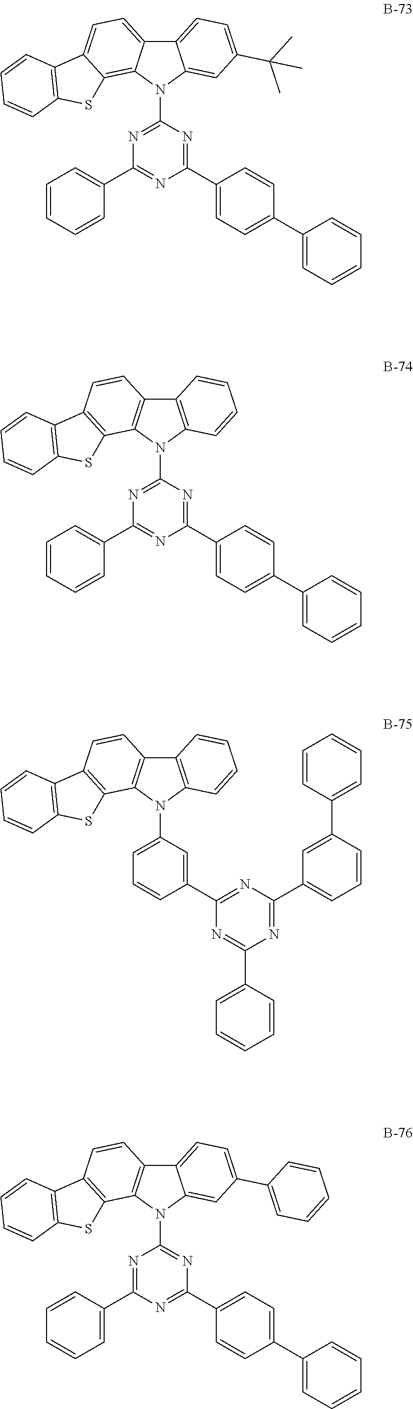 [SMILES: CC(C)(C)c1ccc2c3ccc4c5ccccc5sc4c3n(-c3nc(-c4ccccc4)nc(-c4ccc(-c5ccccc5)cc4)n3)c2c1 ; c1ccc(-c2ccc(-c3nc(-c4ccccc4)nc(-n4c5ccccc5c5ccc6c7ccccc7sc6c54)n3)cc2)cc1 ; c1ccc(-c2cccc(-c3nc(-c4ccccc4)nc(-c4cccc(-n5c6ccccc6c6ccc7c8ccccc8sc7c65)c4)n3)c2)cc1 ; c1ccc(-c2ccc(-c3nc(-c4ccccc4)nc(-n4c5cc(-c6ccccc6)ccc5c5ccc6c7ccccc7sc6c54)n3)cc2)cc1]

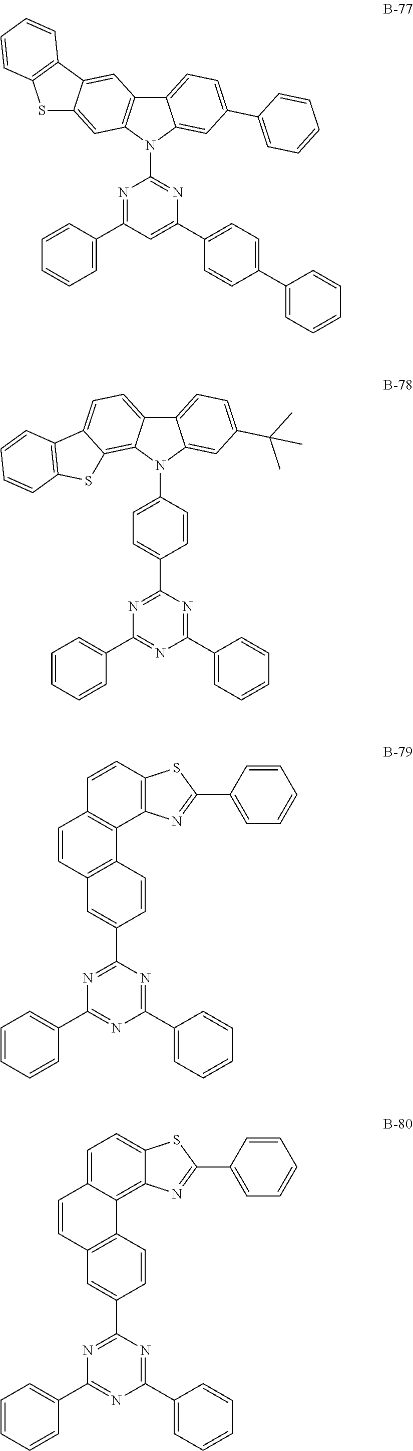 [SMILES: c1ccc(-c2ccc(-c3cc(-c4ccccc4)nc(-n4c5cc(-c6ccccc6)ccc5c5cc6c(cc54)sc4ccccc46)n3)cc2)cc1 ; CC(C)(C)c1ccc2c3ccc4c5ccccc5sc4c3n(-c3ccc(-c4nc(-c5ccccc5)nc(-c5ccccc5)n4)cc3)c2c1 ; c1ccc(-c2nc(-c3ccccc3)nc(-c3ccc4c(ccc5ccc6sc(-c7ccccc7)nc6c54)c3)n2)cc1 ; c1ccc(-c2nc(-c3ccccc3)nc(-c3ccc4c(ccc5ccc6sc(-c7ccccc7)nc6c54)c3)n2)cc1]

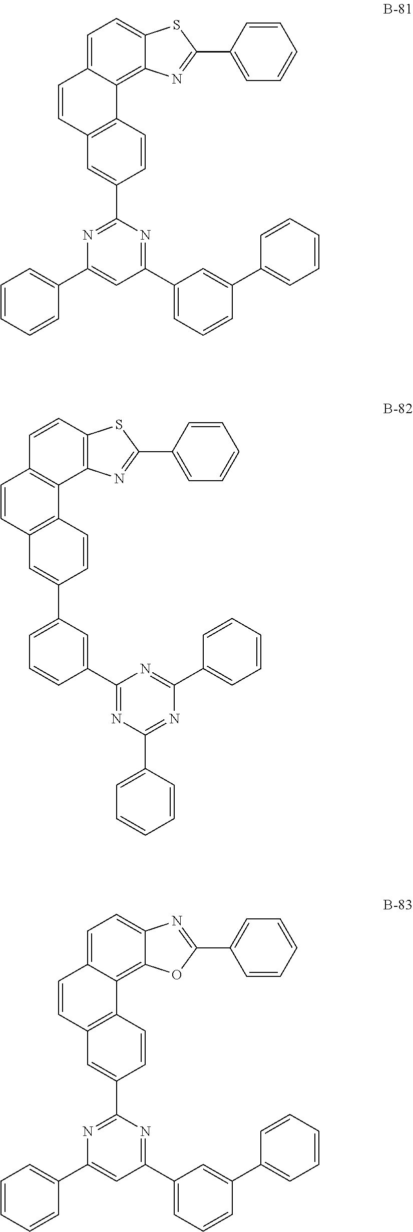 [SMILES: c1ccc(-c2cccc(-c3cc(-c4ccccc4)nc(-c4ccc5c(ccc6ccc7sc(-c8ccccc8)nc7c65)c4)n3)c2)cc1 ; c1ccc(-c2nc(-c3ccccc3)nc(-c3cccc(-c4ccc5c(ccc6ccc7sc(-c8ccccc8)nc7c65)c4)c3)n2)cc1 ; c1ccc(-c2cccc(-c3cc(-c4ccccc4)nc(-c4ccc5c(ccc6ccc7nc(-c8ccccc8)oc7c65)c4)n3)c2)cc1]

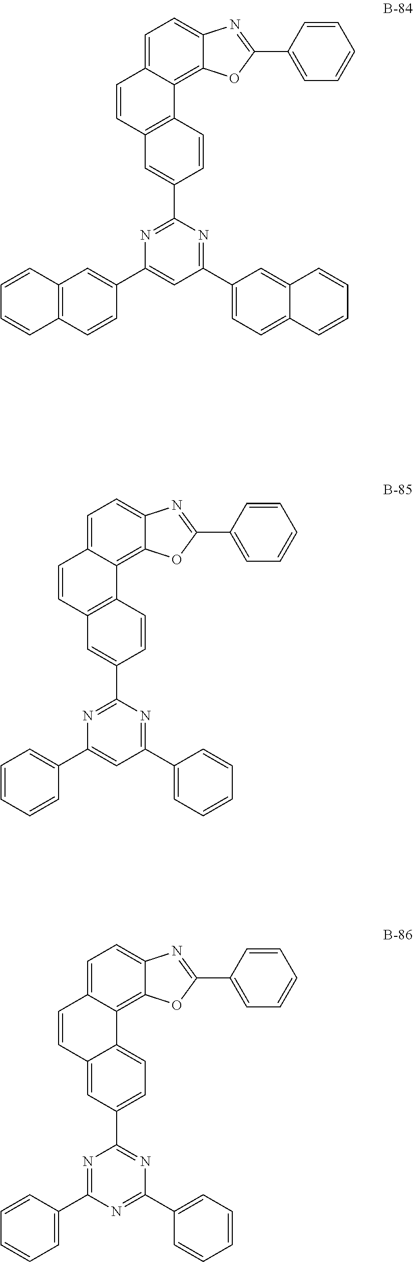 [SMILES: c1ccc(-c2nc3ccc4ccc5cc(-c6nc(-c7ccc8ccccc8c7)cc(-c7ccc8ccccc8c7)n6)ccc5c4c3o2)cc1 ; c1ccc(-c2cc(-c3ccccc3)nc(-c3ccc4c(ccc5ccc6nc(-c7ccccc7)oc6c54)c3)n2)cc1 ; c1ccc(-c2nc(-c3ccccc3)nc(-c3ccc4c(ccc5ccc6nc(-c7ccccc7)oc6c54)c3)n2)cc1]

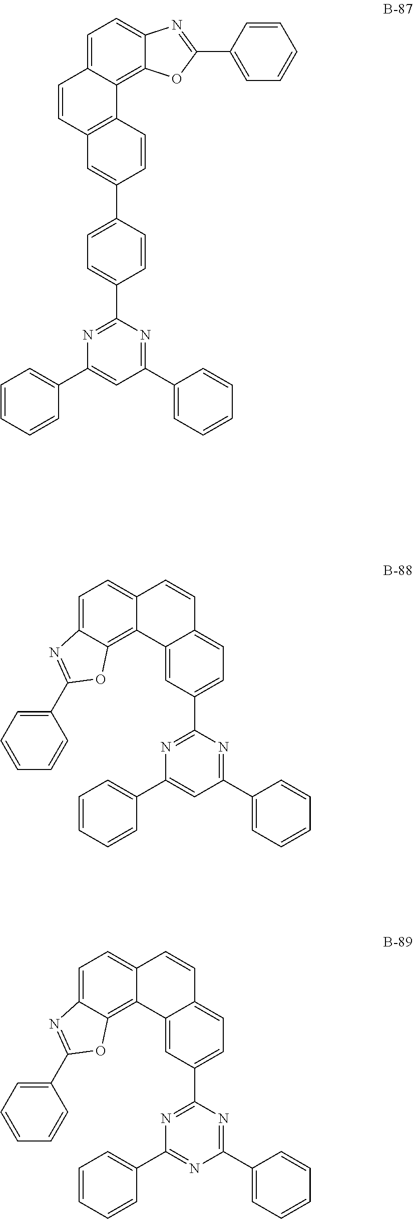 [SMILES: c1ccc(-c2cc(-c3ccccc3)nc(-c3ccc(-c4ccc5c(ccc6ccc7nc(-c8ccccc8)oc7c65)c4)cc3)n2)cc1 ; c1ccc(-c2cc(-c3ccccc3)nc(-c3ccc4ccc5ccc6nc(-c7ccccc7)oc6c5c4c3)n2)cc1 ; c1ccc(-c2nc(-c3ccccc3)nc(-c3ccc4ccc5ccc6nc(-c7ccccc7)oc6c5c4c3)n2)cc1]

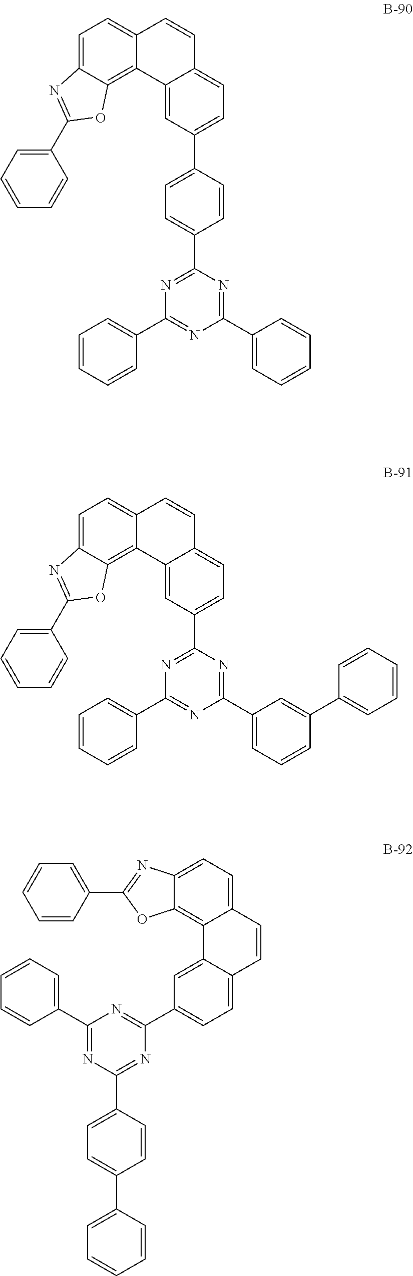 [SMILES: c1ccc(-c2nc(-c3ccccc3)nc(-c3ccc(-c4ccc5ccc6ccc7nc(-c8ccccc8)oc7c6c5c4)cc3)n2)cc1 ; c1ccc(-c2cccc(-c3nc(-c4ccccc4)nc(-c4ccc5ccc6ccc7nc(-c8ccccc8)oc7c6c5c4)n3)c2)cc1 ; c1ccc(-c2ccc(-c3nc(-c4ccccc4)nc(-c4ccc5ccc6ccc7nc(-c8ccccc8)oc7c6c5c4)n3)cc2)cc1]

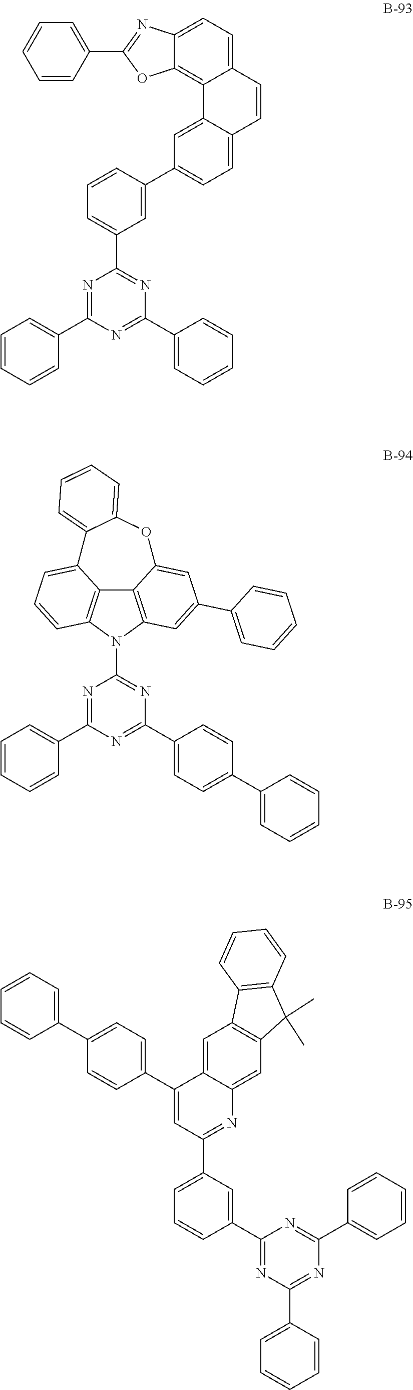 [SMILES: c1ccc(-c2nc(-c3ccccc3)nc(-c3cccc(-c4ccc5ccc6ccc7nc(-c8ccccc8)oc7c6c5c4)c3)n2)cc1 ; c1ccc(-c2ccc(-c3nc(-c4ccccc4)nc(-n4c5cc(-c6ccccc6)cc6oc7ccccc7c7cccc4c7c65)n3)cc2)cc1 ; CC1(C)c2ccccc2-c2cc3c(-c4ccc(-c5ccccc5)cc4)cc(-c4cccc(-c5nc(-c6ccccc6)nc(-c6ccccc6)n5)c4)nc3cc21]

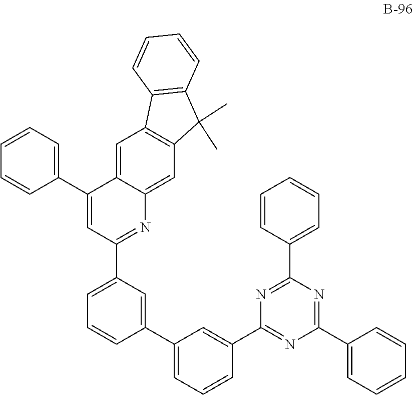 [SMILES: CC1(C)c2ccccc2-c2cc3c(-c4ccccc4)cc(-c4cccc(-c5cccc(-c6nc(-c7ccccc7)nc(-c7ccccc7)n6)c5)c4)nc3cc21]

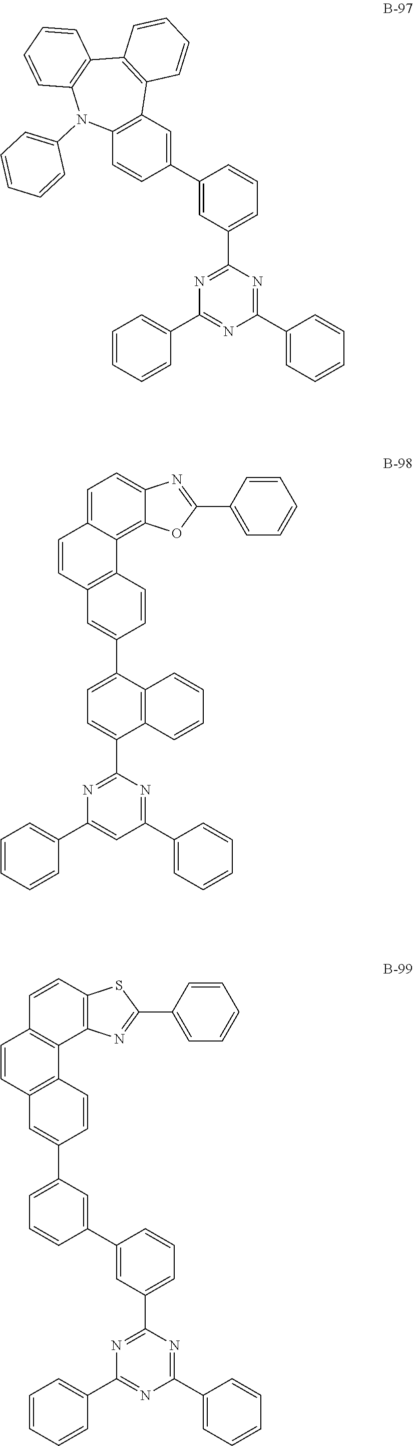 [SMILES: c1ccc(-c2nc(-c3ccccc3)nc(-c3cccc(-c4ccc5c(c4)-c4ccccc4-c4ccccc4N5c4ccccc4)c3)n2)cc1 ; c1ccc(-c2cc(-c3ccccc3)nc(-c3ccc(-c4ccc5c(ccc6ccc7nc(-c8ccccc8)oc7c65)c4)c4ccccc34)n2)cc1 ; c1ccc(-c2nc(-c3ccccc3)nc(-c3cccc(-c4cccc(-c5ccc6c(ccc7ccc8sc(-c9ccccc9)nc8c76)c5)c4)c3)n2)cc1]

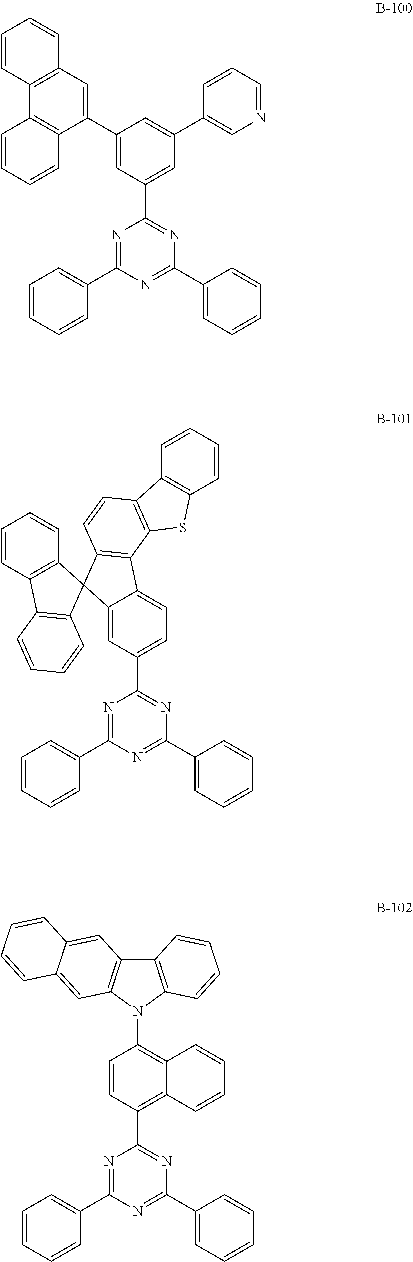 [SMILES: c1ccc(-c2nc(-c3ccccc3)nc(-c3cc(-c4cccnc4)cc(-c4cc5ccccc5c5ccccc45)c3)n2)cc1 ; c1ccc(-c2nc(-c3ccccc3)nc(-c3ccc4c(c3)C3(c5ccccc5-c5ccccc53)c3ccc5c(sc6ccccc65)c3-4)n2)cc1 ; c1ccc(-c2nc(-c3ccccc3)nc(-c3ccc(-n4c5ccccc5c5cc6ccccc6cc54)c4ccccc34)n2)cc1]

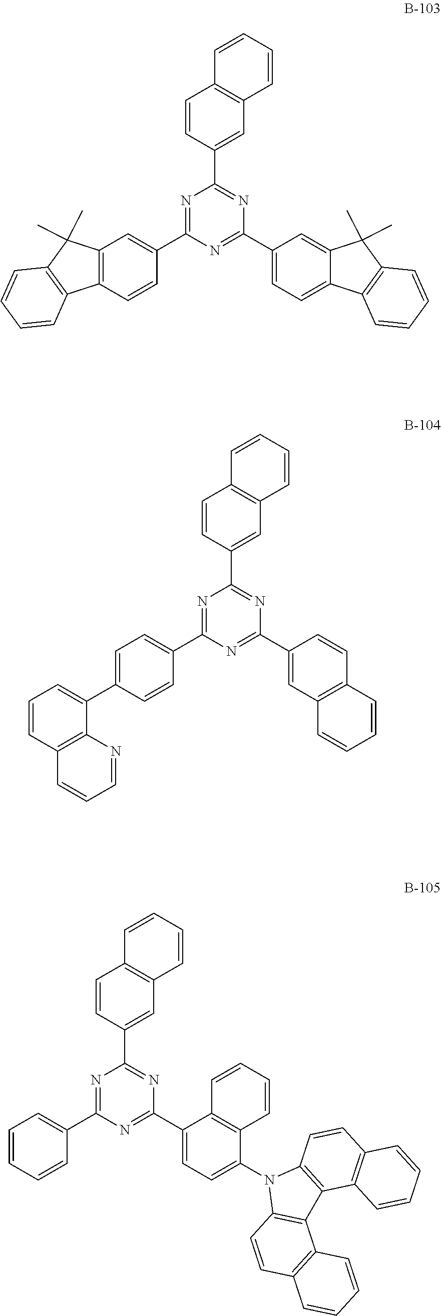 [SMILES: CC1(C)c2ccccc2-c2ccc(-c3nc(-c4ccc5c(c4)C(C)(C)c4ccccc4-5)nc(-c4ccc5ccccc5c4)n3)cc21 ; c1ccc2cc(-c3nc(-c4ccc(-c5cccc6cccnc56)cc4)nc(-c4ccc5ccccc5c4)n3)ccc2c1 ; c1ccc(-c2nc(-c3ccc4ccccc4c3)nc(-c3ccc(-n4c5ccc6ccccc6c5c5c6ccccc6ccc54)c4ccccc34)n2)cc1]

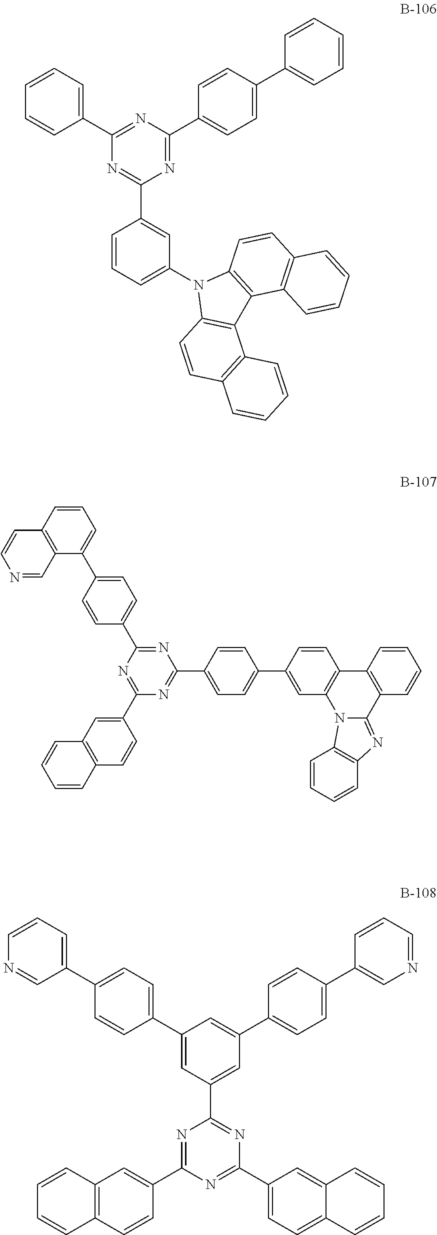 [SMILES: c1ccc(-c2ccc(-c3nc(-c4ccccc4)nc(-c4cccc(-n5c6ccc7ccccc7c6c6c7ccccc7ccc65)c4)n3)cc2)cc1 ; c1ccc2cc(-c3nc(-c4ccc(-c5ccc6c7ccccc7c7nc8ccccc8n7c6c5)cc4)nc(-c4ccc(-c5cccc6ccncc56)cc4)n3)ccc2c1 ; c1cncc(-c2ccc(-c3cc(-c4ccc(-c5cccnc5)cc4)cc(-c4nc(-c5ccc6ccccc6c5)nc(-c5ccc6ccccc6c5)n4)c3)cc2)c1]

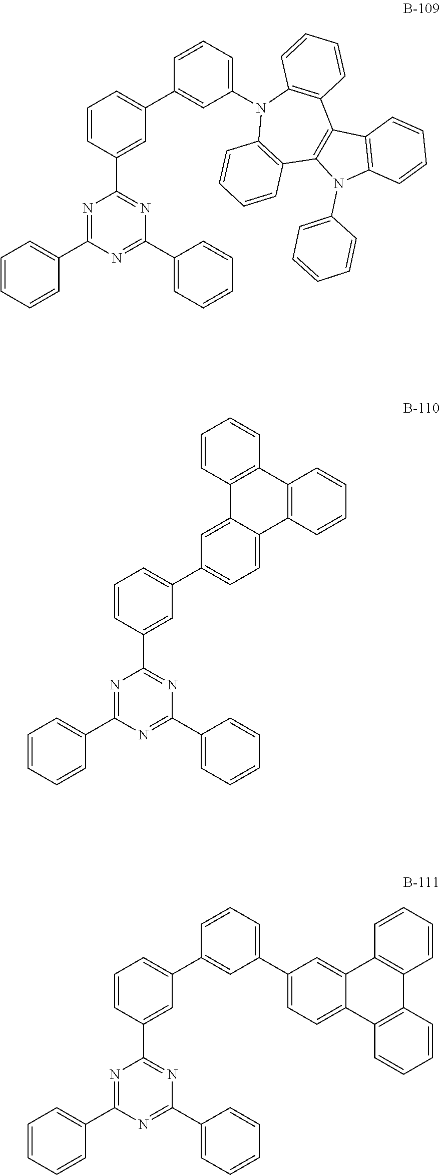 [SMILES: c1ccc(-c2nc(-c3ccccc3)nc(-c3cccc(-c4cccc(N5c6ccccc6-c6c(n(-c7ccccc7)c7ccccc67)-c6ccccc65)c4)c3)n2)cc1 ; c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1]

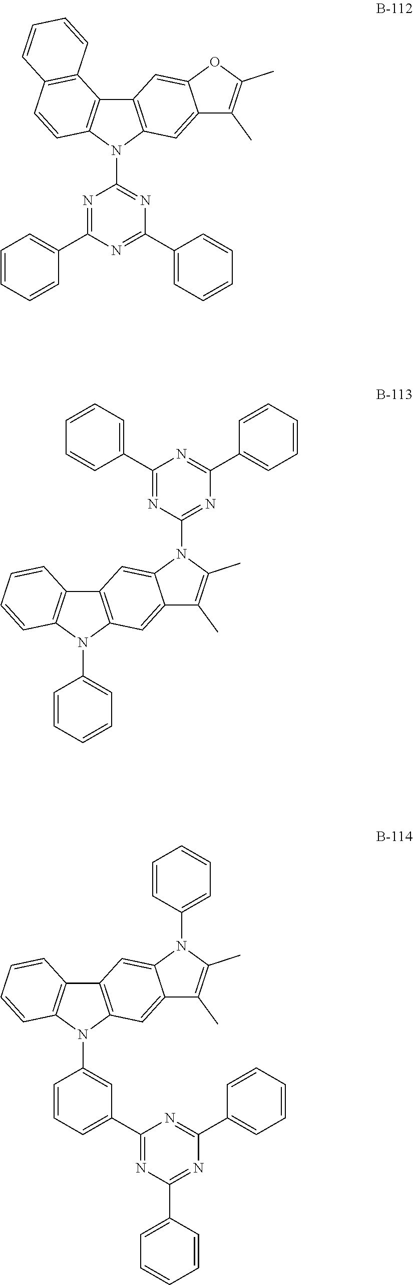 [SMILES: Cc1oc2cc3c4c5ccccc5ccc4n(-c4nc(-c5ccccc5)nc(-c5ccccc5)n4)c3cc2c1C ; Cc1c(C)n(-c2nc(-c3ccccc3)nc(-c3ccccc3)n2)c2cc3c4ccccc4n(-c4ccccc4)c3cc12 ; Cc1c(C)n(-c2ccccc2)c2cc3c4ccccc4n(-c4cccc(-c5nc(-c6ccccc6)nc(-c6ccccc6)n5)c4)c3cc12]

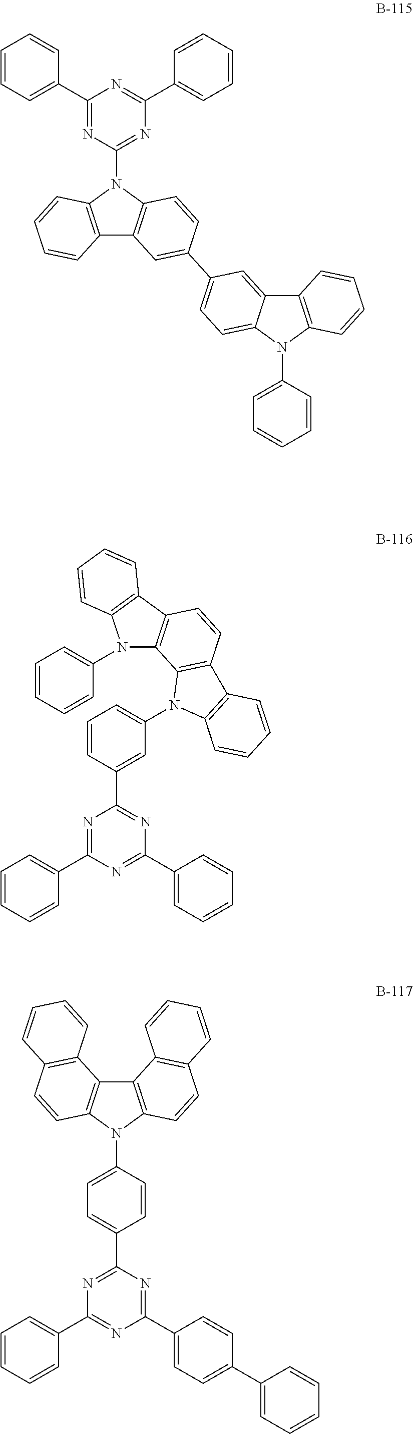 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3cccc(-n4c5ccccc5c5ccc6c7ccccc7n(-c7ccccc7)c6c54)c3)n2)cc1 ; c1ccc(-c2ccc(-c3nc(-c4ccccc4)nc(-c4ccc(-n5c6ccc7ccccc7c6c6c7ccccc7ccc65)cc4)n3)cc2)cc1]

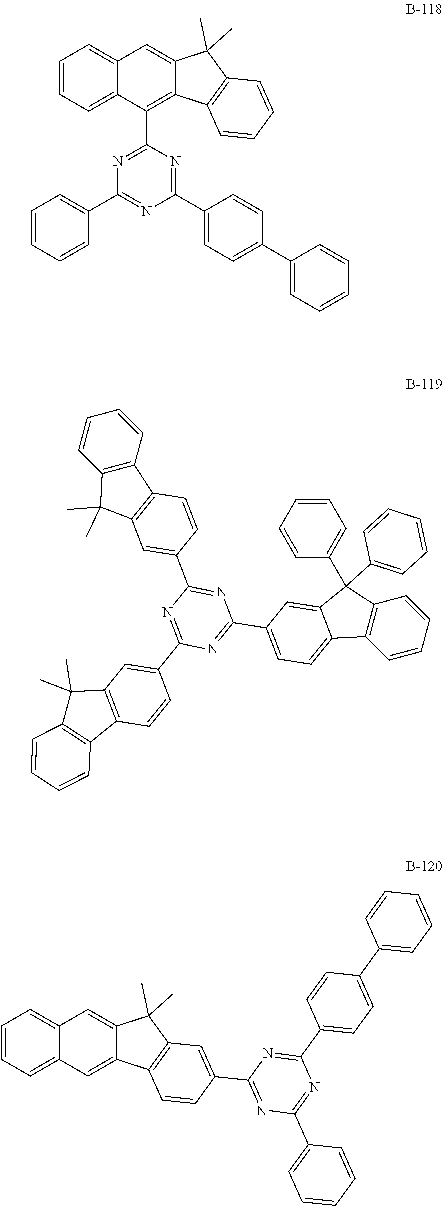 [SMILES: CC1(C)c2ccccc2-c2c1cc1ccccc1c2-c1nc(-c2ccccc2)nc(-c2ccc(-c3ccccc3)cc2)n1 ; CC1(C)c2ccccc2-c2ccc(-c3nc(-c4ccc5c(c4)C(C)(C)c4ccccc4-5)nc(-c4ccc5c(c4)C(c4ccccc4)(c4ccccc4)c4ccccc4-5)n3)cc21 ; CC1(C)c2cc(-c3nc(-c4ccccc4)nc(-c4ccc(-c5ccccc5)cc4)n3)ccc2-c2cc3ccccc3cc21]

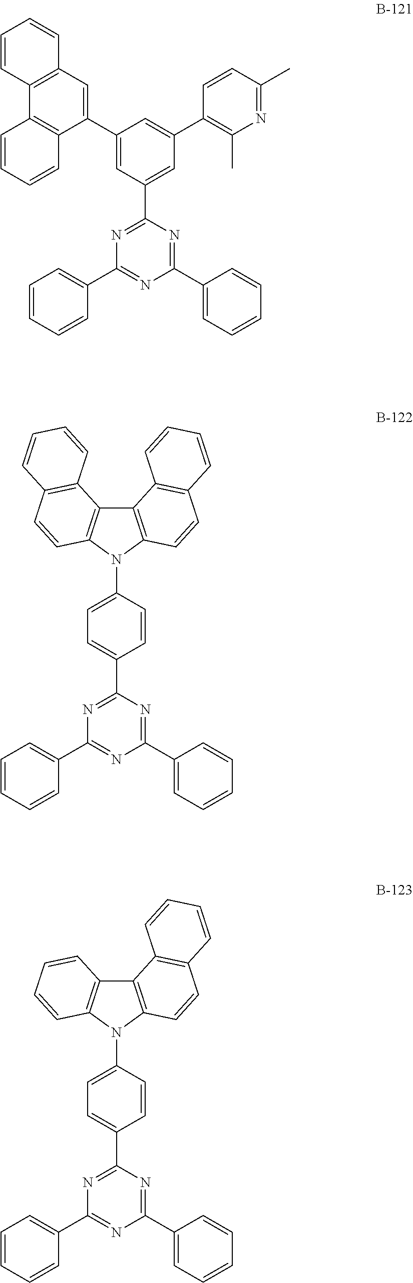 [SMILES: Cc1ccc(-c2cc(-c3nc(-c4ccccc4)nc(-c4ccccc4)n3)cc(-c3cc4ccccc4c4ccccc34)c2)c(C)n1 ; c1ccc(-c2nc(-c3ccccc3)nc(-c3ccc(-n4c5ccc6ccccc6c5c5c6ccccc6ccc54)cc3)n2)cc1 ; c1ccc(-c2nc(-c3ccccc3)nc(-c3ccc(-n4c5ccccc5c5c6ccccc6ccc54)cc3)n2)cc1]

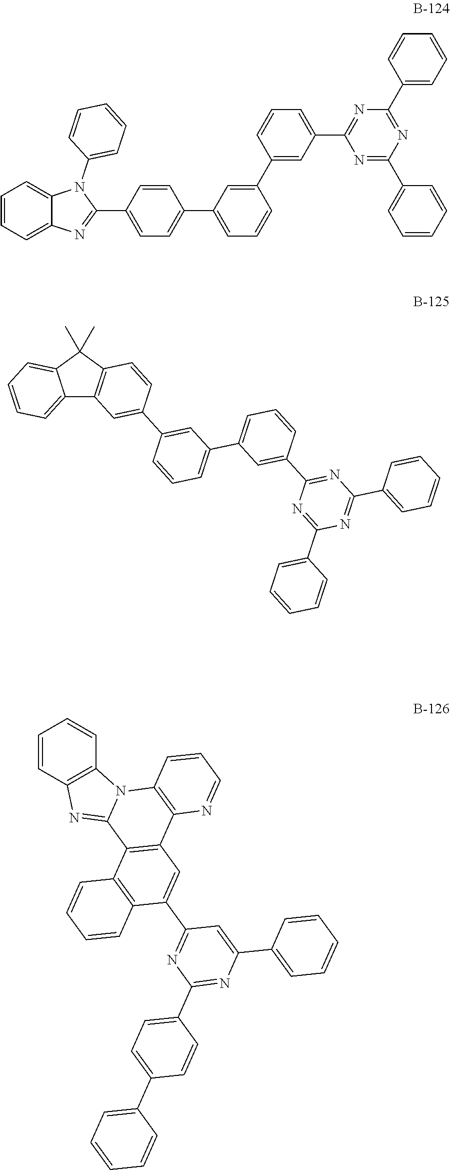 [SMILES: c1ccc(-c2nc(-c3ccccc3)nc(-c3cccc(-c4cccc(-c5ccc(-c6nc7ccccc7n6-c6ccccc6)cc5)c4)c3)n2)cc1 ; CC1(C)c2ccccc2-c2cc(-c3cccc(-c4cccc(-c5nc(-c6ccccc6)nc(-c6ccccc6)n5)c4)c3)ccc21 ; c1ccc(-c2ccc(-c3nc(-c4ccccc4)cc(-c4cc5c6ncccc6n6c7ccccc7nc6c5c5ccccc45)n3)cc2)cc1]

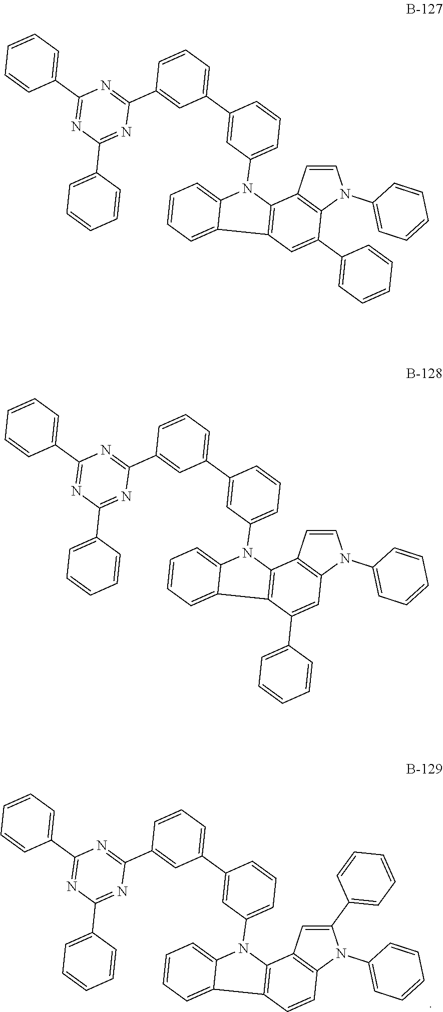 [SMILES: c1ccc(-c2nc(-c3ccccc3)nc(-c3cccc(-c4cccc(-n5c6ccccc6c6cc(-c7ccccc7)c7c(ccn7-c7ccccc7)c65)c4)c3)n2)cc1 ; c1ccc(-c2nc(-c3ccccc3)nc(-c3cccc(-c4cccc(-n5c6ccccc6c6c(-c7ccccc7)cc7c(ccn7-c7ccccc7)c65)c4)c3)n2)cc1 ; c1ccc(-c2nc(-c3ccccc3)nc(-c3cccc(-c4cccc(-n5c6ccccc6c6ccc7c(cc(-c8ccccc8)n7-c7ccccc7)c65)c4)c3)n2)cc1]

The compound represented by formula 1 and the compound represented by formula 11 or 21 of the present disclosure can be prepared by a synthetic method known to a person skilled in the art. For example, the compound of formula 1 can be prepared by the following reaction schemes, and by referring to Korean Patent Appln. Nos. 2017-0124258 (2017.09.26), 2017-0124285 (2017.09.26), etc.

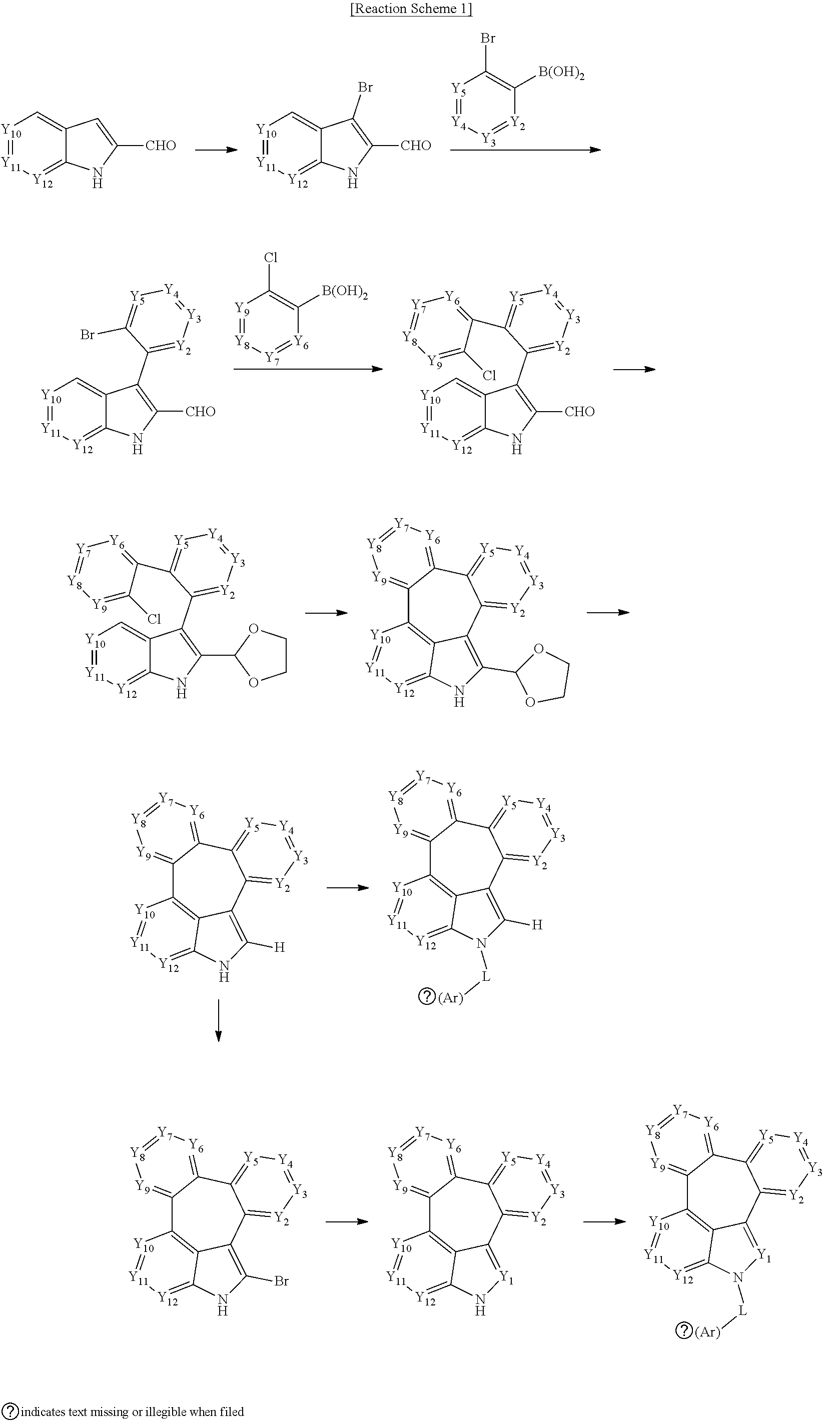

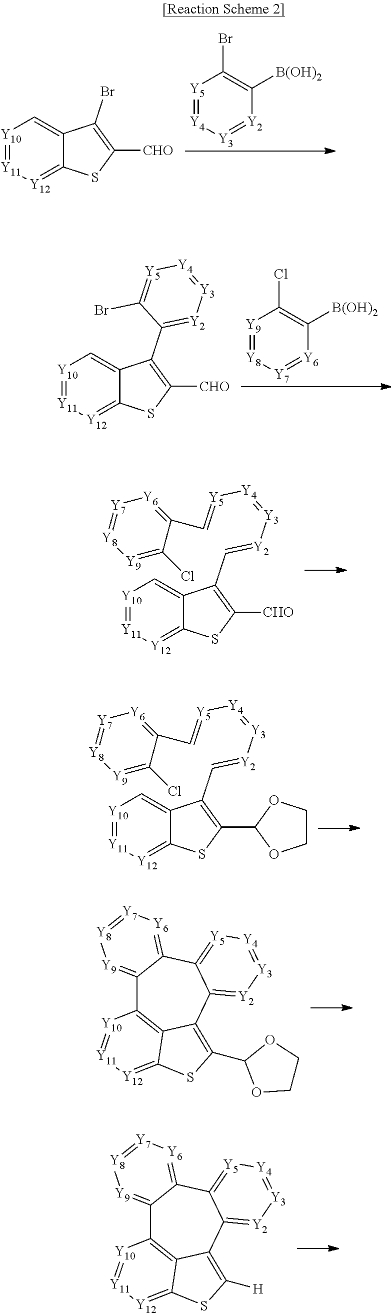

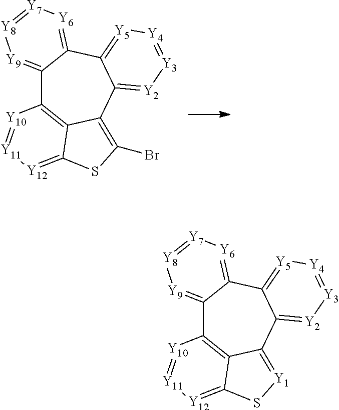

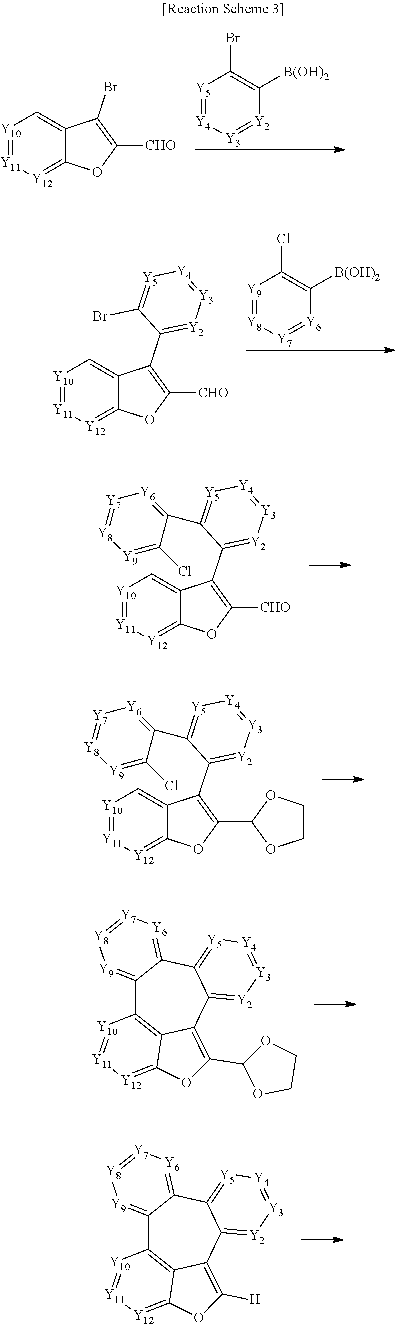

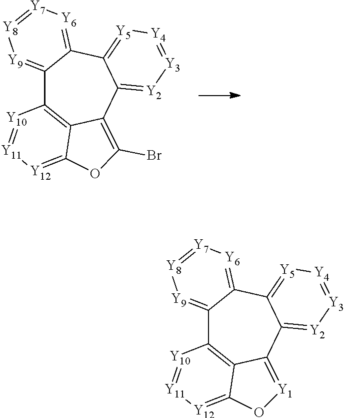

In reaction schemes 1 to 3, L, Ar, Y₁ to Y₁₂, and a are as defined in formula 1.

The compound represented by formula 11 or 21 can be prepared by referring to Korean Patent No. 1741415 (2017.05.30) and Korean Appln. Laying-Open Nos. 2015-0108332 (2015.09.25), 2015-0124886 (2015.11.06), 2015-0128590 (2015.11.18), 2016-0010333 (2016.01.27), 2016-0014556 (2016.02.11), 2016-0018406 (2016.02.17), 2016-0099471 (2016.08.22), 2017-0051198 (2017.05.11), 2017-0067643 (2017.06.16), etc.

The light-emitting layer of the present disclosure may be formed using a host compound and a dopant compound. The host compound may be the compound represented by formula 1 alone, or any conventional material comprised in organic electroluminescent materials may be additionally comprised. The dopant compound is not particularly limited, but is preferably selected from metallated complex compounds of iridium (Ir), osmium (Os), copper (Cu), and platinum (Pt), is more preferably selected from ortho-metallated complex compounds of iridium (Ir), osmium (Os), copper (Cu), and platinum (Pt), and is even more preferably an ortho-metallated iridium complex compound.

The dopant comprised in the organic electroluminescent device of the present disclosure may be selected from the group consisting of the compounds represented by formulas 101 to 104 below.

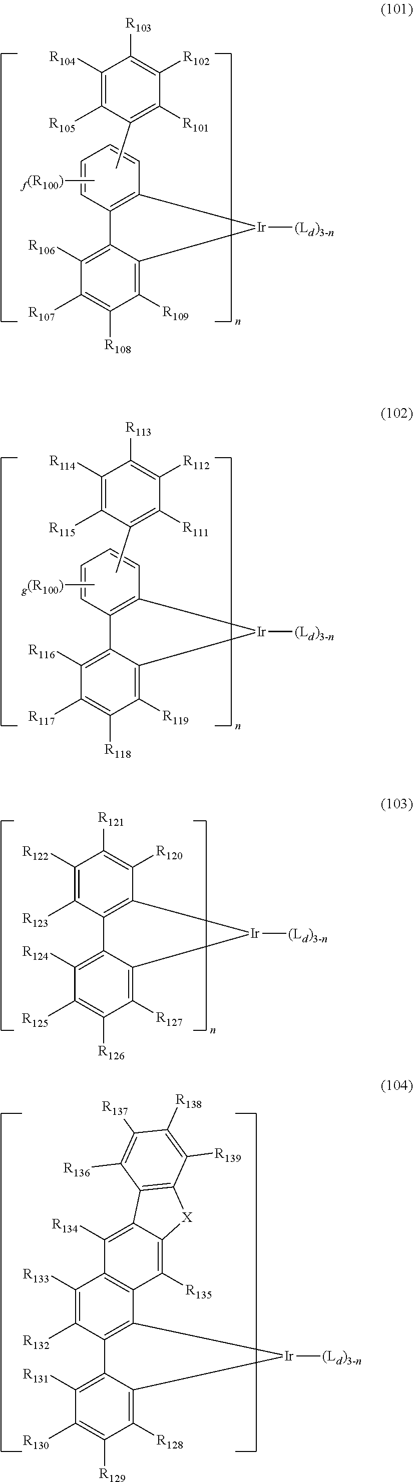

wherein L_{d} is selected from the following structures:

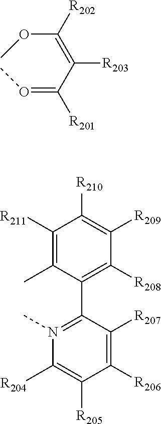

R₁₀₀, R₁₃₄, and R₁₃₅ each independently represent hydrogen, deuterium, a substituted or unsubstituted (C1-C30)alkyl, or a substituted or unsubstituted (C3-C30)cycloalkyl;

R₁₀₁ to R₁₀₉ and R₁₁₁ to R₁₂₃ each independently represent hydrogen, deuterium, a halogen, a (C1-C30)alkyl unsubstituted or substituted with deuterium or a halogen(s), a substituted or unsubstituted (C3-C30)cycloalkyl, a substituted or unsubstituted (C6-C30)aryl, a cyano, or a substituted or unsubstituted (C1-C30)alkoxy; adjacent substituents of R₁₀₆ to R₁₀₉ may be linked to each other to form a substituted or unsubstituted fused ring, e.g., a fluorene unsubstituted or substituted with an alkyl(s), a dibenzothiophene unsubstituted or substituted with an alkyl(s), or a dibenzofuran unsubstituted or substituted with an alkyl(s); and adjacent substituents of R₁₂₀ to R₁₂₃ may be linked to each other to form a substituted or unsubstituted fused ring, e.g., a quinoline unsubstituted or substituted with at least one of an alkyl, an aryl, an aralkyl, and an alkylaryl; R₁₂₄ to R₁₃₃ and R₁₃₆ to R₁₃₉ each independently represent hydrogen, deuterium, a halogen, a substituted or unsubstituted (C1-C30)alkyl, or a substituted or unsubstituted (C6-C30)aryl; and adjacent substituents of R₁₂₄ to R₁₂₇ may be linked to each other to form a substituted or unsubstituted fused ring, e.g., a fluorene unsubstituted or substituted with an alkyl(s), a dibenzothiophene unsubstituted or substituted with an alkyl(s), or a dibenzofuran unsubstituted or substituted with an alkyl(s);

X represents CR₂₁R₂₂, O, or S;

R₂₁ and R₂₂ each independently represent a substituted or unsubstituted (C1-C10)alkyl, or a substituted or unsubstituted (C6-C30)aryl;

R₂₀₁ to R₂₁₁ each independently represent hydrogen, deuterium, a halogen, a (C1-C30)alkyl unsubstituted or substituted with deuterium or a halogen(s), a substituted or unsubstituted (C3-C30)cycloalkyl, or a (C6-C30)aryl unsubstituted or substituted with an alkyl(s) or deuterium; and adjacent substituents of R₂₀₈ to R₂₁₁ may be linked to each other to form a substituted or unsubstituted fused ring, e.g., a fluorene unsubstituted or substituted with an alkyl(s), a dibenzothiophene unsubstituted or substituted with an alkyl(s), or a dibenzofuran unsubstituted or substituted with an alkyl(s);

f and g each independently represent an integer of 1 to 3; where if f or g is an integer of 2 or more, each R₁₀₀ may be the same or different; and

n represents an integer of 1 to 3.

The specific examples of the dopant compound are as follows.

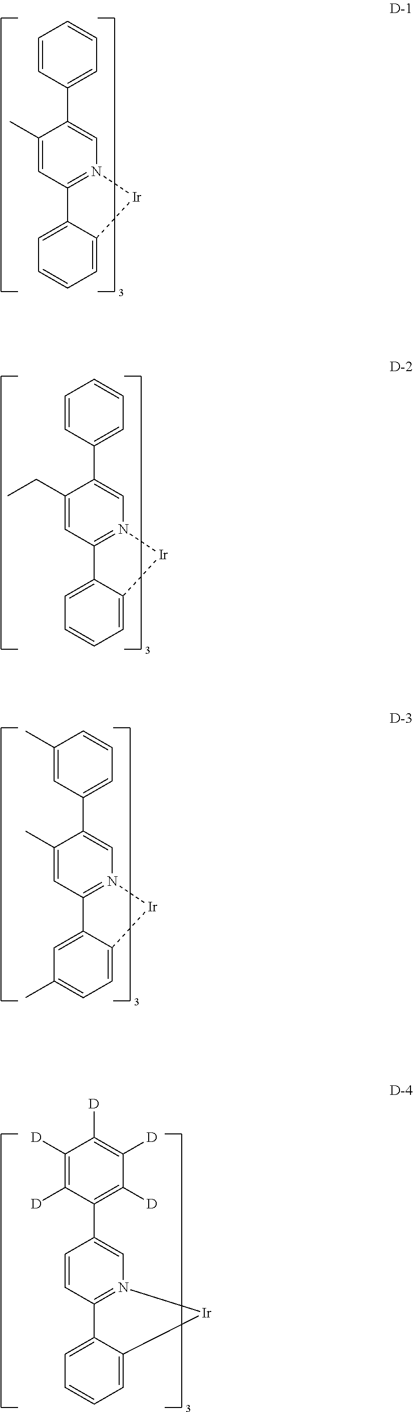

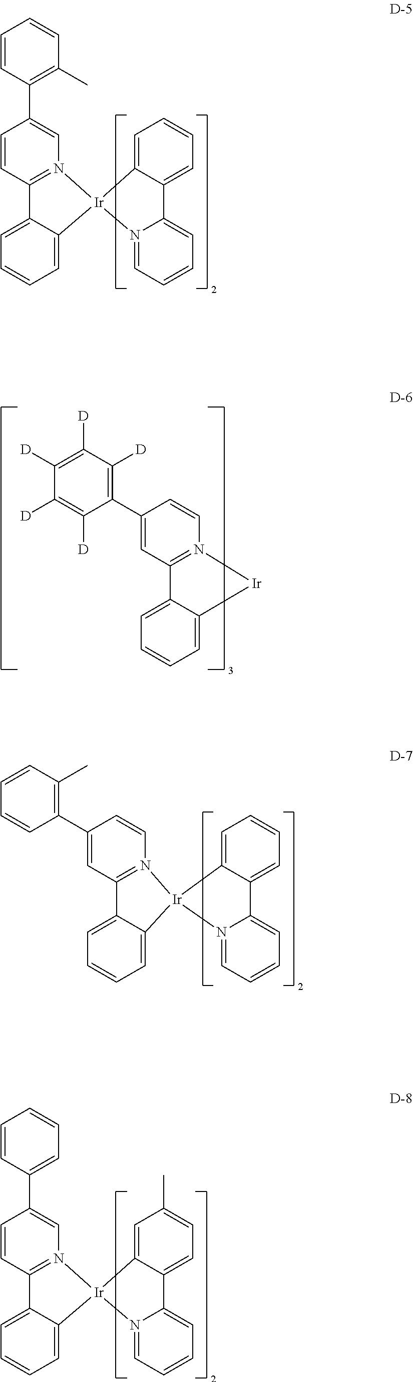

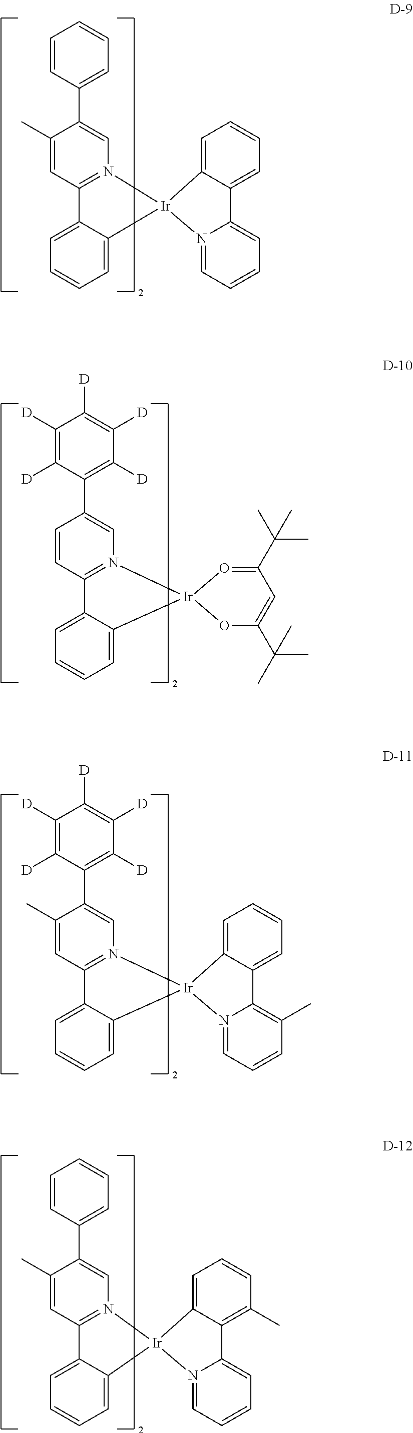

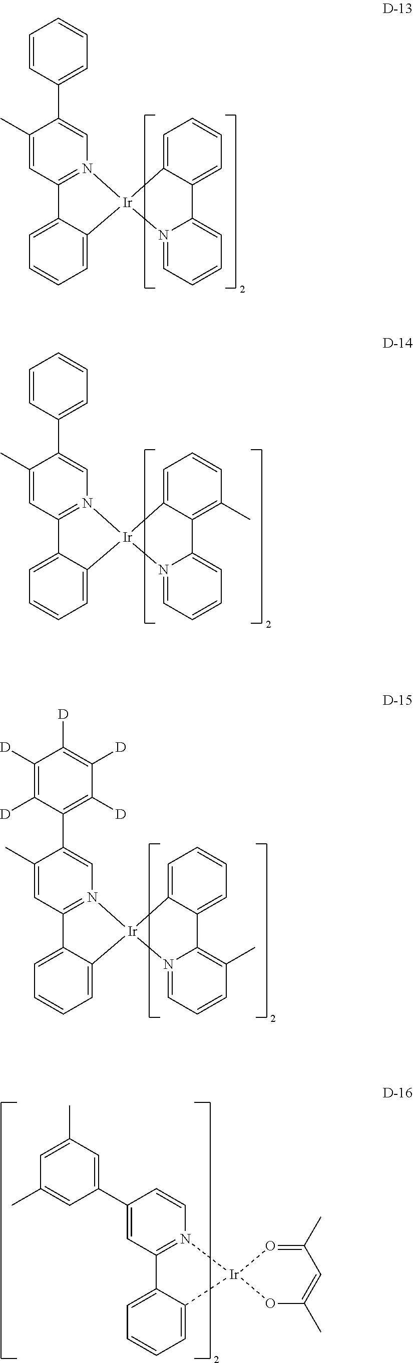

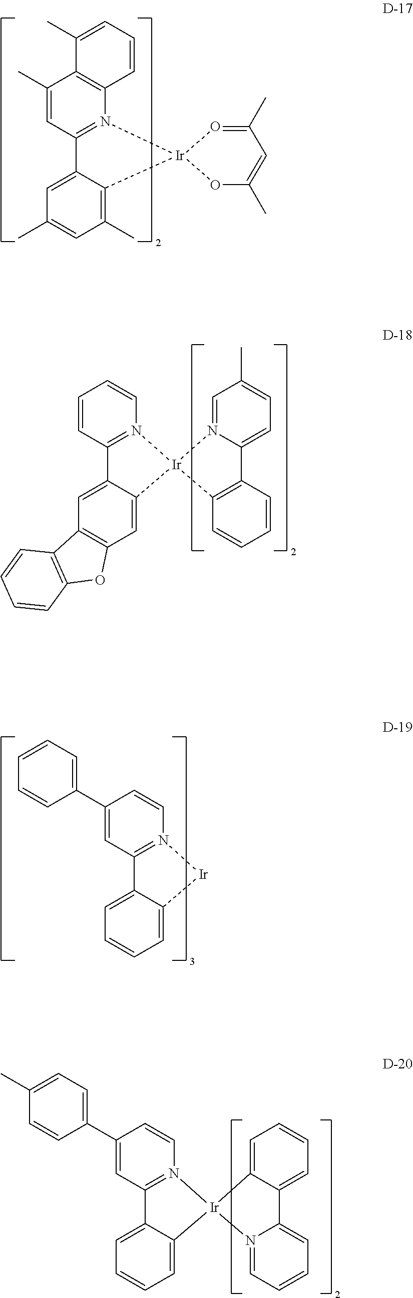

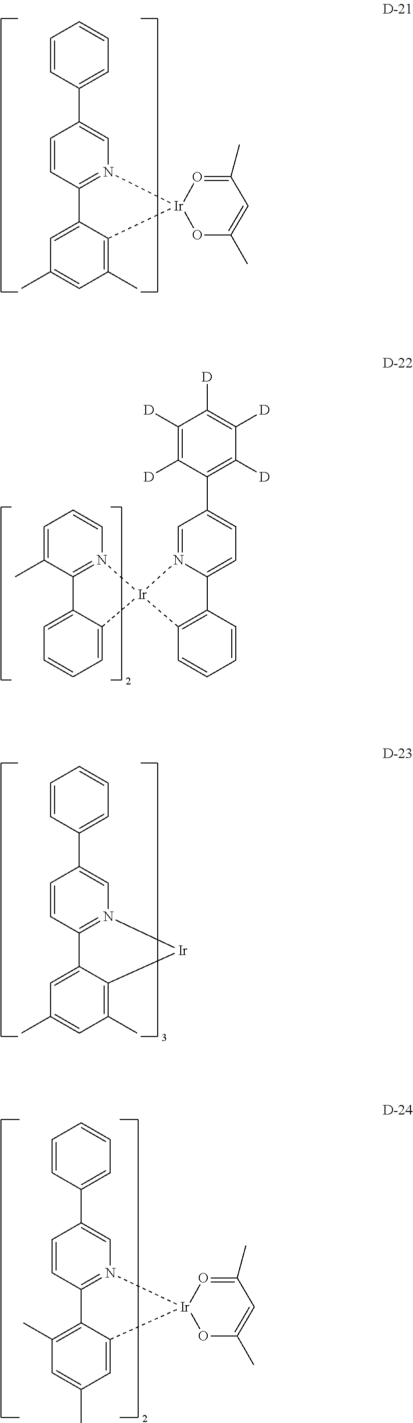

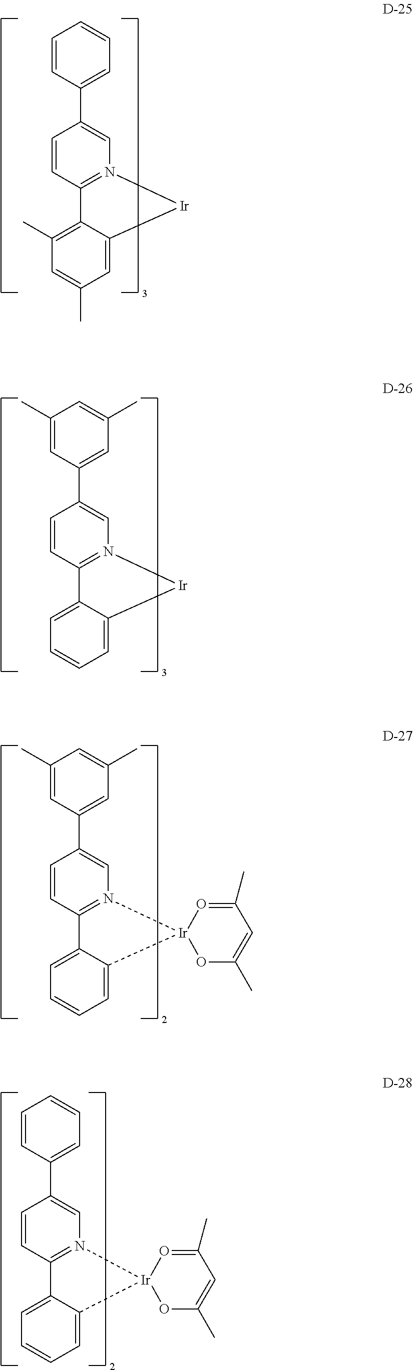

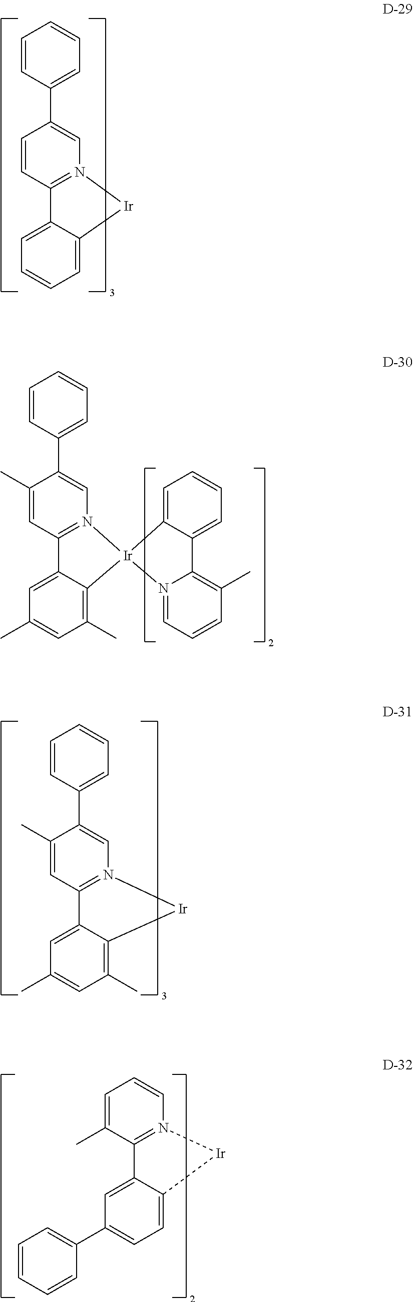

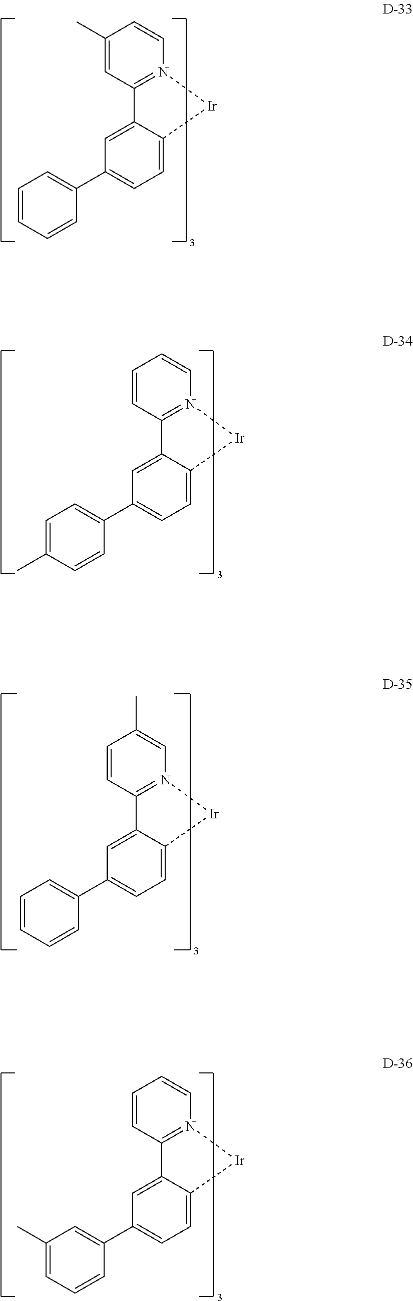

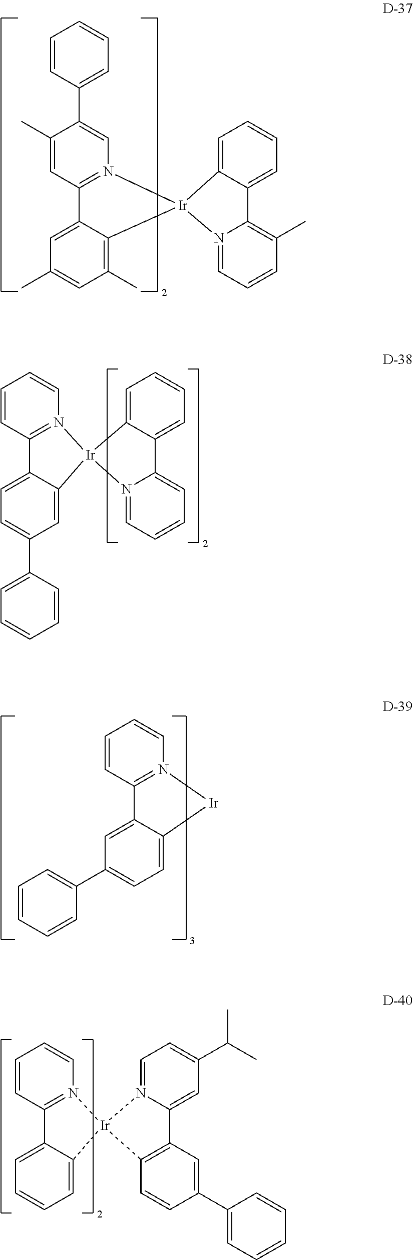

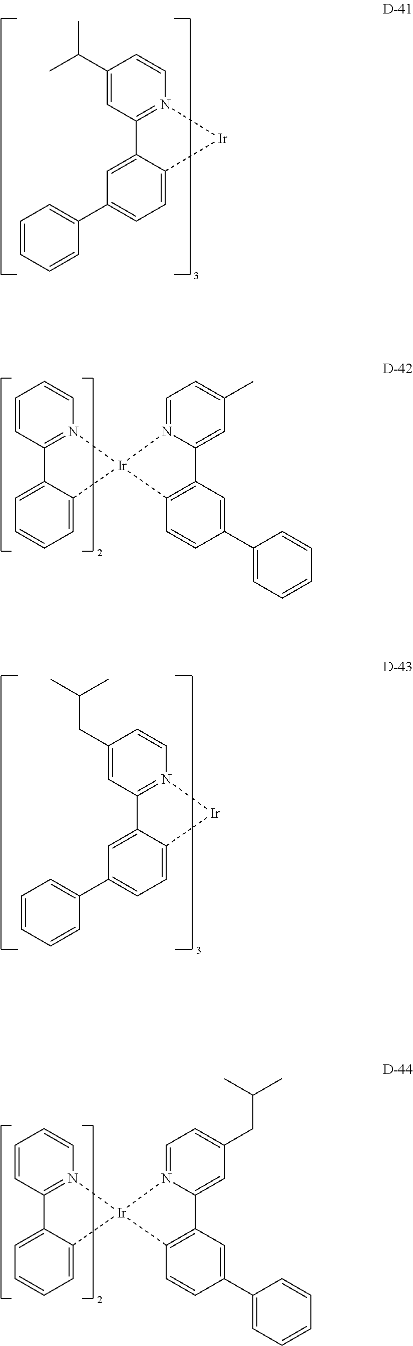

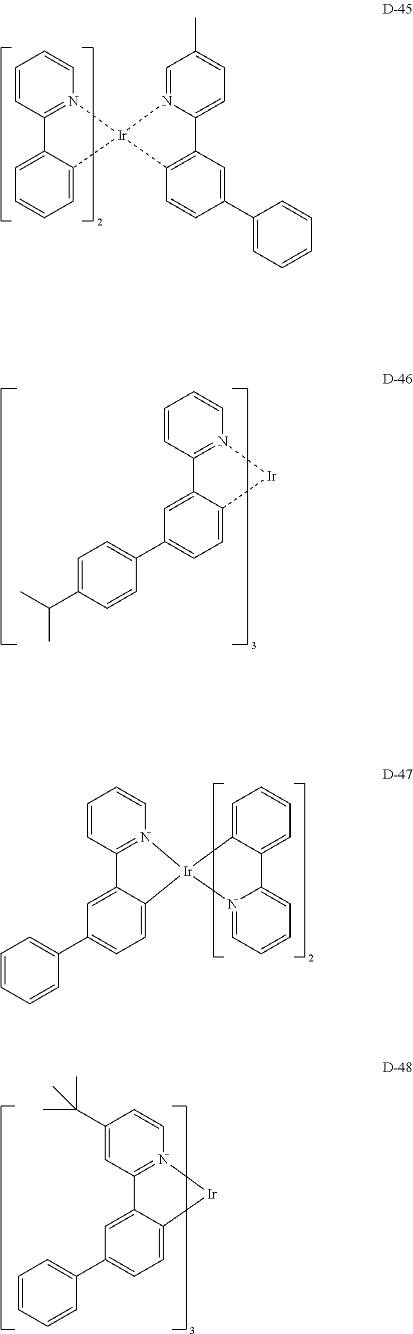

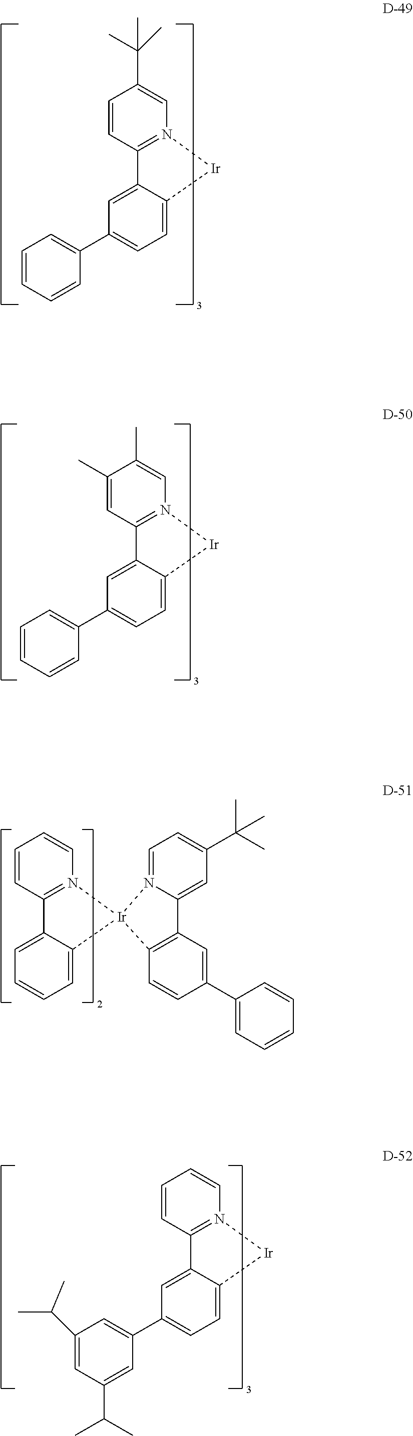

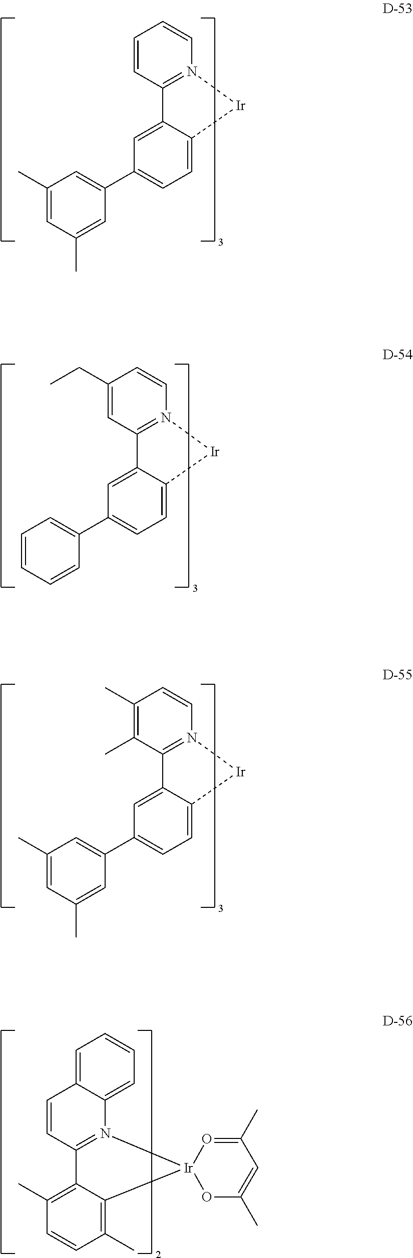

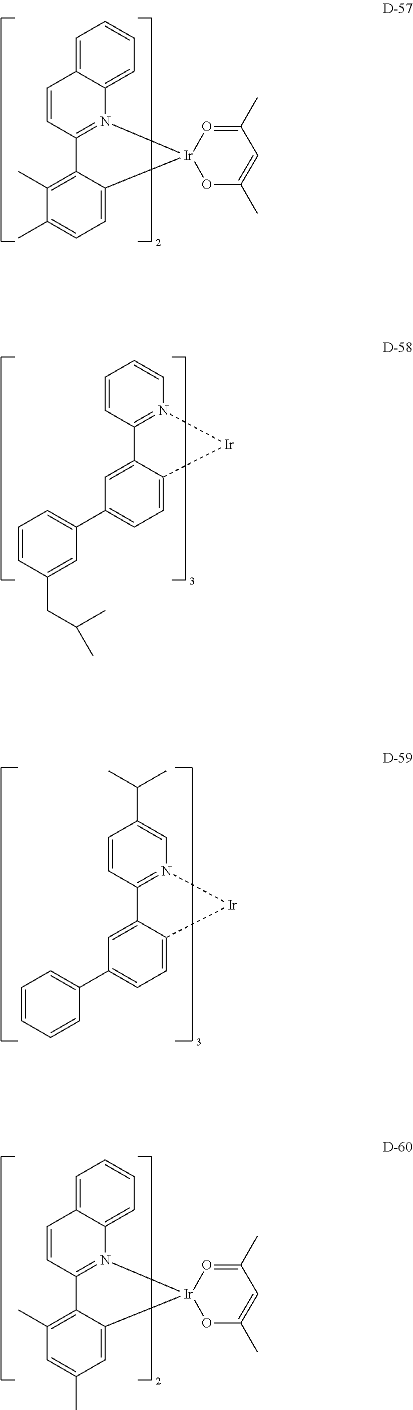

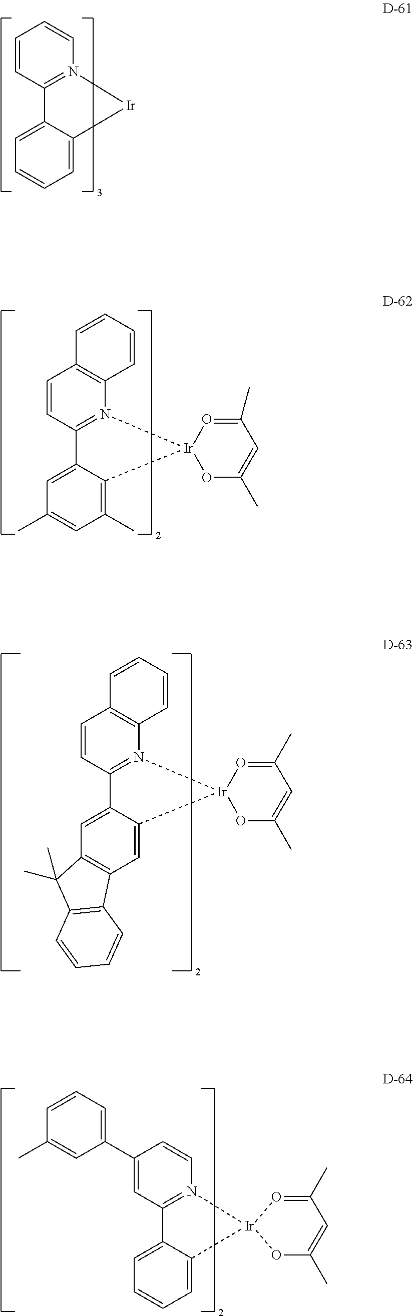

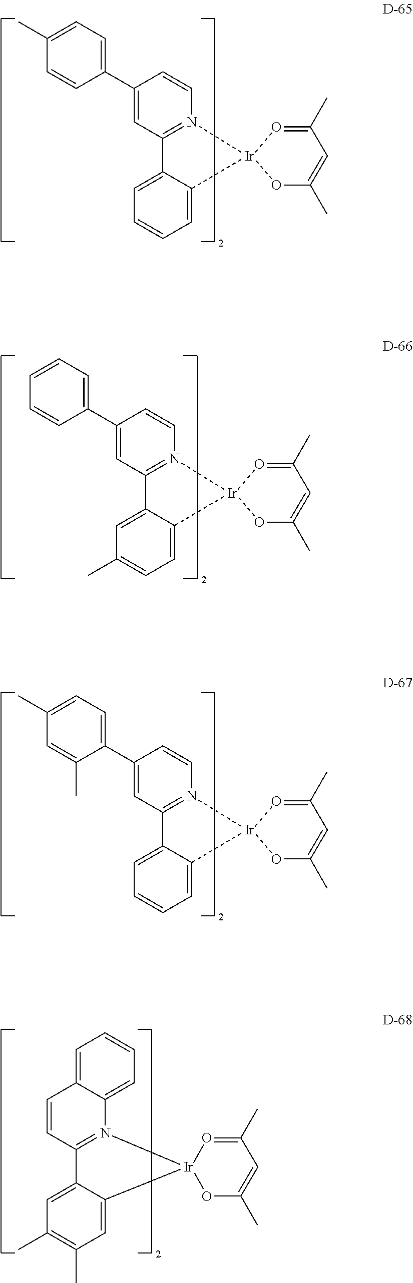

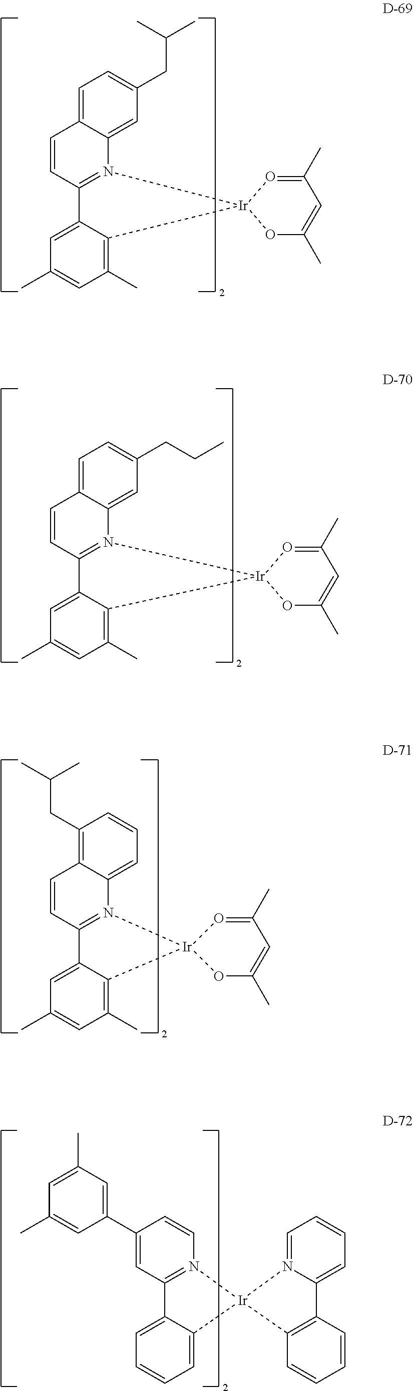

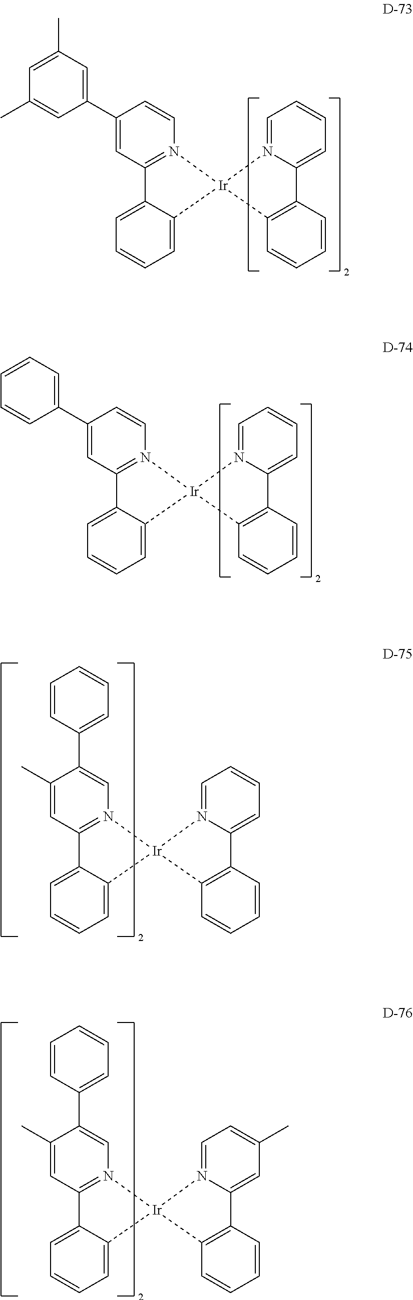

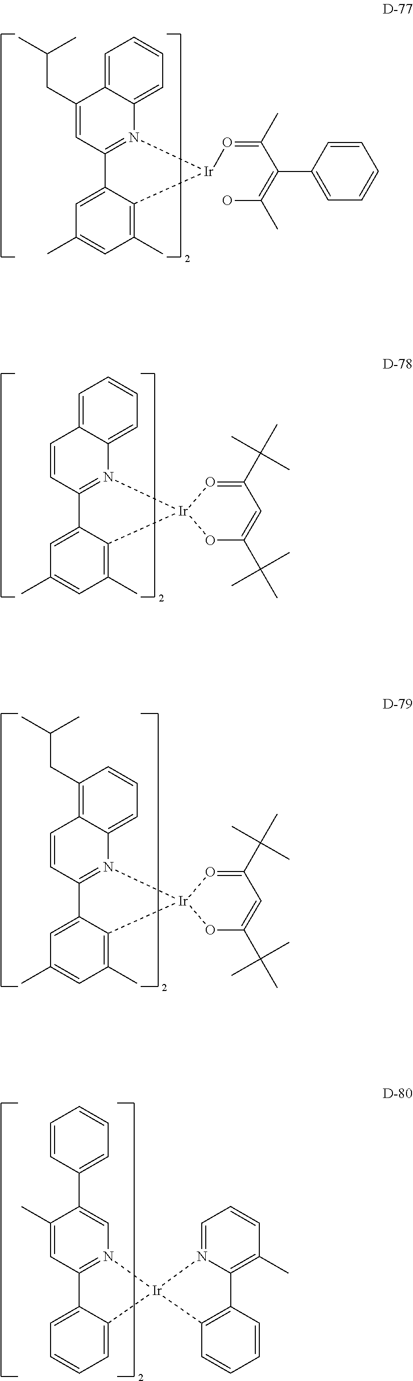

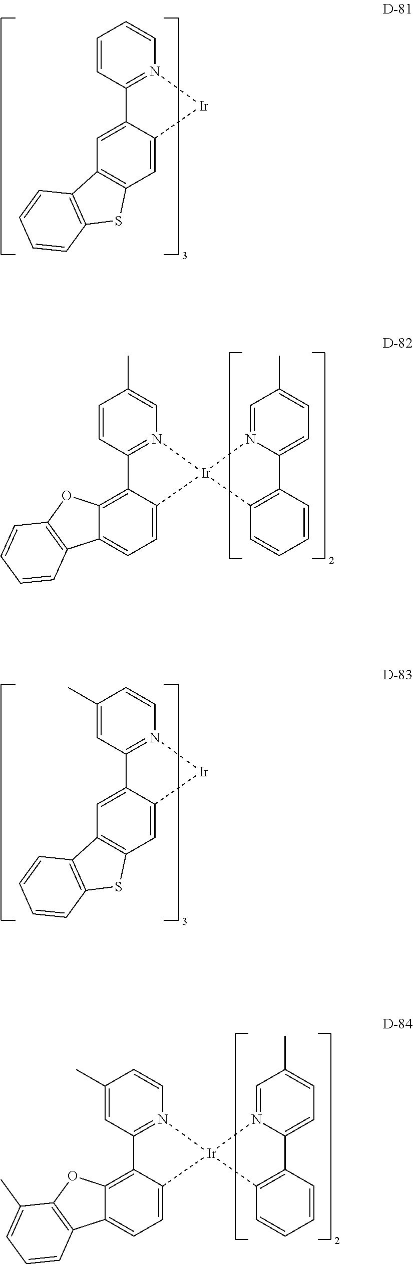

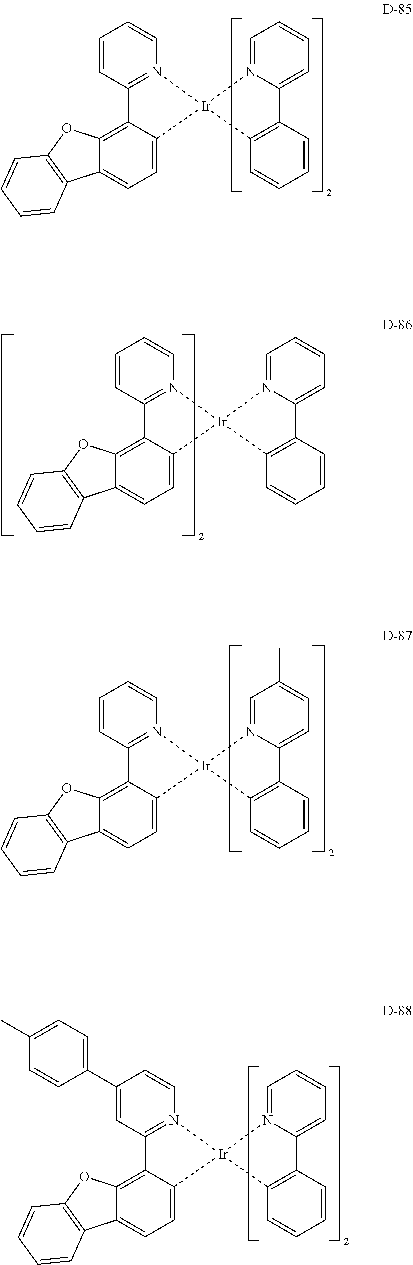

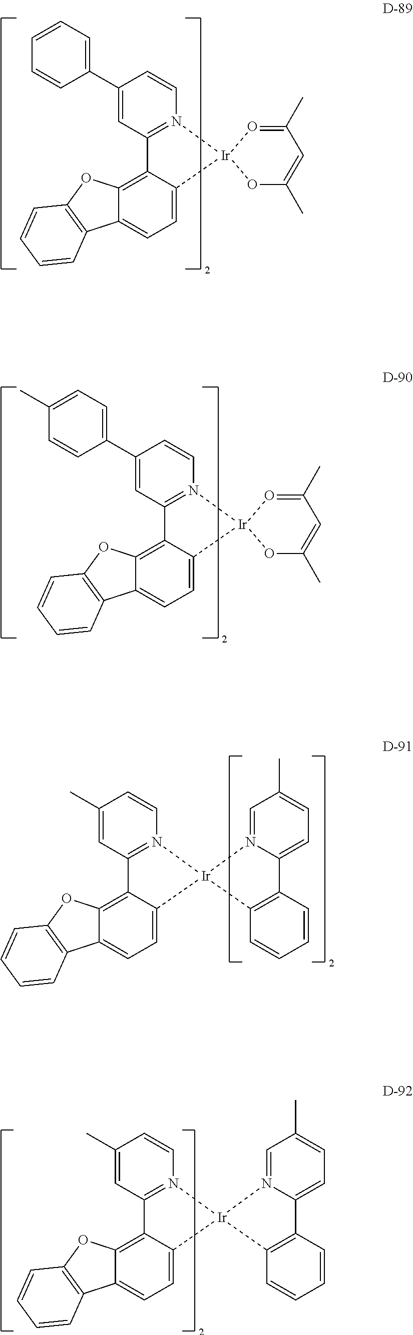

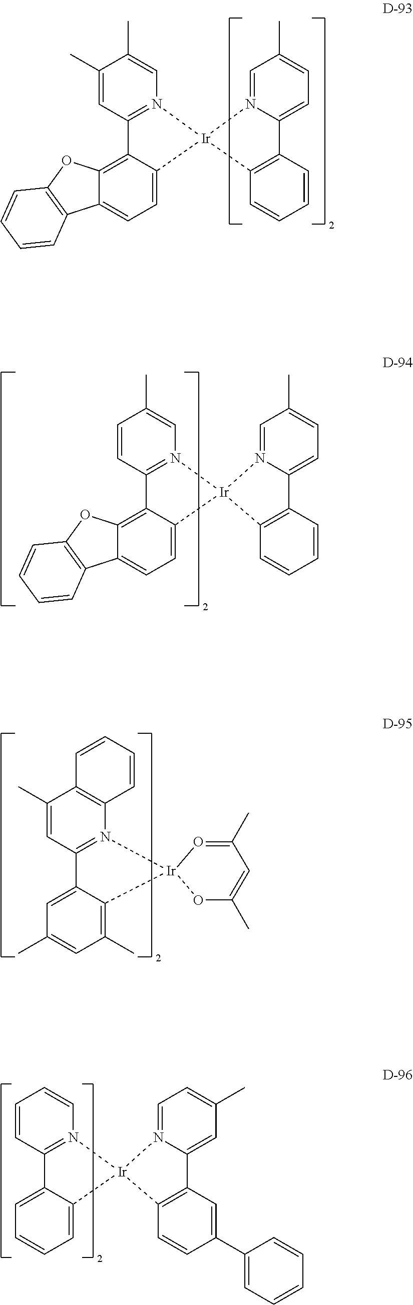

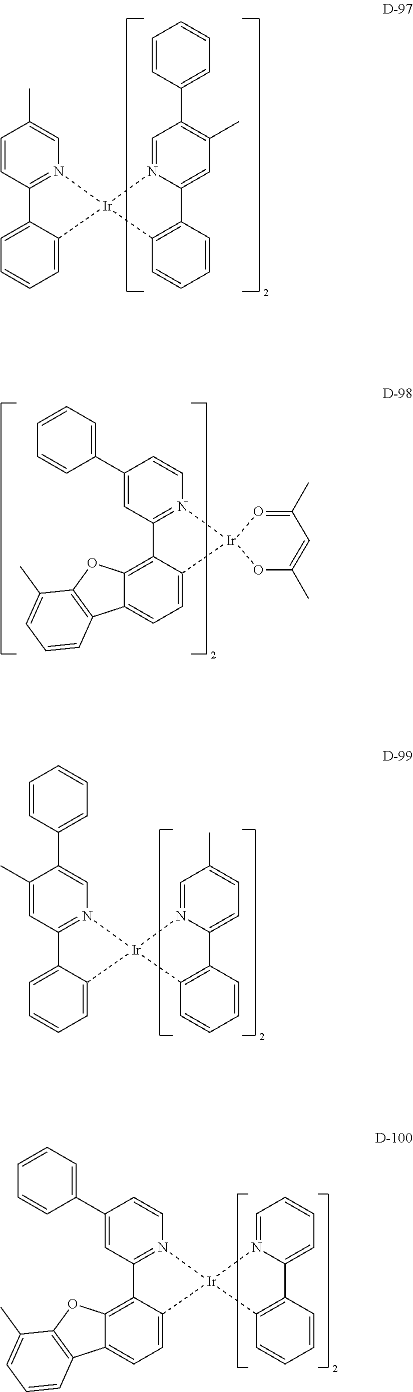

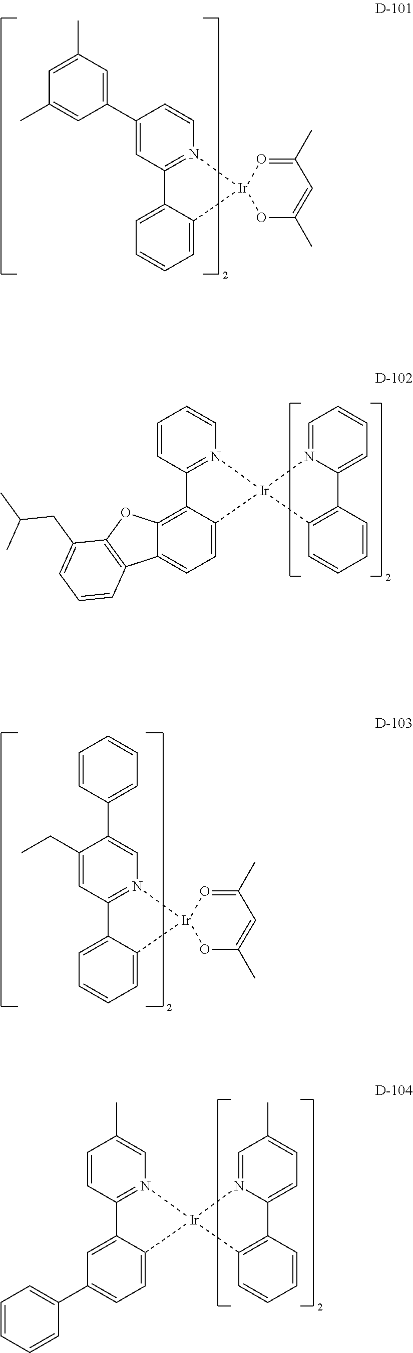

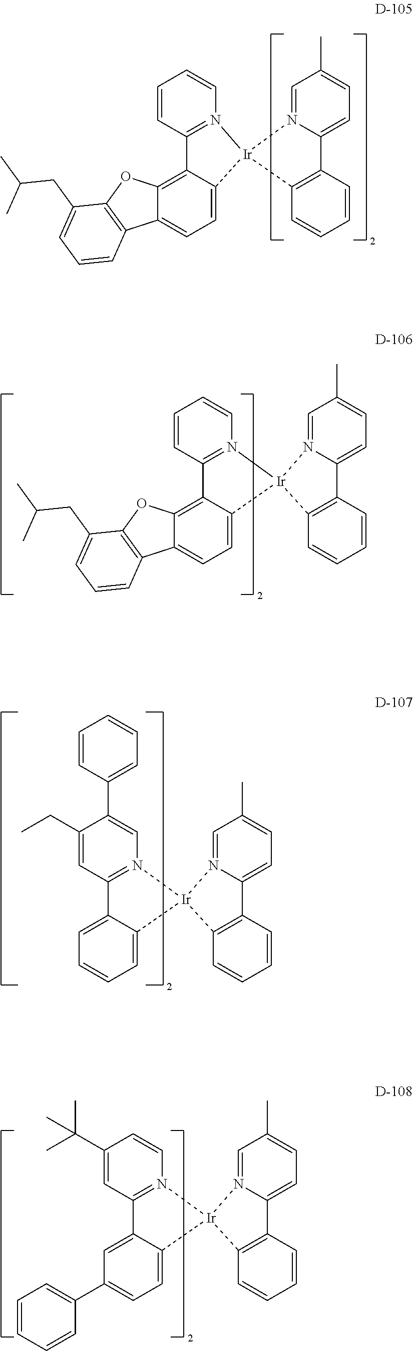

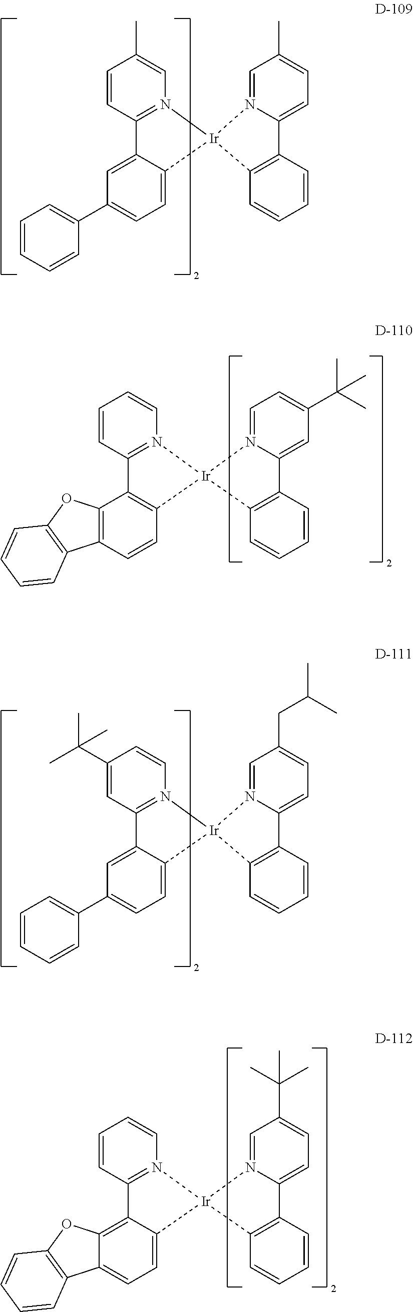

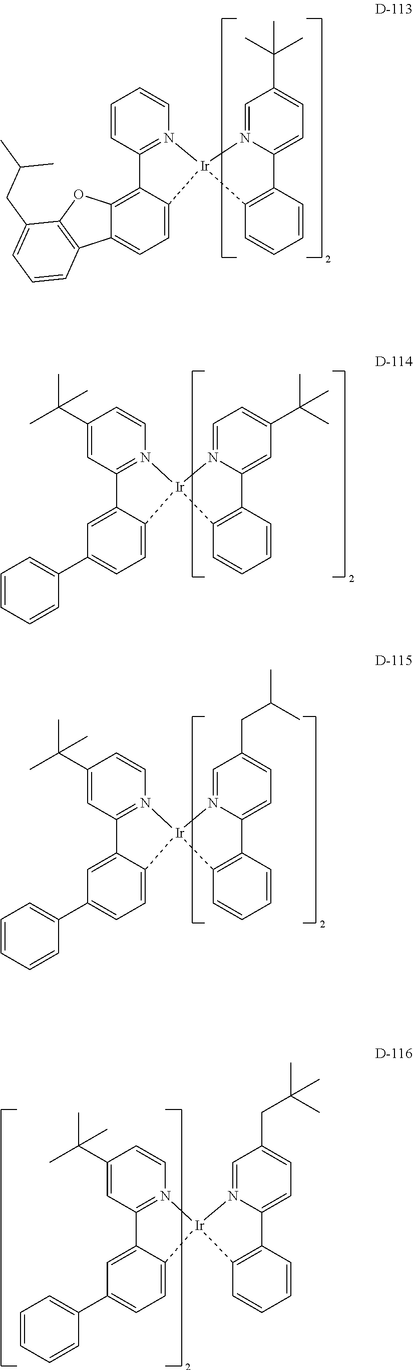

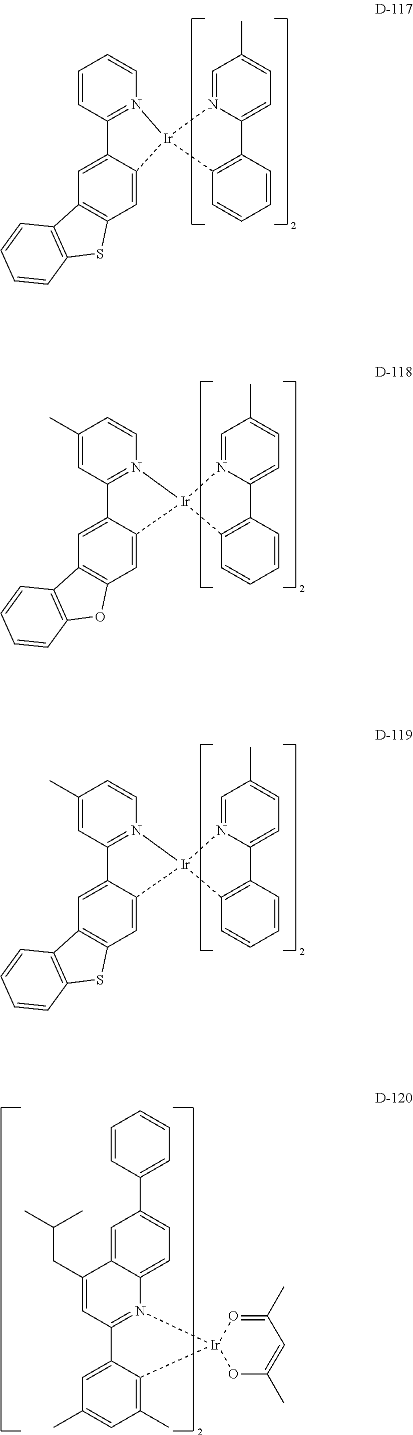

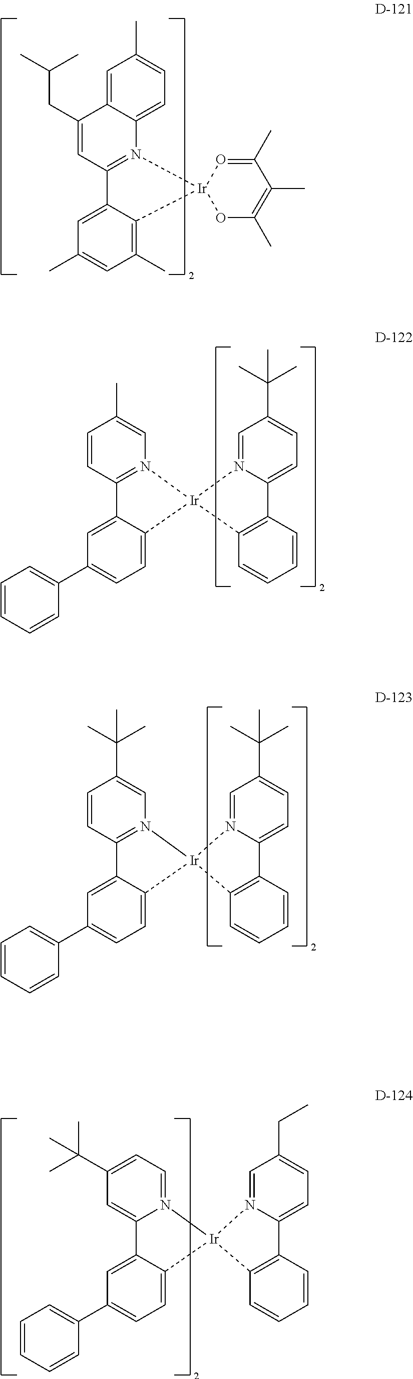

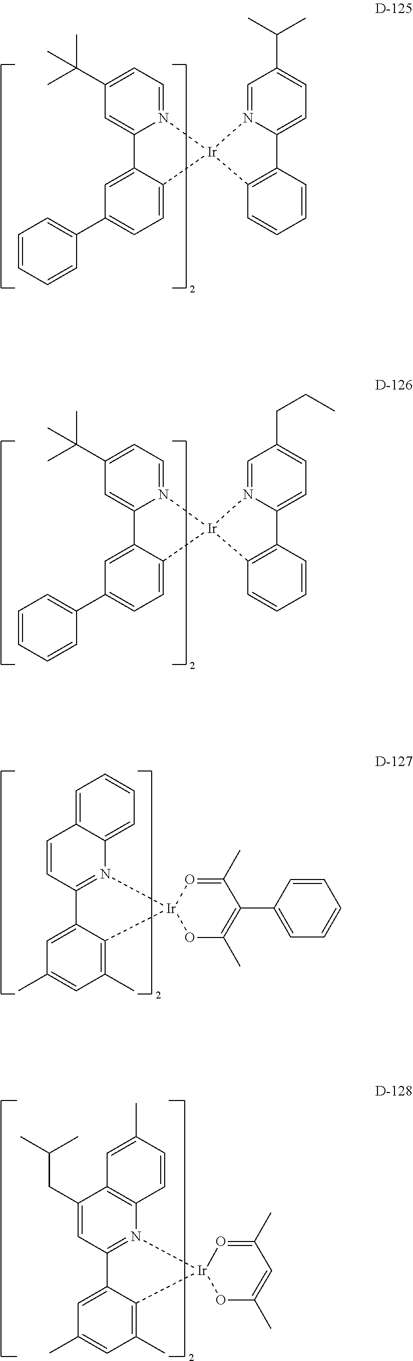

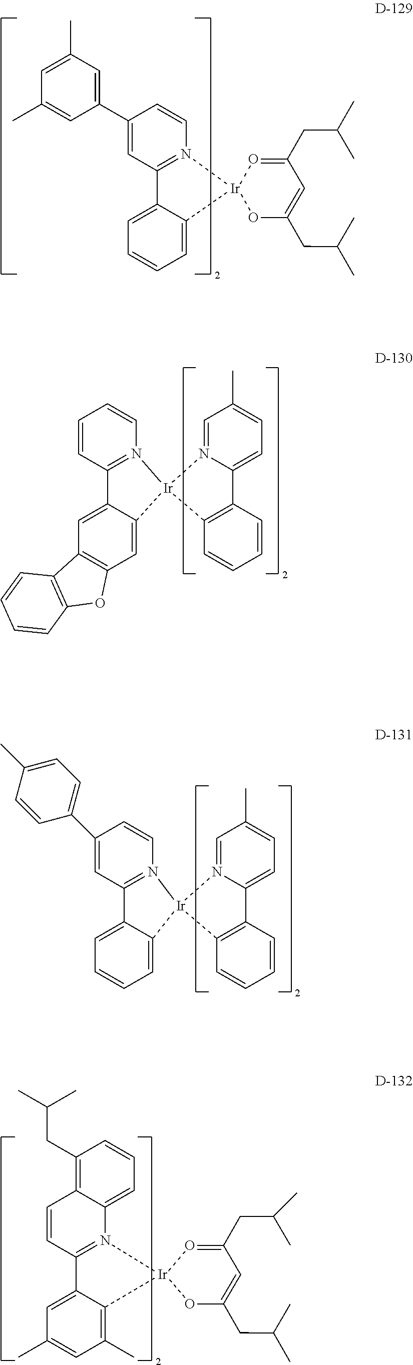

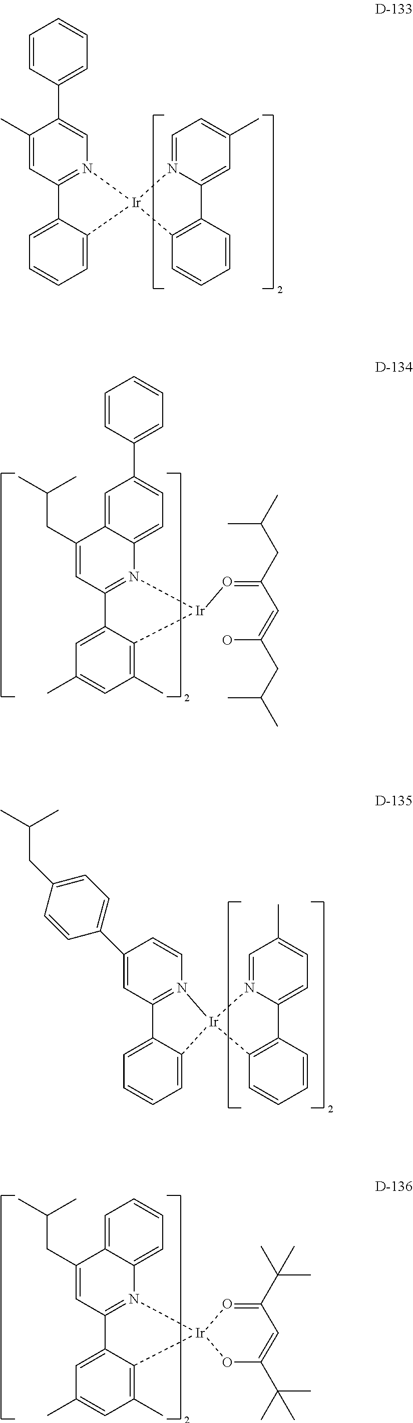

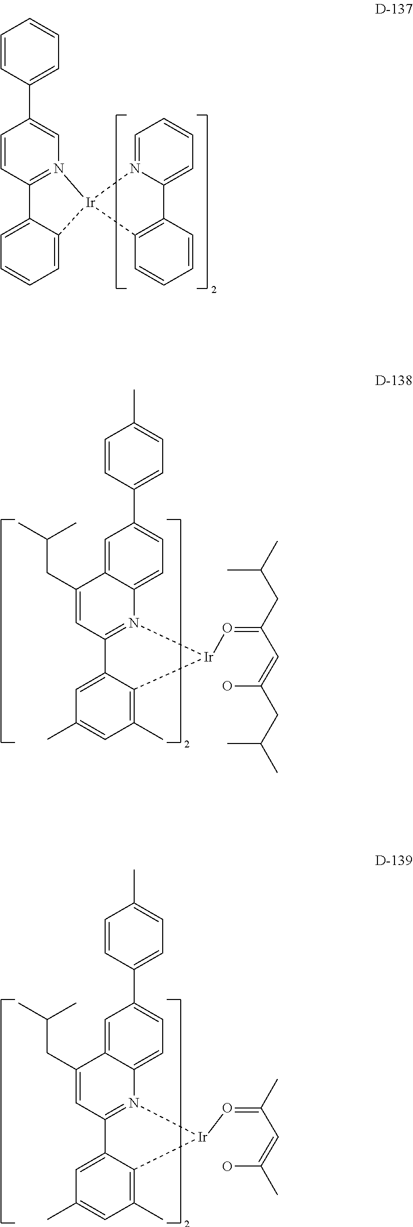

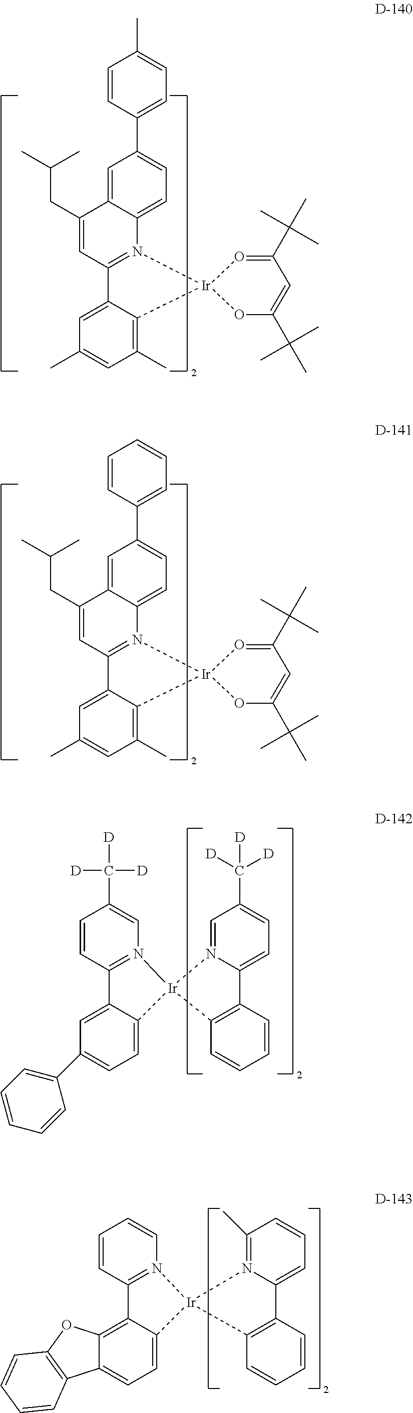

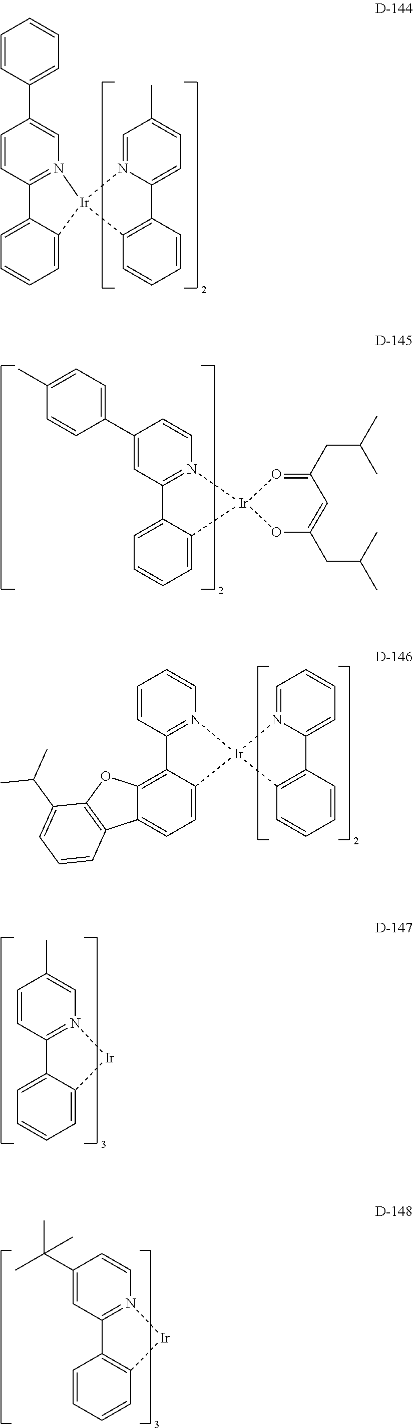

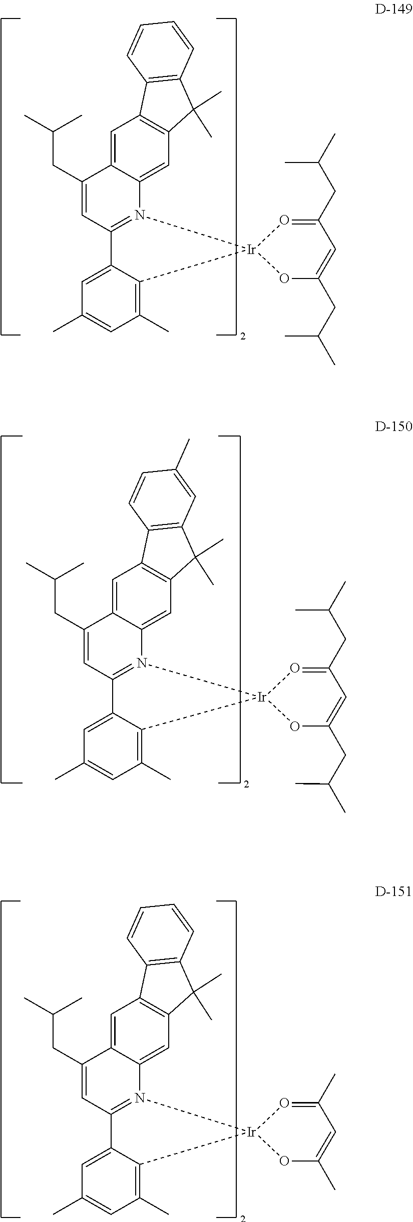

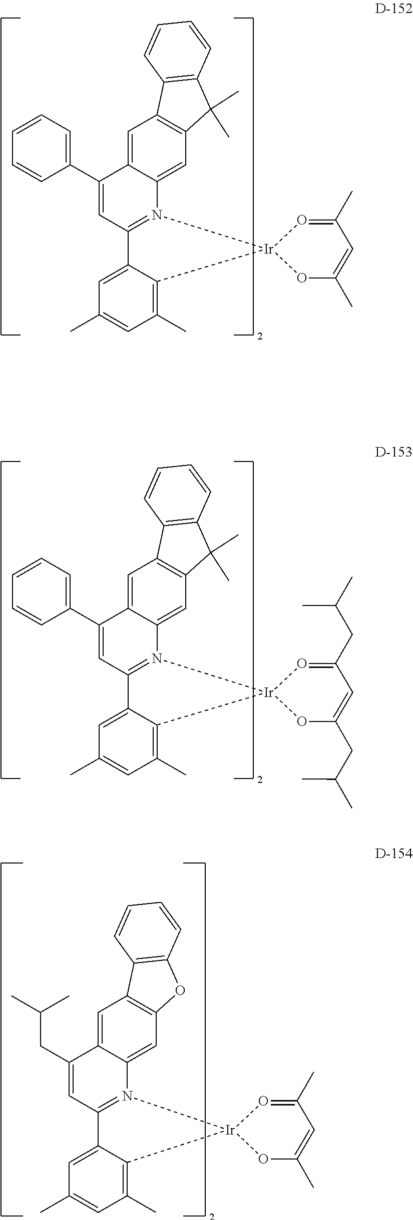

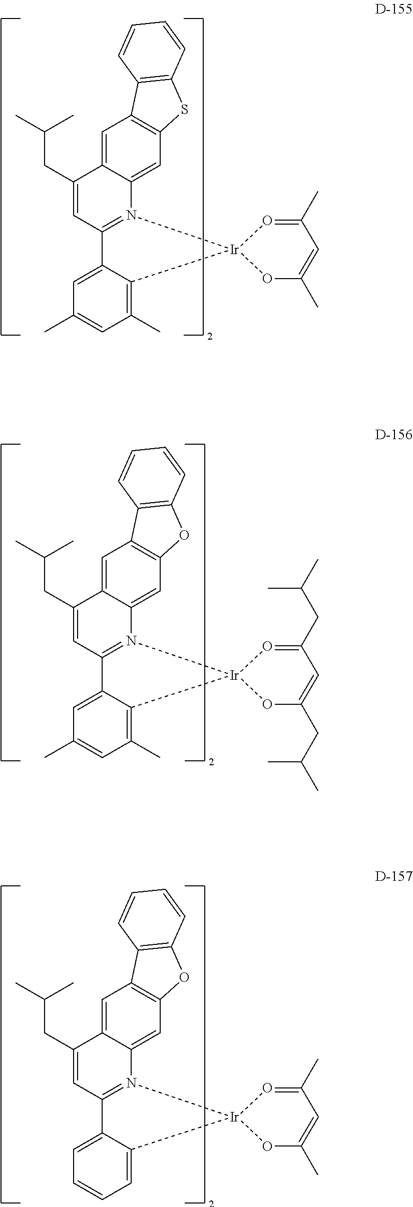

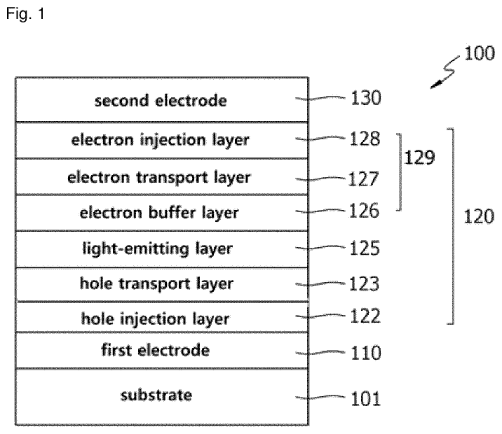

FIG. 1 illustrates a schematic sectional view of an organic electroluminescent device according to an embodiment of the present disclosure.

FIG. 1 shows an organic electroluminescent device 100 comprising a substrate 101, a first electrode 110 formed on the substrate 101, an organic layer 120 formed on the first electrode 110, and a second electrode 130 formed on the organic layer 120 and facing the first electrode 110.

The organic layer 120 comprises a hole injection layer 122, a hole transport layer 123 formed on the hole injection layer 122, a light-emitting layer 125 formed on the hole transport layer 123, and an electron transport zone 129 formed on the light-emitting layer 125; and the electron transport zone 129 comprises an electron buffer layer 126 formed on the light-emitting layer 125, an electron transport layer 127 formed on the electron buffer layer 126, and an electron injection layer 128 formed on the electron transport layer 127.

The light-emitting layer 125 may be prepared with a host compound and a dopant compound. The kinds of host compound and dopant compound to be used are not particularly limited, and may be selected from compounds known in the art. The examples of the host compound and the dopant compound are as described above. When the light-emitting layer 125 comprises a host and a dopant, the dopant can be doped in an amount of less than about 25 wt %, and preferably less than 17 wt %, based on the total amount of the dopant and host of the light-emitting layer. When the light emitting layer 125 is composed of two or more layers, each of the layers may be prepared to emit a color different from one another. For example, the device may emit white light by preparing three light-emitting layers 125 which emit blue, red, and green colors, respectively. Furthermore, the device may include light-emitting layers which emit yellow or orange color, if necessary.

The electron transport zone 129 means a zone in which electrons are transported from the second electrode to the light-emitting layer. The electron transport zone 129 can comprise an electron transport compound, a reductive dopant, or a combination thereof. The electron transport compound can be at least one selected from the group consisting of phenanthrene-based compounds, oxazole-based compounds, isoxazole-based compounds, triazole-based compounds, isothiazole-based compounds, oxadiazole-based compounds, thiadiazole-based compounds, perylene-based compounds, anthracene-based compounds, aluminum complexes, and gallium complexes. The reductive dopant may be selected from the group consisting of alkali metals, alkali metal compounds, alkaline earth metals, rare-earth metals, and halides, oxides, and complexes thereof. Specifically, the reductive dopant includes lithium quinolate, sodium quinolate, cesium quinolate, potassium quinolate, LiF, NaCl, CsF, Li₂O, BaO, and BaF₂, but is not limited thereto. In addition, the electron transport zone 129 can comprise an electron buffer layer 126, an electron transport layer 127, and/or an electron injection layer 128.

The thickness of the electron buffer layer 126 is 1 nm or more, but is not particularly limited thereto. Specifically, the thickness of the electron buffer layer 126 may be in the range of from 2 nm to 200 nm. The electron buffer layer 126 may be formed on the light-emitting layer 125 by using known various methods such as vacuum deposition, wet film-forming methods, laser induced thermal imaging, etc. The electron buffer layer indicates a layer controlling an electron flow. Therefore, the electron buffer layer may be, for example, a layer which traps electrons, blocks electrons, or lowers an energy barrier between an electron transport zone and a light-emitting layer. The electron buffer layer 126 may be comprised in an organic electroluminescent device emitting all kinds of colors, i.e. blue, red, green, etc.

The electron transport layer 127 and the electron injection layer 128 can each be composed of two or more layers.

The electron injection layer 128 may be prepared with any electron injection material known in the art, which includes lithium quinolate, sodium quinolate, cesium quinolate, potassium quinolate, LiF, NaCl, CsF, Li₂O, BaO, and BaF₂, but is not limited thereto.

The aforementioned description regarding the organic electroluminescent device shown in FIG. 1 is intended to explain one embodiment of the disclosure, and is not meant in any way to restrict the scope of the disclosure. The organic electroluminescent device can be constructed in another way. For example, any one optional component such as a hole injection layer may not be comprised in the organic electroluminescent device of FIG. 1, except for a light-emitting layer and an electron transport zone. In addition, an optional component may be further comprised therein, which includes one or more of an impurity layer such as n-doping layer and p-doping layer. The organic electroluminescent device may be a both side emission type in which a light-emitting layer is placed on each of both sides of the impurity layer. The two light-emitting layers on the impurity layer may emit different colors. The organic electroluminescent device may be a bottom emission type in which a first electrode is a transparent electrode and a second electrode is a reflective electrode. The organic electroluminescent device may be a top emission type in which a first electrode is a reflective electrode and a second electrode is a transparent electrode. The organic electroluminescent device may have an inverted type structure in which a cathode, an electron transport layer, a light-emitting layer, a hole transport layer, a hole injection layer, and an anode are sequentially stacked on a substrate.

The electron buffer layer of the present disclosure may comprise an electron buffer material comprising a compound represented by formula 11, or another electron buffer compound.

The electron transport zone of the present disclosure may comprise a compound represented by formula 11, an electron transport compound, a reductive dopant, or a combination thereof.

In addition, the electron transport layer of the present disclosure may comprise an electron transport material comprising a compound represented by formula 11 of the present disclosure. Further, the electron transport layer may comprise the aforementioned reductive dopant. A known electron injection material may be used for the material used in the electron injection layer, which includes lithium quinolate, sodium quinolate, cesium quinolate, potassium quinolate, LiF, NaCl, CsF, Li₂O, BaO, and BaF₂, but is not limited thereto.

Originally, LUMO (lowest unoccupied molecular orbital) energy and HOMO (highest occupied molecular orbital) energy levels have negative values. However, for convenience, LUMO energy level (A) and HOMO energy level are expressed in absolute values in the present disclosure. In addition, the values of the LUMO energy level are compared based on absolute values. Values calculated by density functional theory (DFT) are used for LUMO energy levels and HOMO energy levels in the present disclosure.

The LUMO energy levels can be easily measured by known various methods. Generally, LUMO energy levels are measured by cyclic voltammetry or ultraviolet photoelectron spectroscopy (UPS). Therefore, a person skilled in the art can easily comprehend the electron buffer layer, light-emitting layer, and electron transport layer that satisfy the equational relationship of the LUMO energy levels of the present disclosure, and practice the present disclosure. HOMO energy levels can be easily measured by the same method of measuring LUMO energy levels.

According to one embodiment of the organic electroluminescent device of the present disclosure, the LUMO energy value of the light-emitting layer (Ah) and the LUMO energy value of the electron transport zone (Ae) satisfy the following equation (1). Herein, Ae means the LUMO energy value of the electron transport zone comprising an electron transport layer and/or an electron buffer layer.

Ae≤Ah+0.5 eV (1)

In addition, for appropriate efficiency and/or long lifespan of the organic electroluminescent device, the following equation (2) is satisfied.

Ae≤Ah+0.2 eV (2)

The results according to the relationship of the LUMO energy values of the electron transport zone (Ae) and the light-emitting layer (Ah) are for explaining the rough tendency of the device in accordance with the overall LUMO energy groups, and so results other than the above can appear according to the inherent property of the specific derivatives, and the stability of the materials.

For the case of a light-emitting layer comprising a generally commercialized compound having a structure of a substituted carbazole or a fused carbazole, there is a limit in the improvement of the driving voltage and lifespan due to insufficient hole characteristic compared to electron current since the HOMO energy level is low. Meanwhile, for an electron transport zone, materials of fast electron current characteristic are required for low driving voltage in order to increase efficiency and improve power consumption. Thus, azines of a heterocyclic derivative are generally used. When combining a light-emitting layer of a carbazole-type compound and an electron transport zone of azines, the electron current characteristic within the device is relatively strong which leads to exciton quenching or triplet-polaron quenching since the excitons produced in the organic electroluminescent device are extremely formed between the hole transport zone and the light-emitting layer. Accordingly, efficiency and lifespan need to be improved.

Generally, external quantum efficiency (Nₑₓₜ) of an organic electroluminescent device means the number of photons emitted outside compared to the number of charges injected, and the definition is as follows:

Nₑₓₜ=Nᵢₙₜ*Nₒᵤₜ=γ*Nₑₓ*Øₚ*Nₒᵤₜ

Herein, Nₑₓₜ is the external quantum efficiency, Nᵢₙₜ is the internal quantum efficiency, and Nₒᵤₜ is the emission rate outside the device of the internally produced light. In addition, γ is the combining rate of holes and electrons, Nₑₓ is a producing rate of the excitons, and Øₚ is the PL quantum efficiency.

When using a carbazole-type material and azine-type material in the light-emitting layer and the electron transport zone, respectively, the charge-balance factor, which corresponds to γ, may be decreased due to a relatively fast electron current characteristic. However, in case of the combination of the organic electroluminescent compounds of the present disclosure, the insufficient hole current characteristic is compensated by an appropriate charge balance through the first host compound and the factor corresponding to γ is improved, which may contribute to an enhancement of the organic electroluminescent device performance. Further, the interfacial characteristic is improved by releasing the excitons extremely formed between the hole transport zone and the light-emitting layer to the light emitting layer/electron transport zone. Thus, an organic electroluminescent device of a relatively low driving voltage, excellent luminous efficiency such as current efficiency and power efficiency, and capable of realizing high color purity may be provided.

The fused azulene derivative corresponding to formula 1 of the present disclosure, which has a molecular shape having suitable rigidity, has a dihedral angle of about 15°. While a perfectly planar structure can induce crystallization due to aggregation, if intermolecular stacking is appropriately conducted, long lifespan as well as fast current characteristic is possible. Therefore, by using together with a particular structure of a derivative of triazine, quinazoline, quinoxaline, pyrimidine, etc., as a host material, a luminescent device of relatively low driving voltage, excellent luminous efficiency such as current efficiency and power efficiency, and capable of realizing high color purity may be provided. Herein, by using an azine-type heterocyclic derivative of high electron affinity as an electron transport zone material in the electron transport zone for low driving voltage, the electron injection becomes more easier, which may improve the driving voltage, efficiency, and lifespan of the device. When using an azulene compound corresponding to formula 1 of the present disclosure as a host material and an azine-type material having strong electron current characteristic as an electron transport material as a combination, an organic electroluminescent device of high efficiency and/or long lifespan as well as low driving voltage may be provided.

### Comparative Example 1: Producing a Red Light-Emitting OLED Device not According to the Present Disclosure

An OLED device not according to the present disclosure was produced as follows: A transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and then was stored in isopropanol. Next, the ITO substrate was mounted on a substrate holder of a vacuum vapor deposition apparatus. Compound HI-1 was introduced into a cell of the vacuum vapor deposition apparatus, and the pressure in the chamber of the apparatus was then controlled to 10⁻⁷ torr. Thereafter, an electric current was applied to the cell to evaporate the introduced material, thereby forming a first hole injection layer having a thickness of 80 nm on the ITO substrate. Compound HI-2 was then introduced into another cell of the vacuum vapor deposition apparatus, and an electric current was applied to the cell to evaporate the introduced material, thereby forming a second hole injection layer having a thickness of 5 nm on the first hole injection layer. Compound HT-1 was introduced into another cell of the vacuum vapor deposition apparatus. Thereafter, an electric current was applied to the cell to evaporate the introduced material, thereby forming a first hole transport layer having a thickness of 10 nm on the second hole injection layer. Compound HT-2 was then introduced into another cell of the vacuum vapor deposition apparatus, and an electric current was applied to the cell to evaporate the introduced material, thereby forming a second hole transport layer having a thickness of 60 nm on the first hole transport layer. After forming the hole injection layers and the hole transport layers, a light-emitting layer was then deposited as follows. Compound CBP as a host was introduced into one cell of the vacuum vapor deposition apparatus and compound D-71 as a dopant was introduced into another cell of the apparatus. The two materials were evaporated at a different rate and the dopant was deposited in a doping amount of 3 wt %, based on the total weight of the host and dopant, to form a light-emitting layer having a thickness of 40 nm on the second hole transport layer. Next, compound B-103 and compound ETL-1 were evaporated in a weight ratio of 50:50 as electron transport materials to form an electron transport layer having a thickness of 35 nm on the light-emitting layer. After depositing compound EIL-1 as an electron injection layer having a thickness of 2 nm on the electron transport layer, an Al cathode having a thickness of 80 nm was deposited by another vacuum vapor deposition apparatus on the electron injection layer. Thus, an OLED device was produced. All the materials used for producing the OLED device were purified by vacuum sublimation at 10⁻⁶ torr.

### Comparative Examples 2 to 6: Producing a Red Light-Emitting OLED Device not According to the Present Disclosure

An OLED device was produced in the same manner as in Comparative Example 1, except that compounds of Table 1 below were used as an electron transport material instead of compound B-103.

### Comparative Example 7: Producing a Red Light-Emitting OLED Device not According to the Present Disclosure

An OLED device was produced in the same manner as in Comparative Example 1, except that compound B-7 was used as a host material instead of compound CBP.

### Comparative Examples 8 to 12: Producing a Red Light-Emitting OLED Device not According to the Present Disclosure

An OLED device was produced in the same manner as in Comparative Example 7, except that compounds of Table 1 below were used as an electron transport material instead of compound B-103.

### Device Examples 1 to 6: Producing a Red Light-Emitting OLED Device According to the Present Disclosure

In Device Examples 1 to 6, an OLED device was produced in the same manner as in Comparative Example 1, except that compound CBP was used as a host material and compounds of Table 1 below were used as an electron transport material.

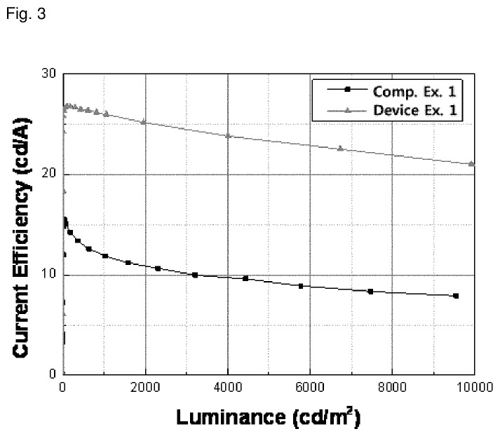

The driving voltage, luminous efficiency, CIE color coordinates, and the time period for the luminance to decrease from 100% to 95% (lifespan; T95) at a luminance of 5,000 nits of the organic electroluminescent devices produced in Comparative Examples 1 to 12 and Device Examples 1 to 6 are provided in Table 1 below. In addition, a current efficiency versus a luminance of the organic electroluminescent devices of Comparative Example 1 and Device Example 1 is illustrated in FIG. 3.

TABLE 1

| | | Electron | Driving | Luminous | Color | Color | |
|---|---|---|---|---|---|---|---|
| | Host | transport | voltage | efficiency | coordinate | coordinate | Lifespan |
| | material | material | (V) | (cd/A) | (x) | (y) | (T95, hr) |
| Comparative | CBP | B-103: EIL-1 | 11.3 | 9.4 | 0.657 | 0.338 | 0.37 |
| Example 1 | | | | | | | |
| Comparative | | B-101: EIL-1 | 11.8 | 9.2 | 0.657 | 0.338 | 0.30 |
| Example 2 | | | | | | | |
| Comparative | | B-92: EIL-1 | 11.8 | 8.7 | 0.656 | 0.338 | 0.34 |
| Example 3 | | | | | | | |
| Comparative | | B-117: EIL-1 | 11.8 | 8.4 | 0.657 | 0.338 | 0.27 |
| Example 4 | | | | | | | |
| Comparative | | B-100: EIL-1 | 11.9 | 9.4 | 0.657 | 0.338 | 0.26 |
| Example 5 | | | | | | | |
| Comparative | | B-31: EIL-1 | 11.8 | 10.1 | 0.657 | 0.338 | 0.32 |
| Example 6 | | | | | | | |
| Comparative | B-7 | B-103: EIL-1 | 5.0 | 20.9 | 0.662 | 0.337 | 65.5 |
| Example 7 | | | | | | | |
| Comparative | | B-101: EIL-1 | 4.8 | 21.2 | 0.662 | 0.337 | 56.4 |
| Example 8 | | | | | | | |
| Comparative | | B-92: EIL-1 | 4.8 | 20.9 | 0.662 | 0.337 | 58.0 |
| Example 9 | | | | | | | |
| Comparative | | B-117: EIL-1 | 4.9 | 20.8 | 0.662 | 0.337 | 65.0 |
| Example 10 | | | | | | | |
| Comparative | | B-100: EIL-1 | 5.9 | 20.6 | 0.661 | 0.338 | 60.5 |
| Example 11 | | | | | | | |
| Comparative | | B-31: EIL-1 | 5.7 | 21.0 | 0.661 | 0.338 | 83.1 |
| Example 12 | | | | | | | |
| Device | C-241 | B-103: EIL-1 | 4.2 | 23.4 | 0.665 | 0.335 | 350.4 |
| Example 1 | | | | | | | |
| Device | | B-101: EIL-1 | 4.0 | 23.1 | 0.665 | 0.335 | 396.3 |
| Example 2 | | | | | | | |
| Device | | B-92: EIL-1 | 3.9 | 22.4 | 0.665 | 0.335 | 338.3 |
| Example 3 | | | | | | | |
| Device | | B-117: EIL-1 | 4.0 | 23.4 | 0.665 | 0.335 | 402.4 |
| Example 4 | | | | | | | |
| Device | | B-100: EIL-1 | 4.1 | 23.1 | 0.665 | 0.335 | 428.3 |
| Example 5 | | | | | | | |
| Device | | B-31: EIL-1 | 4.3 | 23.3 | 0.665 | 0.334 | 371.4 |
| Example 6 | | | | | | | |

### Comparative Example 13: Producing a Red Light-Emitting OLED Device not According to the Present Disclosure

An OLED device was produced in the same manner as in Device Example 1, except that compound HT-3 of Table 4 below was evaporated as a second hole transport layer, the electron buffer material of Table 2 below was evaporated as an electron buffer layer on the light emitting layer in a thickness of 5 nm, and Alq3 was evaporated as an electron transport material on the electron buffer layer in a thickness of 30 nm.

### Device Examples 7 to 11: Producing a Red Light-Emitting OLED Device According to the Present Disclosure

In Device Examples 7 to 11, an OLED device was produced in the same manner as in Comparative Example 13, except that the compounds of Table 2 below were evaporated in a weight ratio of 50:50 as electron transport materials on the electron buffer layer in a thickness of 30 nm.

The driving voltage, luminous efficiency, CIE color coordinates at a luminance of 1,000 nits, and the time period for the luminance to decrease from 100% to 95% (lifespan; T95) at a luminance of 5,000 nits of the organic electroluminescent devices produced in Comparative Example 13 and Device Examples 7 to 11 are provided in Table 2 below.

TABLE 2

| | | Electron | Electron | Driving | Luminous | Color | Color | |
|---|---|---|---|---|---|---|---|---|
| | Host | buffer | transport | voltage | efficiency | coordinate | coordinate | Lifespan |
| | material | material | material | (V) | (cd/A) | (x) | (y) | (T95, hr) |
| Comparative | C-241 | B-2 | Alq3 | 5.1 | 24.0 | 0.666 | 0.333 | 10.7 |
| Example 13 | | | | | | | | |
| Device | | | B-103: EIL-1 | 3.7 | 27.8 | 0.667 | 0.333 | 216.6 |
| Example 7 | | | | | | | | |
| Device | | | B-106: EIL-1 | 3.5 | 27.5 | 0.667 | 0.333 | 210.0 |
| Example 8 | | | | | | | | |
| Device | | | B-118: EIL-1 | 3.5 | 28.0 | 0.668 | 0.332 | 320.5 |
| Example 9 | | | | | | | | |
| Device | | | B-35: EIL-1 | 4.0 | 27.9 | 0.668 | 0.332 | 340.1 |
| Example 10 | | | | | | | | |
| Device | | | B-119: EIL-1 | 3.6 | 28.5 | 0.668 | 0.332 | 251.1 |
| Example 11 | | | | | | | | |

From Tables 1 and 2, it is verified that Device Examples 1 to 11 using the compound of the present disclosure in the light-emitting layer, and the electron buffer layer and/or electron transport layer show low driving voltage, high efficiency, and/or long lifespan characteristics compared to Comparative Examples 1 to 13. Particularly, as a combination with the electron transport material, using compound C-241, compared to compound B-7, as the host material showed improved device characteristics as shown in Table 1. It is understood that the combination of the host of an azulene group having appropriate intermolecular stacking and the electron transport material of azines together with the improved charge balance factor of the azulene derivative compared to the benzocarbazole derivative contributed to the enhancement of the device performance.

### Device Examples 12 to 16: Producing a Red Light-Emitting OLED Device According to the Present Disclosure

In Device Examples 12 to 16, an OLED device was produced in the same manner as in Comparative Example 1, except that compound HT-4 of Table 4 below was evaporated as a second hole transport layer, and using compound C-246 as a host material and the compounds of Table 3 instead of compound B-103 as electron transport materials.

The driving voltage, luminous efficiency, CIE color coordinates at a luminance of 1,000 nits, and the time period for the luminance to decrease from 100% to 95% (lifespan; T95) at a luminance of 5,000 nits of the organic electroluminescent devices produced in Device Examples 12 to 16 are provided in Table 3 below.

TABLE 3

| | | Electron | Driving | Luminous | Color | Color | |
|---|---|---|---|---|---|---|---|
| | Host | transport | voltage | efficiency | coordinate | coordinate | Lifespan |
| | material | material | (V) | (cd/A) | (x) | (y) | (T95, hr) |
| Device | C-246 | B-120: EIL-1 | 3.0 | 28.2 | 0.669 | 0.331 | 266.8 |
| Example | | | | | | | |
| 12 | | | | | | | |
| Device | | B-121: EIL-1 | 3.1 | 28.0 | 0.669 | 0.331 | 290.5 |
| Example | | | | | | | |
| 13 | | | | | | | |
| Device | | B-122: EIL-1 | 3.1 | 28.2 | 0.669 | 0.331 | 299.7 |
| Example | | | | | | | |
| 14 | | | | | | | |
| Device | | B-123: EIL-1 | 3.2 | 26.6 | 0.671 | 0.329 | 312.7 |
| Example | | | | | | | |
| 15 | | | | | | | |
| Device | | B-124: EIL-1 | 3.5 | 26.5 | 0.672 | 0.328 | 294.8 |
| Example | | | | | | | |
| 16 | | | | | | | |

From Table 3, it is verified that Device Examples 12 to 16 using the compound of the present disclosure in the light-emitting layer and the electron transport layer show low driving voltage, high efficiency, and/or long lifespan characteristics compared to Comparative Examples 1 to 13.

In particular, the organic electroluminescent device comprising the specific combination of compounds of the present disclosure is considered to be suitably applied to flexible displays, lightings, and vehicle displays which require long lifespan.

The compounds used in the Comparative Examples and Device Examples are shown in Table 4 below.

TABLE 4
Hole Injection Layer/Hole Transport Layer

| | |
|---|---|
| 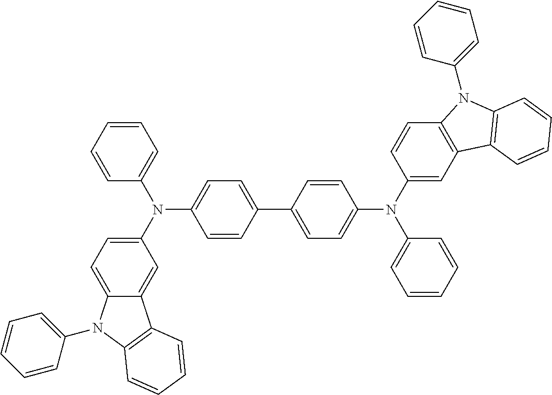 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1] | HI-1 |
| 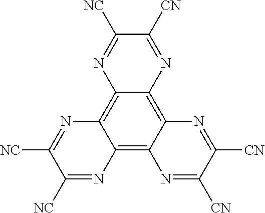 [SMILES: N#Cc1nc2c3nc(C#N)c(C#N)nc3c3nc(C#N)c(C#N)nc3c2nc1C#N] | HI-2 |
| 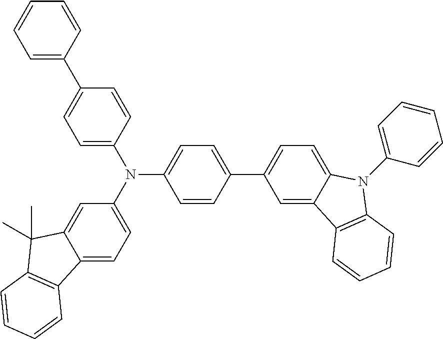 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] | HT-1 |
| 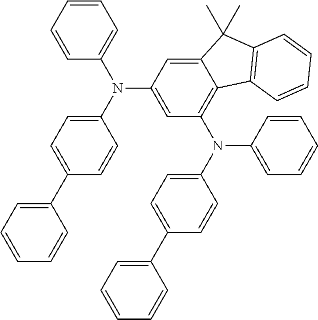 [SMILES: CC1(C)c2ccccc2-c2c(N(c3ccccc3)c3ccc(-c4ccccc4)cc3)cc(N(c3ccccc3)c3ccc(-c4ccccc4)cc3)cc21] | HT-2 |
| 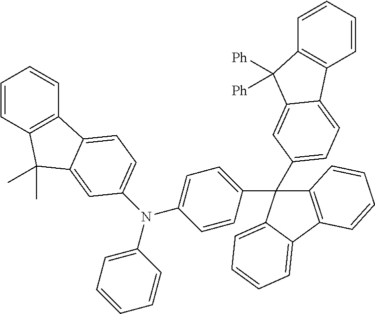 [SMILES: CC1(C)c2ccccc2-c2ccc(N(c3ccccc3)c3ccc(C4(c5ccc6c(c5)C(c5ccccc5)(c5ccccc5)c5ccccc5-6)c5ccccc5-c5ccccc54)cc3)cc21] | HT-3 |
| 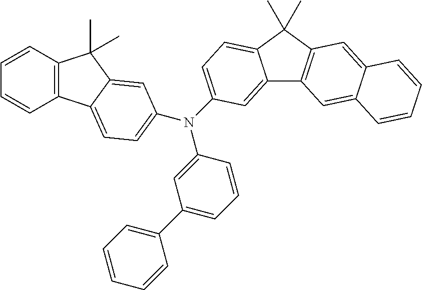 [SMILES: CC1(C)c2ccccc2-c2ccc(N(c3cccc(-c4ccccc4)c3)c3ccc4c(c3)-c3cc5ccccc5cc3C4(C)C)cc21] | HT-4 |

Light-Emitting Layer

| | |
|---|---|
| 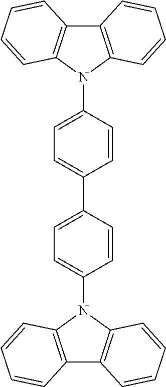 [SMILES: c1ccc2c(c1)c1ccccc1n2-c1ccc(-c2ccc(-n3c4ccccc4c4ccccc43)cc2)cc1] | CBP |
| 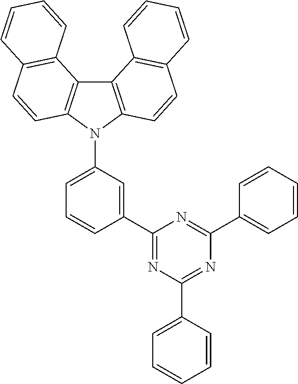 [SMILES: c1ccc(-c2nc(-c3ccccc3)nc(-c3cccc(-n4c5ccc6ccccc6c5c5c6ccccc6ccc54)c3)n2)cc1] | B-7 |
| 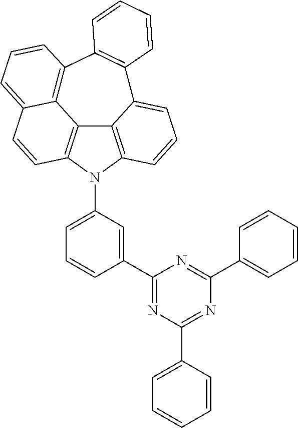 [SMILES: c1ccc(-c2nc(-c3ccccc3)nc(-c3cccc(-n4c5cccc6c5c5c7c(cccc7ccc54)-c4ccccc4-6)c3)n2)cc1] | C-241 |
| 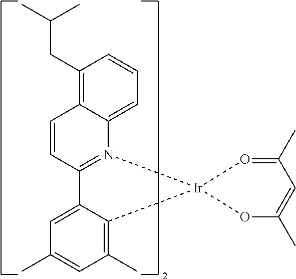 | D-71 |
| 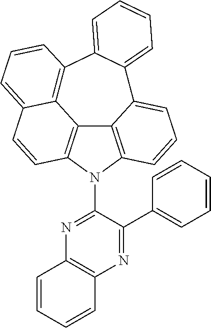 [SMILES: c1ccc(-c2nc3ccccc3nc2-n2c3cccc4c3c3c5c(cccc5ccc32)-c2ccccc2-4)cc1] | C-246 |

Electron Buffer Layer/Electron Transport Layer/Electron Injection Layer

| | |
|---|---|
| 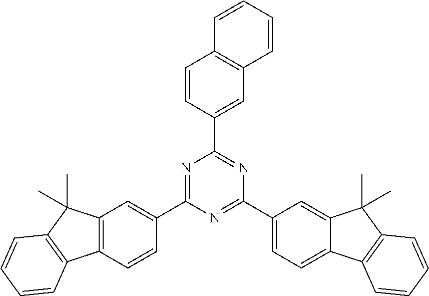 [SMILES: CC1(C)c2ccccc2-c2ccc(-c3nc(-c4ccc5c(c4)C(C)(C)c4ccccc4-5)nc(-c4ccc5ccccc5c4)n3)cc21] | B-103 |
| 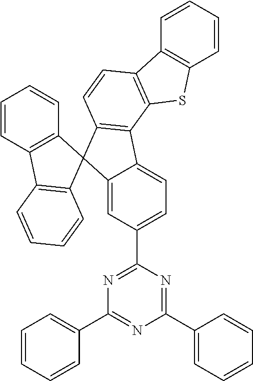 [SMILES: c1ccc(-c2nc(-c3ccccc3)nc(-c3ccc4c(c3)C3(c5ccccc5-c5ccccc53)c3ccc5c(sc6ccccc65)c3-4)n2)cc1] | B-101 |
| 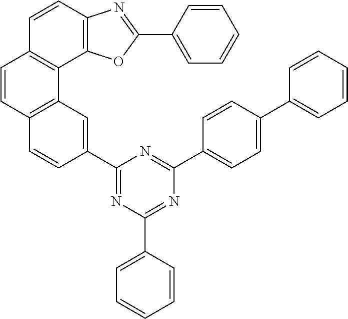 [SMILES: c1ccc(-c2ccc(-c3nc(-c4ccccc4)nc(-c4ccc5ccc6ccc7nc(-c8ccccc8)oc7c6c5c4)n3)cc2)cc1] | B-92 |
| 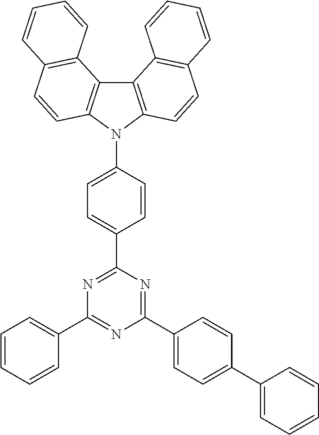 [SMILES: c1ccc(-c2ccc(-c3nc(-c4ccccc4)nc(-c4ccc(-n5c6ccc7ccccc7c6c6c7ccccc7ccc65)cc4)n3)cc2)cc1] | B-117 |
| 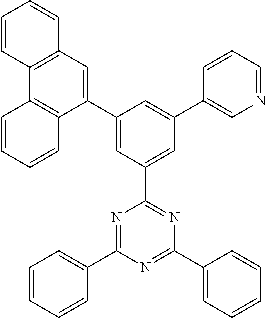 [SMILES: c1ccc(-c2nc(-c3ccccc3)nc(-c3cc(-c4cccnc4)cc(-c4cc5ccccc5c5ccccc45)c3)n2)cc1] | B-100 |
| 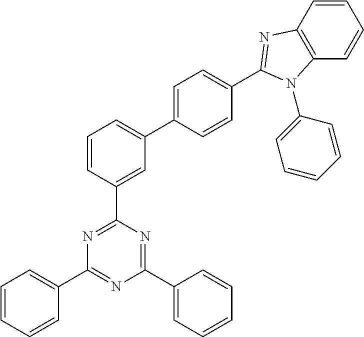 [SMILES: c1ccc(-c2nc(-c3ccccc3)nc(-c3cccc(-c4ccc(-c5nc6ccccc6n5-c5ccccc5)cc4)c3)n2)cc1] | B-31 |
| 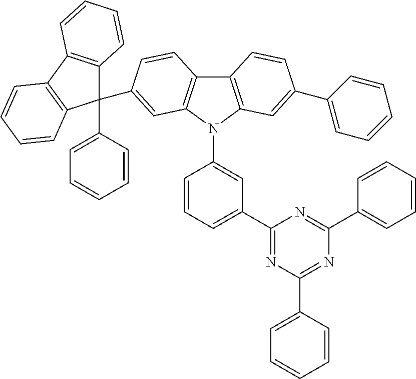 [SMILES: c1ccc(-c2ccc3c4ccc(C5(c6ccccc6)c6ccccc6-c6ccccc65)cc4n(-c4cccc(-c5nc(-c6ccccc6)nc(-c6ccccc6)n5)c4)c3c2)cc1] | B-2 |
| 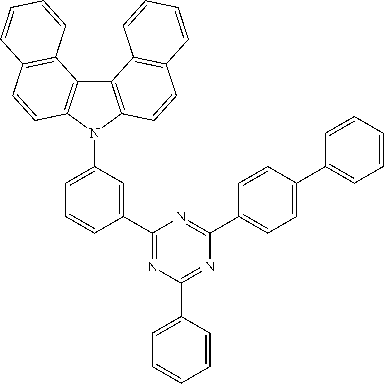 [SMILES: c1ccc(-c2ccc(-c3nc(-c4ccccc4)nc(-c4cccc(-n5c6ccc7ccccc7c6c6c7ccccc7ccc65)c4)n3)cc2)cc1] | B-106 |
| 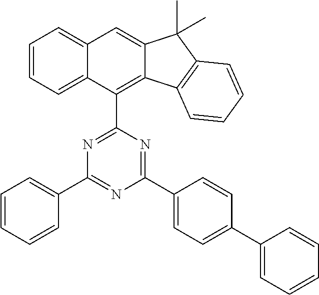 [SMILES: CC1(C)c2ccccc2-c2c1cc1ccccc1c2-c1nc(-c2ccccc2)nc(-c2ccc(-c3ccccc3)cc2)n1] | B-118 |
| 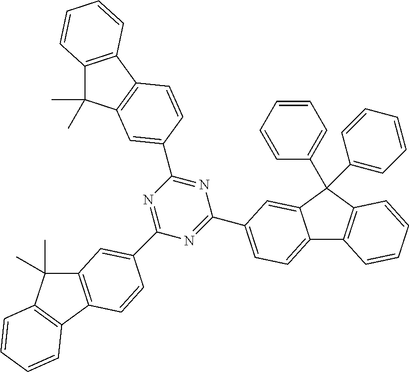 [SMILES: CC1(C)c2ccccc2-c2ccc(-c3nc(-c4ccc5c(c4)C(C)(C)c4ccccc4-5)nc(-c4ccc5c(c4)C(c4ccccc4)(c4ccccc4)c4ccccc4-5)n3)cc21] | B-119 |
| 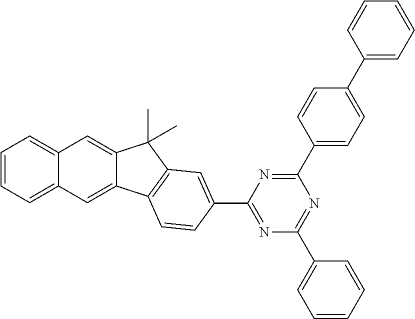 [SMILES: CC1(C)c2cc(-c3nc(-c4ccccc4)nc(-c4ccc(-c5ccccc5)cc4)n3)ccc2-c2cc3ccccc3cc21] | B-120 |
| 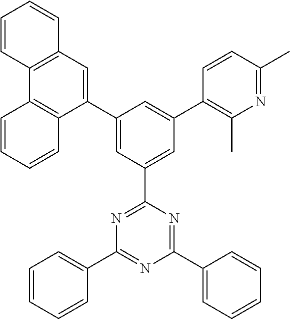 [SMILES: Cc1ccc(-c2cc(-c3nc(-c4ccccc4)nc(-c4ccccc4)n3)cc(-c3cc4ccccc4c4ccccc34)c2)c(C)n1] | B-121 |
| 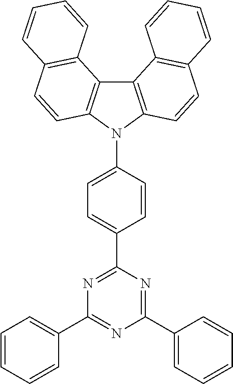 [SMILES: c1ccc(-c2nc(-c3ccccc3)nc(-c3ccc(-n4c5ccc6ccccc6c5c5c6ccccc6ccc54)cc3)n2)cc1] | B-122 |
| 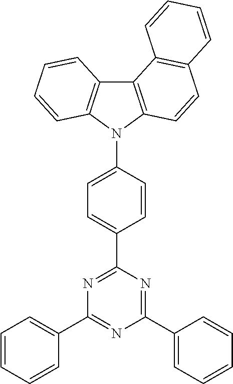 [SMILES: c1ccc(-c2nc(-c3ccccc3)nc(-c3ccc(-n4c5ccccc5c5c6ccccc6ccc54)cc3)n2)cc1] | B-123 |
| 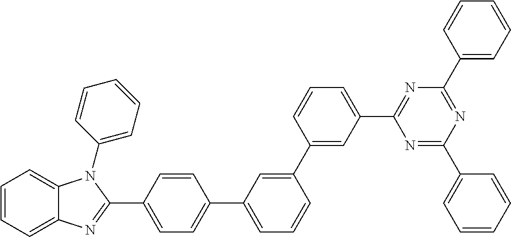 [SMILES: c1ccc(-c2nc(-c3ccccc3)nc(-c3cccc(-c4cccc(-c5ccc(-c6nc7ccccc7n6-c6ccccc6)cc5)c4)c3)n2)cc1] | B-124 |
| 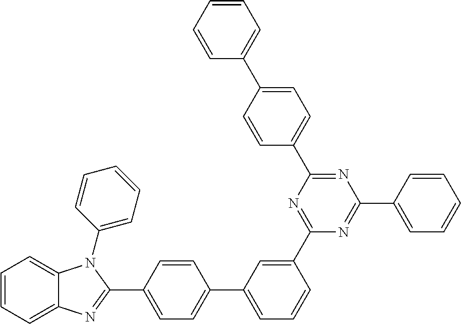 [SMILES: c1ccc(-c2ccc(-c3nc(-c4ccccc4)nc(-c4cccc(-c5ccc(-c6nc7ccccc7n6-c6ccccc6)cc5)c4)n3)cc2)cc1] | B-35 |
| 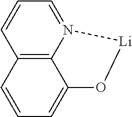 | EIL-1 |
| 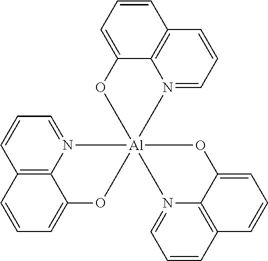 | Alq3 |

### REFERENCE NUMBERS

| | |
|---|---|
| 100: organic electroluminescent device | 101: substrate |
| 110: first electrode | 120: organic layer |
| 122: hole injection layer | 123: hole transport layer |
| 125: light-emitting layer | 126: electron buffer layer |
| 127: electron transport layer | 128: electron injection layer |
| 129: electron transport zone | 130: second electrode |

1. An organic electroluminescent device comprising a first electrode; a second electrode facing the first electrode; a light-emitting layer between the first electrode and the second electrode; and an electron transport zone between the light-emitting layer and the second electrode, wherein the light-emitting layer comprises a compound represented by the following formula 1, and the electron transport zone comprises a compound represented by the following formula 11: 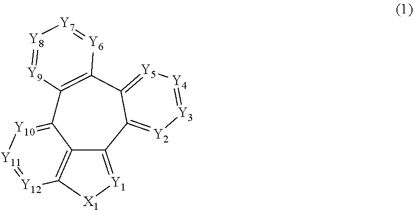
wherein
X₁ represents N-L-(Ar)ₐ, S, or O;
L represents a single bond, a substituted or unsubstituted (C6-C30)arylene, or a substituted or unsubstituted (3- to 30-membered)heteroarylene;
Ar represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino;
Y₁ to Y₁₂ each independently represent N or CR₁;
R, each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or are linked to an adjacent substituent(s) to form a substituted or unsubstituted ring; and
a represents an integer of 1 to 4, where if a is an integer of 2 or more, each of Ar may be the same or different; 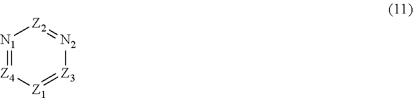
wherein
N₁ and N₂ each independently represent N or CR₁₈, where at least one of N₁ and N₂ represents N;
Z₁ to Z₄ each independently represent N or CR₁₉; and
R₁₈ and R₁₉ each independently represent hydrogen, deuterium, a halogen, a cyano, a substituted or unsubstituted (C1-C30)alkyl, a substituted or unsubstituted (C6-C50)aryl, a substituted or unsubstituted (3- to 50-membered)heteroaryl, a substituted or unsubstituted (C3-C30)cycloalkyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; or are linked to an adjacent substituent(s) to form a substituted or unsubstituted ring.

2. The organic electroluminescent device according to claim 1, wherein the substituents of the substituted alkyl, the substituted aryl(ene), the substituted heteroaryl(ene), the substituted cycloalkyl, the substituted heterocycloalkyl, the substituted alkoxy, the substituted trialkylsilyl, the substituted dialkylarylsilyl, the substituted alkyldiarylsilyl, the substituted triarylsilyl, the substituted mono- or di-alkylamino, the substituted mono- or di-arylamino, the substituted alkylarylamino, and the substituted ring in L, Ar, R₁, R₁₈, and R₁₉ each independently are at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (5- to 50-membered)heteroaryl unsubstituted or substituted with a (C1-C30)alkyl(s) or a (C6-C30)aryl(s); a (C6-C30)aryl unsubstituted or substituted with a (3- to 50-membered)heteroaryl; a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di-(C1-C30)alkylamino; a mono- or di-(C6-C30)arylamino; a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl.

3. The organic electroluminescent device according to claim 1, wherein Ar represents a substituted or unsubstituted phenyl, a substituted or unsubstituted naphthyl, a substituted or unsubstituted biphenyl, a substituted or unsubstituted terphenyl, a substituted or unsubstituted triazinyl, a substituted or unsubstituted pyridyl, a substituted or unsubstituted pyrimidinyl, a substituted or unsubstituted quinazolinyl, a substituted or unsubstituted benzoquinazolinyl, a substituted or unsubstituted quinoxalinyl, a substituted or unsubstituted benzoquinoxalinyl, a substituted or unsubstituted quinolyl, a substituted or unsubstituted benzoquinolyl, a substituted or unsubstituted isoquinolyl, a substituted or unsubstituted benzoisoquinolyl, a substituted or unsubstituted triazolyl, a substituted or unsubstituted pyrazolyl, a substituted or unsubstituted carbazolyl, a substituted or unsubstituted dibenzothiophenyl, a substituted or unsubstituted benzothiophenyl, a substituted or unsubstituted dibenzofuranyl, a substituted or unsubstituted benzofuranyl, a substituted or unsubstituted naphthyridinyl, a substituted or unsubstituted (9- to 25-membered)heteroaryl containing at least one of nitrogen, oxygen, and sulfur, a substituted or unsubstituted diphenylamino, a substituted or unsubstituted phenylbiphenylamino, or a substituted or unsubstituted fluorenylphenylamino.

4. The organic electroluminescent device according to claim 1, wherein at least one adjacent pair of Y₁ to Y₁₂ in formula 1 are CR₁, and the adjacent two R₁'s of CR, are fused together to each independently form a ring represented by any one of the following formulas 2 to 6: 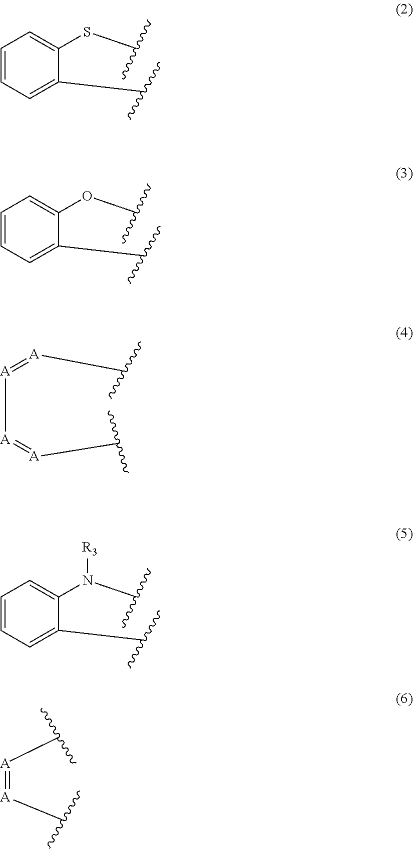
wherein
A represents N or CR₂;
R₂ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino;
R₃ represents hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C6-C30)arylamino, or a substituted or unsubstituted (C1-C30)alkyl(C6-C30)arylamino; and [symbol]
represents a fusing site of adjacent CR₁'s.

5. The organic electroluminescent device according to claim 1, wherein the compound represented by formula 1 is at least one selected from the group consisting of:

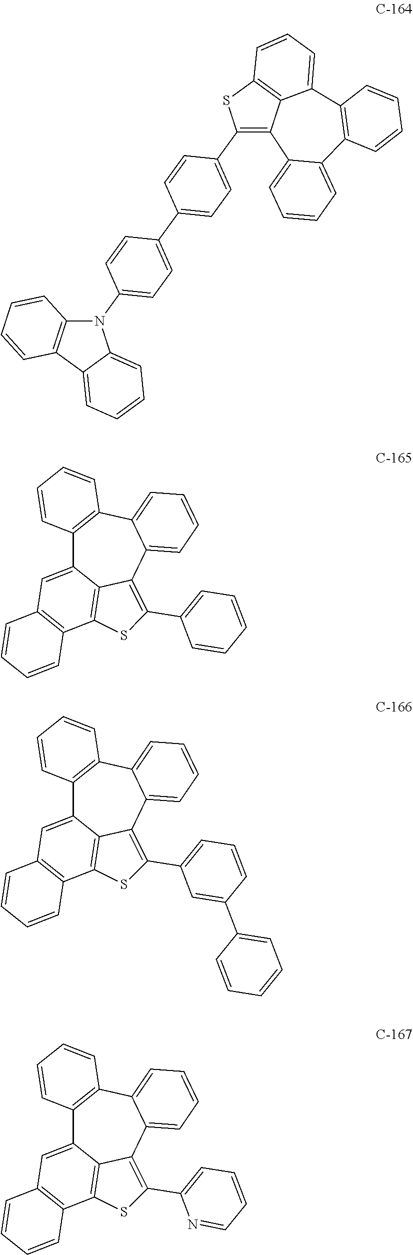 [SMILES: c1ccc2c(c1)-c1ccccc1-c1c(-c3ccc(-c4ccc(-n5c6ccccc6c6ccccc65)cc4)cc3)sc3cccc-2c13 ; c1ccc(-c2sc3c4c(cc5ccccc53)-c3ccccc3-c3ccccc3-c24)cc1 ; c1ccc(-c2cccc(-c3sc4c5c(cc6ccccc64)-c4ccccc4-c4ccccc4-c35)c2)cc1 ; c1ccc(-c2sc3c4c(cc5ccccc53)-c3ccccc3-c3ccccc3-c24)nc1]

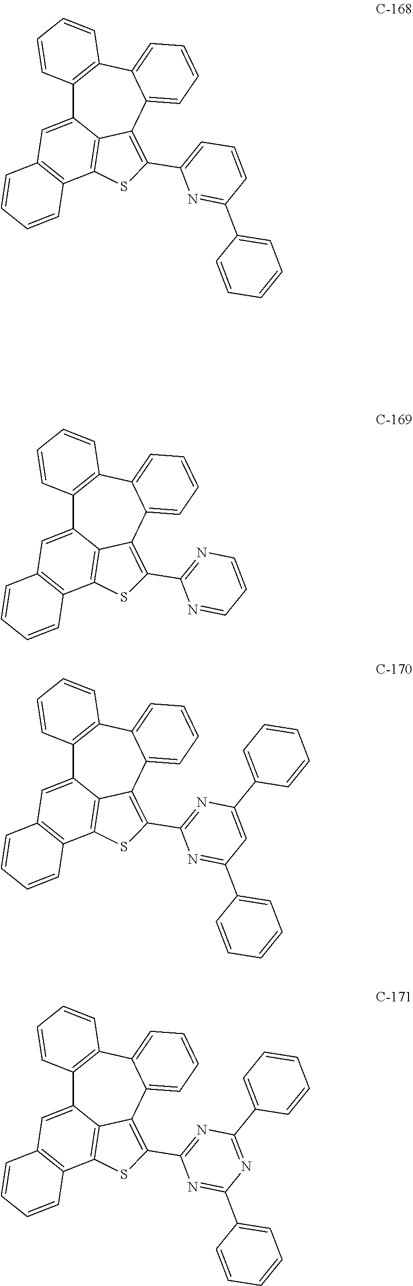 [SMILES: c1ccc(-c2cccc(-c3sc4c5c(cc6ccccc64)-c4ccccc4-c4ccccc4-c35)n2)cc1 ; c1cnc(-c2sc3c4c(cc5ccccc53)-c3ccccc3-c3ccccc3-c24)nc1 ; c1ccc(-c2cc(-c3ccccc3)nc(-c3sc4c5c(cc6ccccc64)-c4ccccc4-c4ccccc4-c35)n2)cc1 ; c1ccc(-c2nc(-c3ccccc3)nc(-c3sc4c5c(cc6ccccc64)-c4ccccc4-c4ccccc4-c35)n2)cc1]

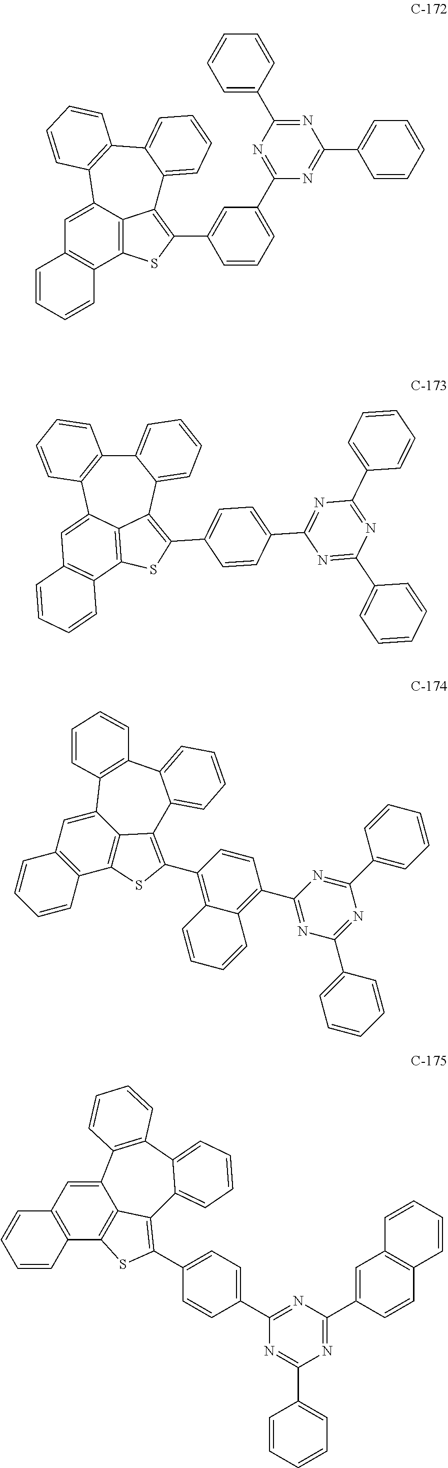 [SMILES: c1ccc(-c2nc(-c3ccccc3)nc(-c3cccc(-c4sc5c6c(cc7ccccc75)-c5ccccc5-c5ccccc5-c46)c3)n2)cc1 ; c1ccc(-c2nc(-c3ccccc3)nc(-c3ccc(-c4sc5c6c(cc7ccccc75)-c5ccccc5-c5ccccc5-c46)cc3)n2)cc1 ; c1ccc(-c2nc(-c3ccccc3)nc(-c3ccc(-c4sc5c6c(cc7ccccc75)-c5ccccc5-c5ccccc5-c46)c4ccccc34)n2)cc1 ; c1ccc(-c2nc(-c3ccc(-c4sc5c6c(cc7ccccc75)-c5ccccc5-c5ccccc5-c46)cc3)nc(-c3ccc4ccccc4c3)n2)cc1]

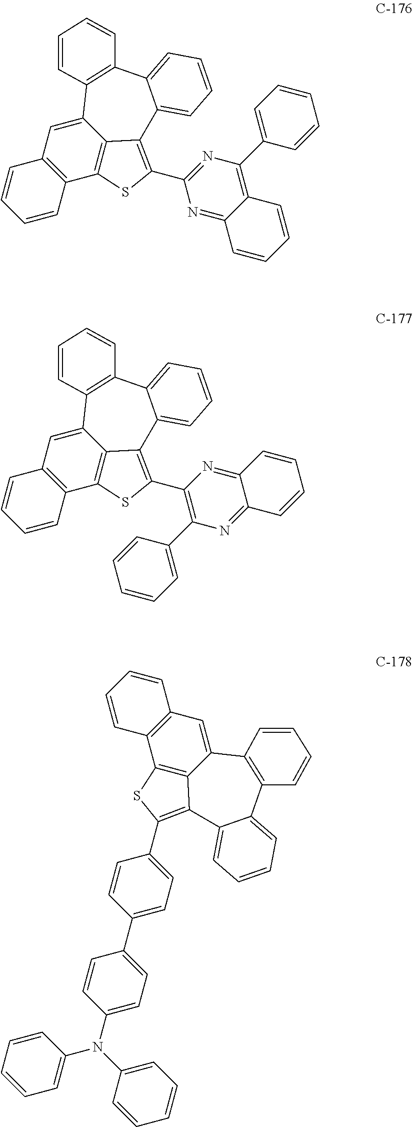 [SMILES: c1ccc(-c2nc(-c3sc4c5c(cc6ccccc64)-c4ccccc4-c4ccccc4-c35)nc3ccccc23)cc1 ; c1ccc(-c2nc3ccccc3nc2-c2sc3c4c(cc5ccccc53)-c3ccccc3-c3ccccc3-c24)cc1 ; c1ccc(N(c2ccccc2)c2ccc(-c3ccc(-c4sc5c6c(cc7ccccc75)-c5ccccc5-c5ccccc5-c46)cc3)cc2)cc1]

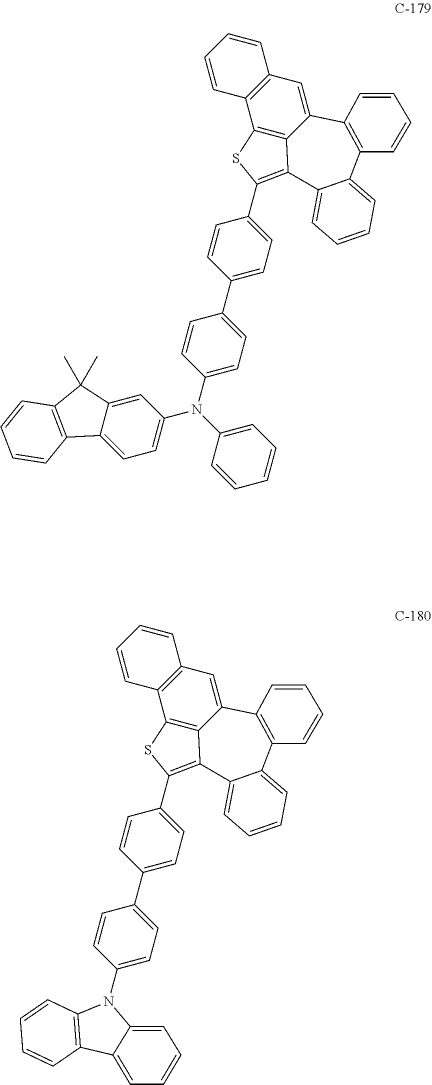 [SMILES: CC1(C)c2ccccc2-c2ccc(N(c3ccccc3)c3ccc(-c4ccc(-c5sc6c7c(cc8ccccc86)-c6ccccc6-c6ccccc6-c57)cc4)cc3)cc21 ; c1ccc2c(c1)-c1ccccc1-c1c(-c3ccc(-c4ccc(-n5c6ccccc6c6ccccc65)cc4)cc3)sc3c1c-2cc1ccccc13]

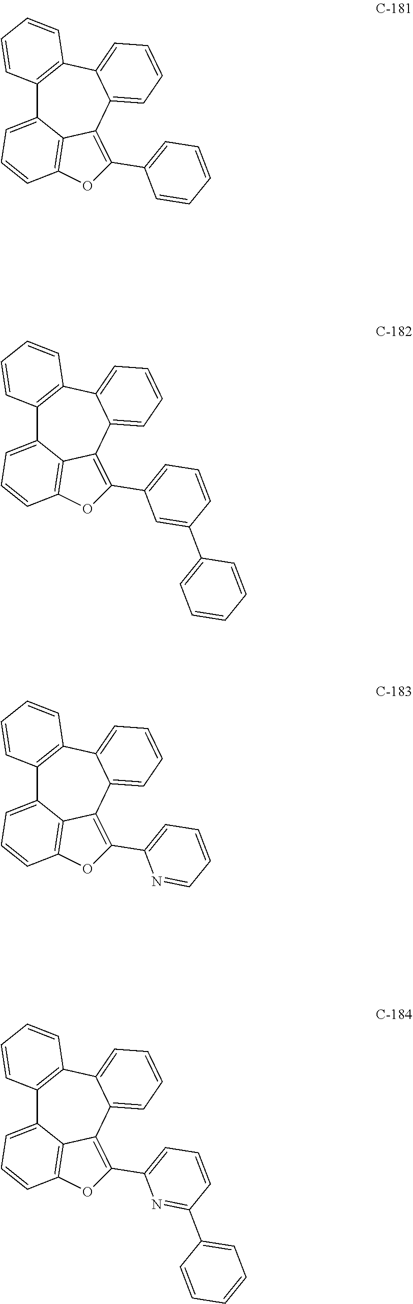 [SMILES: c1ccc(-c2oc3cccc4c3c2-c2ccccc2-c2ccccc2-4)cc1 ; c1ccc(-c2cccc(-c3oc4cccc5c4c3-c3ccccc3-c3ccccc3-5)c2)cc1 ; c1ccc(-c2oc3cccc4c3c2-c2ccccc2-c2ccccc2-4)nc1 ; c1ccc(-c2cccc(-c3oc4cccc5c4c3-c3ccccc3-c3ccccc3-5)n2)cc1]

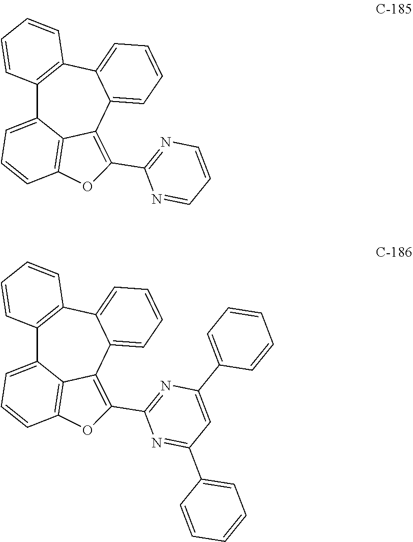 [SMILES: c1cnc(-c2oc3cccc4c3c2-c2ccccc2-c2ccccc2-4)nc1 ; c1ccc(-c2cc(-c3ccccc3)nc(-c3oc4cccc5c4c3-c3ccccc3-c3ccccc3-5)n2)cc1]

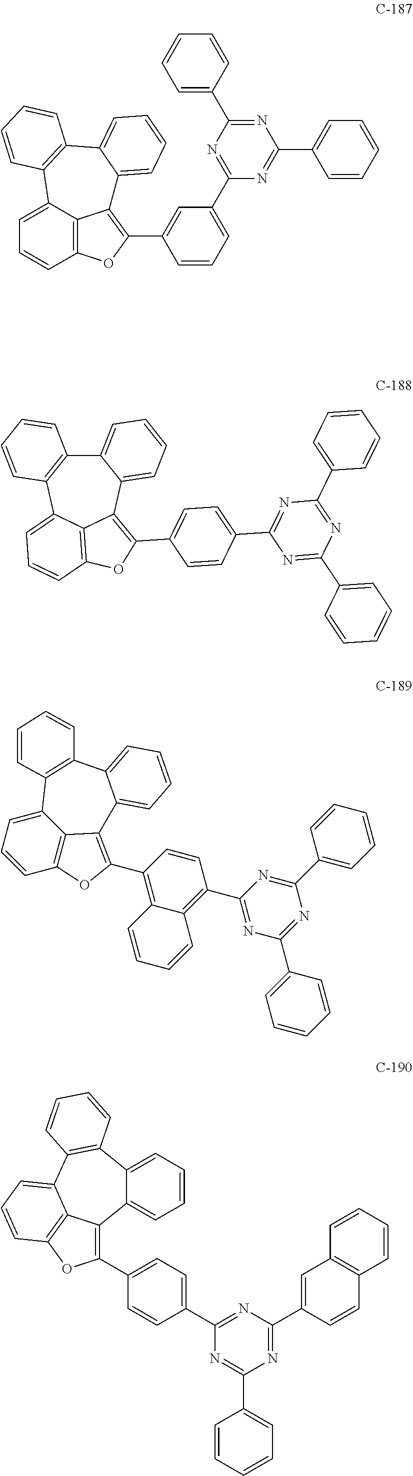 [SMILES: c1ccc(-c2nc(-c3ccccc3)nc(-c3cccc(-c4oc5cccc6c5c4-c4ccccc4-c4ccccc4-6)c3)n2)cc1 ; c1ccc(-c2nc(-c3ccccc3)nc(-c3ccc(-c4oc5cccc6c5c4-c4ccccc4-c4ccccc4-6)cc3)n2)cc1 ; c1ccc(-c2nc(-c3ccccc3)nc(-c3ccc(-c4oc5cccc6c5c4-c4ccccc4-c4ccccc4-6)c4ccccc34)n2)cc1 ; c1ccc(-c2nc(-c3ccc(-c4oc5cccc6c5c4-c4ccccc4-c4ccccc4-6)cc3)nc(-c3ccc4ccccc4c3)n2)cc1]

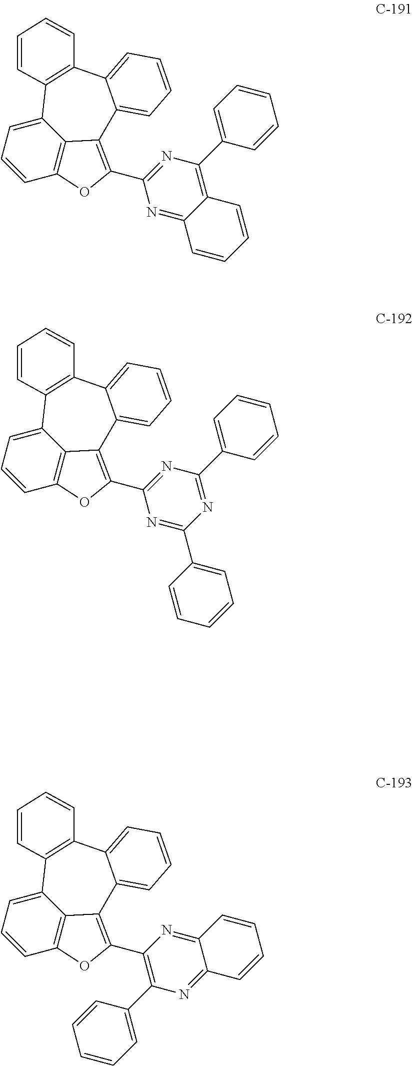 [SMILES: c1ccc(-c2nc(-c3oc4cccc5c4c3-c3ccccc3-c3ccccc3-5)nc3ccccc23)cc1 ; c1ccc(-c2nc(-c3ccccc3)nc(-c3oc4cccc5c4c3-c3ccccc3-c3ccccc3-5)n2)cc1 ; c1ccc(-c2nc3ccccc3nc2-c2oc3cccc4c3c2-c2ccccc2-c2ccccc2-4)cc1]

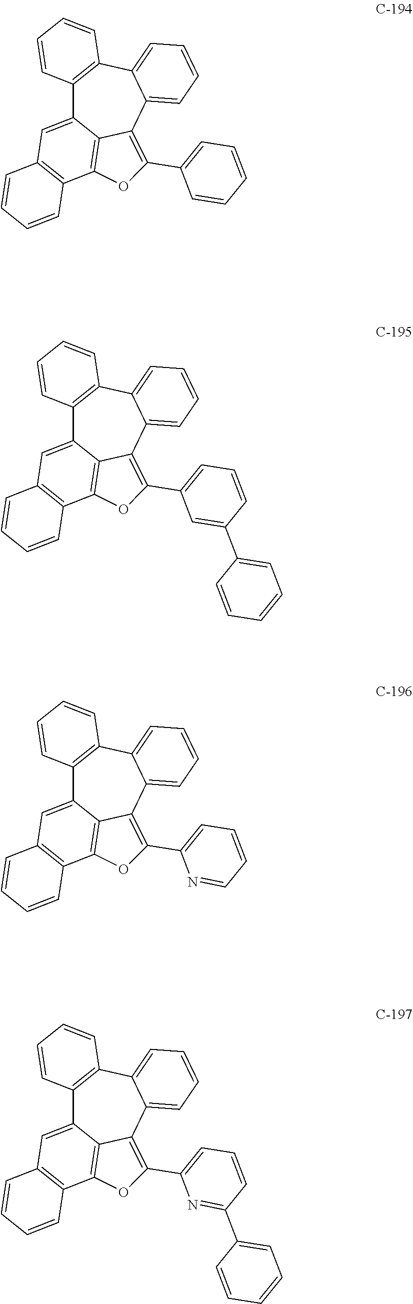 [SMILES: c1ccc(-c2oc3c4c(cc5ccccc53)-c3ccccc3-c3ccccc3-c24)cc1 ; c1ccc(-c2cccc(-c3oc4c5c(cc6ccccc64)-c4ccccc4-c4ccccc4-c35)c2)cc1 ; c1ccc(-c2oc3c4c(cc5ccccc53)-c3ccccc3-c3ccccc3-c24)nc1 ; c1ccc(-c2cccc(-c3oc4c5c(cc6ccccc64)-c4ccccc4-c4ccccc4-c35)n2)cc1]

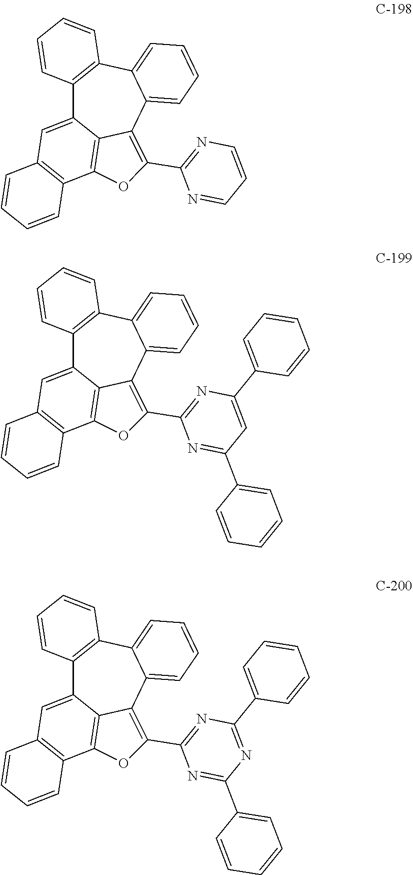 [SMILES: c1cnc(-c2oc3c4c(cc5ccccc53)-c3ccccc3-c3ccccc3-c24)nc1 ; c1ccc(-c2cc(-c3ccccc3)nc(-c3oc4c5c(cc6ccccc64)-c4ccccc4-c4ccccc4-c35)n2)cc1 ; c1ccc(-c2nc(-c3ccccc3)nc(-c3oc4c5c(cc6ccccc64)-c4ccccc4-c4ccccc4-c35)n2)cc1]

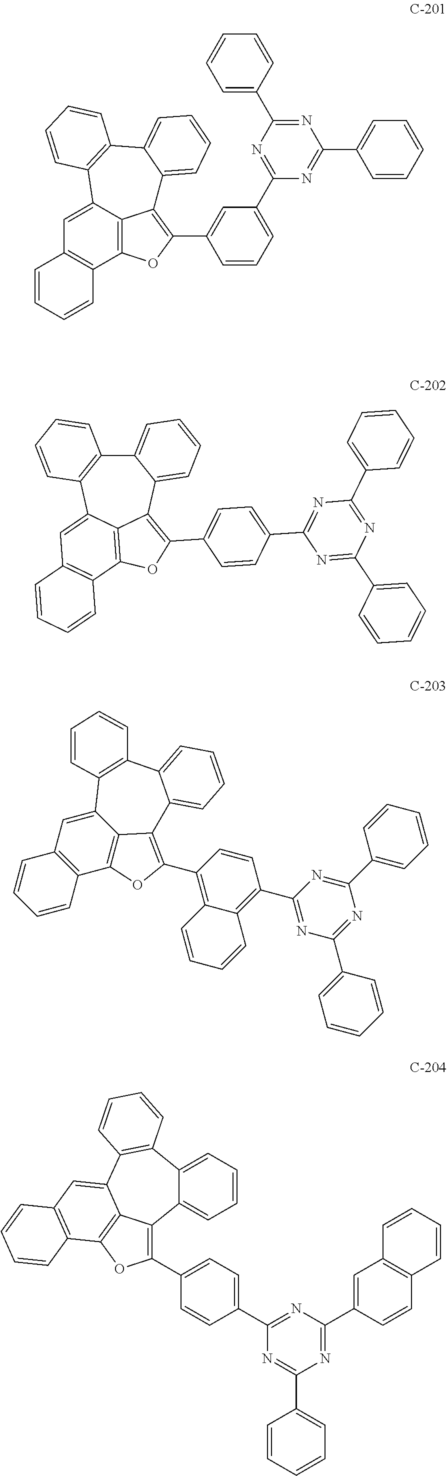 [SMILES: c1ccc(-c2nc(-c3ccccc3)nc(-c3cccc(-c4oc5c6c(cc7ccccc75)-c5ccccc5-c5ccccc5-c46)c3)n2)cc1 ; c1ccc(-c2nc(-c3ccccc3)nc(-c3ccc(-c4oc5c6c(cc7ccccc75)-c5ccccc5-c5ccccc5-c46)cc3)n2)cc1 ; c1ccc(-c2nc(-c3ccccc3)nc(-c3ccc(-c4oc5c6c(cc7ccccc75)-c5ccccc5-c5ccccc5-c46)c4ccccc34)n2)cc1 ; c1ccc(-c2nc(-c3ccc(-c4oc5c6c(cc7ccccc75)-c5ccccc5-c5ccccc5-c46)cc3)nc(-c3ccc4ccccc4c3)n2)cc1]

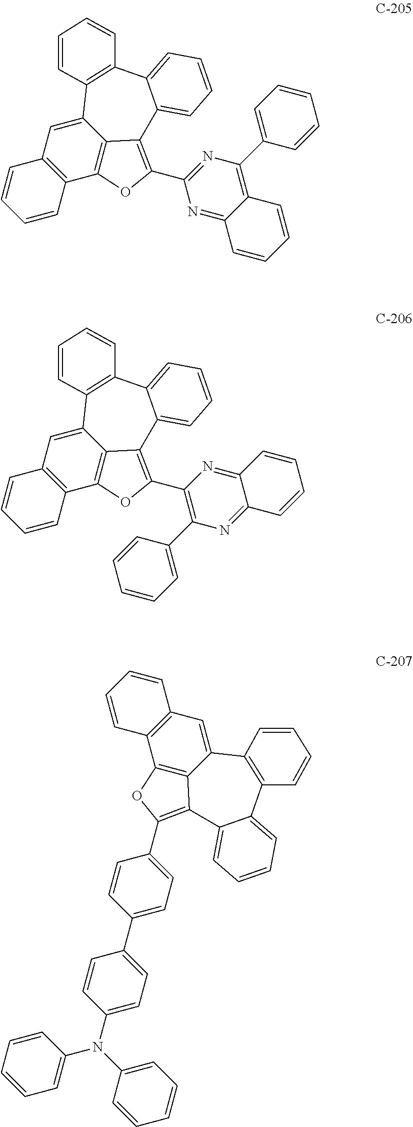 [SMILES: c1ccc(-c2nc(-c3oc4c5c(cc6ccccc64)-c4ccccc4-c4ccccc4-c35)nc3ccccc23)cc1 ; c1ccc(-c2nc3ccccc3nc2-c2oc3c4c(cc5ccccc53)-c3ccccc3-c3ccccc3-c24)cc1 ; c1ccc(N(c2ccccc2)c2ccc(-c3ccc(-c4oc5c6c(cc7ccccc75)-c5ccccc5-c5ccccc5-c46)cc3)cc2)cc1]

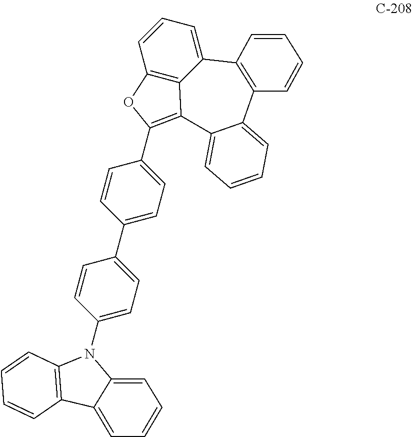 [SMILES: c1ccc2c(c1)-c1ccccc1-c1c(-c3ccc(-c4ccc(-n5c6ccccc6c6ccccc65)cc4)cc3)oc3cccc-2c13]

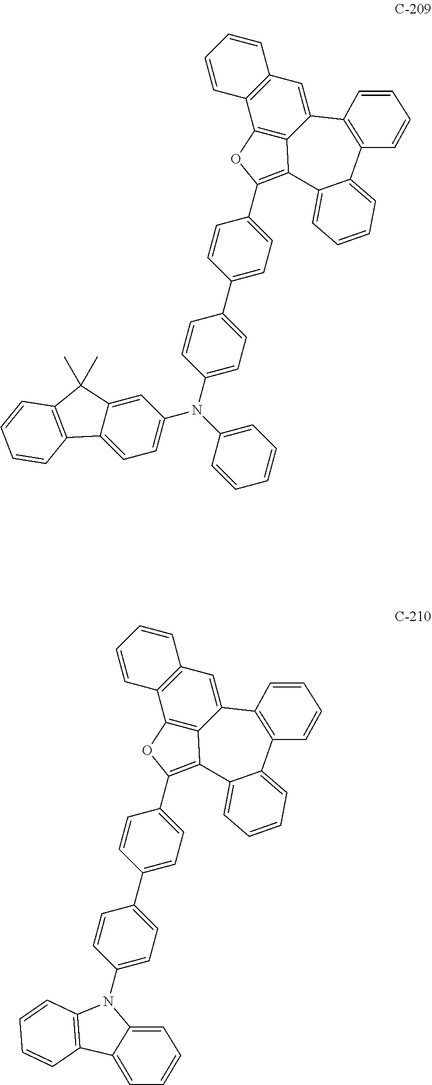 [SMILES: CC1(C)c2ccccc2-c2ccc(N(c3ccccc3)c3ccc(-c4ccc(-c5oc6c7c(cc8ccccc86)-c6ccccc6-c6ccccc6-c57)cc4)cc3)cc21 ; c1ccc2c(c1)-c1ccccc1-c1c(-c3ccc(-c4ccc(-n5c6ccccc6c6ccccc65)cc4)cc3)oc3c1c-2cc1ccccc13]

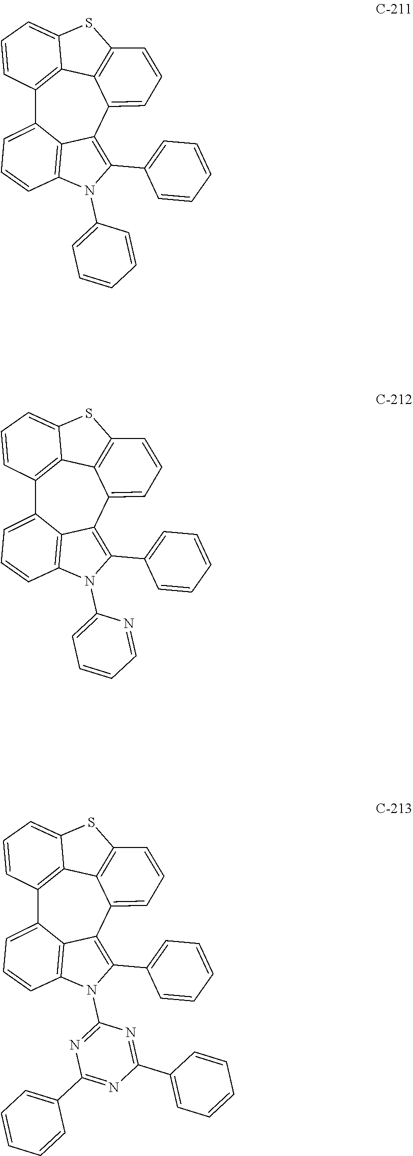 [SMILES: c1ccc(-c2c3c4c(cccc4n2-c2ccccc2)-c2cccc4sc5cccc-3c5c24)cc1 ; c1ccc(-c2c3c4c(cccc4n2-c2ccccn2)-c2cccc4sc5cccc-3c5c24)cc1 ; c1ccc(-c2nc(-c3ccccc3)nc(-n3c(-c4ccccc4)c4c5c(cccc53)-c3cccc5sc6cccc-4c6c35)n2)cc1]

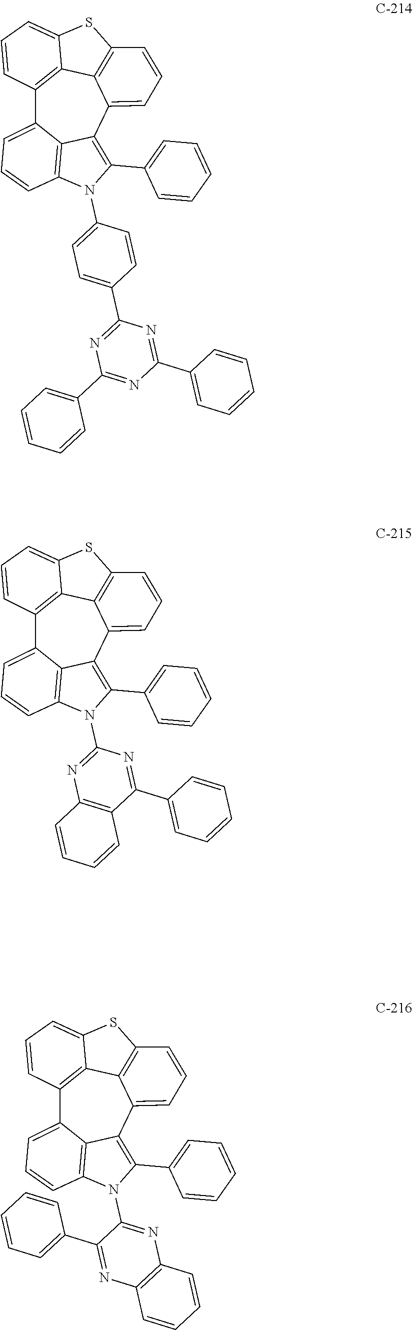 [SMILES: c1ccc(-c2nc(-c3ccccc3)nc(-c3ccc(-n4c(-c5ccccc5)c5c6c(cccc64)-c4cccc6sc7cccc-5c7c46)cc3)n2)cc1 ; c1ccc(-c2nc(-n3c(-c4ccccc4)c4c5c(cccc53)-c3cccc5sc6cccc-4c6c35)nc3ccccc23)cc1 ; c1ccc(-c2nc3ccccc3nc2-n2c(-c3ccccc3)c3c4c(cccc42)-c2cccc4sc5cccc-3c5c24)cc1]

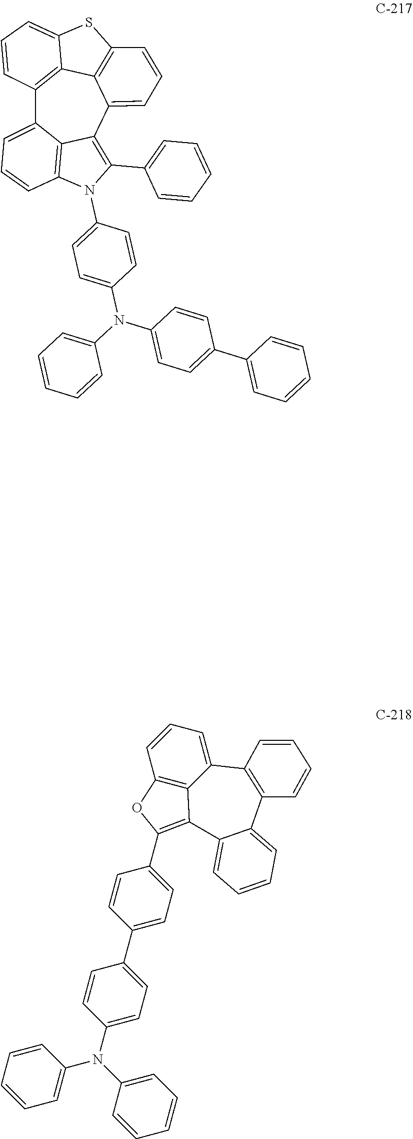 [SMILES: c1ccc(-c2ccc(N(c3ccccc3)c3ccc(-n4c(-c5ccccc5)c5c6c(cccc64)-c4cccc6sc7cccc-5c7c46)cc3)cc2)cc1 ; c1ccc(N(c2ccccc2)c2ccc(-c3ccc(-c4oc5cccc6c5c4-c4ccccc4-c4ccccc4-6)cc3)cc2)cc1]

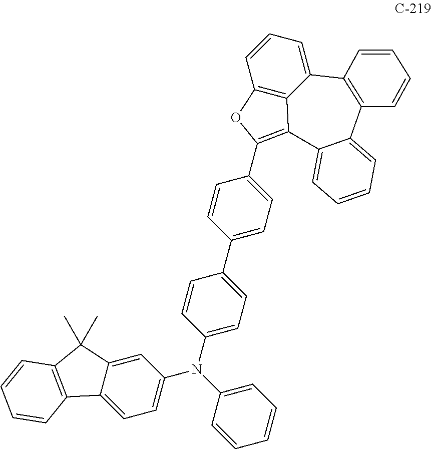 [SMILES: CC1(C)c2ccccc2-c2ccc(N(c3ccccc3)c3ccc(-c4ccc(-c5oc6cccc7c6c5-c5ccccc5-c5ccccc5-7)cc4)cc3)cc21]

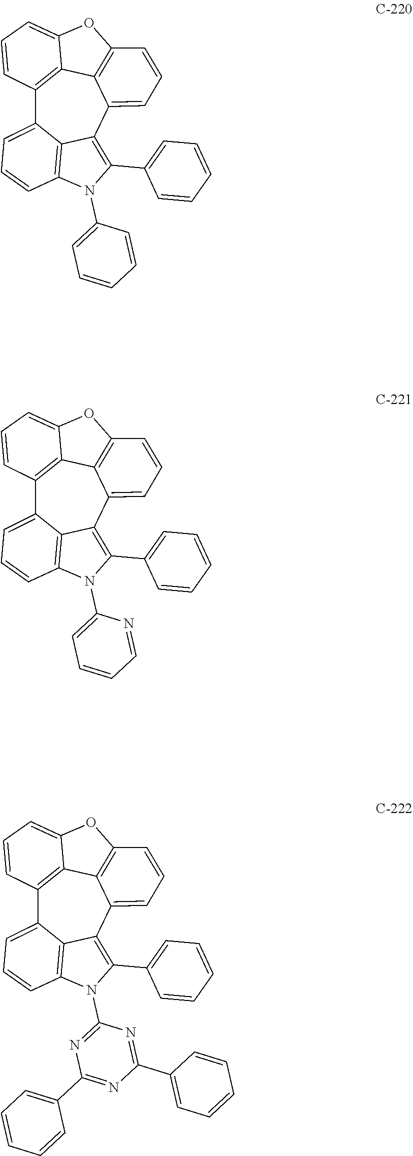 [SMILES: c1ccc(-c2c3c4c(cccc4n2-c2ccccc2)-c2cccc4oc5cccc-3c5c24)cc1 ; c1ccc(-c2c3c4c(cccc4n2-c2ccccn2)-c2cccc4oc5cccc-3c5c24)cc1 ; c1ccc(-c2nc(-c3ccccc3)nc(-n3c(-c4ccccc4)c4c5c(cccc53)-c3cccc5oc6cccc-4c6c35)n2)cc1]

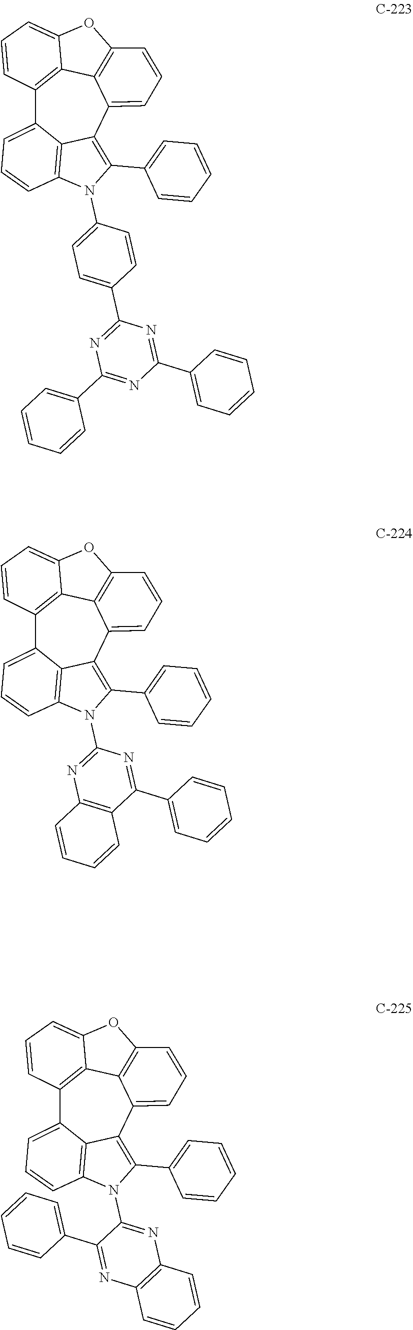 [SMILES: c1ccc(-c2nc(-c3ccccc3)nc(-c3ccc(-n4c(-c5ccccc5)c5c6c(cccc64)-c4cccc6oc7cccc-5c7c46)cc3)n2)cc1 ; c1ccc(-c2nc(-n3c(-c4ccccc4)c4c5c(cccc53)-c3cccc5oc6cccc-4c6c35)nc3ccccc23)cc1 ; c1ccc(-c2nc3ccccc3nc2-n2c(-c3ccccc3)c3c4c(cccc42)-c2cccc4oc5cccc-3c5c24)cc1]

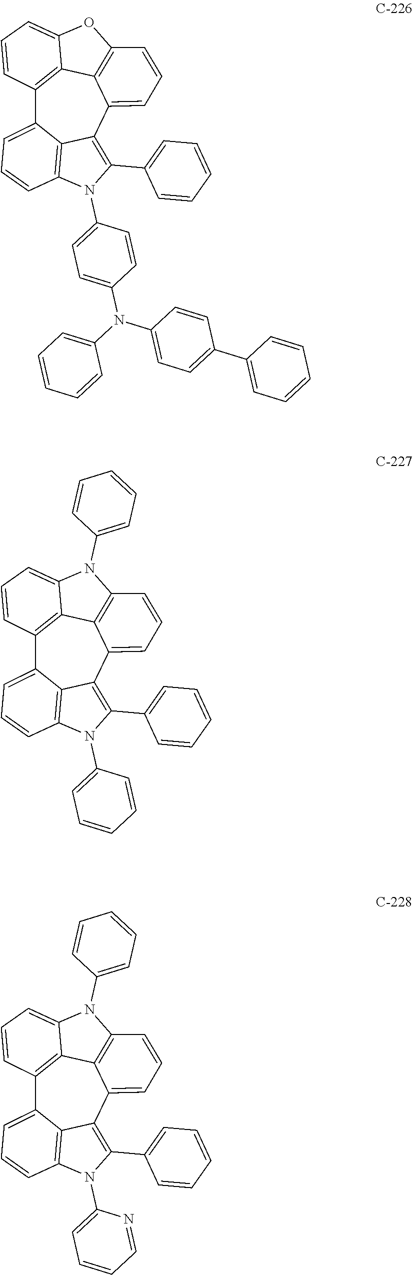 [SMILES: c1ccc(-c2ccc(N(c3ccccc3)c3ccc(-n4c(-c5ccccc5)c5c6c(cccc64)-c4cccc6oc7cccc-5c7c46)cc3)cc2)cc1 ; c1ccc(-c2c3c4c(cccc4n2-c2ccccc2)-c2cccc4c2c2c-3cccc2n4-c2ccccc2)cc1 ; c1ccc(-c2c3c4c(cccc4n2-c2ccccn2)-c2cccc4c2c2c-3cccc2n4-c2ccccc2)cc1]

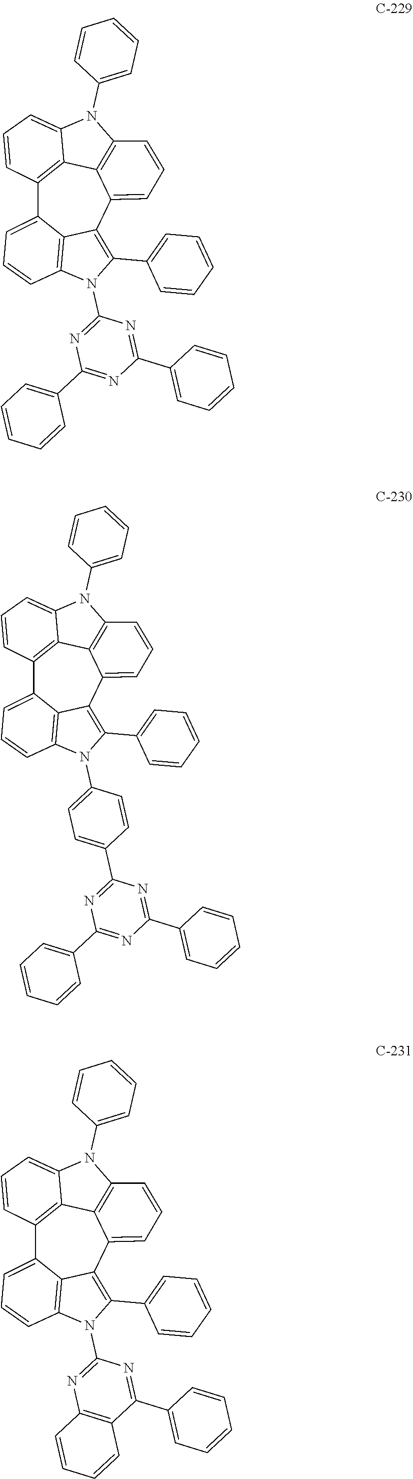 [SMILES: c1ccc(-c2nc(-c3ccccc3)nc(-n3c(-c4ccccc4)c4c5c(cccc53)-c3cccc5c3c3c-4cccc3n5-c3ccccc3)n2)cc1 ; c1ccc(-c2nc(-c3ccccc3)nc(-c3ccc(-n4c(-c5ccccc5)c5c6c(cccc64)-c4cccc6c4c4c-5cccc4n6-c4ccccc4)cc3)n2)cc1 ; c1ccc(-c2nc(-n3c(-c4ccccc4)c4c5c(cccc53)-c3cccc5c3c3c-4cccc3n5-c3ccccc3)nc3ccccc23)cc1]

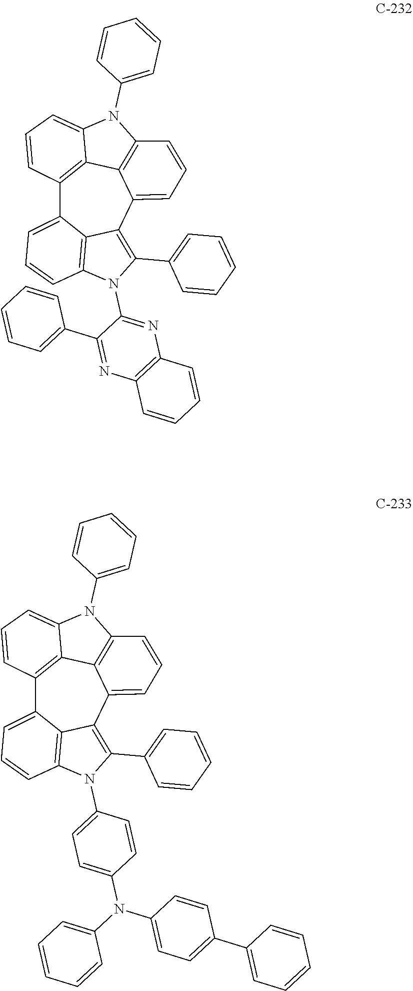 [SMILES: c1ccc(-c2nc3ccccc3nc2-n2c(-c3ccccc3)c3c4c(cccc42)-c2cccc4c2c2c-3cccc2n4-c2ccccc2)cc1 ; c1ccc(-c2ccc(N(c3ccccc3)c3ccc(-n4c(-c5ccccc5)c5c6c(cccc64)-c4cccc6c4c4c-5cccc4n6-c4ccccc4)cc3)cc2)cc1]

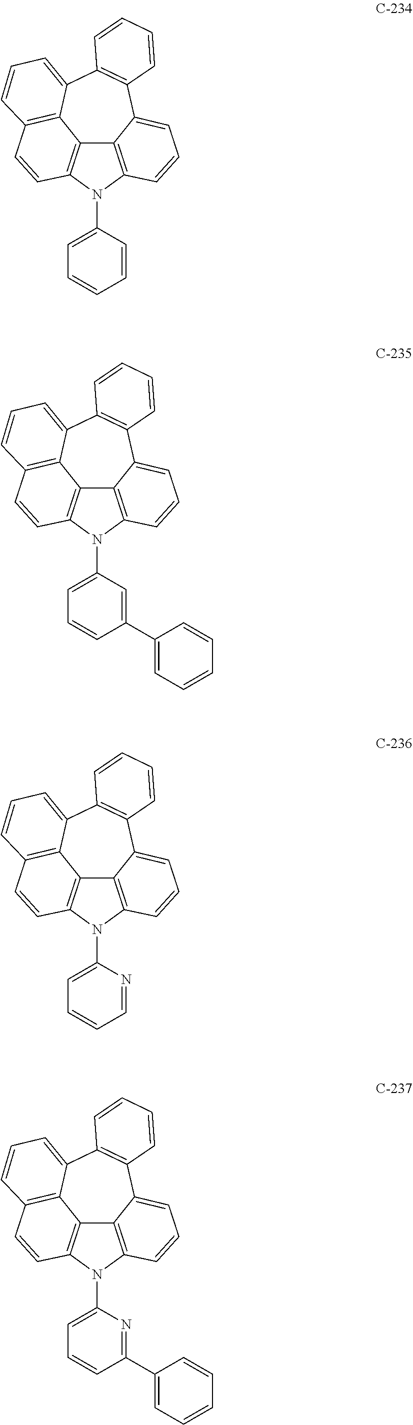 [SMILES: c1ccc(-n2c3cccc4c3c3c5c(cccc5ccc32)-c2ccccc2-4)cc1 ; c1ccc(-c2cccc(-n3c4cccc5c4c4c6c(cccc6ccc43)-c3ccccc3-5)c2)cc1 ; c1ccc(-n2c3cccc4c3c3c5c(cccc5ccc32)-c2ccccc2-4)nc1 ; c1ccc(-c2cccc(-n3c4cccc5c4c4c6c(cccc6ccc43)-c3ccccc3-5)n2)cc1]

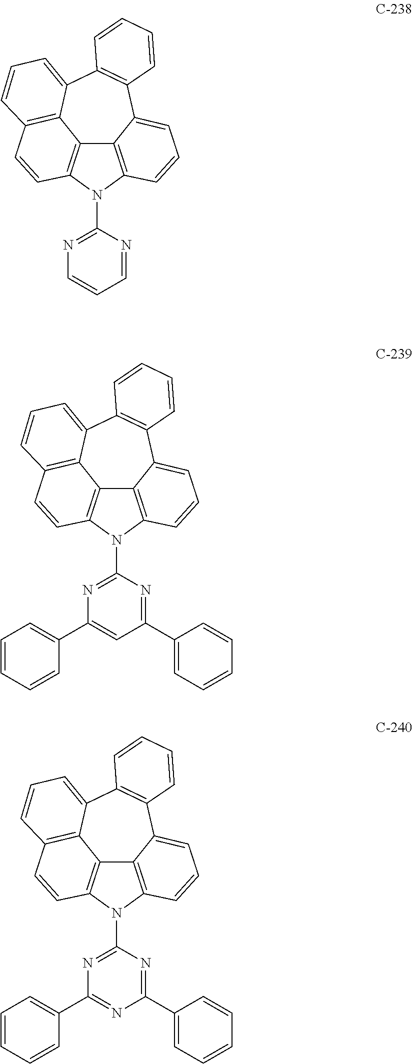 [SMILES: c1cnc(-n2c3cccc4c3c3c5c(cccc5ccc32)-c2ccccc2-4)nc1 ; c1ccc(-c2cc(-c3ccccc3)nc(-n3c4cccc5c4c4c6c(cccc6ccc43)-c3ccccc3-5)n2)cc1 ; c1ccc(-c2nc(-c3ccccc3)nc(-n3c4cccc5c4c4c6c(cccc6ccc43)-c3ccccc3-5)n2)cc1]

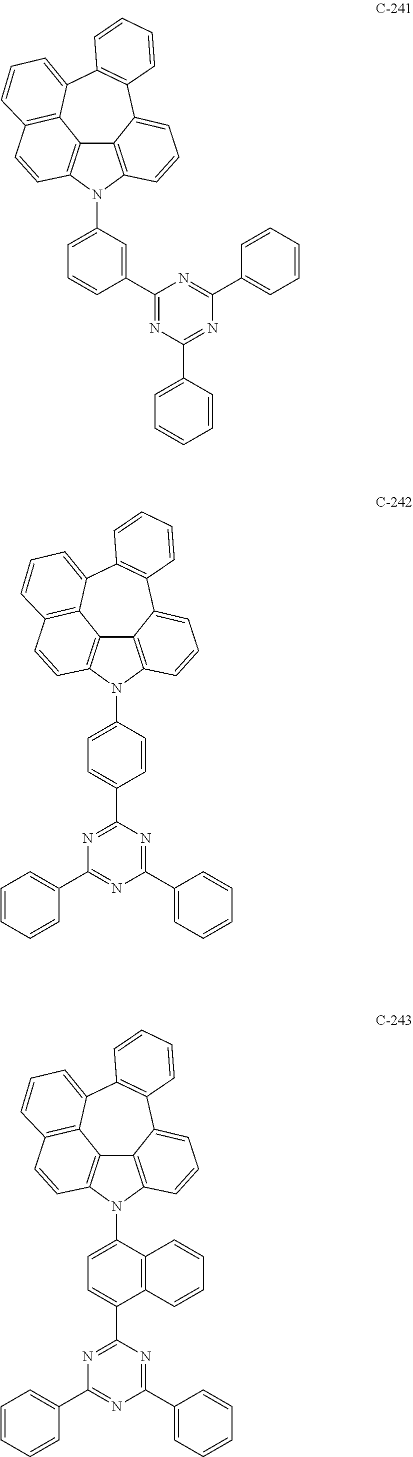 [SMILES: c1ccc(-c2nc(-c3ccccc3)nc(-c3cccc(-n4c5cccc6c5c5c7c(cccc7ccc54)-c4ccccc4-6)c3)n2)cc1 ; c1ccc(-c2nc(-c3ccccc3)nc(-c3ccc(-n4c5cccc6c5c5c7c(cccc7ccc54)-c4ccccc4-6)cc3)n2)cc1 ; c1ccc(-c2nc(-c3ccccc3)nc(-c3ccc(-n4c5cccc6c5c5c7c(cccc7ccc54)-c4ccccc4-6)c4ccccc34)n2)cc1]

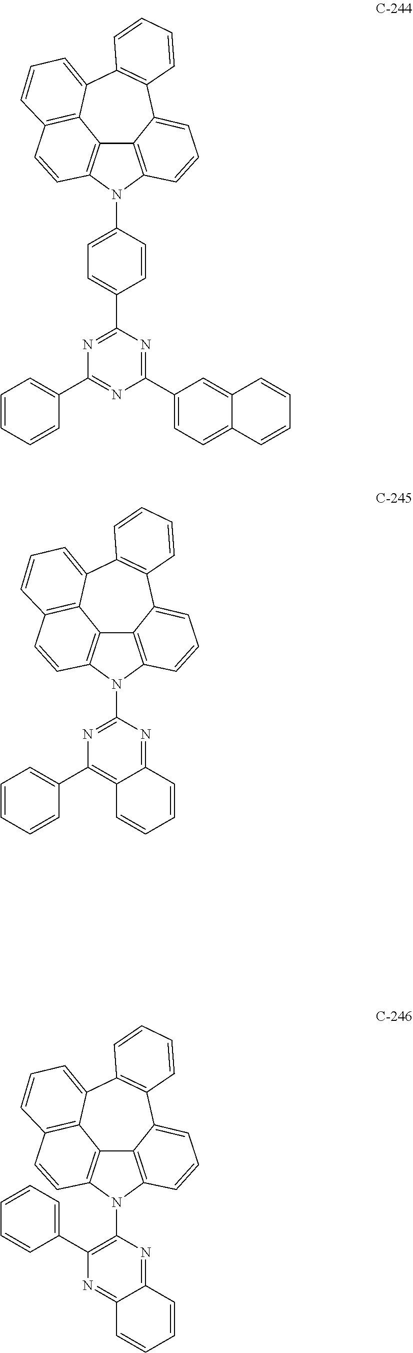 [SMILES: c1ccc(-c2nc(-c3ccc(-n4c5cccc6c5c5c7c(cccc7ccc54)-c4ccccc4-6)cc3)nc(-c3ccc4ccccc4c3)n2)cc1 ; c1ccc(-c2nc(-n3c4cccc5c4c4c6c(cccc6ccc43)-c3ccccc3-5)nc3ccccc23)cc1 ; c1ccc(-c2nc3ccccc3nc2-n2c3cccc4c3c3c5c(cccc5ccc32)-c2ccccc2-4)cc1]

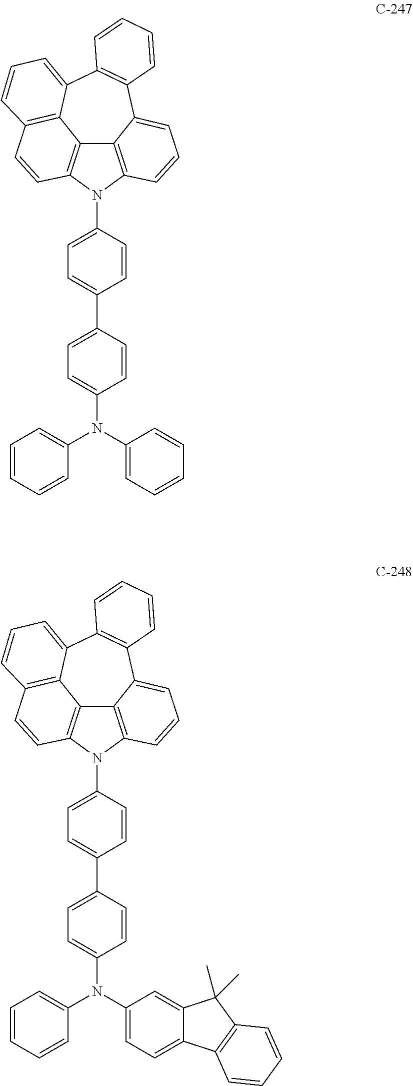 [SMILES: c1ccc(N(c2ccccc2)c2ccc(-c3ccc(-n4c5cccc6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cccc7c6c6c8c(cccc8ccc65)-c5ccccc5-7)cc4)cc3)cc21]

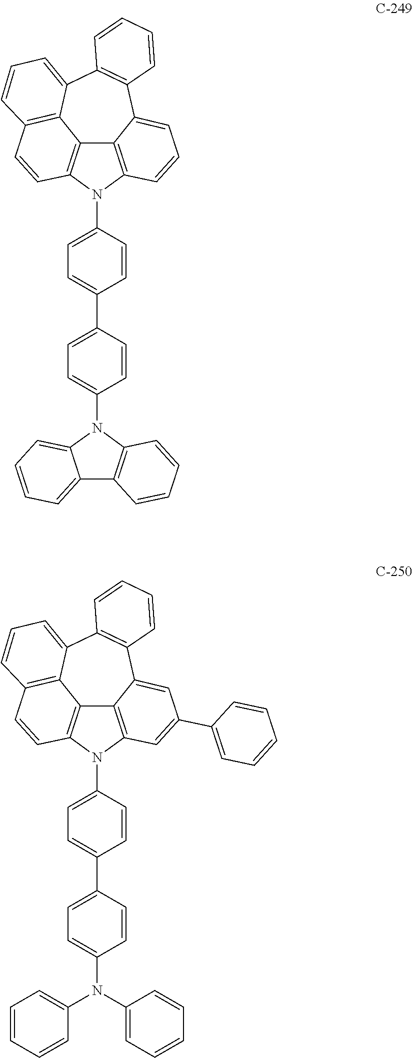 [SMILES: c1ccc2c(c1)-c1cccc3ccc4c(c13)c1c-2cccc1n4-c1ccc(-c2ccc(-n3c4ccccc4c4ccccc43)cc2)cc1 ; c1ccc(-c2cc3c4c5c6c(cccc6ccc5n(-c5ccc(-c6ccc(N(c7ccccc7)c7ccccc7)cc6)cc5)c4c2)-c2ccccc2-3)cc1]

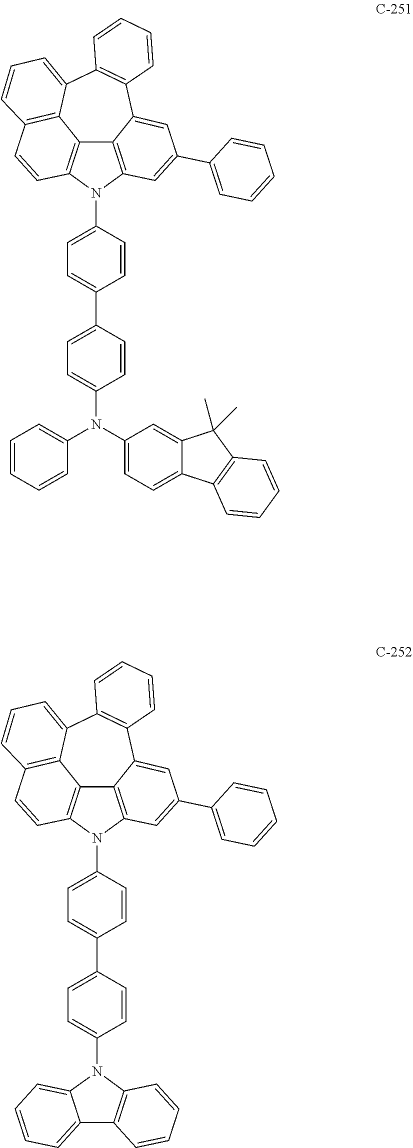 [SMILES: CC1(C)c2ccccc2-c2ccc(N(c3ccccc3)c3ccc(-c4ccc(-n5c6cc(-c7ccccc7)cc7c6c6c8c(cccc8ccc65)-c5ccccc5-7)cc4)cc3)cc21 ; c1ccc(-c2cc3c4c5c6c(cccc6ccc5n(-c5ccc(-c6ccc(-n7c8ccccc8c8ccccc87)cc6)cc5)c4c2)-c2ccccc2-3)cc1]

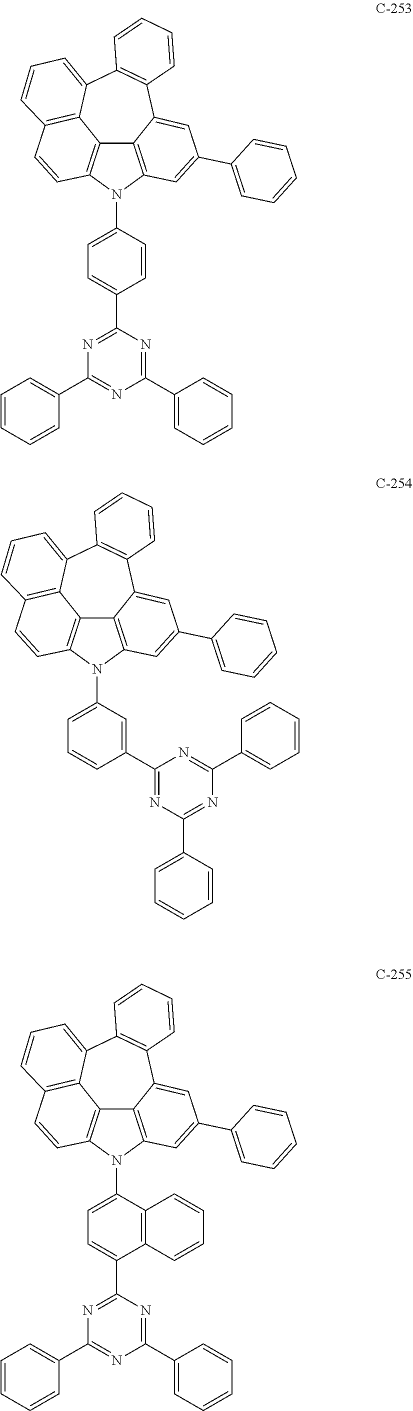 [SMILES: c1ccc(-c2cc3c4c5c6c(cccc6ccc5n(-c5ccc(-c6nc(-c7ccccc7)nc(-c7ccccc7)n6)cc5)c4c2)-c2ccccc2-3)cc1 ; c1ccc(-c2cc3c4c5c6c(cccc6ccc5n(-c5cccc(-c6nc(-c7ccccc7)nc(-c7ccccc7)n6)c5)c4c2)-c2ccccc2-3)cc1 ; c1ccc(-c2cc3c4c5c6c(cccc6ccc5n(-c5ccc(-c6nc(-c7ccccc7)nc(-c7ccccc7)n6)c6ccccc56)c4c2)-c2ccccc2-3)cc1]

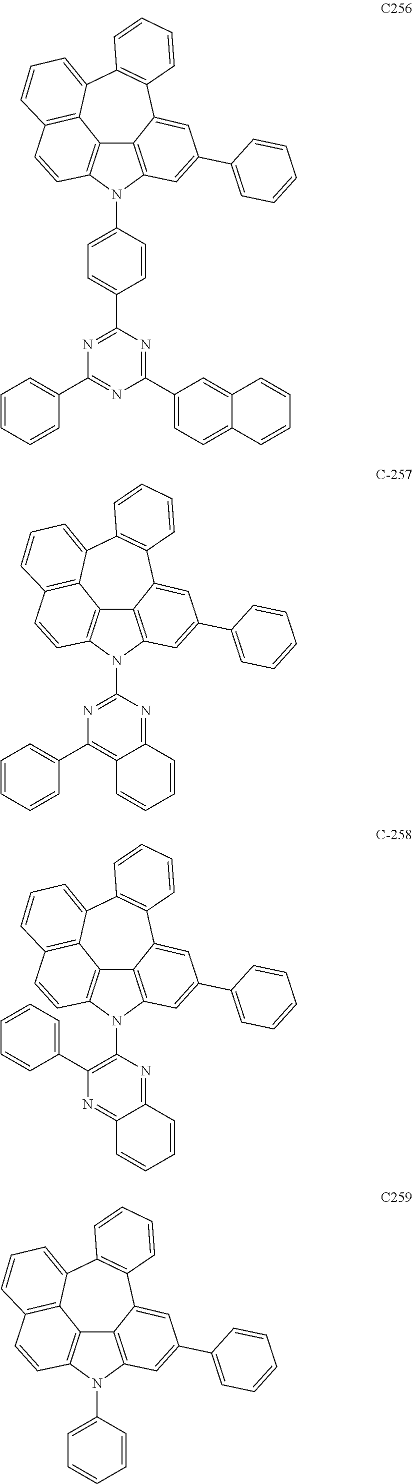

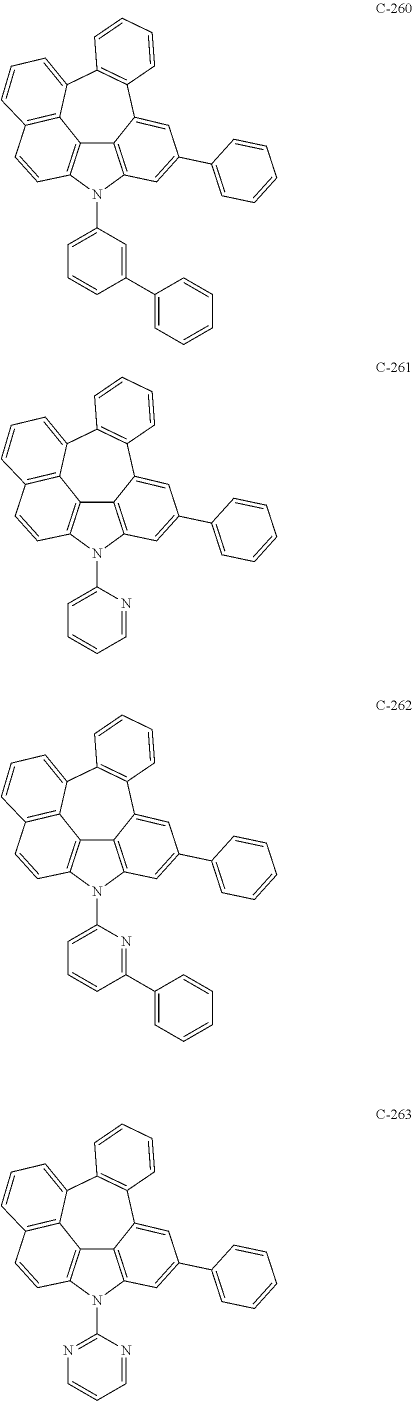 [SMILES: c1ccc(-c2cccc(-n3c4cc(-c5ccccc5)cc5c4c4c6c(cccc6ccc43)-c3ccccc3-5)c2)cc1 ; c1ccc(-c2cc3c4c5c6c(cccc6ccc5n(-c5ccccn5)c4c2)-c2ccccc2-3)cc1 ; c1ccc(-c2cc3c4c5c6c(cccc6ccc5n(-c5cccc(-c6ccccc6)n5)c4c2)-c2ccccc2-3)cc1 ; c1ccc(-c2cc3c4c5c6c(cccc6ccc5n(-c5ncccn5)c4c2)-c2ccccc2-3)cc1]

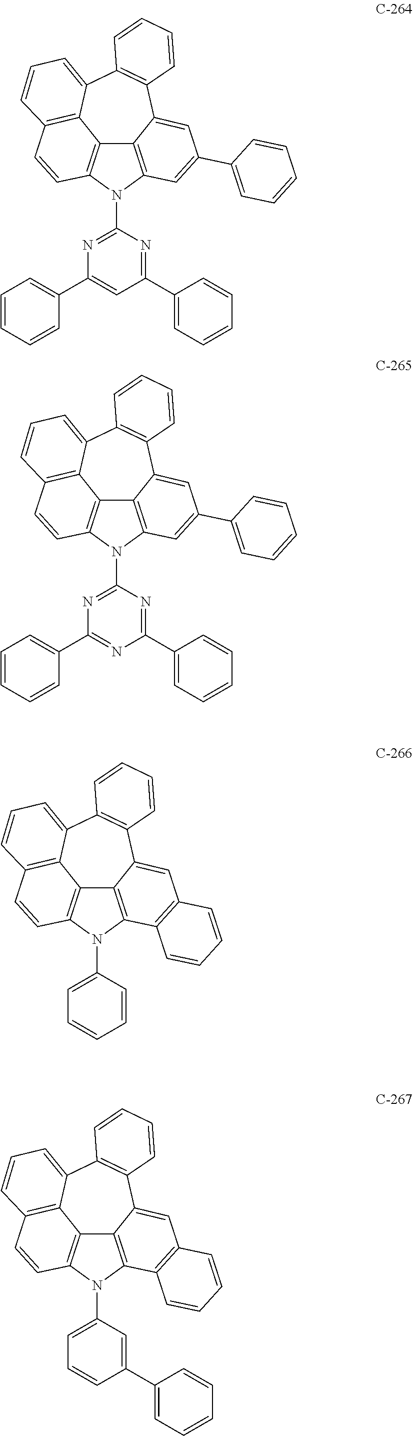 [SMILES: c1ccc(-c2cc3c4c5c6c(cccc6ccc5n(-c5nc(-c6ccccc6)cc(-c6ccccc6)n5)c4c2)-c2ccccc2-3)cc1 ; c1ccc(-c2cc3c4c5c6c(cccc6ccc5n(-c5nc(-c6ccccc6)nc(-c6ccccc6)n5)c4c2)-c2ccccc2-3)cc1 ; c1ccc(-n2c3ccc4cccc5c4c3c3c(cc4ccccc4c32)-c2ccccc2-5)cc1 ; c1ccc(-c2cccc(-n3c4ccc5cccc6c5c4c4c(cc5ccccc5c43)-c3ccccc3-6)c2)cc1]

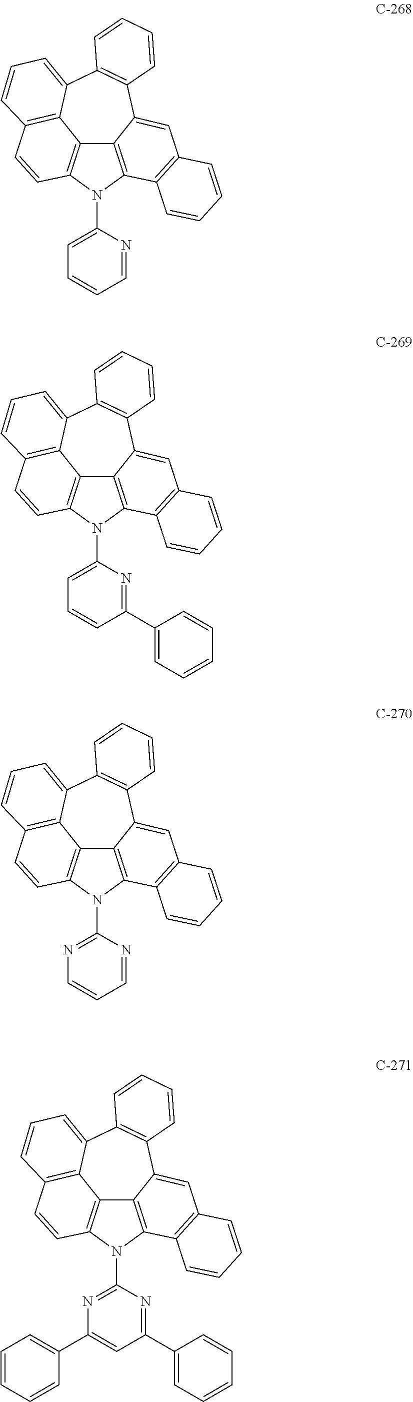 [SMILES: c1ccc(-n2c3ccc4cccc5c4c3c3c(cc4ccccc4c32)-c2ccccc2-5)nc1 ; c1ccc(-c2cccc(-n3c4ccc5cccc6c5c4c4c(cc5ccccc5c43)-c3ccccc3-6)n2)cc1 ; c1cnc(-n2c3ccc4cccc5c4c3c3c(cc4ccccc4c32)-c2ccccc2-5)nc1 ; c1ccc(-c2cc(-c3ccccc3)nc(-n3c4ccc5cccc6c5c4c4c(cc5ccccc5c43)-c3ccccc3-6)n2)cc1]

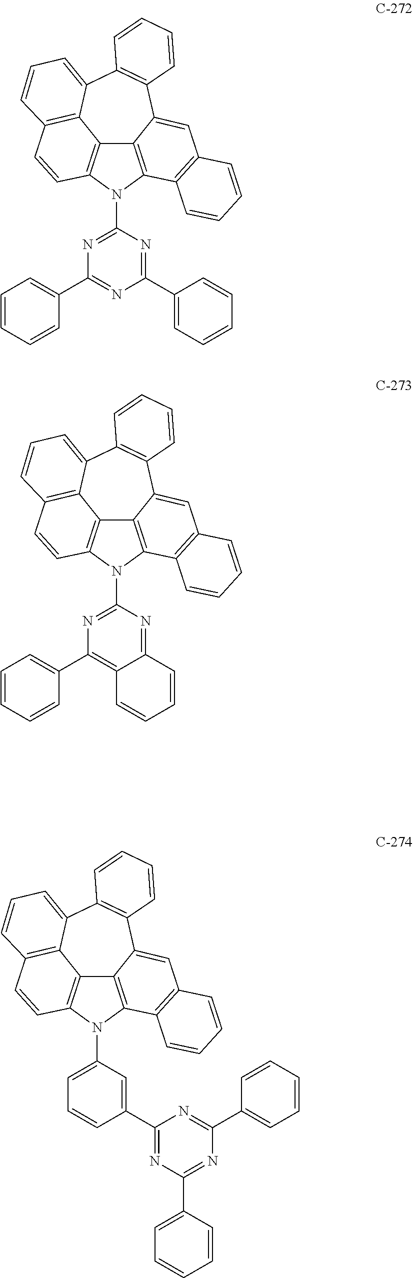 [SMILES: c1ccc(-c2nc(-c3ccccc3)nc(-n3c4ccc5cccc6c5c4c4c(cc5ccccc5c43)-c3ccccc3-6)n2)cc1 ; c1ccc(-c2nc(-n3c4ccc5cccc6c5c4c4c(cc5ccccc5c43)-c3ccccc3-6)nc3ccccc23)cc1 ; c1ccc(-c2nc(-c3ccccc3)nc(-c3cccc(-n4c5ccc6cccc7c6c5c5c(cc6ccccc6c54)-c4ccccc4-7)c3)n2)cc1]

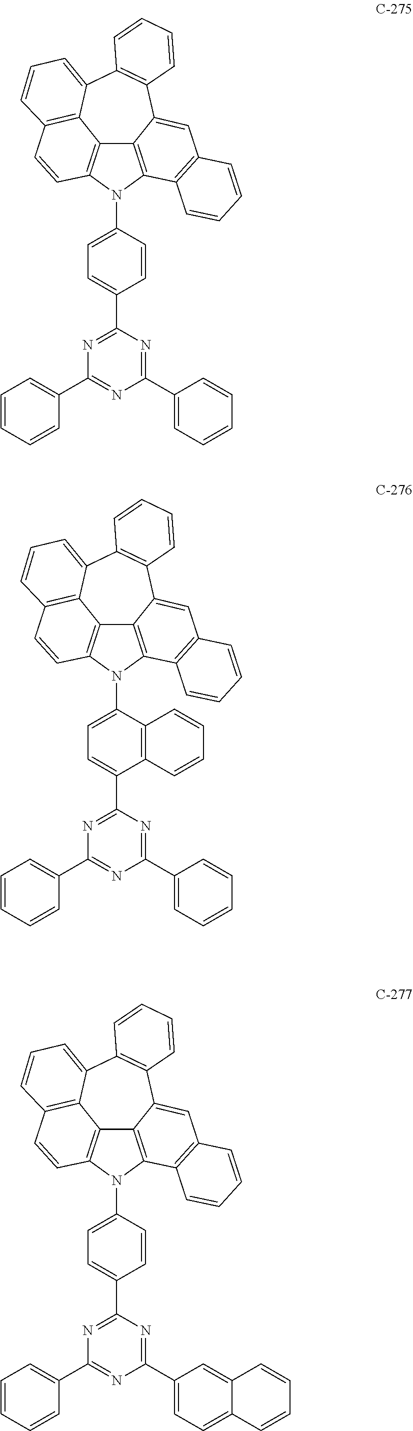 [SMILES: c1ccc(-c2nc(-c3ccccc3)nc(-c3ccc(-n4c5ccc6cccc7c6c5c5c(cc6ccccc6c54)-c4ccccc4-7)cc3)n2)cc1 ; c1ccc(-c2nc(-c3ccccc3)nc(-c3ccc(-n4c5ccc6cccc7c6c5c5c(cc6ccccc6c54)-c4ccccc4-7)c4ccccc34)n2)cc1 ; c1ccc(-c2nc(-c3ccc(-n4c5ccc6cccc7c6c5c5c(cc6ccccc6c54)-c4ccccc4-7)cc3)nc(-c3ccc4ccccc4c3)n2)cc1]

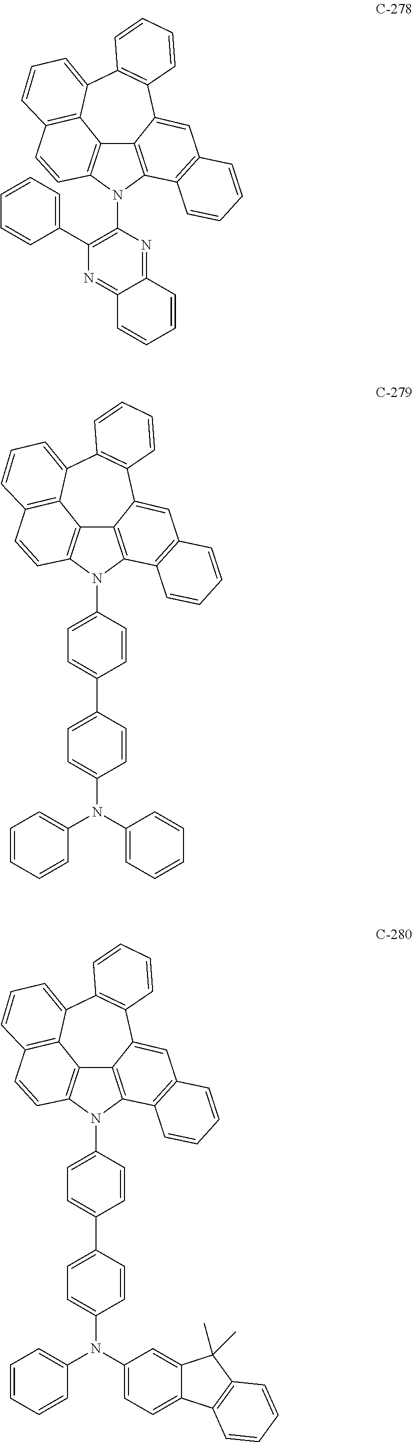 [SMILES: c1ccc(-c2nc3ccccc3nc2-n2c3ccc4cccc5c4c3c3c(cc4ccccc4c32)-c2ccccc2-5)cc1 ; c1ccc(N(c2ccccc2)c2ccc(-c3ccc(-n4c5ccc6cccc7c6c5c5c(cc6ccccc6c54)-c4ccccc4-7)cc3)cc2)cc1 ; CC1(C)c2ccccc2-c2ccc(N(c3ccccc3)c3ccc(-c4ccc(-n5c6ccc7cccc8c7c6c6c(cc7ccccc7c65)-c5ccccc5-8)cc4)cc3)cc21]

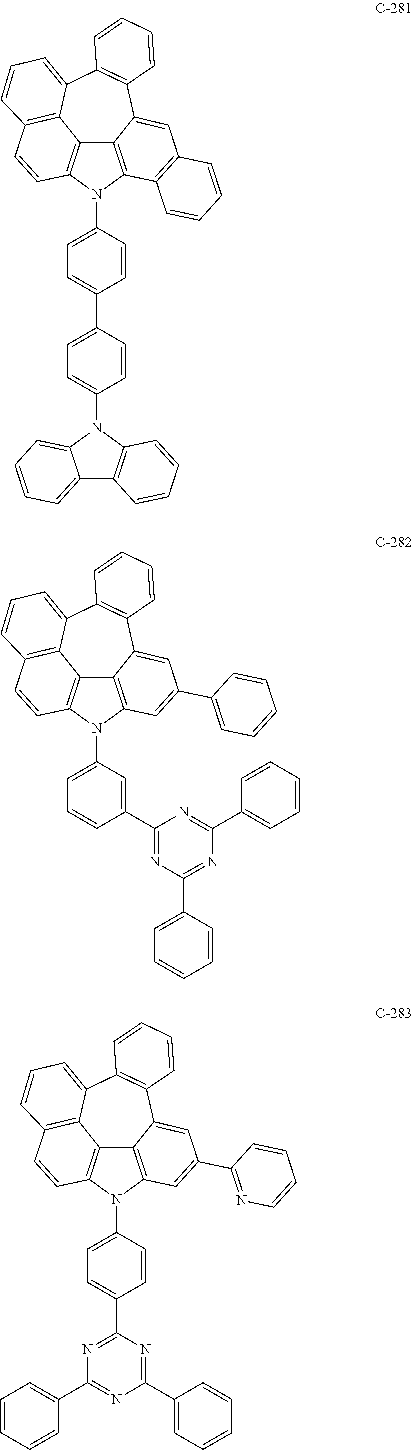 [SMILES: c1ccc2c(c1)-c1cccc3ccc4c(c13)c1c-2cc2ccccc2c1n4-c1ccc(-c2ccc(-n3c4ccccc4c4ccccc43)cc2)cc1 ; c1ccc(-c2cc3c4c5c6c(cccc6ccc5n(-c5cccc(-c6nc(-c7ccccc7)nc(-c7ccccc7)n6)c5)c4c2)-c2ccccc2-3)cc1 ; c1ccc(-c2nc(-c3ccccc3)nc(-c3ccc(-n4c5cc(-c6ccccn6)cc6c5c5c7c(cccc7ccc54)-c4ccccc4-6)cc3)n2)cc1]

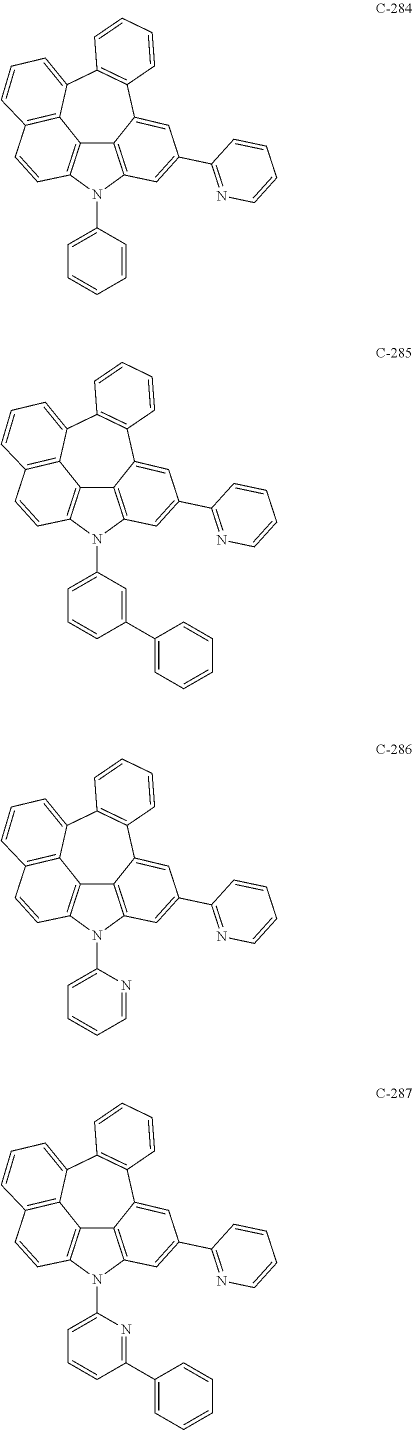 [SMILES: c1ccc(-n2c3cc(-c4ccccn4)cc4c3c3c5c(cccc5ccc32)-c2ccccc2-4)cc1 ; c1ccc(-c2cccc(-n3c4cc(-c5ccccn5)cc5c4c4c6c(cccc6ccc43)-c3ccccc3-5)c2)cc1 ; c1ccc(-c2cc3c4c5c6c(cccc6ccc5n(-c5ccccn5)c4c2)-c2ccccc2-3)nc1 ; c1ccc(-c2cccc(-n3c4cc(-c5ccccn5)cc5c4c4c6c(cccc6ccc43)-c3ccccc3-5)n2)cc1]

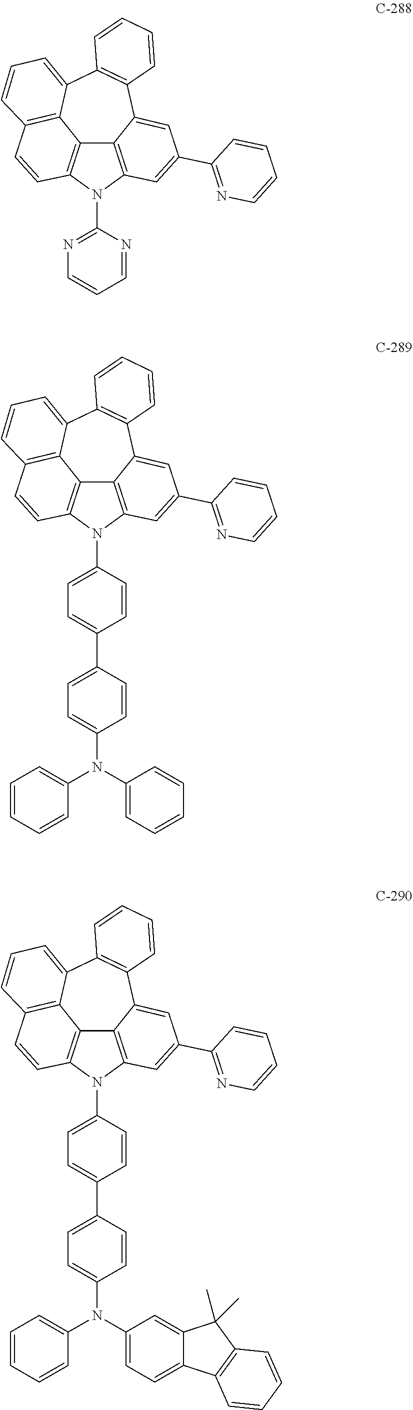 [SMILES: c1ccc(-c2cc3c4c5c6c(cccc6ccc5n(-c5ncccn5)c4c2)-c2ccccc2-3)nc1 ; c1ccc(N(c2ccccc2)c2ccc(-c3ccc(-n4c5cc(-c6ccccn6)cc6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cc(-c7ccccn7)cc7c6c6c8c(cccc8ccc65)-c5ccccc5-7)cc4)cc3)cc21]

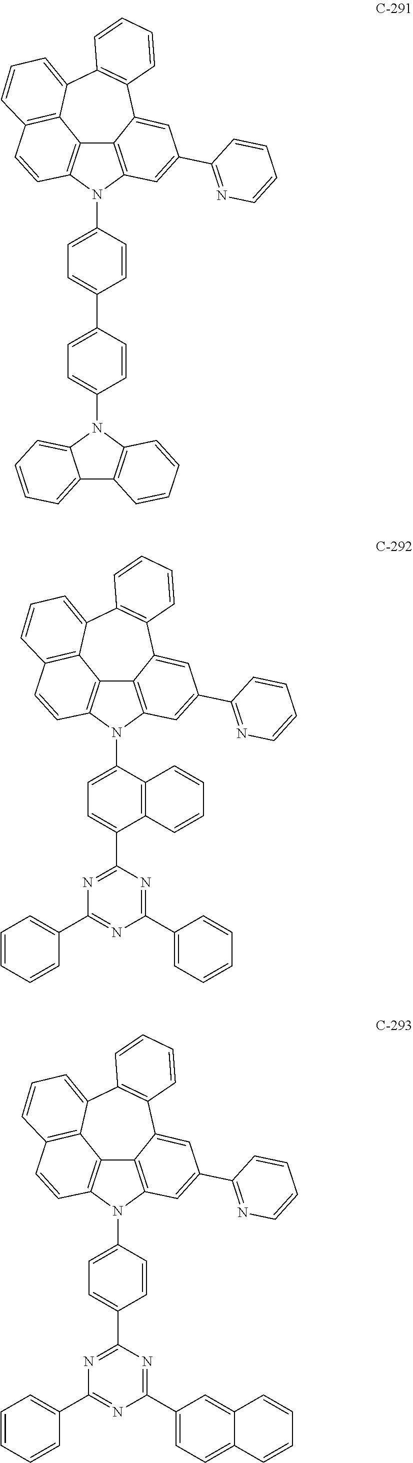 [SMILES: c1ccc(-c2cc3c4c5c6c(cccc6ccc5n(-c5ccc(-c6ccc(-n7c8ccccc8c8ccccc87)cc6)cc5)c4c2)-c2ccccc2-3)nc1 ; c1ccc(-c2nc(-c3ccccc3)nc(-c3ccc(-n4c5cc(-c6ccccn6)cc6c5c5c7c(cccc7ccc54)-c4ccccc4-6)c4ccccc34)n2)cc1 ; c1ccc(-c2nc(-c3ccc(-n4c5cc(-c6ccccn6)cc6c5c5c7c(cccc7ccc54)-c4ccccc4-6)cc3)nc(-c3ccc4ccccc4c3)n2)cc1]

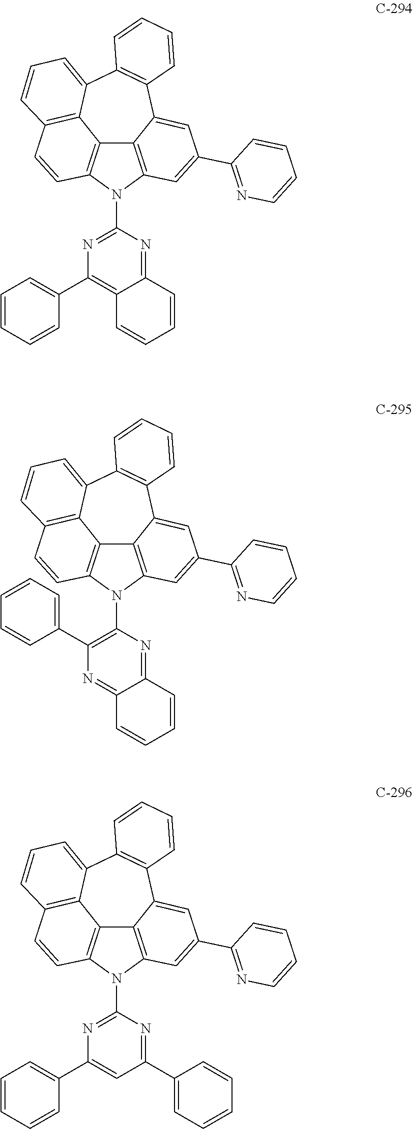 [SMILES: c1ccc(-c2nc(-n3c4cc(-c5ccccn5)cc5c4c4c6c(cccc6ccc43)-c3ccccc3-5)nc3ccccc23)cc1 ; c1ccc(-c2nc3ccccc3nc2-n2c3cc(-c4ccccn4)cc4c3c3c5c(cccc5ccc32)-c2ccccc2-4)cc1 ; c1ccc(-c2cc(-c3ccccc3)nc(-n3c4cc(-c5ccccn5)cc5c4c4c6c(cccc6ccc43)-c3ccccc3-5)n2)cc1]

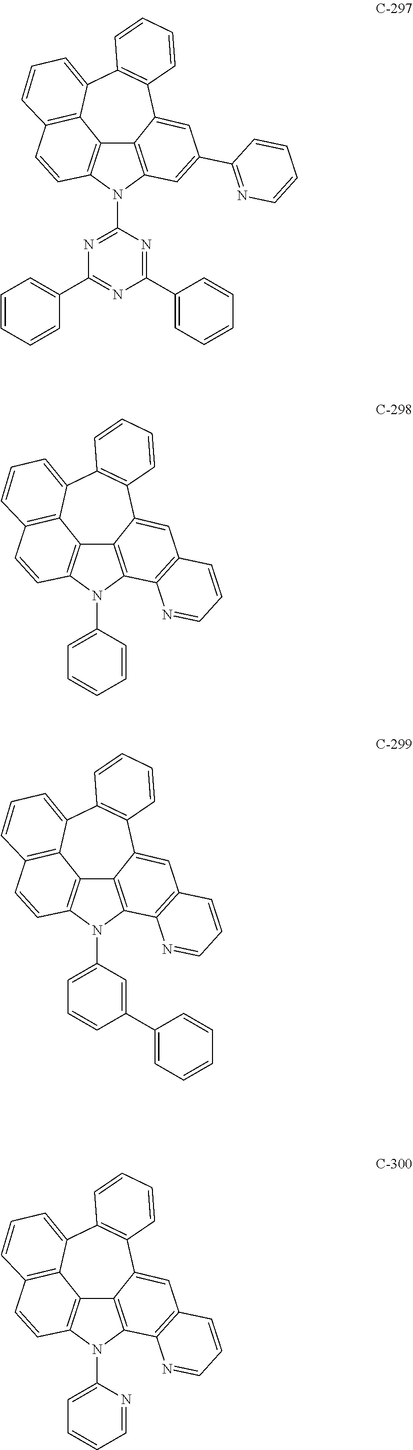 [SMILES: c1ccc(-c2nc(-c3ccccc3)nc(-n3c4cc(-c5ccccn5)cc5c4c4c6c(cccc6ccc43)-c3ccccc3-5)n2)cc1 ; c1ccc(-n2c3ccc4cccc5c4c3c3c(cc4cccnc4c32)-c2ccccc2-5)cc1 ; c1ccc(-c2cccc(-n3c4ccc5cccc6c5c4c4c(cc5cccnc5c43)-c3ccccc3-6)c2)cc1 ; c1ccc(-n2c3ccc4cccc5c4c3c3c(cc4cccnc4c32)-c2ccccc2-5)nc1]

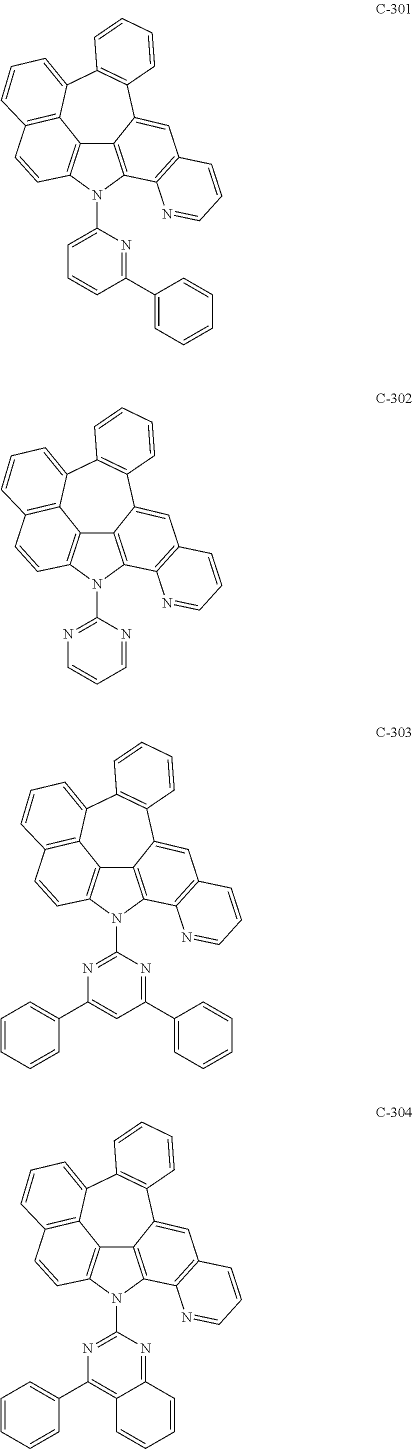 [SMILES: c1ccc(-c2cccc(-n3c4ccc5cccc6c5c4c4c(cc5cccnc5c43)-c3ccccc3-6)n2)cc1 ; c1cnc(-n2c3ccc4cccc5c4c3c3c(cc4cccnc4c32)-c2ccccc2-5)nc1 ; c1ccc(-c2cc(-c3ccccc3)nc(-n3c4ccc5cccc6c5c4c4c(cc5cccnc5c43)-c3ccccc3-6)n2)cc1 ; c1ccc(-c2nc(-n3c4ccc5cccc6c5c4c4c(cc5cccnc5c43)-c3ccccc3-6)nc3ccccc23)cc1]

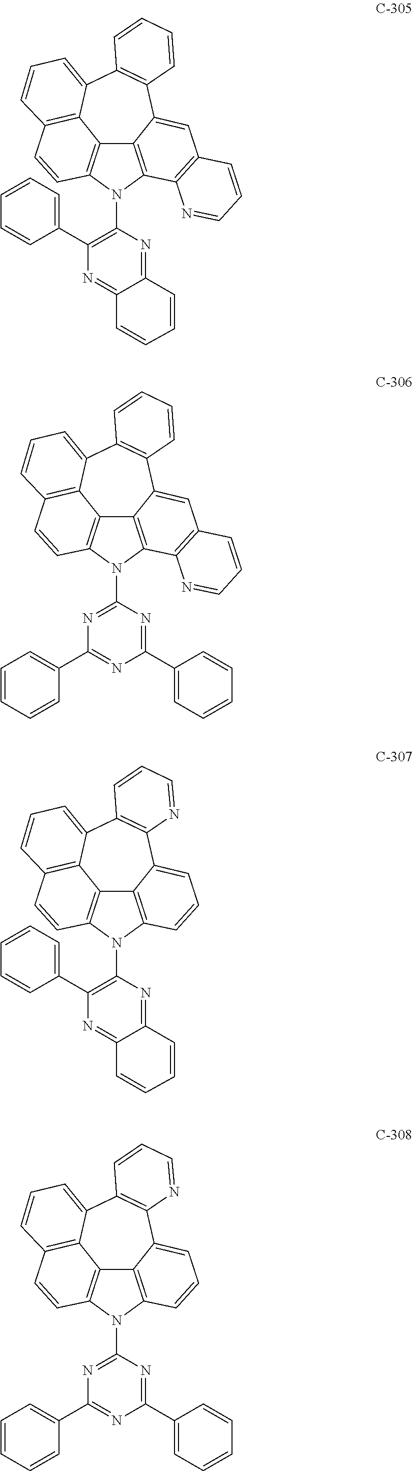 [SMILES: c1ccc(-c2nc3ccccc3nc2-n2c3ccc4cccc5c4c3c3c(cc4cccnc4c32)-c2ccccc2-5)cc1 ; c1ccc(-c2nc(-c3ccccc3)nc(-n3c4ccc5cccc6c5c4c4c(cc5cccnc5c43)-c3ccccc3-6)n2)cc1 ; c1ccc(-c2nc3ccccc3nc2-n2c3cccc4c3c3c5c(cccc5ccc32)-c2cccnc2-4)cc1 ; c1ccc(-c2nc(-c3ccccc3)nc(-n3c4cccc5c4c4c6c(cccc6ccc43)-c3cccnc3-5)n2)cc1]

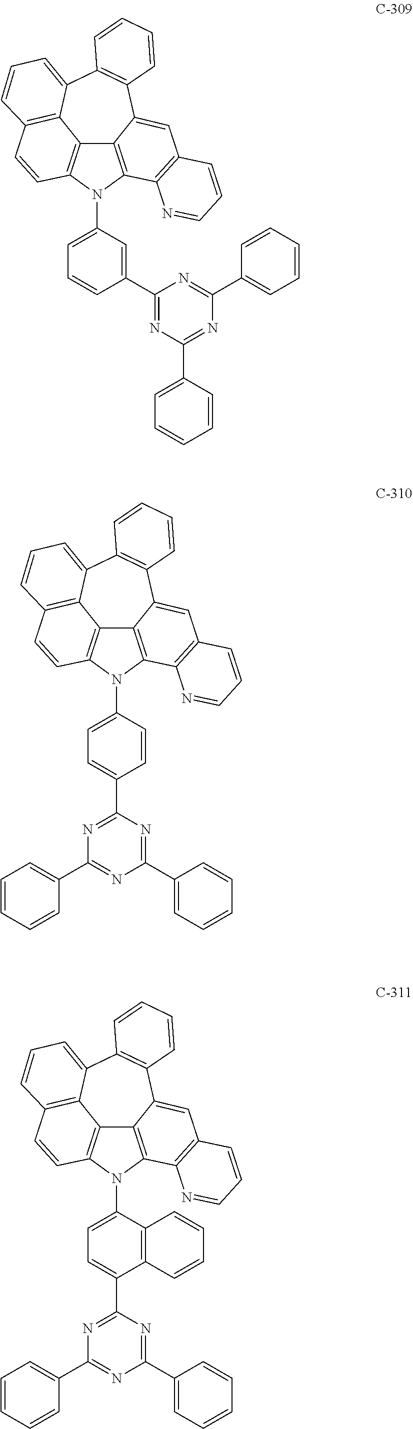 [SMILES: c1ccc(-c2nc(-c3ccccc3)nc(-c3cccc(-n4c5ccc6cccc7c6c5c5c(cc6cccnc6c54)-c4ccccc4-7)c3)n2)cc1 ; c1ccc(-c2nc(-c3ccccc3)nc(-c3ccc(-n4c5ccc6cccc7c6c5c5c(cc6cccnc6c54)-c4ccccc4-7)cc3)n2)cc1 ; c1ccc(-c2nc(-c3ccccc3)nc(-c3ccc(-n4c5ccc6cccc7c6c5c5c(cc6cccnc6c54)-c4ccccc4-7)c4ccccc34)n2)cc1]

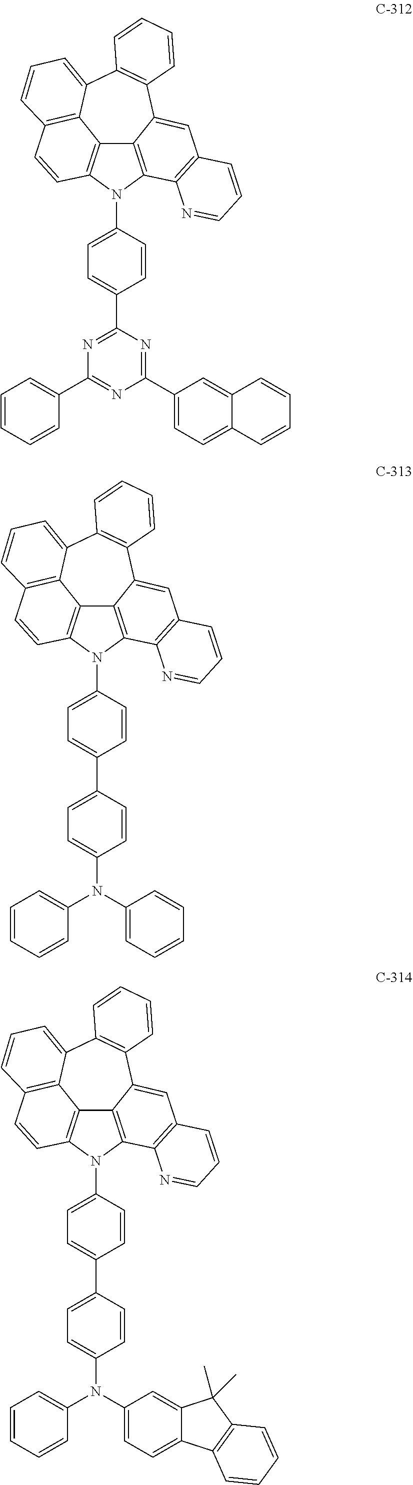

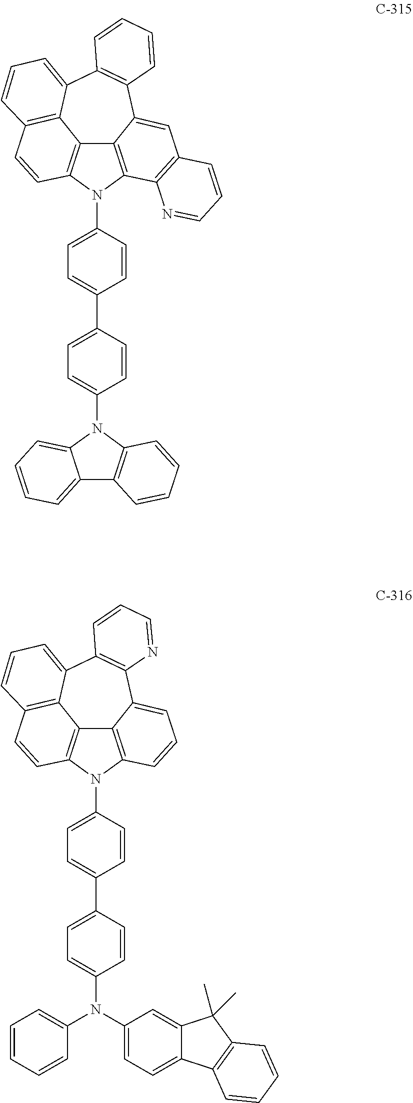 [SMILES: c1ccc2c(c1)-c1cccc3ccc4c(c13)c1c-2cc2cccnc2c1n4-c1ccc(-c2ccc(-n3c4ccccc4c4ccccc43)cc2)cc1 ; CC1(C)c2ccccc2-c2ccc(N(c3ccccc3)c3ccc(-c4ccc(-n5c6cccc7c6c6c8c(cccc8ccc65)-c5cccnc5-7)cc4)cc3)cc21]

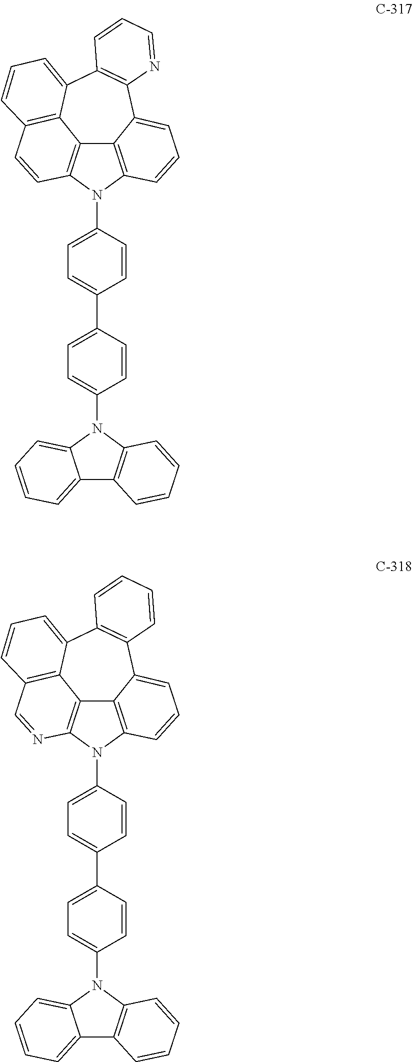 [SMILES: c1cnc2c(c1)-c1cccc3ccc4c(c13)c1c-2cccc1n4-c1ccc(-c2ccc(-n3c4ccccc4c4ccccc43)cc2)cc1 ; c1ccc2c(c1)-c1cccc3cnc4c(c13)c1c-2cccc1n4-c1ccc(-c2ccc(-n3c4ccccc4c4ccccc43)cc2)cc1]

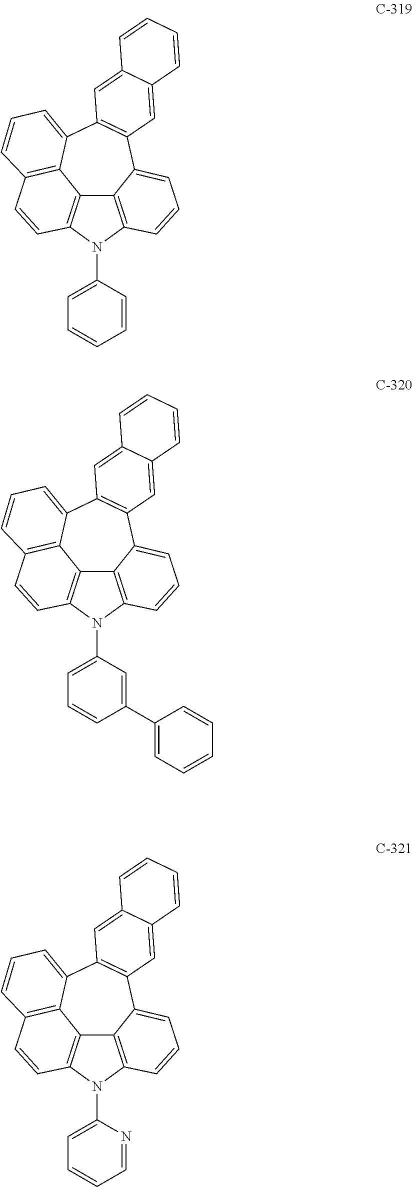 [SMILES: c1ccc(-n2c3cccc4c3c3c5c(cccc5ccc32)-c2cc3ccccc3cc2-4)cc1 ; c1ccc(-c2cccc(-n3c4cccc5c4c4c6c(cccc6ccc43)-c3cc4ccccc4cc3-5)c2)cc1 ; c1ccc(-n2c3cccc4c3c3c5c(cccc5ccc32)-c2cc3ccccc3cc2-4)nc1]

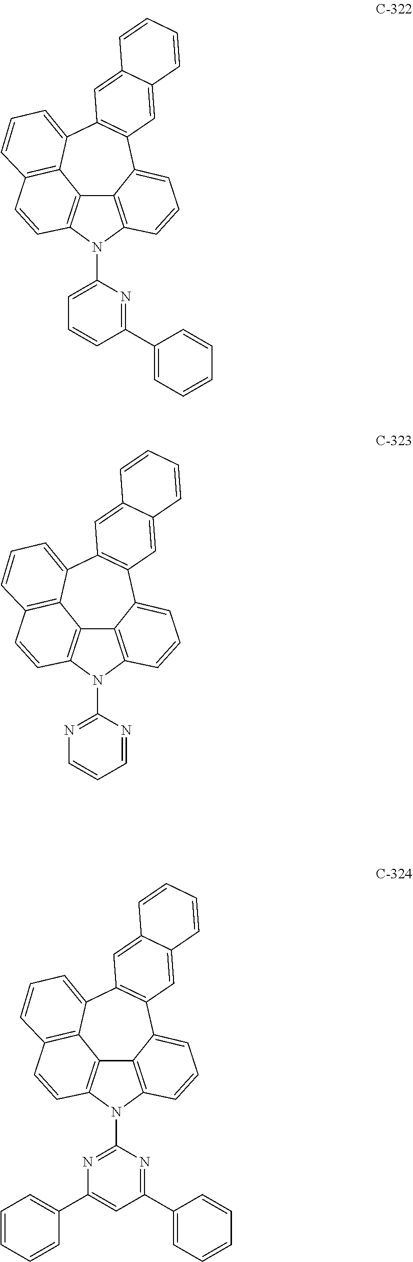 [SMILES: c1ccc(-c2cccc(-n3c4cccc5c4c4c6c(cccc6ccc43)-c3cc4ccccc4cc3-5)n2)cc1 ; c1cnc(-n2c3cccc4c3c3c5c(cccc5ccc32)-c2cc3ccccc3cc2-4)nc1 ; c1ccc(-c2cc(-c3ccccc3)nc(-n3c4cccc5c4c4c6c(cccc6ccc43)-c3cc4ccccc4cc3-5)n2)cc1]

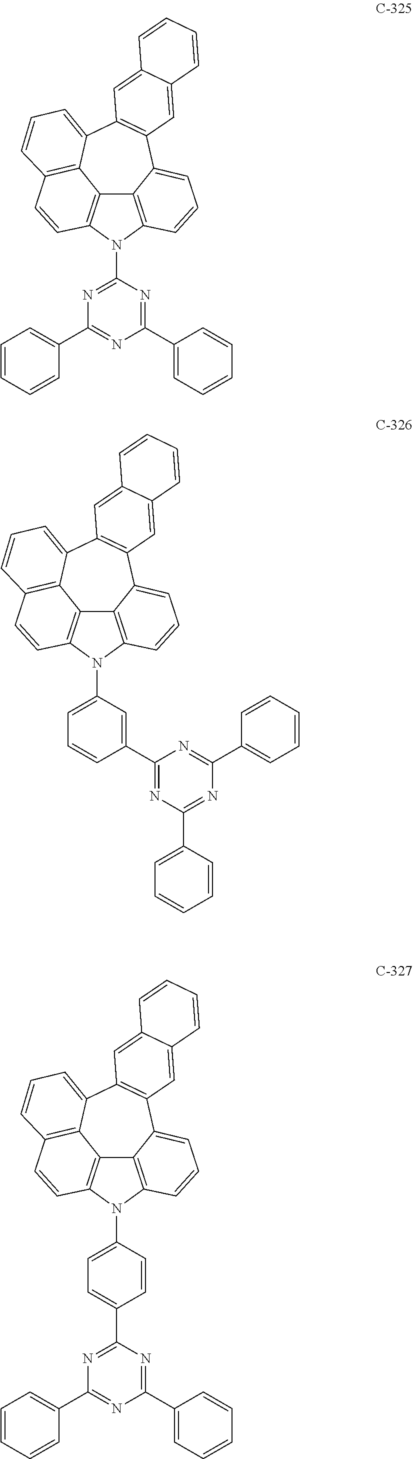 [SMILES: c1ccc(-c2nc(-c3ccccc3)nc(-n3c4cccc5c4c4c6c(cccc6ccc43)-c3cc4ccccc4cc3-5)n2)cc1 ; c1ccc(-c2nc(-c3ccccc3)nc(-c3cccc(-n4c5cccc6c5c5c7c(cccc7ccc54)-c4cc5ccccc5cc4-6)c3)n2)cc1 ; c1ccc(-c2nc(-c3ccccc3)nc(-c3ccc(-n4c5cccc6c5c5c7c(cccc7ccc54)-c4cc5ccccc5cc4-6)cc3)n2)cc1]

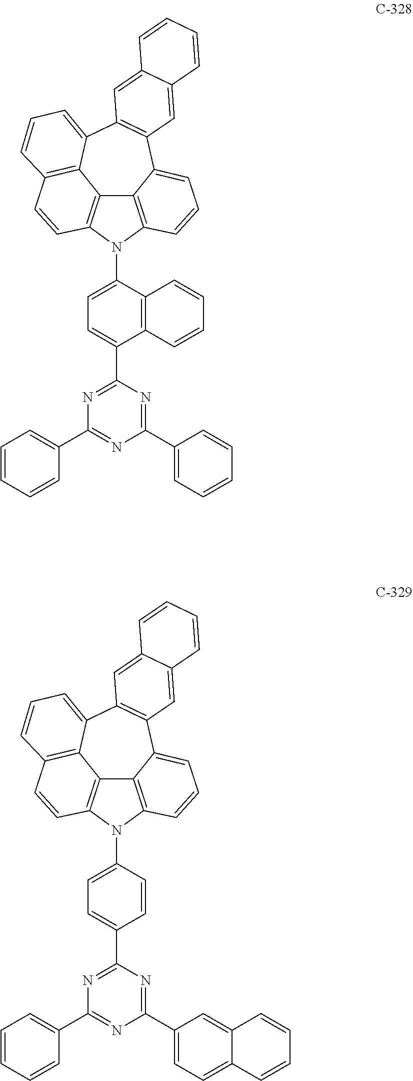 [SMILES: c1ccc(-c2nc(-c3ccccc3)nc(-c3ccc(-n4c5cccc6c5c5c7c(cccc7ccc54)-c4cc5ccccc5cc4-6)c4ccccc34)n2)cc1 ; c1ccc(-c2nc(-c3ccc(-n4c5cccc6c5c5c7c(cccc7ccc54)-c4cc5ccccc5cc4-6)cc3)nc(-c3ccc4ccccc4c3)n2)cc1]

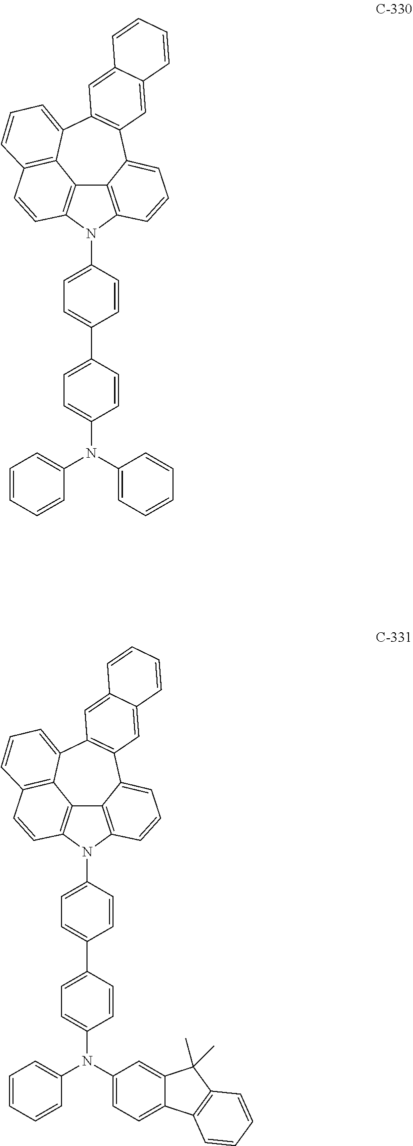 [SMILES: c1ccc(N(c2ccccc2)c2ccc(-c3ccc(-n4c5cccc6c5c5c7c(cccc7ccc54)-c4cc5ccccc5cc4-6)cc3)cc2)cc1 ; CC1(C)c2ccccc2-c2ccc(N(c3ccccc3)c3ccc(-c4ccc(-n5c6cccc7c6c6c8c(cccc8ccc65)-c5cc6ccccc6cc5-7)cc4)cc3)cc21]

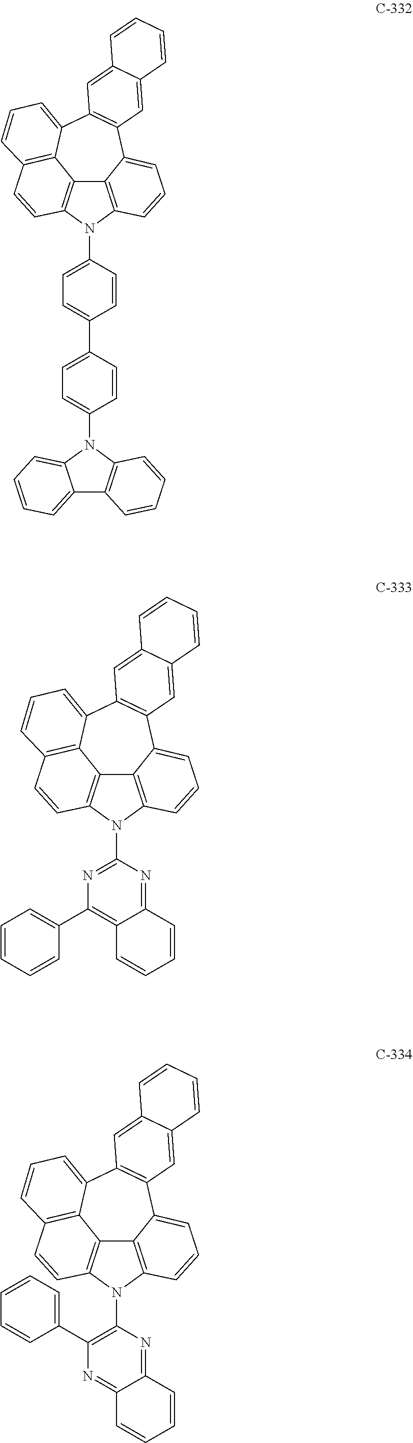 [SMILES: c1ccc2cc3c(cc2c1)-c1cccc2ccc4c(c12)c1c-3cccc1n4-c1ccc(-c2ccc(-n3c4ccccc4c4ccccc43)cc2)cc1 ; c1ccc(-c2nc(-n3c4cccc5c4c4c6c(cccc6ccc43)-c3cc4ccccc4cc3-5)nc3ccccc23)cc1 ; c1ccc(-c2nc3ccccc3nc2-n2c3cccc4c3c3c5c(cccc5ccc32)-c2cc3ccccc3cc2-4)cc1]

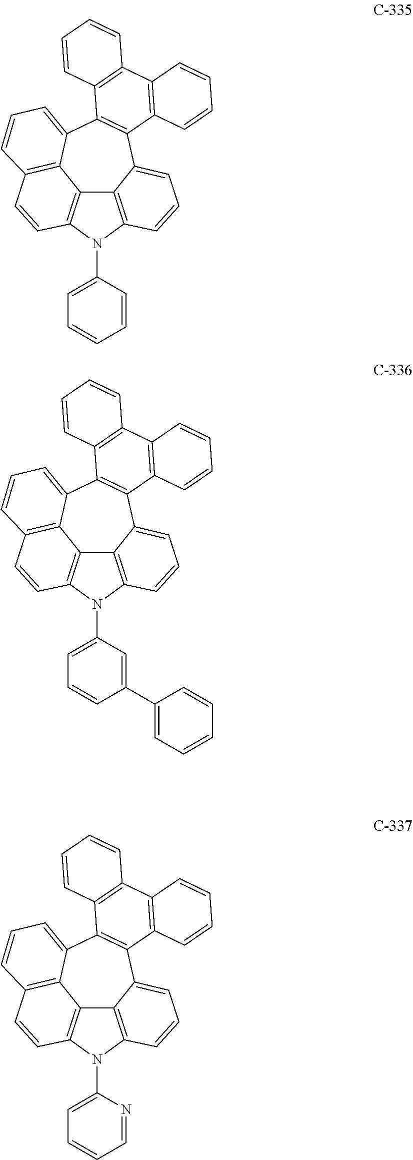

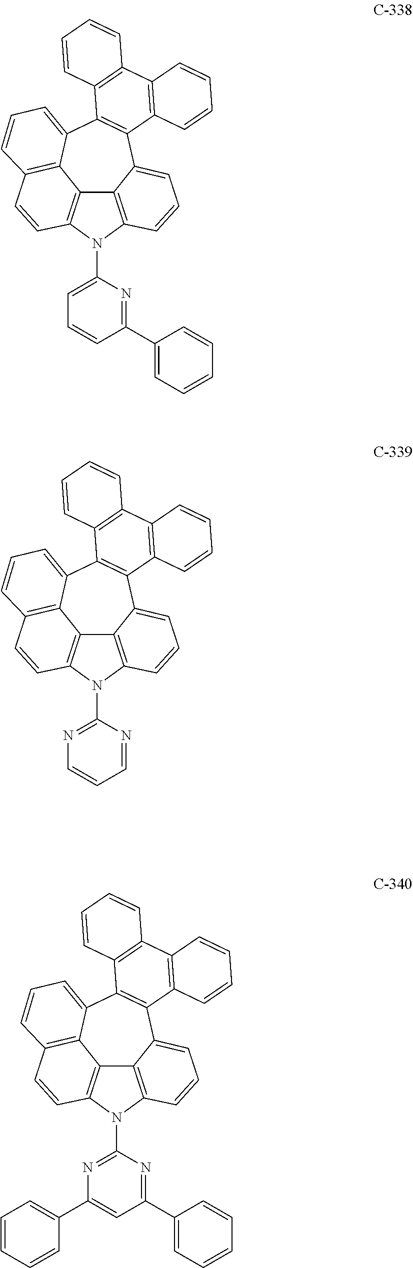 [SMILES: c1ccc(-c2cccc(-n3c4cccc5c4c4c6c(cccc6ccc43)-c3c-5c4ccccc4c4ccccc34)n2)cc1 ; c1cnc(-n2c3cccc4c3c3c5c(cccc5ccc32)-c2c-4c3ccccc3c3ccccc23)nc1 ; c1ccc(-c2cc(-c3ccccc3)nc(-n3c4cccc5c4c4c6c(cccc6ccc43)-c3c-5c4ccccc4c4ccccc34)n2)cc1]

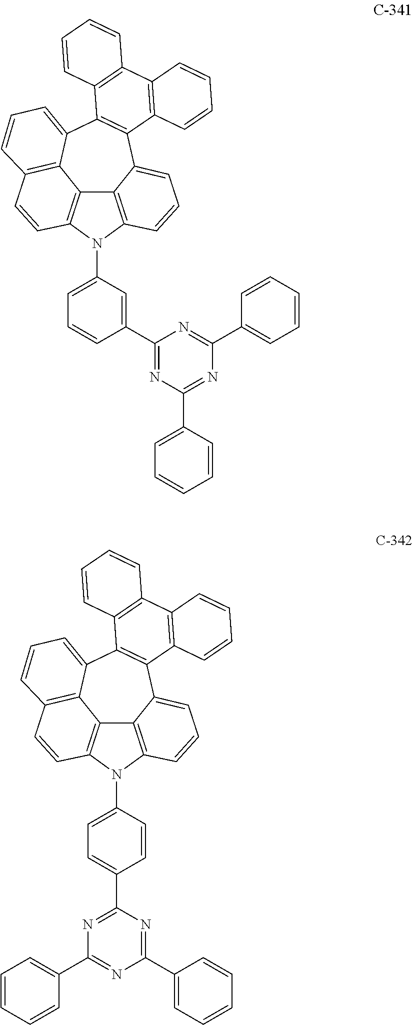 [SMILES: c1ccc(-c2nc(-c3ccccc3)nc(-c3cccc(-n4c5cccc6c5c5c7c(cccc7ccc54)-c4c-6c5ccccc5c5ccccc45)c3)n2)cc1 ; c1ccc(-c2nc(-c3ccccc3)nc(-c3ccc(-n4c5cccc6c5c5c7c(cccc7ccc54)-c4c-6c5ccccc5c5ccccc45)cc3)n2)cc1]

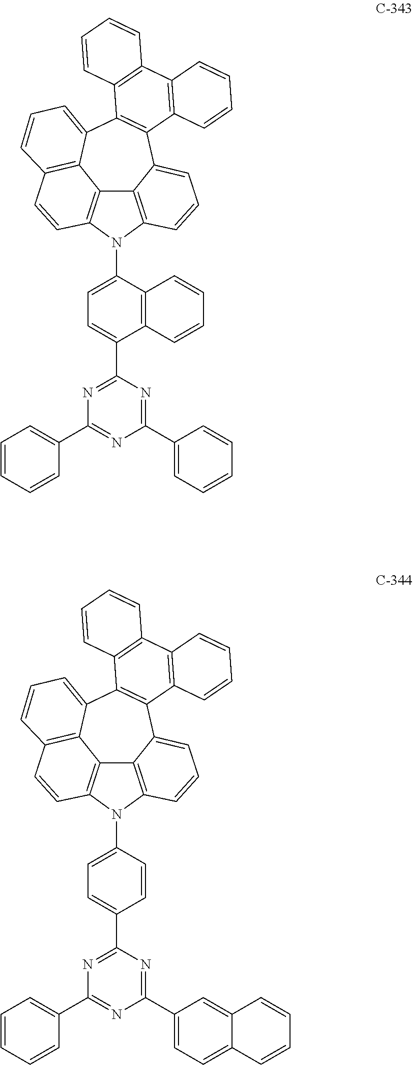 [SMILES: c1ccc(-c2nc(-c3ccccc3)nc(-c3ccc(-n4c5cccc6c5c5c7c(cccc7ccc54)-c4c-6c5ccccc5c5ccccc45)c4ccccc34)n2)cc1 ; c1ccc(-c2nc(-c3ccc(-n4c5cccc6c5c5c7c(cccc7ccc54)-c4c-6c5ccccc5c5ccccc45)cc3)nc(-c3ccc4ccccc4c3)n2)cc1]

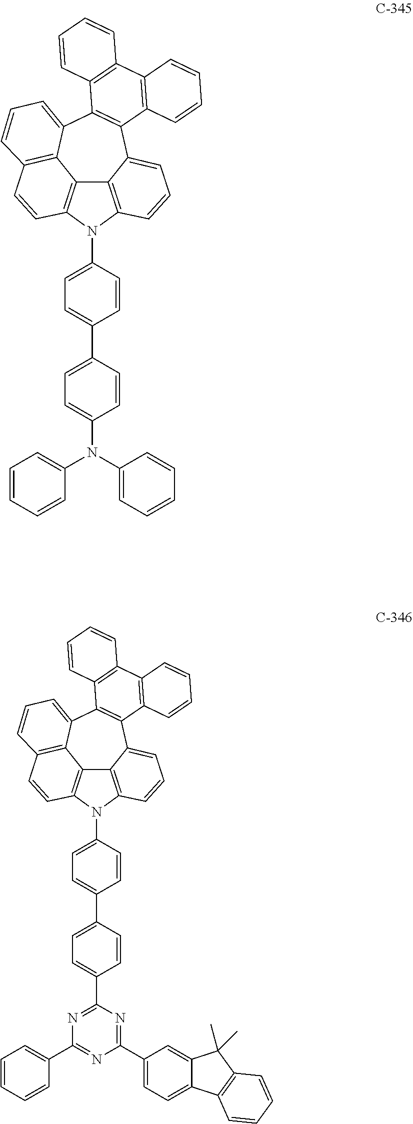 [SMILES: c1ccc(N(c2ccccc2)c2ccc(-c3ccc(-n4c5cccc6c5c5c7c(cccc7ccc54)-c4c-6c5ccccc5c5ccccc45)cc3)cc2)cc1 ; CC1(C)c2ccccc2-c2ccc(-c3nc(-c4ccccc4)nc(-c4ccc(-c5ccc(-n6c7cccc8c7c7c9c(cccc9ccc76)-c6c-8c7ccccc7c7ccccc67)cc5)cc4)n3)cc21]

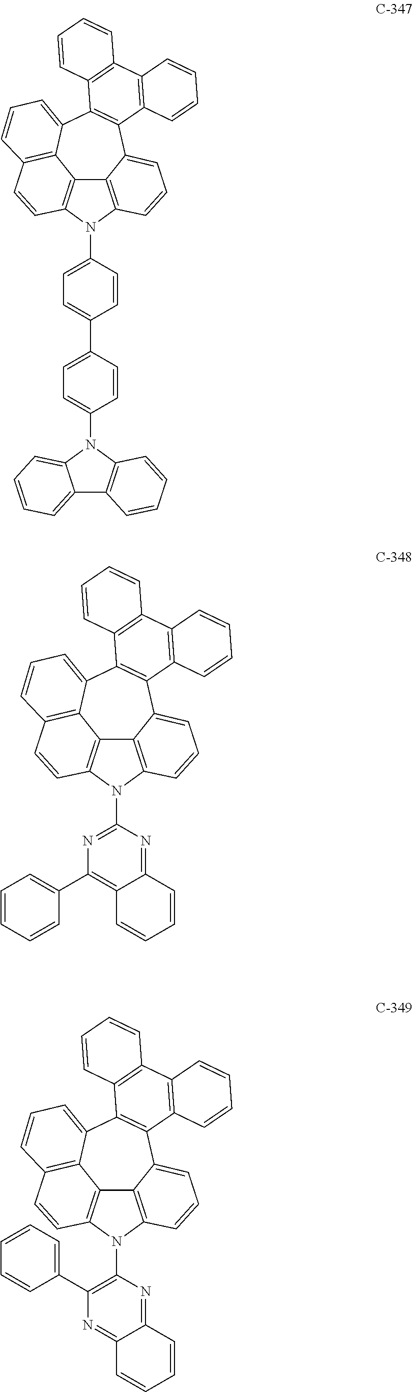 [SMILES: c1cc2c3c(c1)ccc1c3c3c(cccc3n1-c1ccc(-c3ccc(-n4c5ccccc5c5ccccc54)cc3)cc1)-c1c-2c2ccccc2c2ccccc12 ; c1ccc(-c2nc(-n3c4cccc5c4c4c6c(cccc6ccc43)-c3c-5c4ccccc4c4ccccc34)nc3ccccc23)cc1 ; c1ccc(-c2nc3ccccc3nc2-n2c3cccc4c3c3c5c(cccc5ccc32)-c2c-4c3ccccc3c3ccccc23)cc1]

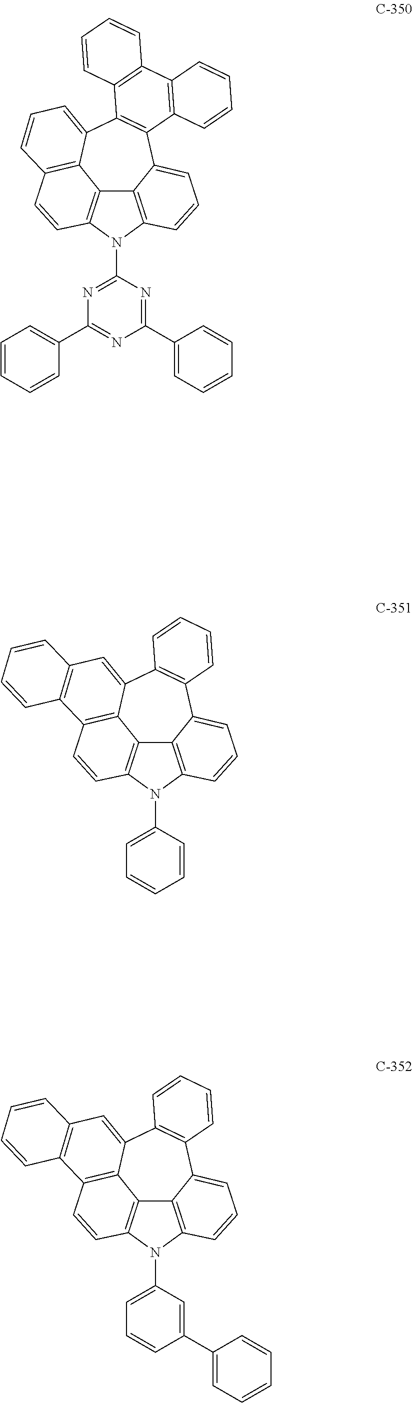 [SMILES: c1ccc(-c2nc(-c3ccccc3)nc(-n3c4cccc5c4c4c6c(cccc6ccc43)-c3c-5c4ccccc4c4ccccc34)n2)cc1 ; c1ccc(-n2c3cccc4c3c3c5c(cc6ccccc6c5ccc32)-c2ccccc2-4)cc1 ; c1ccc(-c2cccc(-n3c4cccc5c4c4c6c(cc7ccccc7c6ccc43)-c3ccccc3-5)c2)cc1]

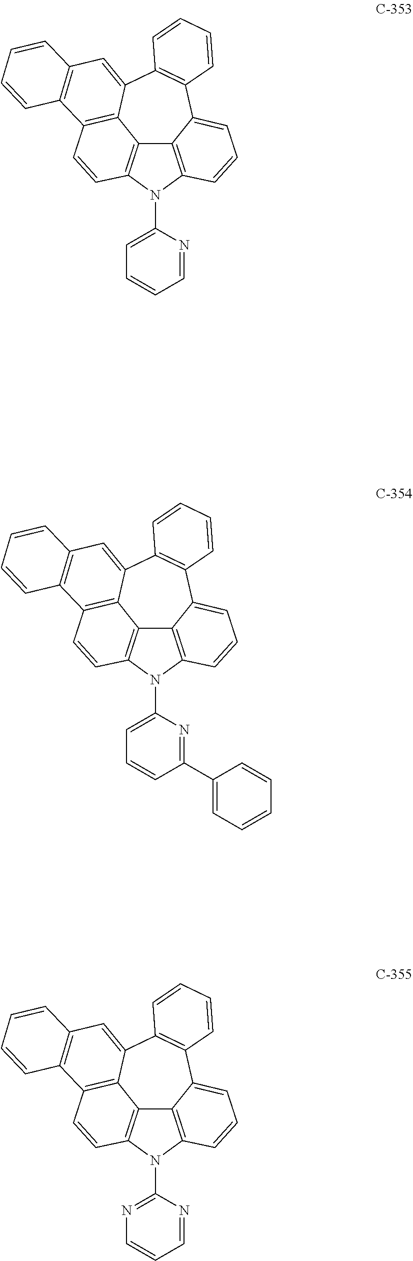 [SMILES: c1ccc(-n2c3cccc4c3c3c5c(cc6ccccc6c5ccc32)-c2ccccc2-4)nc1 ; c1ccc(-c2cccc(-n3c4cccc5c4c4c6c(cc7ccccc7c6ccc43)-c3ccccc3-5)n2)cc1 ; c1cnc(-n2c3cccc4c3c3c5c(cc6ccccc6c5ccc32)-c2ccccc2-4)nc1]

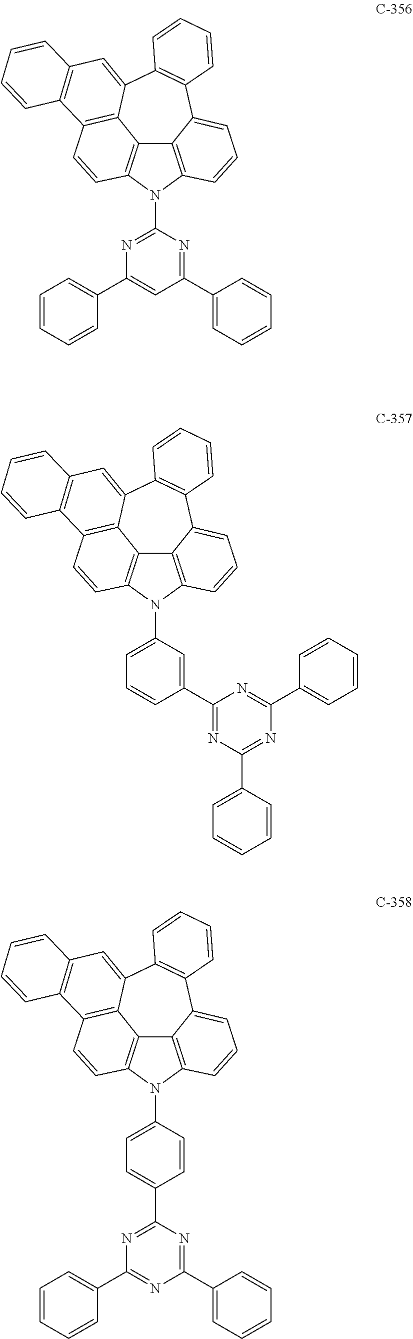 [SMILES: c1ccc(-c2cc(-c3ccccc3)nc(-n3c4cccc5c4c4c6c(cc7ccccc7c6ccc43)-c3ccccc3-5)n2)cc1 ; c1ccc(-c2nc(-c3ccccc3)nc(-c3cccc(-n4c5cccc6c5c5c7c(cc8ccccc8c7ccc54)-c4ccccc4-6)c3)n2)cc1 ; c1ccc(-c2nc(-c3ccccc3)nc(-c3ccc(-n4c5cccc6c5c5c7c(cc8ccccc8c7ccc54)-c4ccccc4-6)cc3)n2)cc1]

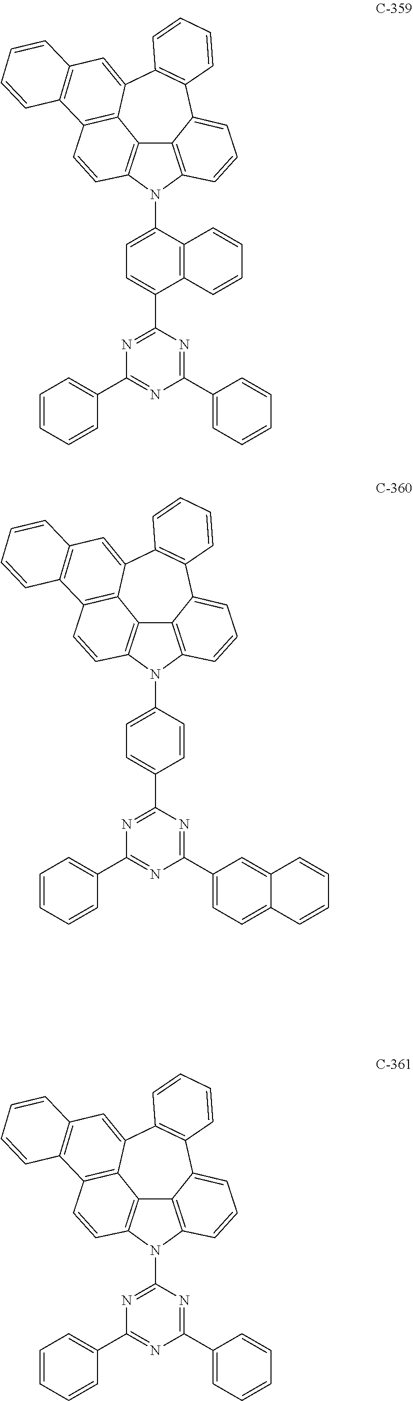 [SMILES: c1ccc(-c2nc(-c3ccccc3)nc(-c3ccc(-n4c5cccc6c5c5c7c(cc8ccccc8c7ccc54)-c4ccccc4-6)c4ccccc34)n2)cc1 ; c1ccc(-c2nc(-c3ccc(-n4c5cccc6c5c5c7c(cc8ccccc8c7ccc54)-c4ccccc4-6)cc3)nc(-c3ccc4ccccc4c3)n2)cc1 ; c1ccc(-c2nc(-c3ccccc3)nc(-n3c4cccc5c4c4c6c(cc7ccccc7c6ccc43)-c3ccccc3-5)n2)cc1]

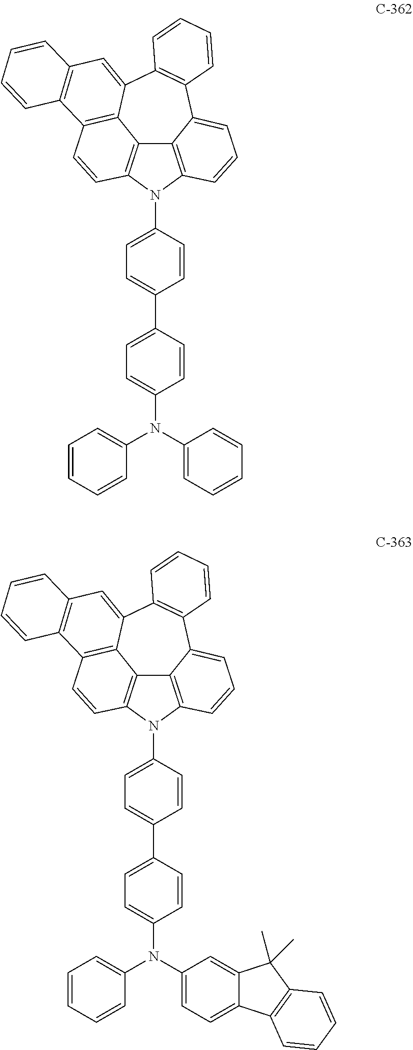 [SMILES: c1ccc(N(c2ccccc2)c2ccc(-c3ccc(-n4c5cccc6c5c5c7c(cc8ccccc8c7ccc54)-c4ccccc4-6)cc3)cc2)cc1 ; CC1(C)c2ccccc2-c2ccc(N(c3ccccc3)c3ccc(-c4ccc(-n5c6cccc7c6c6c8c(cc9ccccc9c8ccc65)-c5ccccc5-7)cc4)cc3)cc21]

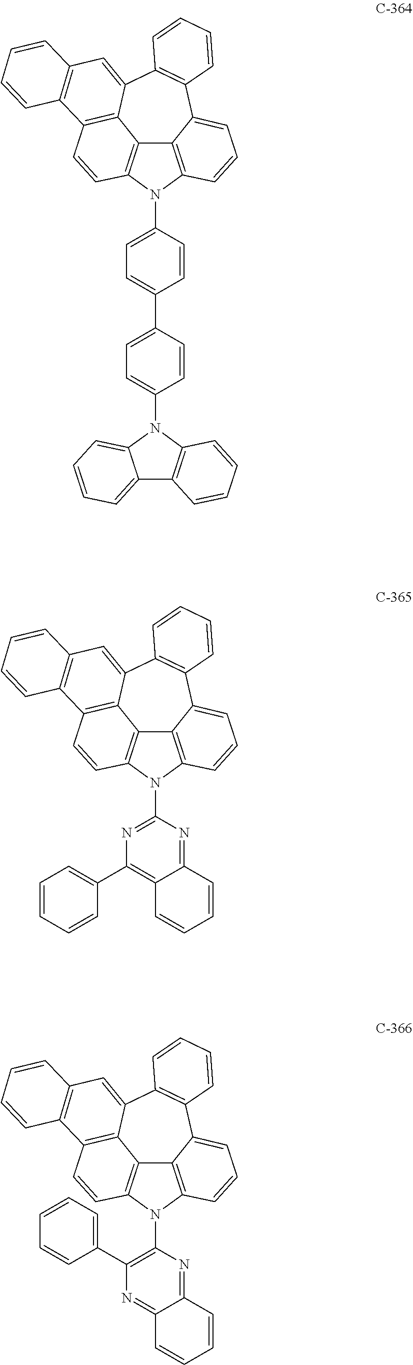 [SMILES: c1ccc2c(c1)-c1cc3ccccc3c3ccc4c(c13)c1c-2cccc1n4-c1ccc(-c2ccc(-n3c4ccccc4c4ccccc43)cc2)cc1 ; c1ccc(-c2nc(-n3c4cccc5c4c4c6c(cc7ccccc7c6ccc43)-c3ccccc3-5)nc3ccccc23)cc1 ; c1ccc(-c2nc3ccccc3nc2-n2c3cccc4c3c3c5c(cc6ccccc6c5ccc32)-c2ccccc2-4)cc1]

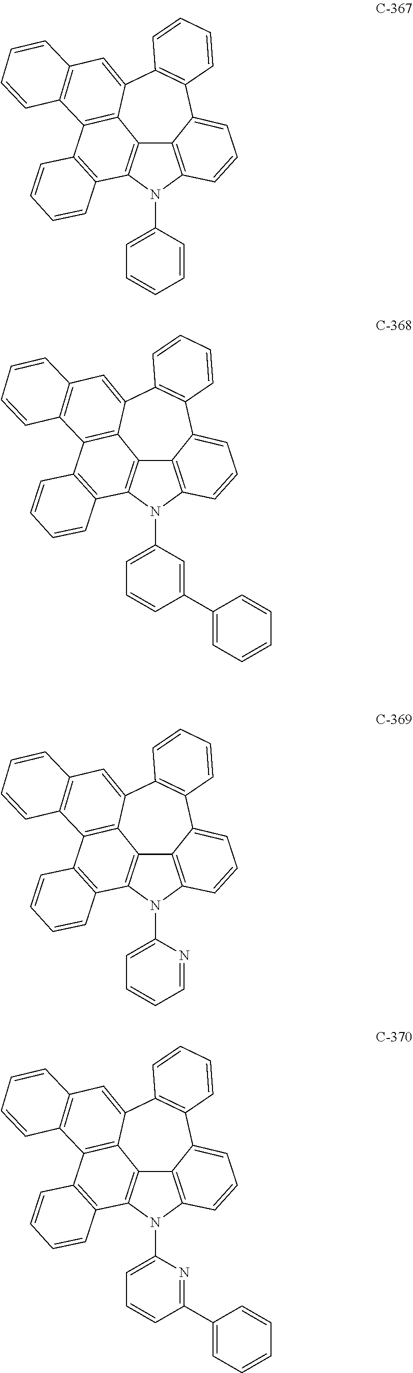 [SMILES: c1ccc(-n2c3cccc4c3c3c5c(cc6ccccc6c5c5ccccc5c32)-c2ccccc2-4)cc1 ; c1ccc(-c2cccc(-n3c4cccc5c4c4c6c(cc7ccccc7c6c6ccccc6c43)-c3ccccc3-5)c2)cc1 ; c1ccc(-n2c3cccc4c3c3c5c(cc6ccccc6c5c5ccccc5c32)-c2ccccc2-4)nc1 ; c1ccc(-c2cccc(-n3c4cccc5c4c4c6c(cc7ccccc7c6c6ccccc6c43)-c3ccccc3-5)n2)cc1]

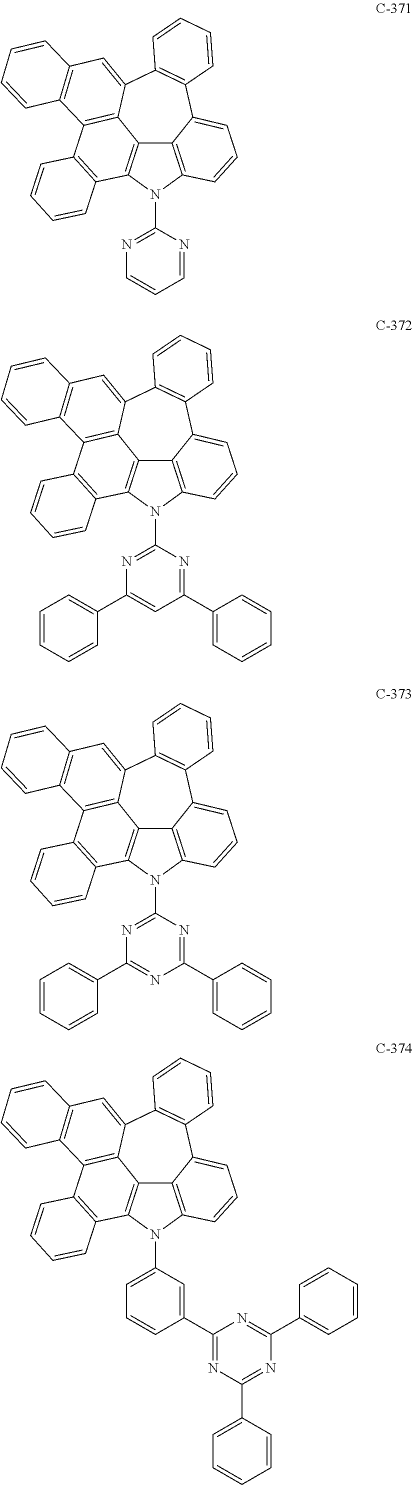 [SMILES: c1cnc(-n2c3cccc4c3c3c5c(cc6ccccc6c5c5ccccc5c32)-c2ccccc2-4)nc1 ; c1ccc(-c2cc(-c3ccccc3)nc(-n3c4cccc5c4c4c6c(cc7ccccc7c6c6ccccc6c43)-c3ccccc3-5)n2)cc1 ; c1ccc(-c2nc(-c3ccccc3)nc(-n3c4cccc5c4c4c6c(cc7ccccc7c6c6ccccc6c43)-c3ccccc3-5)n2)cc1 ; c1ccc(-c2nc(-c3ccccc3)nc(-c3cccc(-n4c5cccc6c5c5c7c(cc8ccccc8c7c7ccccc7c54)-c4ccccc4-6)c3)n2)cc1]

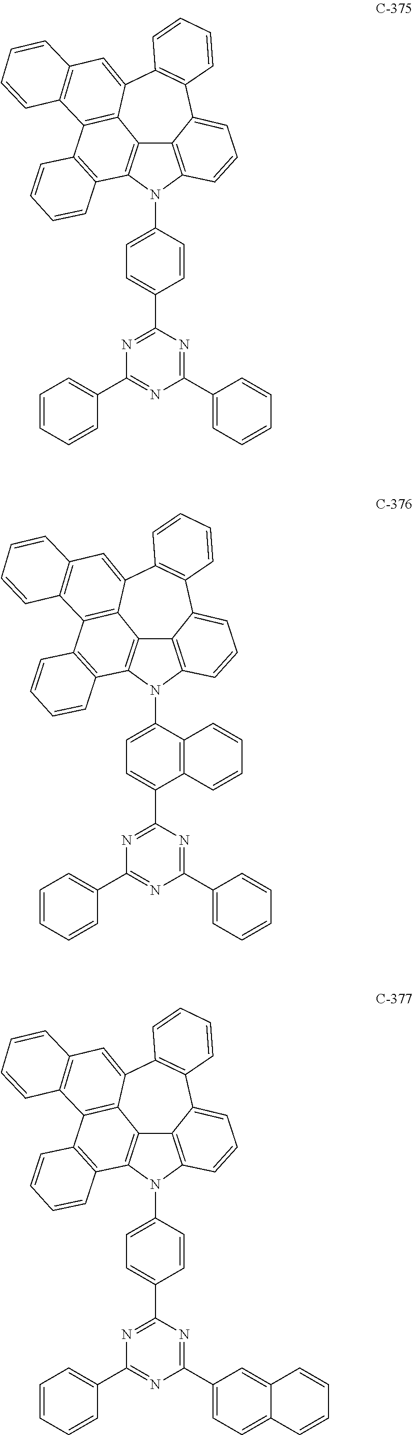 [SMILES: c1ccc(-c2nc(-c3ccccc3)nc(-c3ccc(-n4c5cccc6c5c5c7c(cc8ccccc8c7c7ccccc7c54)-c4ccccc4-6)cc3)n2)cc1 ; c1ccc(-c2nc(-c3ccccc3)nc(-c3ccc(-n4c5cccc6c5c5c7c(cc8ccccc8c7c7ccccc7c54)-c4ccccc4-6)c4ccccc34)n2)cc1 ; c1ccc(-c2nc(-c3ccc(-n4c5cccc6c5c5c7c(cc8ccccc8c7c7ccccc7c54)-c4ccccc4-6)cc3)nc(-c3ccc4ccccc4c3)n2)cc1]

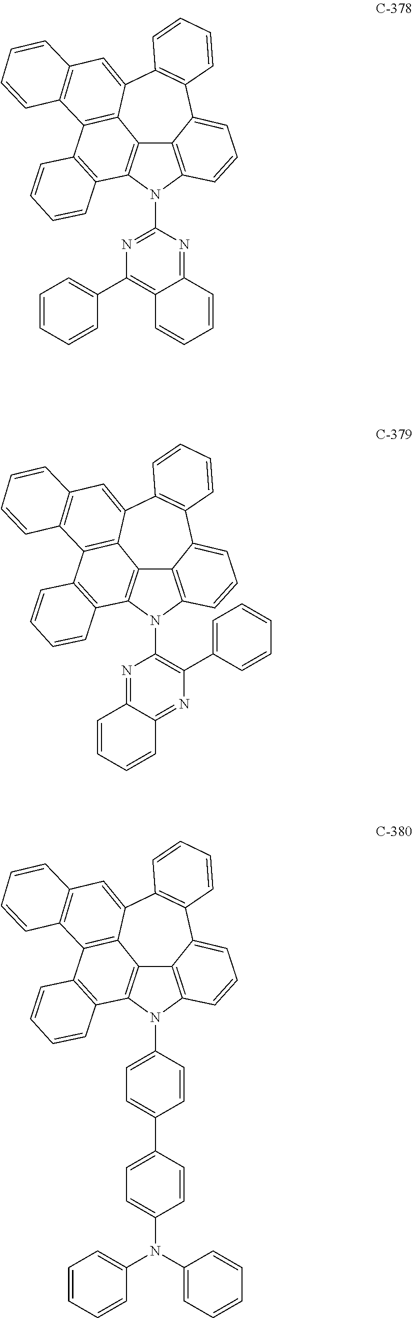 [SMILES: c1ccc(-c2nc(-n3c4cccc5c4c4c6c(cc7ccccc7c6c6ccccc6c43)-c3ccccc3-5)nc3ccccc23)cc1 ; c1ccc(-c2nc3ccccc3nc2-n2c3cccc4c3c3c5c(cc6ccccc6c5c5ccccc5c32)-c2ccccc2-4)cc1 ; c1ccc(N(c2ccccc2)c2ccc(-c3ccc(-n4c5cccc6c5c5c7c(cc8ccccc8c7c7ccccc7c54)-c4ccccc4-6)cc3)cc2)cc1]

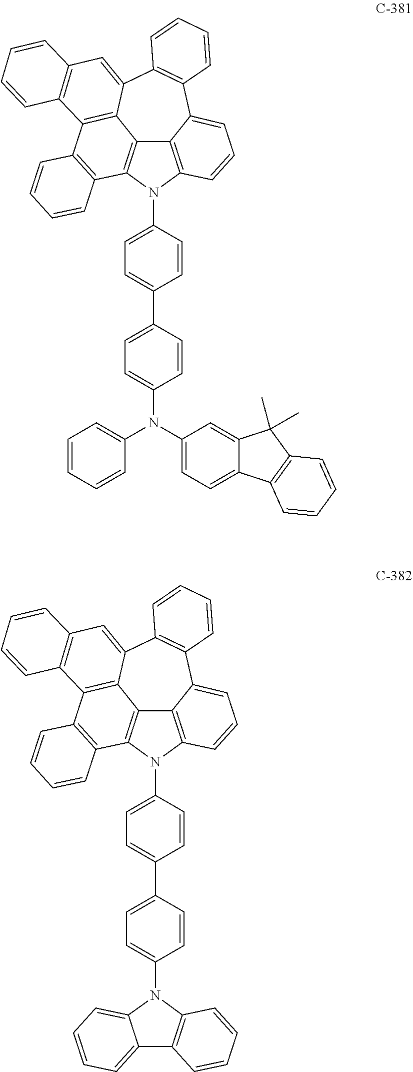 [SMILES: CC1(C)c2ccccc2-c2ccc(N(c3ccccc3)c3ccc(-c4ccc(-n5c6cccc7c6c6c8c(cc9ccccc9c8c8ccccc8c65)-c5ccccc5-7)cc4)cc3)cc21 ; c1ccc2c(c1)-c1cc3ccccc3c3c4ccccc4c4c(c13)c1c-2cccc1n4-c1ccc(-c2ccc(-n3c4ccccc4c4ccccc43)cc2)cc1]

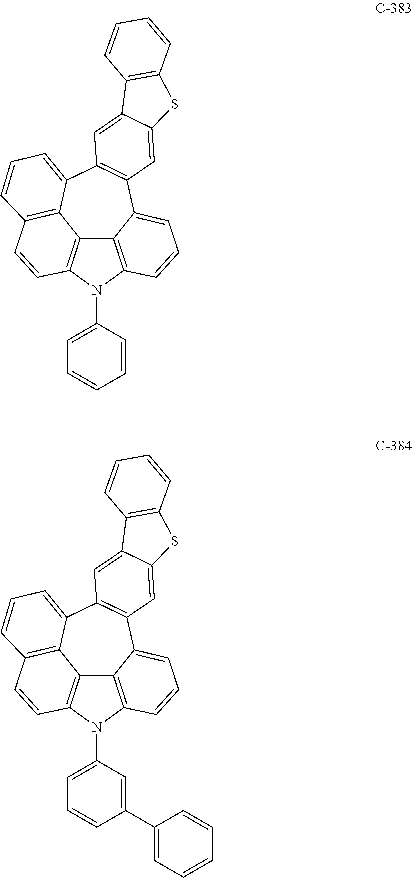 [SMILES: c1ccc(-n2c3cccc4c3c3c5c(cccc5ccc32)-c2cc3c(cc2-4)sc2ccccc23)cc1 ; c1ccc(-c2cccc(-n3c4cccc5c4c4c6c(cccc6ccc43)-c3cc4c(cc3-5)sc3ccccc34)c2)cc1]

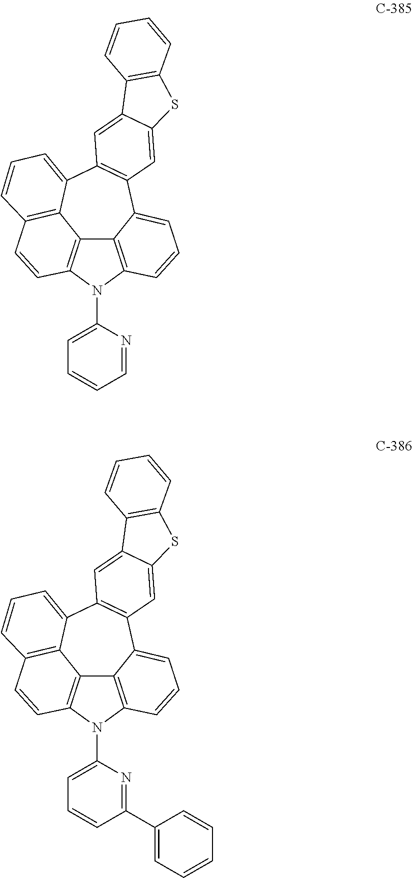 [SMILES: c1ccc(-n2c3cccc4c3c3c5c(cccc5ccc32)-c2cc3c(cc2-4)sc2ccccc23)nc1 ; c1ccc(-c2cccc(-n3c4cccc5c4c4c6c(cccc6ccc43)-c3cc4c(cc3-5)sc3ccccc34)n2)cc1]

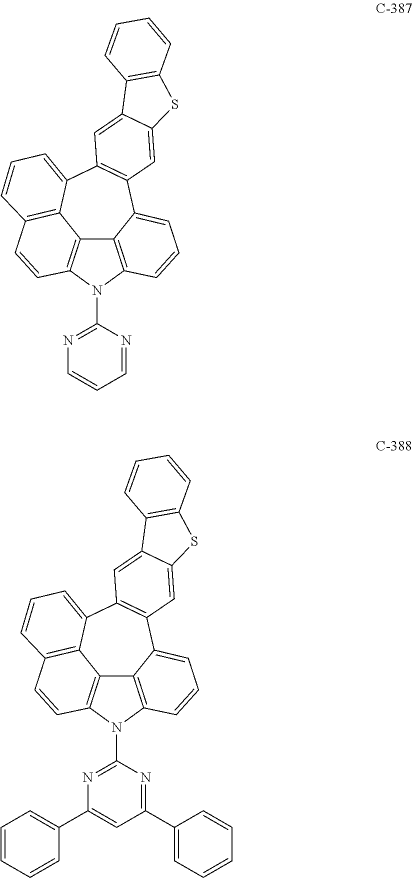 [SMILES: c1cnc(-n2c3cccc4c3c3c5c(cccc5ccc32)-c2cc3c(cc2-4)sc2ccccc23)nc1 ; c1ccc(-c2cc(-c3ccccc3)nc(-n3c4cccc5c4c4c6c(cccc6ccc43)-c3cc4c(cc3-5)sc3ccccc34)n2)cc1]

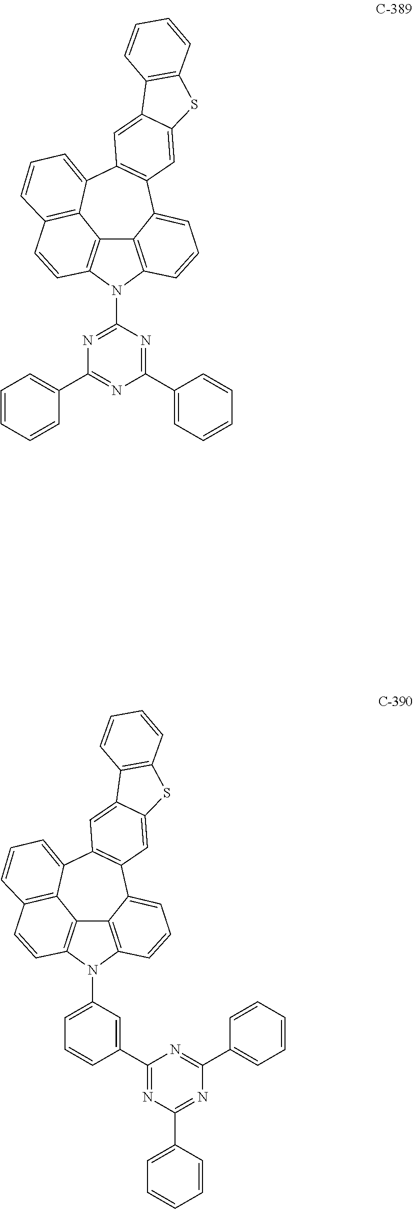 [SMILES: c1ccc(-c2nc(-c3ccccc3)nc(-n3c4cccc5c4c4c6c(cccc6ccc43)-c3cc4c(cc3-5)sc3ccccc34)n2)cc1 ; c1ccc(-c2nc(-c3ccccc3)nc(-c3cccc(-n4c5cccc6c5c5c7c(cccc7ccc54)-c4cc5c(cc4-6)sc4ccccc45)c3)n2)cc1]

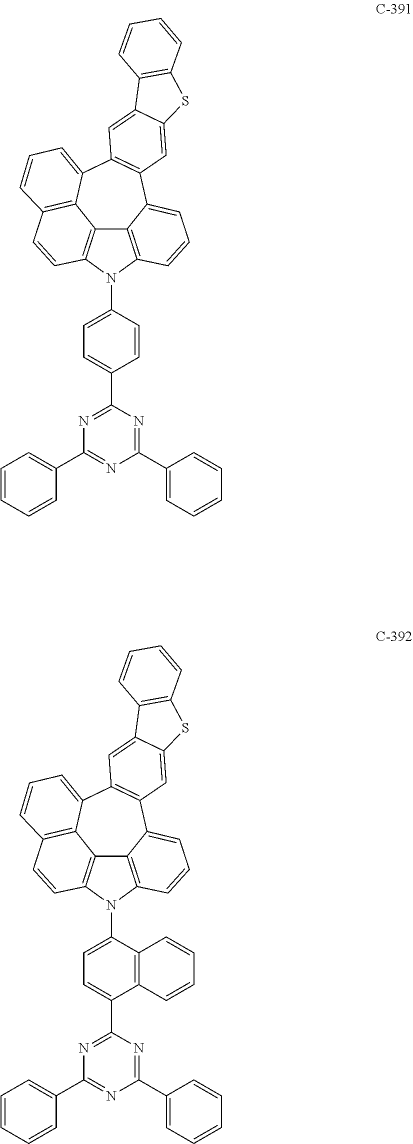 [SMILES: c1ccc(-c2nc(-c3ccccc3)nc(-c3ccc(-n4c5cccc6c5c5c7c(cccc7ccc54)-c4cc5c(cc4-6)sc4ccccc45)cc3)n2)cc1 ; c1ccc(-c2nc(-c3ccccc3)nc(-c3ccc(-n4c5cccc6c5c5c7c(cccc7ccc54)-c4cc5c(cc4-6)sc4ccccc45)c4ccccc34)n2)cc1]

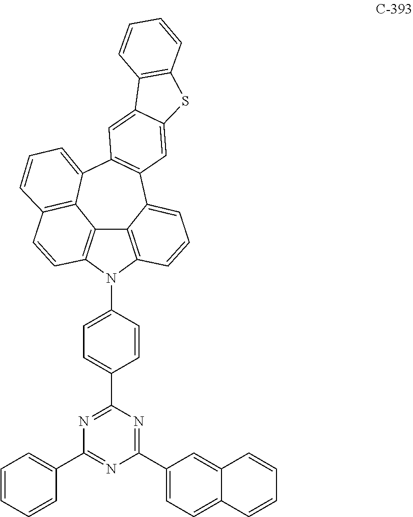 [SMILES: c1ccc(-c2nc(-c3ccc(-n4c5cccc6c5c5c7c(cccc7ccc54)-c4cc5c(cc4-6)sc4ccccc45)cc3)nc(-c3ccc4ccccc4c3)n2)cc1]

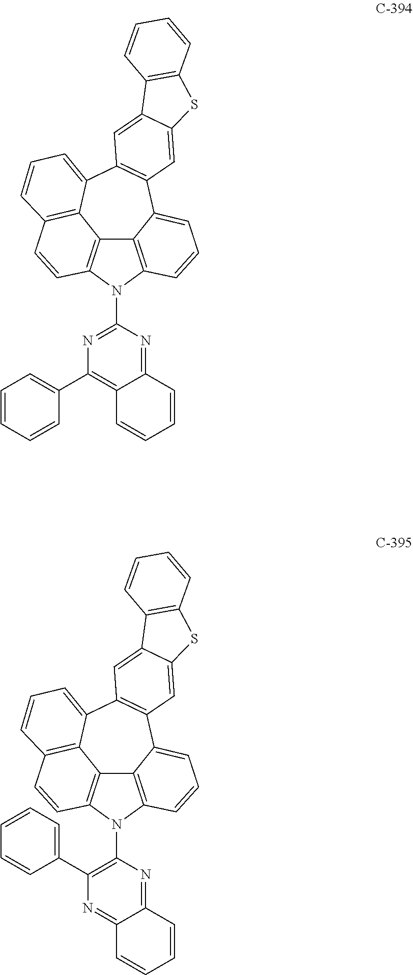 [SMILES: c1ccc(-c2nc(-n3c4cccc5c4c4c6c(cccc6ccc43)-c3cc4c(cc3-5)sc3ccccc34)nc3ccccc23)cc1 ; c1ccc(-c2nc3ccccc3nc2-n2c3cccc4c3c3c5c(cccc5ccc32)-c2cc3c(cc2-4)sc2ccccc23)cc1]

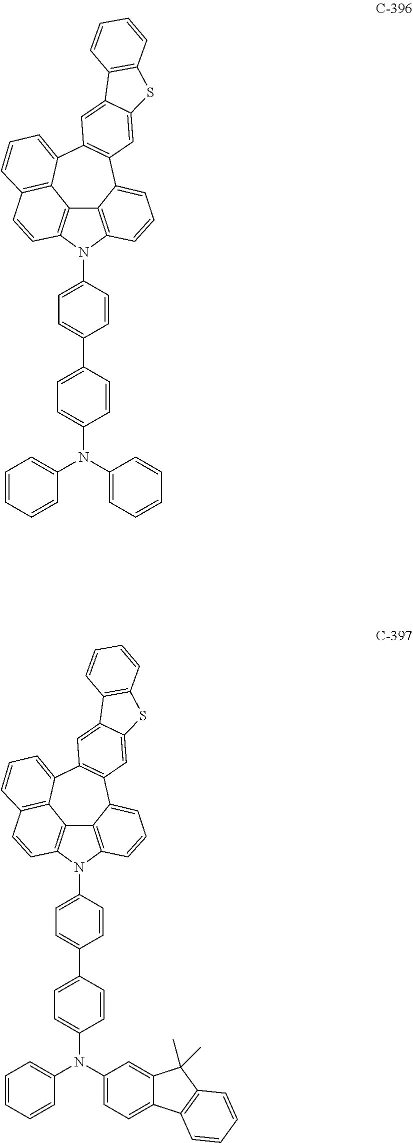 [SMILES: c1ccc(N(c2ccccc2)c2ccc(-c3ccc(-n4c5cccc6c5c5c7c(cccc7ccc54)-c4cc5c(cc4-6)sc4ccccc45)cc3)cc2)cc1 ; CC1(C)c2ccccc2-c2ccc(N(c3ccccc3)c3ccc(-c4ccc(-n5c6cccc7c6c6c8c(cccc8ccc65)-c5cc6c(cc5-7)sc5ccccc56)cc4)cc3)cc21]

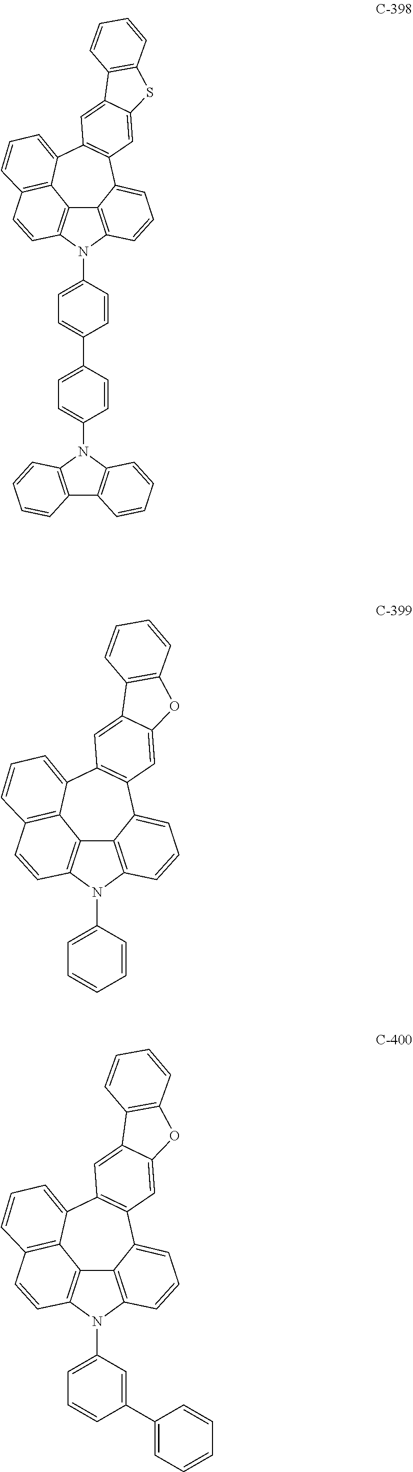 [SMILES: c1cc2c3c(c1)ccc1c3c3c(cccc3n1-c1ccc(-c3ccc(-n4c5ccccc5c5ccccc54)cc3)cc1)-c1cc3sc4ccccc4c3cc1-2 ; c1ccc(-n2c3cccc4c3c3c5c(cccc5ccc32)-c2cc3c(cc2-4)oc2ccccc23)cc1 ; c1ccc(-c2cccc(-n3c4cccc5c4c4c6c(cccc6ccc43)-c3cc4c(cc3-5)oc3ccccc34)c2)cc1]

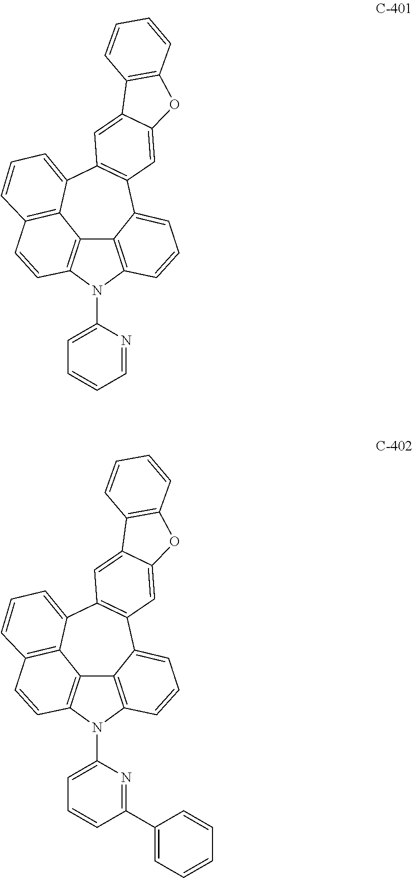 [SMILES: c1ccc(-n2c3cccc4c3c3c5c(cccc5ccc32)-c2cc3c(cc2-4)oc2ccccc23)nc1 ; c1ccc(-c2cccc(-n3c4cccc5c4c4c6c(cccc6ccc43)-c3cc4c(cc3-5)oc3ccccc34)n2)cc1]

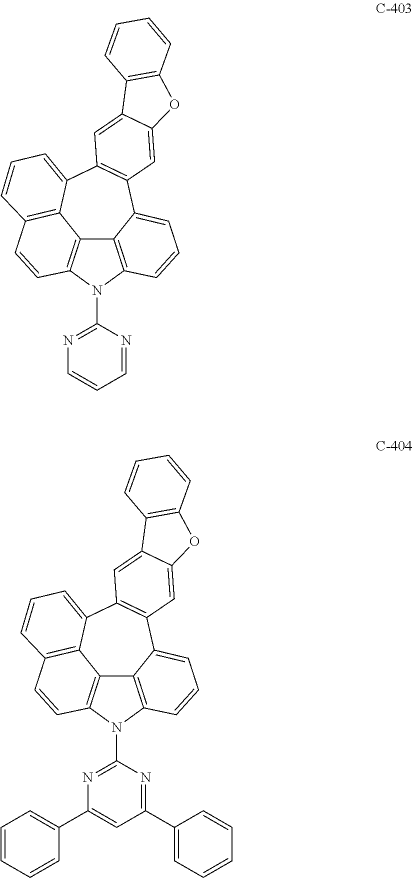 [SMILES: c1cnc(-n2c3cccc4c3c3c5c(cccc5ccc32)-c2cc3c(cc2-4)oc2ccccc23)nc1 ; c1ccc(-c2cc(-c3ccccc3)nc(-n3c4cccc5c4c4c6c(cccc6ccc43)-c3cc4c(cc3-5)oc3ccccc34)n2)cc1]

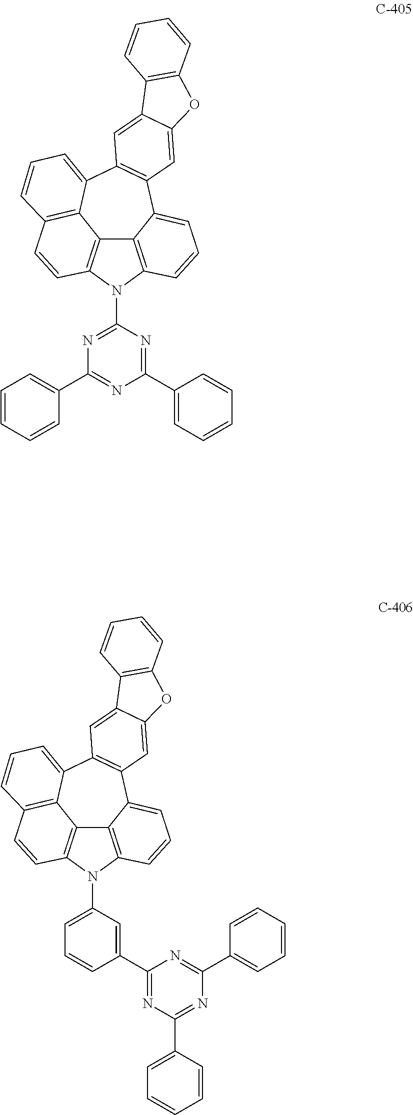 [SMILES: c1ccc(-c2nc(-c3ccccc3)nc(-n3c4cccc5c4c4c6c(cccc6ccc43)-c3cc4c(cc3-5)oc3ccccc34)n2)cc1 ; c1ccc(-c2nc(-c3ccccc3)nc(-c3cccc(-n4c5cccc6c5c5c7c(cccc7ccc54)-c4cc5c(cc4-6)oc4ccccc45)c3)n2)cc1]

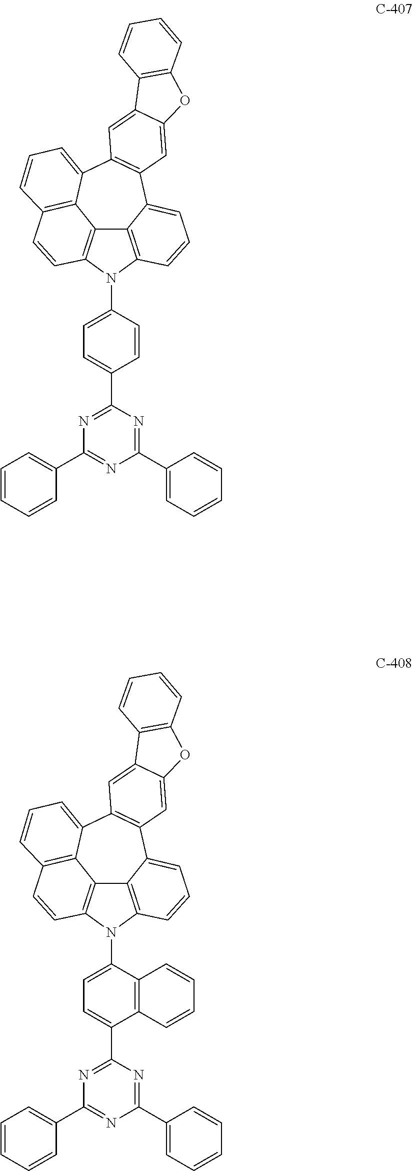 [SMILES: c1ccc(-c2nc(-c3ccccc3)nc(-c3ccc(-n4c5cccc6c5c5c7c(cccc7ccc54)-c4cc5c(cc4-6)oc4ccccc45)cc3)n2)cc1 ; c1ccc(-c2nc(-c3ccccc3)nc(-c3ccc(-n4c5cccc6c5c5c7c(cccc7ccc54)-c4cc5c(cc4-6)oc4ccccc45)c4ccccc34)n2)cc1]

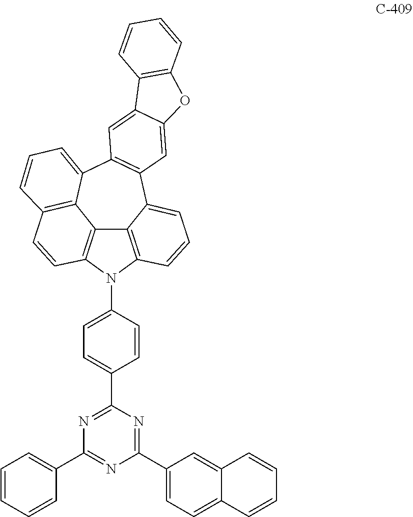 [SMILES: c1ccc(-c2nc(-c3ccc(-n4c5cccc6c5c5c7c(cccc7ccc54)-c4cc5c(cc4-6)oc4ccccc45)cc3)nc(-c3ccc4ccccc4c3)n2)cc1]

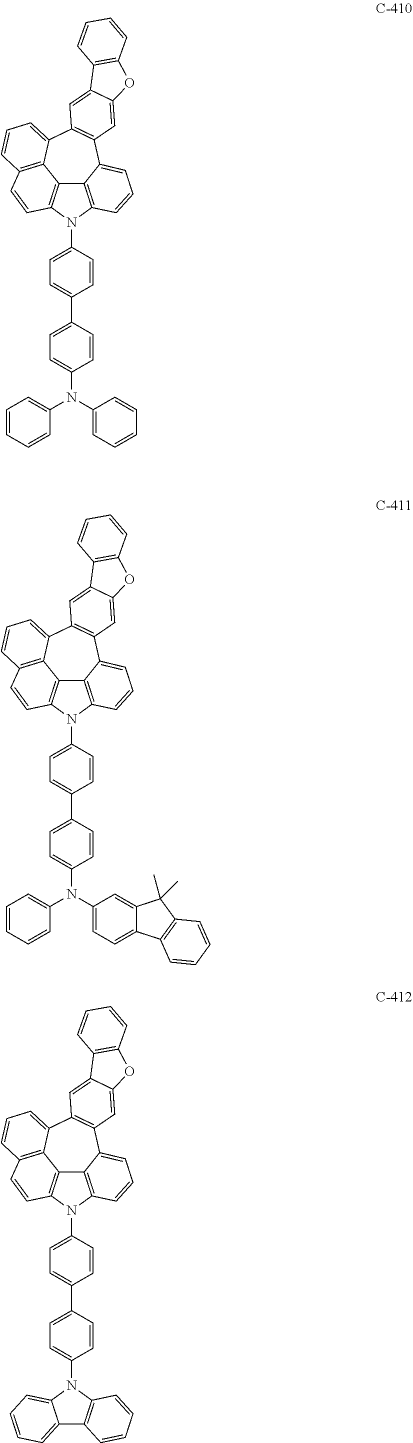 [SMILES: c1ccc(N(c2ccccc2)c2ccc(-c3ccc(-n4c5cccc6c5c5c7c(cccc7ccc54)-c4cc5c(cc4-6)oc4ccccc45)cc3)cc2)cc1 ; CC1(C)c2ccccc2-c2ccc(N(c3ccccc3)c3ccc(-c4ccc(-n5c6cccc7c6c6c8c(cccc8ccc65)-c5cc6c(cc5-7)oc5ccccc56)cc4)cc3)cc21 ; c1cc2c3c(c1)ccc1c3c3c(cccc3n1-c1ccc(-c3ccc(-n4c5ccccc5c5ccccc54)cc3)cc1)-c1cc3oc4ccccc4c3cc1-2]

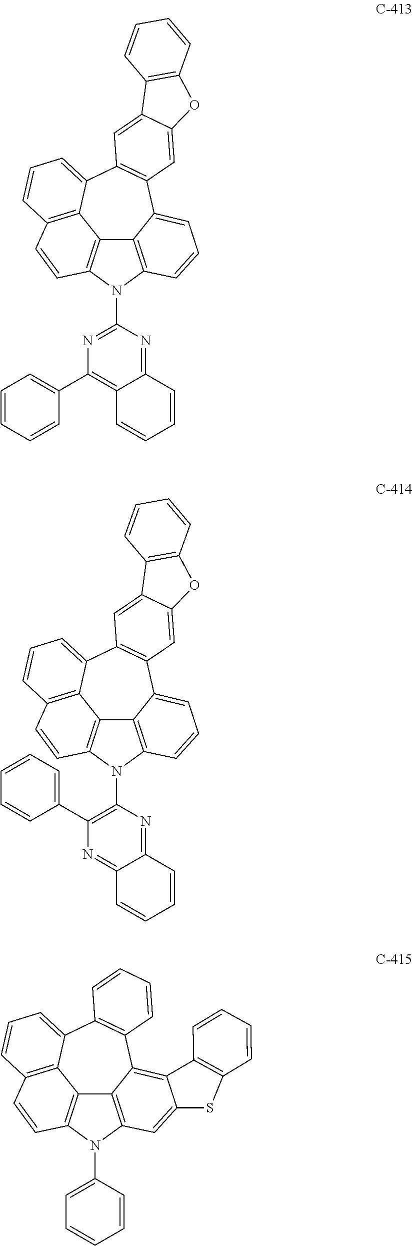 [SMILES: c1ccc(-c2nc(-n3c4cccc5c4c4c6c(cccc6ccc43)-c3cc4c(cc3-5)oc3ccccc34)nc3ccccc23)cc1 ; c1ccc(-c2nc3ccccc3nc2-n2c3cccc4c3c3c5c(cccc5ccc32)-c2cc3c(cc2-4)oc2ccccc23)cc1 ; c1ccc(-n2c3cc4sc5ccccc5c4c4c3c3c5c(cccc5ccc32)-c2ccccc2-4)cc1]

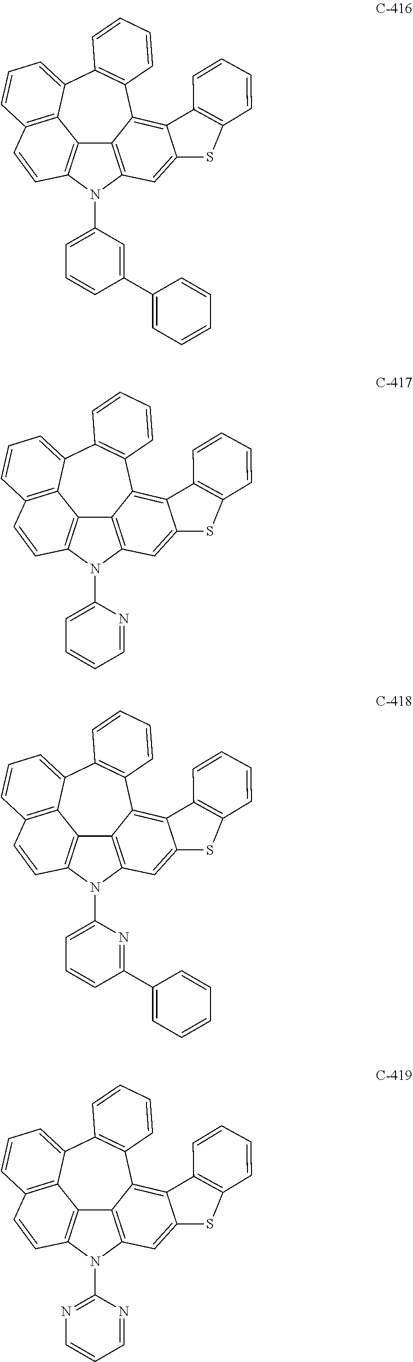 [SMILES: c1ccc(-c2cccc(-n3c4cc5sc6ccccc6c5c5c4c4c6c(cccc6ccc43)-c3ccccc3-5)c2)cc1 ; c1ccc(-n2c3cc4sc5ccccc5c4c4c3c3c5c(cccc5ccc32)-c2ccccc2-4)nc1 ; c1ccc(-c2cccc(-n3c4cc5sc6ccccc6c5c5c4c4c6c(cccc6ccc43)-c3ccccc3-5)n2)cc1 ; c1cnc(-n2c3cc4sc5ccccc5c4c4c3c3c5c(cccc5ccc32)-c2ccccc2-4)nc1]

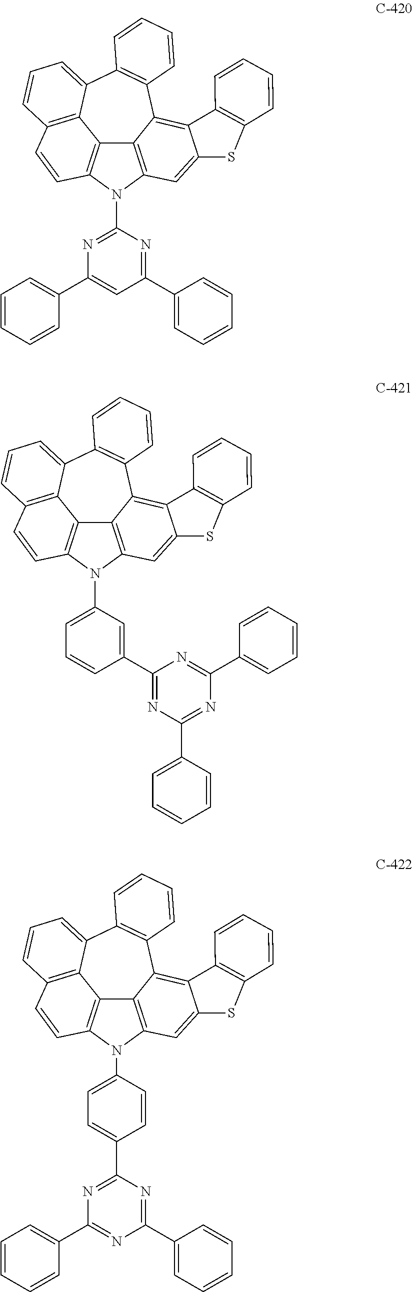 [SMILES: c1ccc(-c2cc(-c3ccccc3)nc(-n3c4cc5sc6ccccc6c5c5c4c4c6c(cccc6ccc43)-c3ccccc3-5)n2)cc1 ; c1ccc(-c2nc(-c3ccccc3)nc(-c3cccc(-n4c5cc6sc7ccccc7c6c6c5c5c7c(cccc7ccc54)-c4ccccc4-6)c3)n2)cc1 ; c1ccc(-c2nc(-c3ccccc3)nc(-c3ccc(-n4c5cc6sc7ccccc7c6c6c5c5c7c(cccc7ccc54)-c4ccccc4-6)cc3)n2)cc1]

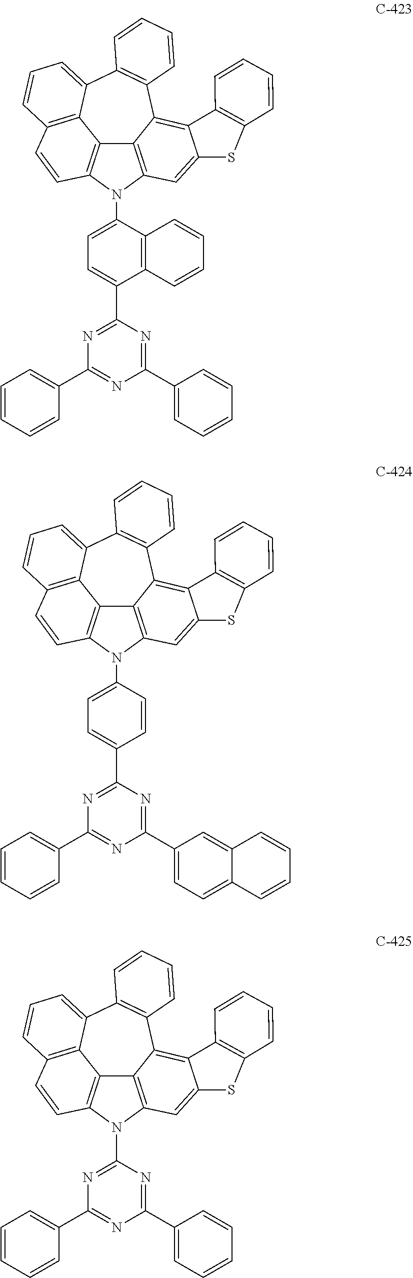 [SMILES: c1ccc(-c2nc(-c3ccccc3)nc(-c3ccc(-n4c5cc6sc7ccccc7c6c6c5c5c7c(cccc7ccc54)-c4ccccc4-6)c4ccccc34)n2)cc1 ; c1ccc(-c2nc(-c3ccc(-n4c5cc6sc7ccccc7c6c6c5c5c7c(cccc7ccc54)-c4ccccc4-6)cc3)nc(-c3ccc4ccccc4c3)n2)cc1 ; c1ccc(-c2nc(-c3ccccc3)nc(-n3c4cc5sc6ccccc6c5c5c4c4c6c(cccc6ccc43)-c3ccccc3-5)n2)cc1]

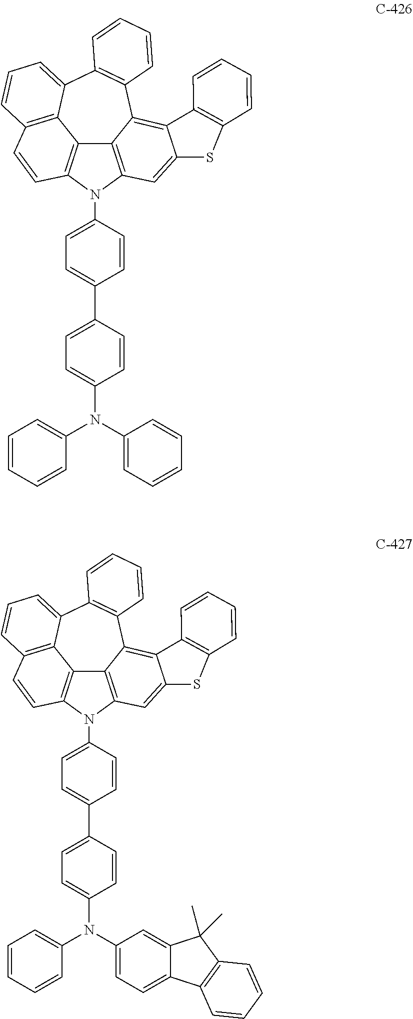 [SMILES: c1ccc(N(c2ccccc2)c2ccc(-c3ccc(-n4c5cc6sc7ccccc7c6c6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cc7sc8ccccc8c7c7c6c6c8c(cccc8ccc65)-c5ccccc5-7)cc4)cc3)cc21]

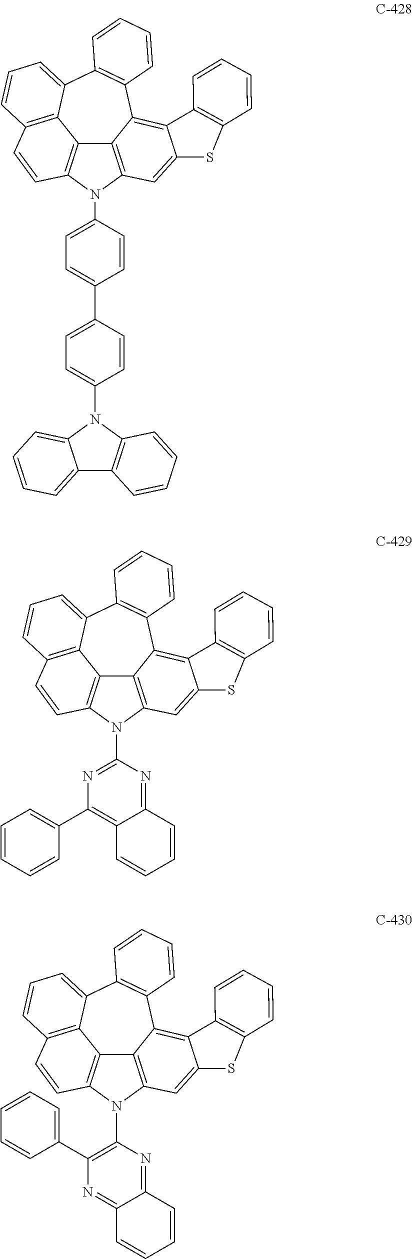 [SMILES: c1ccc2c(c1)-c1cccc3ccc4c(c13)c1c-2c2c(cc1n4-c1ccc(-c3ccc(-n4c5ccccc5c5ccccc54)cc3)cc1)sc1ccccc12 ; c1ccc(-c2nc(-n3c4cc5sc6ccccc6c5c5c4c4c6c(cccc6ccc43)-c3ccccc3-5)nc3ccccc23)cc1 ; c1ccc(-c2nc3ccccc3nc2-n2c3cc4sc5ccccc5c4c4c3c3c5c(cccc5ccc32)-c2ccccc2-4)cc1]

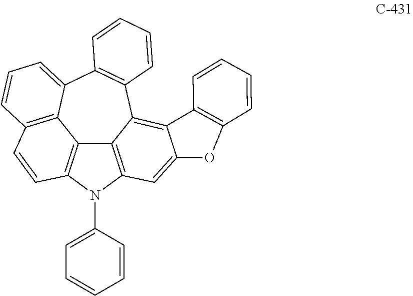 [SMILES: c1ccc(-n2c3cc4oc5ccccc5c4c4c3c3c5c(cccc5ccc32)-c2ccccc2-4)cc1]

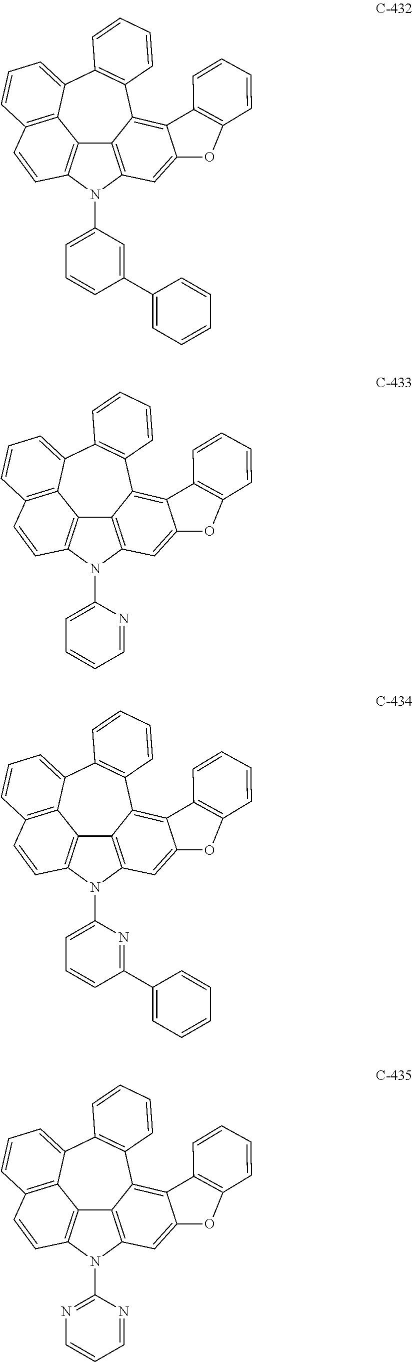 [SMILES: c1ccc(-c2cccc(-n3c4cc5oc6ccccc6c5c5c4c4c6c(cccc6ccc43)-c3ccccc3-5)c2)cc1 ; c1ccc(-n2c3cc4oc5ccccc5c4c4c3c3c5c(cccc5ccc32)-c2ccccc2-4)nc1 ; c1ccc(-c2cccc(-n3c4cc5oc6ccccc6c5c5c4c4c6c(cccc6ccc43)-c3ccccc3-5)n2)cc1 ; c1cnc(-n2c3cc4oc5ccccc5c4c4c3c3c5c(cccc5ccc32)-c2ccccc2-4)nc1]

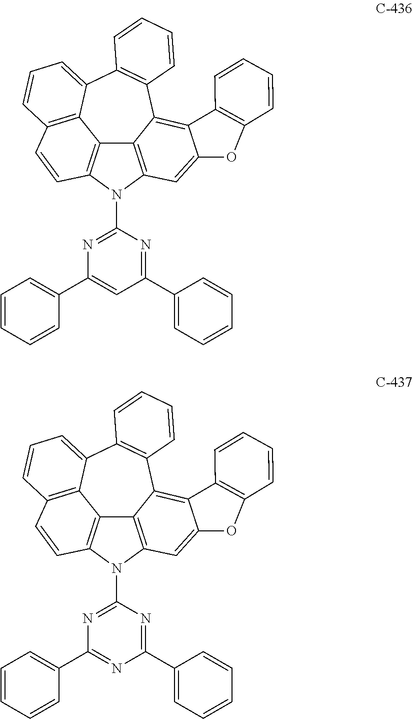 [SMILES: c1ccc(-c2cc(-c3ccccc3)nc(-n3c4cc5oc6ccccc6c5c5c4c4c6c(cccc6ccc43)-c3ccccc3-5)n2)cc1 ; c1ccc(-c2nc(-c3ccccc3)nc(-n3c4cc5oc6ccccc6c5c5c4c4c6c(cccc6ccc43)-c3ccccc3-5)n2)cc1]

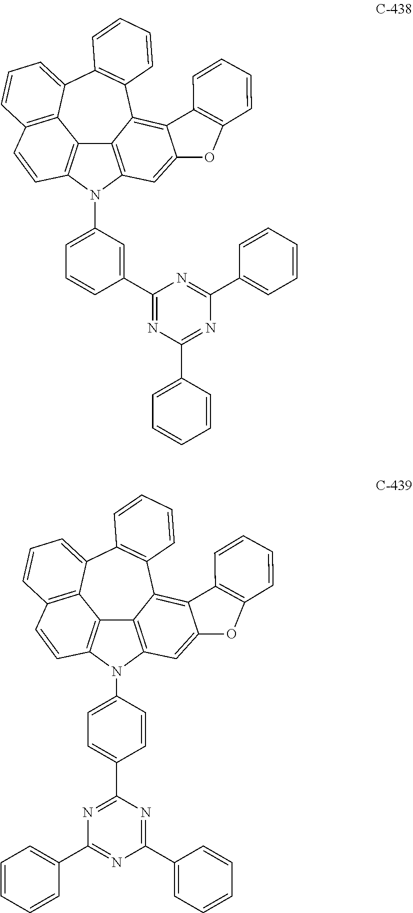 [SMILES: c1ccc(-c2nc(-c3ccccc3)nc(-c3cccc(-n4c5cc6oc7ccccc7c6c6c5c5c7c(cccc7ccc54)-c4ccccc4-6)c3)n2)cc1 ; c1ccc(-c2nc(-c3ccccc3)nc(-c3ccc(-n4c5cc6oc7ccccc7c6c6c5c5c7c(cccc7ccc54)-c4ccccc4-6)cc3)n2)cc1]

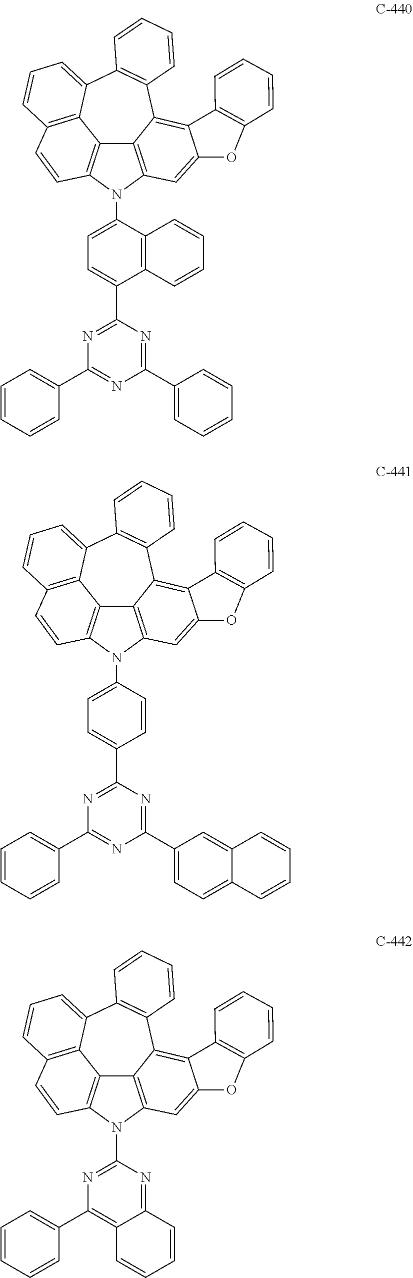 [SMILES: c1ccc(-c2nc(-c3ccccc3)nc(-c3ccc(-n4c5cc6oc7ccccc7c6c6c5c5c7c(cccc7ccc54)-c4ccccc4-6)c4ccccc34)n2)cc1 ; c1ccc(-c2nc(-c3ccc(-n4c5cc6oc7ccccc7c6c6c5c5c7c(cccc7ccc54)-c4ccccc4-6)cc3)nc(-c3ccc4ccccc4c3)n2)cc1 ; c1ccc(-c2nc(-n3c4cc5oc6ccccc6c5c5c4c4c6c(cccc6ccc43)-c3ccccc3-5)nc3ccccc23)cc1]

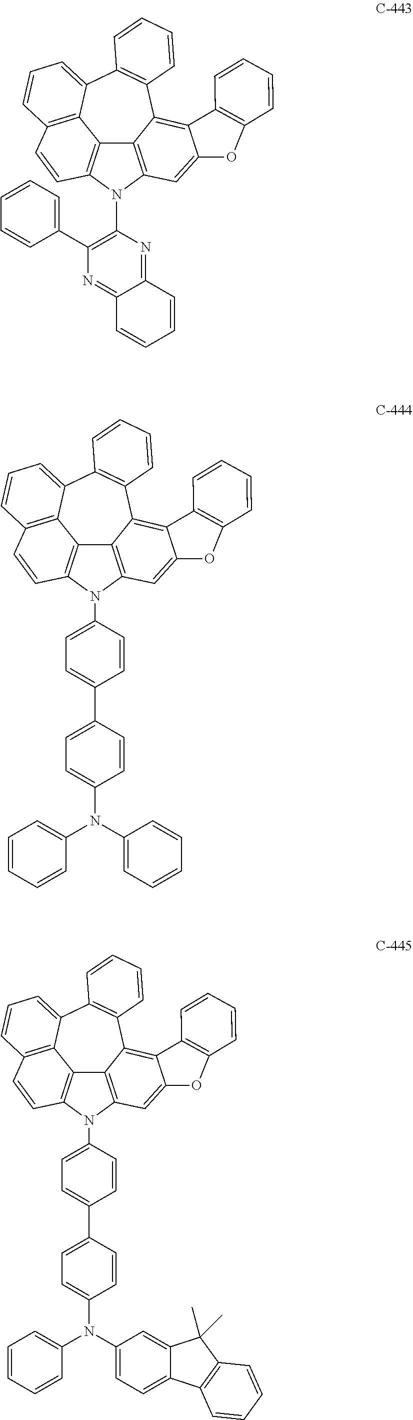 [SMILES: c1ccc(-c2nc3ccccc3nc2-n2c3cc4oc5ccccc5c4c4c3c3c5c(cccc5ccc32)-c2ccccc2-4)cc1 ; c1ccc(N(c2ccccc2)c2ccc(-c3ccc(-n4c5cc6oc7ccccc7c6c6c5c5c7c(cccc7ccc54)-c4ccccc4-6)cc3)cc2)cc1 ; CC1(C)c2ccccc2-c2ccc(N(c3ccccc3)c3ccc(-c4ccc(-n5c6cc7oc8ccccc8c7c7c6c6c8c(cccc8ccc65)-c5ccccc5-7)cc4)cc3)cc21]

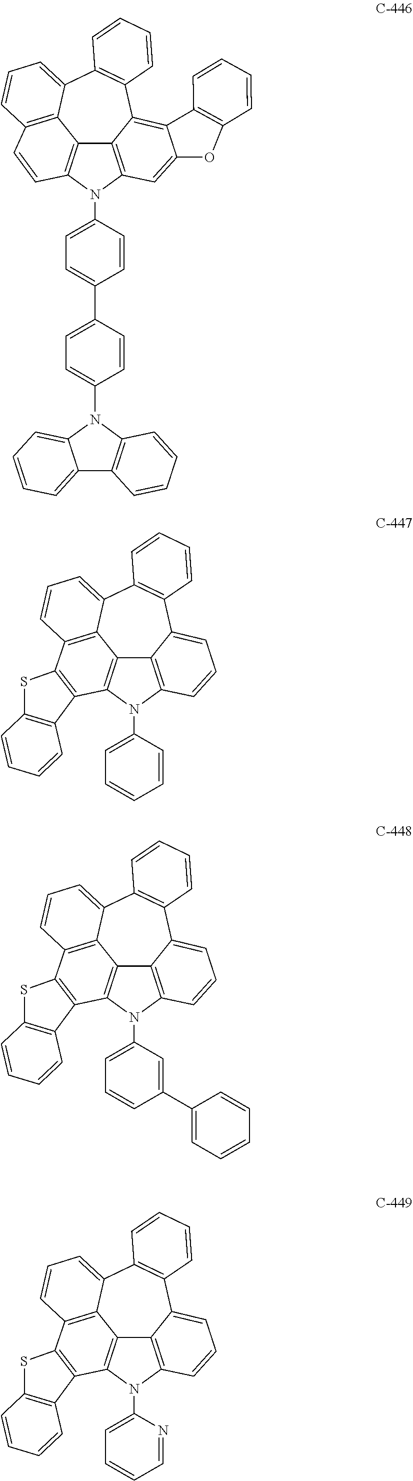

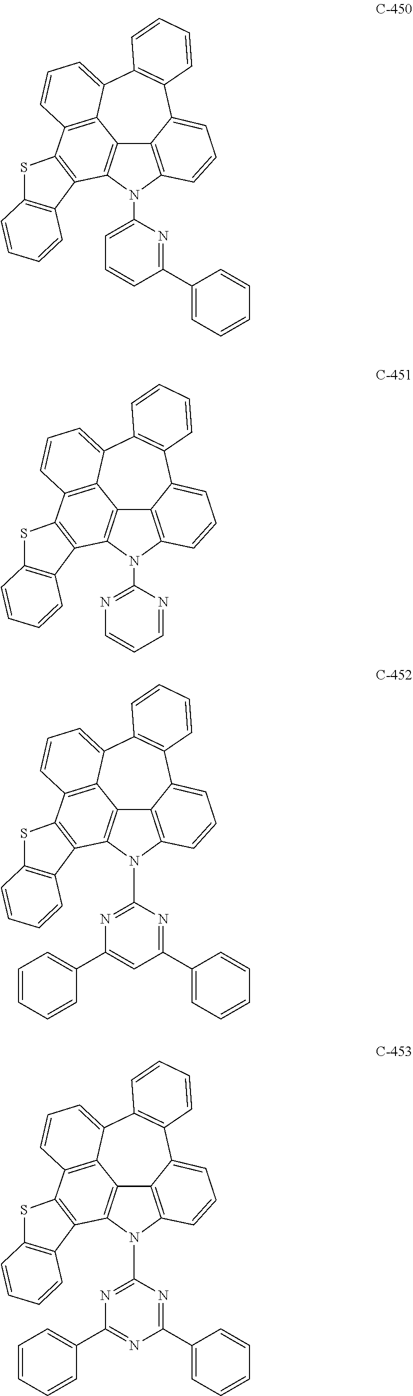

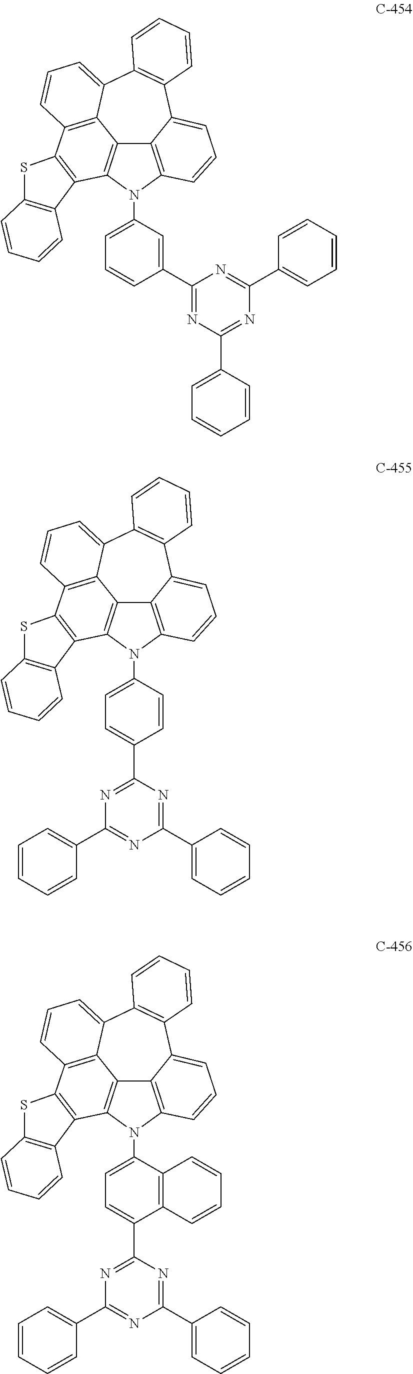 [SMILES: c1ccc(-c2nc(-c3ccccc3)nc(-c3cccc(-n4c5cccc6c5c5c7c(cccc7c7sc8ccccc8c7c54)-c4ccccc4-6)c3)n2)cc1 ; c1ccc(-c2nc(-c3ccccc3)nc(-c3ccc(-n4c5cccc6c5c5c7c(cccc7c7sc8ccccc8c7c54)-c4ccccc4-6)cc3)n2)cc1 ; c1ccc(-c2nc(-c3ccccc3)nc(-c3ccc(-n4c5cccc6c5c5c7c(cccc7c7sc8ccccc8c7c54)-c4ccccc4-6)c4ccccc34)n2)cc1]

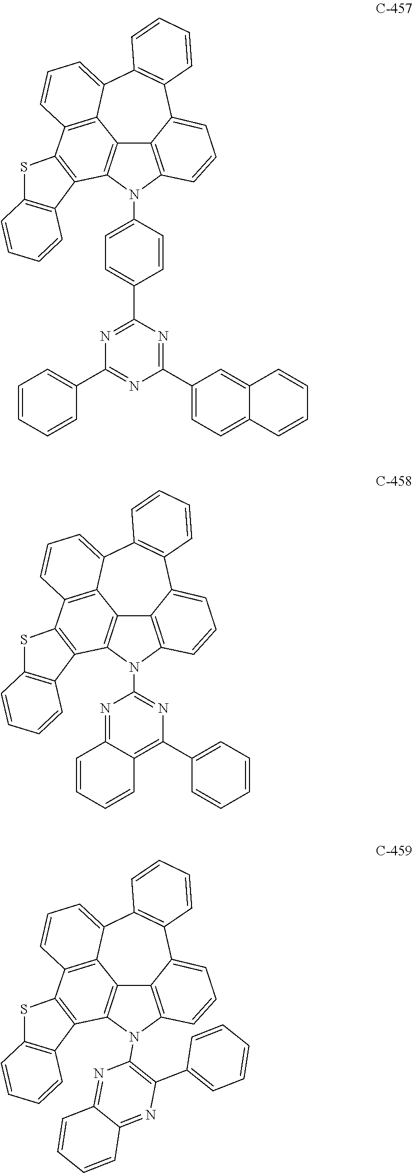 [SMILES: c1ccc(-c2nc(-c3ccc(-n4c5cccc6c5c5c7c(cccc7c7sc8ccccc8c7c54)-c4ccccc4-6)cc3)nc(-c3ccc4ccccc4c3)n2)cc1 ; c1ccc(-c2nc(-n3c4cccc5c4c4c6c(cccc6c6sc7ccccc7c6c43)-c3ccccc3-5)nc3ccccc23)cc1 ; c1ccc(-c2nc3ccccc3nc2-n2c3cccc4c3c3c5c(cccc5c5sc6ccccc6c5c32)-c2ccccc2-4)cc1]

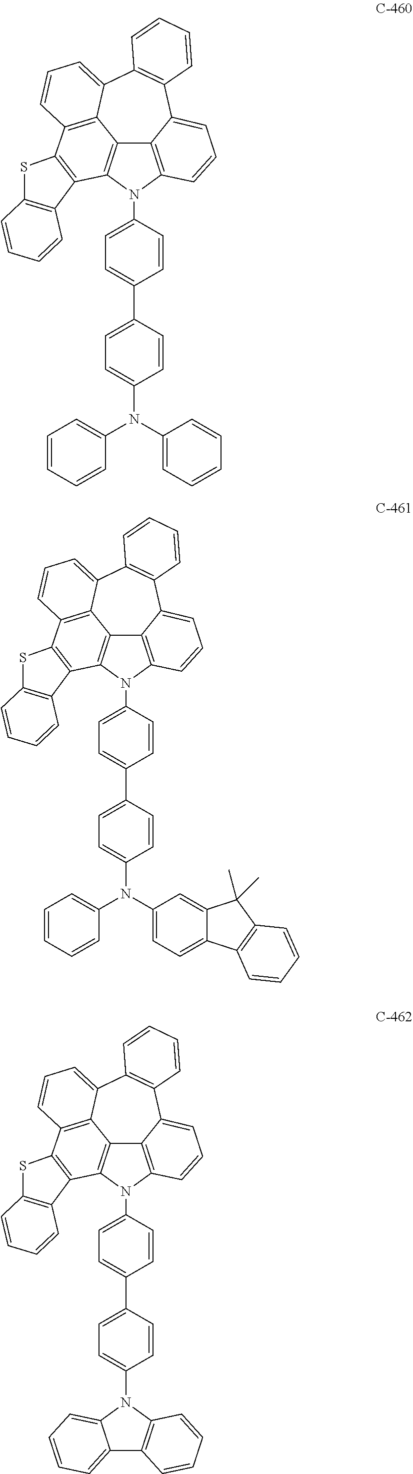 [SMILES: c1ccc(N(c2ccccc2)c2ccc(-c3ccc(-n4c5cccc6c5c5c7c(cccc7c7sc8ccccc8c7c54)-c4ccccc4-6)cc3)cc2)cc1 ; CC1(C)c2ccccc2-c2ccc(N(c3ccccc3)c3ccc(-c4ccc(-n5c6cccc7c6c6c8c(cccc8c8sc9ccccc9c8c65)-c5ccccc5-7)cc4)cc3)cc21 ; c1ccc2c(c1)-c1cccc3c4sc5ccccc5c4c4c(c13)c1c-2cccc1n4-c1ccc(-c2ccc(-n3c4ccccc4c4ccccc43)cc2)cc1]

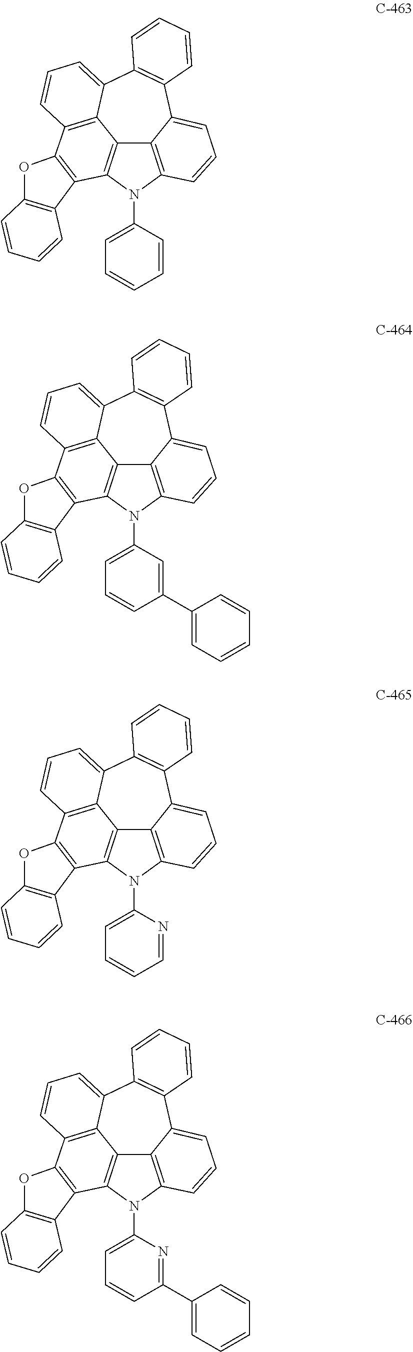 [SMILES: c1ccc(-n2c3cccc4c3c3c5c(cccc5c5oc6ccccc6c5c32)-c2ccccc2-4)cc1 ; c1ccc(-c2cccc(-n3c4cccc5c4c4c6c(cccc6c6oc7ccccc7c6c43)-c3ccccc3-5)c2)cc1 ; c1ccc(-n2c3cccc4c3c3c5c(cccc5c5oc6ccccc6c5c32)-c2ccccc2-4)nc1 ; c1ccc(-c2cccc(-n3c4cccc5c4c4c6c(cccc6c6oc7ccccc7c6c43)-c3ccccc3-5)n2)cc1]

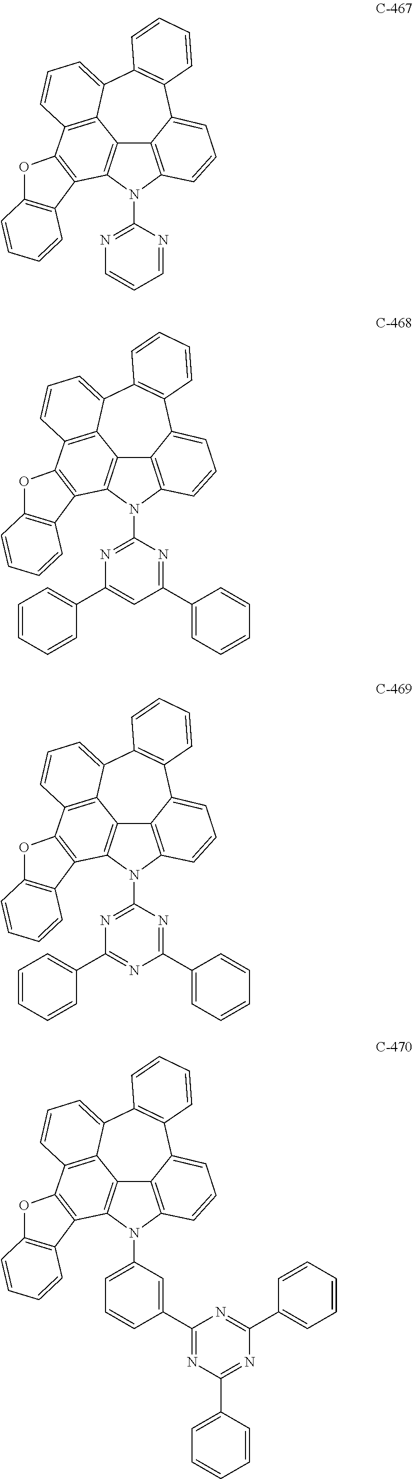 [SMILES: c1cnc(-n2c3cccc4c3c3c5c(cccc5c5oc6ccccc6c5c32)-c2ccccc2-4)nc1 ; c1ccc(-c2cc(-c3ccccc3)nc(-n3c4cccc5c4c4c6c(cccc6c6oc7ccccc7c6c43)-c3ccccc3-5)n2)cc1 ; c1ccc(-c2nc(-c3ccccc3)nc(-n3c4cccc5c4c4c6c(cccc6c6oc7ccccc7c6c43)-c3ccccc3-5)n2)cc1 ; c1ccc(-c2nc(-c3ccccc3)nc(-c3cccc(-n4c5cccc6c5c5c7c(cccc7c7oc8ccccc8c7c54)-c4ccccc4-6)c3)n2)cc1]

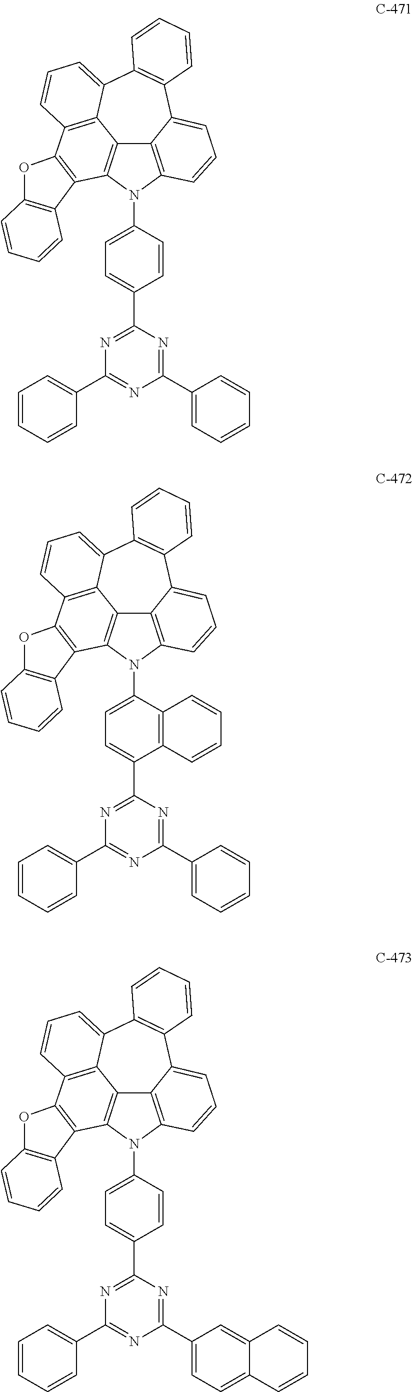 [SMILES: c1ccc(-c2nc(-c3ccccc3)nc(-c3ccc(-n4c5cccc6c5c5c7c(cccc7c7oc8ccccc8c7c54)-c4ccccc4-6)cc3)n2)cc1 ; c1ccc(-c2nc(-c3ccccc3)nc(-c3ccc(-n4c5cccc6c5c5c7c(cccc7c7oc8ccccc8c7c54)-c4ccccc4-6)c4ccccc34)n2)cc1 ; c1ccc(-c2nc(-c3ccc(-n4c5cccc6c5c5c7c(cccc7c7oc8ccccc8c7c54)-c4ccccc4-6)cc3)nc(-c3ccc4ccccc4c3)n2)cc1]

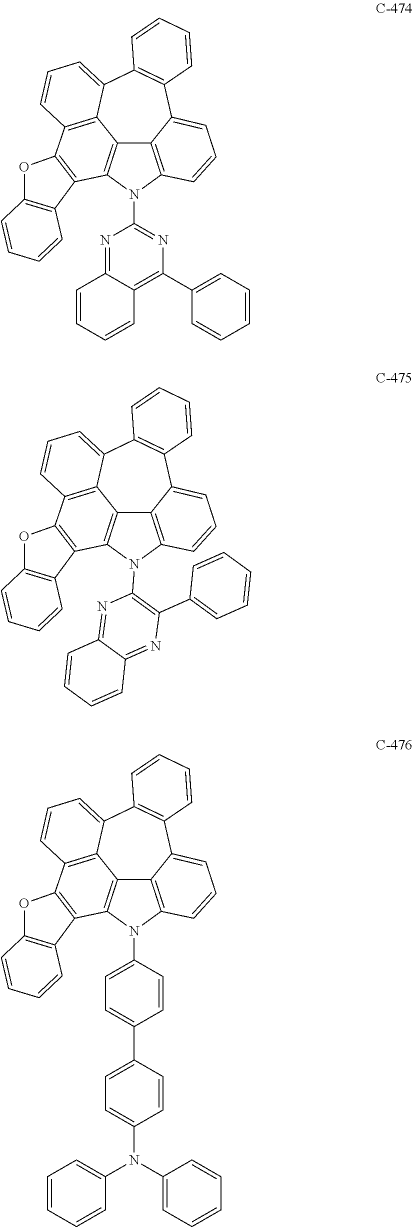 [SMILES: c1ccc(-c2nc(-n3c4cccc5c4c4c6c(cccc6c6oc7ccccc7c6c43)-c3ccccc3-5)nc3ccccc23)cc1 ; c1ccc(-c2nc3ccccc3nc2-n2c3cccc4c3c3c5c(cccc5c5oc6ccccc6c5c32)-c2ccccc2-4)cc1 ; c1ccc(N(c2ccccc2)c2ccc(-c3ccc(-n4c5cccc6c5c5c7c(cccc7c7oc8ccccc8c7c54)-c4ccccc4-6)cc3)cc2)cc1]

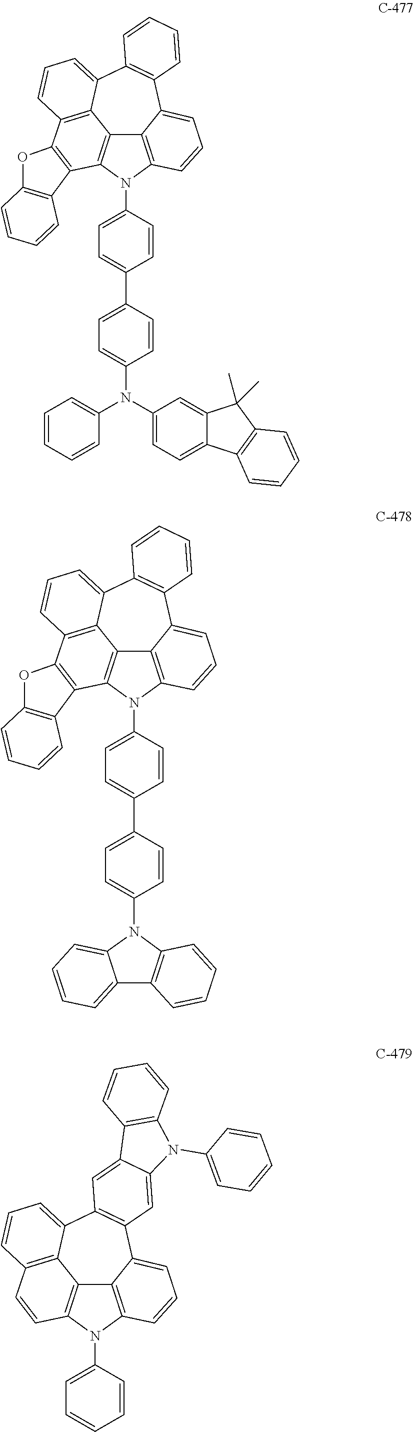 [SMILES: CC1(C)c2ccccc2-c2ccc(N(c3ccccc3)c3ccc(-c4ccc(-n5c6cccc7c6c6c8c(cccc8c8oc9ccccc9c8c65)-c5ccccc5-7)cc4)cc3)cc21 ; c1ccc2c(c1)-c1cccc3c4oc5ccccc5c4c4c(c13)c1c-2cccc1n4-c1ccc(-c2ccc(-n3c4ccccc4c4ccccc43)cc2)cc1 ; c1ccc(-n2c3ccccc3c3cc4c(cc32)-c2cccc3c2c2c5c-4cccc5ccc2n3-c2ccccc2)cc1]

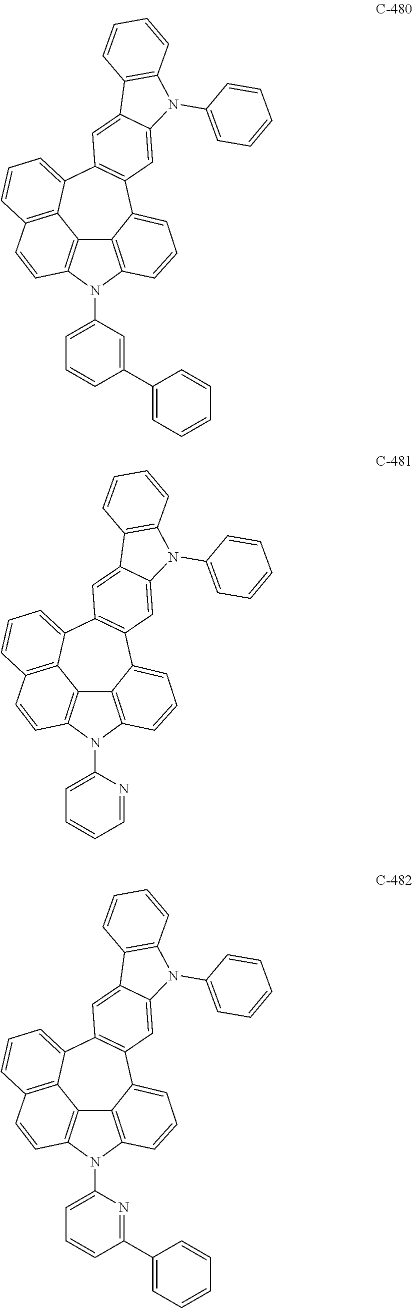 [SMILES: c1ccc(-c2cccc(-n3c4cccc5c4c4c6c(cccc6ccc43)-c3cc4c6ccccc6n(-c6ccccc6)c4cc3-5)c2)cc1 ; c1ccc(-n2c3ccccc3c3cc4c(cc32)-c2cccc3c2c2c5c-4cccc5ccc2n3-c2ccccn2)cc1 ; c1ccc(-c2cccc(-n3c4cccc5c4c4c6c(cccc6ccc43)-c3cc4c6ccccc6n(-c6ccccc6)c4cc3-5)n2)cc1]

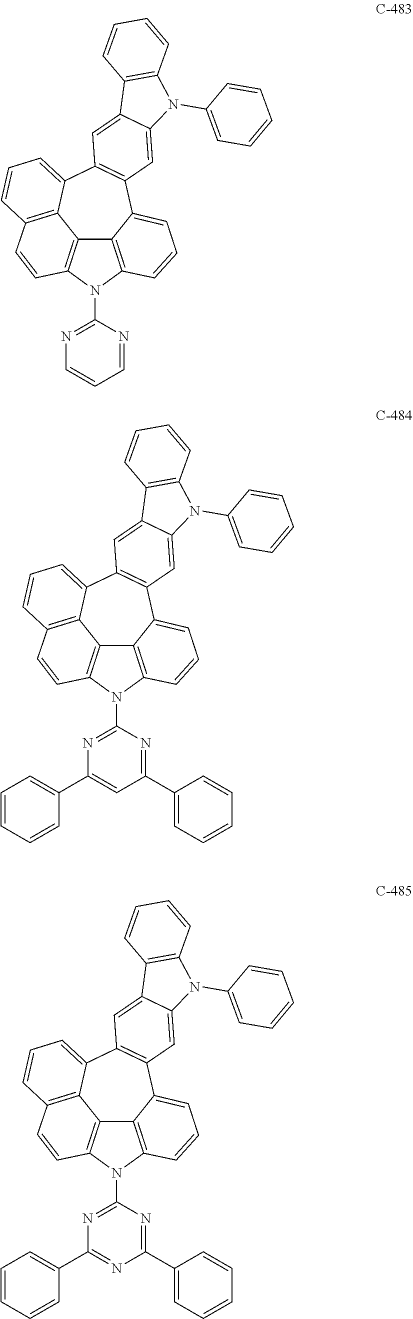 [SMILES: c1ccc(-n2c3ccccc3c3cc4c(cc32)-c2cccc3c2c2c5c-4cccc5ccc2n3-c2ncccn2)cc1 ; c1ccc(-c2cc(-c3ccccc3)nc(-n3c4cccc5c4c4c6c(cccc6ccc43)-c3cc4c6ccccc6n(-c6ccccc6)c4cc3-5)n2)cc1 ; c1ccc(-c2nc(-c3ccccc3)nc(-n3c4cccc5c4c4c6c(cccc6ccc43)-c3cc4c6ccccc6n(-c6ccccc6)c4cc3-5)n2)cc1]

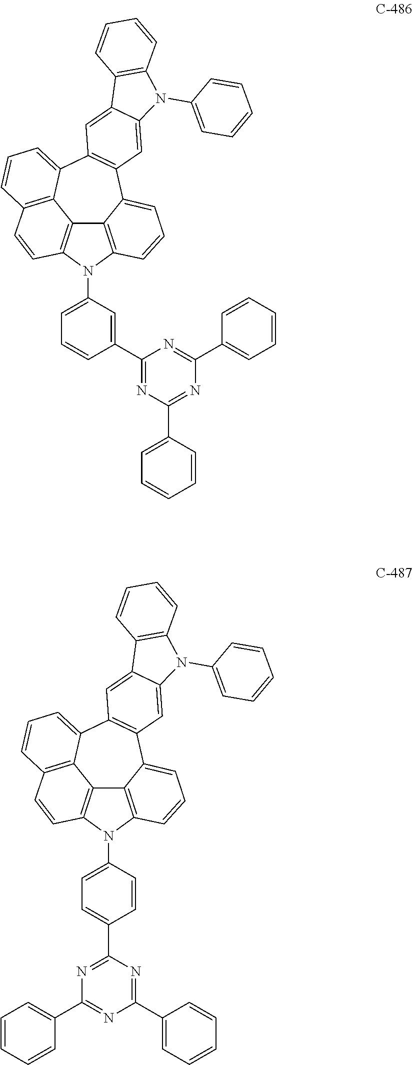 [SMILES: c1ccc(-c2nc(-c3ccccc3)nc(-c3cccc(-n4c5cccc6c5c5c7c(cccc7ccc54)-c4cc5c7ccccc7n(-c7ccccc7)c5cc4-6)c3)n2)cc1 ; c1ccc(-c2nc(-c3ccccc3)nc(-c3ccc(-n4c5cccc6c5c5c7c(cccc7ccc54)-c4cc5c7ccccc7n(-c7ccccc7)c5cc4-6)cc3)n2)cc1]

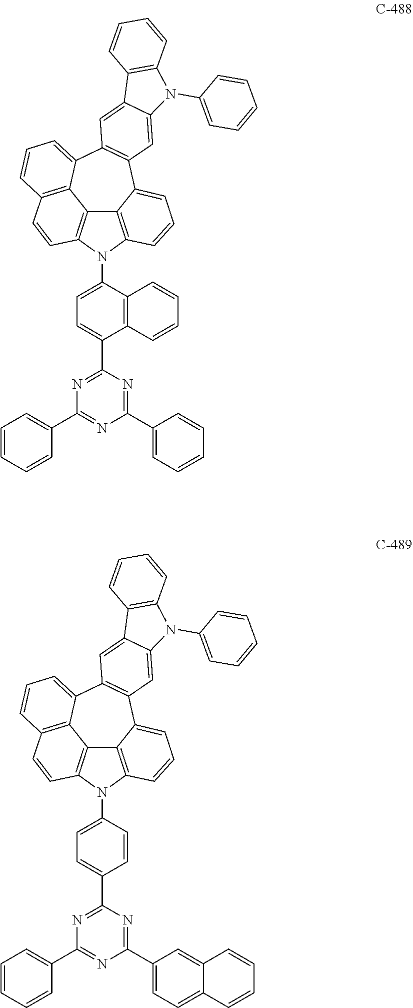 [SMILES: c1ccc(-c2nc(-c3ccccc3)nc(-c3ccc(-n4c5cccc6c5c5c7c(cccc7ccc54)-c4cc5c7ccccc7n(-c7ccccc7)c5cc4-6)c4ccccc34)n2)cc1 ; c1ccc(-c2nc(-c3ccc(-n4c5cccc6c5c5c7c(cccc7ccc54)-c4cc5c7ccccc7n(-c7ccccc7)c5cc4-6)cc3)nc(-c3ccc4ccccc4c3)n2)cc1]

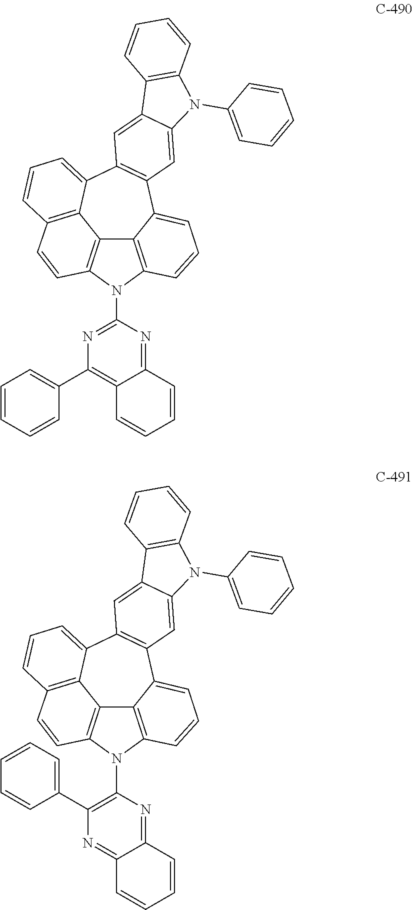 [SMILES: c1ccc(-c2nc(-n3c4cccc5c4c4c6c(cccc6ccc43)-c3cc4c6ccccc6n(-c6ccccc6)c4cc3-5)nc3ccccc23)cc1 ; c1ccc(-c2nc3ccccc3nc2-n2c3cccc4c3c3c5c(cccc5ccc32)-c2cc3c5ccccc5n(-c5ccccc5)c3cc2-4)cc1]

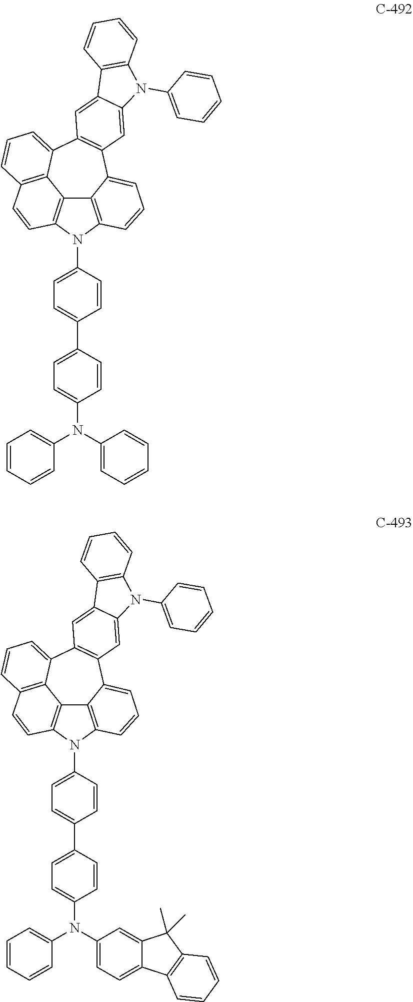 [SMILES: c1ccc(N(c2ccccc2)c2ccc(-c3ccc(-n4c5cccc6c5c5c7c(cccc7ccc54)-c4cc5c7ccccc7n(-c7ccccc7)c5cc4-6)cc3)cc2)cc1 ; CC1(C)c2ccccc2-c2ccc(N(c3ccccc3)c3ccc(-c4ccc(-n5c6cccc7c6c6c8c(cccc8ccc65)-c5cc6c8ccccc8n(-c8ccccc8)c6cc5-7)cc4)cc3)cc21]

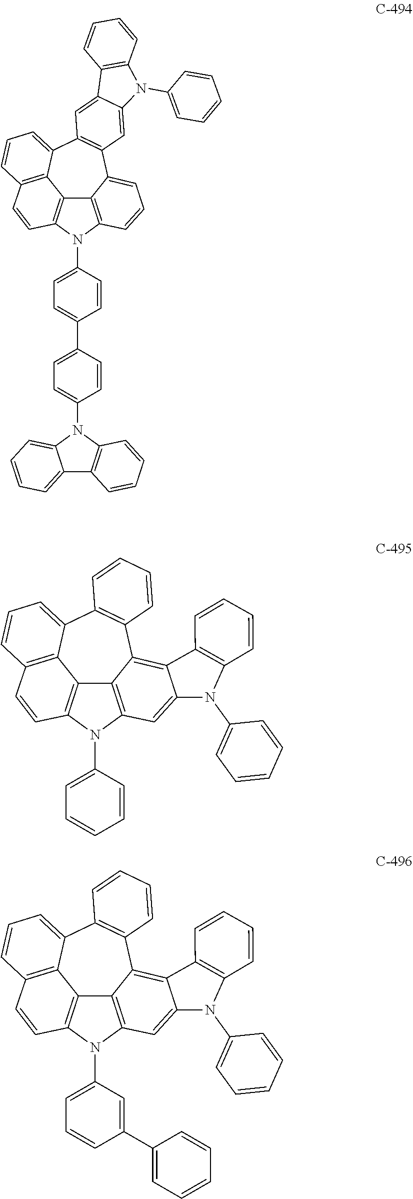

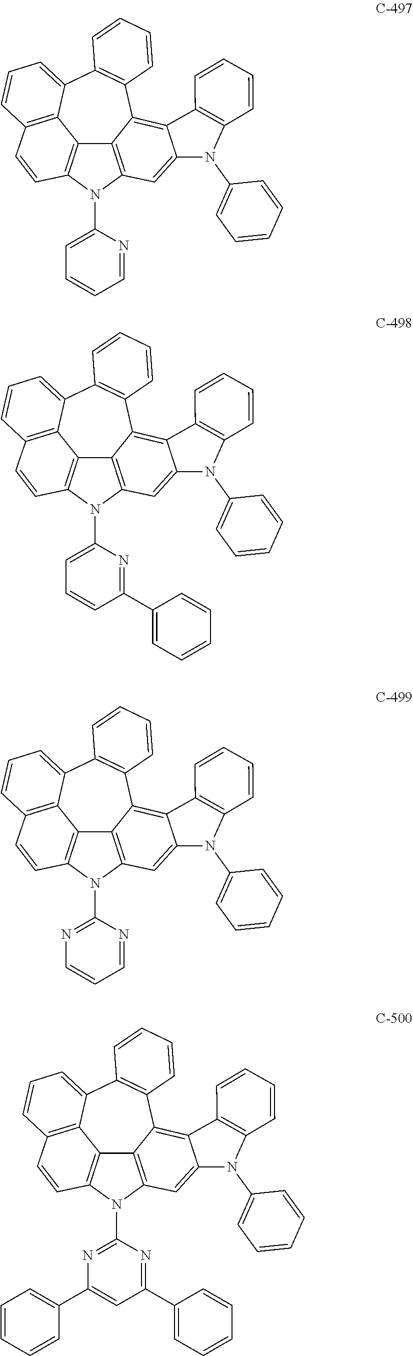

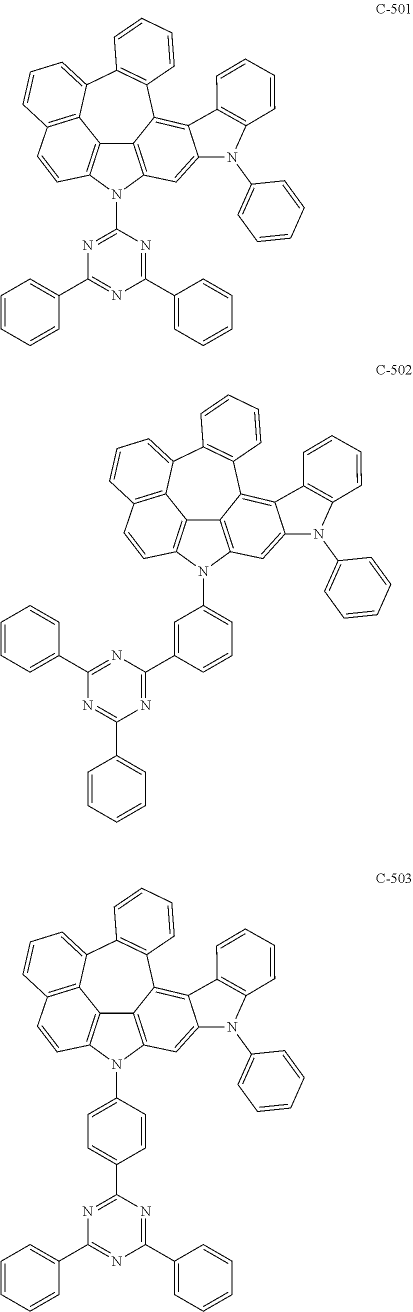 [SMILES: c1ccc(-c2nc(-c3ccccc3)nc(-n3c4cc5c(c6c4c4c7c(cccc7ccc43)-c3ccccc3-6)c3ccccc3n5-c3ccccc3)n2)cc1 ; c1ccc(-c2nc(-c3ccccc3)nc(-c3cccc(-n4c5cc6c(c7c5c5c8c(cccc8ccc54)-c4ccccc4-7)c4ccccc4n6-c4ccccc4)c3)n2)cc1 ; c1ccc(-c2nc(-c3ccccc3)nc(-c3ccc(-n4c5cc6c(c7c5c5c8c(cccc8ccc54)-c4ccccc4-7)c4ccccc4n6-c4ccccc4)cc3)n2)cc1]

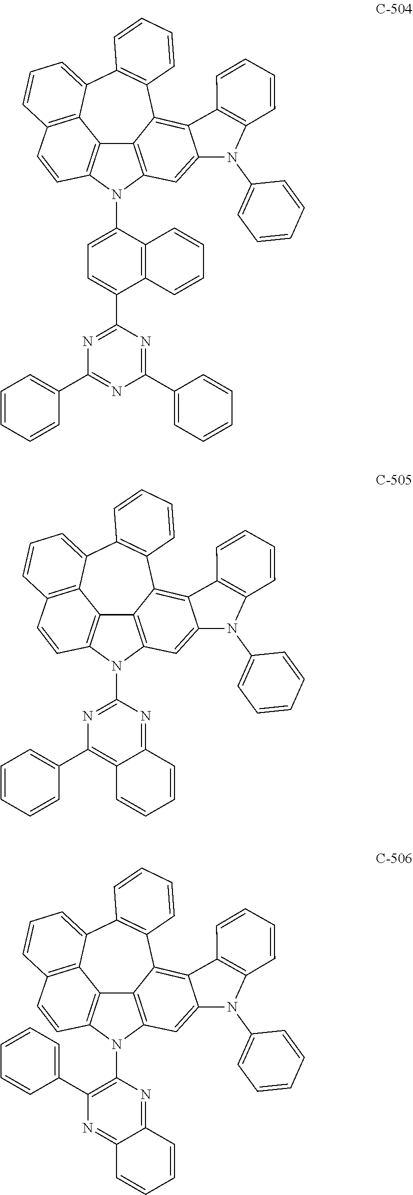 [SMILES: c1ccc(-c2nc(-c3ccccc3)nc(-c3ccc(-n4c5cc6c(c7c5c5c8c(cccc8ccc54)-c4ccccc4-7)c4ccccc4n6-c4ccccc4)c4ccccc34)n2)cc1 ; c1ccc(-c2nc(-n3c4cc5c(c6c4c4c7c(cccc7ccc43)-c3ccccc3-6)c3ccccc3n5-c3ccccc3)nc3ccccc23)cc1 ; c1ccc(-c2nc3ccccc3nc2-n2c3cc4c(c5c3c3c6c(cccc6ccc32)-c2ccccc2-5)c2ccccc2n4-c2ccccc2)cc1]

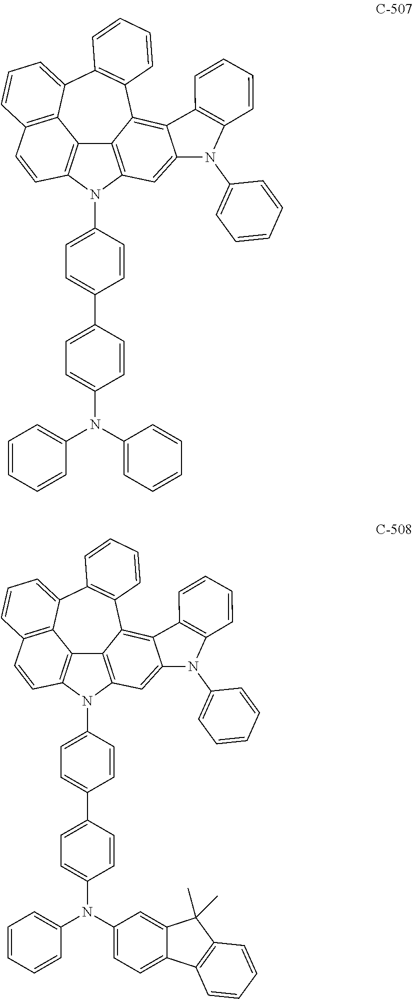 [SMILES: c1ccc(N(c2ccccc2)c2ccc(-c3ccc(-n4c5cc6c(c7c5c5c8c(cccc8ccc54)-c4ccccc4-7)c4ccccc4n6-c4ccccc4)cc3)cc2)cc1 ; CC1(C)c2ccccc2-c2ccc(N(c3ccccc3)c3ccc(-c4ccc(-n5c6cc7c(c8c6c6c9c(cccc9ccc65)-c5ccccc5-8)c5ccccc5n7-c5ccccc5)cc4)cc3)cc21]

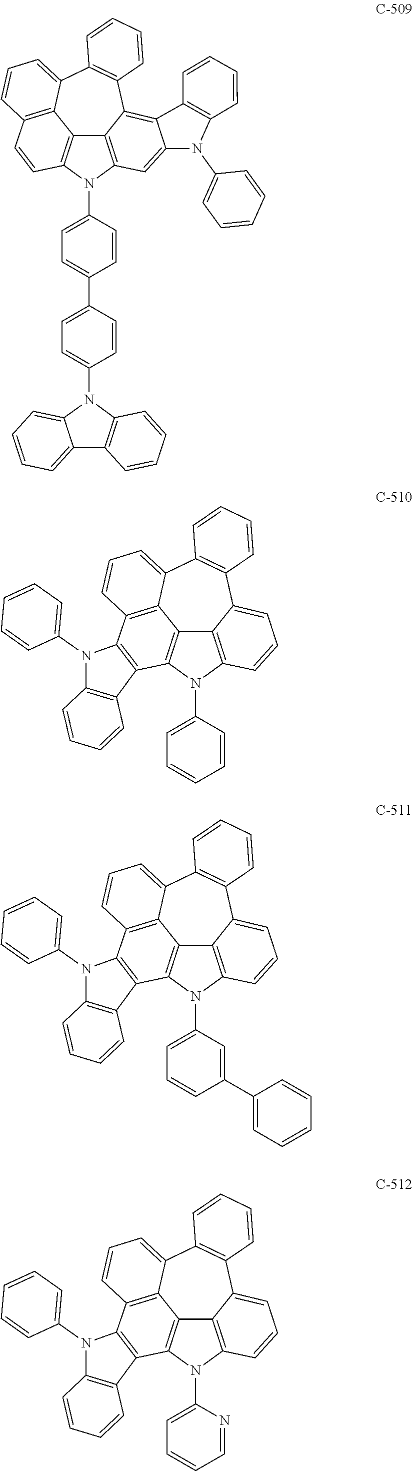

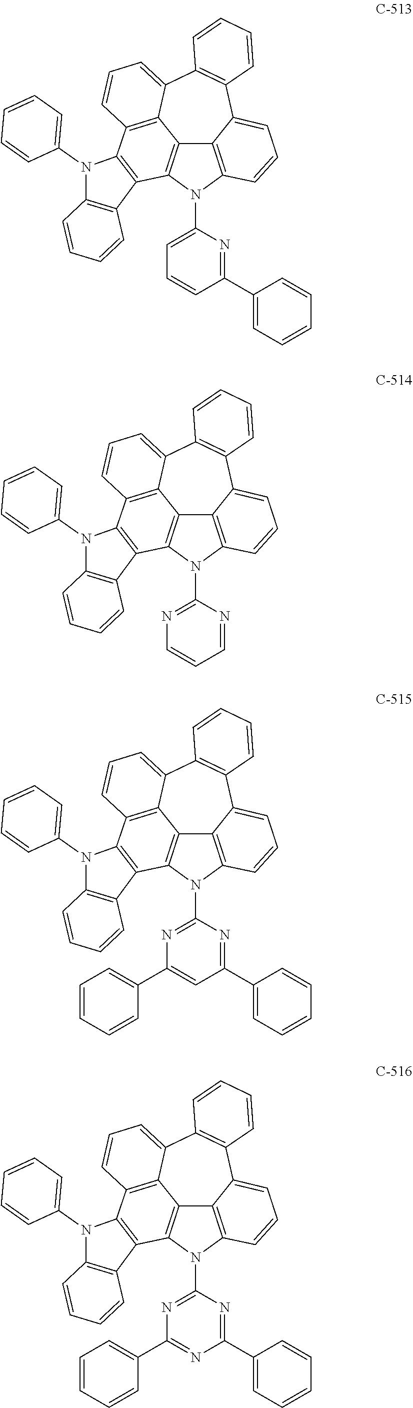 [SMILES: c1ccc(-c2cccc(-n3c4cccc5c4c4c6c(cccc6c6c(c7ccccc7n6-c6ccccc6)c43)-c3ccccc3-5)n2)cc1 ; c1ccc(-n2c3ccccc3c3c2c2cccc4c2c2c5c(cccc5n(-c5ncccn5)c23)-c2ccccc2-4)cc1 ; c1ccc(-c2cc(-c3ccccc3)nc(-n3c4cccc5c4c4c6c(cccc6c6c(c7ccccc7n6-c6ccccc6)c43)-c3ccccc3-5)n2)cc1 ; c1ccc(-c2nc(-c3ccccc3)nc(-n3c4cccc5c4c4c6c(cccc6c6c(c7ccccc7n6-c6ccccc6)c43)-c3ccccc3-5)n2)cc1]

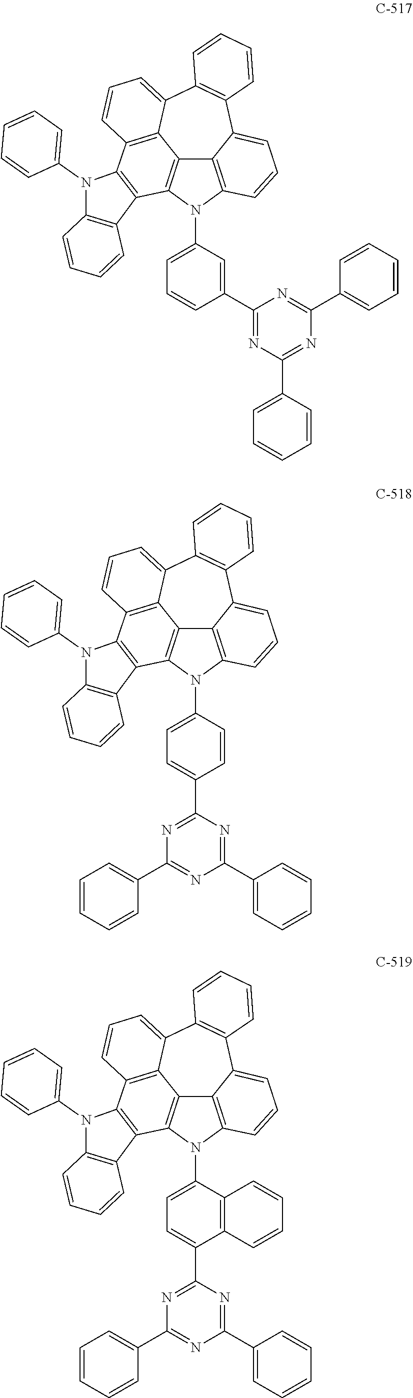 [SMILES: c1ccc(-c2nc(-c3ccccc3)nc(-c3cccc(-n4c5cccc6c5c5c7c(cccc7c7c(c8ccccc8n7-c7ccccc7)c54)-c4ccccc4-6)c3)n2)cc1 ; c1ccc(-c2nc(-c3ccccc3)nc(-c3ccc(-n4c5cccc6c5c5c7c(cccc7c7c(c8ccccc8n7-c7ccccc7)c54)-c4ccccc4-6)cc3)n2)cc1 ; c1ccc(-c2nc(-c3ccccc3)nc(-c3ccc(-n4c5cccc6c5c5c7c(cccc7c7c(c8ccccc8n7-c7ccccc7)c54)-c4ccccc4-6)c4ccccc34)n2)cc1]

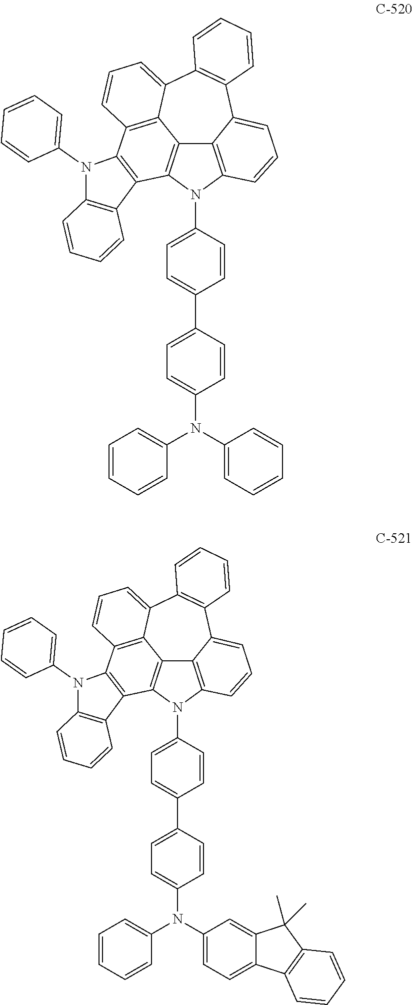 [SMILES: c1ccc(N(c2ccccc2)c2ccc(-c3ccc(-n4c5cccc6c5c5c7c(cccc7c7c(c8ccccc8n7-c7ccccc7)c54)-c4ccccc4-6)cc3)cc2)cc1 ; CC1(C)c2ccccc2-c2ccc(N(c3ccccc3)c3ccc(-c4ccc(-n5c6cccc7c6c6c8c(cccc8c8c(c9ccccc9n8-c8ccccc8)c65)-c5ccccc5-7)cc4)cc3)cc21]

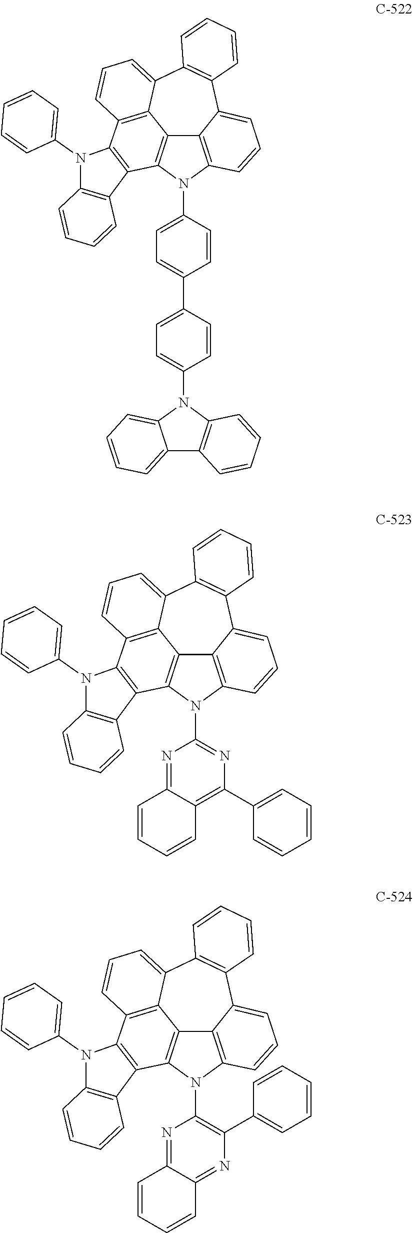 [SMILES: c1ccc(-n2c3ccccc3c3c2c2cccc4c2c2c5c(cccc5n(-c5ccc(-c6ccc(-n7c8ccccc8c8ccccc87)cc6)cc5)c23)-c2ccccc2-4)cc1 ; c1ccc(-c2nc(-n3c4cccc5c4c4c6c(cccc6c6c(c7ccccc7n6-c6ccccc6)c43)-c3ccccc3-5)nc3ccccc23)cc1 ; c1ccc(-c2nc3ccccc3nc2-n2c3cccc4c3c3c5c(cccc5c5c(c6ccccc6n5-c5ccccc5)c32)-c2ccccc2-4)cc1]

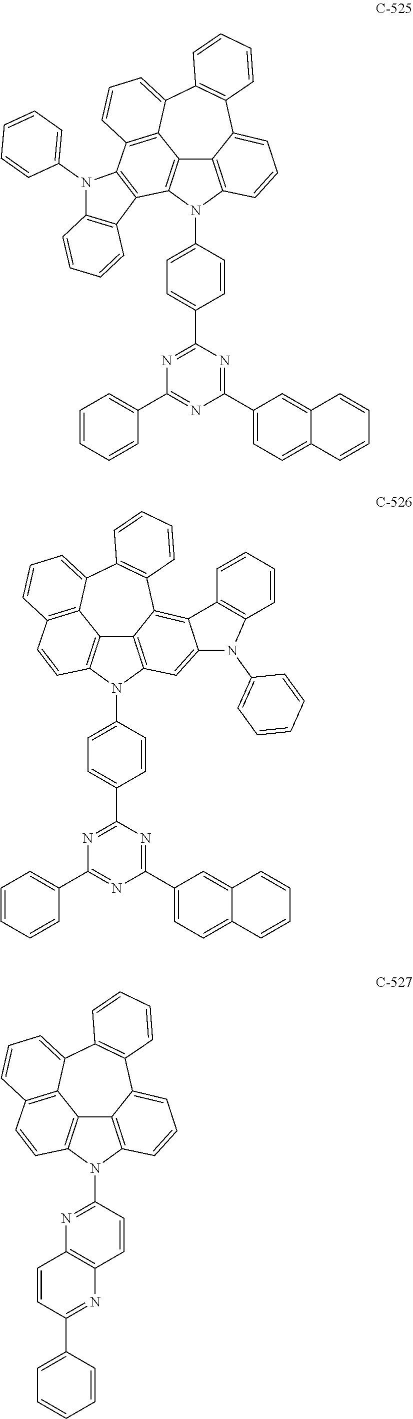 [SMILES: c1ccc(-c2nc(-c3ccc(-n4c5cccc6c5c5c7c(cccc7c7c(c8ccccc8n7-c7ccccc7)c54)-c4ccccc4-6)cc3)nc(-c3ccc4ccccc4c3)n2)cc1 ; c1ccc(-c2nc(-c3ccc(-n4c5cc6c(c7c5c5c8c(cccc8ccc54)-c4ccccc4-7)c4ccccc4n6-c4ccccc4)cc3)nc(-c3ccc4ccccc4c3)n2)cc1 ; c1ccc(-c2ccc3nc(-n4c5cccc6c5c5c7c(cccc7ccc54)-c4ccccc4-6)ccc3n2)cc1]

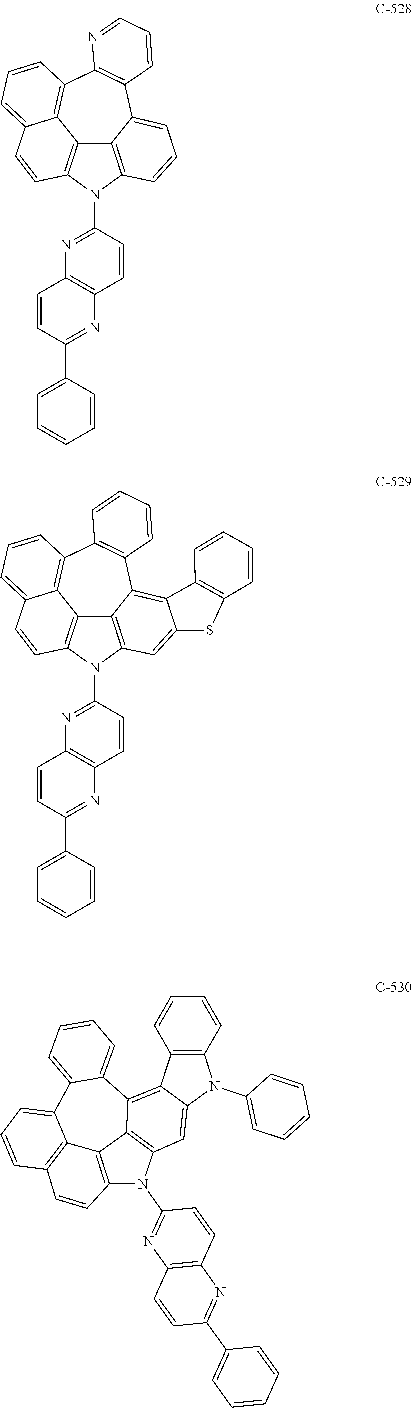 [SMILES: c1ccc(-c2ccc3nc(-n4c5cccc6c5c5c7c(cccc7ccc54)-c4ncccc4-6)ccc3n2)cc1 ; c1ccc(-c2ccc3nc(-n4c5cc6sc7ccccc7c6c6c5c5c7c(cccc7ccc54)-c4ccccc4-6)ccc3n2)cc1 ; c1ccc(-c2ccc3nc(-n4c5cc6c(c7c5c5c8c(cccc8ccc54)-c4ccccc4-7)c4ccccc4n6-c4ccccc4)ccc3n2)cc1]

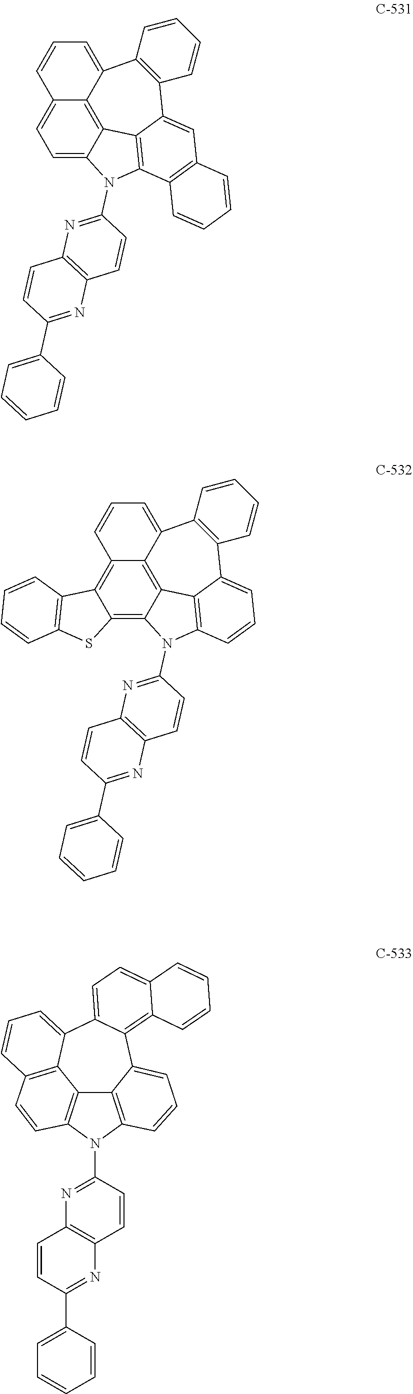 [SMILES: c1ccc(-c2ccc3nc(-n4c5ccc6cccc7c6c5c5c(cc6ccccc6c54)-c4ccccc4-7)ccc3n2)cc1 ; c1ccc(-c2ccc3nc(-n4c5cccc6c5c5c7c(cccc7c7c8ccccc8sc7c54)-c4ccccc4-6)ccc3n2)cc1 ; c1ccc(-c2ccc3nc(-n4c5cccc6c5c5c7c(cccc7ccc54)-c4ccc5ccccc5c4-6)ccc3n2)cc1]

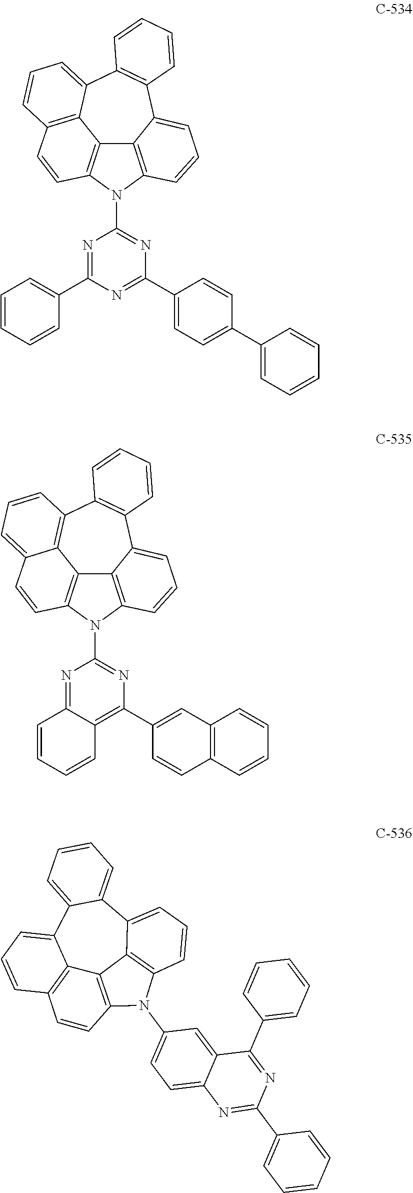 [SMILES: c1ccc(-c2ccc(-c3nc(-c4ccccc4)nc(-n4c5cccc6c5c5c7c(cccc7ccc54)-c4ccccc4-6)n3)cc2)cc1 ; c1ccc2c(c1)-c1cccc3ccc4c(c13)c1c-2cccc1n4-c1nc(-c2ccc3ccccc3c2)c2ccccc2n1 ; c1ccc(-c2nc(-c3ccccc3)c3cc(-n4c5cccc6c5c5c7c(cccc7ccc54)-c4ccccc4-6)ccc3n2)cc1]

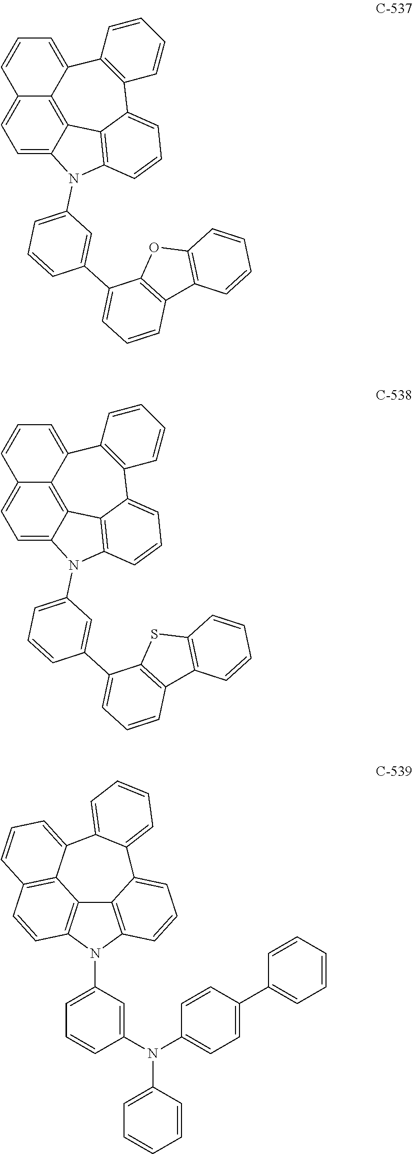 [SMILES: c1cc(-c2cccc3c2oc2ccccc23)cc(-n2c3cccc4c3c3c5c(cccc5ccc32)-c2ccccc2-4)c1 ; c1cc(-c2cccc3c2sc2ccccc23)cc(-n2c3cccc4c3c3c5c(cccc5ccc32)-c2ccccc2-4)c1 ; c1ccc(-c2ccc(N(c3ccccc3)c3cccc(-n4c5cccc6c5c5c7c(cccc7ccc54)-c4ccccc4-6)c3)cc2)cc1]

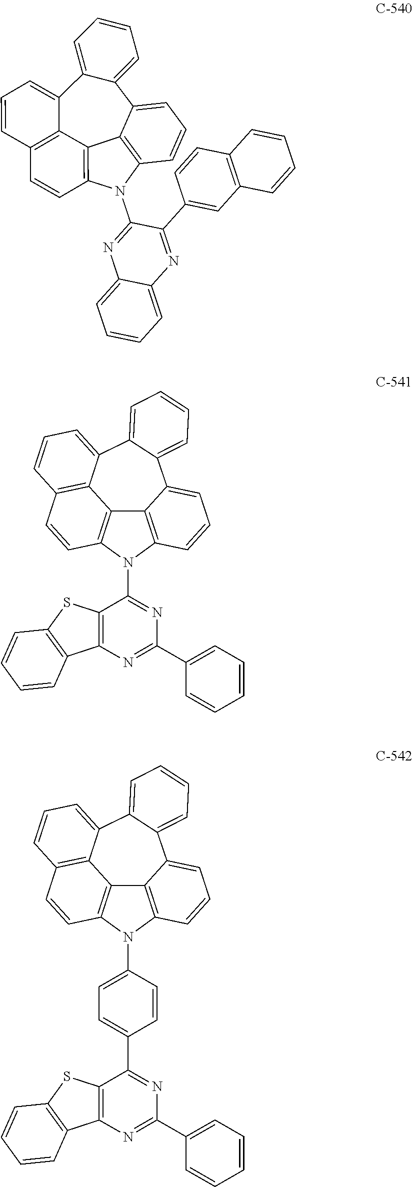 [SMILES: c1ccc2c(c1)-c1cccc3ccc4c(c13)c1c-2cccc1n4-c1nc2ccccc2nc1-c1ccc2ccccc2c1 ; c1ccc(-c2nc(-n3c4cccc5c4c4c6c(cccc6ccc43)-c3ccccc3-5)c3sc4ccccc4c3n2)cc1 ; c1ccc(-c2nc(-c3ccc(-n4c5cccc6c5c5c7c(cccc7ccc54)-c4ccccc4-6)cc3)c3sc4ccccc4c3n2)cc1]

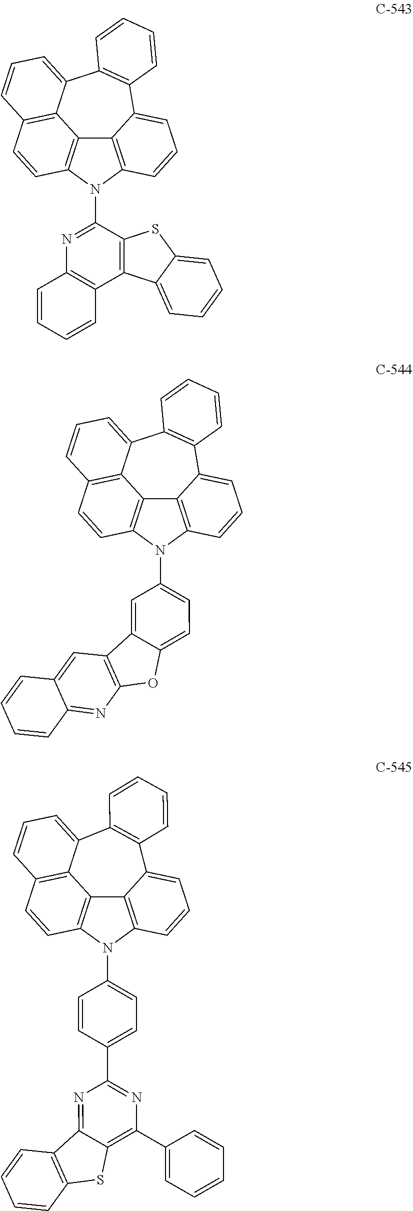 [SMILES: c1ccc2c(c1)-c1cccc3ccc4c(c13)c1c-2cccc1n4-c1nc2ccccc2c2c1sc1ccccc12 ; c1ccc2c(c1)-c1cccc3ccc4c(c13)c1c-2cccc1n4-c1ccc2oc3nc4ccccc4cc3c2c1 ; c1ccc(-c2nc(-c3ccc(-n4c5cccc6c5c5c7c(cccc7ccc54)-c4ccccc4-6)cc3)nc3c2sc2ccccc23)cc1]

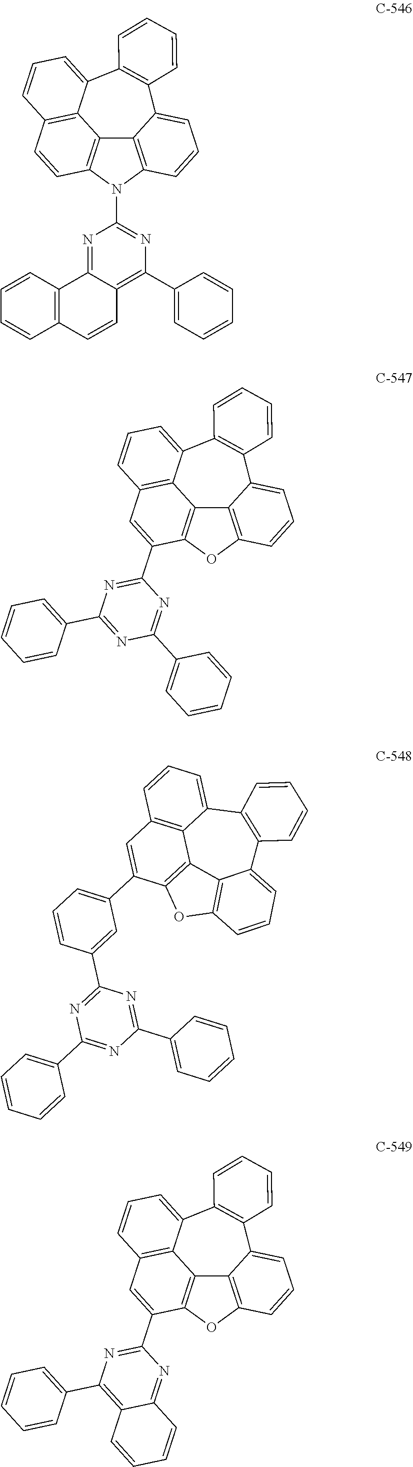 [SMILES: c1ccc(-c2nc(-n3c4cccc5c4c4c6c(cccc6ccc43)-c3ccccc3-5)nc3c2ccc2ccccc23)cc1 ; c1ccc(-c2nc(-c3ccccc3)nc(-c3cc4cccc5c4c4c3oc3cccc(c34)-c3ccccc3-5)n2)cc1 ; c1ccc(-c2nc(-c3ccccc3)nc(-c3cccc(-c4cc5cccc6c5c5c4oc4cccc(c45)-c4ccccc4-6)c3)n2)cc1 ; c1ccc(-c2nc(-c3cc4cccc5c4c4c3oc3cccc(c34)-c3ccccc3-5)nc3ccccc23)cc1]

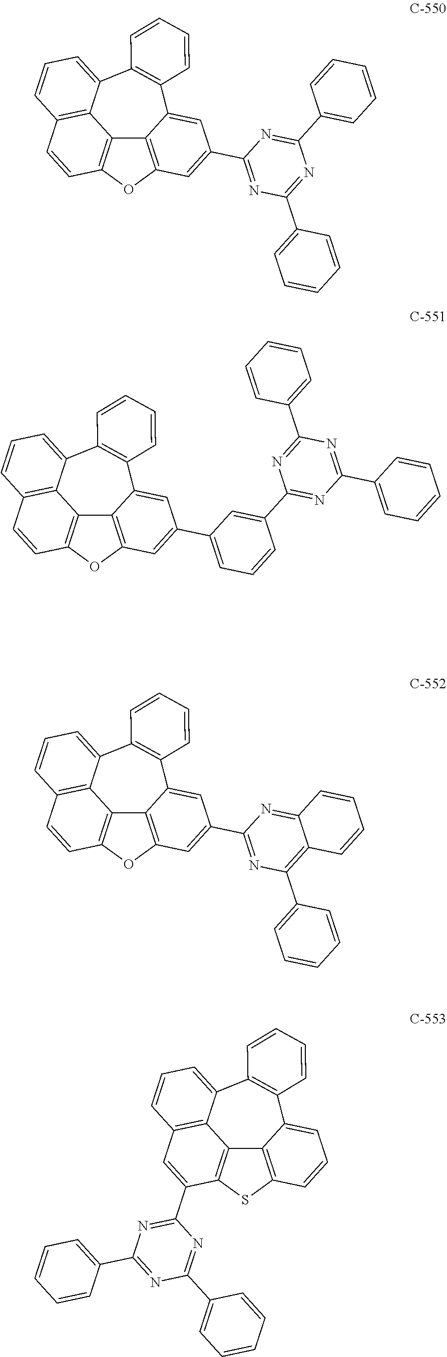 [SMILES: c1ccc(-c2nc(-c3ccccc3)nc(-c3cc4c5c(c3)oc3ccc6cccc(c6c35)-c3ccccc3-4)n2)cc1 ; c1ccc(-c2nc(-c3ccccc3)nc(-c3cccc(-c4cc5c6c(c4)oc4ccc7cccc(c7c46)-c4ccccc4-5)c3)n2)cc1 ; c1ccc(-c2nc(-c3cc4c5c(c3)oc3ccc6cccc(c6c35)-c3ccccc3-4)nc3ccccc23)cc1 ; c1ccc(-c2nc(-c3ccccc3)nc(-c3cc4cccc5c4c4c3sc3cccc(c34)-c3ccccc3-5)n2)cc1]

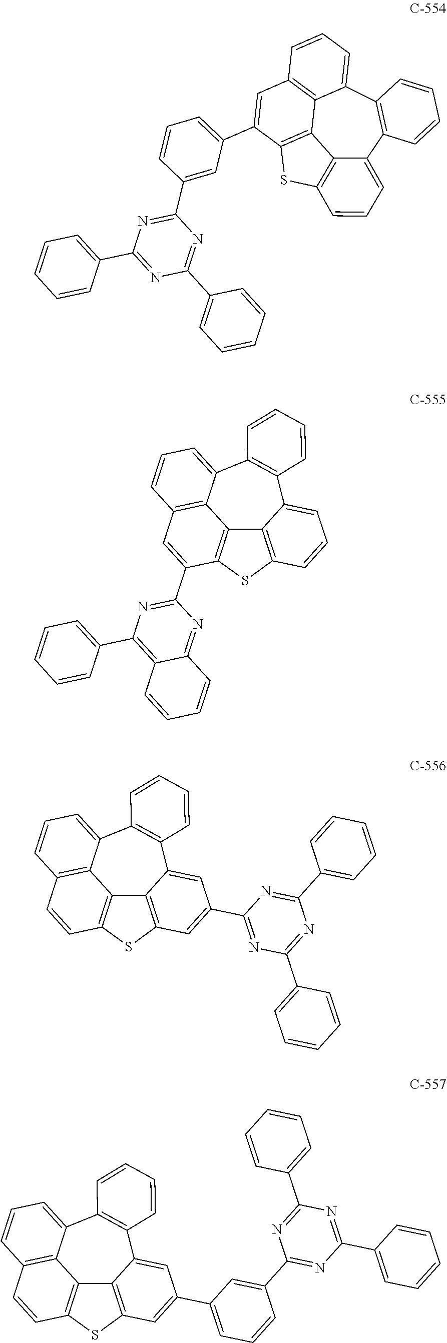 [SMILES: c1ccc(-c2nc(-c3ccccc3)nc(-c3cccc(-c4cc5cccc6c5c5c4sc4cccc(c45)-c4ccccc4-6)c3)n2)cc1 ; c1ccc(-c2nc(-c3cc4cccc5c4c4c3sc3cccc(c34)-c3ccccc3-5)nc3ccccc23)cc1 ; c1ccc(-c2nc(-c3ccccc3)nc(-c3cc4c5c(c3)sc3ccc6cccc(c6c35)-c3ccccc3-4)n2)cc1 ; c1ccc(-c2nc(-c3ccccc3)nc(-c3cccc(-c4cc5c6c(c4)sc4ccc7cccc(c7c46)-c4ccccc4-5)c3)n2)cc1]

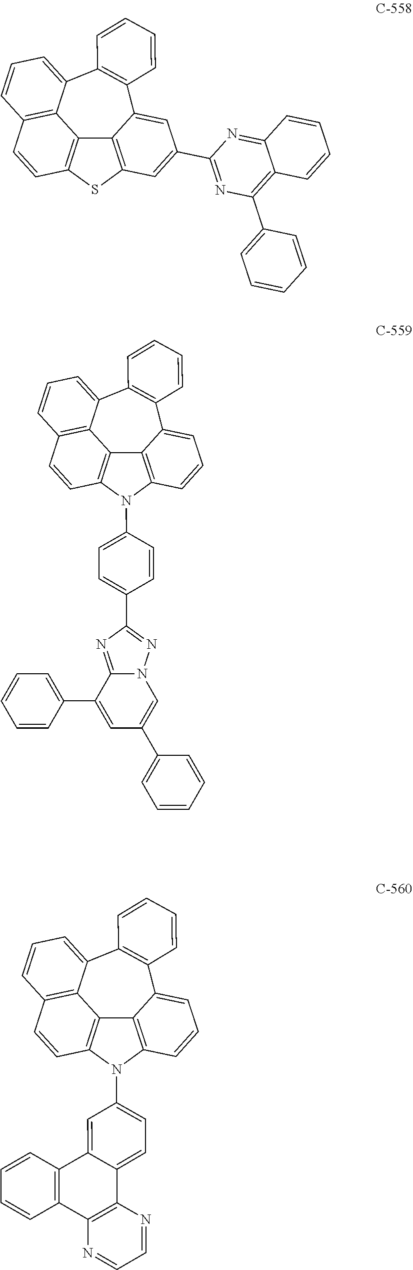 [SMILES: c1ccc(-c2nc(-c3cc4c5c(c3)sc3ccc6cccc(c6c35)-c3ccccc3-4)nc3ccccc23)cc1 ; c1ccc(-c2cc(-c3ccccc3)c3nc(-c4ccc(-n5c6cccc7c6c6c8c(cccc8ccc65)-c5ccccc5-7)cc4)nn3c2)cc1 ; c1ccc2c(c1)-c1cccc3ccc4c(c13)c1c-2cccc1n4-c1ccc2c(c1)c1ccccc1c1nccnc21]

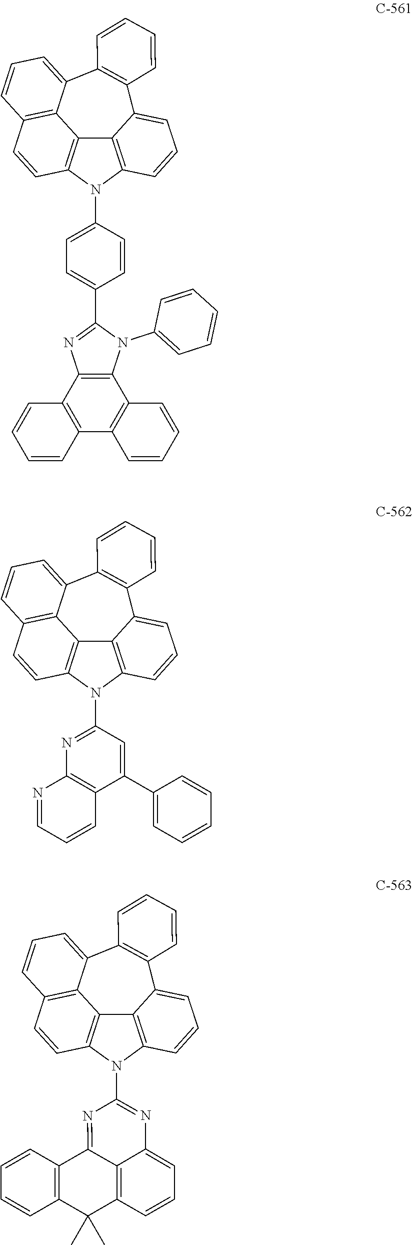 [SMILES: c1ccc(-n2c(-c3ccc(-n4c5cccc6c5c5c7c(cccc7ccc54)-c4ccccc4-6)cc3)nc3c4ccccc4c4ccccc4c32)cc1 ; c1ccc(-c2cc(-n3c4cccc5c4c4c6c(cccc6ccc43)-c3ccccc3-5)nc3ncccc23)cc1 ; CC1(C)c2ccccc2-c2nc(-n3c4cccc5c4c4c6c(cccc6ccc43)-c3ccccc3-5)nc3cccc1c23]

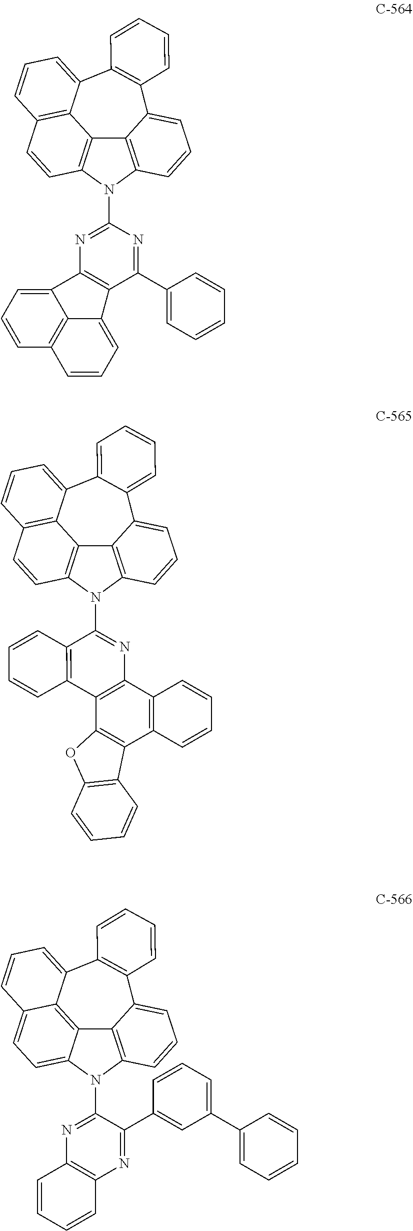 [SMILES: c1ccc(-c2nc(-n3c4cccc5c4c4c6c(cccc6ccc43)-c3ccccc3-5)nc3c2-c2cccc4cccc-3c24)cc1 ; c1ccc2c(c1)-c1cccc3ccc4c(c13)c1c-2cccc1n4-c1nc2c3ccccc3c3c4ccccc4oc3c2c2ccccc12 ; c1ccc(-c2cccc(-c3nc4ccccc4nc3-n3c4cccc5c4c4c6c(cccc6ccc43)-c3ccccc3-5)c2)cc1]

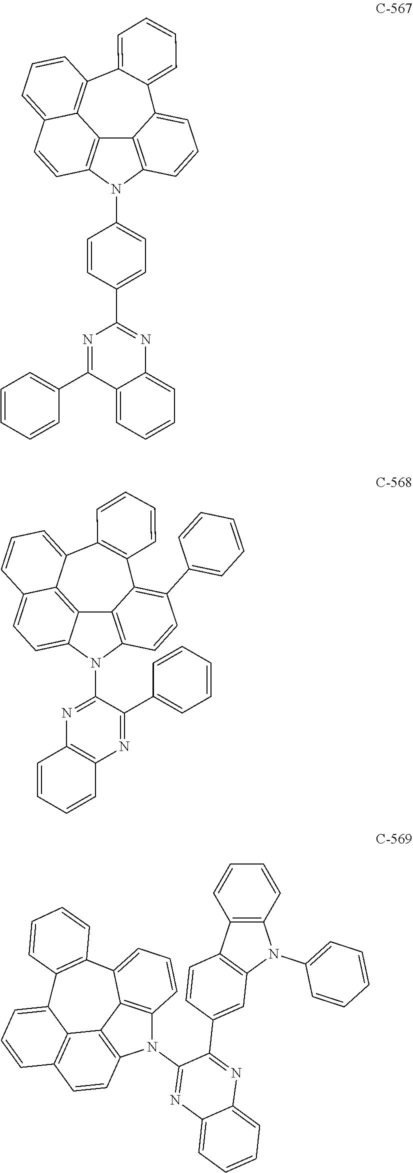 [SMILES: c1ccc(-c2nc(-c3ccc(-n4c5cccc6c5c5c7c(cccc7ccc54)-c4ccccc4-6)cc3)nc3ccccc23)cc1 ; c1ccc(-c2ccc3c4c2-c2ccccc2-c2cccc5ccc(c4c25)n3-c2nc3ccccc3nc2-c2ccccc2)cc1 ; c1ccc(-n2c3ccccc3c3ccc(-c4nc5ccccc5nc4-n4c5cccc6c5c5c7c(cccc7ccc54)-c4ccccc4-6)cc32)cc1]

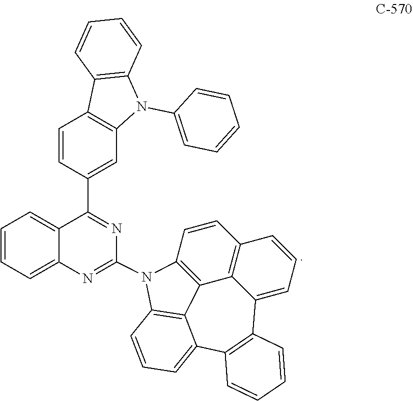 [SMILES: c1ccc(-n2c3ccccc3c3ccc(-c4nc(-n5c6cccc7c6c6c8c(cccc8ccc65)-c5ccccc5-7)nc5ccccc45)cc32)cc1]

6. The organic electroluminescent device according to claim 1, wherein formula 11 is represented by the following formula 21: 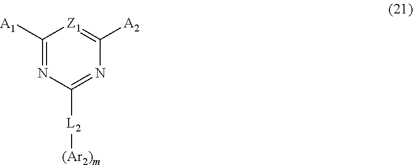
wherein
Z₁ is as defined in formula 11;
A₁ and A₂ are each independently identical to the definition of R₁₉ of formula 11;
L₂ represents a single bond, a substituted or unsubstituted (C6-C50)arylene, or a substituted or unsubstituted (5- to 50-membered)heteroarylene;
Ar₂ represents a substituted or unsubstituted (C6-C50)aryl, or a substituted or unsubstituted (5- to 50-membered)heteroaryl; and
m represents 1 or 2.

7. The organic electroluminescent device according to claim 1, wherein the compound represented by formula 11 is at least one selected from the group consisting of:

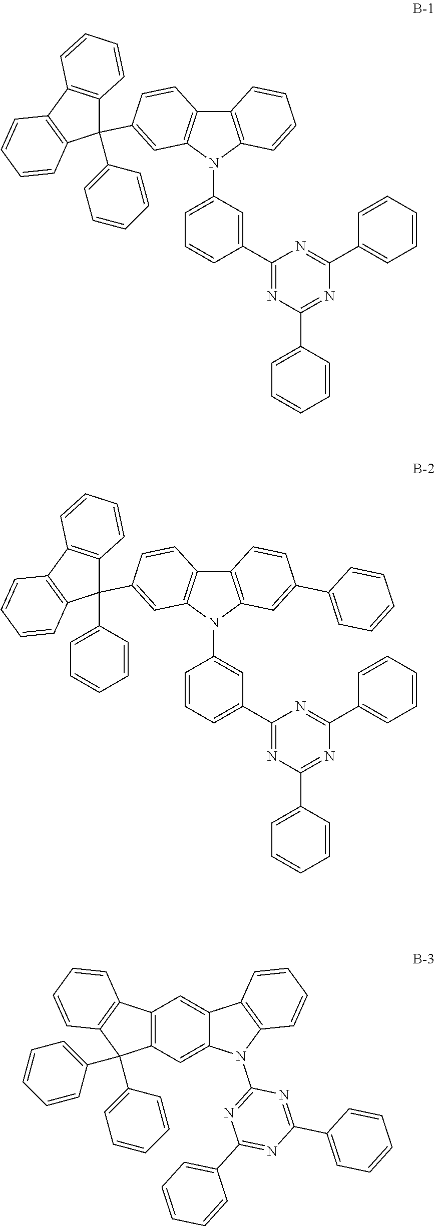 [SMILES: c1ccc(-c2nc(-c3ccccc3)nc(-c3cccc(-n4c5ccccc5c5ccc(C6(c7ccccc7)c7ccccc7-c7ccccc76)cc54)c3)n2)cc1 ; c1ccc(-c2ccc3c4ccc(C5(c6ccccc6)c6ccccc6-c6ccccc65)cc4n(-c4cccc(-c5nc(-c6ccccc6)nc(-c6ccccc6)n5)c4)c3c2)cc1 ; c1ccc(-c2nc(-c3ccccc3)nc(-n3c4ccccc4c4cc5c(cc43)C(c3ccccc3)(c3ccccc3)c3ccccc3-5)n2)cc1]

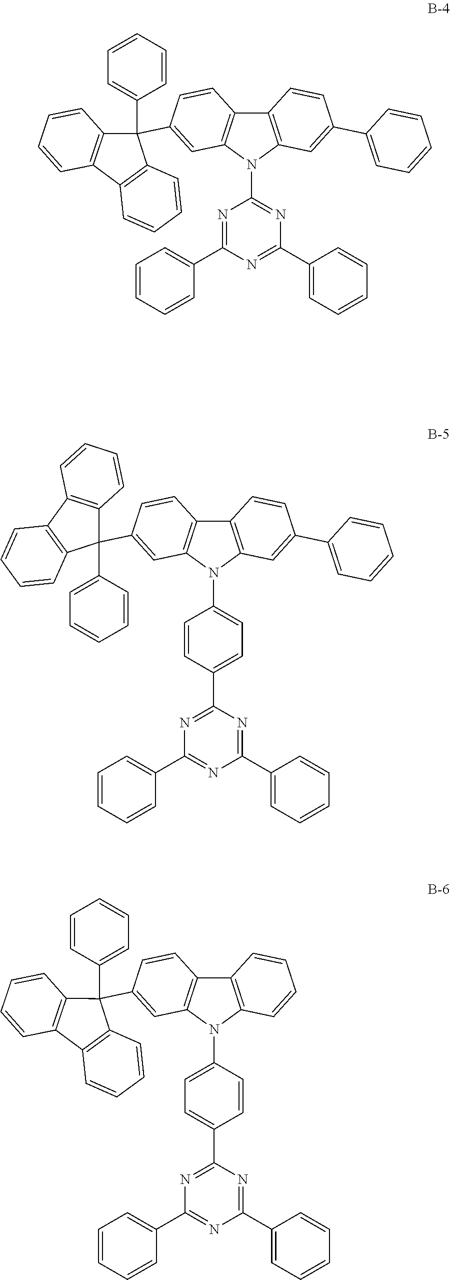 [SMILES: c1ccc(-c2ccc3c4ccc(C5(c6ccccc6)c6ccccc6-c6ccccc65)cc4n(-c4nc(-c5ccccc5)nc(-c5ccccc5)n4)c3c2)cc1 ; c1ccc(-c2ccc3c4ccc(C5(c6ccccc6)c6ccccc6-c6ccccc65)cc4n(-c4ccc(-c5nc(-c6ccccc6)nc(-c6ccccc6)n5)cc4)c3c2)cc1 ; c1ccc(-c2nc(-c3ccccc3)nc(-c3ccc(-n4c5ccccc5c5ccc(C6(c7ccccc7)c7ccccc7-c7ccccc76)cc54)cc3)n2)cc1]

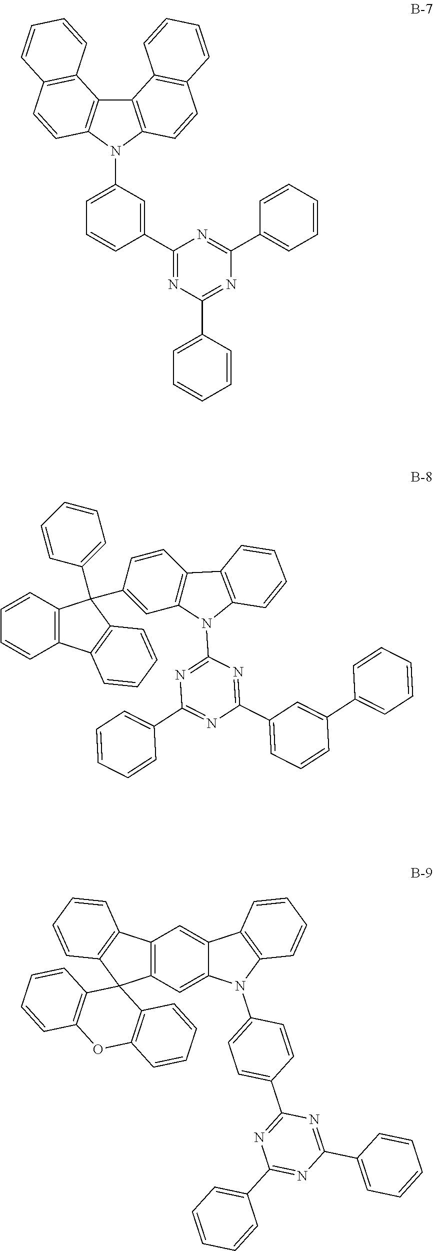 [SMILES: c1ccc(-c2nc(-c3ccccc3)nc(-c3cccc(-n4c5ccc6ccccc6c5c5c6ccccc6ccc54)c3)n2)cc1 ; c1ccc(-c2cccc(-c3nc(-c4ccccc4)nc(-n4c5ccccc5c5ccc(C6(c7ccccc7)c7ccccc7-c7ccccc76)cc54)n3)c2)cc1 ; c1ccc(-c2nc(-c3ccccc3)nc(-c3ccc(-n4c5ccccc5c5cc6c(cc54)C4(c5ccccc5Oc5ccccc54)c4ccccc4-6)cc3)n2)cc1]

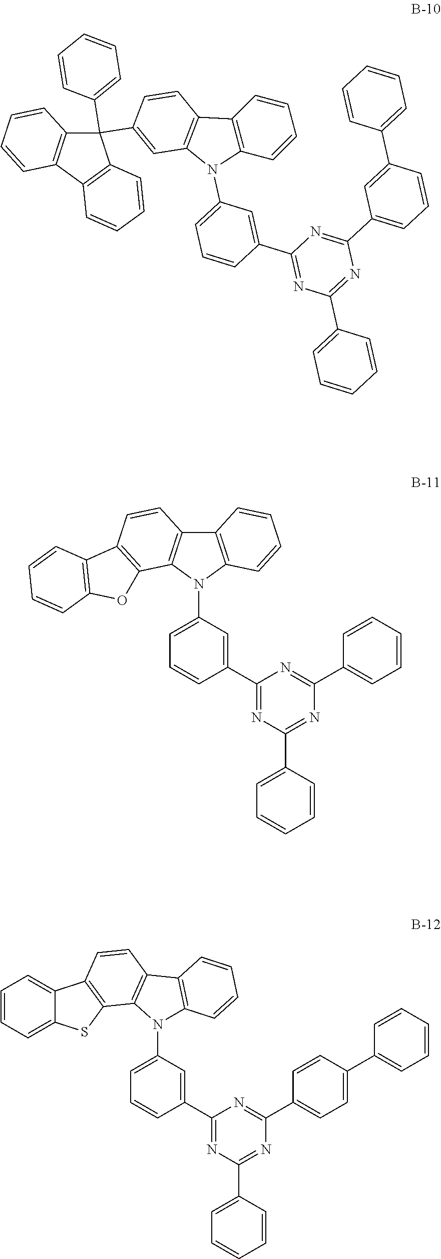 [SMILES: c1ccc(-c2cccc(-c3nc(-c4ccccc4)nc(-c4cccc(-n5c6ccccc6c6ccc(C7(c8ccccc8)c8ccccc8-c8ccccc87)cc65)c4)n3)c2)cc1 ; c1ccc(-c2nc(-c3ccccc3)nc(-c3cccc(-n4c5ccccc5c5ccc6c7ccccc7oc6c54)c3)n2)cc1 ; c1ccc(-c2ccc(-c3nc(-c4ccccc4)nc(-c4cccc(-n5c6ccccc6c6ccc7c8ccccc8sc7c65)c4)n3)cc2)cc1]

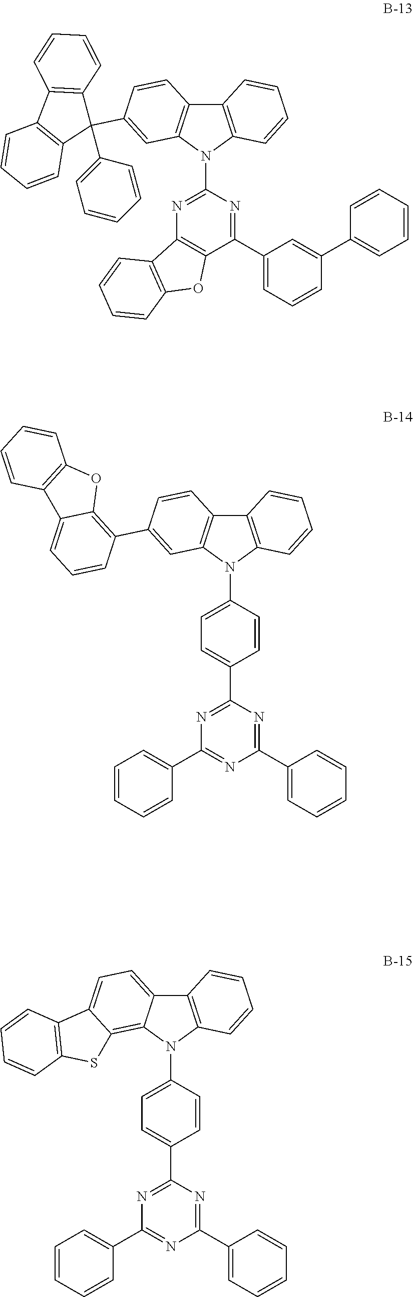 [SMILES: c1ccc(-c2cccc(-c3nc(-n4c5ccccc5c5ccc(C6(c7ccccc7)c7ccccc7-c7ccccc76)cc54)nc4c3oc3ccccc34)c2)cc1 ; c1ccc(-c2nc(-c3ccccc3)nc(-c3ccc(-n4c5ccccc5c5ccc(-c6cccc7c6oc6ccccc67)cc54)cc3)n2)cc1 ; c1ccc(-c2nc(-c3ccccc3)nc(-c3ccc(-n4c5ccccc5c5ccc6c7ccccc7sc6c54)cc3)n2)cc1]

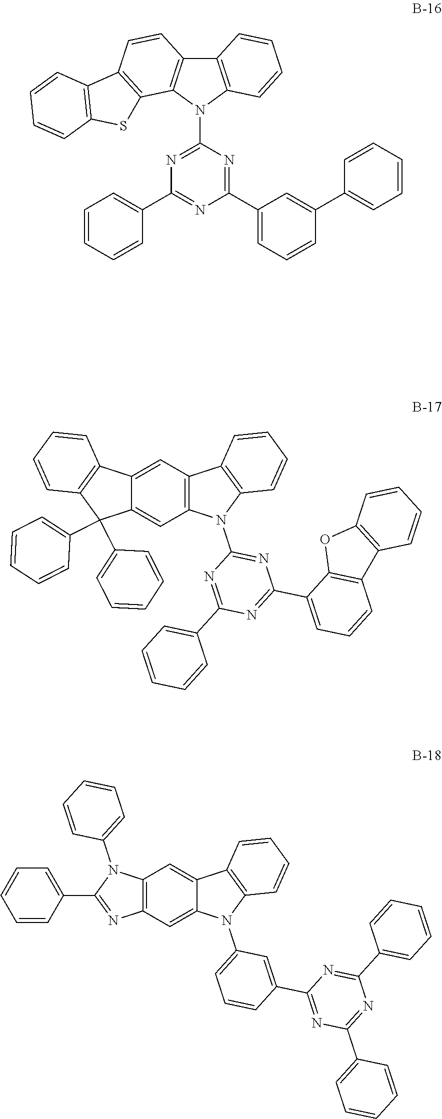 [SMILES: c1ccc(-c2cccc(-c3nc(-c4ccccc4)nc(-n4c5ccccc5c5ccc6c7ccccc7sc6c54)n3)c2)cc1 ; c1ccc(-c2nc(-c3cccc4c3oc3ccccc34)nc(-n3c4ccccc4c4cc5c(cc43)C(c3ccccc3)(c3ccccc3)c3ccccc3-5)n2)cc1 ; c1ccc(-c2nc(-c3ccccc3)nc(-c3cccc(-n4c5ccccc5c5cc6c(cc54)nc(-c4ccccc4)n6-c4ccccc4)c3)n2)cc1]

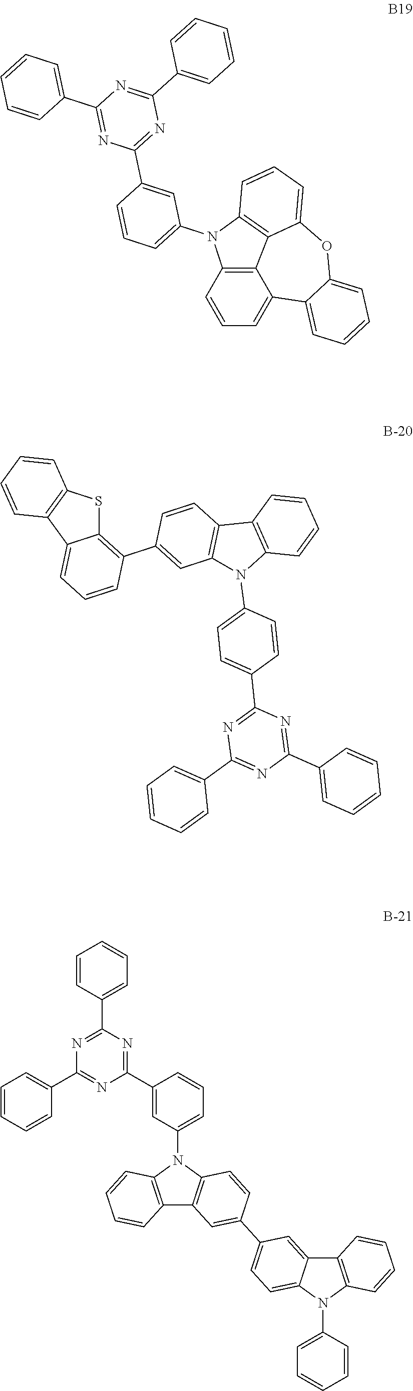 [SMILES: c1ccc(-c2nc(-c3ccccc3)nc(-c3cccc(-n4c5cccc6oc7ccccc7c7cccc4c7c65)c3)n2)cc1 ; c1ccc(-c2nc(-c3ccccc3)nc(-c3ccc(-n4c5ccccc5c5ccc(-c6cccc7c6sc6ccccc67)cc54)cc3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

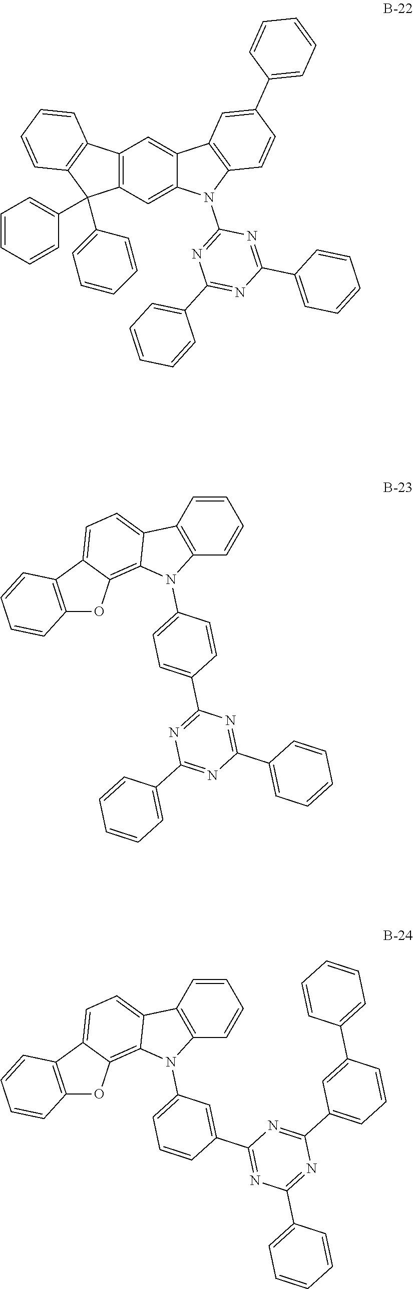 [SMILES: c1ccc(-c2ccc3c(c2)c2cc4c(cc2n3-c2nc(-c3ccccc3)nc(-c3ccccc3)n2)C(c2ccccc2)(c2ccccc2)c2ccccc2-4)cc1 ; c1ccc(-c2nc(-c3ccccc3)nc(-c3ccc(-n4c5ccccc5c5ccc6c7ccccc7oc6c54)cc3)n2)cc1 ; c1ccc(-c2cccc(-c3nc(-c4ccccc4)nc(-c4cccc(-n5c6ccccc6c6ccc7c8ccccc8oc7c65)c4)n3)c2)cc1]

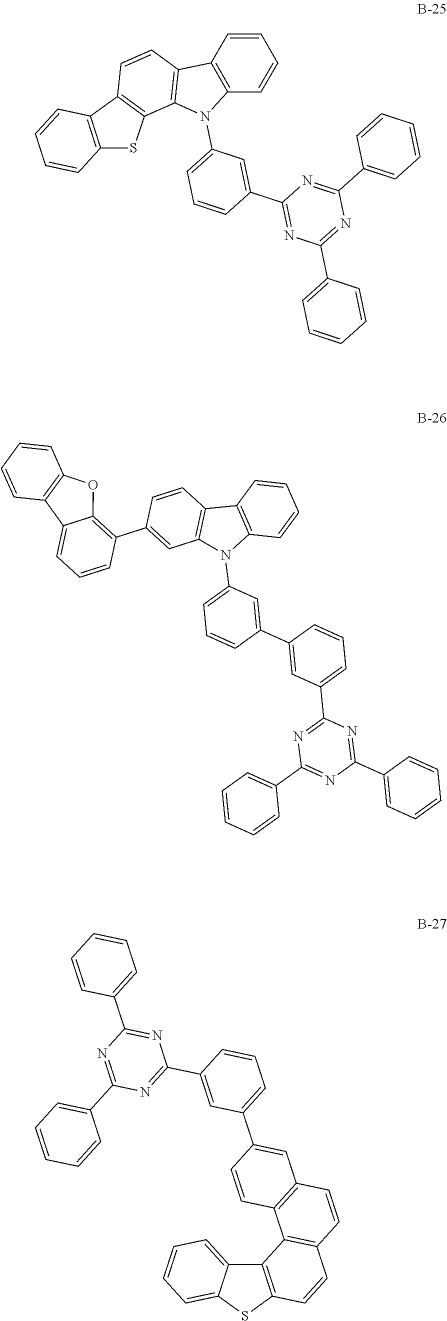 [SMILES: c1ccc(-c2nc(-c3ccccc3)nc(-c3cccc(-n4c5ccccc5c5ccc6c7ccccc7sc6c54)c3)n2)cc1 ; c1ccc(-c2nc(-c3ccccc3)nc(-c3cccc(-c4cccc(-n5c6ccccc6c6ccc(-c7cccc8c7oc7ccccc78)cc65)c4)c3)n2)cc1 ; c1ccc(-c2nc(-c3ccccc3)nc(-c3cccc(-c4ccc5c(ccc6ccc7sc8ccccc8c7c65)c4)c3)n2)cc1]

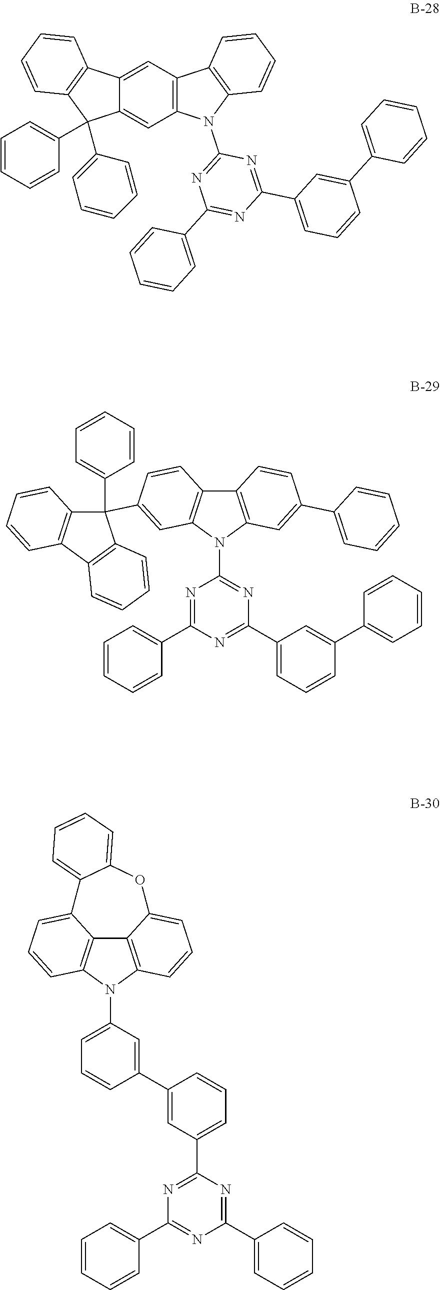 [SMILES: c1ccc(-c2cccc(-c3nc(-c4ccccc4)nc(-n4c5ccccc5c5cc6c(cc54)C(c4ccccc4)(c4ccccc4)c4ccccc4-6)n3)c2)cc1 ; c1ccc(-c2cccc(-c3nc(-c4ccccc4)nc(-n4c5cc(-c6ccccc6)ccc5c5ccc(C6(c7ccccc7)c7ccccc7-c7ccccc76)cc54)n3)c2)cc1 ; c1ccc(-c2nc(-c3ccccc3)nc(-c3cccc(-c4cccc(-n5c6cccc7oc8ccccc8c8cccc5c8c76)c4)c3)n2)cc1]

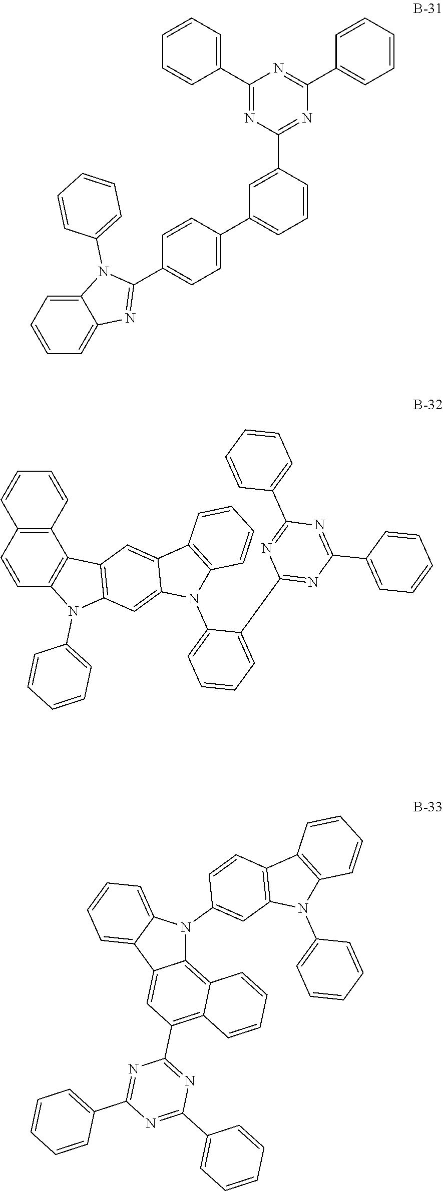 [SMILES: c1ccc(-c2nc(-c3ccccc3)nc(-c3cccc(-c4ccc(-c5nc6ccccc6n5-c5ccccc5)cc4)c3)n2)cc1 ; c1ccc(-c2nc(-c3ccccc3)nc(-c3ccccc3-n3c4ccccc4c4cc5c6c7ccccc7ccc6n(-c6ccccc6)c5cc43)n2)cc1 ; c1ccc(-c2nc(-c3ccccc3)nc(-c3cc4c5ccccc5n(-c5ccc6c7ccccc7n(-c7ccccc7)c6c5)c4c4ccccc34)n2)cc1]

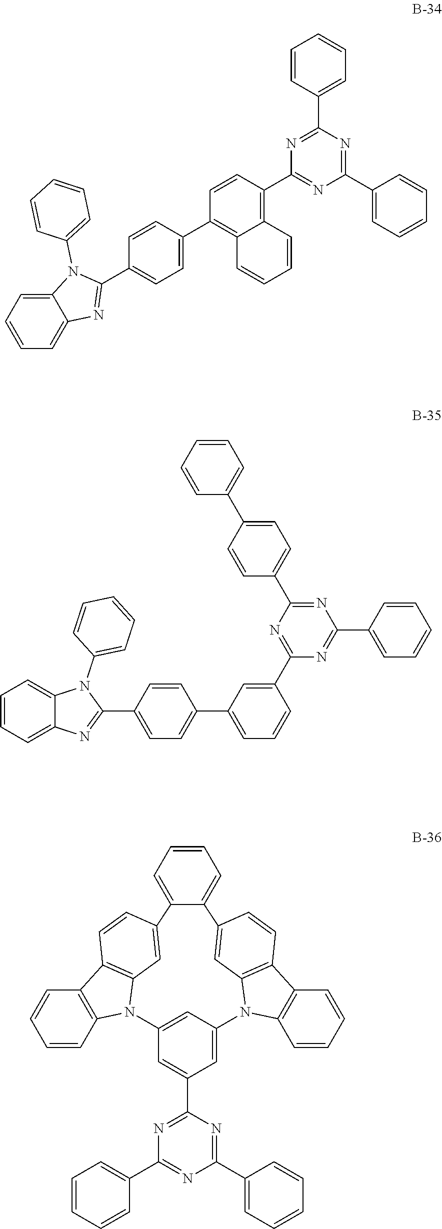 [SMILES: c1ccc(-c2nc(-c3ccccc3)nc(-c3ccc(-c4ccc(-c5nc6ccccc6n5-c5ccccc5)cc4)c4ccccc34)n2)cc1 ; c1ccc(-c2ccc(-c3nc(-c4ccccc4)nc(-c4cccc(-c5ccc(-c6nc7ccccc7n6-c6ccccc6)cc5)c4)n3)cc2)cc1 ; c1ccc(-c2nc(-c3ccccc3)nc(-c3cc4cc(c3)n3c5ccccc5c5ccc(cc53)c3ccccc3c3ccc5c6ccccc6n4c5c3)n2)cc1]

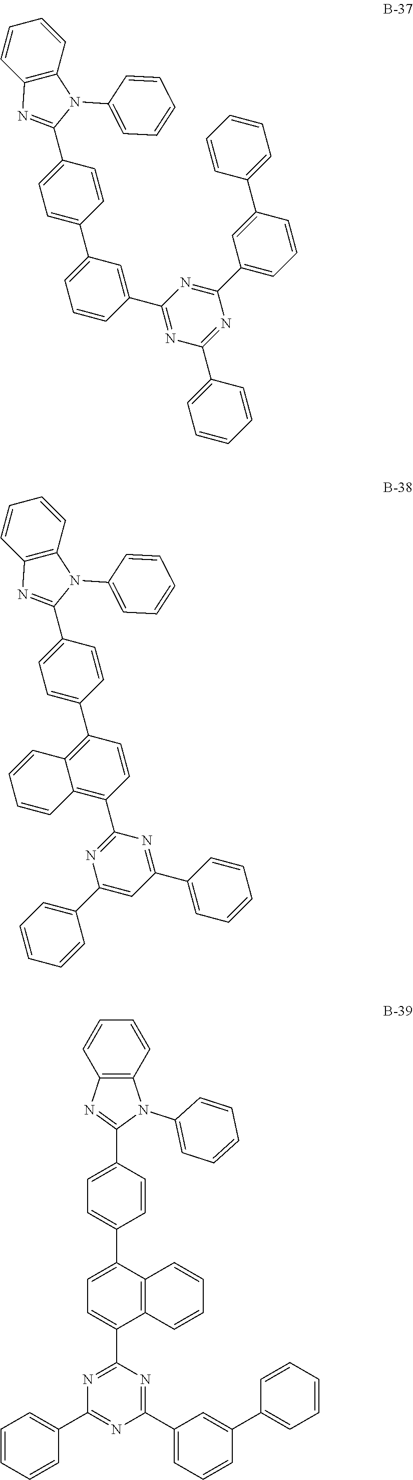 [SMILES: c1ccc(-c2cccc(-c3nc(-c4ccccc4)nc(-c4cccc(-c5ccc(-c6nc7ccccc7n6-c6ccccc6)cc5)c4)n3)c2)cc1 ; c1ccc(-c2cc(-c3ccccc3)nc(-c3ccc(-c4ccc(-c5nc6ccccc6n5-c5ccccc5)cc4)c4ccccc34)n2)cc1 ; c1ccc(-c2cccc(-c3nc(-c4ccccc4)nc(-c4ccc(-c5ccc(-c6nc7ccccc7n6-c6ccccc6)cc5)c5ccccc45)n3)c2)cc1]

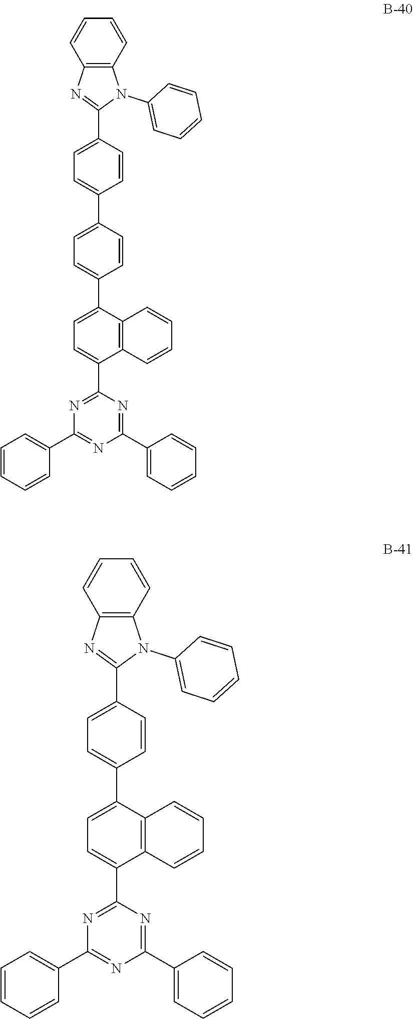 [SMILES: c1ccc(-c2nc(-c3ccccc3)nc(-c3ccc(-c4ccc(-c5ccc(-c6nc7ccccc7n6-c6ccccc6)cc5)cc4)c4ccccc34)n2)cc1 ; c1ccc(-c2nc(-c3ccccc3)nc(-c3ccc(-c4ccc(-c5nc6ccccc6n5-c5ccccc5)cc4)c4ccccc34)n2)cc1]

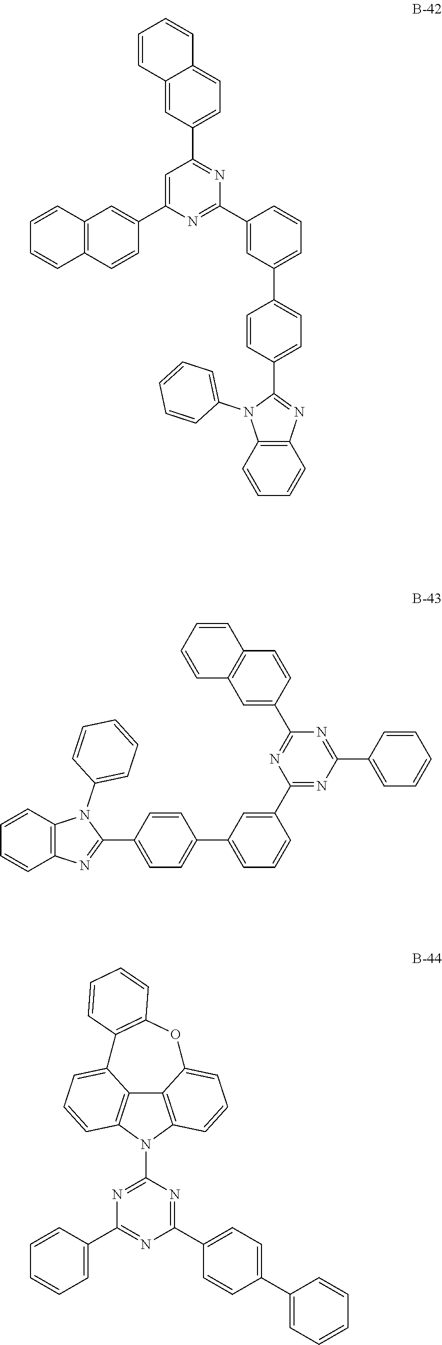 [SMILES: c1ccc(-n2c(-c3ccc(-c4cccc(-c5nc(-c6ccc7ccccc7c6)cc(-c6ccc7ccccc7c6)n5)c4)cc3)nc3ccccc32)cc1 ; c1ccc(-c2nc(-c3cccc(-c4ccc(-c5nc6ccccc6n5-c5ccccc5)cc4)c3)nc(-c3ccc4ccccc4c3)n2)cc1 ; c1ccc(-c2ccc(-c3nc(-c4ccccc4)nc(-n4c5cccc6oc7ccccc7c7cccc4c7c65)n3)cc2)cc1]

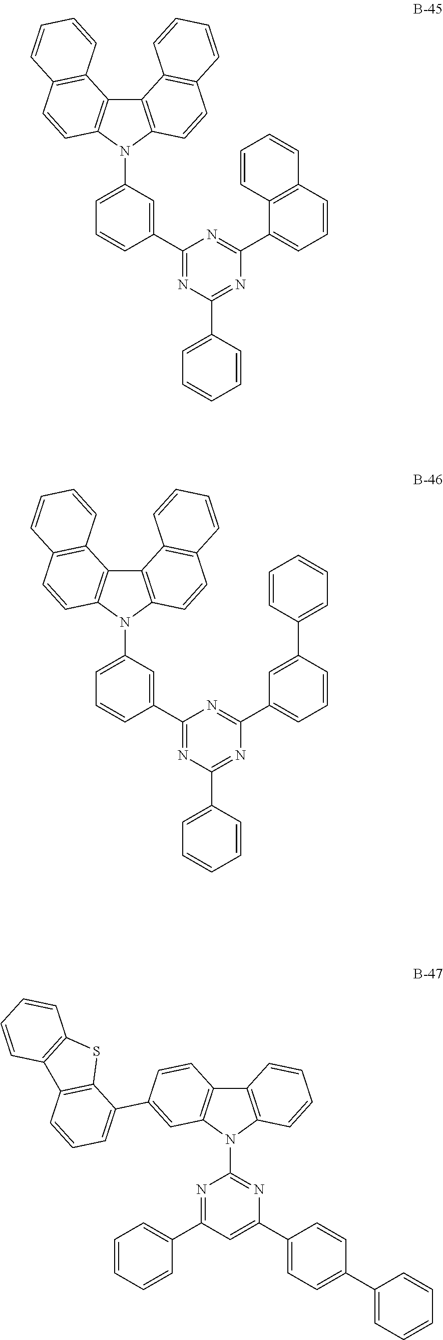 [SMILES: c1ccc(-c2nc(-c3cccc(-n4c5ccc6ccccc6c5c5c6ccccc6ccc54)c3)nc(-c3cccc4ccccc34)n2)cc1 ; c1ccc(-c2cccc(-c3nc(-c4ccccc4)nc(-c4cccc(-n5c6ccc7ccccc7c6c6c7ccccc7ccc65)c4)n3)c2)cc1 ; c1ccc(-c2ccc(-c3cc(-c4ccccc4)nc(-n4c5ccccc5c5ccc(-c6cccc7c6sc6ccccc67)cc54)n3)cc2)cc1]

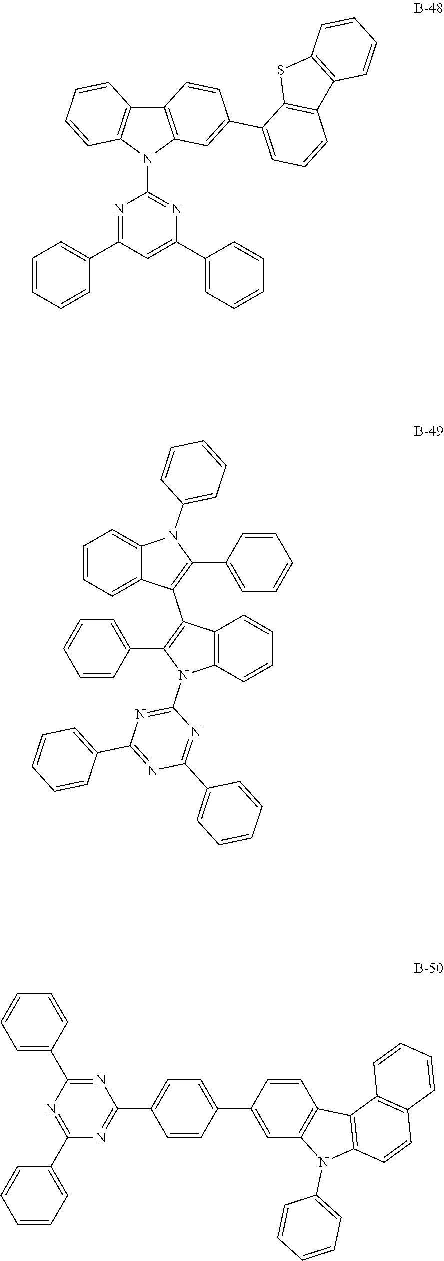 [SMILES: c1ccc(-c2cc(-c3ccccc3)nc(-n3c4ccccc4c4ccc(-c5cccc6c5sc5ccccc56)cc43)n2)cc1 ; c1ccc(-c2nc(-c3ccccc3)nc(-n3c(-c4ccccc4)c(-c4c(-c5ccccc5)n(-c5ccccc5)c5ccccc45)c4ccccc43)n2)cc1 ; c1ccc(-c2nc(-c3ccccc3)nc(-c3ccc(-c4ccc5c6c7ccccc7ccc6n(-c6ccccc6)c5c4)cc3)n2)cc1]

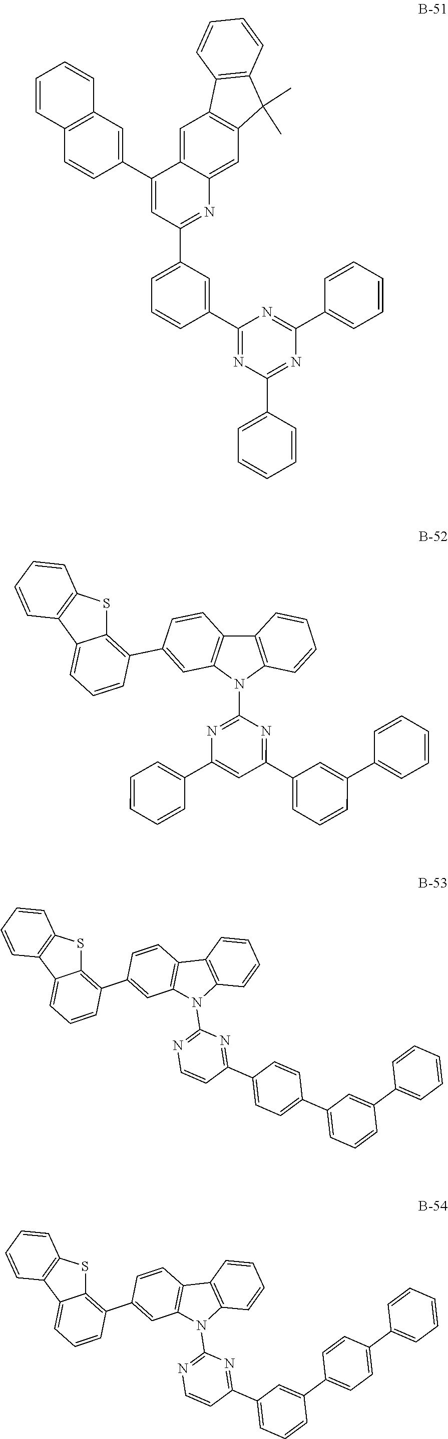 [SMILES: CC1(C)c2ccccc2-c2cc3c(-c4ccc5ccccc5c4)cc(-c4cccc(-c5nc(-c6ccccc6)nc(-c6ccccc6)n5)c4)nc3cc21 ; c1ccc(-c2cccc(-c3cc(-c4ccccc4)nc(-n4c5ccccc5c5ccc(-c6cccc7c6sc6ccccc67)cc54)n3)c2)cc1 ; c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2ccc(-c3cccc(-c4ccnc(-n5c6ccccc6c6ccc(-c7cccc8c7sc7ccccc78)cc65)n4)c3)cc2)cc1]

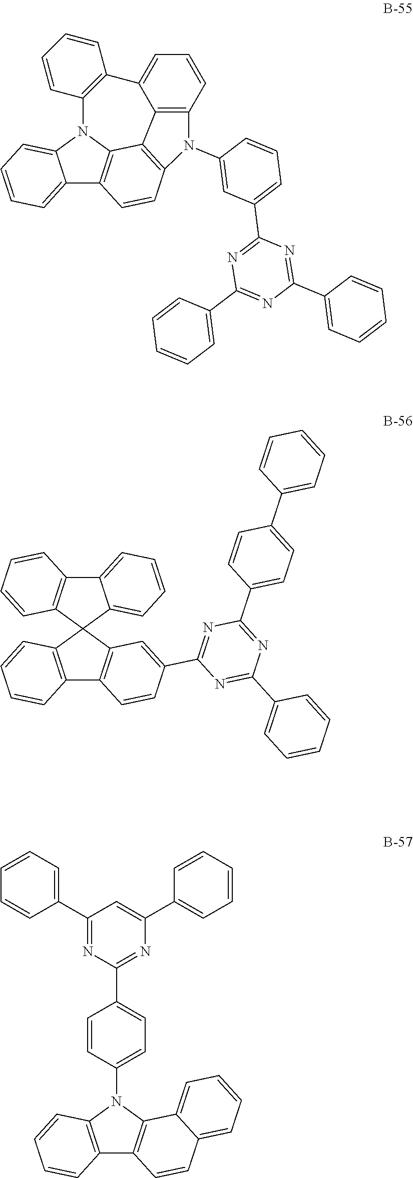 [SMILES: c1ccc(-c2nc(-c3ccccc3)nc(-c3cccc(-n4c5cccc6c7ccccc7n7c8ccccc8c8ccc4c(c65)c87)c3)n2)cc1 ; c1ccc(-c2ccc(-c3nc(-c4ccccc4)nc(-c4ccc5c(c4)C4(c6ccccc6-c6ccccc64)c4ccccc4-5)n3)cc2)cc1 ; c1ccc(-c2cc(-c3ccccc3)nc(-c3ccc(-n4c5ccccc5c5ccc6ccccc6c54)cc3)n2)cc1]

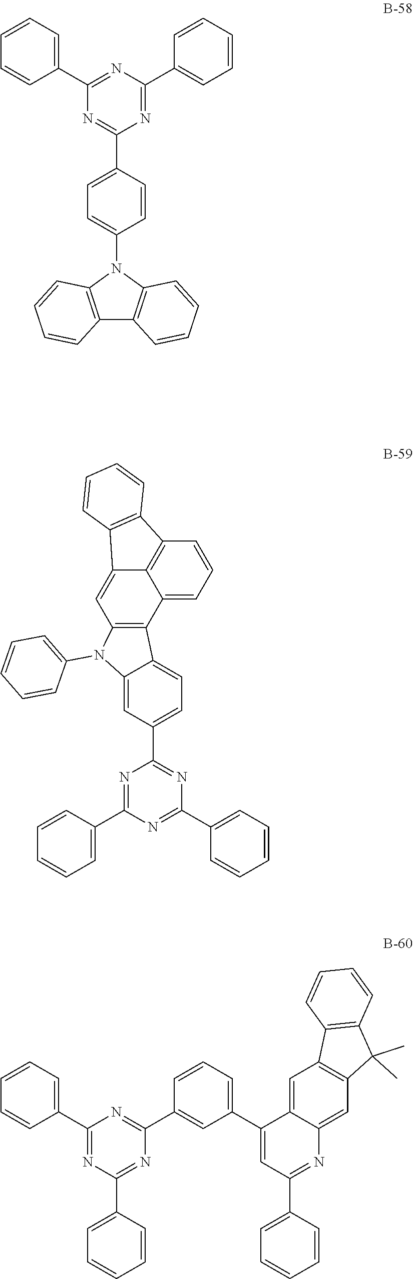 [SMILES: c1ccc(-c2nc(-c3ccccc3)nc(-c3ccc(-n4c5ccccc5c5ccccc54)cc3)n2)cc1 ; c1ccc(-c2nc(-c3ccccc3)nc(-c3ccc4c5c6cccc7c6c(cc5n(-c5ccccc5)c4c3)-c3ccccc3-7)n2)cc1 ; CC1(C)c2ccccc2-c2cc3c(-c4cccc(-c5nc(-c6ccccc6)nc(-c6ccccc6)n5)c4)cc(-c4ccccc4)nc3cc21]

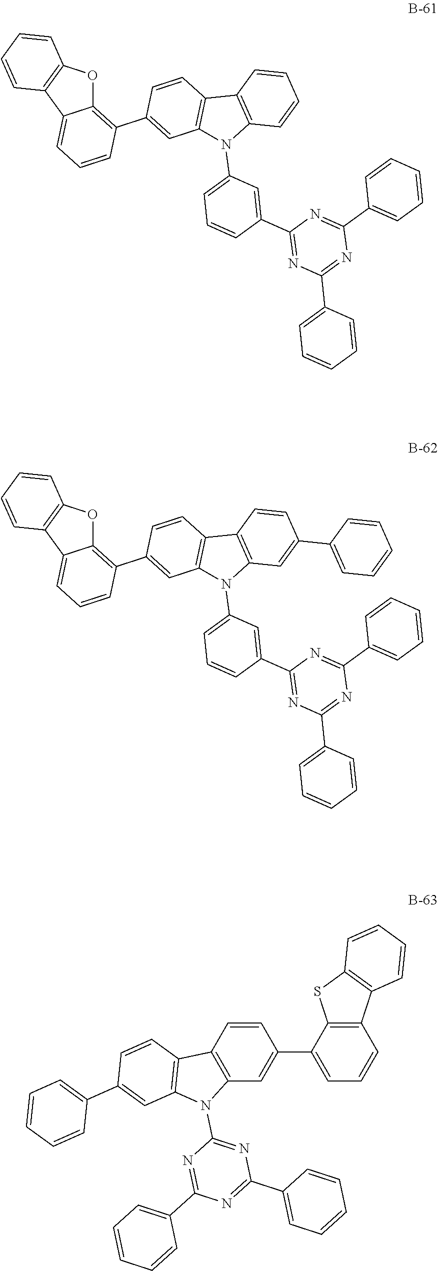 [SMILES: c1ccc(-c2nc(-c3ccccc3)nc(-c3cccc(-n4c5ccccc5c5ccc(-c6cccc7c6oc6ccccc67)cc54)c3)n2)cc1 ; c1ccc(-c2ccc3c4ccc(-c5cccc6c5oc5ccccc56)cc4n(-c4cccc(-c5nc(-c6ccccc6)nc(-c6ccccc6)n5)c4)c3c2)cc1 ; c1ccc(-c2ccc3c4ccc(-c5cccc6c5sc5ccccc56)cc4n(-c4nc(-c5ccccc5)nc(-c5ccccc5)n4)c3c2)cc1]

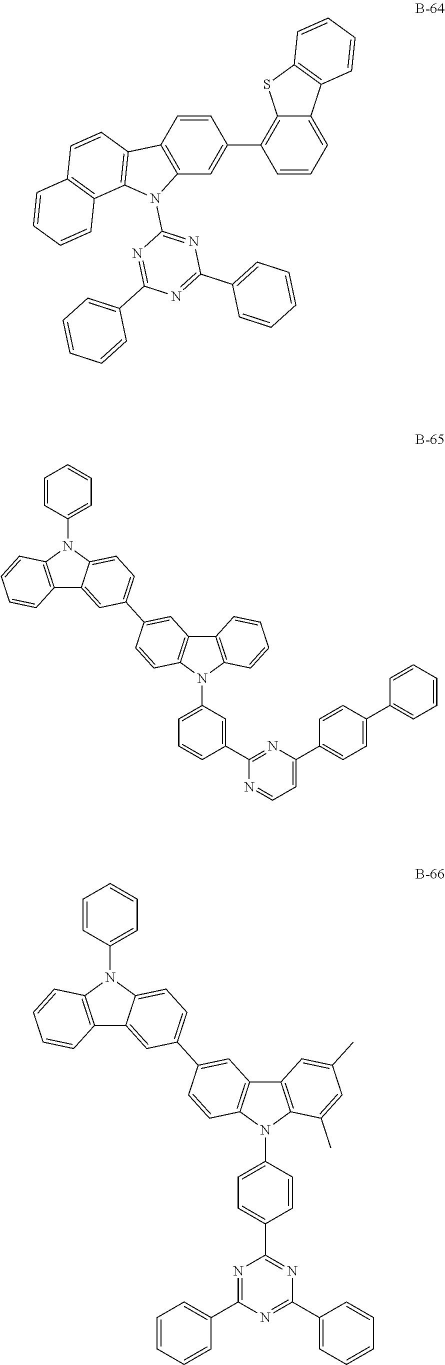 [SMILES: c1ccc(-c2nc(-c3ccccc3)nc(-n3c4cc(-c5cccc6c5sc5ccccc56)ccc4c4ccc5ccccc5c43)n2)cc1 ; c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1]

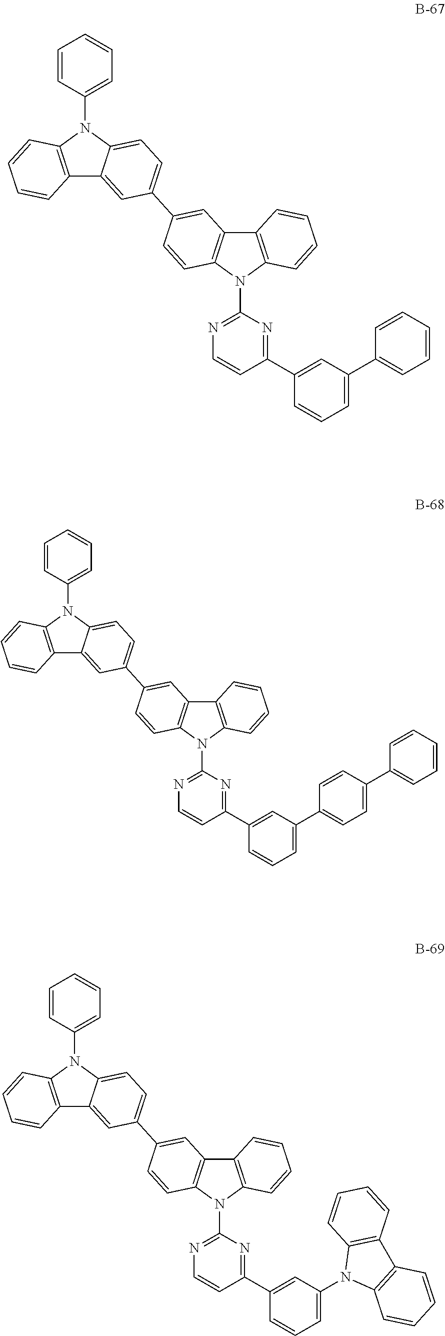 [SMILES: c1ccc(-c2cccc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1 ; c1ccc(-n2c3ccccc3c3cc(-c4ccc5c(c4)c4ccccc4n5-c4nccc(-c5cccc(-n6c7ccccc7c7ccccc76)c5)n4)ccc32)cc1]

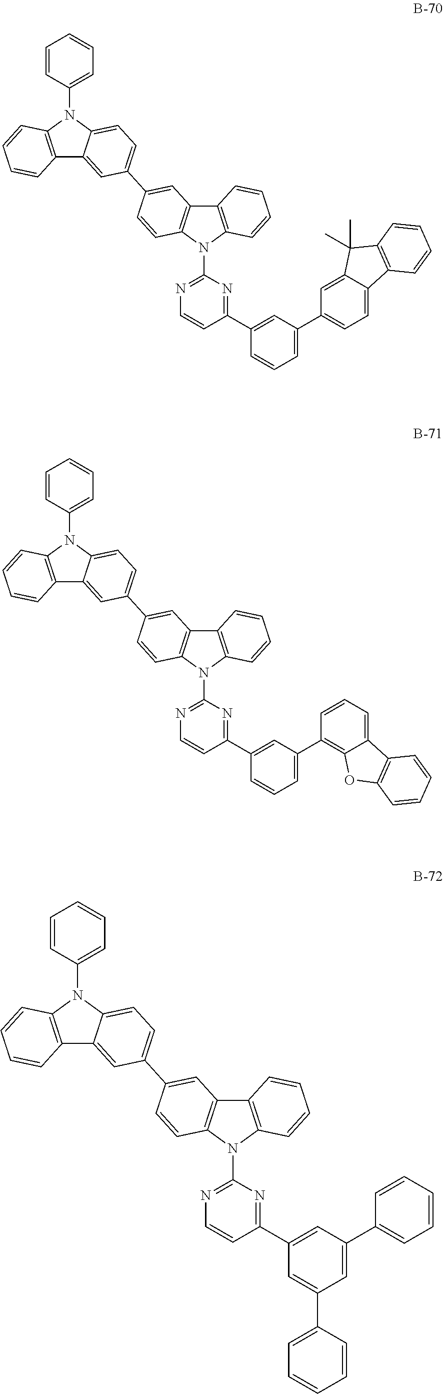 [SMILES: CC1(C)c2ccccc2-c2ccc(-c3cccc(-c4ccnc(-n5c6ccccc6c6cc(-c7ccc8c(c7)c7ccccc7n8-c7ccccc7)ccc65)n4)c3)cc21 ; c1ccc(-n2c3ccccc3c3cc(-c4ccc5c(c4)c4ccccc4n5-c4nccc(-c5cccc(-c6cccc7c6oc6ccccc67)c5)n4)ccc32)cc1 ; c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1]

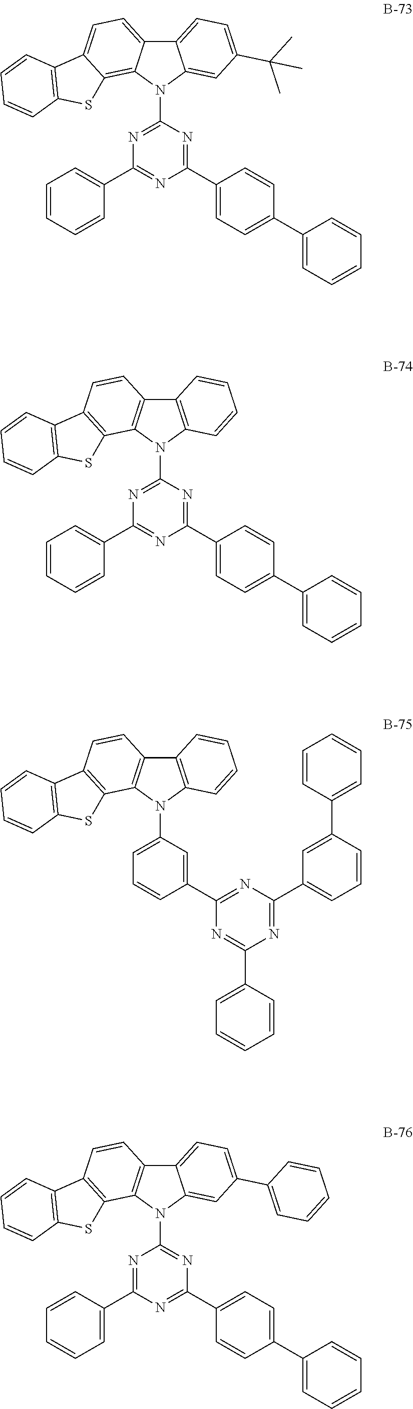 [SMILES: CC(C)(C)c1ccc2c3ccc4c5ccccc5sc4c3n(-c3nc(-c4ccccc4)nc(-c4ccc(-c5ccccc5)cc4)n3)c2c1 ; c1ccc(-c2ccc(-c3nc(-c4ccccc4)nc(-n4c5ccccc5c5ccc6c7ccccc7sc6c54)n3)cc2)cc1 ; c1ccc(-c2cccc(-c3nc(-c4ccccc4)nc(-c4cccc(-n5c6ccccc6c6ccc7c8ccccc8sc7c65)c4)n3)c2)cc1 ; c1ccc(-c2ccc(-c3nc(-c4ccccc4)nc(-n4c5cc(-c6ccccc6)ccc5c5ccc6c7ccccc7sc6c54)n3)cc2)cc1]

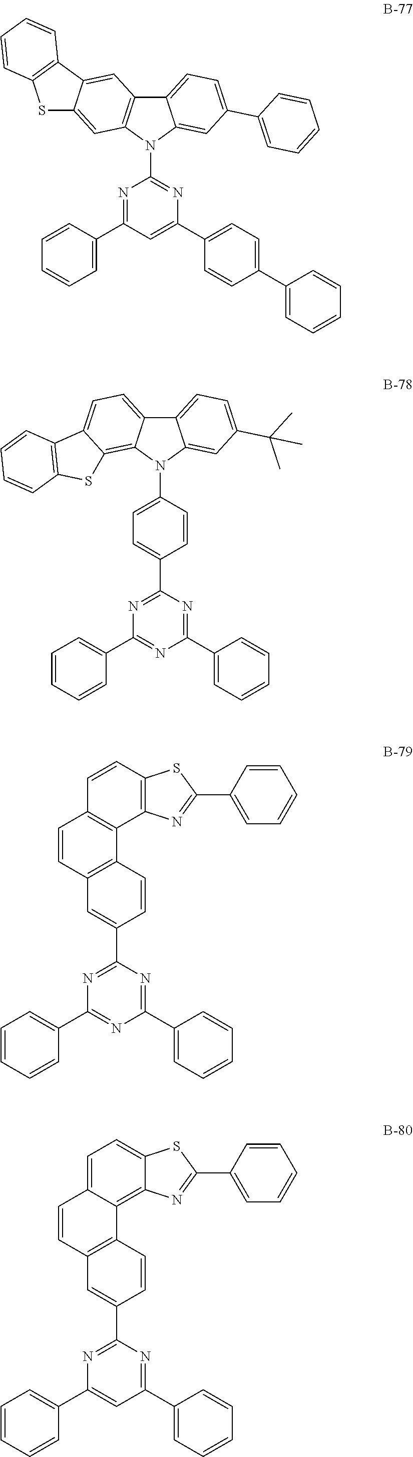 [SMILES: c1ccc(-c2ccc(-c3cc(-c4ccccc4)nc(-n4c5cc(-c6ccccc6)ccc5c5cc6c(cc54)sc4ccccc46)n3)cc2)cc1 ; CC(C)(C)c1ccc2c3ccc4c5ccccc5sc4c3n(-c3ccc(-c4nc(-c5ccccc5)nc(-c5ccccc5)n4)cc3)c2c1 ; c1ccc(-c2nc(-c3ccccc3)nc(-c3ccc4c(ccc5ccc6sc(-c7ccccc7)nc6c54)c3)n2)cc1 ; c1ccc(-c2cc(-c3ccccc3)nc(-c3ccc4c(ccc5ccc6sc(-c7ccccc7)nc6c54)c3)n2)cc1]

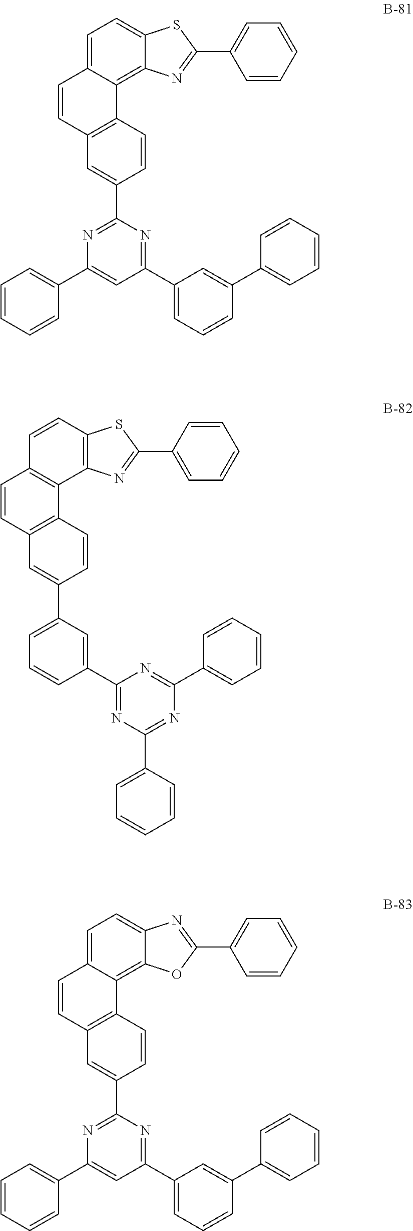 [SMILES: c1ccc(-c2cccc(-c3cc(-c4ccccc4)nc(-c4ccc5c(ccc6ccc7sc(-c8ccccc8)nc7c65)c4)n3)c2)cc1 ; c1ccc(-c2nc(-c3ccccc3)nc(-c3cccc(-c4ccc5c(ccc6ccc7sc(-c8ccccc8)nc7c65)c4)c3)n2)cc1 ; c1ccc(-c2cccc(-c3cc(-c4ccccc4)nc(-c4ccc5c(ccc6ccc7nc(-c8ccccc8)oc7c65)c4)n3)c2)cc1]

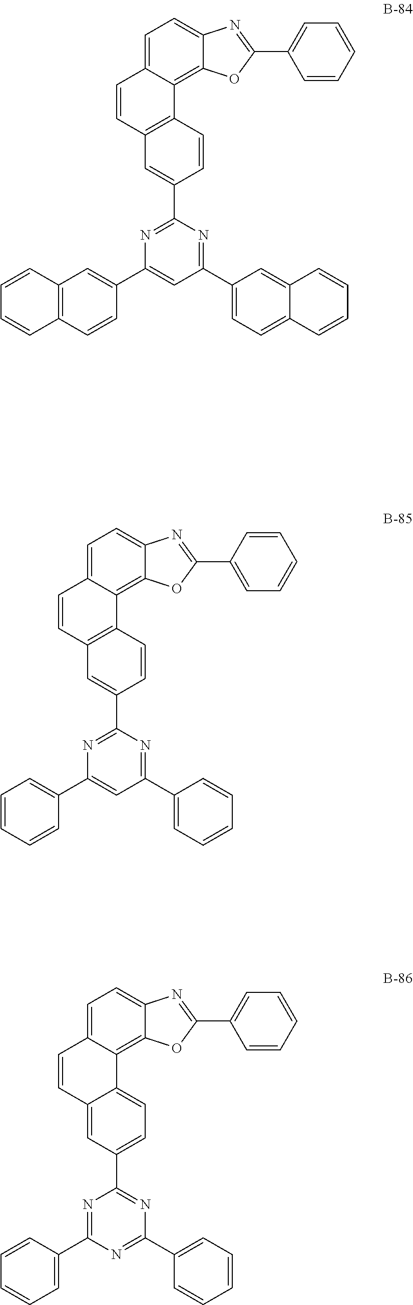 [SMILES: c1ccc(-c2nc3ccc4ccc5cc(-c6nc(-c7ccc8ccccc8c7)cc(-c7ccc8ccccc8c7)n6)ccc5c4c3o2)cc1 ; c1ccc(-c2cc(-c3ccccc3)nc(-c3ccc4c(ccc5ccc6nc(-c7ccccc7)oc6c54)c3)n2)cc1 ; c1ccc(-c2nc(-c3ccccc3)nc(-c3ccc4c(ccc5ccc6nc(-c7ccccc7)oc6c54)c3)n2)cc1]

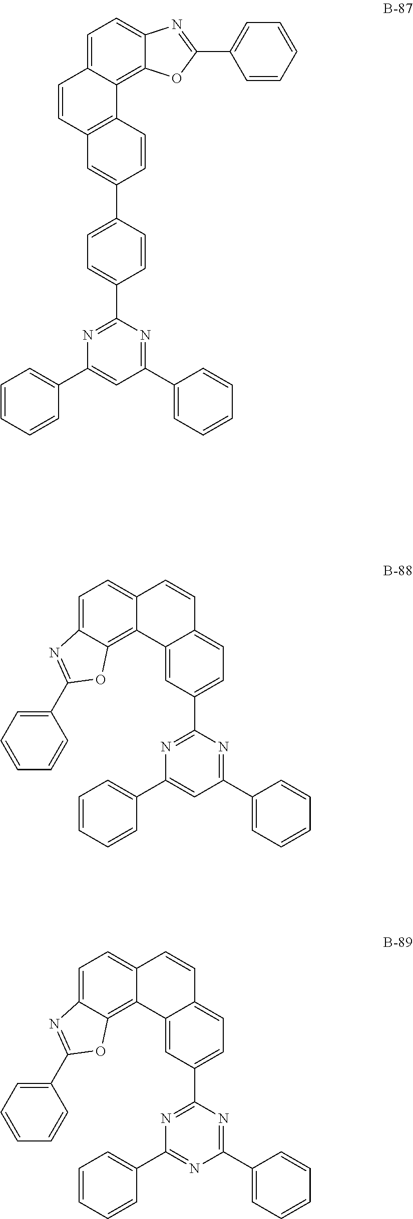 [SMILES: c1ccc(-c2cc(-c3ccccc3)nc(-c3ccc(-c4ccc5c(ccc6ccc7nc(-c8ccccc8)oc7c65)c4)cc3)n2)cc1 ; c1ccc(-c2cc(-c3ccccc3)nc(-c3ccc4ccc5ccc6nc(-c7ccccc7)oc6c5c4c3)n2)cc1 ; c1ccc(-c2nc(-c3ccccc3)nc(-c3ccc4ccc5ccc6nc(-c7ccccc7)oc6c5c4c3)n2)cc1]

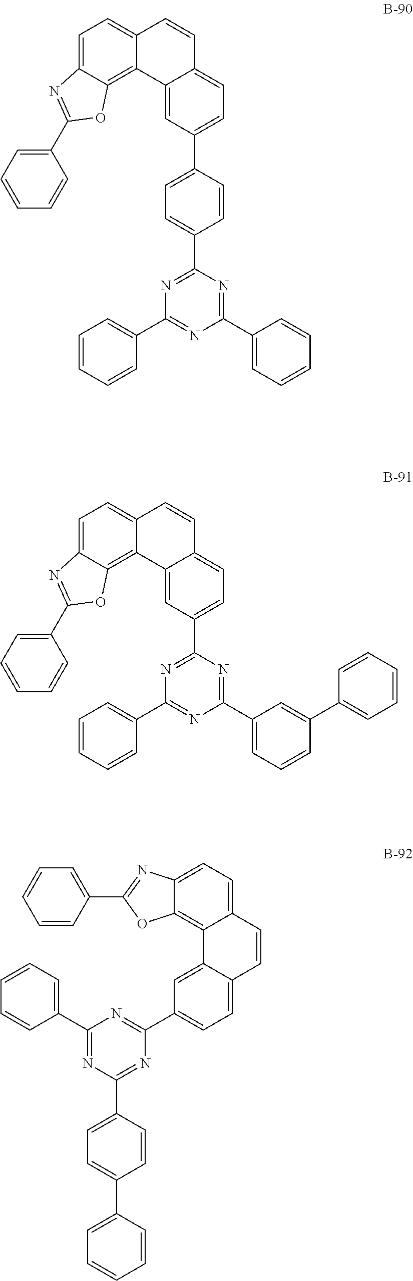 [SMILES: c1ccc(-c2nc(-c3ccccc3)nc(-c3ccc(-c4ccc5ccc6ccc7nc(-c8ccccc8)oc7c6c5c4)cc3)n2)cc1 ; c1ccc(-c2cccc(-c3nc(-c4ccccc4)nc(-c4ccc5ccc6ccc7nc(-c8ccccc8)oc7c6c5c4)n3)c2)cc1 ; c1ccc(-c2ccc(-c3nc(-c4ccccc4)nc(-c4ccc5ccc6ccc7nc(-c8ccccc8)oc7c6c5c4)n3)cc2)cc1]

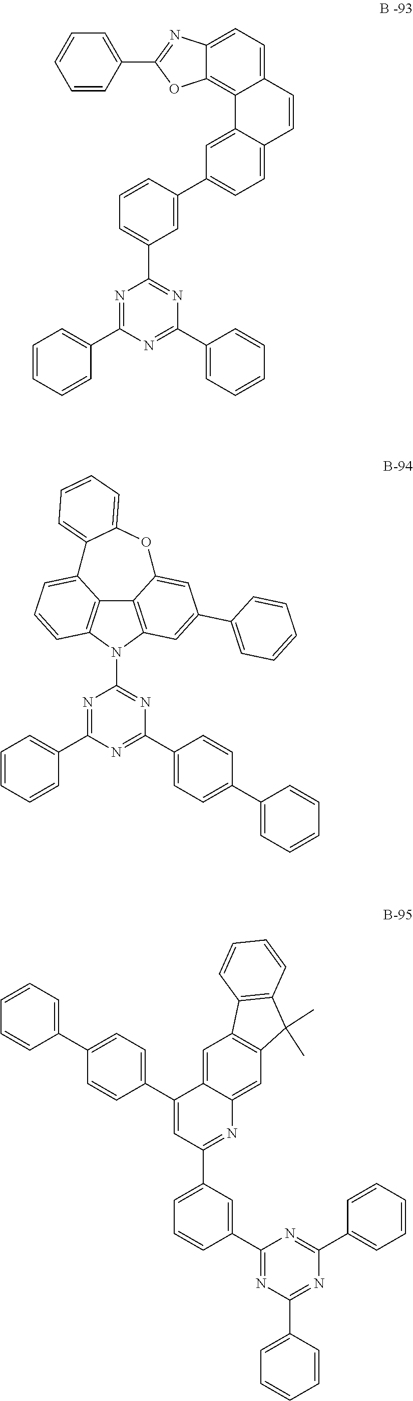 [SMILES: c1ccc(-c2nc(-c3ccccc3)nc(-c3cccc(-c4ccc5ccc6ccc7nc(-c8ccccc8)oc7c6c5c4)c3)n2)cc1 ; c1ccc(-c2ccc(-c3nc(-c4ccccc4)nc(-n4c5cc(-c6ccccc6)cc6oc7ccccc7c7cccc4c7c65)n3)cc2)cc1 ; CC1(C)c2ccccc2-c2cc3c(-c4ccc(-c5ccccc5)cc4)cc(-c4cccc(-c5nc(-c6ccccc6)nc(-c6ccccc6)n5)c4)nc3cc21]

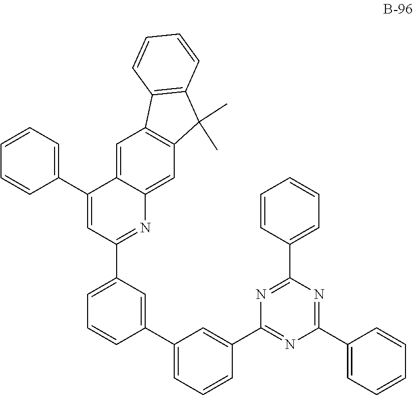 [SMILES: CC1(C)c2ccccc2-c2cc3c(-c4ccccc4)cc(-c4cccc(-c5cccc(-c6nc(-c7ccccc7)nc(-c7ccccc7)n6)c5)c4)nc3cc21]

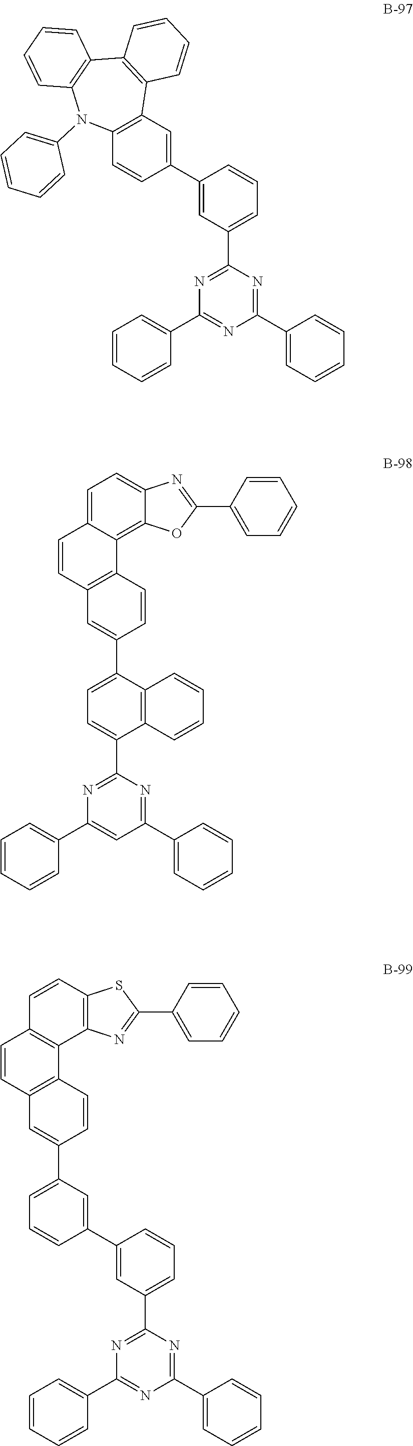 [SMILES: c1ccc(-c2nc(-c3ccccc3)nc(-c3cccc(-c4ccc5c(c4)-c4ccccc4-c4ccccc4N5c4ccccc4)c3)n2)cc1 ; c1ccc(-c2cc(-c3ccccc3)nc(-c3ccc(-c4ccc5c(ccc6ccc7nc(-c8ccccc8)oc7c65)c4)c4ccccc34)n2)cc1 ; c1ccc(-c2nc(-c3ccccc3)nc(-c3cccc(-c4cccc(-c5ccc6c(ccc7ccc8sc(-c9ccccc9)nc8c76)c5)c4)c3)n2)cc1]

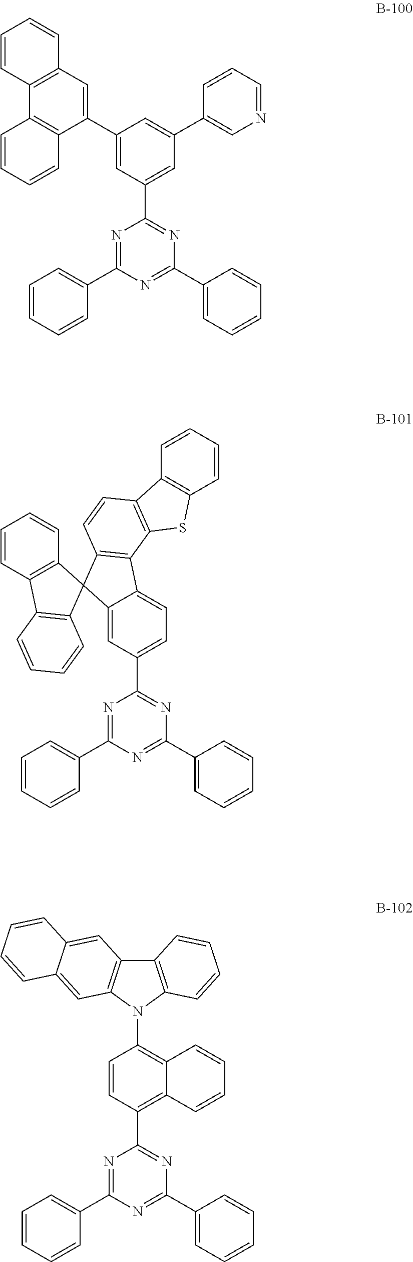 [SMILES: c1ccc(-c2nc(-c3ccccc3)nc(-c3cc(-c4cccnc4)cc(-c4cc5ccccc5c5ccccc45)c3)n2)cc1 ; c1ccc(-c2nc(-c3ccccc3)nc(-c3ccc4c(c3)C3(c5ccccc5-c5ccccc53)c3ccc5c(sc6ccccc65)c3-4)n2)cc1 ; c1ccc(-c2nc(-c3ccccc3)nc(-c3ccc(-n4c5ccccc5c5cc6ccccc6cc54)c4ccccc34)n2)cc1]

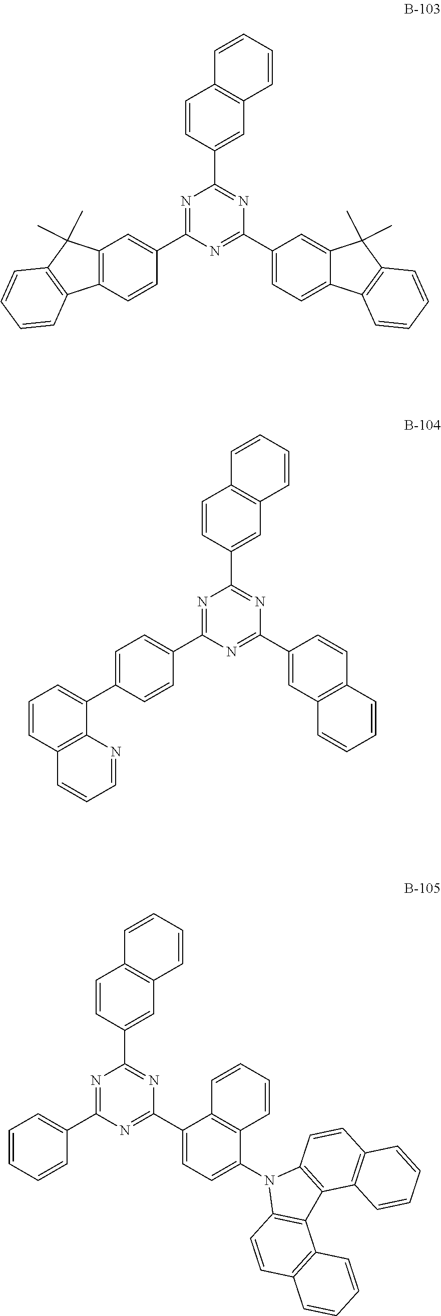 [SMILES: CC1(C)c2ccccc2-c2ccc(-c3nc(-c4ccc5c(c4)C(C)(C)c4ccccc4-5)nc(-c4ccc5ccccc5c4)n3)cc21 ; c1ccc2cc(-c3nc(-c4ccc(-c5cccc6cccnc56)cc4)nc(-c4ccc5ccccc5c4)n3)ccc2c1 ; c1ccc(-c2nc(-c3ccc4ccccc4c3)nc(-c3ccc(-n4c5ccc6ccccc6c5c5c6ccccc6ccc54)c4ccccc34)n2)cc1]

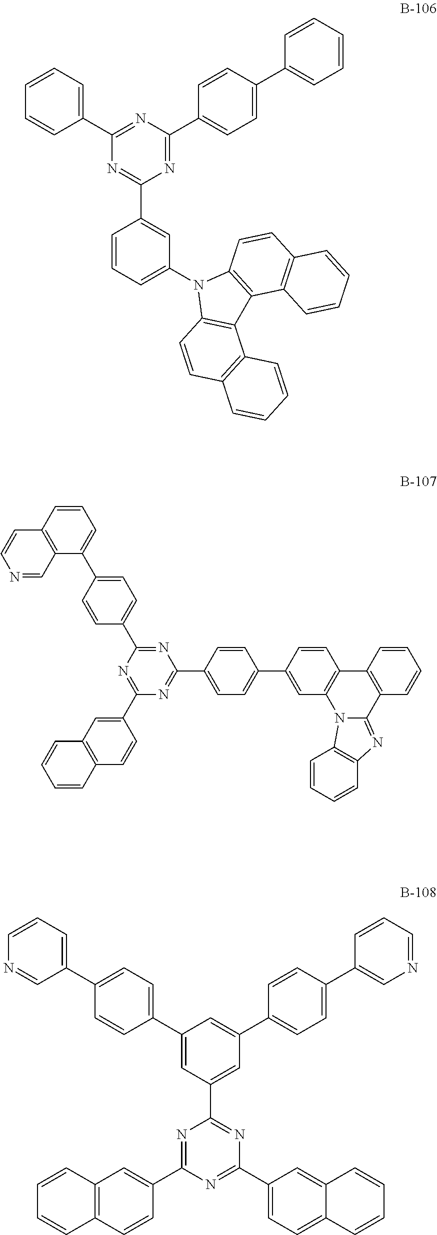 [SMILES: c1ccc(-c2ccc(-c3nc(-c4ccccc4)nc(-c4cccc(-n5c6ccc7ccccc7c6c6c7ccccc7ccc65)c4)n3)cc2)cc1 ; c1ccc2cc(-c3nc(-c4ccc(-c5ccc6c7ccccc7c7nc8ccccc8n7c6c5)cc4)nc(-c4ccc(-c5cccc6ccncc56)cc4)n3)ccc2c1 ; c1cncc(-c2ccc(-c3cc(-c4ccc(-c5cccnc5)cc4)cc(-c4nc(-c5ccc6ccccc6c5)nc(-c5ccc6ccccc6c5)n4)c3)cc2)c1]

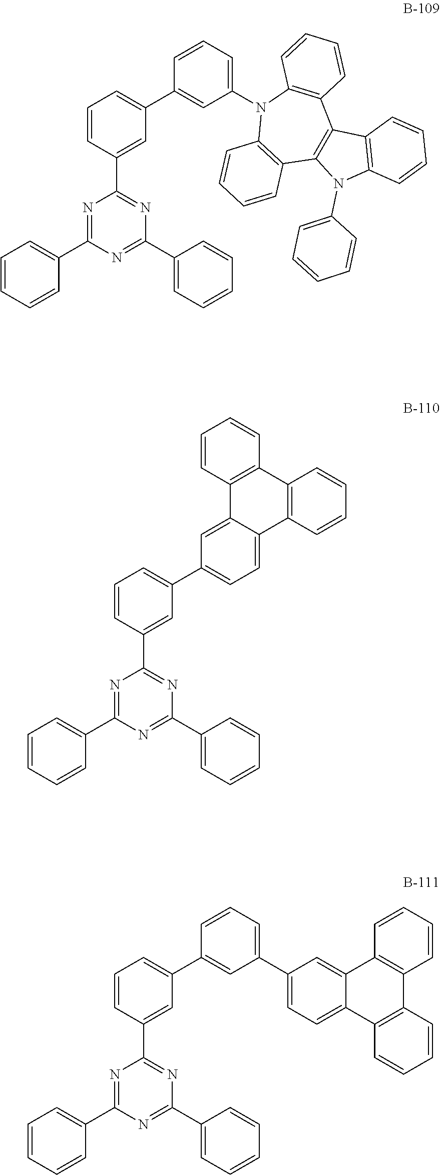 [SMILES: c1ccc(-c2nc(-c3ccccc3)nc(-c3cccc(-c4cccc(N5c6ccccc6-c6c(n(-c7ccccc7)c7ccccc67)-c6ccccc65)c4)c3)n2)cc1 ; c1ccc(-c2nc(-c3ccccc3)nc(-c3cccc(-c4ccc5c6ccccc6c6ccccc6c5c4)c3)n2)cc1 ; c1ccc(-c2nc(-c3ccccc3)nc(-c3cccc(-c4cccc(-c5ccc6c7ccccc7c7ccccc7c6c5)c4)c3)n2)cc1]

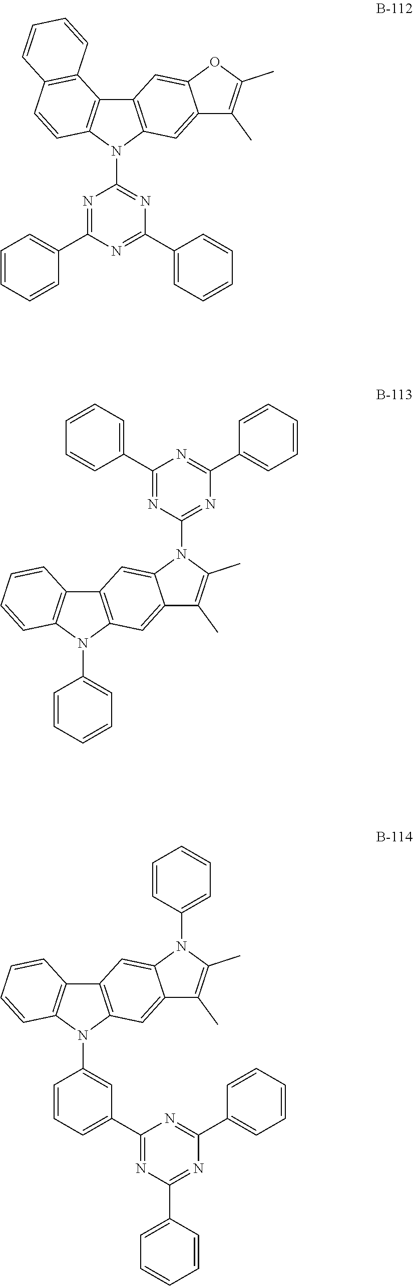 [SMILES: Cc1oc2cc3c4c5ccccc5ccc4n(-c4nc(-c5ccccc5)nc(-c5ccccc5)n4)c3cc2c1C ; Cc1c(C)n(-c2nc(-c3ccccc3)nc(-c3ccccc3)n2)c2cc3c4ccccc4n(-c4ccccc4)c3cc12 ; Cc1c(C)n(-c2ccccc2)c2cc3c4ccccc4n(-c4cccc(-c5nc(-c6ccccc6)nc(-c6ccccc6)n5)c4)c3cc12]

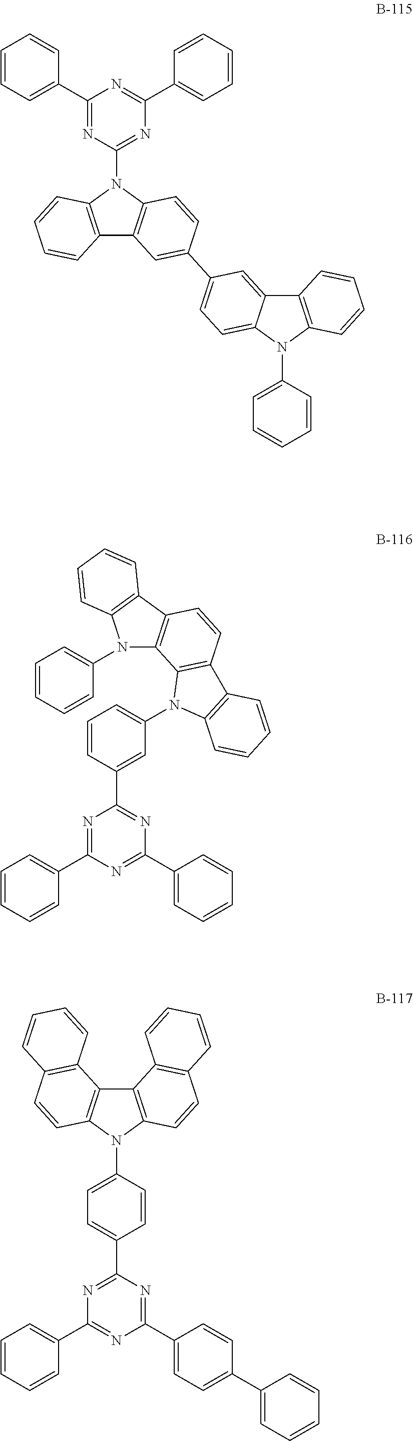 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3cccc(-n4c5ccccc5c5ccc6c7ccccc7n(-c7ccccc7)c6c54)c3)n2)cc1 ; c1ccc(-c2ccc(-c3nc(-c4ccccc4)nc(-c4ccc(-n5c6ccc7ccccc7c6c6c7ccccc7ccc65)cc4)n3)cc2)cc1]

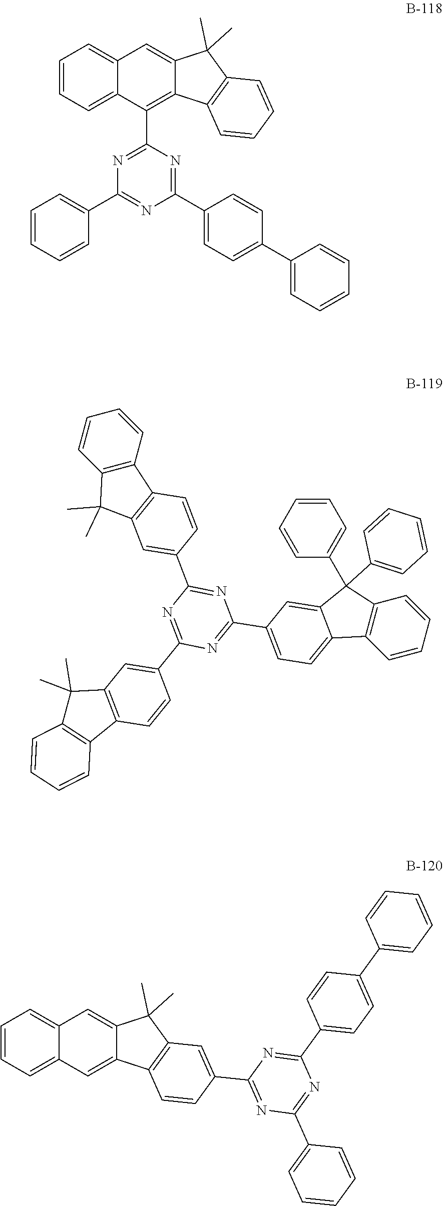 [SMILES: CC1(C)c2ccccc2-c2c1cc1ccccc1c2-c1nc(-c2ccccc2)nc(-c2ccc(-c3ccccc3)cc2)n1 ; CC1(C)c2ccccc2-c2ccc(-c3nc(-c4ccc5c(c4)C(C)(C)c4ccccc4-5)nc(-c4ccc5c(c4)C(c4ccccc4)(c4ccccc4)c4ccccc4-5)n3)cc21 ; CC1(C)c2cc(-c3nc(-c4ccccc4)nc(-c4ccc(-c5ccccc5)cc4)n3)ccc2-c2cc3ccccc3cc21]

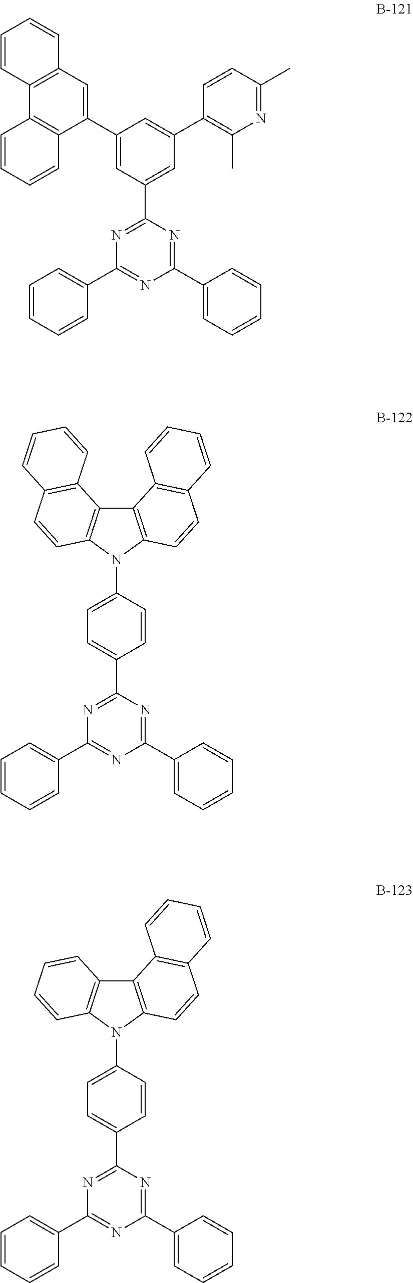 [SMILES: Cc1ccc(-c2cc(-c3nc(-c4ccccc4)nc(-c4ccccc4)n3)cc(-c3cc4ccccc4c4ccccc34)c2)c(C)n1 ; c1ccc(-c2nc(-c3ccccc3)nc(-c3ccc(-n4c5ccc6ccccc6c5c5c6ccccc6ccc54)cc3)n2)cc1 ; c1ccc(-c2nc(-c3ccccc3)nc(-c3ccc(-n4c5ccccc5c5c6ccccc6ccc54)cc3)n2)cc1]

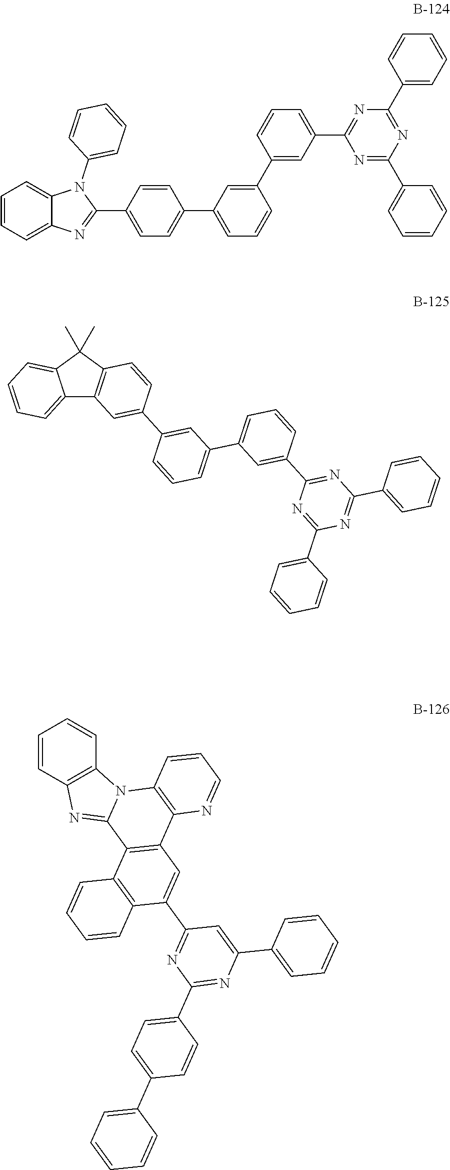 [SMILES: c1ccc(-c2nc(-c3ccccc3)nc(-c3cccc(-c4cccc(-c5ccc(-c6nc7ccccc7n6-c6ccccc6)cc5)c4)c3)n2)cc1 ; CC1(C)c2ccccc2-c2cc(-c3cccc(-c4cccc(-c5nc(-c6ccccc6)nc(-c6ccccc6)n5)c4)c3)ccc21 ; c1ccc(-c2ccc(-c3nc(-c4ccccc4)cc(-c4cc5c6ncccc6n6c7ccccc7nc6c5c5ccccc45)n3)cc2)cc1]

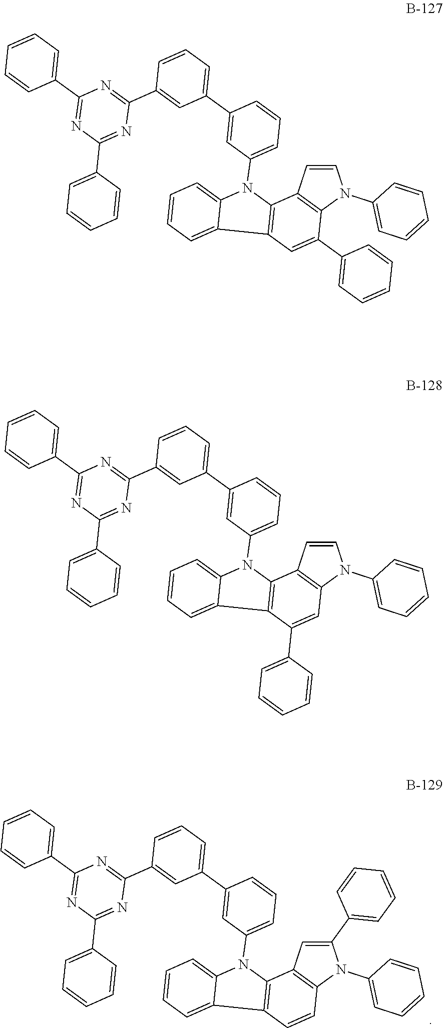 [SMILES: c1ccc(-c2nc(-c3ccccc3)nc(-c3cccc(-c4cccc(-n5c6ccccc6c6cc(-c7ccccc7)c7c(ccn7-c7ccccc7)c65)c4)c3)n2)cc1 ; c1ccc(-c2nc(-c3ccccc3)nc(-c3cccc(-c4cccc(-n5c6ccccc6c6c(-c7ccccc7)cc7c(ccn7-c7ccccc7)c65)c4)c3)n2)cc1 ; c1ccc(-c2nc(-c3ccccc3)nc(-c3cccc(-c4cccc(-n5c6ccccc6c6ccc7c(cc(-c8ccccc8)n7-c7ccccc7)c65)c4)c3)n2)cc1]

8. The organic electroluminescent device according to claim 1, wherein the LUMO energy value of the light-emitting layer (Ah) and the LUMO energy value of the electron transport zone (Ae) satisfy the following equation 1:
Ae≤Ah+0.5 eV (1)
wherein the comparison of the energy values is based on the absolute values thereof.

9. The organic electroluminescent device according to claim 1, wherein the electron transport zone comprises one or more of a hole blocking layer, an electron transport layer, an electron buffer layer, and an electron injection layer.

10. The organic electroluminescent device according to claim 1, wherein the electron transport zone further comprises an electron transport compound, a reductive dopant, or a combination thereof.
